(19) United States
(12) Patent Application Publication
(10) Pub. No.: US 2024/0349528 A1
(43) Pub. Date: Oct. 17, 2024

(54) ORGANIC ELECTROLUMINESCENT ELEMENT, ORGANIC ELECTROLUMINESCENT DISPLAY DEVICE, AND ELECTRONIC DEVICE

(71) Applicant: IDEMITSU KOSAN CO., LTD., Tokyo (JP)

(72) Inventors: Masato NAKAMURA, Tokyo (JP); Emiko KAMBE, Tokyo (JP); Kazuki NISHIMURA, Tokyo (JP); Yusuke TAKAHASHI, Tokyo (JP); Tasuku HAKETA, Tokyo (JP); Satomi TASAKI, Tokyo (JP); Tetsuya MASUDA, Tokyo (JP); Keitaro YAMADA, Tokyo (JP)

(73) Assignee: IDEMITSU KOSAN CO., LTD., Tokyo (JP)

(21) Appl. No.: 18/261,119

(22) PCT Filed: Jan. 13, 2022
(86) PCT No.: PCT/JP2022/000808

§ 371 Date: Nov. 7, 2023

Related U.S. Application Data
(63) Continuation-in-part of application No. 17/511,477, filed on Oct. 26, 2021.

(30) Foreign Application Priority Data
Jan. 13, 2021 (JP) 2021-003672
Feb. 17, 2021 (JP) 2021-023381
Apr. 28, 2021 (JP) 2021-076715
Jun. 9, 2021 (JP) 2021-096578
Jun. 25, 2021 (JP) 2021-106128

(51) Int. Cl. H10K 50/16; H10K 50/13; H10K 85/60; H10K 101/30

(52) U.S. Cl. CPC H10K 50/166; H10K 50/13; H10K 50/167; H10K 85/636; H10K 2101/30

(57) ABSTRACT

An organic electroluminescence device includes an emitting region provided between a cathode and an anode, a first anode side organic layer, a second anode side organic layer, and a third anode side organic layer, in which the emitting region includes at least one emitting layer, the second anode side organic layer contains at least one compound different from the compound contained in the third anode side organic layer, the third anode side organic layer has a film thickness of 20 nm or more, and a difference NM₂−NM₃ between a refractive index NM₂ of a constituent material contained in the second anode side organic layer and a refractive index NM₃ of a constituent material contained in the third anode side organic layer satisfies a relationship of a numerical formula (Numerical Formula N1) below,

$$N {M}_{2} - N {M}_{3} \geq 0.05 . \qquad ( Numerical Formula N1 )$$

### TECHNICAL FIELD

The present invention relates to an organic electroluminescence device, an organic electroluminescence display device, and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

For instance, studies for improving performance of an organic EL device have been made in Patent Literature 1, Patent Literature 2, and Patent Literature 3. The performance of the organic EL device is evaluable in terms of, for instance, luminance, emission wavelength, chromaticity, luminous efficiency, drive voltage, and lifetime. The organic EL device has a problem of a low light-extraction efficiency. Especially, the decay due to reflection caused by a difference in refractive indices between adjacent layers is a major factor of decreasing the light-extraction efficiency of the organic EL device. In order to reduce this impact, there is provided an arrangement of an organic EL device including a layer formed from a low refractive index material.

### CITATION LIST

### Patent Literature(s)

Patent Literature 1 International Publication No. WO 2020/189316
Patent Literature 2 JP 2019-161218 A
Patent Literature 3 International Publication No. WO 2011/093056

### SUMMARY OF THE INVENTION

### Problems to be Solved by the Invention

An object of the invention is to provide an organic electroluminescence device and an organic electroluminescence display device with enhanced luminous efficiency, an electronic device provided with the organic electroluminescence device, and an electronic device provided with the organic electroluminescence display device.

### Means for Solving the Problem(s)

According to an aspect of the invention, there is provided an organic electroluminescence device including: a cathode; an anode; an emitting region provided between the cathode and the anode; a first anode side organic layer; a second anode side organic layer; and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, a total of a film thickness of the second anode side organic layer and a film thickness of the third anode side organic layer is in range from 30 nm to 150 nm, and a ratio of the film thickness of the third anode side organic layer to the film thickness of the second anode side organic layer satisfies a relationship of a numerical formula (Numerical Formula A1) below,

$$0.50 < T {L}_{3} / {TL}_{2} < 4. \qquad ( Numerical Formula A1 )$$

where TL₂ is a film thickness of the second anode side organic layer, TL₃ is a film thickness of the third anode side organic layer, and a unit of the film thickness is denoted by nm.

According to an aspect of the invention, there is provided an organic electroluminescence device including: a cathode; an anode; an emitting region provided between the cathode and the anode; a first anode side organic layer; a second anode side organic layer; and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, the third anode side organic layer contains a compound represented by a formula (C1) below or a compound represented by a formula (C2) below, a total of a film thickness of the second anode side organic layer and a film thickness of the third anode side organic layer is in range from 30 nm to 150 nm, and a ratio of the film thickness of the third anode side organic layer to the film thickness of the second anode side organic layer satisfies a relationship of a numerical formula (Numerical Formula A2) below,

$$0.30 < T {L}_{3} / {TL}_{2} < 4. \qquad ( Numerical Formula A2 )$$

where TL₂ is a film thickness of the second anode side organic layer, TL₃ is a film thickness of the third anode side organic layer, and a unit of the film thickness is denoted by nm.

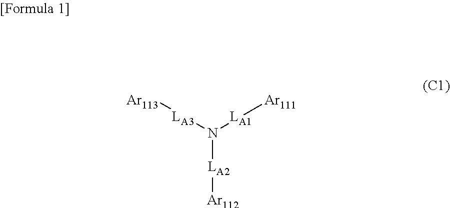

In the formula (C1):
L_{A1}, L_{A2}, and L_{A3} are each independently a single bond, a substituted or unsubstituted arylene group having 6 to 50 ring carbon atoms, or a substituted or unsubstituted divalent heterocyclic group having 5 to 50 ring atoms;
Ar₁₁₁, Ar₁₁₂, and Ar₁₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

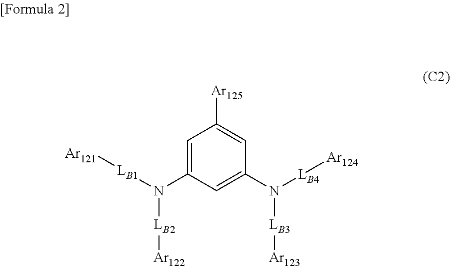

In the formula (C2):
L_{B1}, L_{B2}, L_{B3}, and L_{B4} are each independently a single bond, or a substituted or unsubstituted arylene group having 6 to 50 ring carbon atoms; and
Ar₁₂₁, Ar₁₂₂, Ar₁₂₃, Ar₁₂₄, and Ar₁₂₅ are each independently a substituted or unsubstituted aryl group having 6 to 50 ring carbon atoms, or a substituted or unsubstituted heterocyclic group having 5 to 50 ring atoms.

In the compound represented by the formula (C1) and the compound represented by the formula (C2), the substituent for the “substituted or unsubstituted” group is not a group represented by —N(R_{C6})(R_{C7}), and R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

According to an aspect of the invention, there is provided an organic electroluminescence device including: a cathode; an anode; an emitting region provided between the cathode and the anode; and a hole transporting zone provided between the anode and the emitting region, in which the emitting region includes at least one emitting layer, the hole transporting zone includes at least a second anode side organic layer and a third anode side organic layer, the second anode side organic layer and the third anode side organic layer are arranged between the anode and the emitting region in this order from a side close to the anode, the second anode side organic layer contains at least one compound selected from the group consisting of the compound represented by the formula (C1) and a compound represented by a formula (C3) below, the third anode side organic layer contains the compound represented by the formula (C1), here, the second anode side organic layer contains at least one compound different from the compound contained in the third anode side organic layer, a difference NM₂−NM₃ between a refractive index NM₂ of a constituent material contained in the second anode side organic layer and a refractive index NM₃ of a constituent material contained in the third anode side organic layer satisfies a relationship of a numerical formula (Numerical Formula N1) below, and a distance from an interface at a side close to the anode of the third anode side organic layer to an interface at a side close to the anode of an emitting layer disposed closest to the anode in the emitting region is 20 nm or more.

$$N {M}_{2} - N {M}_{3} \geq 0.05 \qquad ( Numerical Formula N1 )$$

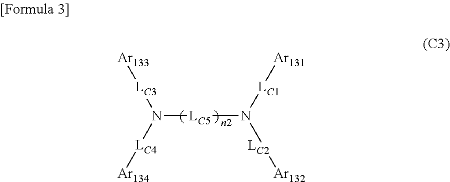

In the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different; and
a first amino group represented by a formula (C3-1) below and a second amino group represented by a formula (C3-2) below are an identical group.

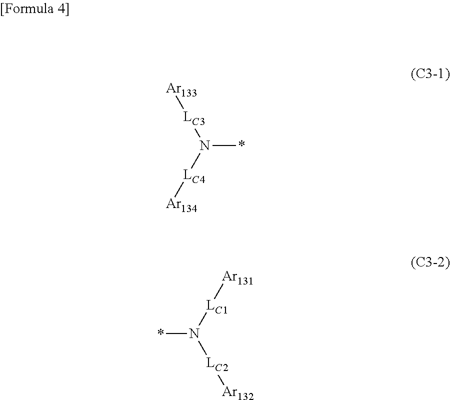

In the formulae (C3-1) and (C3-2), each * represents a bonding position to L_{C5}.

In the compound represented by the formula (C1) and the compound represented by the formula (C3), the substituent for the “substituted or unsubstituted” group is not a group represented by —N(R_{C6})(R_{C7}), and R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

According to an aspect of the invention, there is provided an organic electroluminescence device, including: a cathode; an anode; an emitting region provided between the cathode and the anode; and a hole transporting zone provided between the anode and the emitting region, in which the emitting region includes at least one emitting layer, the hole transporting zone includes at least a first anode side organic layer, a second anode side organic layer, and a third anode side organic layer, the first anode side organic layer, the second anode side organic layer, and the third anode side organic layer are arranged between the anode and the emitting region in this order from a side close to the anode, the first anode side organic layer includes a first organic material and a second organic material, the first organic material is different from the second organic material, a content of the second organic material in the first anode side organic layer is less than 50 mass %, the second anode side organic layer contains at least one compound selected from the group consisting of the compound represented by the formula (C1) and the compound represented by the formula (C3), the first amino group represented by the formula (C3-1) and the second amino group represented by the formula (C3-2) are optionally an identical group or different groups, the third anode side organic layer contains the compound represented by the formula (C1), the second anode side organic layer contains at least one compound different from the compound contained in the third anode side organic layer, a difference NM₂−NM₃ between a refractive index NM₂ of a constituent material contained in the second anode side organic layer and a refractive index NM₃ of a constituent material contained in the third anode side organic layer satisfies the relationship of the numerical formula (Numerical Formula N1), and a film thickness of the third anode side organic layer is 20 nm or more.

According to an aspect of the invention, there is provided an organic electroluminescence display device, including: an anode and a cathode arranged opposite each other; a blue-emitting organic EL device as a blue pixel; a green-emitting organic EL device as a green pixel; and a red-emitting organic EL device as a red pixel, in which the blue pixel includes the organic electroluminescence device according to the aspect of the invention as the blue-emitting organic EL device, the green-emitting organic EL device includes a green emitting region provided between the anode and the cathode, the red-emitting organic EL device includes a red emitting region provided between the anode and the cathode, in a case where the first anode side organic layer, the second anode side organic layer, and the third anode side organic layer are included in the blue-emitting organic EL device, the first anode side organic layer, the second anode side organic layer, and the third anode side organic layer are provided between the anode and the emitting region of the blue-emitting organic EL device, the green emitting region, and the red emitting region in a shared manner across the blue-emitting organic EL device, the green-emitting organic EL device, and the red-emitting organic EL device, and in a case where the first anode side organic layer is not included in the blue-emitting organic EL device and the second anode side organic layer and the third anode side organic layer are included in the blue-emitting organic EL device, the second anode side organic layer and the third anode side organic layer are provided between the anode and the emitting region of the blue-emitting organic EL device, the green emitting region, and the red emitting region in a shared manner across the blue-emitting organic EL device, the green-emitting organic EL device, and the red-emitting organic EL device.

According to an aspect of the invention, there is provided an electronic device provided with the organic electroluminescence device according to the aspect of the invention.

According to an aspect of the invention, there is provided an electronic device provided with the organic electroluminescence display device according to the aspect of the invention.

According to the aspects of the invention, there are provided an organic electroluminescence device and an organic electroluminescence display device with enhanced luminous efficiency, an electronic device provided with the organic electroluminescence device, and an electronic device provided with the organic electroluminescence display device.

### BRIEF EXPLANATION OF DRAWING(S)

FIG. 1 schematically depicts an exemplary arrangement of an organic electroluminescence device according to a first exemplary embodiment.

FIG. 2 schematically depicts another exemplary arrangement of the organic electroluminescence device according to the first exemplary embodiment.

FIG. 3 schematically depicts still another exemplary arrangement of the organic electroluminescence device according to the first exemplary embodiment.

FIG. 4 schematically depicts yet another exemplary arrangement of the organic electroluminescence device according to the first exemplary embodiment.

FIG. 5 schematically depicts an exemplary arrangement of an organic electroluminescence display device according to a second exemplary embodiment.

FIG. 6 schematically depicts another exemplary arrangement of the organic electroluminescence display device according to the second exemplary embodiment.

FIG. 7 schematically depicts still another exemplary arrangement of the organic electroluminescence display device according to the second exemplary embodiment.

FIG. 8 schematically depicts yet another exemplary arrangement of the organic electroluminescence display device according to the second exemplary embodiment.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, cross-linking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless otherwise specified, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as the pyridine ring atoms. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituent Mentioned Herein

Substituent mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G11B). (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

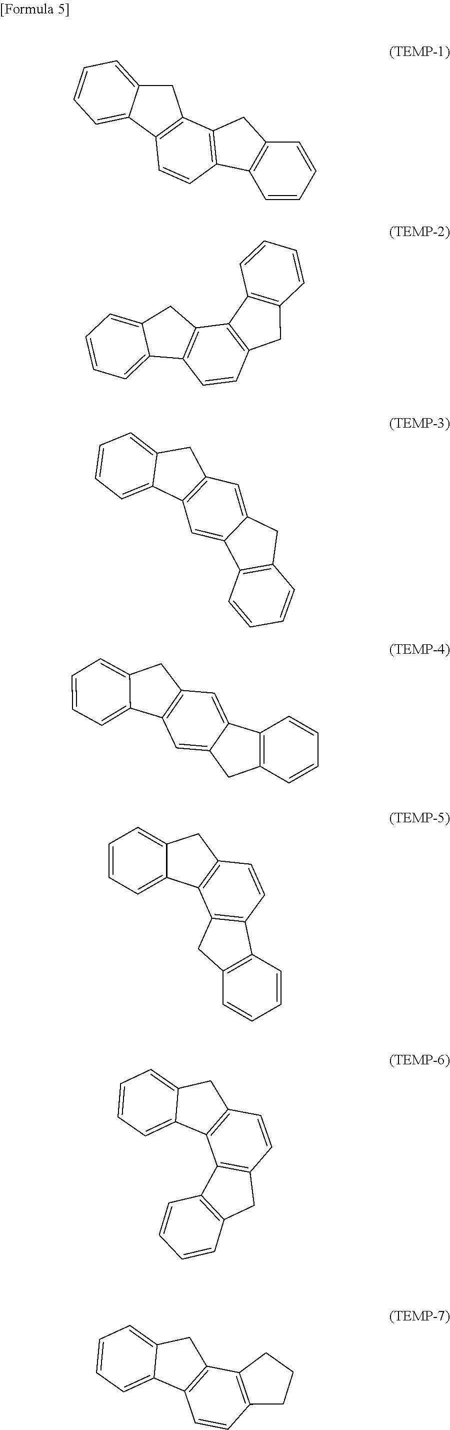

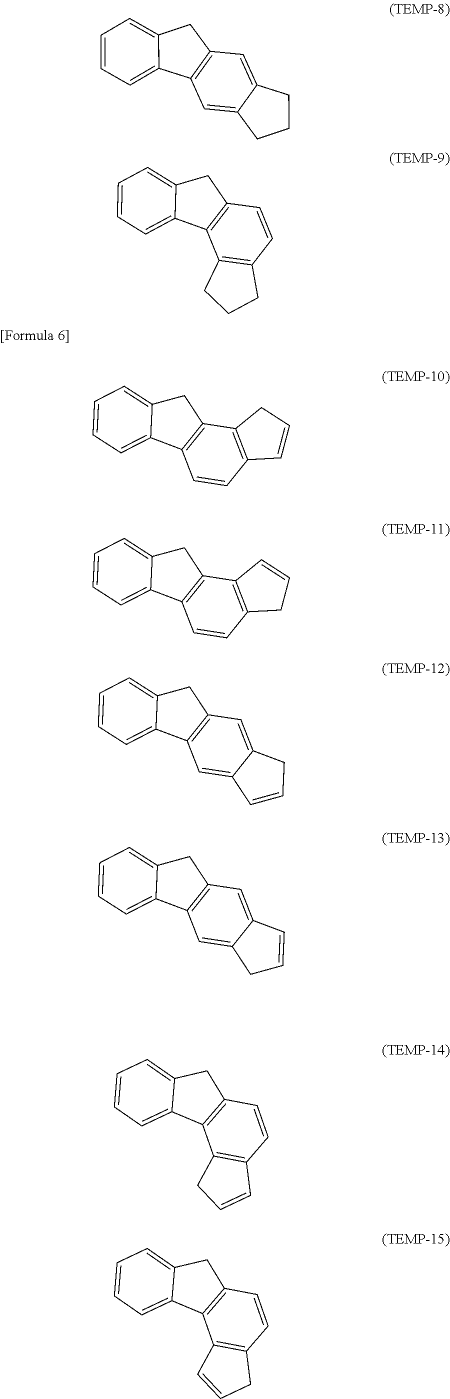

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

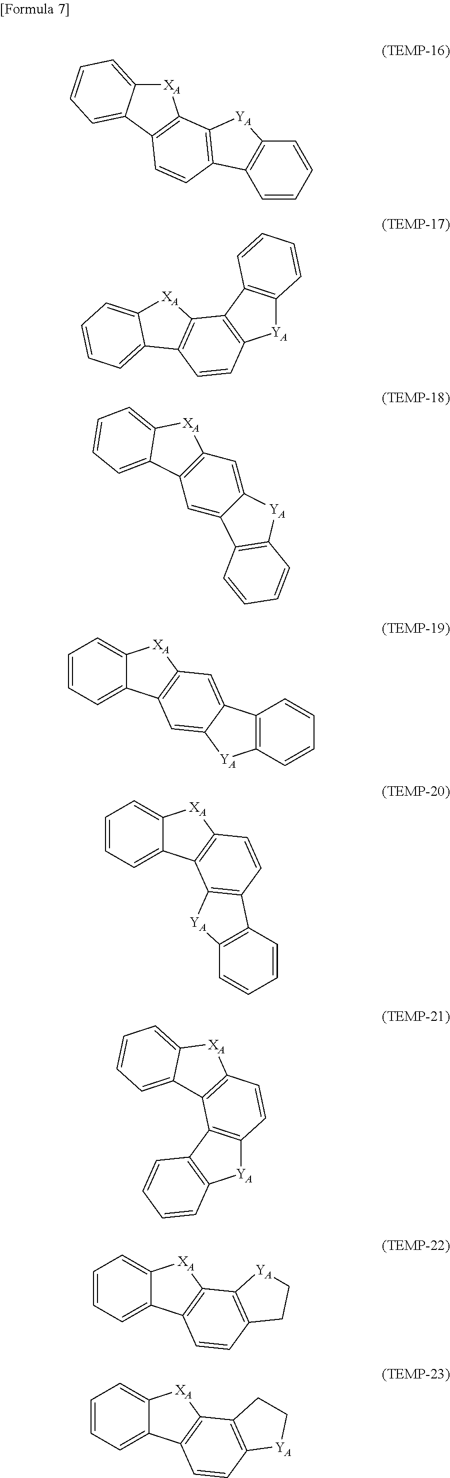

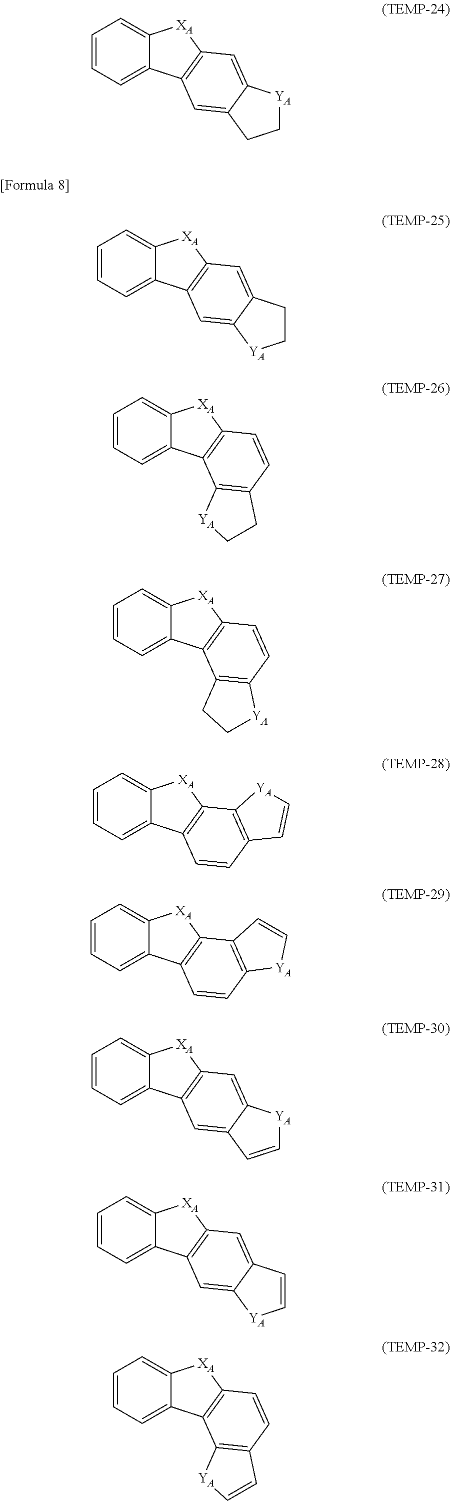

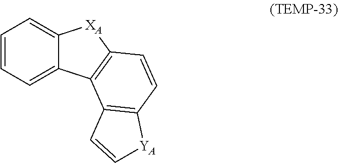

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

(9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A): Ethynyl Group

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include:
—Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);
   where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

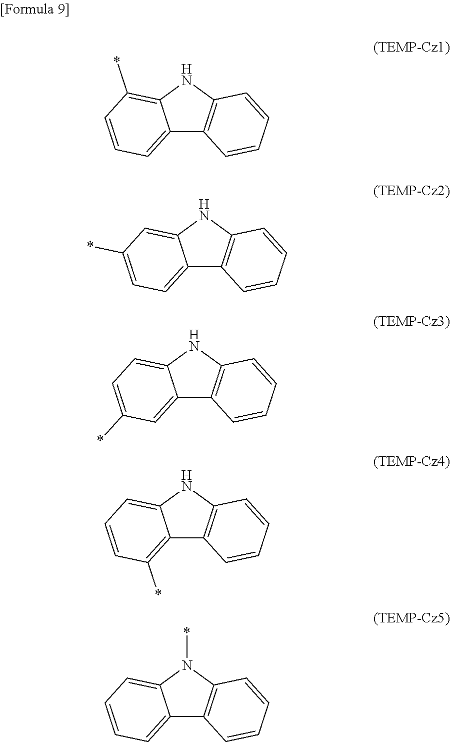 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

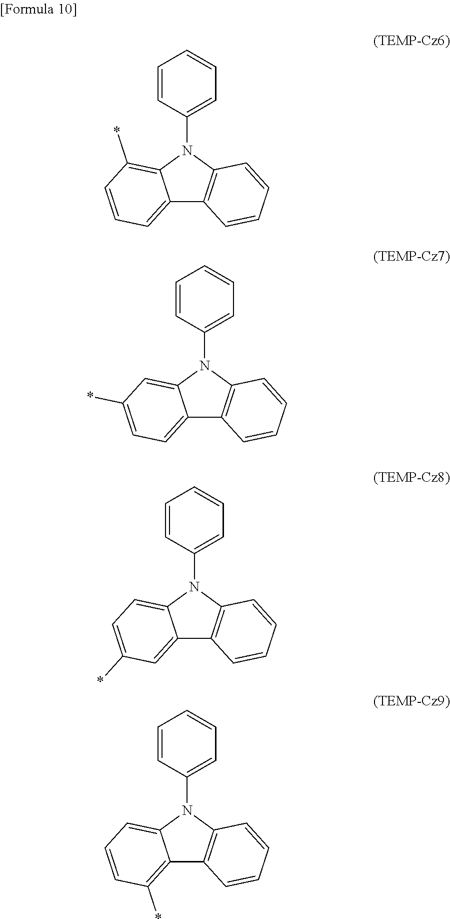

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

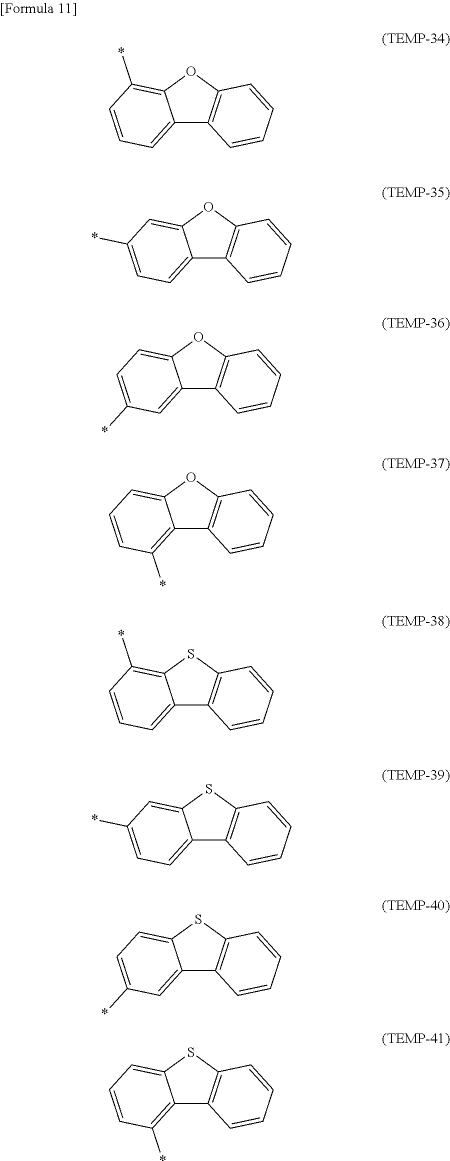

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

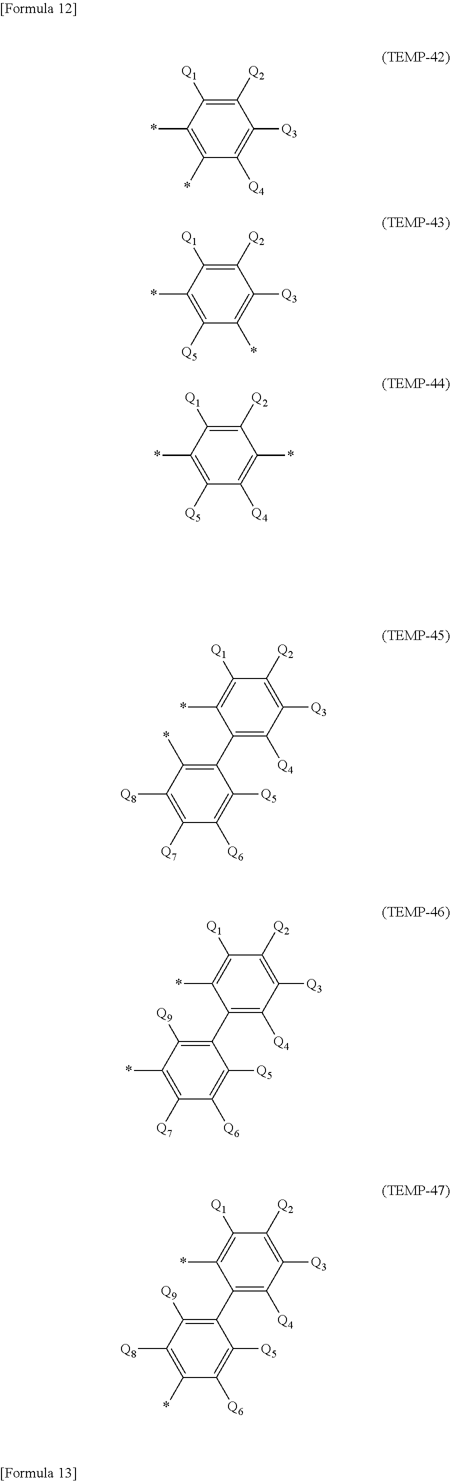

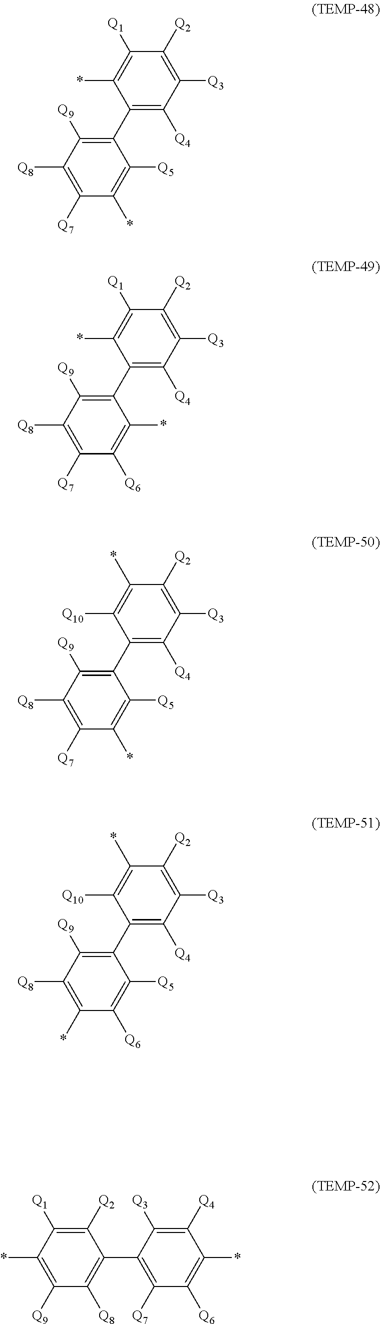

In the formulae (TEMP-42) to (TEMP-52), Q₁ to Q₁₀ are each independently a hydrogen atom or a substituent.

In the formulae (TEMP-42) to (TEMP-52), * represents a bonding position.

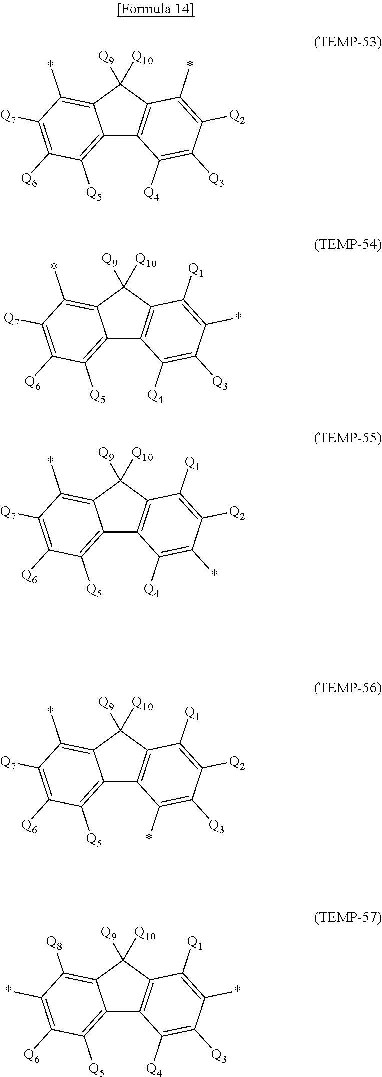

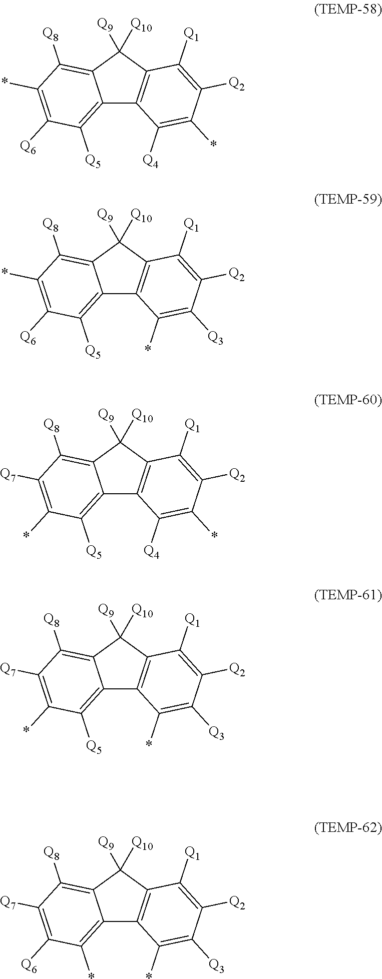

In the formulae (TEMP-53) to (TEMP-62), Q₁ to Q₁₀ are each independently a hydrogen atom or a substituent.

In the formulae, 09 and Q₁₀ may be mutually bonded through a single bond to form a ring.

In the formulae (TEMP-53) to (TEMP-62), * represents a bonding position.

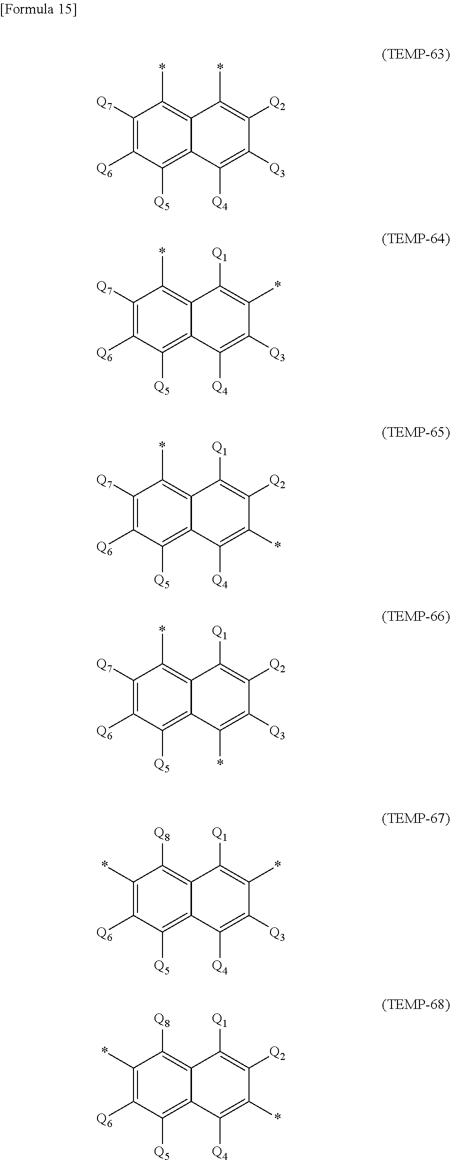

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

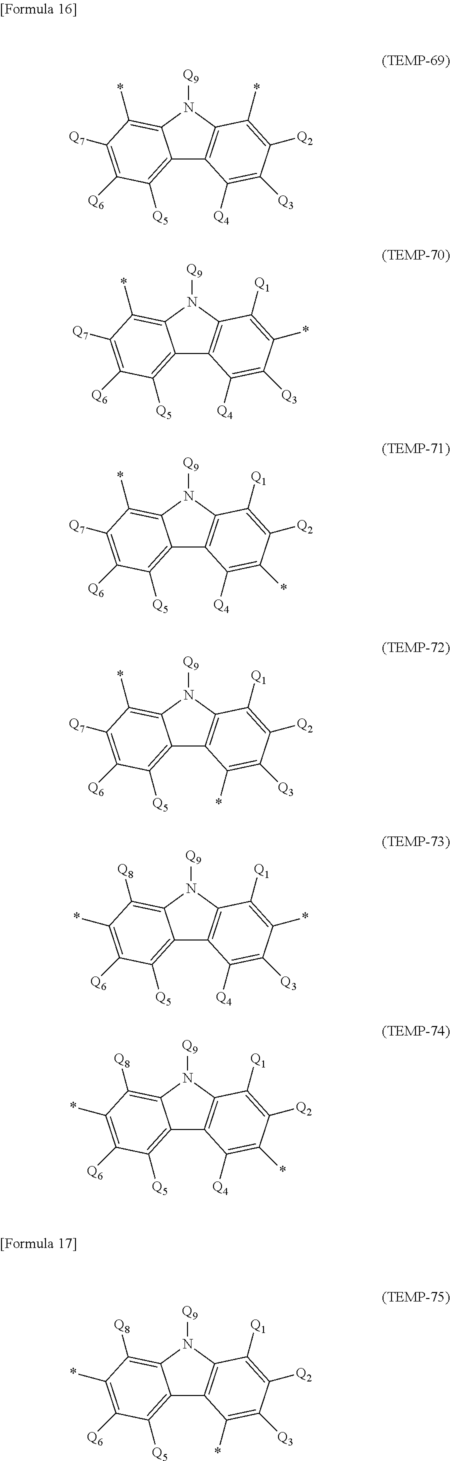

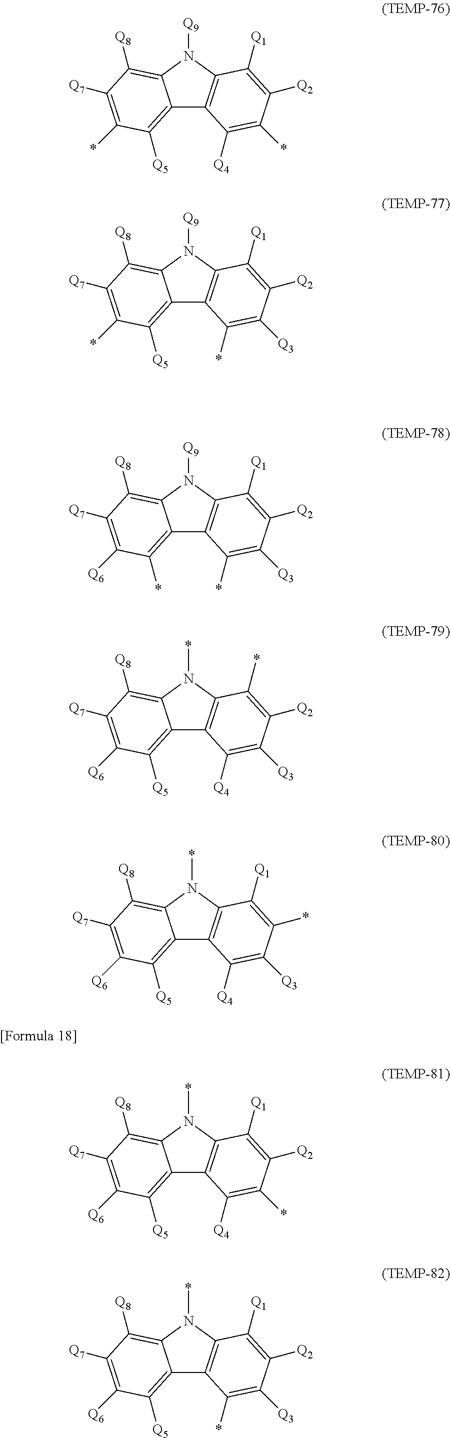

In the formulae (TEMP-69) to (TEMP-82), Q₁ to Q₉ are each independently a hydrogen atom or a substituent.

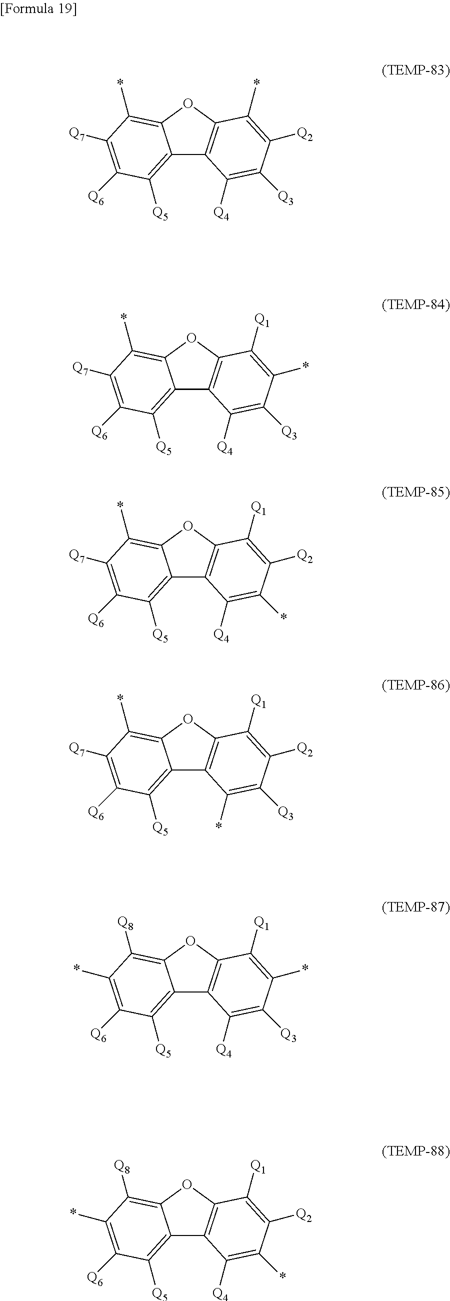

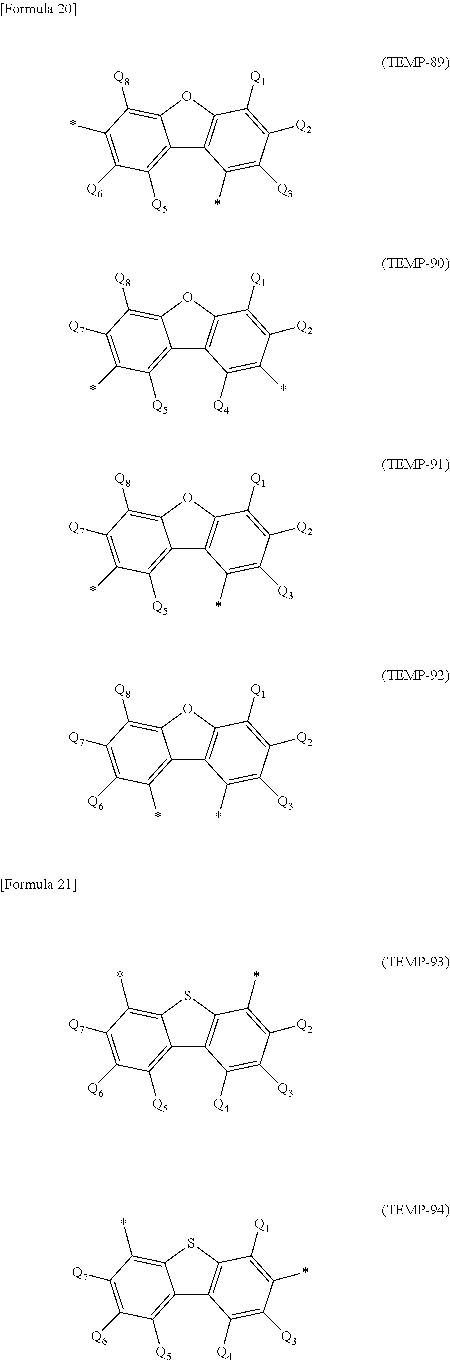

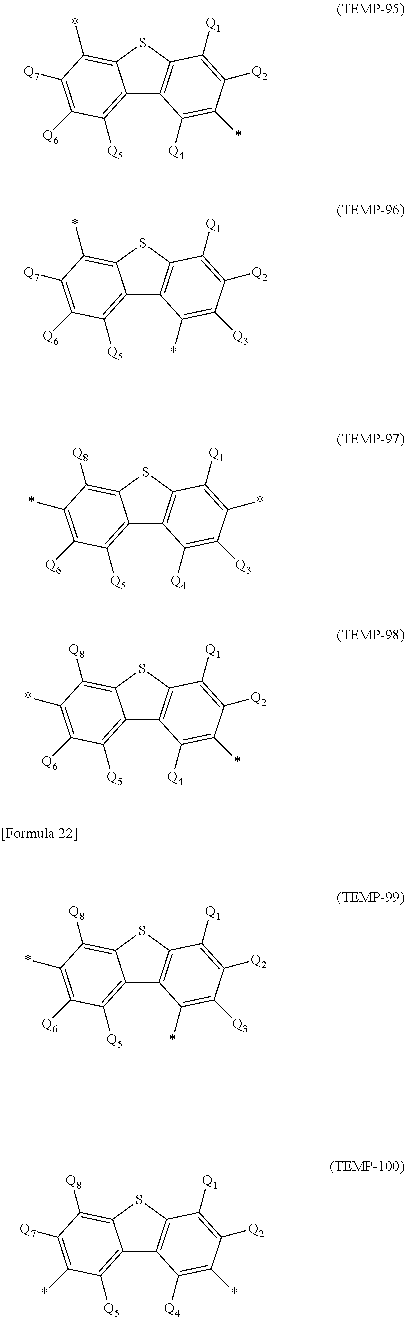

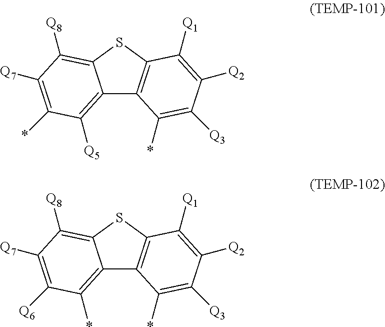

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

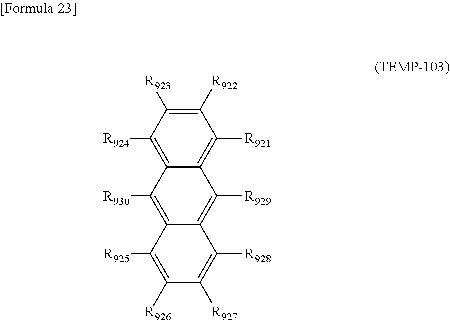

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

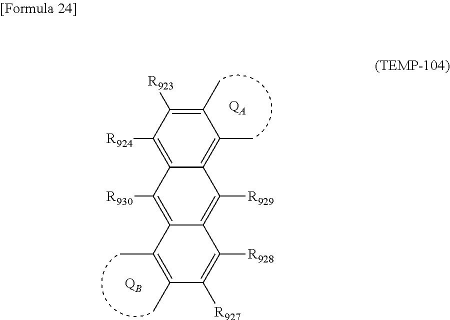

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

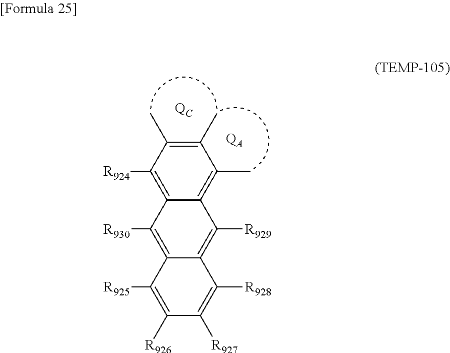

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific example of the specific example group G1 with a hydrogen atom.

Specific examples of the aromatic heterocycle include a ring formed by terminating a bond of an aromatic heterocyclic group in the specific example of the specific example group G2 with a hydrogen atom.

Specific examples of the aliphatic hydrocarbon ring include a ring formed by terminating a bond of a group in the specific example of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle

### “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle

### “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;

R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle

### “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

An organic electroluminescence device (organic EL device) according to a first exemplary embodiment includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, and the third anode side organic layer does not contain a compound contained in the second anode side organic layer. The organic EL device according to the exemplary embodiment may have a variety of arrangements that include not only the above elements but also any other element(s). For instance, exemplary arrangements of the organic EL device according to the exemplary embodiment include a first arrangement, a second arrangement, a third arrangement, a fourth arrangement, and a fifth arrangement below. It should be noted that the organic EL device according to the exemplary embodiment is not limited to these arrangements.

An organic EL device according to the first arrangement of the exemplary embodiment includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, a total of a film thickness of the second anode side organic layer and a film thickness of the third anode side organic layer is in range from 30 nm to 150 nm, and a ratio of the film thickness of the third anode side organic layer to the film thickness of the second anode side organic layer satisfies a relationship of a numerical formula (Numerical Formula A1) below.

$$0.50 < T {L}_{3} / {TL}_{2} < 4. \qquad ( Numerical Formula A1 )$$

where TL₂ is a film thickness of the second anode side organic layer, TL₃ is a film thickness of the third anode side organic layer, and a unit of the film thickness is denoted by nm.

An organic EL device according to the second arrangement of the exemplary embodiment includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, the third anode side organic layer contains a compound represented by a formula (C1) below or a compound represented by a formula (C2) below, a total of a film thickness of the second anode side organic layer and a film thickness of the third anode side organic layer is in range from 30 nm to 150 nm, and a ratio of the film thickness of the third anode side organic layer to the film thickness of the second anode side organic layer satisfies a relationship of a numerical formula (Numerical Formula A2) below.

$$0.30 < T {L}_{3} / {TL}_{2} < 4. \qquad ( Numerical Formula A2 )$$

where TL₂ is a film thickness of the second anode side organic layer, TL₃ is a film thickness of the third anode side organic layer, and a unit of the film thickness is denoted by nm.

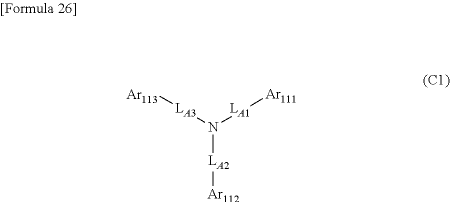

In the formula (C1):
L_{A1}, L_{A2}, and L_{A3} are each independently a single bond, a substituted or unsubstituted arylene group having 6 to 50 ring carbon atoms, or a substituted or unsubstituted divalent heterocyclic group having 5 to 50 ring atoms;
Ar₁₁₁, Ar₁₁₂, and Ar₁₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

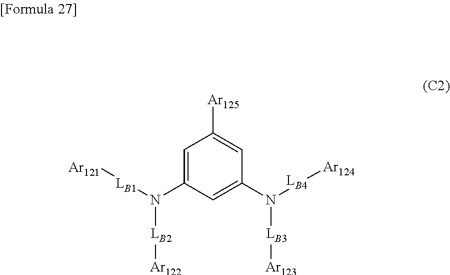

In the formula (C2):
L_{B1}, L_{B2}, L_{B3}, and L_{B4} are each independently a single bond, or a substituted or unsubstituted arylene group having 6 to 50 ring carbon atoms; and
Ar₁₂₁, Ar₁₂₂, Ar₁₂₃, Ar₁₂₄, and Ar₁₂₅ are each independently a substituted or unsubstituted aryl group having 6 to 50 ring carbon atoms, or a substituted or unsubstituted heterocyclic group having 5 to 50 ring atoms.

In the compound represented by the formula (C1) and the compound represented by the formula (C2), the substituent for the “substituted or unsubstituted” group is not a group represented by —N(R_{C6})(R_{C7}), and R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

An organic EL device according to the third arrangement of the exemplary embodiment includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, the first anode side organic layer, the second anode side organic layer, and the third anode side organic layer each contain at least one compound, the compounds respectively contained in the first, second, and third anode side organic layers being different from each other, the third anode side organic layer does not contain a compound contained in the second anode side organic layer, the third anode side organic layer contains a third hole transporting zone material, a hole mobility of the third hole transporting zone material μh(cHT3) is larger than 1.0×10⁻⁵ cm²/Vs, and an energy level of a highest occupied molecular orbital of the third hole transporting zone material HOMO(cHT3) is −5.6 eV or less.

An organic EL device according to the fourth arrangement of the exemplary embodiment includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, and a total of a film thickness of the second anode side organic layer and a film thickness of the third anode side organic layer is 100 nm or more.

An organic EL device according to the fifth arrangement of the exemplary embodiment includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, a total of a film thickness of the second anode side organic layer and a film thickness of the third anode side organic layer is 30 nm or more, a ratio of the film thickness of the third anode side organic layer to the film thickness of the second anode side organic layer satisfies a relationship of a numerical formula (Numerical Formula A4) below, the third anode side organic layer contains a third hole transporting zone material, and a singlet energy of the third hole transporting zone material is larger than 3.12 eV.

$$0.30 < T {L}_{3} / {TL}_{2} < 5. \qquad ( Numerical Formula A4 )$$

where TL₂ is a film thickness of the second anode side organic layer, TL₃ is a film thickness of the third anode side organic layer, and a unit of the film thickness is denoted by nm.

Elements that can be provided in the organic EL devices according to the respective arrangements of the exemplary embodiment are described below. The first, second, third, fourth, and fifth arrangements described above are exemplary arrangements including at least one element from among elements described below.

According to the exemplary embodiment, the organic EL device has improved device performance. In an exemplary arrangement according to the exemplary embodiment, the organic EL device has improved luminous efficiency. In an exemplary arrangement according to the exemplary embodiment, the organic EL device has a longer lifetime.

Using a layer formed from a low refractive index material as the organic layer (e.g., hole transporting layer) in the hole transporting zone reduces light emission loss in an evanescent mode. Further, as the organic layers (e.g., hole transporting layers) in the hole transporting zone, the organic layer formed from a high refractive index material may be disposed close to the anode and the organic layer formed from a low refractive index material may be disposed close to the emitting layer. In this case, light emission loss in a thin film mode is reducible. Especially for the light extraction in a bottom-emission organic electroluminescence device, not only the light emission loss in an organic thin-film layer but also the light emission loss in a substrate mode are preventable, resulting in enhanced light-extraction efficiency. In particular, the light-extraction efficiency can be effectively enhanced when the organic layer formed from the low refractive index material has a film thickness of 20 nm or more. Further, a hole supply property can be easily adjusted by combining two different kinds of materials in the organic layers in the hole transporting zone.

### Hole Transporting Zone

Herein, a zone disposed between the anode and the emitting region and formed by a plurality of organic layers is occasionally referred to as a hole transporting zone.

In an exemplary arrangement of the organic EL device of the exemplary embodiment, a ratio TL₃/TL₂ of a film thickness TL₃ of the third anode side organic layer to a film thickness TL₂ of the second anode side organic layer satisfies a predetermined relationship.

In an exemplary arrangement of the organic EL device of the exemplary embodiment, the ratio of the film thickness of the third anode side organic layer to the film thickness of the second anode side organic layer satisfies a relationship of a numerical formula (Numerical Formula A1), numerical formula (Numerical Formula A2), numerical formula (Numerical Formula A3), or numerical formula (Numerical Formula A4) below.

$$0.5 < {TL}_{3} / {TL}_{2} < 4. \qquad ( Numerical Formula A1 )$$

$$0.3 < {TL}_{3} / {TL}_{2} < 4. \qquad ( Numerical Formula A2 )$$

$$0.75 < {TL}_{3} / {TL}_{2} < 3. \qquad ( Numerical Formula A3 )$$

$$0.3 < {TL}_{3} / {TL}_{2} < 5. \qquad ( Numerical Formula A4 )$$

where TL₂ is a film thickness of the second anode side organic layer, TL₃ is a film thickness of the third anode side organic layer, and a unit of the film thickness is denoted by nm.

In an exemplary arrangement of the organic EL device of the exemplary embodiment, the ratio TL₃/TL₂ is 1 or more.

In an exemplary arrangement of the organic EL device of the exemplary embodiment, the ratio TL₃/TL₂ is 2.5 or less.

In an exemplary arrangement of the organic EL device of the exemplary embodiment, the total of the film thickness of the second anode side organic layer and the film thickness of the third anode side organic layer is 30 nm or more, 70 nm or more, or 100 nm or more.

In the organic EL device according to the exemplary embodiment, presumably, an excitation energy of the emitting layer can be inhibited from transferring to the hole transporting zone by making the film thickness of the organic layer(s) in the hole transporting zone that is/are close to the anode with respect to the emitting region large (e.g., the total of the film thickness of the second anode side organic layer and the film thickness of the third anode side organic layer being 30 nm or more) and making the ratio of the film thickness of the third anode side organic layer to the film thickness of the second anode side organic layer fall within a predefined range (e.g., in a range satisfying the numerical formula A1, A2, A3, or A4). It is considered that the luminous efficiency of the organic EL device is improved by inhibiting the transfer of the excitation energy of the emitting layer.

In an exemplary arrangement of the organic EL device of the exemplary embodiment, the total of the film thickness of the second anode side organic layer and the film thickness of the third anode side organic layer is 150 nm or less.

In an exemplary arrangement of the organic EL device of the exemplary embodiment, the total of the film thickness of the first anode side organic layer, the film thickness of the second anode side organic layer, and the film thickness of the third anode side organic layer is 150 nm or less.

In an exemplary arrangement of the organic EL device of the exemplary embodiment, the film thickness of the third anode side organic layer is 15 nm or more or 20 nm or more.

It is considered that the third anode side organic layer having a film thickness of 15 nm or more readily inhibits the transfer of the excitation energy of the emitting layer.

In an exemplary arrangement of the organic EL device of the exemplary embodiment, the film thickness of the third anode side organic layer is 80 nm or less, 75 nm or less, or 60 nm or less.

In terms of the improvement in light-extraction efficiency, the film thickness of the third anode side organic layer is preferably in a range from 15 nm to 75 nm, more preferably in a range from 20 nm to 60 nm.

In an exemplary arrangement of the organic EL device of the exemplary embodiment, a difference NM₂−NM₃ between a refractive index NM₂ of a constituent material contained in the second anode side organic layer and a refractive index NM₃ of a constituent material contained in the third anode side organic layer satisfies a relationship of a numerical formula (Numerical Formula N1) below. When the second anode side organic layer contains a single type of compound, the refractive index NM₂ of the constituent material contained in the second anode side organic layer corresponds to a refractive index of the single type of compound. When the second anode side organic layer contains a plurality of types of compounds, the refractive index NM₂ of the constituent material contained in the second anode side organic layer corresponds to a refractive index of a mixture containing the plurality types of compounds. The refractive index NM₃ of the constituent material contained in the third anode side organic layer is also defined similarly to the refractive index NM₂ of the constituent material contained in the second anode side organic layer. The refractive index can be measured by a measurement method described in Examples below. Herein, a value of the refractive index at 2.7 eV in a substrate parallel direction (Ordinary direction), from among the values measured by the variable-angle spectroscopic ellipsometry measurement, is defined as a refractive index of a measurement target material. The refractive index at 2.7 eV corresponds to a refractive index at 460 nm.

$${NM}_{2} - {NM}_{3} \geq 0.05 \qquad ( Numerical Formula N1 )$$

Satisfying the relationship of the above numerical formula (Numerical Formula N1) improves the light-extraction efficiency of the organic EL device.

In an exemplary arrangement of the organic EL device of the exemplary embodiment, the difference NM₂−NM₃ between the refractive index NM₂ of the constituent material contained in the second anode side organic layer and the refractive index NM₃ of the constituent material contained in the third anode side organic layer satisfies a relationship of a numerical formula (Numerical Formula N2) or a numerical formula (Numerical Formula N3) below.

$${NM}_{2} - {NM}_{3} \geq 0.1 \qquad ( Numerical Formula N2 )$$

$${NM}_{2} - {NM}_{3} \geq 0.075 \qquad ( Numerical Formula N3 )$$

Herein, the refractive index at 2.7 eV (460 nm) in the substrate parallel direction (Ordinary direction) may be referred to as n_{ORD}, and the refractive index at 2.7 eV (460 nm) in a substrate perpendicular direction (Extra-Ordinary direction) may be referred to as n_{EXT}.

In an exemplary arrangement of the organic EL device of the exemplary embodiment, a difference n_{ORD}−n_{EXT} between the refractive index n_{ORD} and the refractive index n_{EXT} at 460 nm of the constituent material contained in the second anode side organic layer is preferably 0.1 or more.

In an exemplary arrangement of the organic EL device of the exemplary embodiment, the refractive index of the compound contained in the second anode side organic layer is 1.94 or more.

In an exemplary arrangement of the organic EL device of the exemplary embodiment, the refractive index of a compound contained in the third anode side organic layer is 1.89 or less.

In an exemplary arrangement of the organic EL device of the exemplary embodiment, a distance from an interface close to the anode of the third anode side organic layer to an interface close to the anode of an emitting layer disposed closest to the anode in the emitting region is 20 nm or more.

Light-extraction efficiency of the organic EL device is easily improved by making the distance from the interface close to the anode of the third anode side organic layer to the interface close to the anode of the emitting layer disposed closest to the anode in the emitting region 20 nm or more.

For instance, when the side of the third anode side organic layer close to the anode is in direct contact with the second anode side organic layer and the side of the third anode side organic layer close to the cathode is in direct contact with the emitting layer disposed closest to the anode in the emitting region, the distance from the interface close to the anode of the third anode side organic layer to the interface close to the anode of the emitting layer disposed closest to the anode in the emitting region corresponds to a film thickness of the third anode side organic layer.

For instance, when the side of the third anode side organic layer close to the anode is in direct contact with the second anode side organic layer, the side of the third anode side organic layer close to the cathode is in direct contact with a fourth anode side organic layer which will be described later, and the side of the fourth anode side organic layer close to the cathode is in direct contact with the emitting layer disposed closest to the anode in the emitting region, the distance from the interface close to the anode of the third anode side organic layer to the interface close to the anode of the emitting layer disposed closest to the anode in the emitting region corresponds to a total of the film thickness of the third anode side organic layer and the film thickness of the fourth anode side organic layer.

In an exemplary arrangement of the organic EL device of the exemplary embodiment, a distance from the interface close to the anode of the third anode side organic layer to the interface close to the anode of the emitting layer disposed closest to the anode in the emitting region is 30 nm or more.

In an exemplary arrangement of the organic EL device of the exemplary embodiment, the third anode side organic layer contains a compound represented by the formula (C1) or a compound represented by the formula (C2).

In an exemplary arrangement of the organic EL device of the exemplary embodiment, the first anode side organic layer, the second anode side organic layer, and the third anode side organic layer each contain at least one compound, the compounds respectively contained in the first, second, and third anode side organic layers being different from each other.

In an exemplary arrangement of the organic EL device of the exemplary embodiment, although each of the first anode side organic layer and the second anode side organic layer may contain a compound represented by the formula (C1) or a compound represented by the formula (C2), the compound(s) contained in the first anode side organic layer and the second anode side organic layer is/are different from a compound contained in the third anode side organic layer in a molecular structure.

In an exemplary arrangement of the organic EL device of the exemplary embodiment, all the compound(s) contained in the second anode side organic layer is/are different from all the compound(s) contained in the third anode side organic layer.

An arrangement satisfying the above condition is exemplified by a case where the second anode side organic layer contains a compound AA and the third anode side organic layer contains a compound BB.

Further, for instance, the above condition is satisfied also when the second anode side organic layer contains two types of compounds (compound AA and compound AB) and the third anode side organic layer contains a compound (compound BB), because both the compounds AA and AB are different from the compound BB. The compounds AA, AB, and BB are compounds different from each other.

On the other hand, for instance, the above condition is not satisfied when the second anode side organic layer contains two types of compounds (compound AA and compound AB) and the third anode side organic layer contains a compound (compound AB), because the second anode side organic layer and the third anode side organic layer contain the same compound (compound AB).

In an exemplary arrangement of the organic EL device of the exemplary embodiment, the third anode side organic layer contains the third hole transporting zone material. The compound(s) contained in the third anode side organic layer is/are occasionally referred to as the third hole transporting zone material.

In an exemplary arrangement of the organic EL device of the exemplary embodiment, the hole mobility of the third hole transporting zone material μh(cHT3) is larger than 1.0×10⁻⁵ cm²/Vs.

In an exemplary arrangement of the organic EL device of the exemplary embodiment, the energy level of the highest occupied molecular orbital of the third hole transporting zone material HOMO(cHT3) is −5.6 eV or less.

In an exemplary arrangement of the organic EL device of the exemplary embodiment, the hole mobility of the third hole transporting zone material μh(cHT3) is larger than 1.0×10⁻⁵ cm²/Vs, and the energy level of the highest occupied molecular orbital of the third hole transporting zone material HOMO(cHT3) is −5.6 eV or less. When the hole mobility μh(cHT3) and the energy level HOMO(cHT3) of the third hole transporting zone material fall within the above ranges, the third anode side organic layer has a high hole mobility and a high hole injectability to the emitting layer in the emitting region.

In an exemplary arrangement of the organic EL device of the exemplary embodiment, the singlet energy of the third hole transporting zone material is larger than 3.12 eV.

In an exemplary arrangement of the organic EL device of the exemplary embodiment, the singlet energy of the third hole transporting zone material is 3.15 eV or more.

In an exemplary arrangement of the organic EL device of the exemplary embodiment, the singlet energy of the third hole transporting zone material is 3.40 eV or less or 3.30 eV or less.

In an exemplary arrangement of the organic EL device of the exemplary embodiment, the third hole transporting zone material is a compound represented by the formula (C1) or a compound represented by the formula (C2).

The compound represented by the formula (C1) is preferably a compound represented by a formula (C11) below.

In an exemplary arrangement of the organic EL device of the exemplary embodiment, the third hole transporting zone material is a compound represented by the formula (C11).

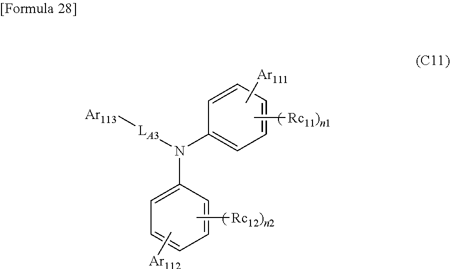

In the formula (C11):
Ar₁₁₁, Ar₁₁₂, Ar₁₁₃, and L_{A3} respectively represent the same as Ar₁₁₁, Ar₁₁₂, Ar₁₁₃, and L_{A3} in the formula (C1);
n1 and n2 are 4;
a plurality of R_{C11} are mutually the same or different;
at least one combination of adjacent two or more of a plurality of R_{C11} are mutually bonded to form a substituted or unsubstituted monocyclic ring, mutually bonded to form a substituted or unsubstituted fused ring, or not mutually bonded;
a plurality of R_{C12} are mutually the same or different;
at least one combination of adjacent two or more of a plurality of R_{C12} are mutually bonded to form a substituted or unsubstituted monocyclic ring, mutually bonded to form a substituted or unsubstituted fused ring, or not mutually bonded; and
R_{C11} and R_{C12} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted cycloalkyl group having 3 to 50 ring carbon atoms, —Si(R₉₀₁)(R₉₀₂)(R₉₀₃), —O—(R₉₀₄), a substituted or unsubstituted aryl group having 6 to 50 ring carbon atoms, or a substituted or unsubstituted heterocyclic group having 5 to 50 ring atoms.

In the compound represented by the formula (C1) and the compound represented by the formula (C11), at least one of Ar₁₁₁, Ar₁₁₂, or Ar₁₁₃ is preferably a group selected from the group consisting of groups represented by formulae (21a), (21b), (21c), (21d) and (21e) below.

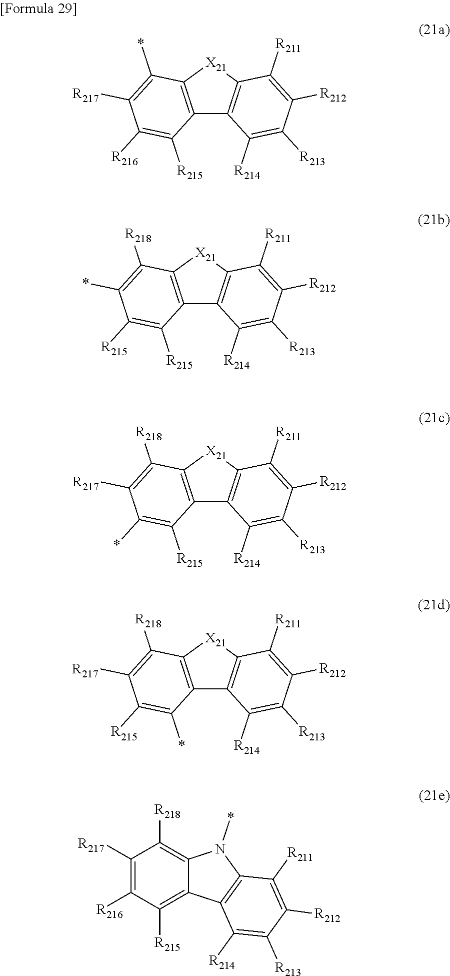

In the formulae (21a), (21b), (21c), (21 d), and (21e):
X₂₁ is NR₂₁, CR₂₂R₂₃, an oxygen atom, or a sulfur atom;
when a plurality of X₂₁ are present, the plurality of X₂₁ are mutually the same or different;
when X₂₁ is CR₂₂R₂₃, a combination of R₂₂ and R₂₃ are mutually bonded to form a substituted or unsubstituted monocyclic ring, mutually bonded to form a substituted or unsubstituted fused ring, or not mutually bonded;
R₂₁, and R₂₂ and R₂₃ forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having to 50 ring atoms;
at least one combination of adjacent two or more of R₂₁₁ to R₂₁₈ are mutually bonded to form a substituted or unsubstituted monocyclic ring, mutually bonded to form a substituted or unsubstituted fused ring, or not mutually bonded;
R₂₁₁ to R₂₁₈ forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms; and
* in the formulae (21a), (21b), (21c), (21d), and (21e) each independently represent a bonding position to L_{A}1, L_{A2}, and L_{A3}.
Ar₁₁₁, Ar₁₁₂, and Ar₁₁₃ not being the group selected from the group consisting of groups represented by the formulae (21a), (21b), (21c), (21d) and (21e) are preferably each independently a substituted or unsubstituted aryl group having 6 to 30 ring carbon atoms, more preferably a substituted or unsubstituted phenyl group or a substituted or unsubstituted biphenyl group.

In the compound represented by the formula (C1), it is also preferable that two of Ar₁₁₁, Ar₁₁₂, and Ar₁₁₃ are each a group selected from the group consisting of groups represented by the formulae (21a), (21b), (21c), (21d), and (21e), and a remaining one of Ar₁₁₁, Ar₁₁₂, and Ar₁₁₃ is a substituted or unsubstituted aryl group having 6 to 30 ring carbon atoms.

In the compound represented by the formula (C1), it is also preferable that one of Ar₁₁₁, Ar₁₁₂, and Ar₁₁₃ is a group selected from the group consisting of groups represented by the formulae (21a), (21b), (21c), (21d), and (21e), and remaining two of Ar₁₁₁, Ar₁₁₂, and Ar₁₁₃ are each a substituted or unsubstituted aryl group having 6 to 30 ring carbon atoms.

In an exemplary arrangement of the organic EL device of the exemplary embodiment, the second anode side organic layer contains a second hole transporting zone material. The compound(s) contained in the second anode side organic layer is/are occasionally referred to as the second hole transporting zone material.

In an exemplary arrangement of the organic EL device of the exemplary embodiment, the second hole transporting zone material and the third hole transporting zone material are different compounds.

In an exemplary arrangement of the organic EL device of the exemplary embodiment, a hole mobility of the second hole transporting zone material μh(cHT2) is larger than 1.0×10⁻⁴ cm²/Vs.

In an exemplary arrangement of the organic EL device of the exemplary embodiment, the hole mobility of the second hole transporting zone material μh(cHT2) is larger than the hole mobility of the third hole transporting zone material μh(cHT3).

In an exemplary arrangement of the organic EL device of the exemplary embodiment, an energy level of the highest occupied molecular orbital of the second hole transporting zone material HOMO(cHT2) and the energy level of the highest occupied molecular orbital of the third hole transporting zone material HOMO(cHT3) satisfy a relationship of a numerical formula (Numerical Formula B1) below.

$$HOMO ( cHT 2 ) < HOMO ( cHT 3 ) \qquad ( Numerical Formula B1 )$$

In an exemplary arrangement of the organic EL device of the exemplary embodiment, the hole mobility of the second hole transporting zone material μh(cHT2) is larger than 1.0×10⁻⁴ cm²/Vs, the hole mobility of the third hole transporting zone material μh(cHT3) is larger than 1.0×10⁻⁵ cm²/Vs, and the energy level of the highest occupied molecular orbital of the second hole transporting zone material HOMO(cHT2) and the energy level of the highest occupied molecular orbital of the third hole transporting zone material HOMO(cHT3) satisfy the relationship of the numerical formula (Numerical Formula B1).

In an exemplary arrangement of the organic EL device of the exemplary embodiment, the second hole transporting zone material is a compound represented by the formula (C1) or a compound represented by the formula (C2).

In an exemplary arrangement of the organic EL device of the exemplary embodiment, although both the second anode side organic layer and the third anode side organic layer may contain a compound represented by the formula (C1), the compound contained in the second anode side organic layer and the compound contained in the third anode side organic layer are mutually different in a molecular structure.

In an exemplary arrangement of the organic EL device of the exemplary embodiment, although both the second anode side organic layer and the third anode side organic layer may contain a compound represented by the formula (C2), the compound contained in the second anode side organic layer and the compound contained in the third anode side organic layer are mutually different in a molecular structure.

In an exemplary arrangement of the organic EL device of the exemplary embodiment, the third anode side organic layer contains at least one compound selected from the group consisting of a compound represented by a formula (cHT3-1), a compound represented by a formula (cHT3-2), a compound represented by a formula (cHT3-3), and a compound represented by a formula (cHT3-4) below.

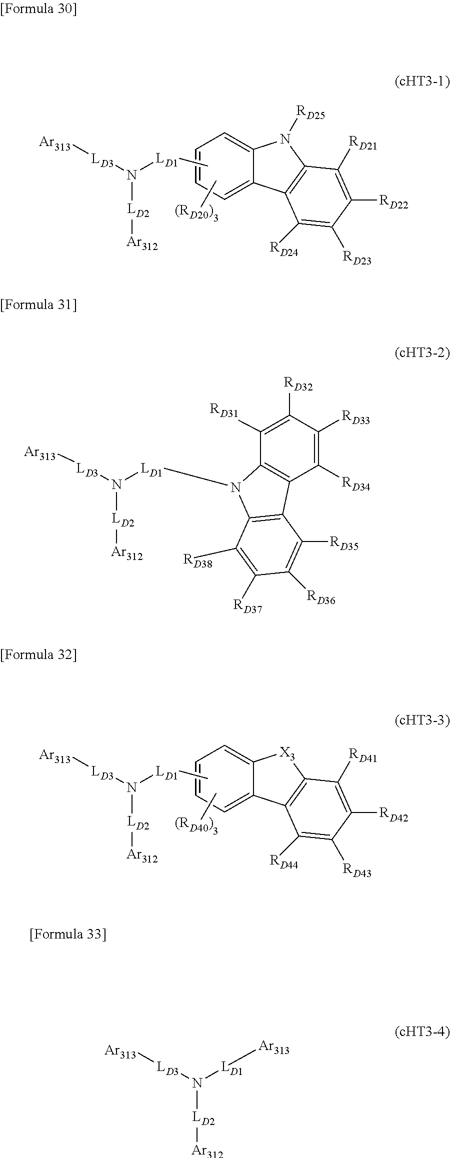

In the formulae (cHT3-1), (cHT3-2), (cHT3-3), and (cHT3-4):
Ar₃₁₁ is a group represented by one of formulae (1-a), (1-b), (1-c), and (1-d) below;
Ar₃₁₂ and Ar₃₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{D1}, L_{D2}, and L_{D3} are each independently a single bond, a substituted or unsubstituted arylene group having 6 to 50 ring carbon atoms, or a substituted or unsubstituted divalent heterocyclic group having 5 to 50 ring atoms;
at least one combination of adjacent two or more of R_{D20} to R_{D24} are mutually bonded to form a substituted or unsubstituted monocyclic ring, mutually bonded to form a substituted or unsubstituted fused ring, or not mutually bonded;
at least one combination of adjacent two or more of R_{D31} to R_{D38} are mutually bonded to form a substituted or unsubstituted monocyclic ring, mutually bonded to form a substituted or unsubstituted fused ring, or not mutually bonded;
at least one combination of adjacent two or more of R_{D40} to R_{D44} are mutually bonded to form a substituted or unsubstituted monocyclic ring, mutually bonded to form a substituted or unsubstituted fused ring, or not mutually bonded;
X₃ is an oxygen atom, a sulfur atom, or C(R_{D45})(R_{D46});
a combination of R_{D45} and R_{D46} are mutually bonded to form a substituted or unsubstituted monocyclic ring, mutually bonded to form a substituted or unsubstituted fused ring, or not mutually bonded;
R_{D25}, and R_{D20} to R_{D24}, R_{D31} to R_{D38}, R_{D40} to R_{D44}, R_{D45} and R_{D46} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a plurality of R_{D20} are mutually the same or different;
a plurality of R_{D40} are mutually the same or different; and
R₉₀₁ to R₉₀₄ in the compounds represented by the formulae (cHT3-1), (cHT3-2), (cHT3-3), and (cHT3-4) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

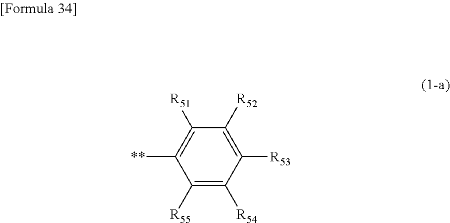

In the formula (1-a):
none of a combination(s) of adjacent two or more of R₅₁ to R₅₅ are bonded to each other;
R₅₁ to R₅₅ are each independently a hydrogen atom, or a substituted or unsubstituted alkyl group having 1 to 6 carbon atoms; and
** represents a bonding position to L_{D1}.

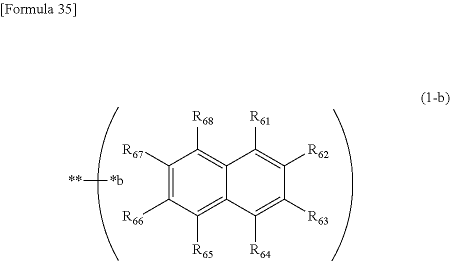

In the formula (1-b):
one of R₆₁ to R₆₈ is a single bond with *b;
none of a combination(s) of adjacent two or more of R₆₁ to R₆₈ not being the single bond with *b are bonded to each other;
R₆₁ to R₆₈ not being the single bond with *b are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}.

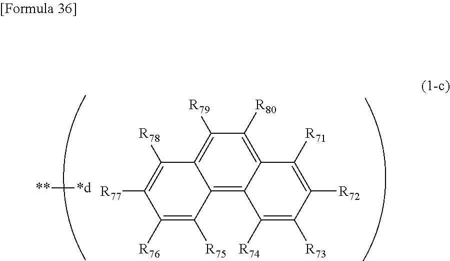

In the formula (1-c):
one of R₇₁ to R₈₀ is a single bond with *d;
none of a combination(s) of adjacent two or more of R₇₁ to R₈₀ not being the single bond with *d are bonded to each other;
R₇₁ to R₈₀ not being the single bond with *d are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}.

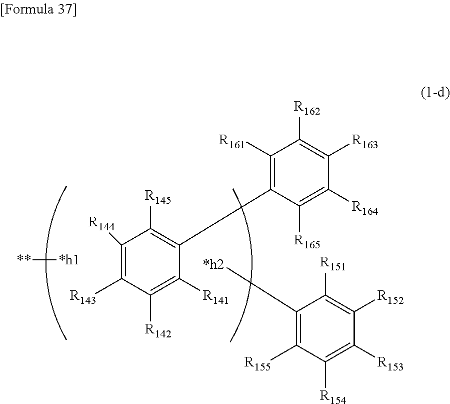

In the formula (1-d):
one of R₁₄₁ to R₁₄₅ is a single bond with *h1 and another one of R₁₄₁ to R₁₄₅ is a single bond with *h2;
none of a combination(s) of adjacent two or more of R₁₄₁ to R₁₄₅ not being the single bond with *h1 and not being the single bond with *h2 are bonded to each other;
at least one combination of adjacent two or more of R₁₅₁ to R₁₅₅ are mutually bonded to form a substituted or unsubstituted monocyclic ring, mutually bonded to form a substituted or unsubstituted fused ring, or not mutually bonded;
at least one combination of adjacent two or more of R₁₆₁ to R₁₆₅ are mutually bonded to form a substituted or unsubstituted monocyclic ring, mutually bonded to form a substituted or unsubstituted fused ring, or not mutually bonded;
R₁₄₁ to R₁₄₅ not being the single bond with *h1 and not being the single bond with *h2 as well as R₁₅₁ to R₁₅₅ and R₁₆₁ to R₁₆₅ forming neither the substituted or unsubstituted monocyclic ring nor the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}.

The compound represented by the formula (cHT3-1) may be a compound represented by a formula (cHT3-11) below.

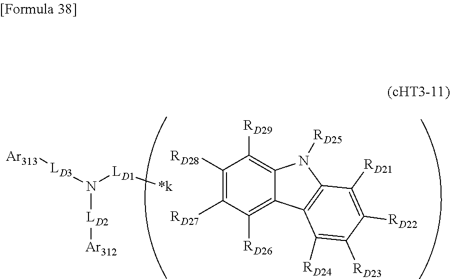

In the formula (cHT3-11):
Ar₃₁₂, Ar₃₁₃, L_{D1}, L_{D2}, L_{D3} and R_{D25} respectively represent the same as Ar₃₁₂, Ar₃₁₃, L_{D1}, L_{D2}, L_{D3} and R_{D25} in the formula (cHT3-1);
one of R_{D26} to R_{D29} is a single bond with L_{D1}, and *k represents a bonding position;
at least one combination of adjacent two or more of R_{D21} to R_{D24} and R_{D26} to R_{D29} not being the single bond with L_{D1} are mutually bonded to form a substituted or unsubstituted monocyclic ring, mutually bonded to form a substituted or unsubstituted fused ring, or not mutually bonded; and
R_{D21} to R_{D24} and R_{D26} to R_{D29} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having to 50 ring atoms.

In an exemplary arrangement of the organic EL device of the exemplary embodiment, R_{D26}, R_{D28}, or R_{D29} in the formula (cHT3-11) is a single bond with L_{D1}.

When R_{D26} in the formula (cHT3-11) is a single bond with L_{D1}, the compound represented by the formula (cHT3-11) is represented by a formula (cHT3-12) below.

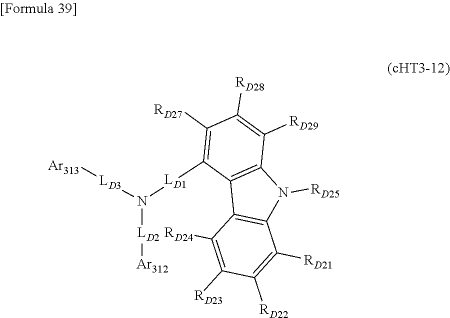

When R_{D28} in the formula (cHT3-11) is a single bond with L_{D1}, the compound represented by the formula (cHT3-11) is represented by a formula (cHT3-13) below.

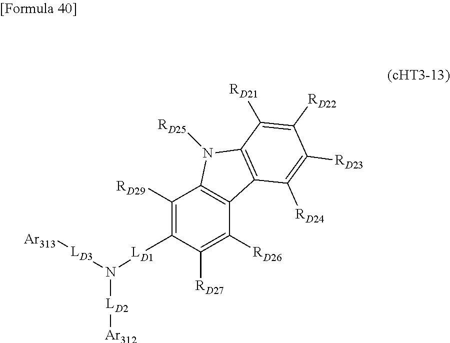

When R_{D29} in the formula (cHT3-11) is a single bond with L_{D1}, the compound represented by the formula (cHT3-11) is represented by a formula (cHT3-14) below.

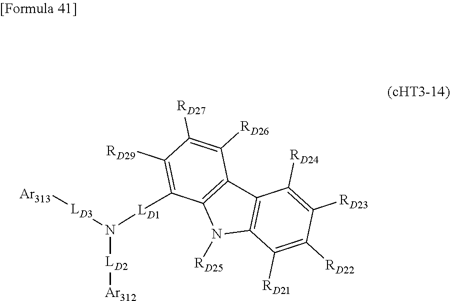

In the formulae (cHT3-12), (cHT3-13), and (cHT3-14), Ar₃₁₂, Ar₃₁₃, L_{D1}, L_{D2}, L_{D3} and R_{D21} to R_{D29} respectively represent the same as Ar₃₁₂, Ar₃₁₃, L_{D1}, L_{D2}, L_{D3} and R_{D21} to R_{D29} in the formula (cHT3-11).

The compound represented by the formula (cHT3-3) may be a compound represented by a formula (cHT3-31) below.

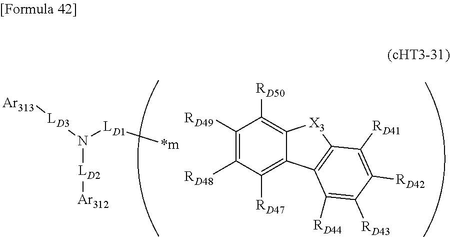

In the formula (cHT3-31):
Ar₃₁₂, Ar₃₁₃, L_{D1}, L_{D2}, L_{D3} and X₃ respectively represent the same as Ar₃₁₂, Ar₃₁₃, L_{D1}, L_{D2}, L_{D3} and X₃ in the formula (cHT3-3);
one of R_{D47} to R_{D50} is a single bond with L_{D1}, and *m represents a bonding position;
at least one combination of adjacent two or more of R_{D41} to R_{D44} and R_{D47} to R_{D50} not being the single bond with L_{D1} are mutually bonded to form a substituted or unsubstituted monocyclic ring, mutually bonded to form a substituted or unsubstituted fused ring, or not mutually bonded; and
R_{D41} to R_{D50} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, L_{D1} is a single bond or a substituted or unsubstituted phenylene group.

In an exemplary arrangement of the organic EL device of the exemplary embodiment, in the compounds represented by the formulae (cHT3-1) to (cHT3-4), (cHT3-11) to (cHT3-14), and (cHT3-31), the substituent for the “substituted or unsubstituted” group is not a group represented by —N(R_{C6})(R_{C7}).

In the exemplary embodiment, R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms. A plurality of R_{C6} are mutually the same or different, and a plurality of R_{C7} are mutually the same or different.

When the substituent for the “substituted or unsubstituted” group is not a group represented by —N(R_{C6})(R_{C7}), the compounds represented by the formulae (cHT3-1) to (cHT3-4), (cHT3-11) to (cHT3-14), and (cHT3-31) are each a monoamine compound.

In an exemplary arrangement of the organic EL device of the exemplary embodiment, the compound contained in the third anode side organic layer is a diamine compound having two substituted or unsubstituted amino groups in a molecule.

In an exemplary arrangement of the organic EL device of the exemplary embodiment, the compound contained in the third anode side organic layer is a triamine compound having three substituted or unsubstituted amino groups in a molecule.

In an exemplary arrangement of the organic EL device of the exemplary embodiment, the compound contained in the third anode side organic layer is a tetraamine compound having four substituted or unsubstituted amino groups in a molecule.

When the compounds represented by the formulae (cHT3-1) to (cHT3-4), (cHT3-11) to (cHT3-14), and (cHT3-31) are each a diamine compound, the compounds represented by the formulae (cHT3-1) to (cHT3-4), (cHT3-11) to (cHT3-14), and (cHT3-31) each have one group represented by —N(R_{C6})(R_{C7}) as the substituent for the “substituted or unsubstituted” group.

When the compounds represented by the formulae (cHT3-1) to (cHT3-4), (cHT3-11) to (cHT3-14), and (cHT3-31) are each a triamine compound, the compounds represented by the formulae (cHT3-1) to (cHT3-4), (cHT3-11) to (cHT3-14), and (cHT3-31) each have two groups represented by —N(R_{C6})(R_{C7}) as the substituents for the “substituted or unsubstituted” group.

When the compounds represented by the formulae (cHT3-1) to (cHT3-4), (cHT3-11) to (cHT3-14), and (cHT3-31) are each a tetraamine compound, the compounds represented by the formulae (cHT3-1) to (cHT3-4), (cHT3-11) to (cHT3-14), and (cHT3-31) each have three groups represented by —N(R_{C6})(R_{C7}) as the substituents for the “substituted or unsubstituted” group.

In an exemplary arrangement of the organic EL device of the exemplary embodiment, the third hole transporting zone material is at least one compound selected from the group consisting of compounds represented by the formulae (cHT3-1) to (cHT3-4), (cHT3-11) to (cHT3-14), and (cHT3-31).

In an exemplary arrangement of the organic EL device of the exemplary embodiment, the third hole transporting zone material is a monoamine compound, a diamine compound, a triamine compound, or a tetraamine compound.

In an exemplary arrangement of the organic EL device of the exemplary embodiment, the second anode side organic layer contains at least one compound selected from the group consisting of a compound represented by a formula (cHT2-1), a compound represented by a formula (cHT2-2), and a compound represented by a formula (cHT2-3) below.

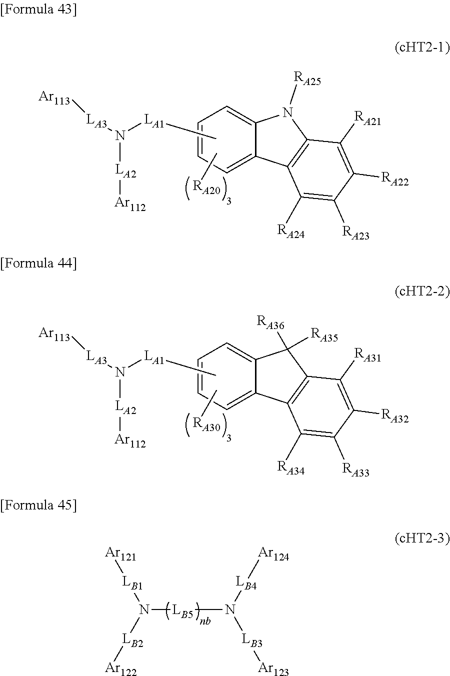

In the formulae (cHT2-1), (cHT2-2), and (cHT2-3):
Ar₁₁₂, Ar₁₁₃, Ar₁₂₁, Ar₁₂₂, Ar₁₂₃, and Ar₁₂₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different;
L_{A1}, L_{A2}, L_{A3}, L_{B1}, L_{B2}, L_{B3}, and L_{B4} are each independently a single bond, a substituted or unsubstituted arylene group having 6 to 50 ring carbon atoms, or a substituted or unsubstituted divalent heterocyclic group having 5 to 50 ring atoms;
nb is 1, 2, 3 or 4;
when nb is 1, L_{B5} is a substituted or unsubstituted arylene group having 6 to 50 ring carbon atoms, or a substituted or unsubstituted divalent heterocyclic group having 5 to 50 ring atoms;
when nb is 2, 3, or 4, a plurality of L_{B5} are mutually the same or different;
when nb is 2, 3, or 4, a plurality of L_{B5} are mutually bonded to form a substituted or unsubstituted monocyclic ring, mutually bonded to form a substituted or unsubstituted fused ring, or not mutually bonded;
L_{B5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
a combination of R_{A35} and R_{A36} are mutually bonded to form a substituted or unsubstituted monocyclic ring, mutually bonded to form a substituted or unsubstituted fused ring, or not mutually bonded;
R_{A25}, and R_{A35} and R_{A36} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having to 50 ring atoms;
at least one combination of adjacent two or more of R_{A20} to R_{A24} are mutually bonded to form a substituted or unsubstituted monocyclic ring, mutually bonded to form a substituted or unsubstituted fused ring, or not mutually bonded;
at least one combination of adjacent two or more of R_{A30} to R_{A34} are mutually bonded to form a substituted or unsubstituted monocyclic ring, mutually bonded to form a substituted or unsubstituted fused ring, or not mutually bonded;
R_{A20} to R_{A24} and R_{A30} to R_{A34} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having to 50 ring atoms;
a plurality of R_{A20} are mutually the same or different;
a plurality of R_{A30} are mutually the same or different; and
R₉₀₁ to R₉₀₄ in the compounds represented by the formulae (cHT2-1), (cHT2-2), and (cHT2-3) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

In an exemplary arrangement of the organic EL device of the exemplary embodiment, a first amino group represented by a formula (c21) below and a second amino group represented by a formula (c22) below in the compound represented by the formula (cHT2-3) are an identical group or different groups.

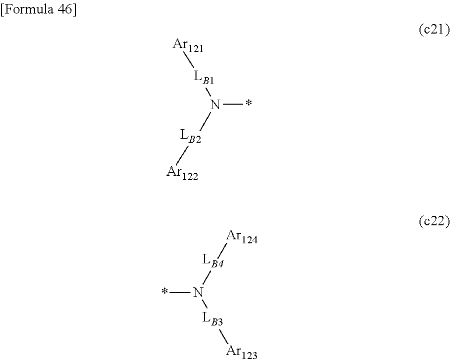

In the formulae (c21) and (c22), each * represents a bonding position to L_{B5}.

In an exemplary arrangement of the organic EL device of the exemplary embodiment, in the compounds represented by the formulae (cHT2-1), (cHT2-2), and (cHT2-3), the substituent for the “substituted or unsubstituted” group is not a group represented by —N(R_{C6})(R_{C7}).

In the exemplary embodiment, R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms. A plurality of R_{C6} are mutually the same or different, and a plurality of R_{C7} are mutually the same or different.

When the substituent for the “substituted or unsubstituted” group is not a group represented by —N(R_{C6})(R_{C7}), the compounds represented by the formulae (cHT2-1) and (cHT2-2) are each a monoamine compound.

When the substituent for the “substituted or unsubstituted” group is not a group represented by —N(R_{C6})(R_{C7}), the compound represented by the formula (cHT2-3) is a diamine compound.

In an exemplary arrangement of the organic EL device of the exemplary embodiment, the second anode side organic layer contains at least one compound selected from the group consisting of a compound represented by the formula (cHT2-1), a compound represented by the formula (cHT2-2), and a compound represented by the formula (cHT2-3), and the third anode side organic layer contains at least one compound selected from the group consisting of a compound represented by the formula (cHT3-1), a compound represented by the formula (cHT3-2), a compound represented by the formula (cHT3-3), and a compound represented by the formula (cHT3-4).

In an exemplary arrangement of the organic EL device of the exemplary embodiment, the compound contained in the second anode side organic layer is a monoamine compound. The monoamine compound has only one substituted or unsubstituted amino group in a molecule.

In an exemplary arrangement of the organic EL device of the exemplary embodiment, the compound represented by the formula (cHT2-1) and the compound represented by the formula (cHT2-2) are each a monoamine compound.

In an exemplary arrangement of the organic EL device of the exemplary embodiment, the compound contained in the second anode side organic layer is a diamine compound having two substituted or unsubstituted amino groups in a molecule.

In an exemplary arrangement of the organic EL device of the exemplary embodiment, the compound represented by the formula (cHT2-3) is a diamine compound.

In an exemplary arrangement of the organic EL device of the exemplary embodiment, the compound contained in the second anode side organic layer is a triamine compound having three substituted or unsubstituted amino groups in a molecule.

In an exemplary arrangement of the organic EL device of the exemplary embodiment, the compound contained in the second anode side organic layer is a tetraamine compound having four substituted or unsubstituted amino groups in a molecule.

When the compounds represented by the formulae (cHT2-1) and (cHT2-2) are each a triamine compound, the compounds represented by the formulae (cHT2-1) and (cHT2-2) each have two groups represented by —N(R_{C6})(R_{C7}) as the substituents for the “substituted or unsubstituted” group.

When the compounds represented by the formulae (cHT2-1) and (cHT2-2) are each a tetraamine compound, the compounds represented by the formulae (cHT2-1) and (cHT2-2) each have three groups represented by —N(R_{C6})(R_{C7}) as the substituents for the “substituted or unsubstituted” group.

When the compound represented by the formula (cHT2-3) is a triamine compound, the compound represented by the formula (cHT2-3) has one group represented by —N(R_{C6})(R_{C7}) as the substituent for the “substituted or unsubstituted” group.

When the compound represented by the formula (cHT2-3) is a tetraamine compound, the compound represented by the formula (cHT2-3) has two groups represented by —N(R_{C6})(R_{C7}) as the substituents for the “substituted or unsubstituted” group.

In an exemplary arrangement of the organic EL device of the exemplary embodiment, the compound contained in the second anode side organic layer has at least one group selected from the group consisting of a group represented by a formula (2-a), a group represented by a formula (2-b), a group represented by a formula (2-c), a group represented by a formula (2-d), a group represented by a formula (2-e), and a group represented by a formula (2-f) below.

In an exemplary arrangement of the organic EL device of the exemplary embodiment, the compound contained in the second anode side organic layer is at least one compound selected from the group consisting of a compound represented by the formula (cHT2-1), a compound represented by the formula (cHT2-2), and a compound represented by the formula (cHT2-3), and at least one of Ar₁₁₂, Ar₁₁₃, Ar₁₂₁, Ar₁₂₂, Ar₁₂₃ or Ar₁₂₄ in the formulae (cHT2-1), (cHT2-2), and (cHT2-3) has at least one group selected from the group consisting of a group represented by a formula (2-a), a group represented by a formula (2-b), a group represented by a formula (2-c), a group represented by a formula (2-d), a group represented by a formula (2-e), and a group represented by a formula (2-f) below.

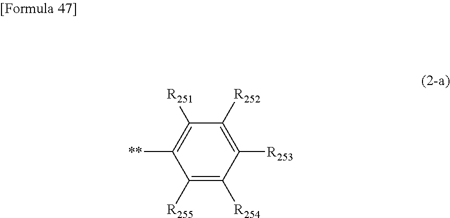

In the formula (2-a):
none of a combination(s) of adjacent two or more of R₂₅₁ to R₂₅₅ are bonded to each other;
R₂₅₁ to R₂₅₅ are each independently a hydrogen atom, or a substituted or unsubstituted alkyl group having 1 to 6 carbon atoms; and
** represents a bonding position.

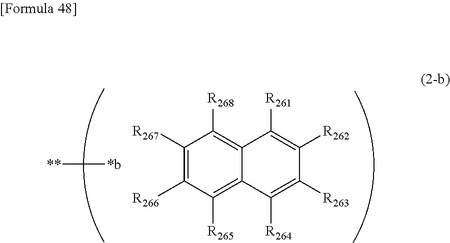

In the formula (2-b):
one of R₂₆₁ to R₂₆₈ is a single bond with *b;
none of a combination(s) of adjacent two or more of R₂₆₁ to R₂₆₈ not being the single bond with *b are bonded to each other;
R₂₆₁ to R₂₆₈ not being the single bond with *b are each independently a hydrogen atom, a substituted or unsubstituted alkyl group having 1 to 6 carbon atoms, or a substituted or unsubstituted aryl group having 6 to 12 ring carbon atoms; and
** represents a bonding position.

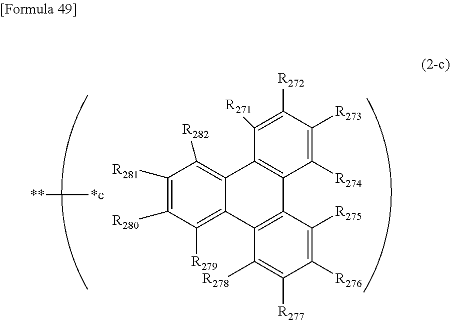

In the formula (2-c):
one of R₂₇₁ to R₂₈₂ is a single bond with *c;
none of a combination(s) of adjacent two or more of R₂₇₁ to R₂₈₂ not being the single bond with *c are bonded to each other;
R₂₇₁ to R₂₈₂ not being the single bond with *c are each independently a hydrogen atom, a substituted or unsubstituted alkyl group having 1 to 6 carbon atoms, or a substituted or unsubstituted aryl group having 6 to 12 ring carbon atoms; and
** represents a bonding position.

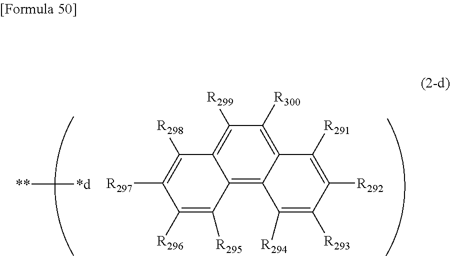

In the formula (2-d):
one of R₂₉₁ to R₃₀₀ is a single bond with *d;
none of a combination(s) of adjacent two or more of R₂₉₁ to R₃₀₀ not being the single bond with *d are bonded to each other;
R₂₉₁ to R₃₀₀ not being the single bond with *d are each independently a hydrogen atom, a substituted or unsubstituted alkyl group having 1 to 6 carbon atoms, or a substituted or unsubstituted aryl group having 6 to 12 ring carbon atoms; and
** represents a bonding position.

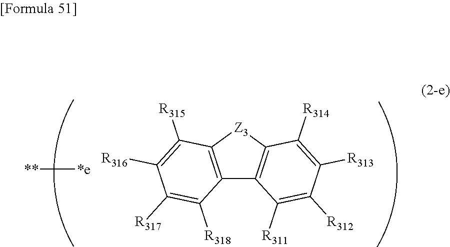

In the formula (2-e):
Z₃ is an oxygen atom, a sulfur atom, NR₃₁₉, or C(R₃₂₀)(R₃₂₁);
one of R₃₁₁ to R₃₂₁ is a single bond with *e, or one of carbon atoms of a substituted or unsubstituted benzene ring, described below, formed by mutually bonding a combination of adjacent two or more of R₃₁₁ to R₃₁₈ is bonded to *e by a single bond;
a combination of adjacent two or more of R₃₁₁ to R₃₁₈ not being the single bond with *e are mutually bonded to form a substituted or unsubstituted benzene ring, or not mutually bonded; and
R₃₁₁ to R₃₁₈ not being the single bond with *e and not forming the substituted or unsubstituted benzene ring are each independently a hydrogen atom, a substituted or unsubstituted alkyl group having 1 to 6 carbon atoms, a substituted or unsubstituted aryl group having 6 to 12 ring carbon atoms, or a substituted or unsubstituted heterocyclic group having 5 to 10 ring atoms;
R₃₁₉ not being the single bond with *e is a hydrogen atom, a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e are mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position.

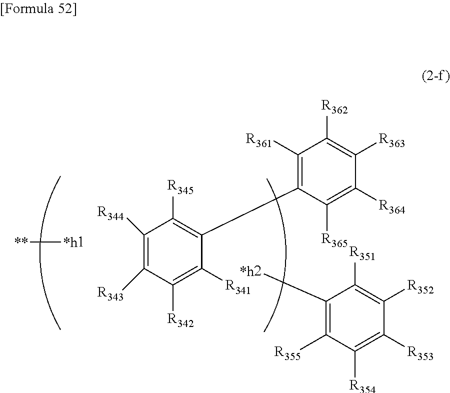

In the formula (2-f):
one of R₃₄₁ to R₃₄₅ is a single bond with *h1, and another one of R₃₄₁ to R₃₄₅ is a single bond with *h2;
none of a combination(s) of adjacent two or more of R₃₄₁ to R₃₄₅ not being the single bond with *h1 and not being the single bond with *h2 are bonded to each other;
at least one combination of adjacent two or more of R₃₅₁ to R₃₅₅ are mutually bonded to form a substituted or unsubstituted monocyclic ring, mutually bonded to form a substituted or unsubstituted fused ring, or not mutually bonded;
at least one combination of adjacent two or more of R₃₆₁ to R₃₆₅ are mutually bonded to form a substituted or unsubstituted monocyclic ring, mutually bonded to form a substituted or unsubstituted fused ring, or not mutually bonded;
R₃₄₁ to R₃₄₅ not being the single bond with *h1 and not being the single bond with *h2 as well as R₃₅₁ to R₃₅₅ and R₃₆₁ to R₃₆₅ forming neither the substituted or unsubstituted monocyclic ring nor the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position.

In an exemplary arrangement of the organic EL device of the exemplary embodiment, the group represented by the formula (2-a), the group represented by the formula (2-b), the group represented by the formula (2-c), the group represented by the formula (2-d), the group represented by the formula (2-e), and the group represented by the formula (2-f) are each independently bonded directly, with a phenylene group, or with a biphenylene group to a nitrogen atom of an amino group of the monoamine compound.

In an exemplary arrangement of the organic EL device of the exemplary embodiment, the compound contained in the second anode side organic layer is a compound represented by the formula (cHT2-1), and at least one of Ar₁₁₂ or Ar₁₁₃ is a group selected from the group consisting of a group represented by the formula (2-a), a group represented by the formula (2-b), a group represented by the formula (2-c), a group represented by the formula (2-d), a group represented by the formula (2-e), and a group represented by the formula (2-f).

In an exemplary arrangement of the organic EL device of the exemplary embodiment, the compound contained in the second anode side organic layer is a compound represented by the formula (cHT2-2), and at least one of Ar₁₁₂ or Ar₁₁₃ is a group selected from the group consisting of a group represented by the formula (2-a), a group represented by the formula (2-b), a group represented by the formula (2-c), a group represented by the formula (2-d), a group represented by the formula (2-e), and a group represented by the formula (2-f).

In an exemplary arrangement of the organic EL device of the exemplary embodiment, the compound contained in the second anode side organic layer is a compound represented by the formula (cHT2-3), and at least one of Ar₁₂₁, Ar₁₂₂, A₁₂₃, or A₁₂₄ is a group selected from the group consisting of a group represented by the formula (2-a), a group represented by the formula (2-b), a group represented by the formula (2-c), a group represented by the formula (2-d), a group represented by the formula (2-e), and a group represented by the formula (2-f).

In the organic EL device of the exemplary embodiment, when Z₃ is NR₃₁₉, R₃₁₂ or R₃₁₇ is preferably a single bond with *e.

In an exemplary arrangement of the organic EL device of the exemplary embodiment, the group represented by the formula (2-e) is a group represented by a formula (2-e7) below.

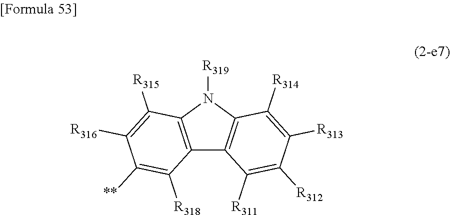

In the formula (2-e7), R₃₁₁ to R₃₁₆, R₃₁₈ and R₃₁₉ respectively represent the same as R₃₁₁ to R₃₁₆, R₃₁₈ and R₃₁₉ in the formula (2-e); and ** represents a bonding position.

In the organic EL device of the exemplary embodiment, when Z₃ is NR₃₁₉, R₃₁₅, R₃₁₆, or R₃₁₈ is also preferably a single bond with *e.

In an exemplary arrangement of the organic EL device of the exemplary embodiment, the group represented by the formula (2-e) is a group represented by a formula (2-e4), a formula (2-e5), or a formula (2-e6) below.

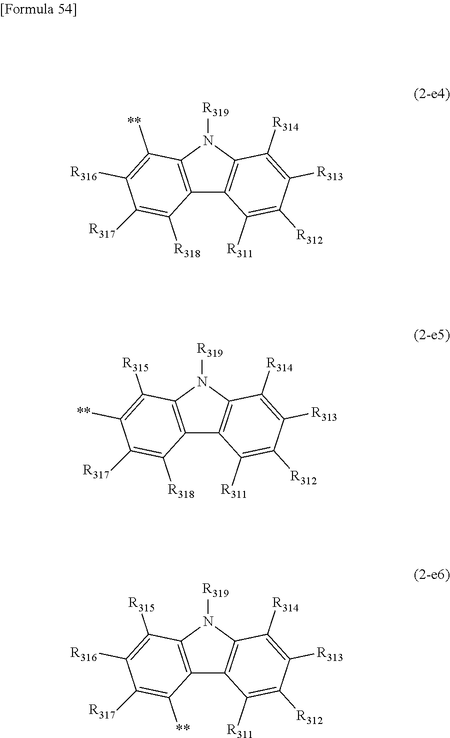

In the formulae (2-e4), (2-e5), and (2-e6), R₃₁₁ to R₃₁₉ respectively represent the same as R₃₁₁ to R₃₁₉ in the formula (2-e); and ** represents a bonding position.

In an exemplary arrangement of the organic EL device of the exemplary embodiment, the group represented by the formula (2-e) is a group represented by a formula (2-e1), a formula (2-e2), or a formula (2-e3) below.

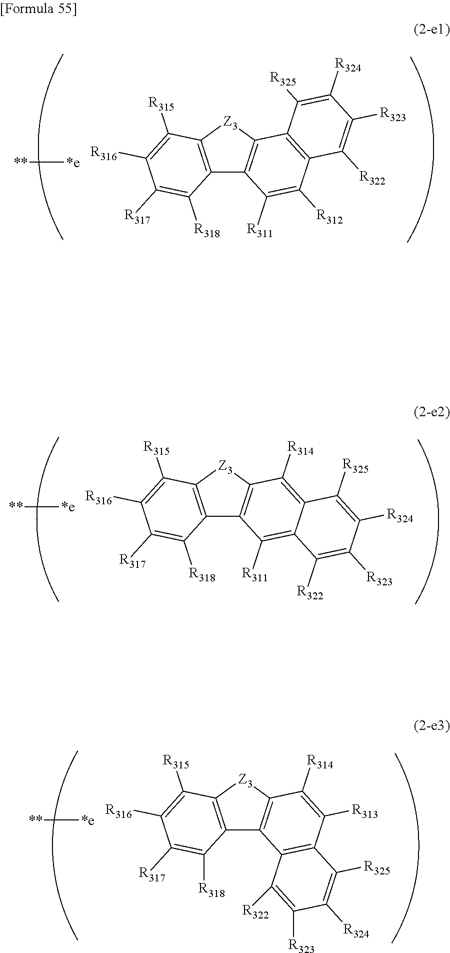

In the formulae (2-e1), (2-e2), and (2-e3):
Z₃ is an oxygen atom, a sulfur atom, NR₃₁₉, or C(R₃₂₀)(R₃₂₁);
one of R₃₁₁ to R₃₂₅ is a single bond with *e;
R₃₁₁ to R₃₁₈ and R₃₂₂ and R₃₂₅ not being the single bond with *e are each independently a hydrogen atom, a substituted or unsubstituted alkyl group having 1 to 6 carbon atoms, a substituted or unsubstituted aryl group having 6 to 12 ring carbon atoms, or a substituted or unsubstituted heterocyclic group having 5 to 10 ring atoms;
R₃₁₉ not being the single bond with *e is a hydrogen atom, a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e are mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position.

In an exemplary arrangement of the organic EL device of the exemplary embodiment, ** in the formulae (2-a), (2-b), (2-c), (2-d), (2-e), (2-f), (2-e1), (2-e2), (2-e3), (2-e4), (2-e5), (2-e6) and (2-e7) are each independently a bonding position to L_{A2}, L_{A3}, L_{B1}, L_{B2}, L_{B3} or L_{B}4, or a bonding position to a nitrogen atom of an amino group.

In an exemplary arrangement of the organic EL device of the exemplary embodiment, the compound contained in the second anode side organic layer is a compound having no thiophene ring in a molecule.

In an exemplary arrangement of the organic EL device of the exemplary embodiment, the second hole transporting zone material is at least one compound selected from the group consisting of a compound represented by the formula (cHT2-1), a compound represented by the formula (cHT2-2), and a compound represented by the formula (cHT2-3).

In an exemplary arrangement of the organic EL device of the exemplary embodiment, the second hole transporting zone material is a monoamine compound, a diamine compound, a triamine compound, or a tetraamine compound.

In an exemplary arrangement of the organic EL device of the exemplary embodiment, the first anode side organic layer contains a first hole transporting zone material.

In an exemplary arrangement of the organic EL device of the exemplary embodiment, the first hole transporting zone material and the third hole transporting zone material are different compounds.

In an exemplary arrangement of the organic EL device of the exemplary embodiment, the first hole transporting zone material and the second hole transporting zone material may be different compounds or the same compound. When the first hole transporting zone material and the second hole transporting zone material are the same compound, the first anode side organic layer preferably contains a compound (e.g., a doped compound) having a molecular structure different from that of the first hole transporting zone material, the second hole transporting zone material, and the third hole transporting zone material.

In an exemplary arrangement of the organic EL device of the exemplary embodiment, the first anode side organic layer also preferably contains a first organic material and a second organic material different from each other. The content of the second organic material in the first anode side organic layer is preferably less than 50 mass %. The first anode side organic layer containing the first and second organic materials improves hole injectability from the anode to the first anode side organic layer.

The first organic material contained in the first anode side organic layer is preferably the first hole transporting zone material and the second organic material is preferably a doped compound.

When the first anode side organic layer contains the first hole transporting zone material and the doped compound, the content of the doped compound in the first anode side organic layer is preferably in a range from 0.5 mass % to 5 mass %, more preferably in a range from 1.0 mass % to 3.0 mass %. The content of the first hole transporting zone material in the first anode side organic layer is preferably 40 mass % or more, more preferably 45 mass % or more, and still more preferably 50 mass % or more. The content of the first hole transporting zone material in the first anode side organic layer is preferably 99.5 mass % or less. The total of a content of the first hole transporting zone material and a content of the doped compound in the first anode side organic layer is 100 mass % or less.

In an exemplary arrangement of the organic EL device of the exemplary embodiment, the doped compound has at least one of a first cyclic structure represented by a formula (P11) below or a second cyclic structure represented by a formula (P12) below.

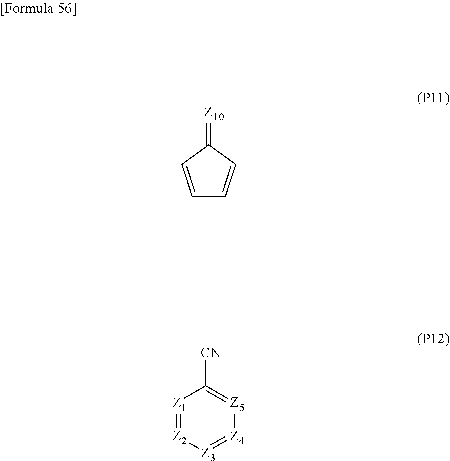

The first cyclic structure represented by the formula (P11) is fused to at least one cyclic structure of a substituted or unsubstituted aromatic hydrocarbon ring having 6 to 50 ring carbon atoms or a substituted or unsubstituted heterocycle having 5 to 50 ring atoms in a molecule of the doped compound, and
a structure represented by ═Z₁₀ is represented by a formula (11a), (11 b), (11c), (11d), (11e), (11f), (11g), (11h), (11i), (11j), (11k) or (11m) below.

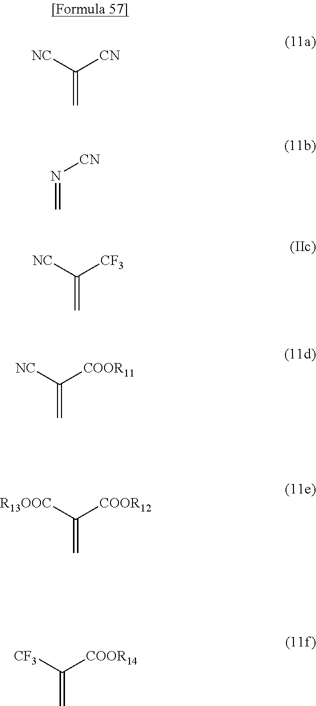

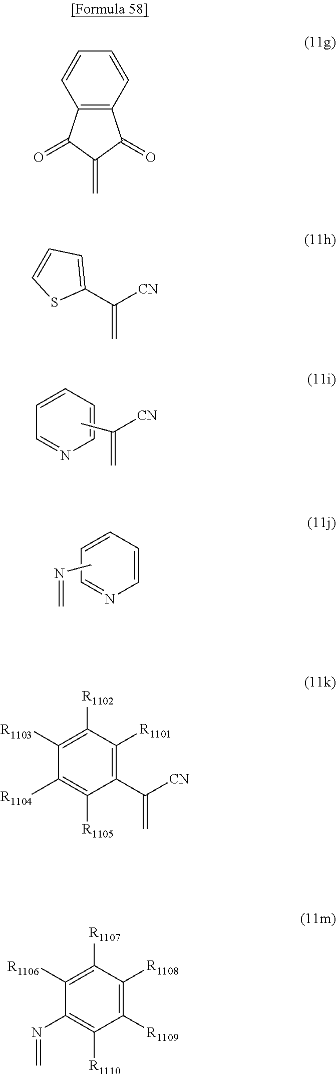

In the formula (11a), (11b), (11c), (11d), (11e), (11f), (11g), (11h), (11i), (11j), (11k) or (11m), R₁₁ to R₁₄ and R₁₁₀₁ to R₁₁₁₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the formula (P12):
Z₁ to Z₅ are each independently a nitrogen atom, a carbon atom bonded to R₁₅, or a carbon atom bonded to another atom in a molecule of the doped compound;
at least one of Z₁ to Z₅ is a carbon atom bonded to another atom in a molecule of the doped compound;
R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the doped compound, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

An ester group herein is at least one group selected from the group consisting of an alkyl ester group and an aryl ester group.

An alkyl ester group herein is represented, for instance, by —C(═O)OR^{E}. R^{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R^{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂.

A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having 5 to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms.
R^{C} is exemplified by a substituted or unsubstituted alkyl group having 1 to 50 carbon atoms (preferably 1 to 6 carbon atoms).

In the doped compound, all groups specified as “substituted or unsubstituted” groups are preferably “unsubstituted” groups.

### Specific Examples of Doped Compound

Specific examples of the doped compound include the following compounds. It should however be noted that the invention is not limited to the specific examples of the doped compound.

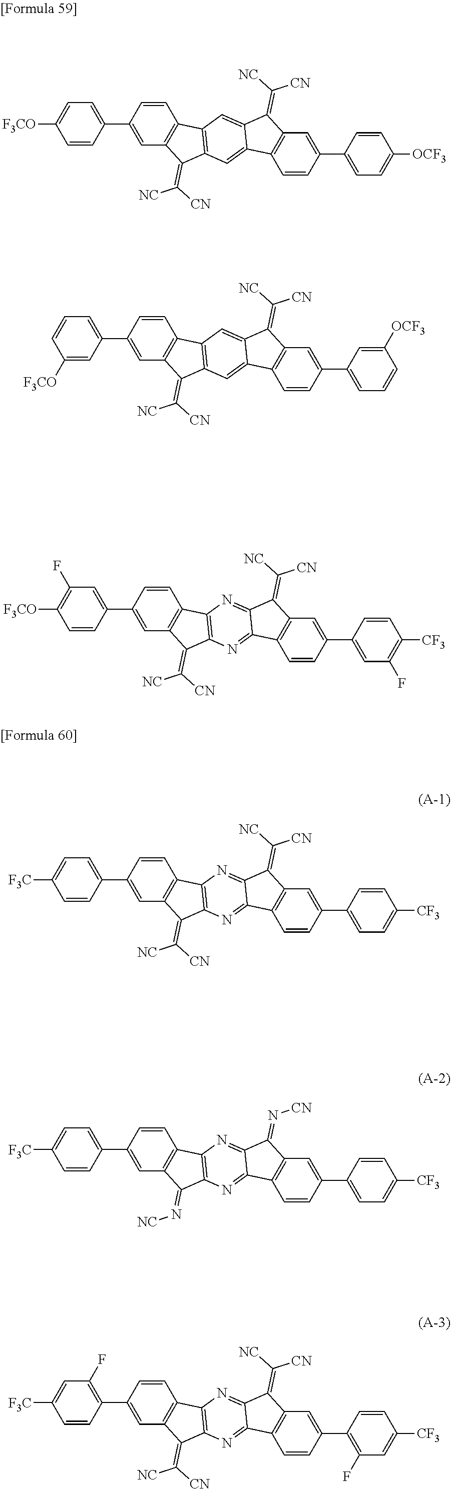

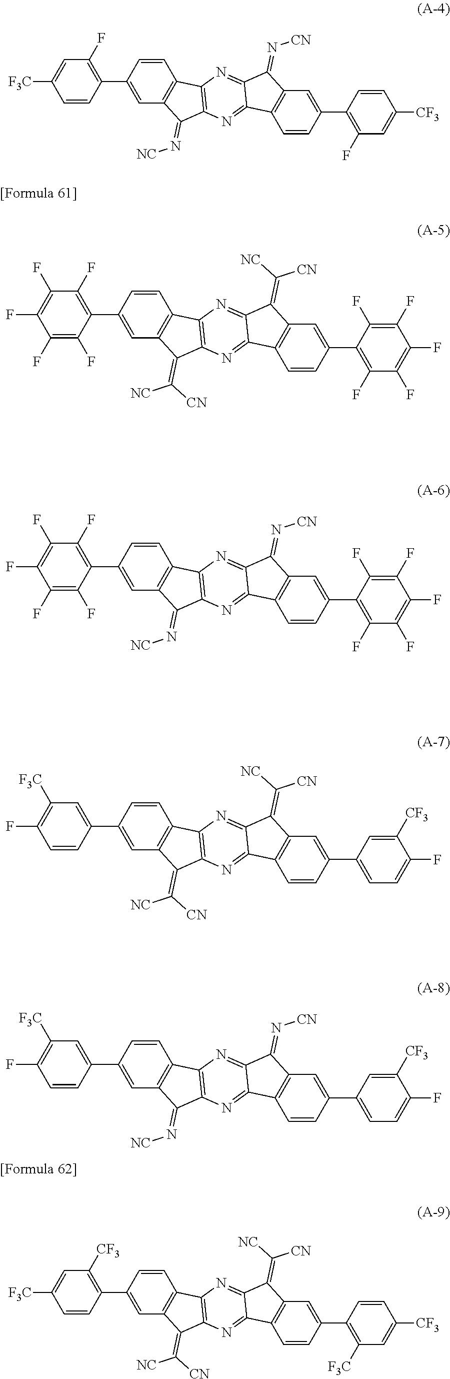

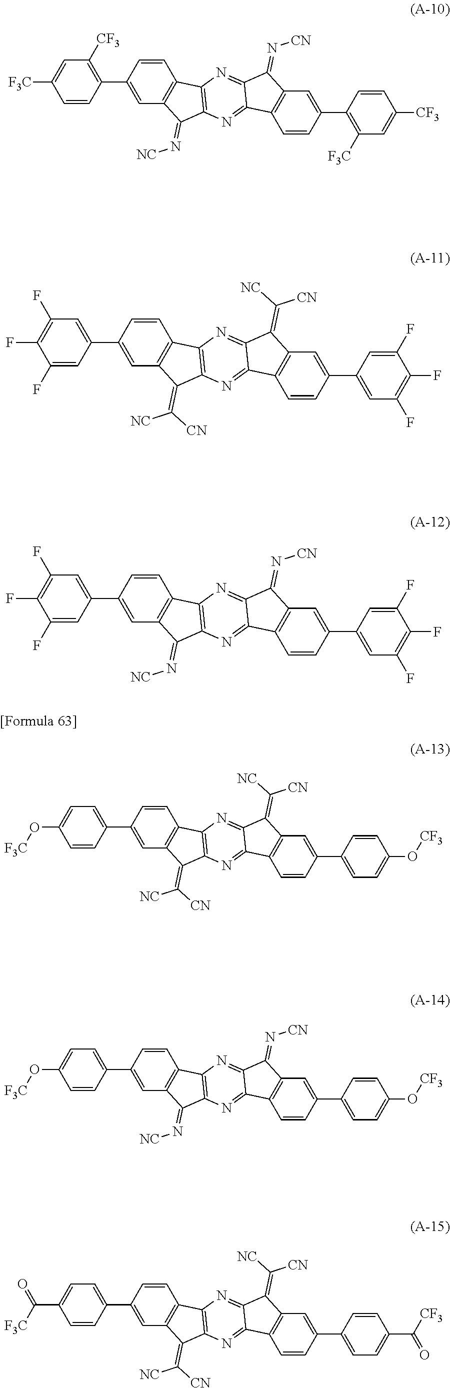

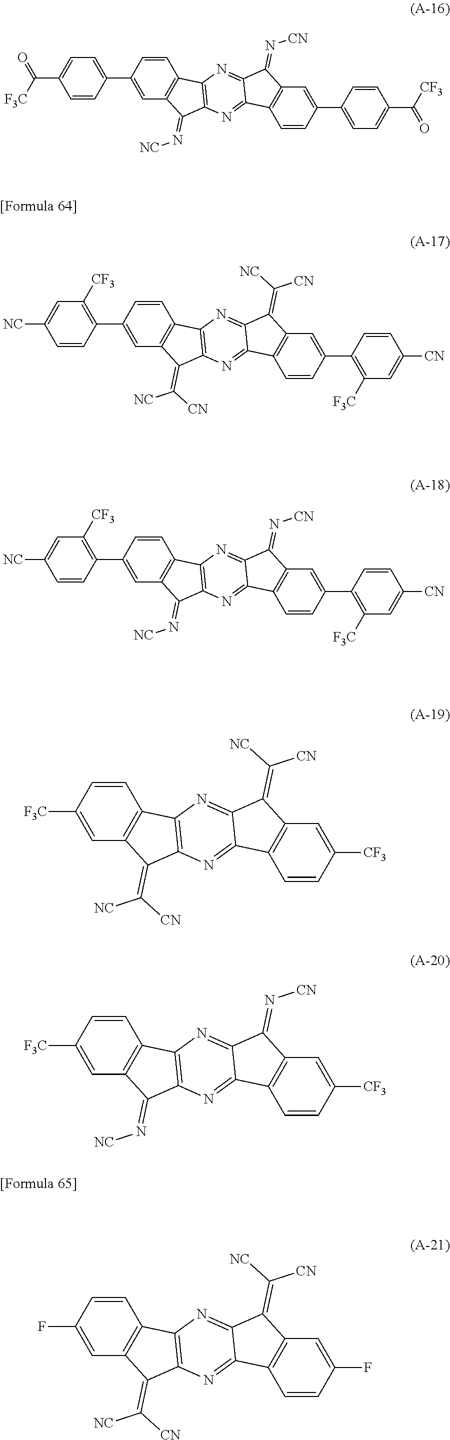

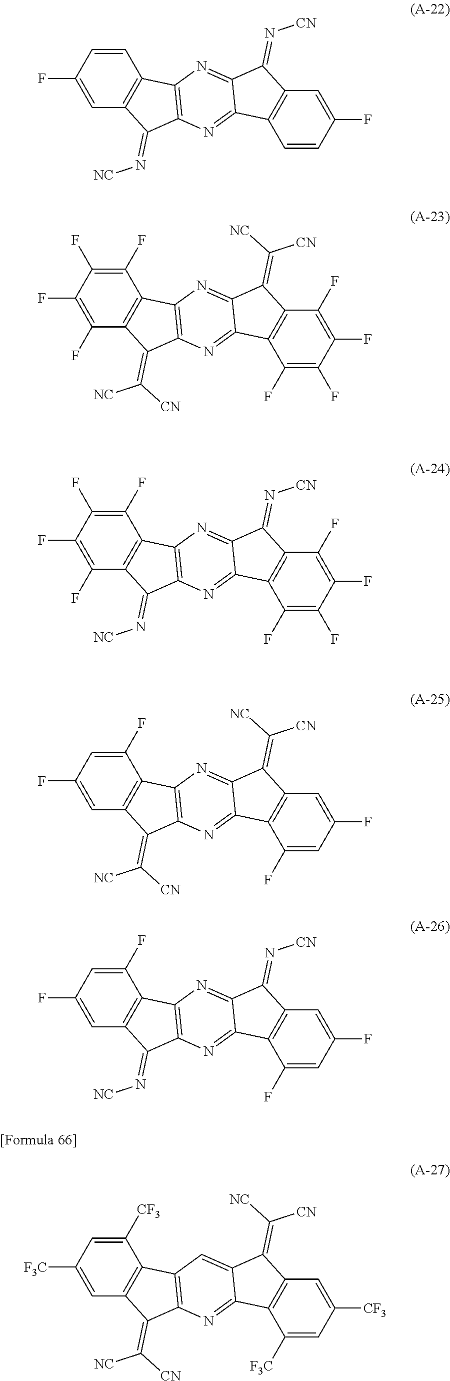 [SMILES: N#C/N=c1\c2cc(F)ccc2c2nc3/c(=N/C#N)c4cc(F)ccc4c3nc12 ; N#CC(C#N)=C1c2nc3c(nc2-c2c(F)c(F)c(F)c(F)c21)C(=C(C#N)C#N)c1c(F)c(F)c(F)c(F)c1-3 ; N#C/N=c1/c2nc3c(nc2c2c(F)c(F)c(F)c(F)c12)/c(=N/C#N)c1c(F)c(F)c(F)c(F)c13 ; N#CC(C#N)=C1c2cc(F)cc(F)c2-c2nc3c(nc21)-c1c(F)cc(F)cc1C3=C(C#N)C#N ; N#C/N=c1\c2cc(F)cc(F)c2c2nc3/c(=N/C#N)c4cc(F)cc(F)c4c3nc12 ; N#CC(C#N)=C1c2cc3c(nc2-c2c1cc(C(F)(F)F)cc2C(F)(F)F)C(=C(C#N)C#N)c1cc(C(F)(F)F)cc(C(F)(F)F)c1-3]

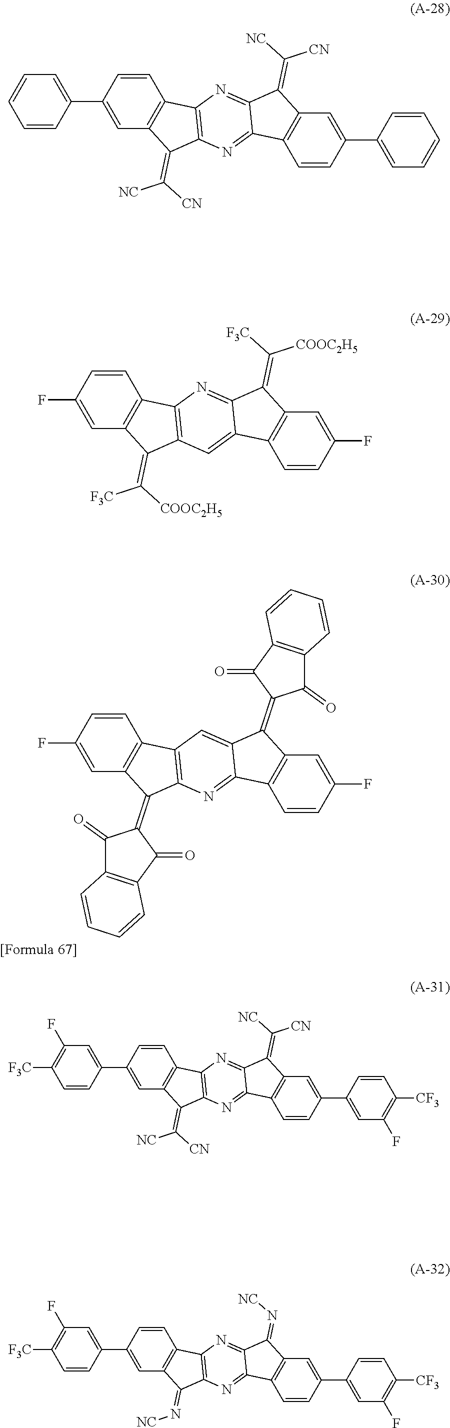

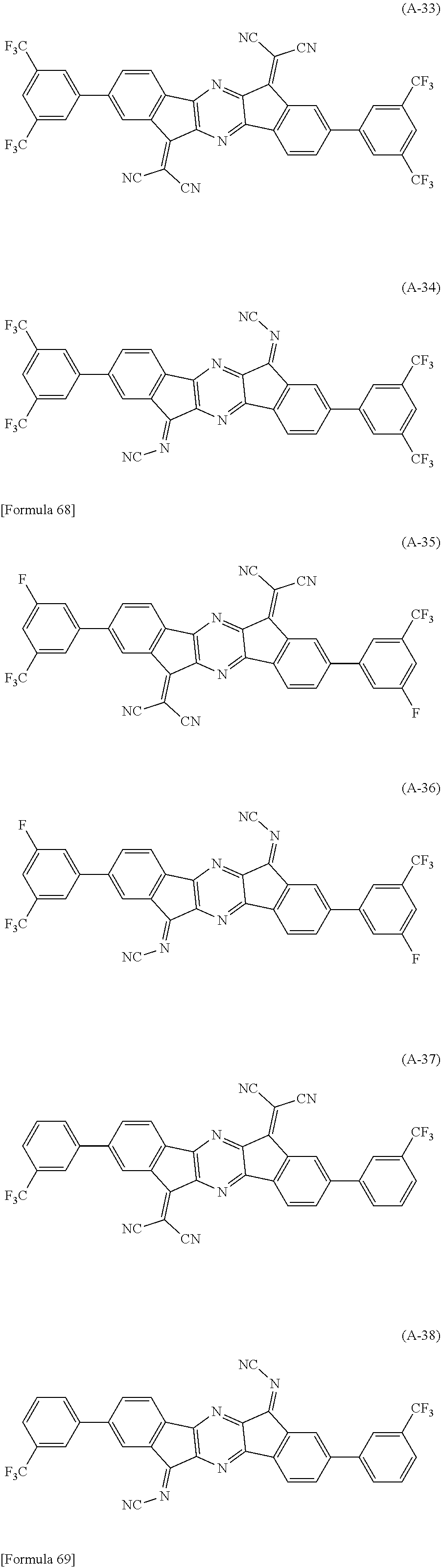

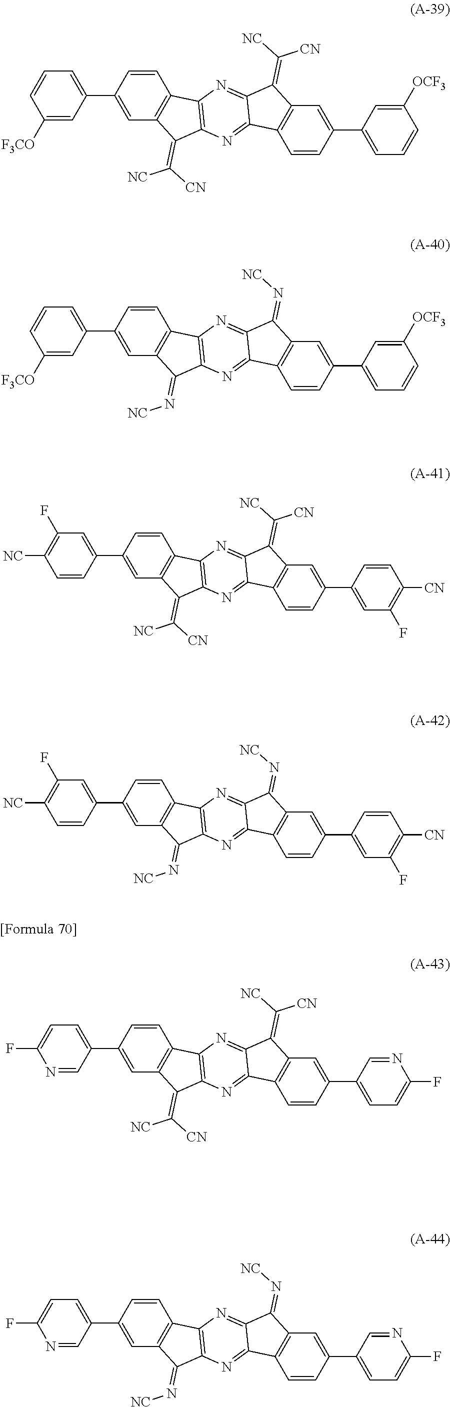

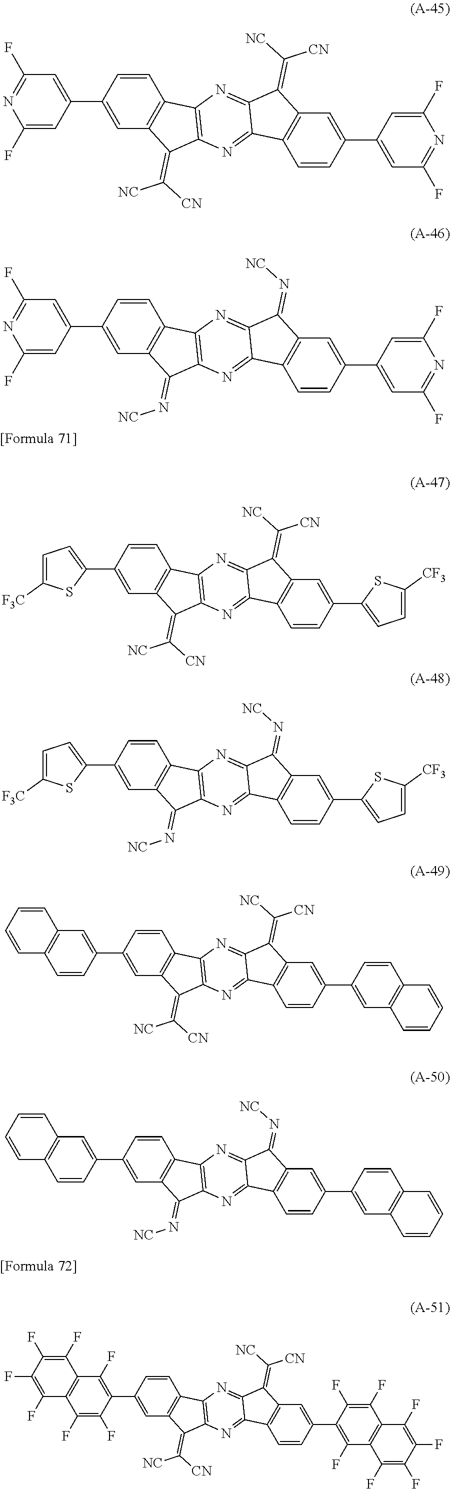

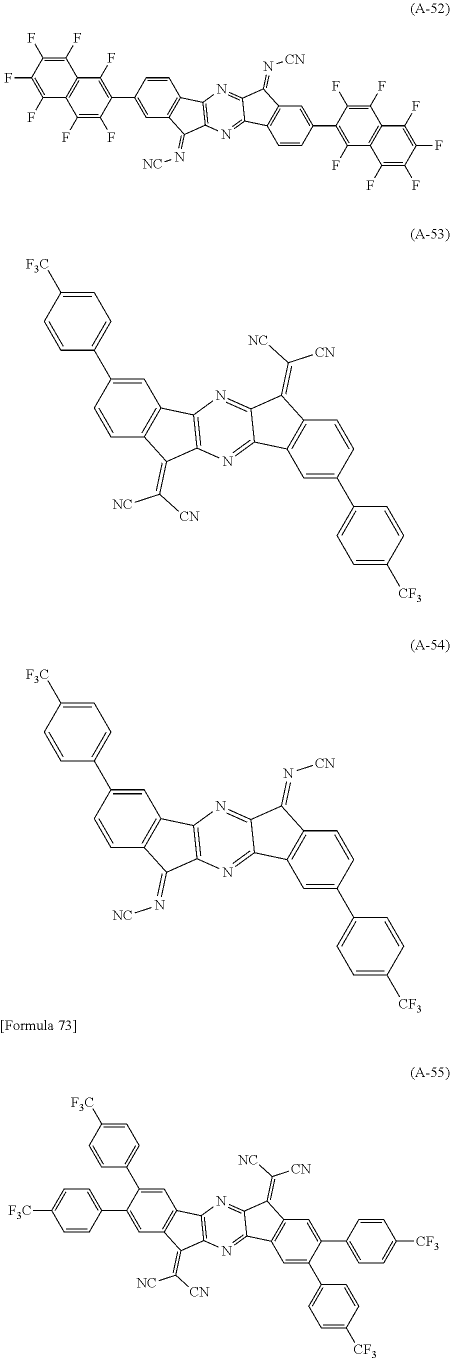 [SMILES: N#C/N=c1\c2cc(-c3c(F)c(F)c4c(F)c(F)c(F)c(F)c4c3F)ccc2c2nc3/c(=N/C#N)c4cc(-c5c(F)c(F)c6c(F)c(F)c(F)c(F)c6c5F)ccc4c3nc12 ; N#CC(C#N)=C1c2ccc(-c3ccc(C(F)(F)F)cc3)cc2-c2nc3c(nc21)-c1cc(-c2ccc(C(F)(F)F)cc2)ccc1C3=C(C#N)C#N ; N#C/N=c1\c2ccc(-c3ccc(C(F)(F)F)cc3)cc2c2nc3/c(=N/C#N)c4ccc(-c5ccc(C(F)(F)F)cc5)cc4c3nc12 ; N#CC(C#N)=C1c2cc(-c3ccc(C(F)(F)F)cc3)c(-c3ccc(C(F)(F)F)cc3)cc2-c2nc3c(nc21)-c1cc(-c2ccc(C(F)(F)F)cc2)c(-c2ccc(C(F)(F)F)cc2)cc1C3=C(C#N)C#N]

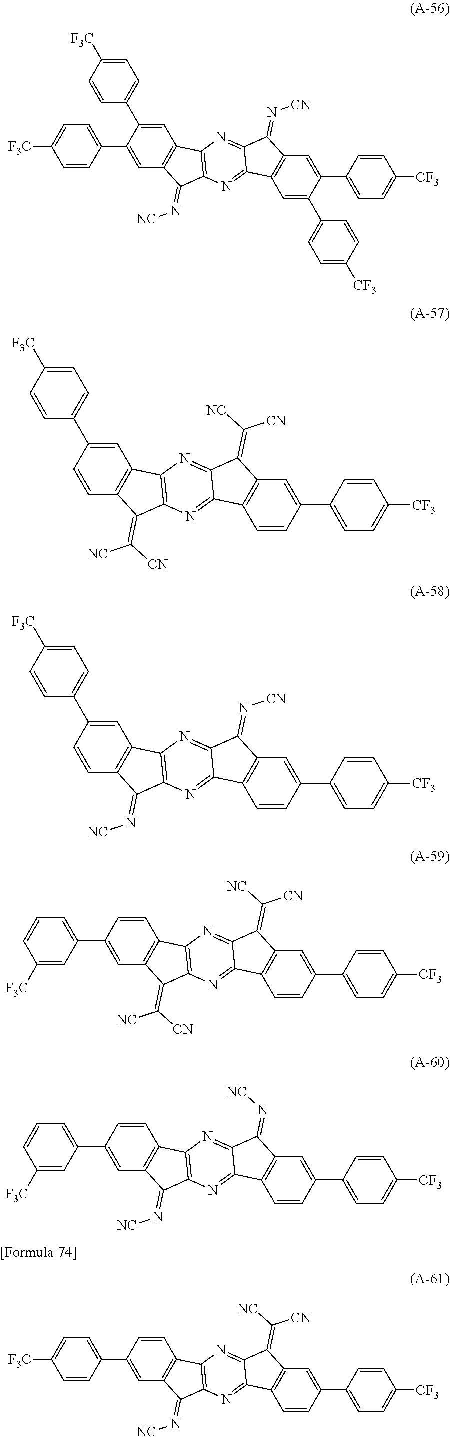

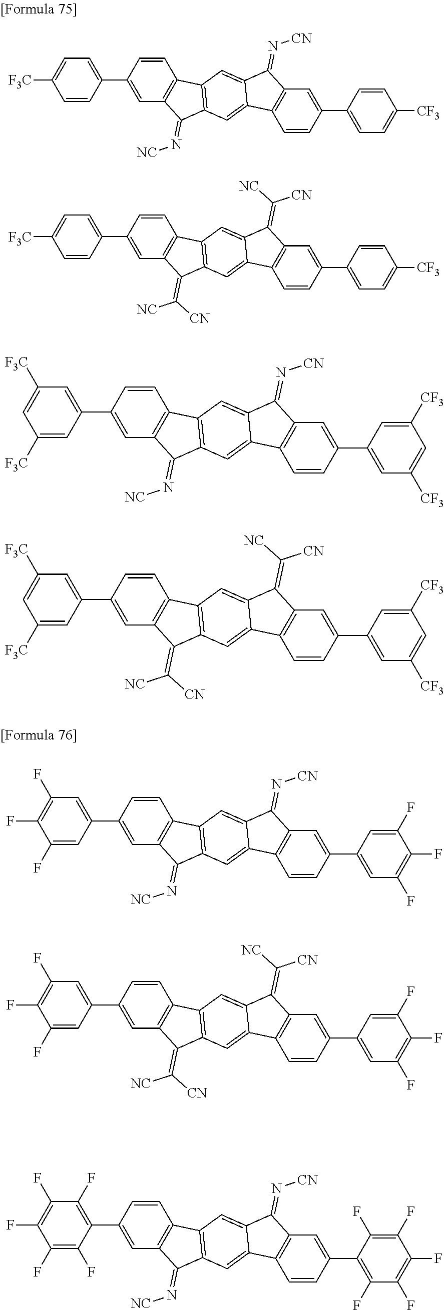

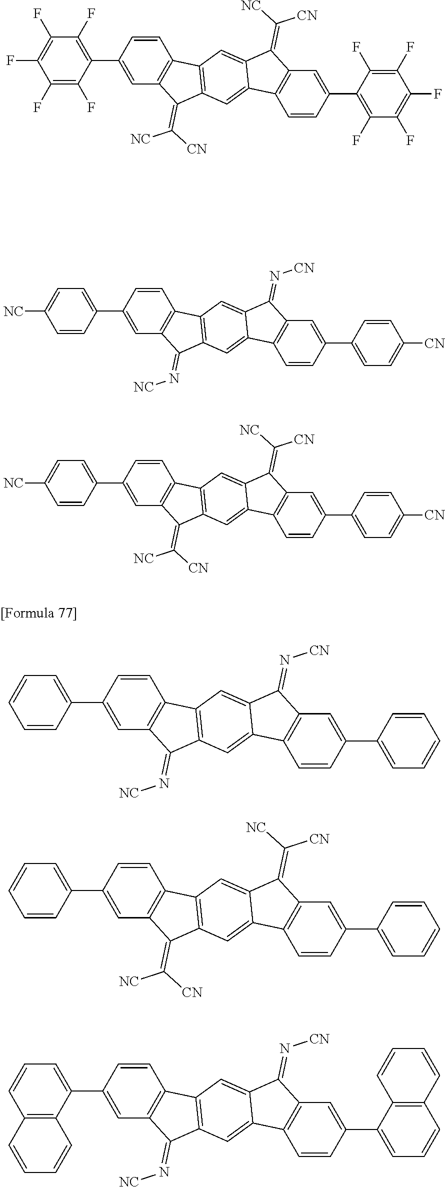

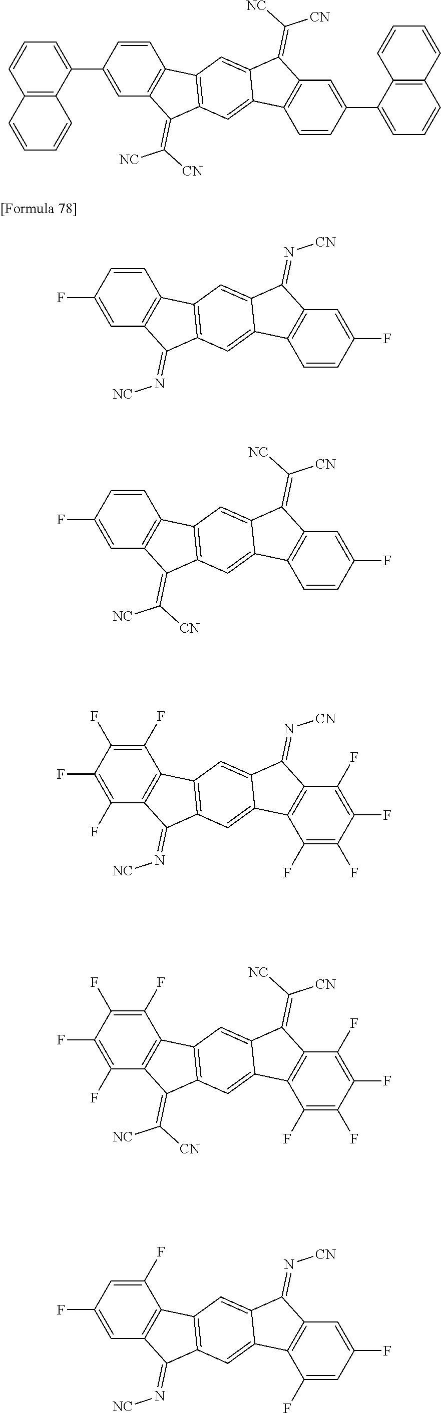 [SMILES: N#CC(C#N)=C1c2cc(-c3cccc4ccccc34)ccc2-c2cc3c(cc21)-c1ccc(-c2cccc4ccccc24)cc1C3=C(C#N)C#N ; N#C/N=c1\c2cc(F)ccc2c2cc3/c(=N/C#N)c4cc(F)ccc4c3cc12 ; N#CC(C#N)=C1c2cc(F)ccc2-c2cc3c(cc21)-c1ccc(F)cc1C3=C(C#N)C#N ; N#C/N=c1/c2cc3c(cc2c2c(F)c(F)c(F)c(F)c12)/c(=N/C#N)c1c(F)c(F)c(F)c(F)c13 ; N#CC(C#N)=C1c2cc3c(cc2-c2c(F)c(F)c(F)c(F)c21)C(=C(C#N)C#N)c1c(F)c(F)c(F)c(F)c1-3 ; N#C/N=c1/c2cc3c(cc2c2c(F)cc(F)cc12)/c(=N/C#N)c1cc(F)cc(F)c13]

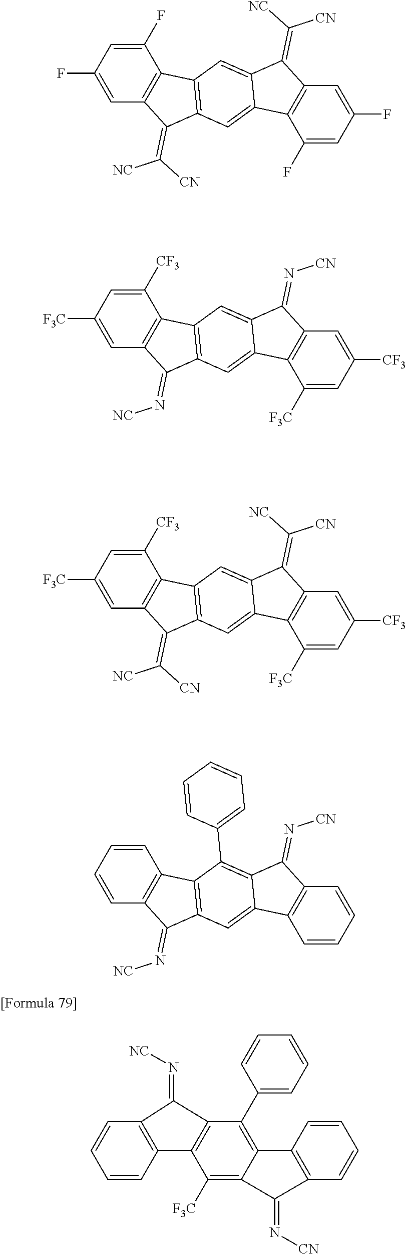 [SMILES: N#CC(C#N)=C1c2cc3c(cc2-c2c(F)cc(F)cc21)C(=C(C#N)C#N)c1cc(F)cc(F)c1-3 ; N#C/N=c1/c2cc3c(cc2c2c(C(F)(F)F)cc(C(F)(F)F)cc12)/c(=N/C#N)c1cc(C(F)(F)F)cc(C(F)(F)F)c13 ; N#CC(C#N)=C1c2cc3c(cc2-c2c1cc(C(F)(F)F)cc2C(F)(F)F)C(=C(C#N)C#N)c1cc(C(F)(F)F)cc(C(F)(F)F)c1-3 ; N#C/N=c1\c2ccccc2c2c(-c3ccccc3)c3/c(=N/C#N)c4ccccc4c3cc12 ; N#C/N=c1\c2ccccc2c2c(-c3ccccc3)c3/c(=N/C#N)c4ccccc4c3c(C(F)(F)F)c12]

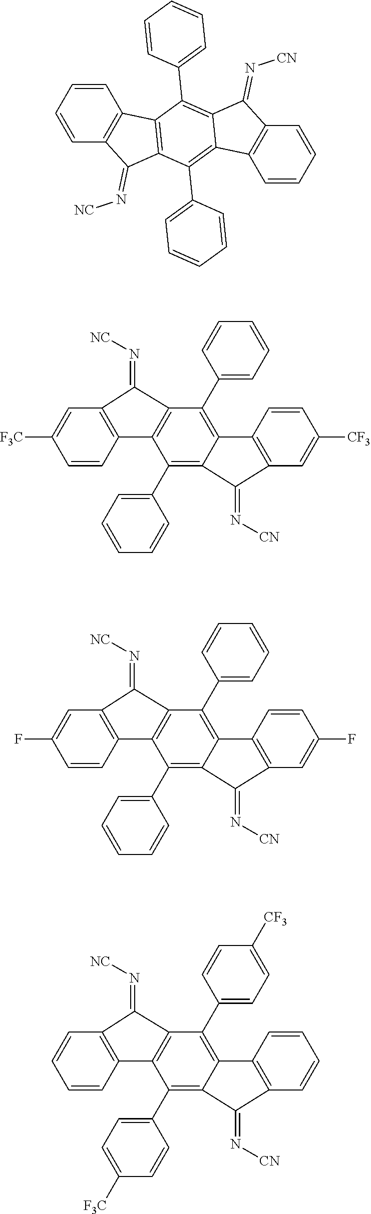 [SMILES: N#C/N=c1\c2ccccc2c2c(-c3ccccc3)c3/c(=N/C#N)c4ccccc4c3c(-c3ccccc3)c12 ; N#C/N=c1\c2cc(C(F)(F)F)ccc2c2c(-c3ccccc3)c3/c(=N/C#N)c4cc(C(F)(F)F)ccc4c3c(-c3ccccc3)c12 ; N#C/N=c1\c2cc(F)ccc2c2c(-c3ccccc3)c3/c(=N/C#N)c4cc(F)ccc4c3c(-c3ccccc3)c12 ; N#C/N=c1\c2ccccc2c2c(-c3ccc(C(F)(F)F)cc3)c3/c(=N/C#N)c4ccccc4c3c(-c3ccc(C(F)(F)F)cc3)c12]

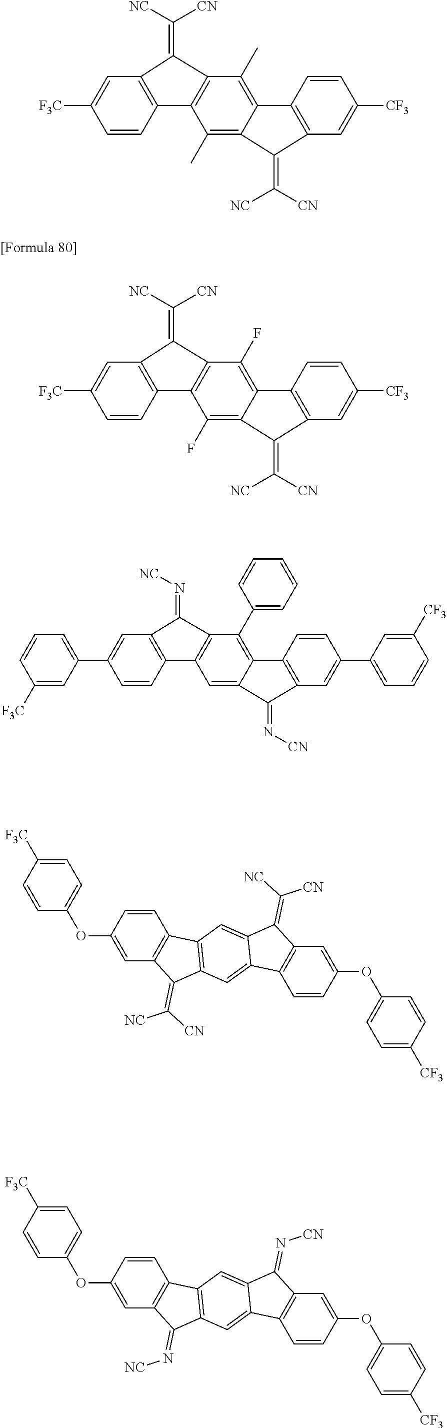 [SMILES: Cc1c2c(c(C)c3c1-c1ccc(C(F)(F)F)cc1C3=C(C#N)C#N)-c1ccc(C(F)(F)F)cc1C2=C(C#N)C#N ; N#CC(C#N)=C1c2cc(C(F)(F)F)ccc2-c2c(F)c3c(c(F)c21)-c1ccc(C(F)(F)F)cc1C3=C(C#N)C#N ; N#C/N=c1\c2cc(-c3cccc(C(F)(F)F)c3)ccc2c2c(-c3ccccc3)c3/c(=N/C#N)c4cc(-c5cccc(C(F)(F)F)c5)ccc4c3cc12 ; N#CC(C#N)=C1c2cc(Oc3ccc(C(F)(F)F)cc3)ccc2-c2cc3c(cc21)-c1ccc(Oc2ccc(C(F)(F)F)cc2)cc1C3=C(C#N)C#N ; N#C/N=c1\c2cc(Oc3ccc(C(F)(F)F)cc3)ccc2c2cc3/c(=N/C#N)c4cc(Oc5ccc(C(F)(F)F)cc5)ccc4c3cc12]

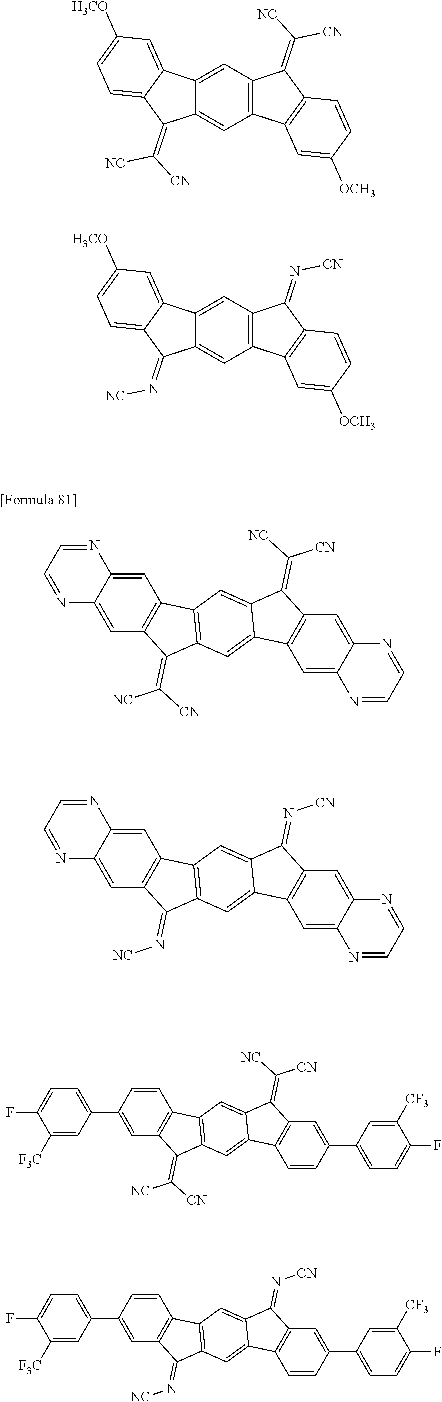 [SMILES: COc1ccc2c(c1)-c1cc3c(cc1C2=C(C#N)C#N)-c1cc(OC)ccc1C3=C(C#N)C#N ; COc1ccc2/c(=N\C#N)c3cc4c(cc3c2c1)/c(=N/C#N)c1ccc(OC)cc14 ; N#CC(C#N)=C1c2cc3c(cc2-c2cc4nccnc4cc21)C(=C(C#N)C#N)c1cc2nccnc2cc1-3 ; N#C/N=c1\c2cc3nccnc3cc2c2cc3/c(=N/C#N)c4cc5nccnc5cc4c3cc12 ; N#CC(C#N)=C1c2cc(-c3ccc(F)c(C(F)(F)F)c3)ccc2-c2cc3c(cc21)-c1ccc(-c2ccc(F)c(C(F)(F)F)c2)cc1C3=C(C#N)C#N ; N#C/N=c1\c2cc(-c3ccc(F)c(C(F)(F)F)c3)ccc2c2cc3/c(=N/C#N)c4cc(-c5ccc(F)c(C(F)(F)F)c5)ccc4c3cc12]

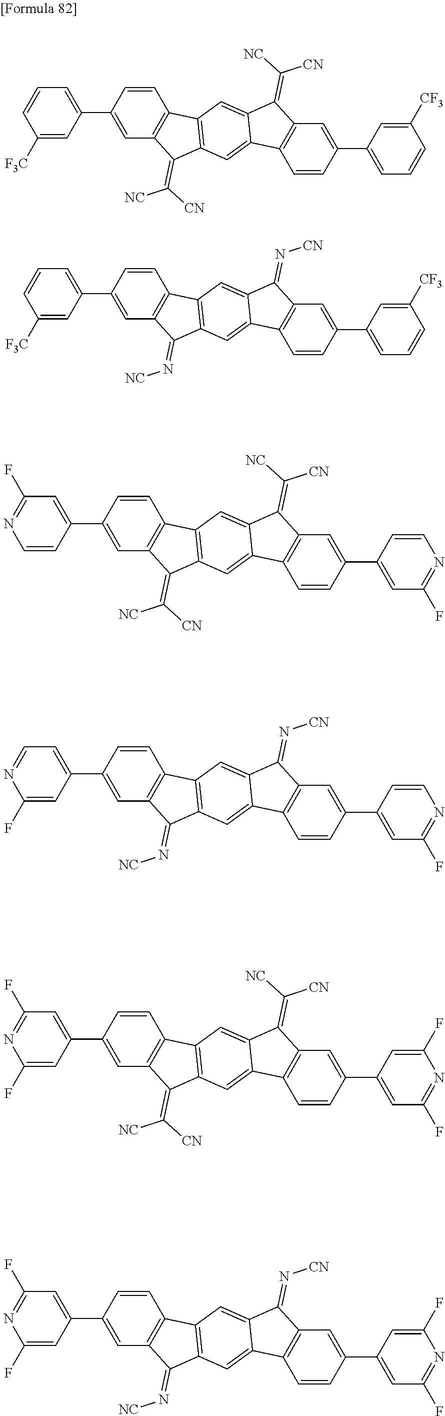

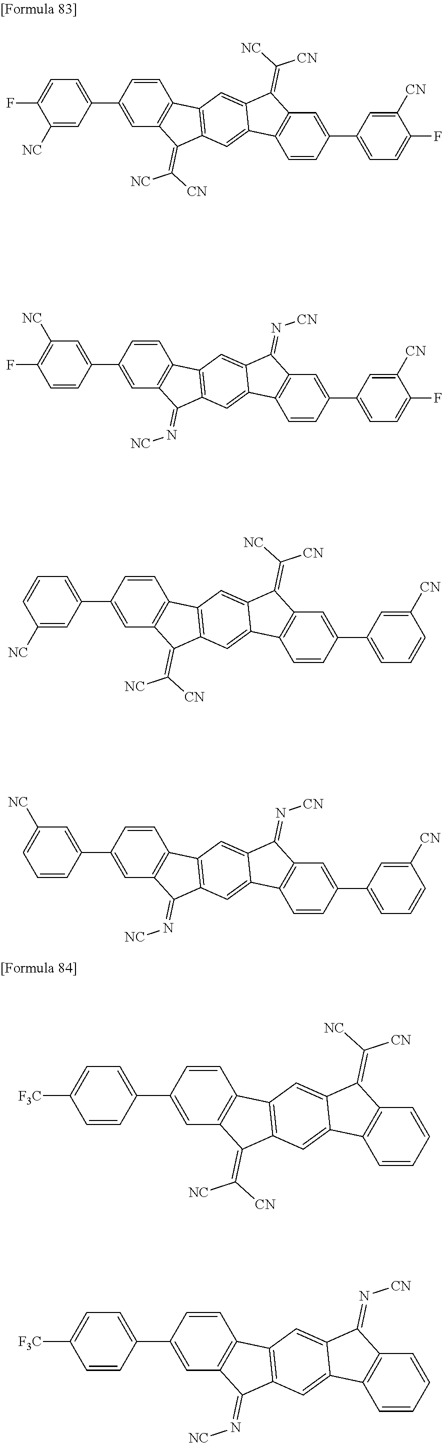 [SMILES: N#CC(C#N)=C1c2cc(-c3ccc(F)c(C#N)c3)ccc2-c2cc3c(cc21)-c1ccc(-c2ccc(F)c(C#N)c2)cc1C3=C(C#N)C#N ; N#C/N=c1\c2cc(-c3ccc(F)c(C#N)c3)ccc2c2cc3/c(=N/C#N)c4cc(-c5ccc(F)c(C#N)c5)ccc4c3cc12 ; N#CC(C#N)=C1c2cc(-c3cccc(C#N)c3)ccc2-c2cc3c(cc21)-c1ccc(-c2cccc(C#N)c2)cc1C3=C(C#N)C#N ; N#C/N=c1\c2cc(-c3cccc(C#N)c3)ccc2c2cc3/c(=N/C#N)c4cc(-c5cccc(C#N)c5)ccc4c3cc12 ; N#CC(C#N)=C1c2ccccc2-c2cc3c(cc21)-c1ccc(-c2ccc(C(F)(F)F)cc2)cc1C3=C(C#N)C#N ; N#C/N=c1\c2ccccc2c2cc3/c(=N/C#N)c4cc(-c5ccc(C(F)(F)F)cc5)ccc4c3cc12]

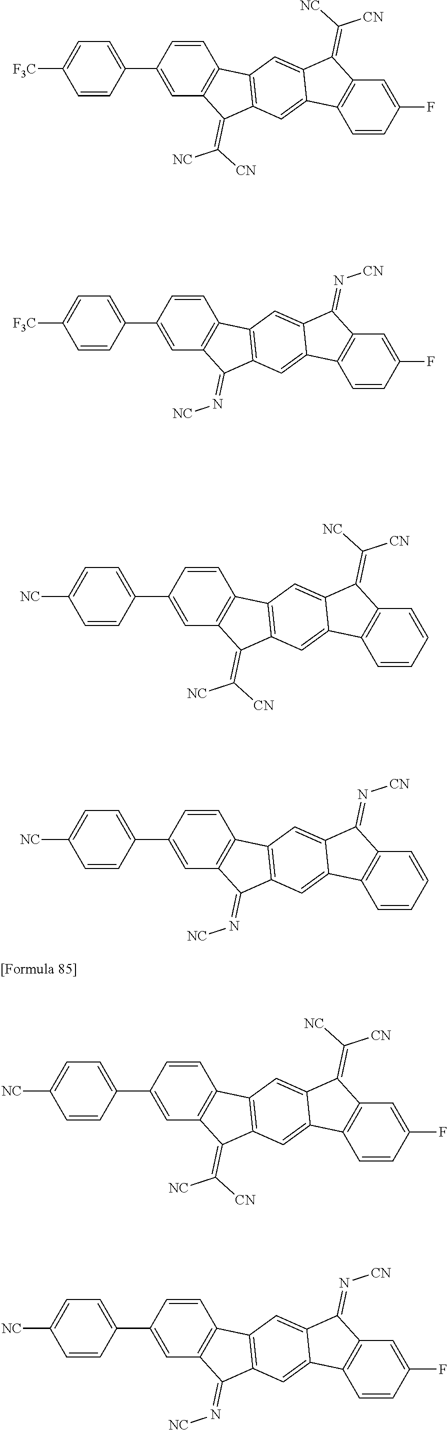 [SMILES: N#CC(C#N)=C1c2cc(F)ccc2-c2cc3c(cc21)-c1ccc(-c2ccc(C(F)(F)F)cc2)cc1C3=C(C#N)C#N ; N#C/N=c1\c2cc(F)ccc2c2cc3/c(=N/C#N)c4cc(-c5ccc(C(F)(F)F)cc5)ccc4c3cc12 ; N#CC(C#N)=C1c2ccccc2-c2cc3c(cc21)-c1ccc(-c2ccc(C#N)cc2)cc1C3=C(C#N)C#N ; N#C/N=c1\c2ccccc2c2cc3/c(=N/C#N)c4cc(-c5ccc(C#N)cc5)ccc4c3cc12 ; N#CC(C#N)=C1c2cc(F)ccc2-c2cc3c(cc21)-c1ccc(-c2ccc(C#N)cc2)cc1C3=C(C#N)C#N ; N#C/N=c1\c2cc(F)ccc2c2cc3/c(=N/C#N)c4cc(-c5ccc(C#N)cc5)ccc4c3cc12]

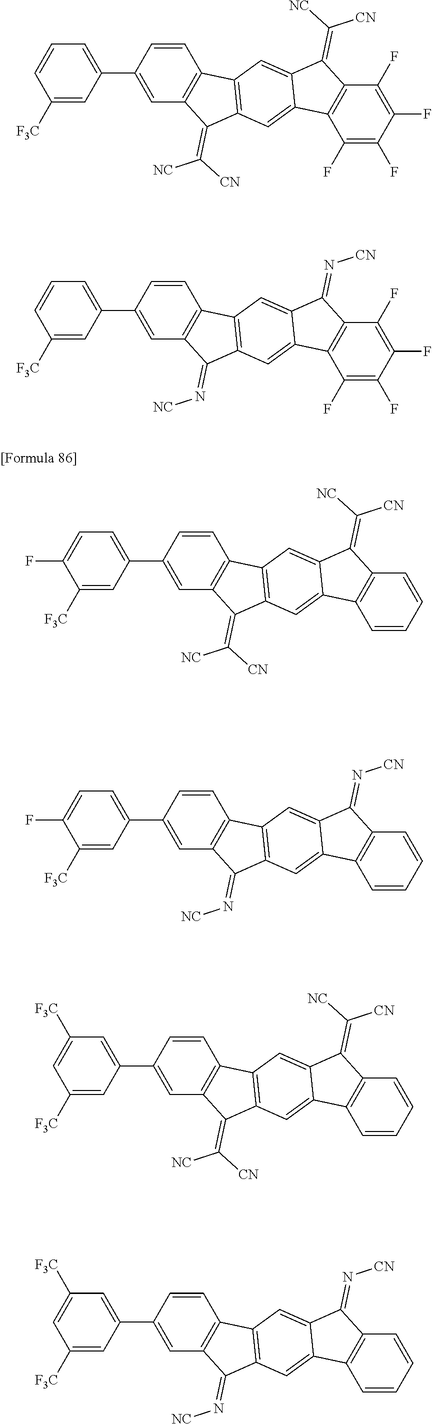 [SMILES: N#CC(C#N)=C1c2cc(-c3cccc(C(F)(F)F)c3)ccc2-c2cc3c(cc21)-c1c(F)c(F)c(F)c(F)c1C3=C(C#N)C#N ; N#C/N=c1/c2cc3c(cc2c2c(F)c(F)c(F)c(F)c12)/c(=N/C#N)c1cc(-c2cccc(C(F)(F)F)c2)ccc13 ; N#CC(C#N)=C1c2ccccc2-c2cc3c(cc21)-c1ccc(-c2ccc(F)c(C(F)(F)F)c2)cc1C3=C(C#N)C#N ; N#C/N=c1\c2ccccc2c2cc3/c(=N/C#N)c4cc(-c5ccc(F)c(C(F)(F)F)c5)ccc4c3cc12 ; N#CC(C#N)=C1c2ccccc2-c2cc3c(cc21)-c1ccc(-c2cc(C(F)(F)F)cc(C(F)(F)F)c2)cc1C3=C(C#N)C#N ; N#C/N=c1\c2ccccc2c2cc3/c(=N/C#N)c4cc(-c5cc(C(F)(F)F)cc(C(F)(F)F)c5)ccc4c3cc12]

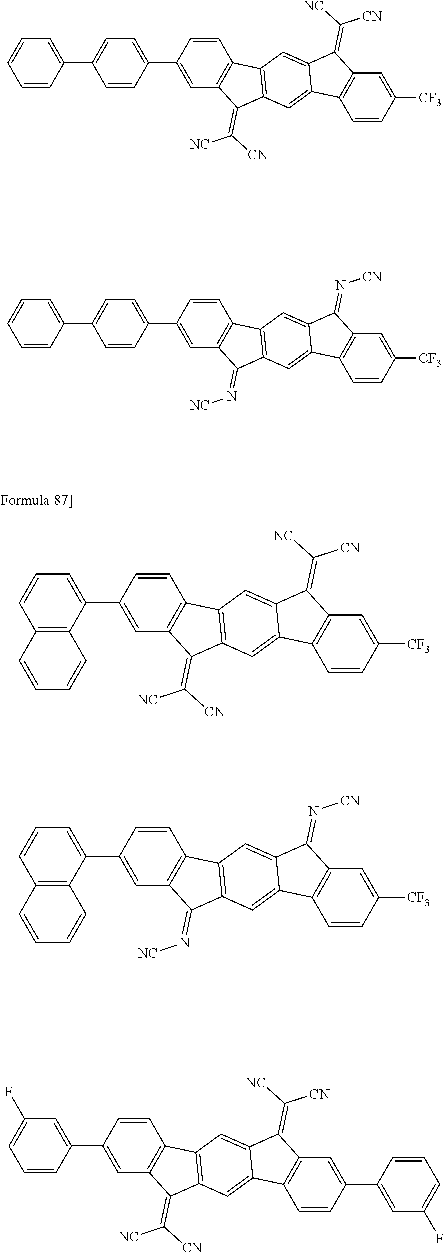 [SMILES: N#CC(C#N)=C1c2cc(-c3ccc(-c4ccccc4)cc3)ccc2-c2cc3c(cc21)-c1ccc(C(F)(F)F)cc1C3=C(C#N)C#N ; N#C/N=c1\c2cc(-c3ccc(-c4ccccc4)cc3)ccc2c2cc3/c(=N/C#N)c4cc(C(F)(F)F)ccc4c3cc12 ; N#CC(C#N)=C1c2cc(-c3cccc4ccccc34)ccc2-c2cc3c(cc21)-c1ccc(C(F)(F)F)cc1C3=C(C#N)C#N ; N#C/N=c1\c2cc(-c3cccc4ccccc34)ccc2c2cc3/c(=N/C#N)c4cc(C(F)(F)F)ccc4c3cc12 ; N#CC(C#N)=C1c2cc(-c3cccc(F)c3)ccc2-c2cc3c(cc21)-c1ccc(-c2cccc(F)c2)cc1C3=C(C#N)C#N]

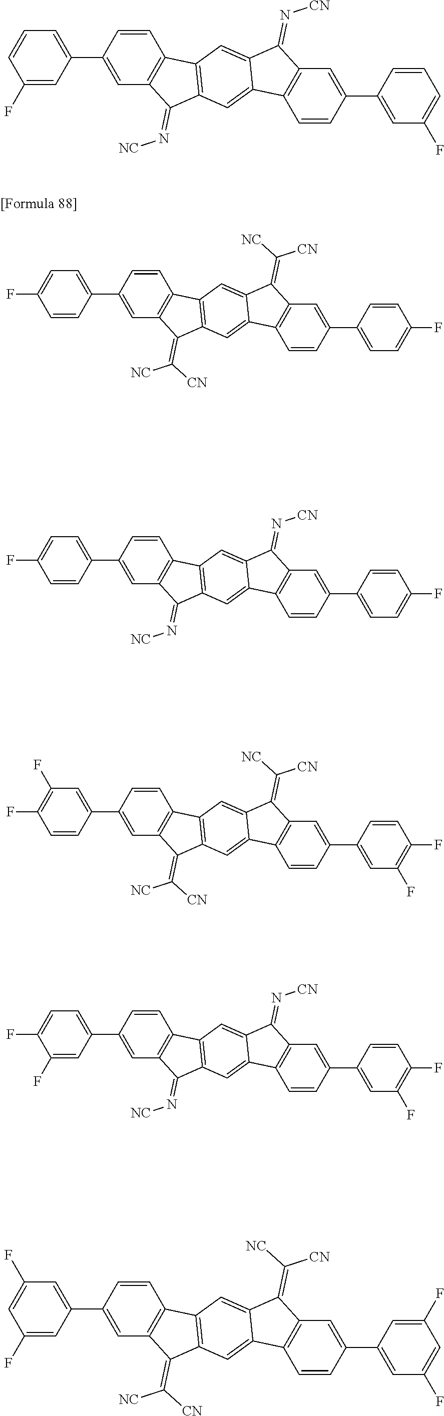

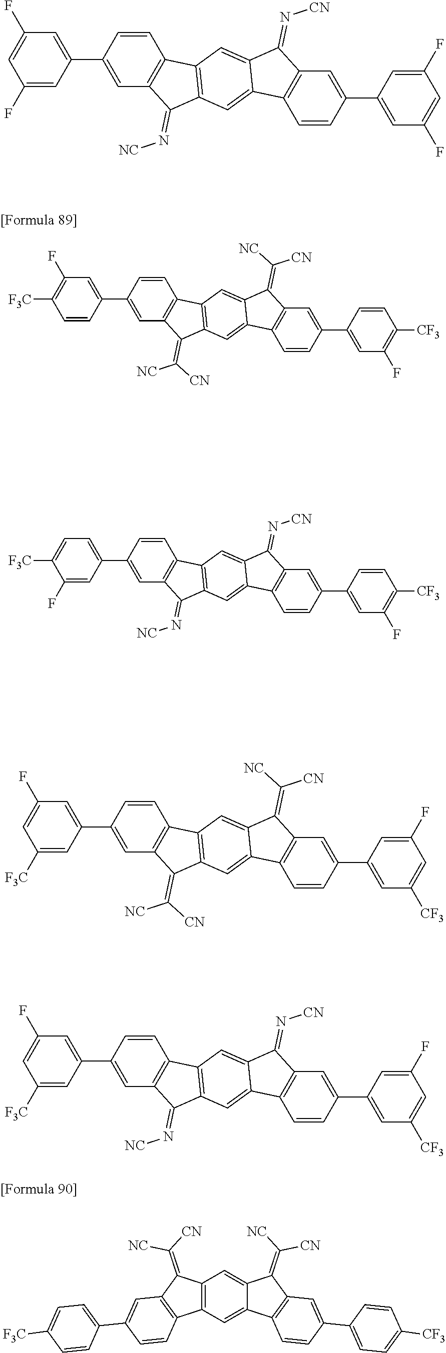

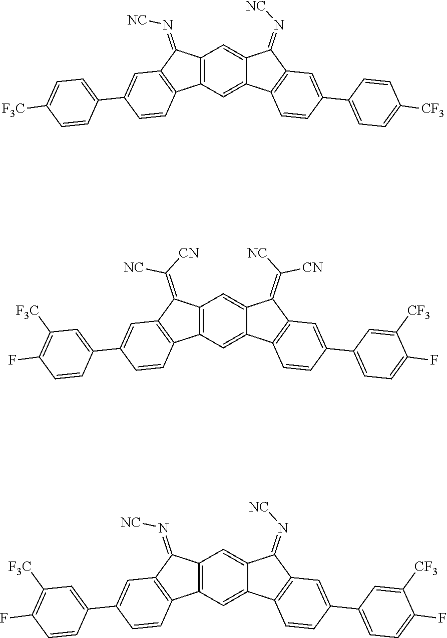 [SMILES: N#C/N=c1/c2cc(-c3ccc(C(F)(F)F)cc3)ccc2c2cc3c(cc12)/c(=N/C#N)c1cc(-c2ccc(C(F)(F)F)cc2)ccc13 ; N#CC(C#N)=C1c2cc(-c3ccc(F)c(C(F)(F)F)c3)ccc2-c2cc3c(cc21)C(=C(C#N)C#N)c1cc(-c2ccc(F)c(C(F)(F)F)c2)ccc1-3 ; N#C/N=c1/c2cc(-c3ccc(F)c(C(F)(F)F)c3)ccc2c2cc3c(cc12)/c(=N/C#N)c1cc(-c2ccc(F)c(C(F)(F)F)c2)ccc13]

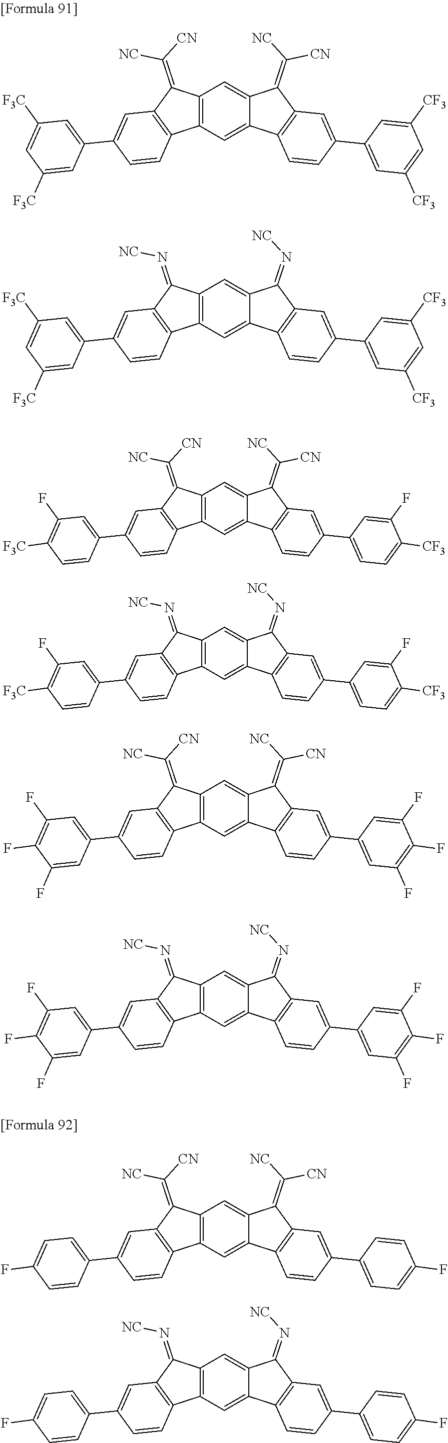

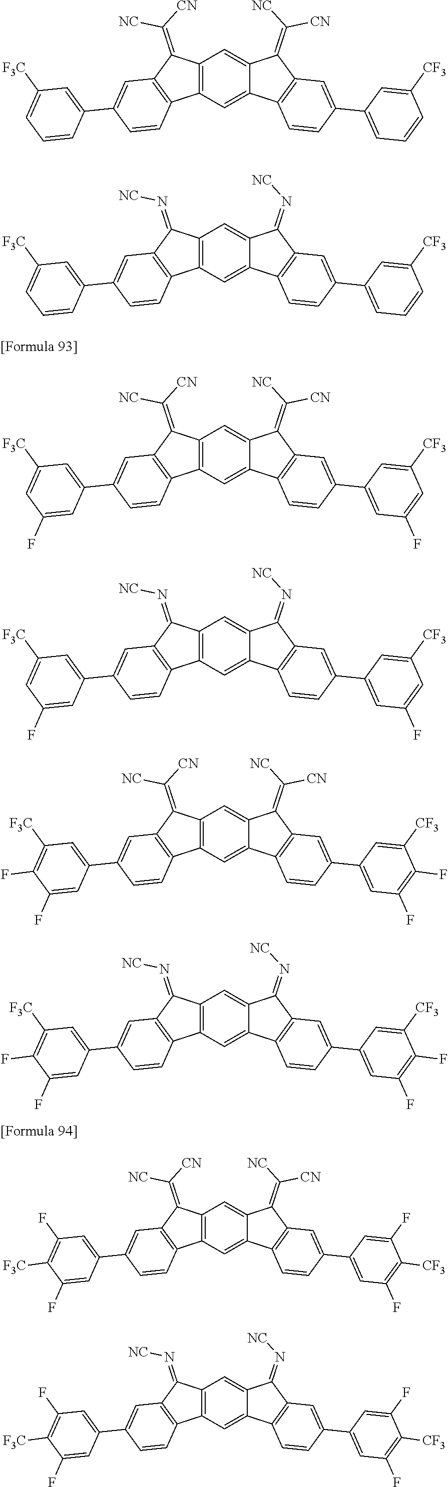

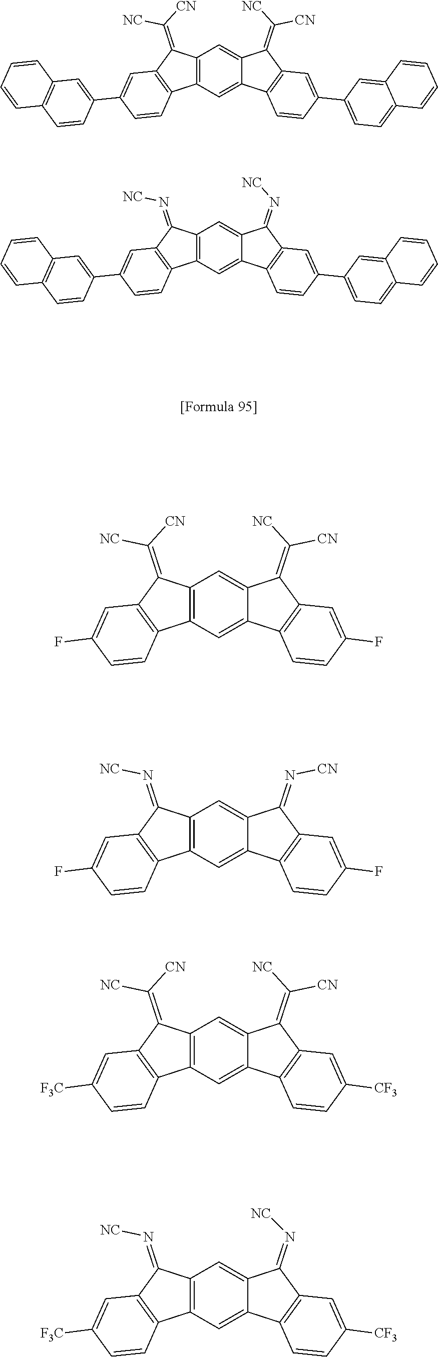 [SMILES: N#CC(C#N)=C1c2cc(-c3ccc4ccccc4c3)ccc2-c2cc3c(cc21)C(=C(C#N)C#N)c1cc(-c2ccc4ccccc4c2)ccc1-3 ; N#C/N=c1/c2cc(-c3ccc4ccccc4c3)ccc2c2cc3c(cc12)/c(=N/C#N)c1cc(-c2ccc4ccccc4c2)ccc13 ; N#CC(C#N)=C1c2cc(F)ccc2-c2cc3c(cc21)C(=C(C#N)C#N)c1cc(F)ccc1-3 ; N#C/N=c1\c2cc(F)ccc2c2cc3c(cc12)/c(=N/C#N)c1cc(F)ccc13 ; N#CC(C#N)=C1c2cc(C(F)(F)F)ccc2-c2cc3c(cc21)C(=C(C#N)C#N)c1cc(C(F)(F)F)ccc1-3 ; N#C/N=c1/c2cc(C(F)(F)F)ccc2c2cc3c(cc12)/c(=N/C#N)c1cc(C(F)(F)F)ccc13]

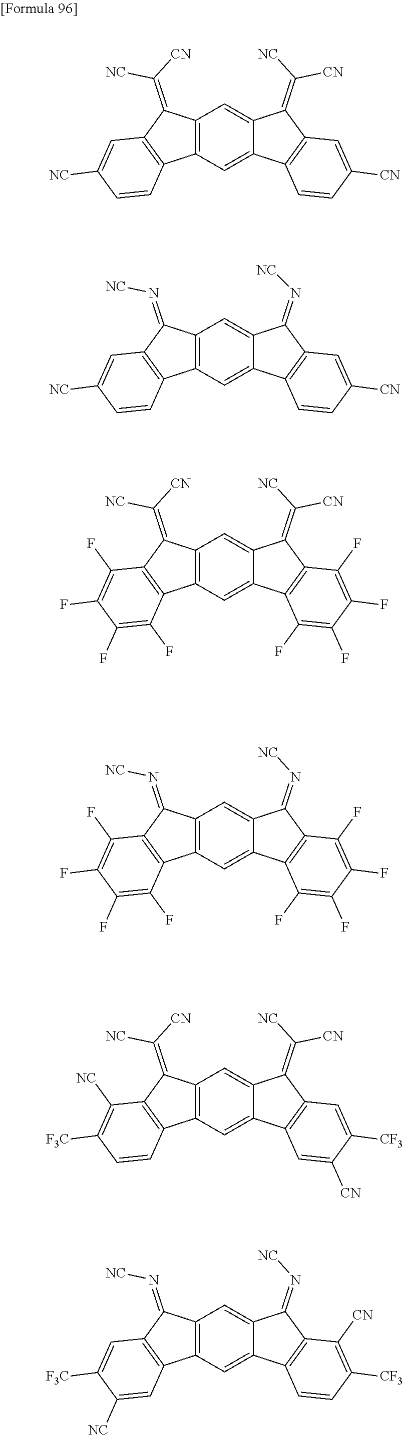 [SMILES: N#CC(C#N)=C1c2cc(C#N)ccc2-c2cc3c(cc21)C(=C(C#N)C#N)c1cc(C#N)ccc1-3 ; N#C/N=c1/c2cc(C#N)ccc2c2cc3c(cc12)/c(=N/C#N)c1cc(C#N)ccc13 ; N#CC(C#N)=C1c2cc3c(cc2-c2c(F)c(F)c(F)c(F)c21)-c1c(F)c(F)c(F)c(F)c1C3=C(C#N)C#N ; N#C/N=c1/c2cc3/c(=N\C#N)c4c(F)c(F)c(F)c(F)c4c3cc2c2c(F)c(F)c(F)c(F)c12 ; N#CC(C#N)=C1c2cc(C(F)(F)F)c(C#N)cc2-c2cc3c(cc21)C(=C(C#N)C#N)c1c-3ccc(C(F)(F)F)c1C#N ; N#C/N=c1\c2cc(C(F)(F)F)c(C#N)cc2c2cc3c(cc12)/c(=N\C#N)c1c(C#N)c(C(F)(F)F)ccc13]

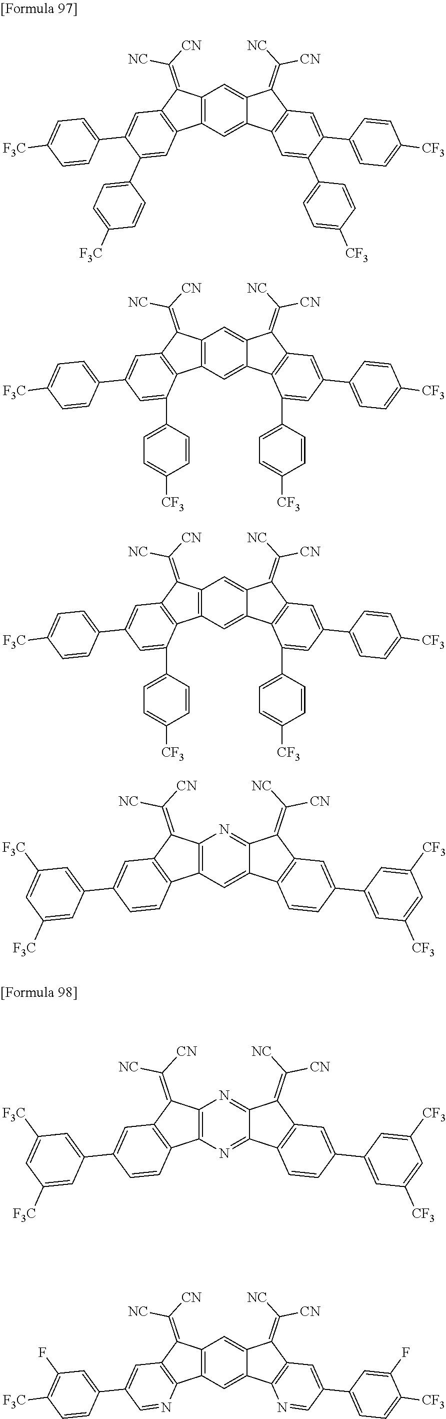

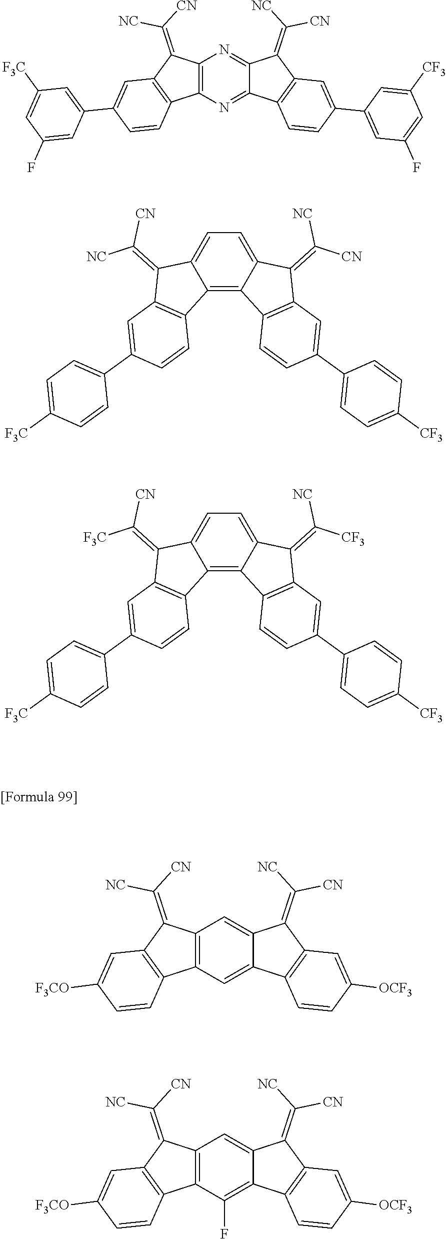 [SMILES: N#CC(C#N)=C1c2cc(-c3cc(F)cc(C(F)(F)F)c3)ccc2-c2nc3c(nc21)C(=C(C#N)C#N)c1cc(-c2cc(F)cc(C(F)(F)F)c2)ccc1-3 ; N#CC(C#N)=C1c2cc(-c3ccc(C(F)(F)F)cc3)ccc2-c2c1ccc1c2-c2ccc(-c3ccc(C(F)(F)F)cc3)cc2C1=C(C#N)C#N ; N#C/C(=C1/c2cc(-c3ccc(C(F)(F)F)cc3)ccc2-c2c1ccc1c2-c2ccc(-c3ccc(C(F)(F)F)cc3)cc2/C1=C(/C#N)C(F)(F)F)C(F)(F)F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(OC(F)(F)F)ccc2-c2c1cc1c(c2F)-c2ccc(OC(F)(F)F)cc2C1=C(C#N)C#N]

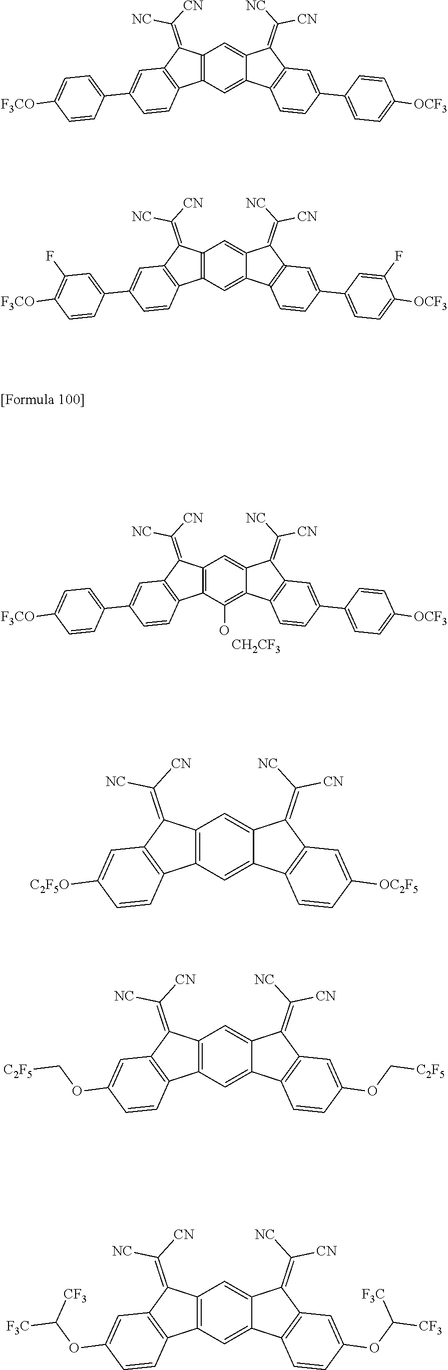

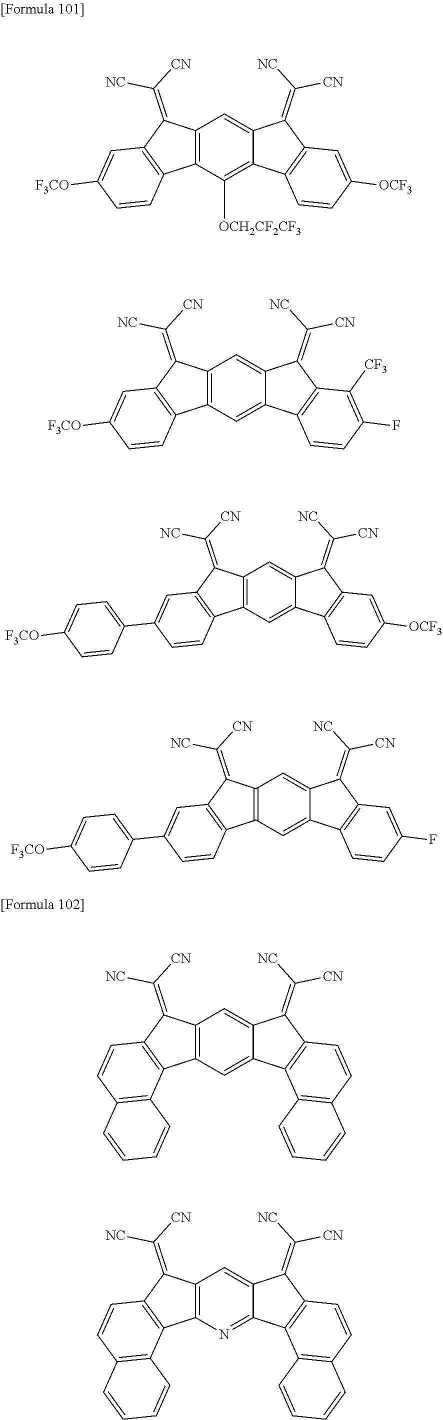

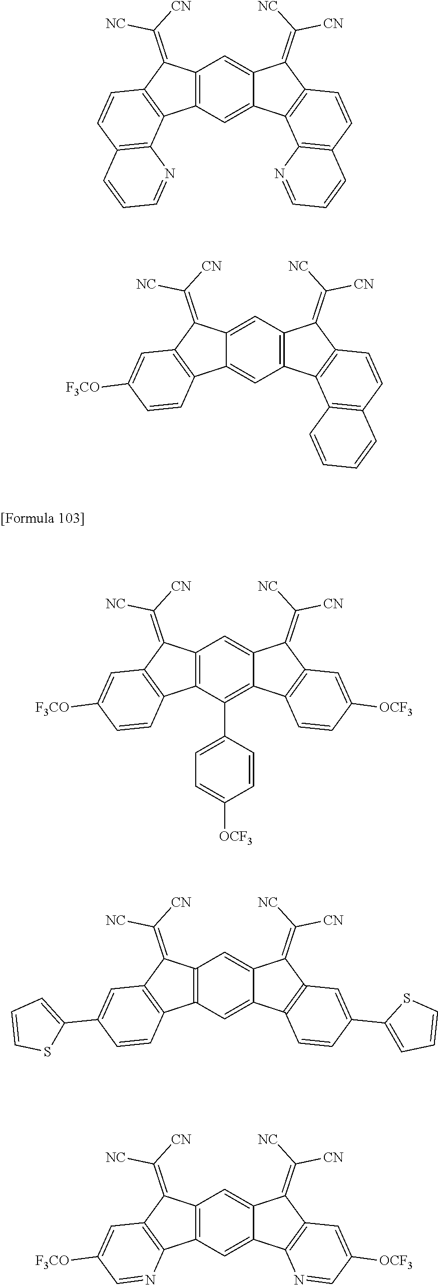 [SMILES: N#CC(C#N)=C1c2cc3c(cc2-c2c1ccc1cccnc21)-c1c(ccc2cccnc12)C3=C(C#N)C#N ; N#CC(C#N)=C1c2cc(OC(F)(F)F)ccc2-c2cc3c(cc21)C(=C(C#N)C#N)c1ccc2ccccc2c1-3 ; N#CC(C#N)=C1c2cc(OC(F)(F)F)ccc2-c2c1cc1c(c2-c2ccc(OC(F)(F)F)cc2)-c2ccc(OC(F)(F)F)cc2C1=C(C#N)C#N ; N#CC(C#N)=C1c2cc(-c3cccs3)ccc2-c2cc3c(cc21)C(=C(C#N)C#N)c1cc(-c2cccs2)ccc1-3 ; N#CC(C#N)=C1c2cc3c(cc2-c2ncc(OC(F)(F)F)cc21)-c1ncc(OC(F)(F)F)cc1C3=C(C#N)C#N]

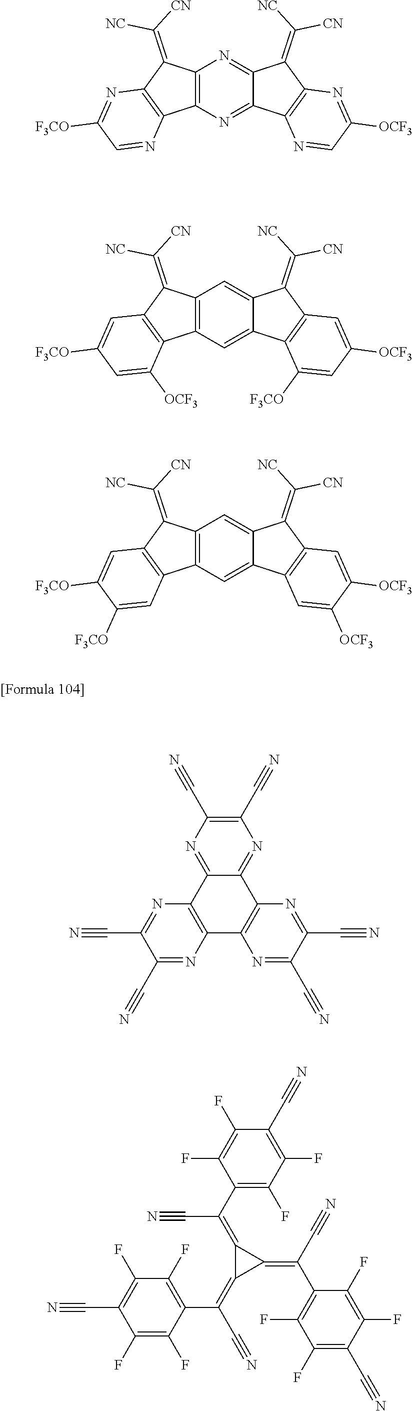 [SMILES: N#CC(C#N)=C1c2nc(OC(F)(F)F)cnc2-c2nc3c(nc21)C(=C(C#N)C#N)c1nc(OC(F)(F)F)cnc1-3 ; N#CC(C#N)=C1c2cc3c(cc2-c2c(OC(F)(F)F)cc(OC(F)(F)F)cc21)-c1c(OC(F)(F)F)cc(OC(F)(F)F)cc1C3=C(C#N)C#N ; N#CC(C#N)=C1c2cc(OC(F)(F)F)c(OC(F)(F)F)cc2-c2cc3c(cc21)C(=C(C#N)C#N)c1cc(OC(F)(F)F)c(OC(F)(F)F)cc1-3 ; N#Cc1nc2c3nc(C#N)c(C#N)nc3c3nc(C#N)c(C#N)nc3c2nc1C#N ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

In an exemplary arrangement of the organic EL device of the exemplary embodiment, the third anode side organic layer is in direct contact with the emitting region.

In an exemplary arrangement of the organic EL device of the exemplary embodiment, the second anode side organic layer is in direct contact with the third anode side organic layer.

In an exemplary arrangement of the organic EL device of the exemplary embodiment, the anode is in direct contact with the first anode side organic layer.

In an exemplary arrangement of the organic EL device of the exemplary embodiment, the organic EL device further includes the fourth anode side organic layer disposed between the third anode side organic layer and the emitting region.

In an exemplary arrangement of the organic EL device of the exemplary embodiment, the fourth anode side organic layer is in direct contact with the emitting region.

In an exemplary arrangement of the organic EL device of the exemplary embodiment, the fourth anode side organic layer is in direct contact with the third anode side organic layer.

In an exemplary arrangement of the organic EL device of the exemplary embodiment, the first anode side organic layer, the second anode side organic layer, the third anode side organic layer, and the fourth anode side organic layer are arranged in this order from a side close to the anode.

In an exemplary arrangement of the organic EL device of the exemplary embodiment, the fourth anode side organic layer is a blocking layer. For instance, when the blocking layer is disposed close to the anode with respect to the emitting layer, the blocking layer permits transport of holes and blocks electrons from reaching each organic layer in the hole transporting zone provided closer to the anode beyond the blocking layer. Alternatively, the blocking layer may be provided in direct contact with the emitting layer so that excitation energy does not leak out from the emitting layer toward neighboring layer(s). The blocking layer disposed close to the anode with respect to the emitting layer blocks excitons generated in the emitting layer from transferring to each organic layer in the hole transporting zone. The emitting layer is preferably in direct contact with the blocking layer.

In an exemplary arrangement of the organic EL device of the exemplary embodiment, the fourth anode side organic layer is thinner than the third anode side organic layer.

In an exemplary arrangement of the organic EL device of the exemplary embodiment, the fourth anode side organic layer has a film thickness of 20 nm or less.

In an exemplary arrangement of the organic EL device of the exemplary embodiment, the fourth anode side organic layer has a film thickness of 5 nm or more.

Presumably, the organic EL device according to the exemplary embodiment has a long lifetime by being provided with the fourth anode side organic layer (preferably an electron blocking layer) smaller in film thickness than that of the third anode side organic layer.

In an exemplary arrangement of the organic EL device of the exemplary embodiment, the total of the film thickness of the first anode side organic layer, the film thickness of the second anode side organic layer, the film thickness of the third anode side organic layer, and the film thickness of the fourth anode side organic layer is 150 nm or less.

In an exemplary arrangement of the organic EL device of the exemplary embodiment, the fourth anode side organic layer contains a fourth hole transporting zone material. The compound(s) contained in the fourth anode side organic layer is/are occasionally referred to as the fourth hole transporting zone material.

In an exemplary arrangement of the organic EL device of the exemplary embodiment, the fourth hole transporting zone material and the third hole transporting zone material are different compounds.

In an exemplary arrangement of the organic EL device of the exemplary embodiment, the fourth hole transporting zone material, the third hole transporting zone material, and the second hole transporting zone material are different compounds.

In an exemplary arrangement of the organic EL device of the exemplary embodiment, the fourth anode side organic layer contains a compound represented by the formula (C1) or a compound represented by the formula (C2).

In an exemplary arrangement of the organic EL device of the exemplary embodiment, although the third anode side organic layer and the fourth anode side organic layer may each contain a compound represented by the formula (C1), the compound contained in the third anode side organic layer and the compound contained in the fourth anode side organic layer are mutually different in a molecular structure.

In an exemplary arrangement of the organic EL device of the exemplary embodiment, the fourth hole transporting zone material is a monoamine compound, a diamine compound, a triamine compound, or a tetraamine compound.

In an exemplary arrangement of the organic EL device of the exemplary embodiment, the fourth hole transporting zone material is at least one compound selected from the group consisting of a compound represented by the formula (cHT3-1), a compound represented by the formula (cHT3-2), a compound represented by the formula (cHT3-3), and a compound represented by the formula (cHT3-4).

In an exemplary arrangement of the organic EL device of the exemplary embodiment, the first anode side organic layer, the second anode side organic layer, the third anode side organic layer, and the fourth anode side organic layer each contain at least one compound, the compounds respectively contained in the first, second, third, and fourth anode side organic layers being different from each other.

In an exemplary arrangement of the organic EL device of the exemplary embodiment, the first anode side organic layer, the second anode side organic layer, the third anode side organic layer, and the fourth anode side organic layer each contain a monoamine compound having only one substituted or unsubstituted amino group in a molecule.

In an exemplary arrangement of the organic EL device of the exemplary embodiment, the first anode side organic layer, the second anode side organic layer, the third anode side organic layer, and the fourth anode side organic layer contain no diamine compound. The diamine compound has two substituted or unsubstituted amino groups in a molecule.

The compound represented by the formula (C1) is preferably a monoamine compound.

In an exemplary arrangement of the organic EL device of the exemplary embodiment, at least one of the first anode side organic layer, the second anode side organic layer, the third anode side organic layer, or the fourth anode side organic layer may also contain a diamine compound. The compound represented by the formula (C2) is preferably a diamine compound.

In the organic EL device according to the exemplary embodiment, R₉₀₁, R₉₀₂, R₉₀₃, and R₉₀₄ in the compounds contained in the hole transporting zone are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

In the exemplary embodiment, all groups specified as “substituted or unsubstituted” groups are preferably “unsubstituted” groups.

In the exemplary embodiment, the first hole transporting zone material, the second hole transporting zone material, the third hole transporting zone material, and the fourth hole transporting zone material each may be occasionally referred to as a hole transporting zone material.

In the organic EL device according to the exemplary embodiment, the hole transporting zone material may be a compound that contains a substituted or unsubstituted 3-carbazolyl group in a molecule. In the organic EL device according to the exemplary embodiment, the hole transporting zone material may be a compound that does not contain a substituted or unsubstituted 3-carbazolyl group in a molecule.

### Method of Producing Hole Transporting Zone Material

The hole transporting zone material according to the exemplary embodiment can be produced by a known method or through a known alternative reaction using a known material(s) tailored for the target compound in accordance with the known method.

### Specific Examples of Hole Transporting Zone Material

Specific examples of the hole transporting zone material according to the exemplary embodiment include the following compounds. It should however be noted that the invention is not limited to the specific examples.

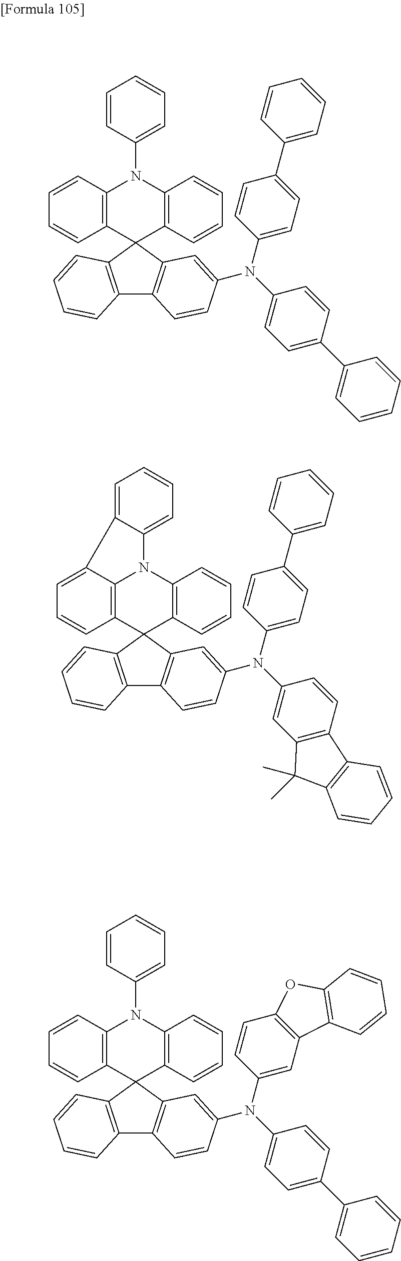 [SMILES: c1ccc(-c2ccc(N(c3ccc(-c4ccccc4)cc3)c3ccc4c(c3)C3(c5ccccc5-4)c4ccccc4N(c4ccccc4)c4ccccc43)cc2)cc1 ; CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; c1ccc(-c2ccc(N(c3ccc4c(c3)C3(c5ccccc5-4)c4ccccc4N(c4ccccc4)c4ccccc43)c3ccc4oc5ccccc5c4c3)cc2)cc1]

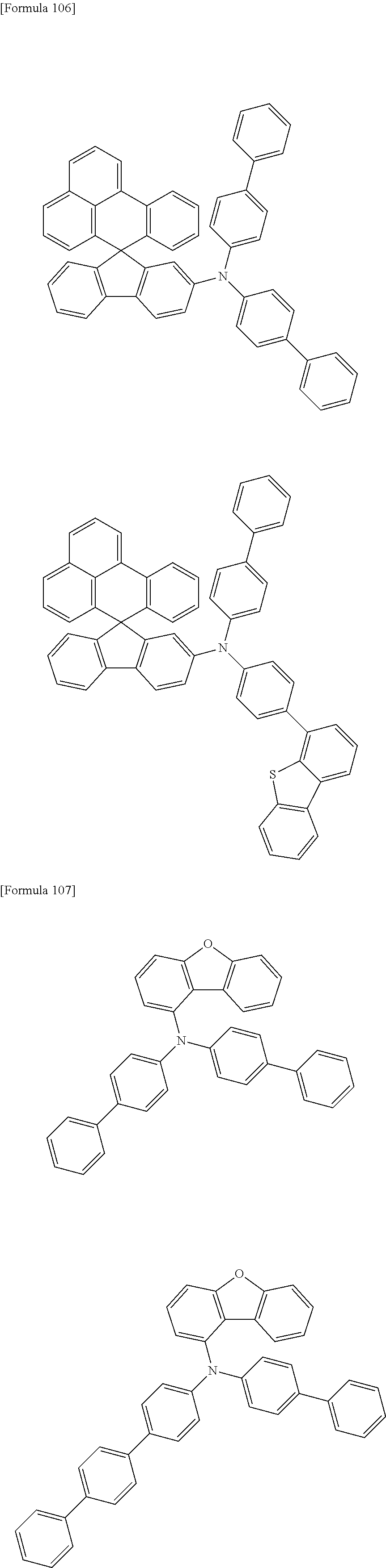 [SMILES: c1ccc(-c2ccc(N(c3ccc(-c4ccccc4)cc3)c3ccc4c(c3)C3(c5ccccc5-4)c4ccccc4-c4cccc5cccc3c45)cc2)cc1 ; c1ccc(-c2ccc(N(c3ccc(-c4cccc5c4sc4ccccc45)cc3)c3ccc4c(c3)C3(c5ccccc5-4)c4ccccc4-c4cccc5cccc3c45)cc2)cc1 ; c1ccc(-c2ccc(N(c3ccc(-c4ccccc4)cc3)c3cccc4oc5ccccc5c34)cc2)cc1 ; c1ccc(-c2ccc(-c3ccc(N(c4ccc(-c5ccccc5)cc4)c4cccc5oc6ccccc6c45)cc3)cc2)cc1]

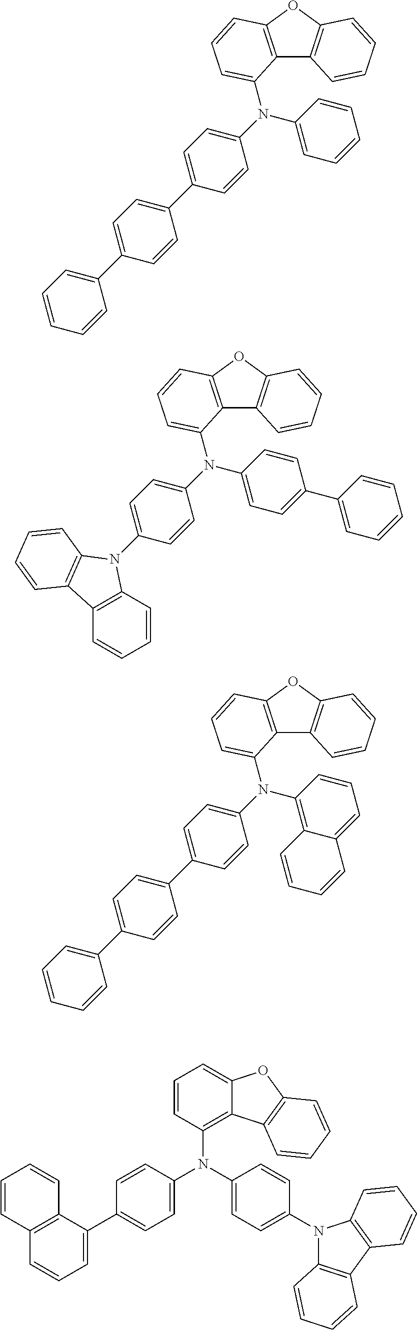 [SMILES: c1ccc(-c2ccc(-c3ccc(N(c4ccccc4)c4cccc5oc6ccccc6c45)cc3)cc2)cc1 ; c1ccc(-c2ccc(N(c3ccc(-n4c5ccccc5c5ccccc54)cc3)c3cccc4oc5ccccc5c34)cc2)cc1 ; c1ccc(-c2ccc(-c3ccc(N(c4cccc5ccccc45)c4cccc5oc6ccccc6c45)cc3)cc2)cc1 ; c1ccc2c(-c3ccc(N(c4ccc(-n5c6ccccc6c6ccccc65)cc4)c4cccc5oc6ccccc6c45)cc3)cccc2c1]

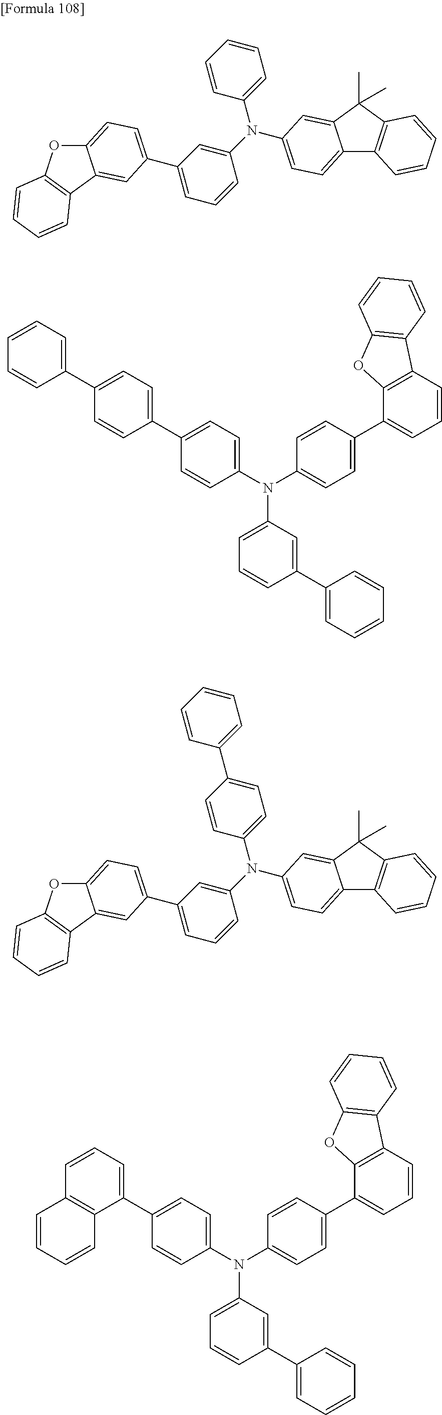 [SMILES: CC1(C)c2ccccc2-c2ccc(N(c3ccccc3)c3cccc(-c4ccc5oc6ccccc6c5c4)c3)cc21 ; c1ccc(-c2ccc(-c3ccc(N(c4ccc(-c5cccc6c5oc5ccccc56)cc4)c4cccc(-c5ccccc5)c4)cc3)cc2)cc1 ; CC1(C)c2ccccc2-c2ccc(N(c3ccc(-c4ccccc4)cc3)c3cccc(-c4ccc5oc6ccccc6c5c4)c3)cc21 ; c1ccc(-c2cccc(N(c3ccc(-c4cccc5ccccc45)cc3)c3ccc(-c4cccc5c4oc4ccccc45)cc3)c2)cc1]

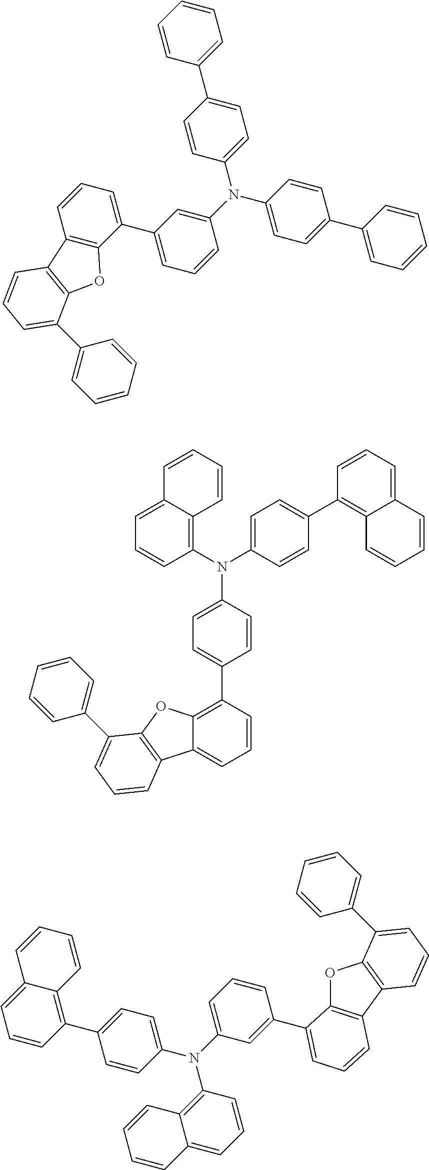 [SMILES: c1ccc(-c2ccc(N(c3ccc(-c4ccccc4)cc3)c3cccc(-c4cccc5c4oc4c(-c6ccccc6)cccc45)c3)cc2)cc1 ; c1ccc(-c2cccc3c2oc2c(-c4ccc(N(c5ccc(-c6cccc7ccccc67)cc5)c5cccc6ccccc56)cc4)cccc23)cc1 ; c1ccc(-c2cccc3c2oc2c(-c4cccc(N(c5ccc(-c6cccc7ccccc67)cc5)c5cccc6ccccc56)c4)cccc23)cc1]

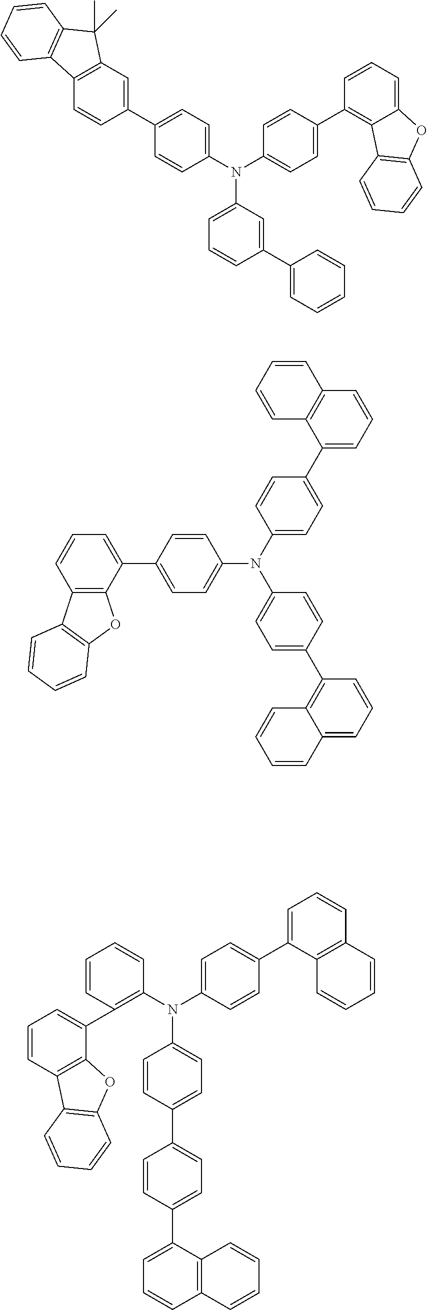 [SMILES: CC1(C)c2ccccc2-c2ccc(-c3ccc(N(c4ccc(-c5cccc6oc7ccccc7c56)cc4)c4cccc(-c5ccccc5)c4)cc3)cc21 ; c1ccc2c(-c3ccc(N(c4ccc(-c5cccc6ccccc56)cc4)c4ccc(-c5cccc6c5oc5ccccc56)cc4)cc3)cccc2c1 ; c1ccc(N(c2ccc(-c3ccc(-c4cccc5ccccc45)cc3)cc2)c2ccc(-c3cccc4ccccc34)cc2)c(-c2cccc3c2oc2ccccc23)c1]

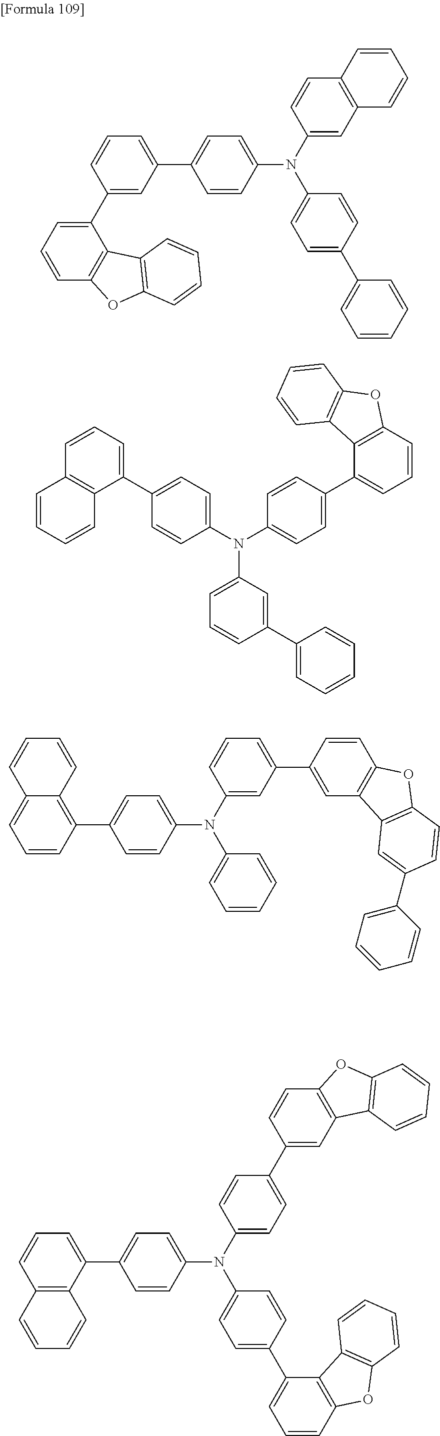

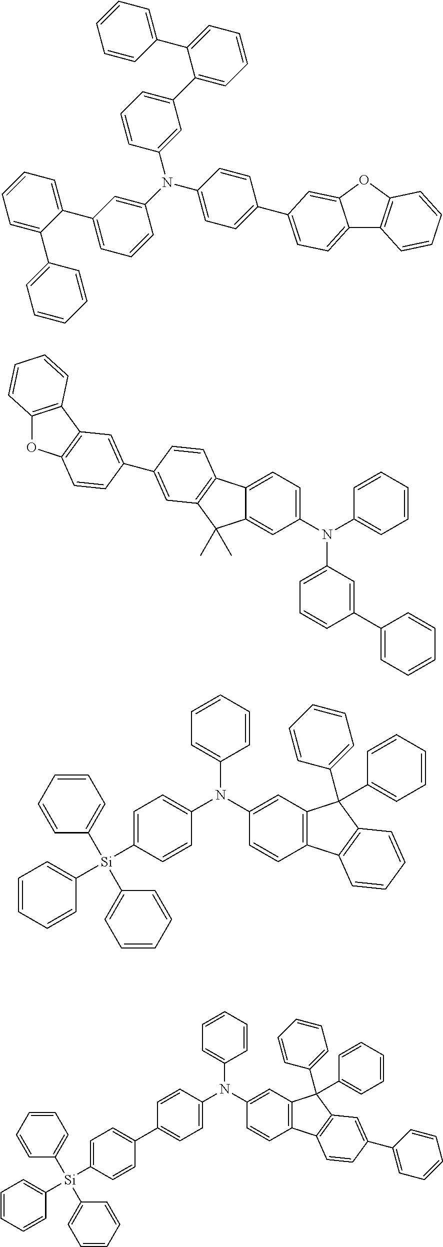

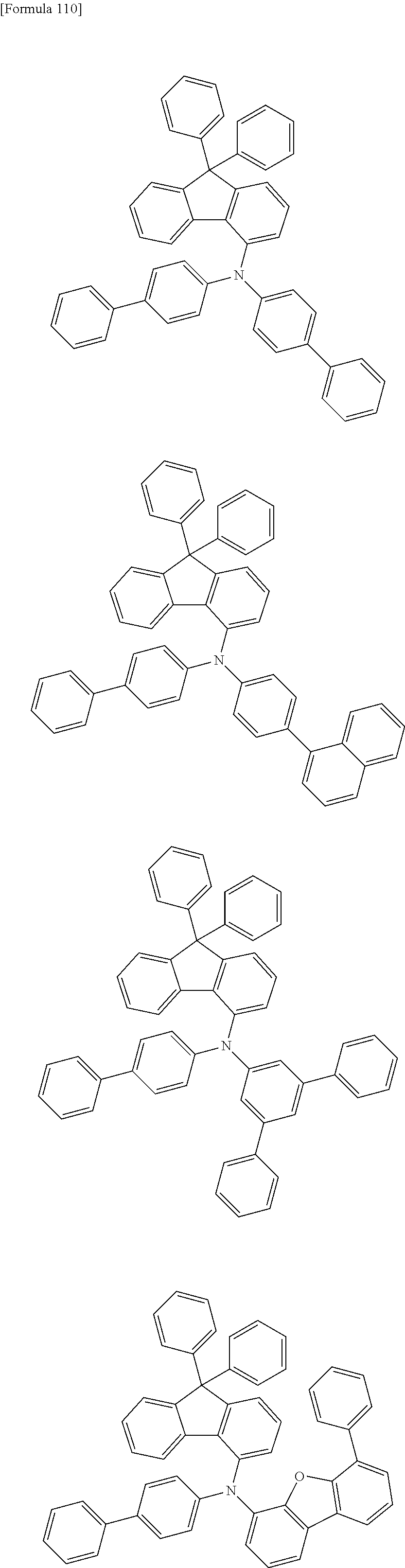 [SMILES: c1ccc(-c2ccc(N(c3ccc(-c4ccccc4)cc3)c3cccc4c3-c3ccccc3C4(c3ccccc3)c3ccccc3)cc2)cc1 ; c1ccc(-c2ccc(N(c3ccc(-c4cccc5ccccc45)cc3)c3cccc4c3-c3ccccc3C4(c3ccccc3)c3ccccc3)cc2)cc1 ; c1ccc(-c2ccc(N(c3cc(-c4ccccc4)cc(-c4ccccc4)c3)c3cccc4c3-c3ccccc3C4(c3ccccc3)c3ccccc3)cc2)cc1 ; c1ccc(-c2ccc(N(c3cccc4c3-c3ccccc3C4(c3ccccc3)c3ccccc3)c3cccc4c3oc3c(-c5ccccc5)cccc34)cc2)cc1]

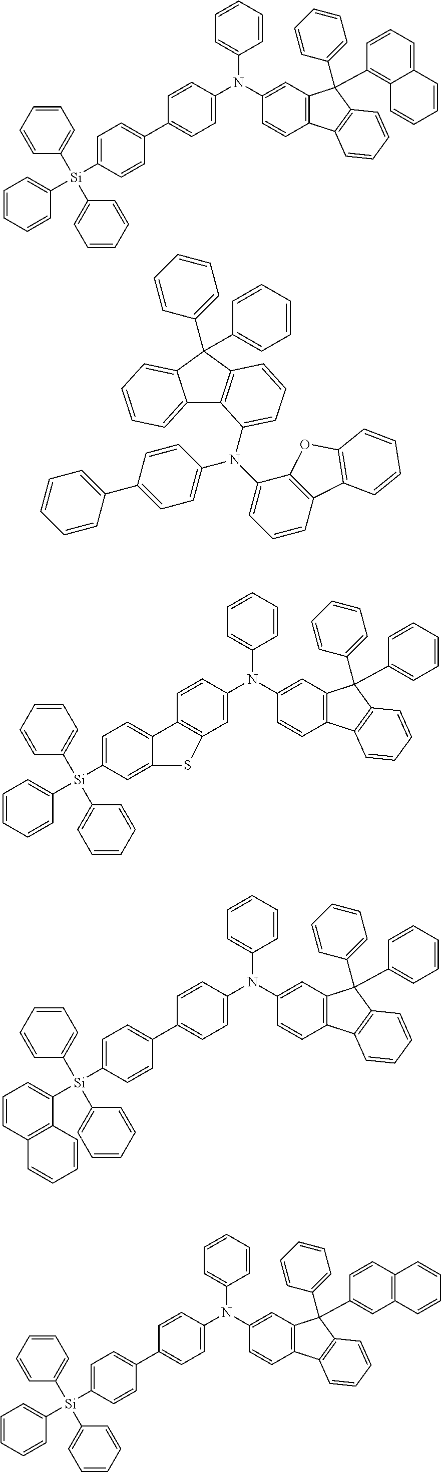

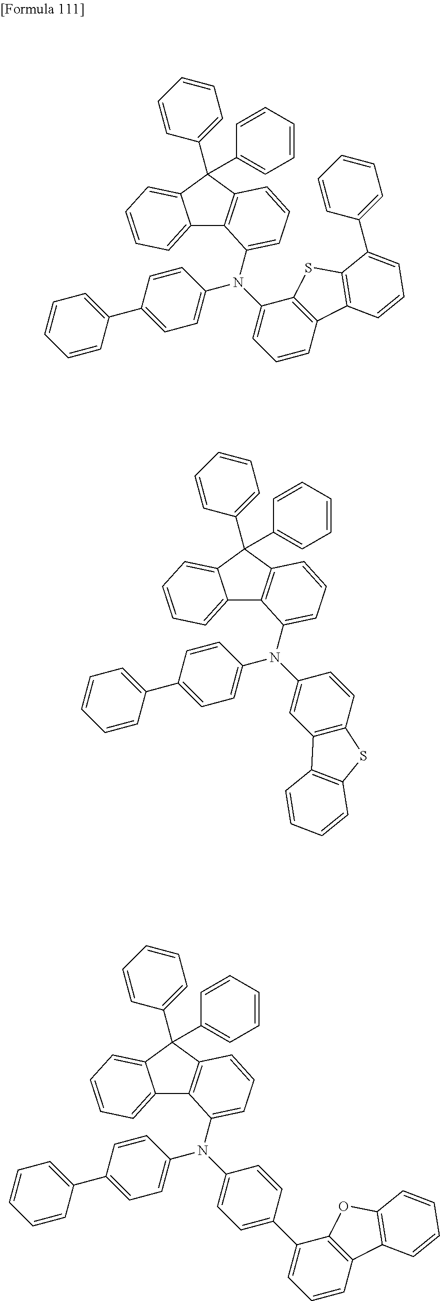 [SMILES: c1ccc(-c2ccc(N(c3cccc4c3-c3ccccc3C4(c3ccccc3)c3ccccc3)c3cccc4c3sc3c(-c5ccccc5)cccc34)cc2)cc1 ; c1ccc(-c2ccc(N(c3ccc4sc5ccccc5c4c3)c3cccc4c3-c3ccccc3C4(c3ccccc3)c3ccccc3)cc2)cc1 ; c1ccc(-c2ccc(N(c3ccc(-c4cccc5c4oc4ccccc45)cc3)c3cccc4c3-c3ccccc3C4(c3ccccc3)c3ccccc3)cc2)cc1]

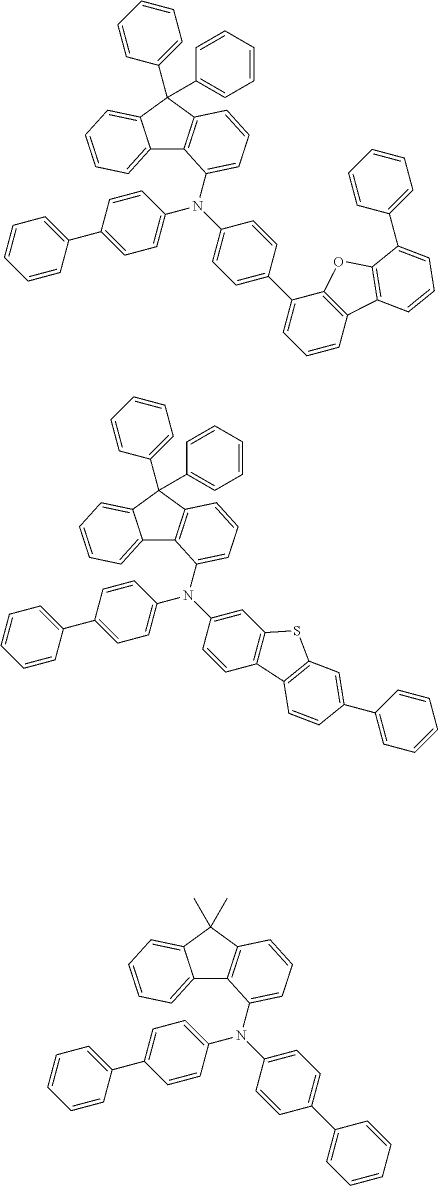 [SMILES: c1ccc(-c2ccc(N(c3ccc(-c4cccc5c4oc4c(-c6ccccc6)cccc45)cc3)c3cccc4c3-c3ccccc3C4(c3ccccc3)c3ccccc3)cc2)cc1 ; c1ccc(-c2ccc(N(c3ccc4c(c3)sc3cc(-c5ccccc5)ccc34)c3cccc4c3-c3ccccc3C4(c3ccccc3)c3ccccc3)cc2)cc1 ; CC1(C)c2ccccc2-c2c(N(c3ccc(-c4ccccc4)cc3)c3ccc(-c4ccccc4)cc3)cccc21]

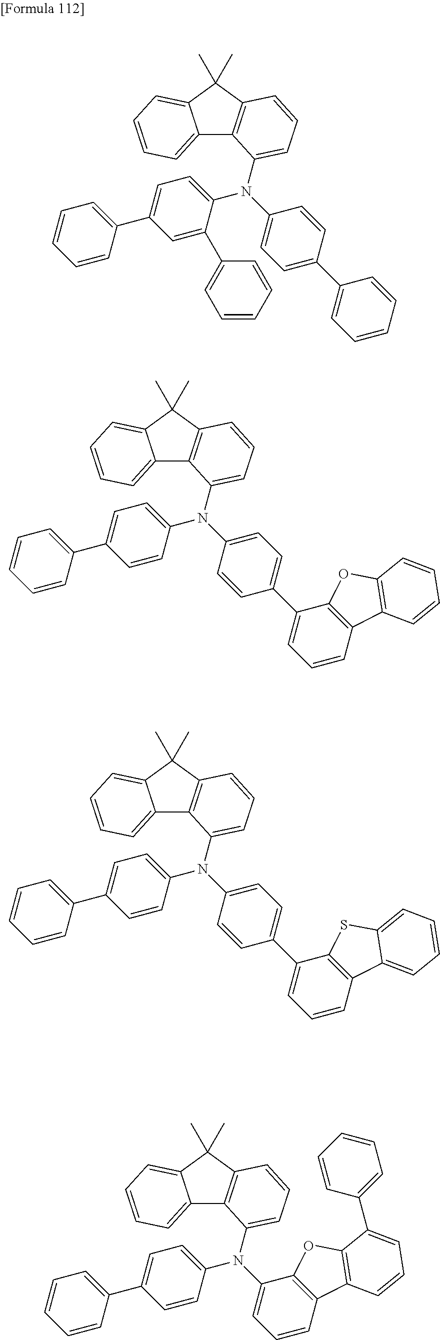 [SMILES: CC1(C)c2ccccc2-c2c(N(c3ccc(-c4ccccc4)cc3)c3ccc(-c4ccccc4)cc3-c3ccccc3)cccc21 ; CC1(C)c2ccccc2-c2c(N(c3ccc(-c4ccccc4)cc3)c3ccc(-c4cccc5c4oc4ccccc45)cc3)cccc21 ; CC1(C)c2ccccc2-c2c(N(c3ccc(-c4ccccc4)cc3)c3ccc(-c4cccc5c4sc4ccccc45)cc3)cccc21 ; CC1(C)c2ccccc2-c2c(N(c3ccc(-c4ccccc4)cc3)c3cccc4c3oc3c(-c5ccccc5)cccc34)cccc21]

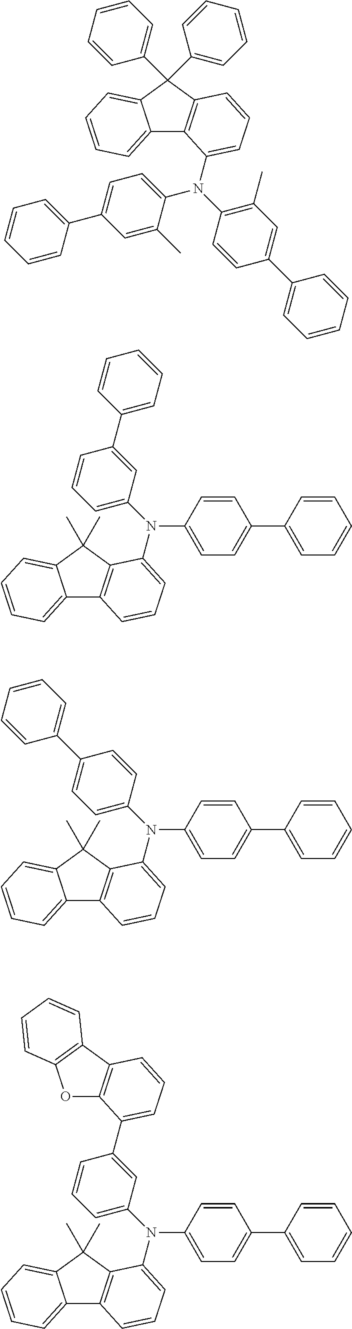 [SMILES: Cc1cc(-c2ccccc2)ccc1N(c1ccc(-c2ccccc2)cc1C)c1cccc2c1-c1ccccc1C2(c1ccccc1)c1ccccc1 ; CC1(C)c2ccccc2-c2cccc(N(c3ccc(-c4ccccc4)cc3)c3cccc(-c4ccccc4)c3)c21 ; CC1(C)c2ccccc2-c2cccc(N(c3ccc(-c4ccccc4)cc3)c3ccc(-c4ccccc4)cc3)c21 ; CC1(C)c2ccccc2-c2cccc(N(c3ccc(-c4ccccc4)cc3)c3cccc(-c4cccc5c4oc4ccccc45)c3)c21]

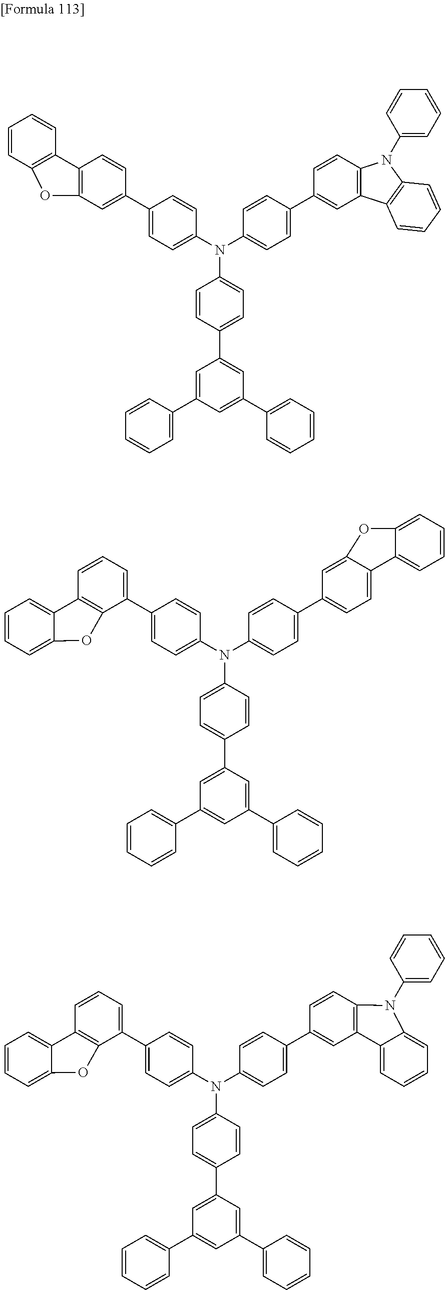 [SMILES: c1ccc(-c2cc(-c3ccccc3)cc(-c3ccc(N(c4ccc(-c5ccc6c(c5)oc5ccccc56)cc4)c4ccc(-c5ccc6c(c5)c5ccccc5n6-c5ccccc5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6c(c5)c5ccccc5n6-c5ccccc5)cc4)c4ccc(-c5cccc6c5oc5ccccc56)cc4)cc3)c2)cc1]

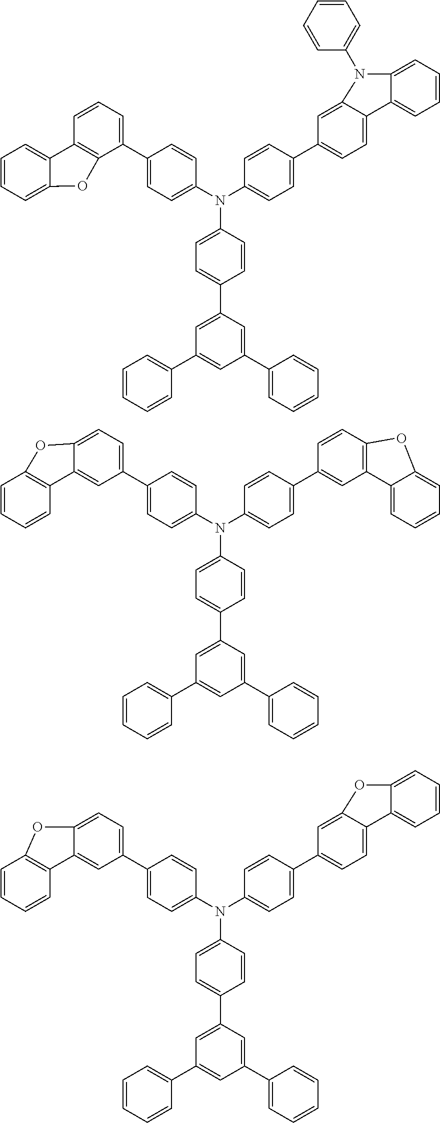 [SMILES: c1ccc(-c2cc(-c3ccccc3)cc(-c3ccc(N(c4ccc(-c5ccc6c7ccccc7n(-c7ccccc7)c6c5)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6oc7ccccc7c6c5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5ccc6oc7ccccc7c6c5)cc4)cc3)c2)cc1]

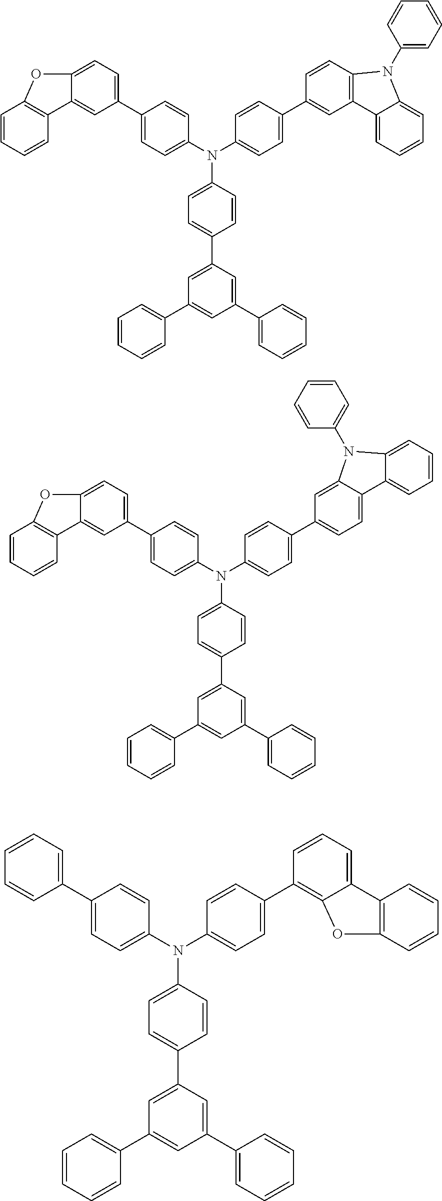

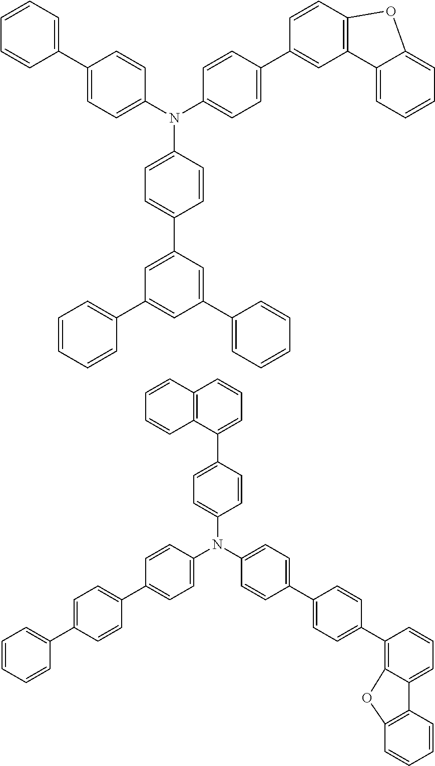

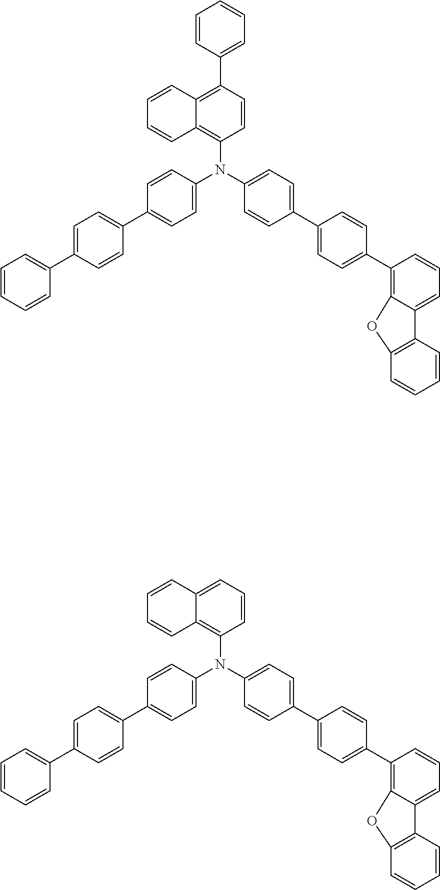 [SMILES: c1ccc(-c2ccc(-c3ccc(N(c4ccc(-c5ccc(-c6cccc7c6oc6ccccc67)cc5)cc4)c4ccc(-c5ccccc5)c5ccccc45)cc3)cc2)cc1 ; c1ccc(-c2ccc(-c3ccc(N(c4ccc(-c5ccc(-c6cccc7c6oc6ccccc67)cc5)cc4)c4cccc5ccccc45)cc3)cc2)cc1]

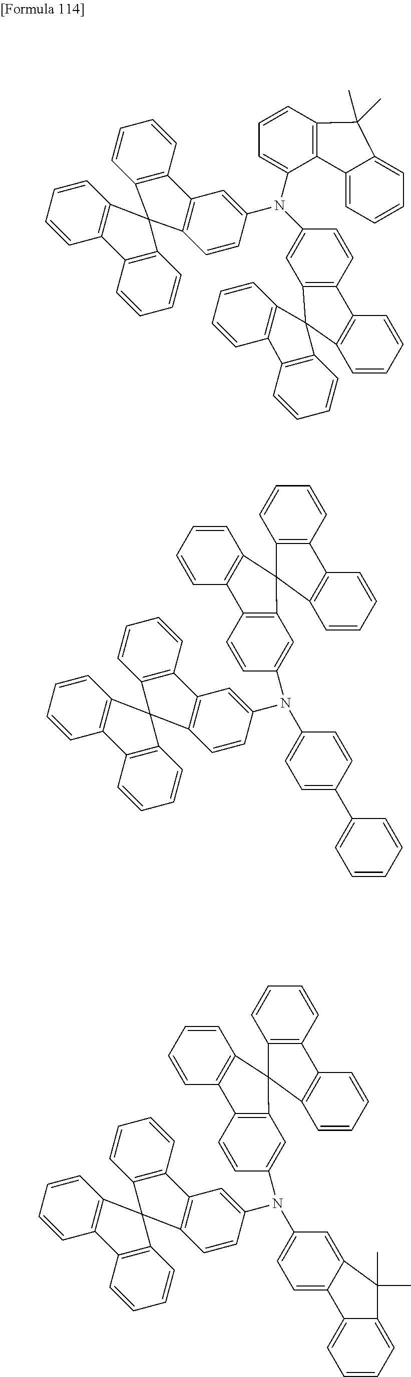 [SMILES: CC1(C)c2ccccc2-c2c(N(c3ccc4c(c3)-c3ccccc3C43c4ccccc4-c4ccccc43)c3ccc4c(c3)C3(c5ccccc5-c5ccccc53)c3ccccc3-4)cccc21 ; c1ccc(-c2ccc(N(c3ccc4c(c3)-c3ccccc3C43c4ccccc4-c4ccccc43)c3ccc4c(c3)C3(c5ccccc5-c5ccccc53)c3ccccc3-4)cc2)cc1 ; CC1(C)c2ccccc2-c2ccc(N(c3ccc4c(c3)-c3ccccc3C43c4ccccc4-c4ccccc43)c3ccc4c(c3)C3(c5ccccc5-c5ccccc53)c3ccccc3-4)cc21]

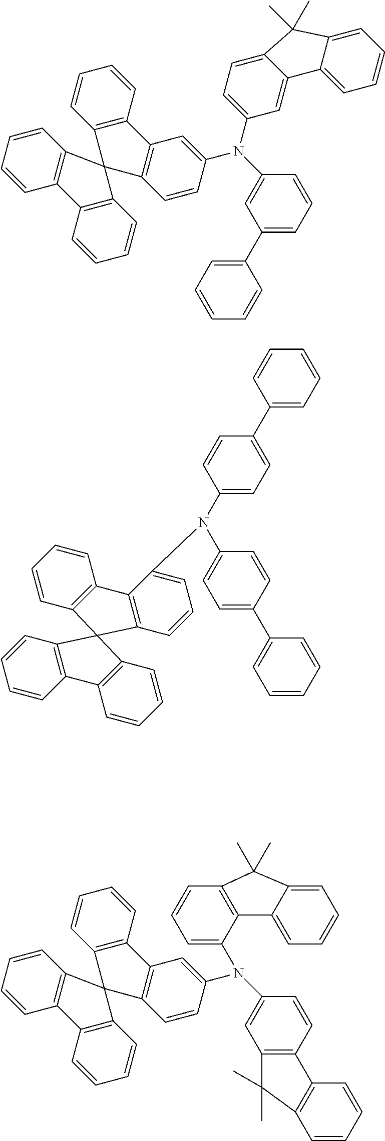

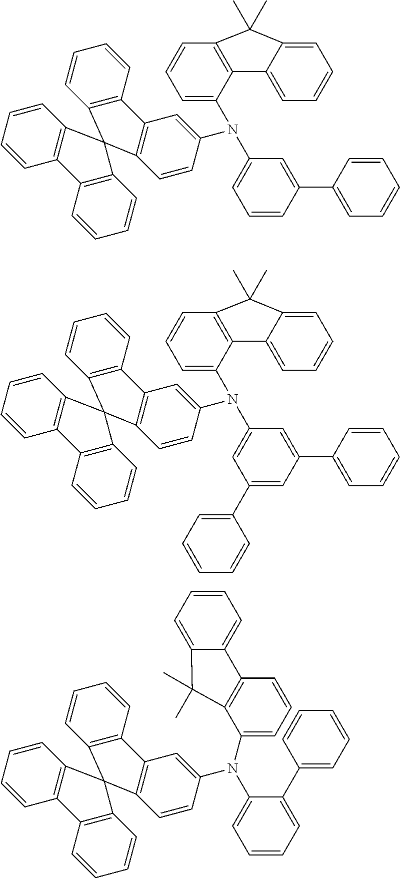

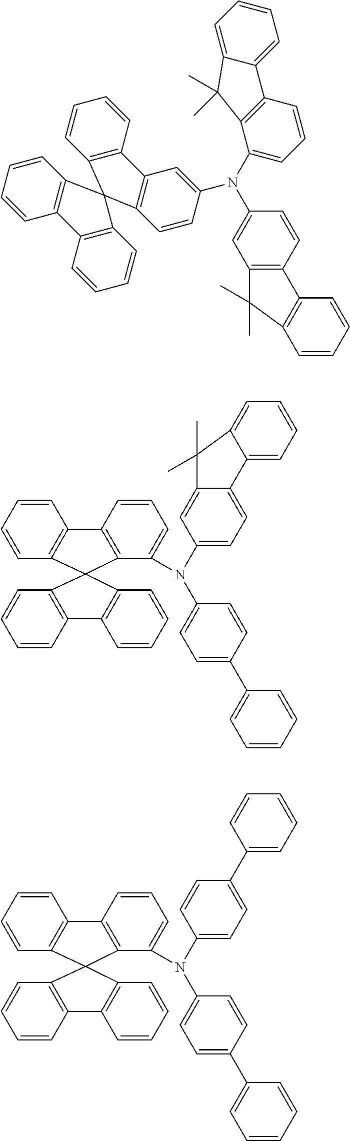

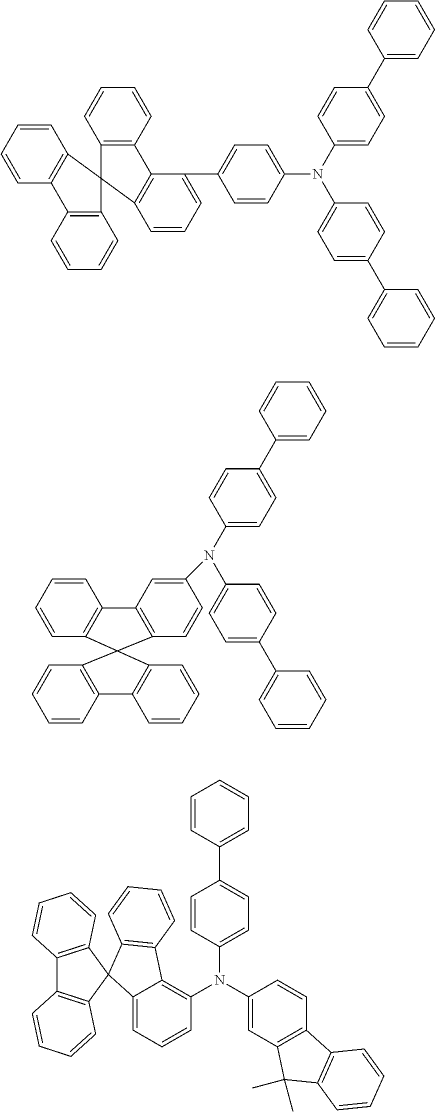 [SMILES: c1ccc(-c2ccc(N(c3ccc(-c4ccccc4)cc3)c3ccc(-c4cccc5c4-c4ccccc4C54c5ccccc5-c5ccccc54)cc3)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C43c4ccccc4-c4ccccc43)cc21]

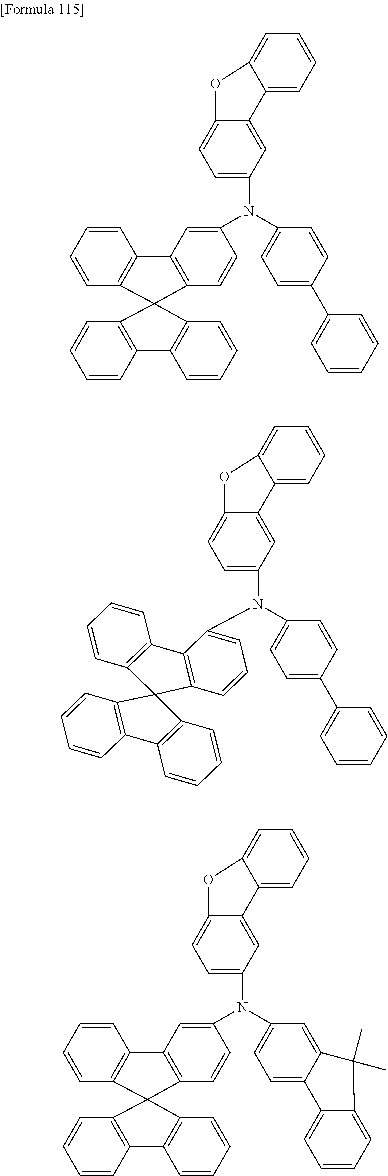 [SMILES: c1ccc(-c2ccc(N(c3ccc4c(c3)-c3ccccc3C43c4ccccc4-c4ccccc43)c3ccc4oc5ccccc5c4c3)cc2)cc1 ; c1ccc(-c2ccc(N(c3ccc4oc5ccccc5c4c3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3ccc4oc5ccccc5c4c3)cc21]

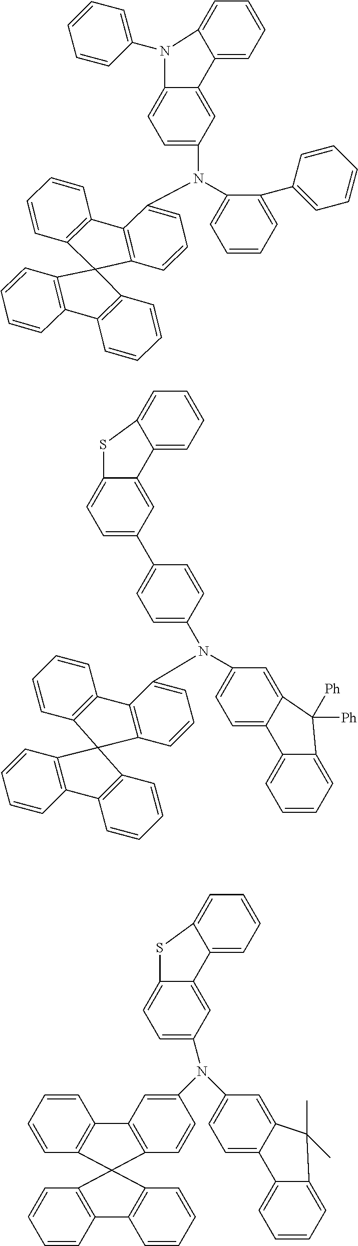

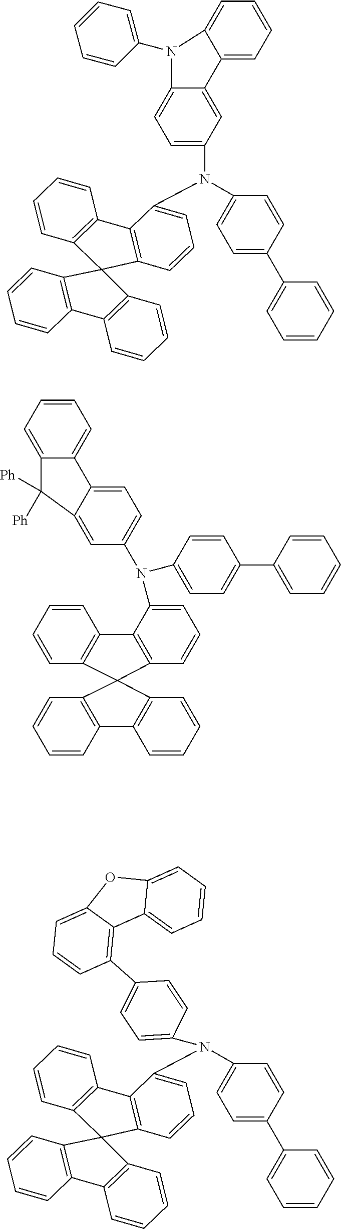 [SMILES: c1ccc(-c2ccc(N(c3ccc4c(c3)c3ccccc3n4-c3ccccc3)c3cccc4c3-c3ccccc3C43c4ccccc4-c4ccccc43)cc2)cc1 ; c1ccc(-c2ccc(N(c3ccc4c(c3)C(c3ccccc3)(c3ccccc3)c3ccccc3-4)c3cccc4c3-c3ccccc3C43c4ccccc4-c4ccccc43)cc2)cc1 ; c1ccc(-c2ccc(N(c3ccc(-c4cccc5oc6ccccc6c45)cc3)c3cccc4c3-c3ccccc3C43c4ccccc4-c4ccccc43)cc2)cc1]

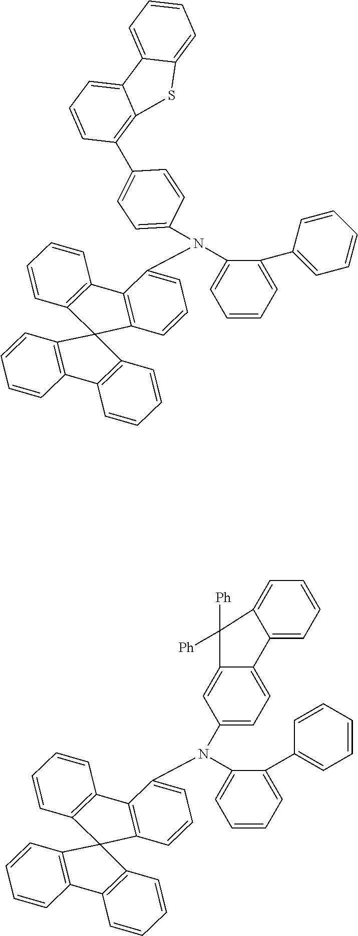 [SMILES: c1ccc(-c2ccccc2N(c2ccc(-c3cccc4c3sc3ccccc34)cc2)c2cccc3c2-c2ccccc2C32c3ccccc3-c3ccccc32)cc1 ; c1ccc(-c2ccccc2N(c2ccc3c(c2)C(c2ccccc2)(c2ccccc2)c2ccccc2-3)c2cccc3c2-c2ccccc2C32c3ccccc3-c3ccccc32)cc1]

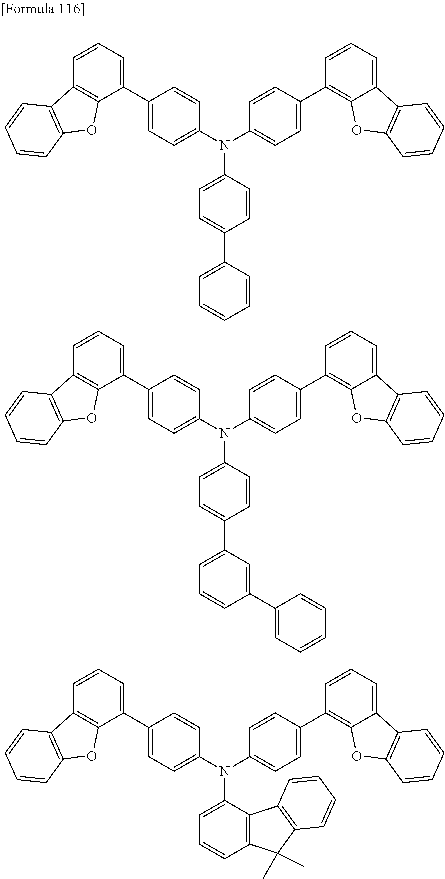

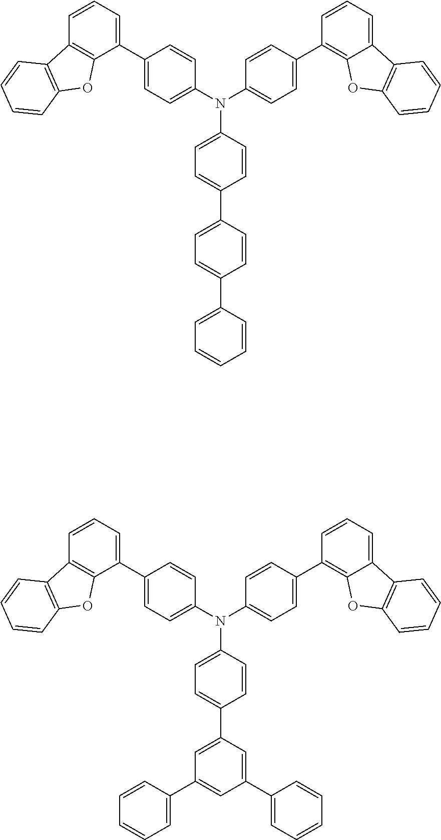 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

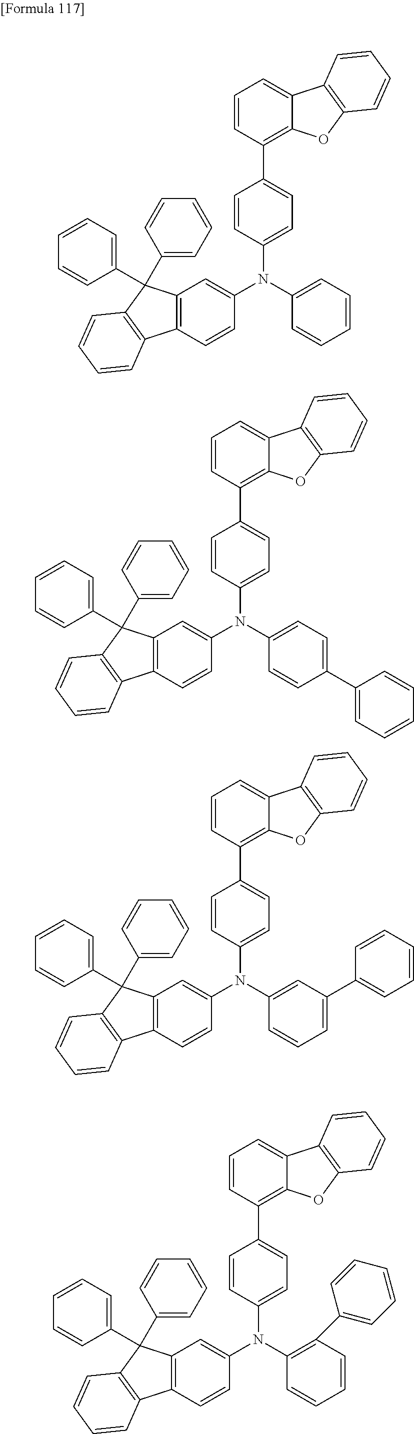

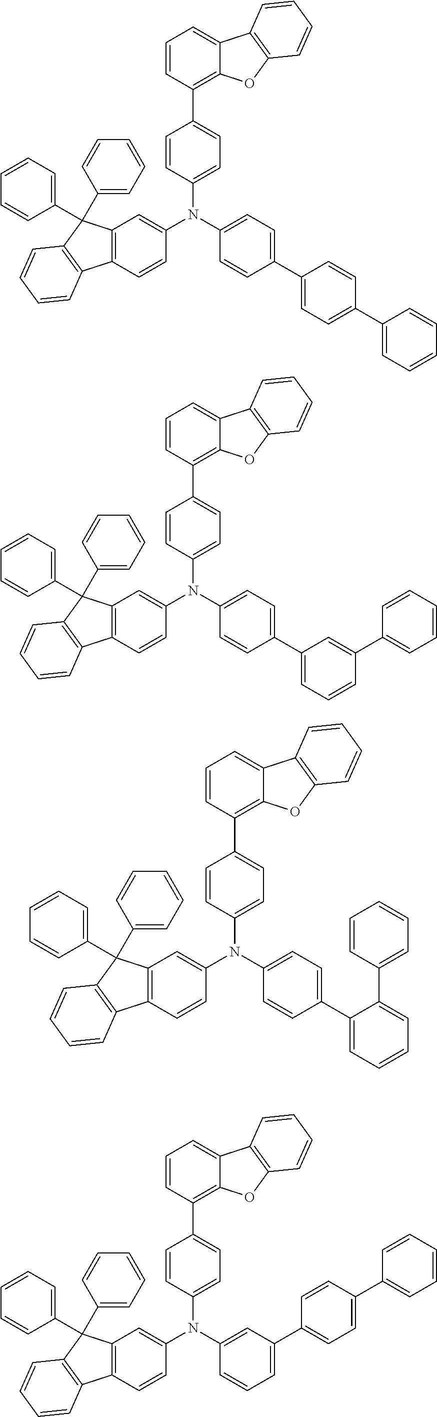

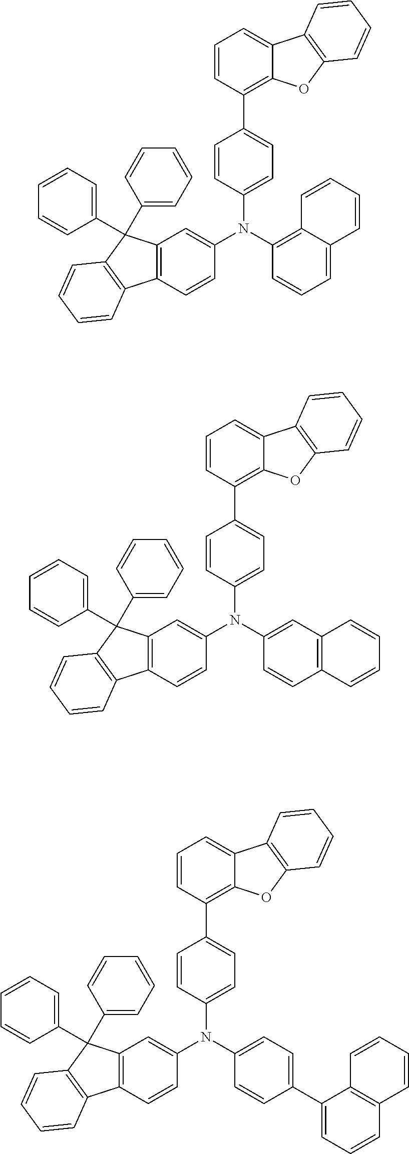 [SMILES: c1ccc(C2(c3ccccc3)c3ccccc3-c3ccc(N(c4ccc(-c5cccc6c5oc5ccccc56)cc4)c4cccc5ccccc45)cc32)cc1 ; c1ccc(C2(c3ccccc3)c3ccccc3-c3ccc(N(c4ccc(-c5cccc6c5oc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5oc5ccccc56)cc4)cc32)cc1]

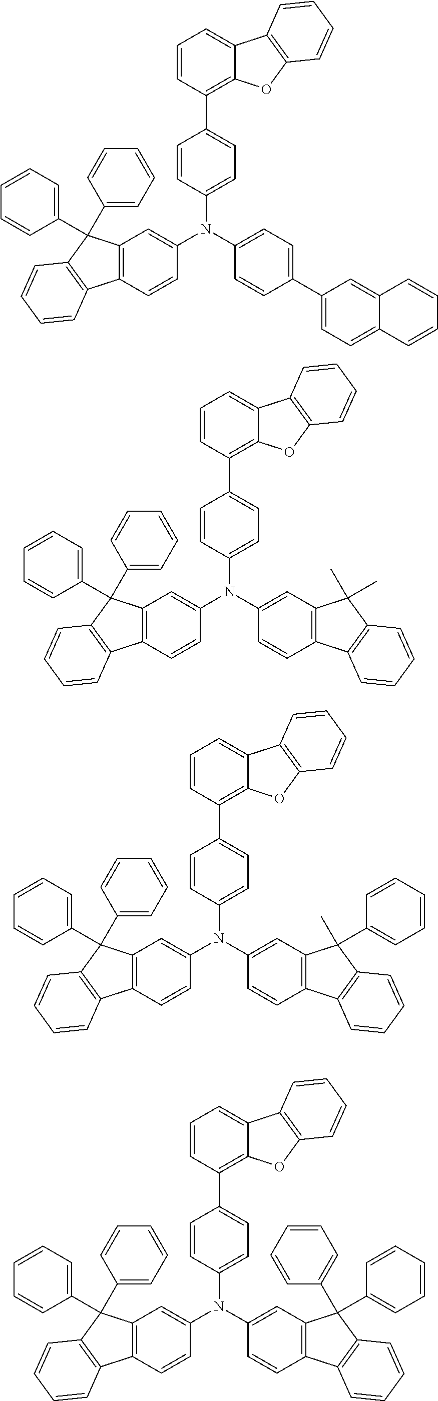

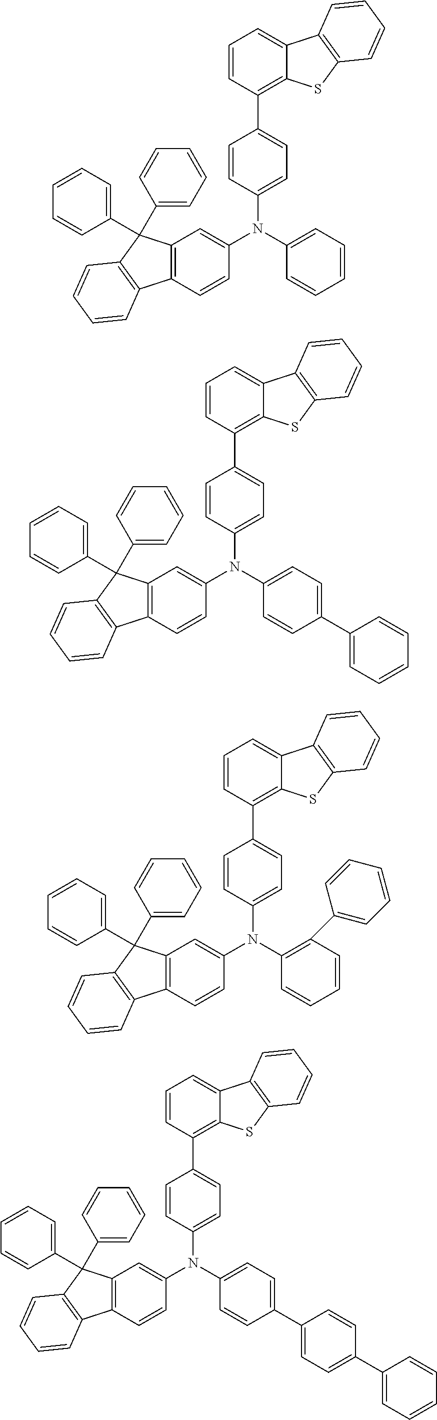

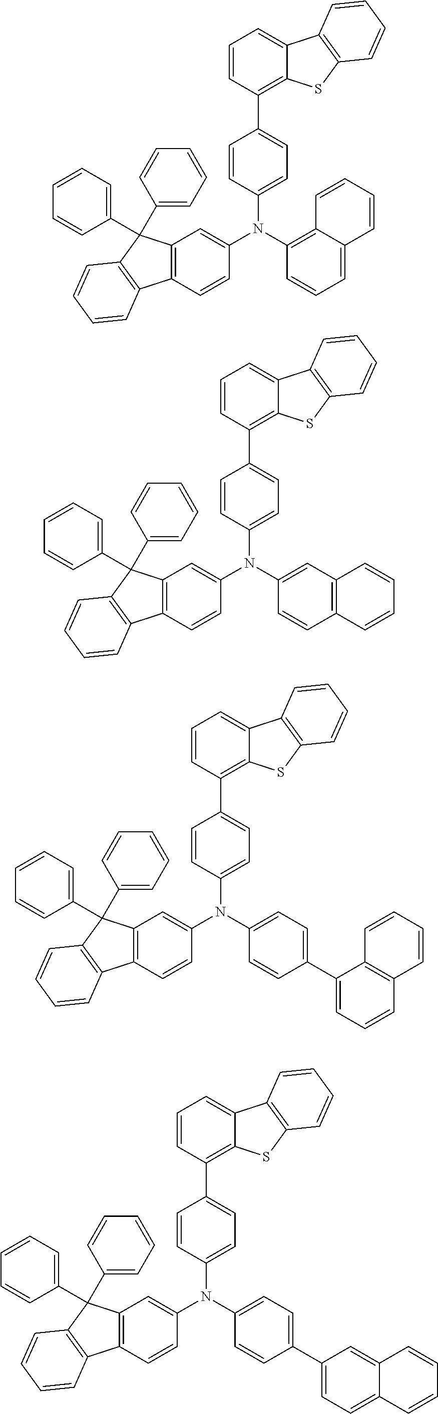

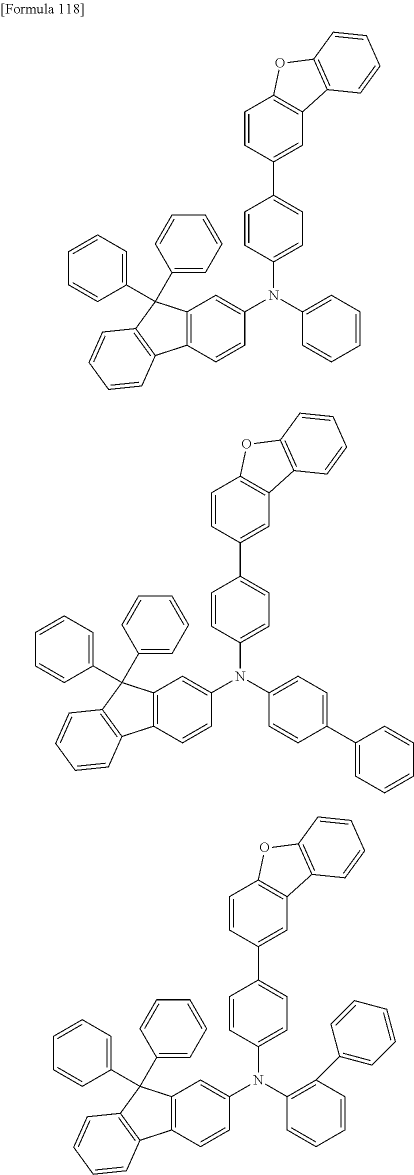

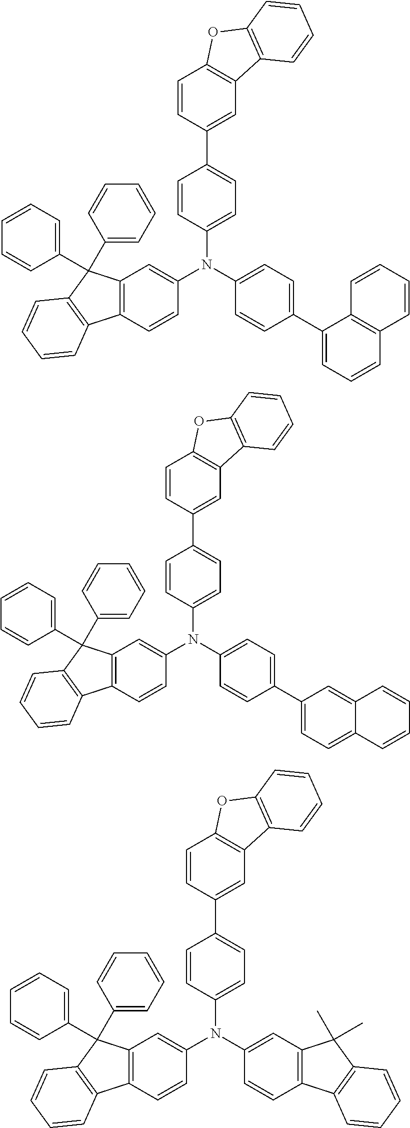

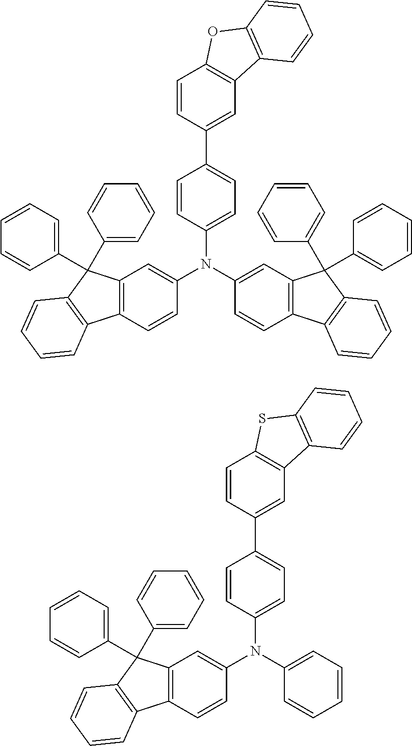

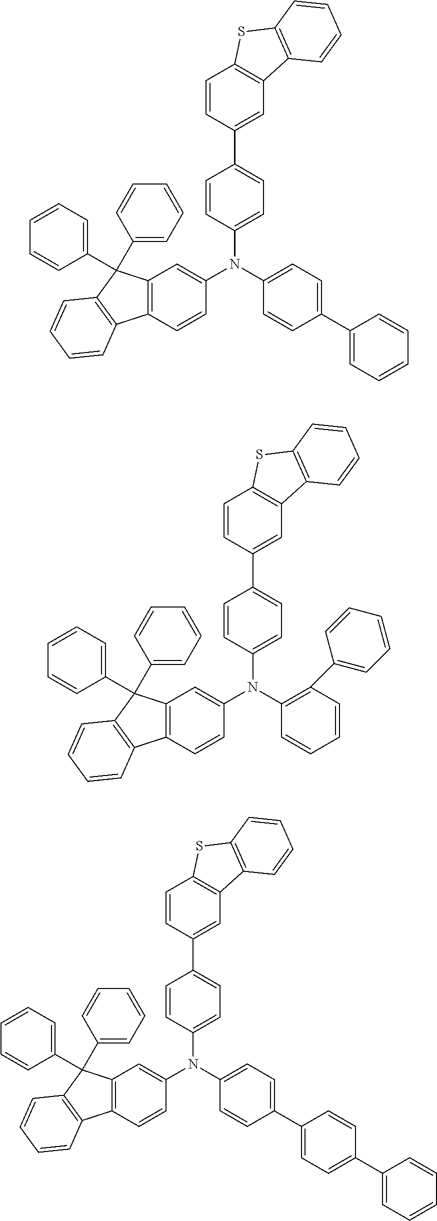 [SMILES: c1ccc(-c2ccc(N(c3ccc(-c4ccc5sc6ccccc6c5c4)cc3)c3ccc4c(c3)C(c3ccccc3)(c3ccccc3)c3ccccc3-4)cc2)cc1 ; c1ccc(-c2ccccc2N(c2ccc(-c3ccc4sc5ccccc5c4c3)cc2)c2ccc3c(c2)C(c2ccccc2)(c2ccccc2)c2ccccc2-3)cc1 ; c1ccc(-c2ccc(-c3ccc(N(c4ccc(-c5ccc6sc7ccccc7c6c5)cc4)c4ccc5c(c4)C(c4ccccc4)(c4ccccc4)c4ccccc4-5)cc3)cc2)cc1]

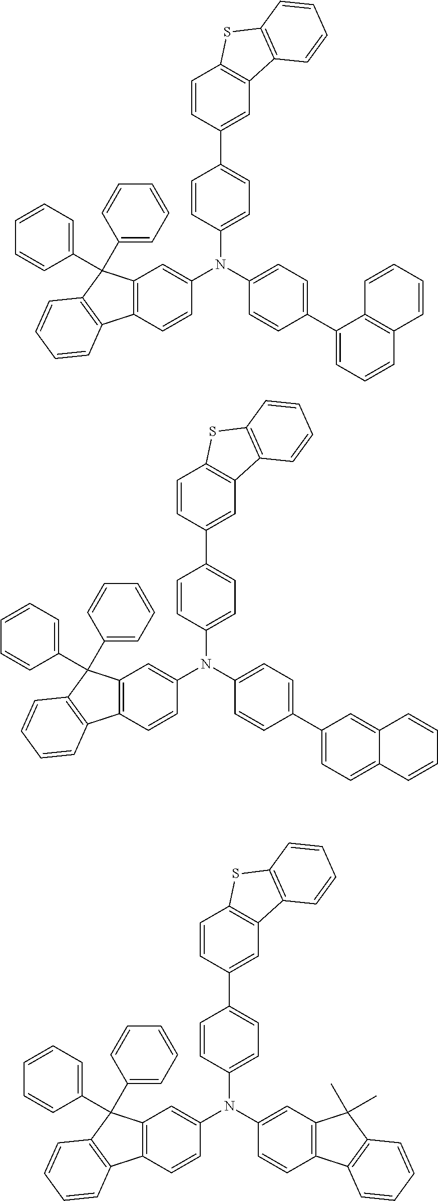 [SMILES: c1ccc(C2(c3ccccc3)c3ccccc3-c3ccc(N(c4ccc(-c5ccc6sc7ccccc7c6c5)cc4)c4ccc(-c5cccc6ccccc56)cc4)cc32)cc1 ; c1ccc(C2(c3ccccc3)c3ccccc3-c3ccc(N(c4ccc(-c5ccc6ccccc6c5)cc4)c4ccc(-c5ccc6sc7ccccc7c6c5)cc4)cc32)cc1 ; CC1(C)c2ccccc2-c2ccc(N(c3ccc(-c4ccc5sc6ccccc6c5c4)cc3)c3ccc4c(c3)C(c3ccccc3)(c3ccccc3)c3ccccc3-4)cc21]

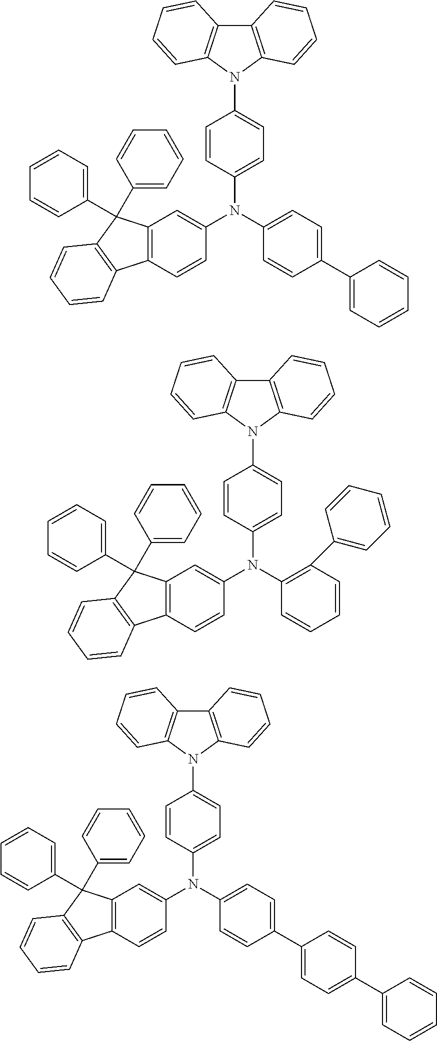

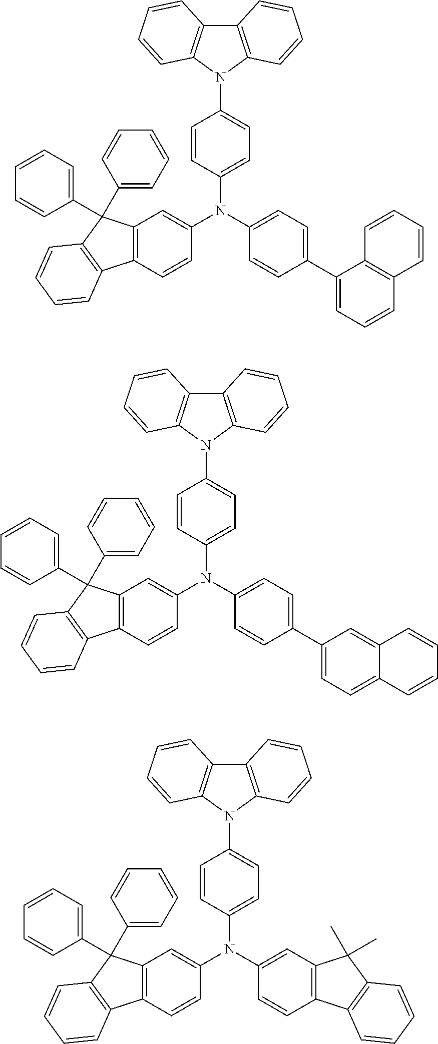 [SMILES: c1ccc(C2(c3ccccc3)c3ccccc3-c3ccc(N(c4ccc(-c5cccc6ccccc56)cc4)c4ccc(-n5c6ccccc6c6ccccc65)cc4)cc32)cc1 ; c1ccc(C2(c3ccccc3)c3ccccc3-c3ccc(N(c4ccc(-c5ccc6ccccc6c5)cc4)c4ccc(-n5c6ccccc6c6ccccc65)cc4)cc32)cc1 ; CC1(C)c2ccccc2-c2ccc(N(c3ccc(-n4c5ccccc5c5ccccc54)cc3)c3ccc4c(c3)C(c3ccccc3)(c3ccccc3)c3ccccc3-4)cc21]

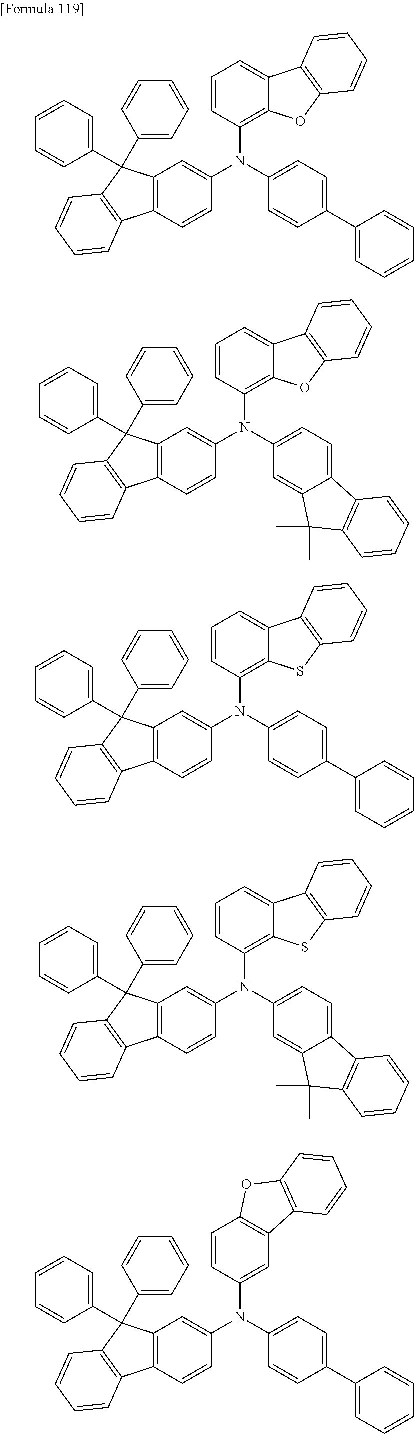

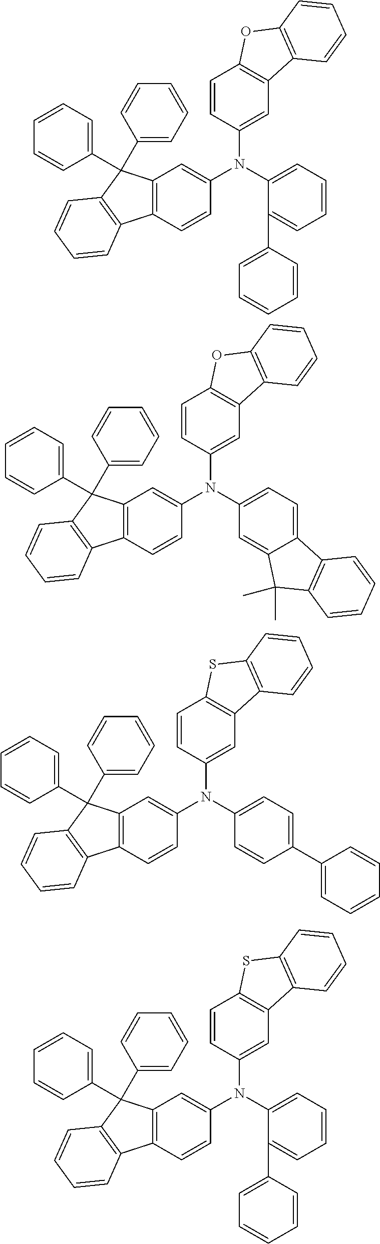

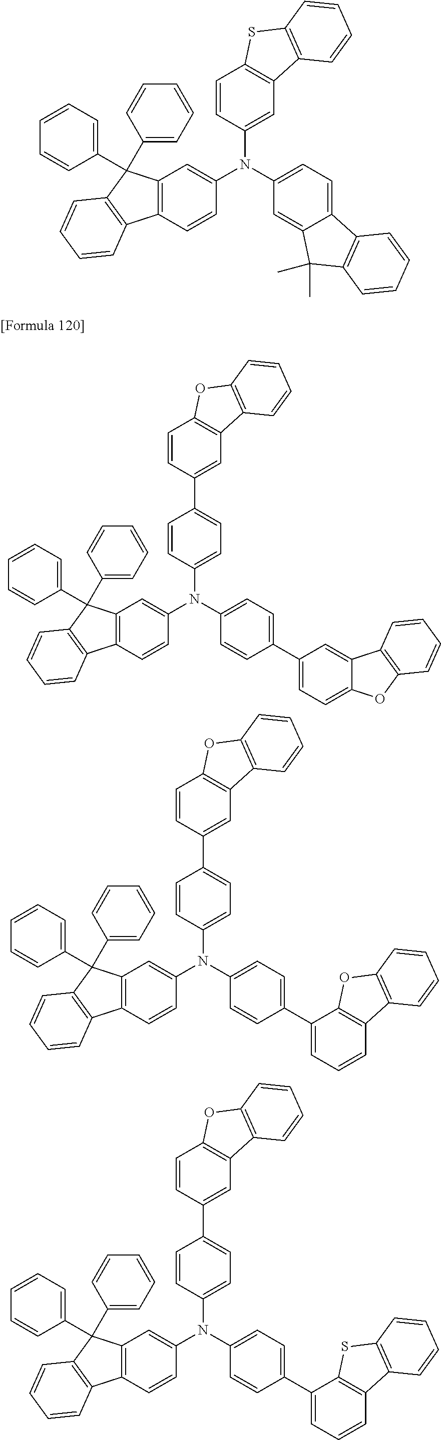

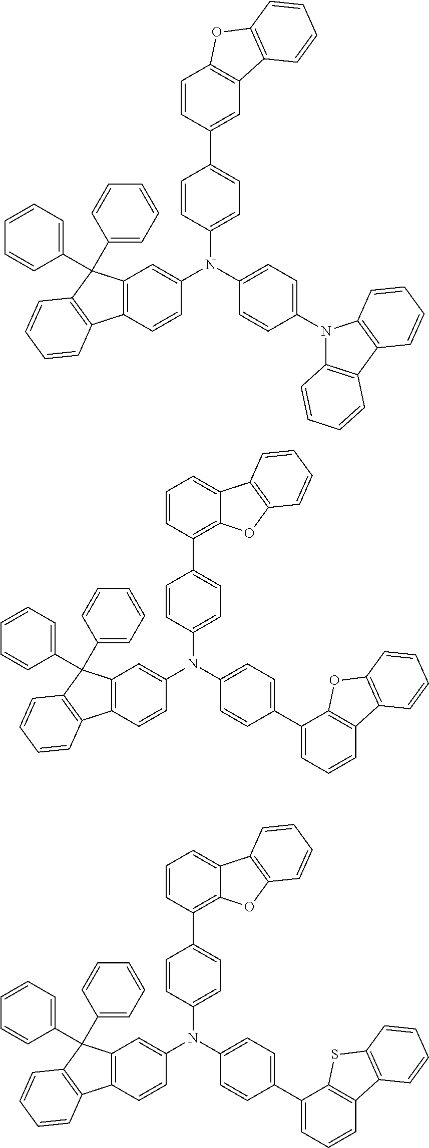

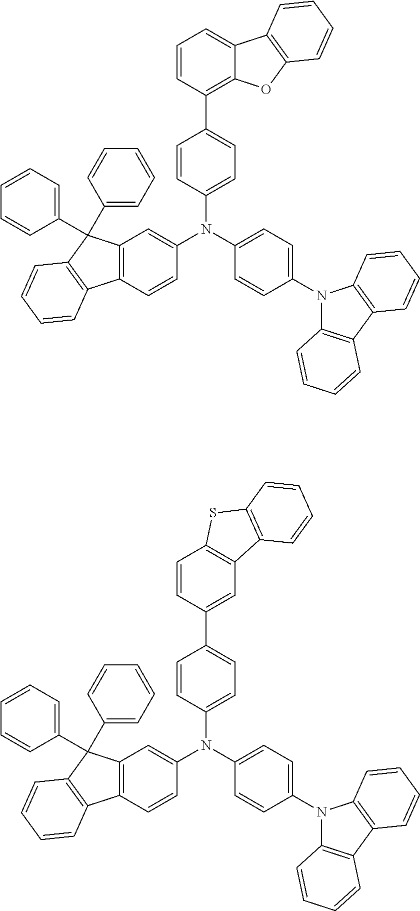 [SMILES: c1ccc(C2(c3ccccc3)c3ccccc3-c3ccc(N(c4ccc(-c5cccc6c5oc5ccccc56)cc4)c4ccc(-n5c6ccccc6c6ccccc65)cc4)cc32)cc1 ; c1ccc(C2(c3ccccc3)c3ccccc3-c3ccc(N(c4ccc(-c5ccc6sc7ccccc7c6c5)cc4)c4ccc(-n5c6ccccc6c6ccccc65)cc4)cc32)cc1]

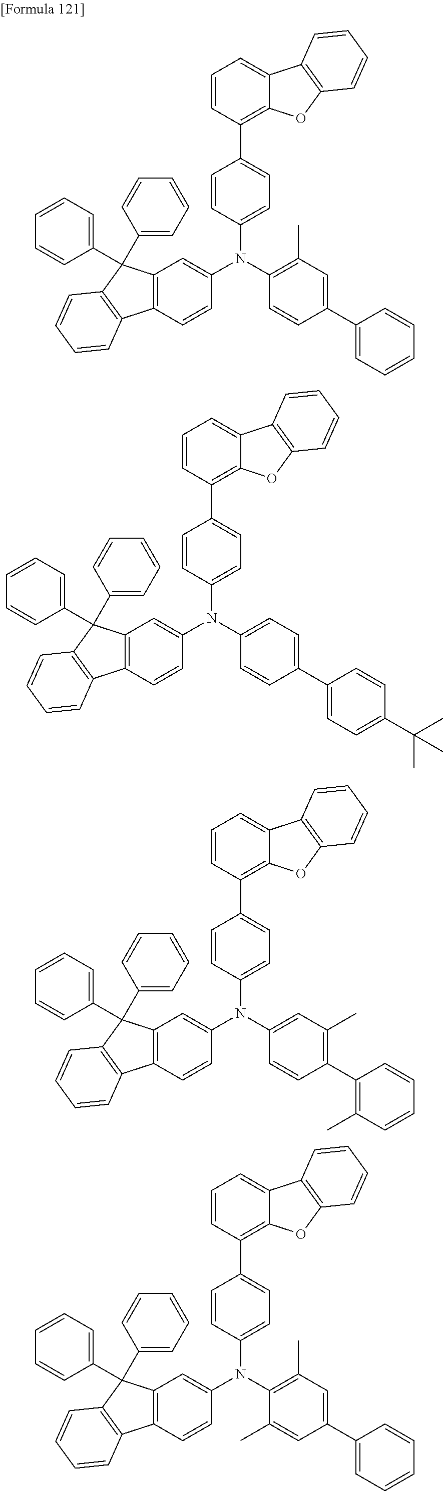

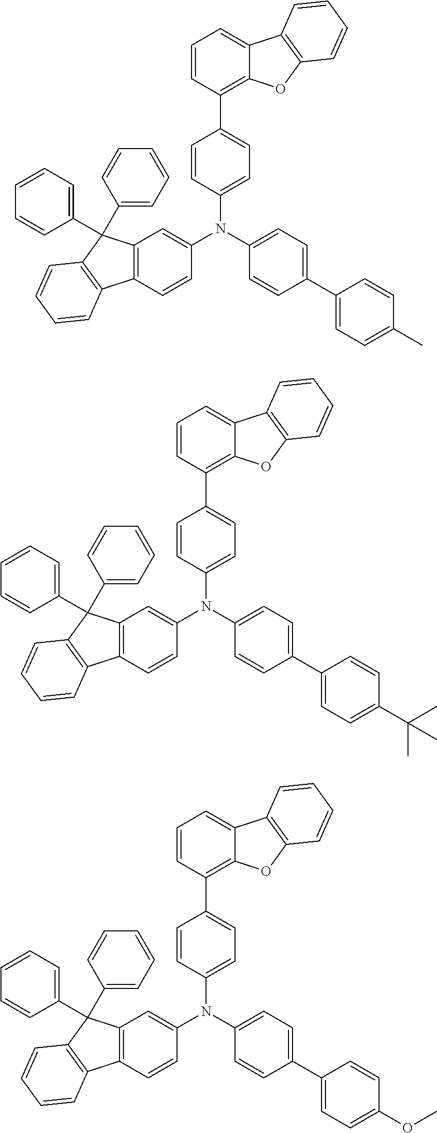 [SMILES: Cc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; COc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1]

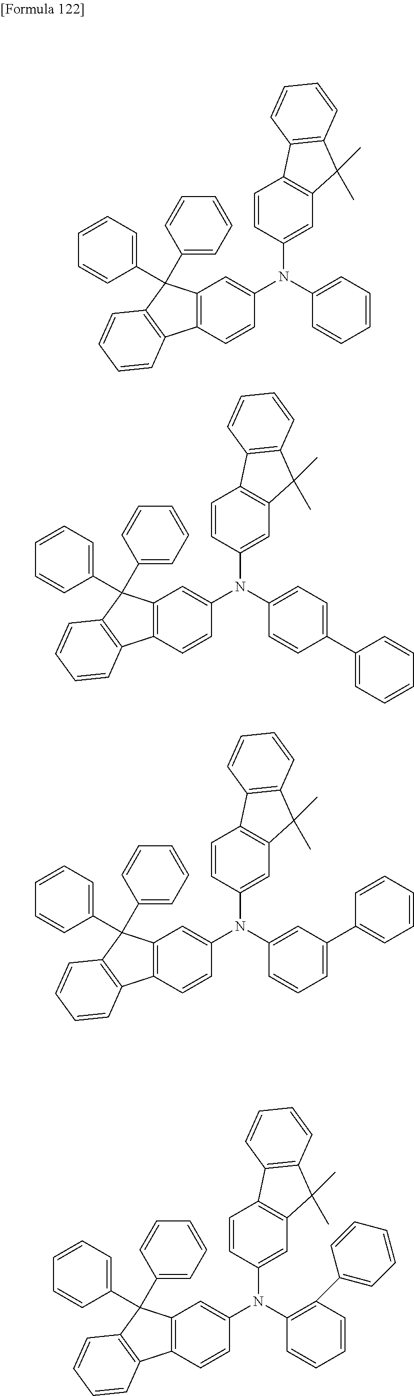 [SMILES: CC1(C)c2ccccc2-c2ccc(N(c3ccccc3)c3ccc4c(c3)C(c3ccccc3)(c3ccccc3)c3ccccc3-4)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3cccc(-c4ccccc4)c3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21]

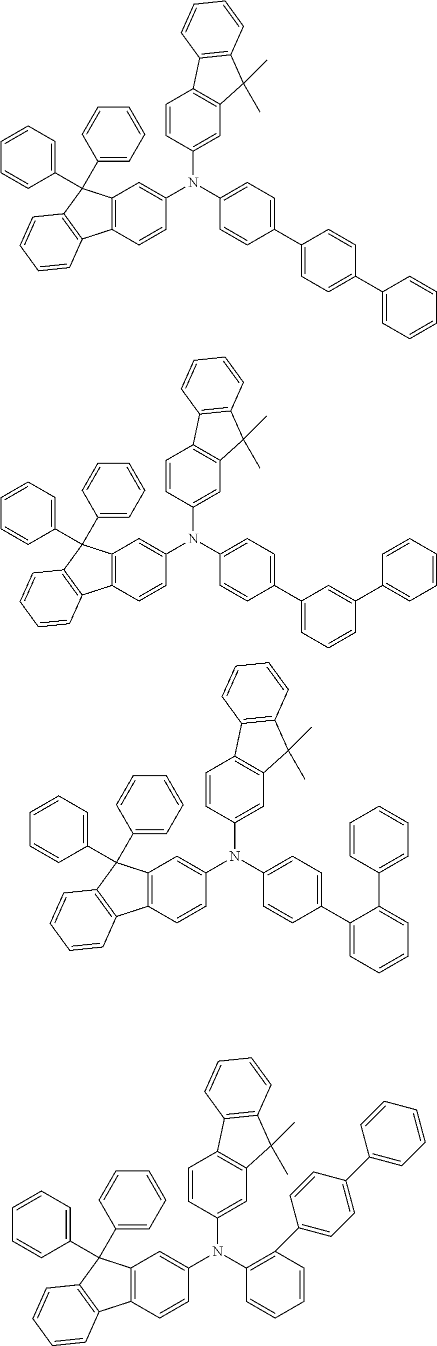

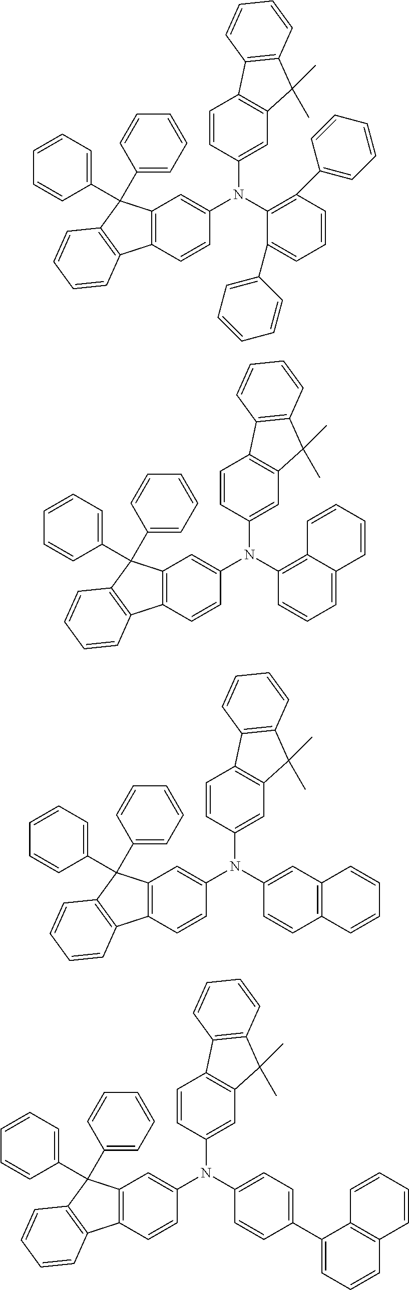

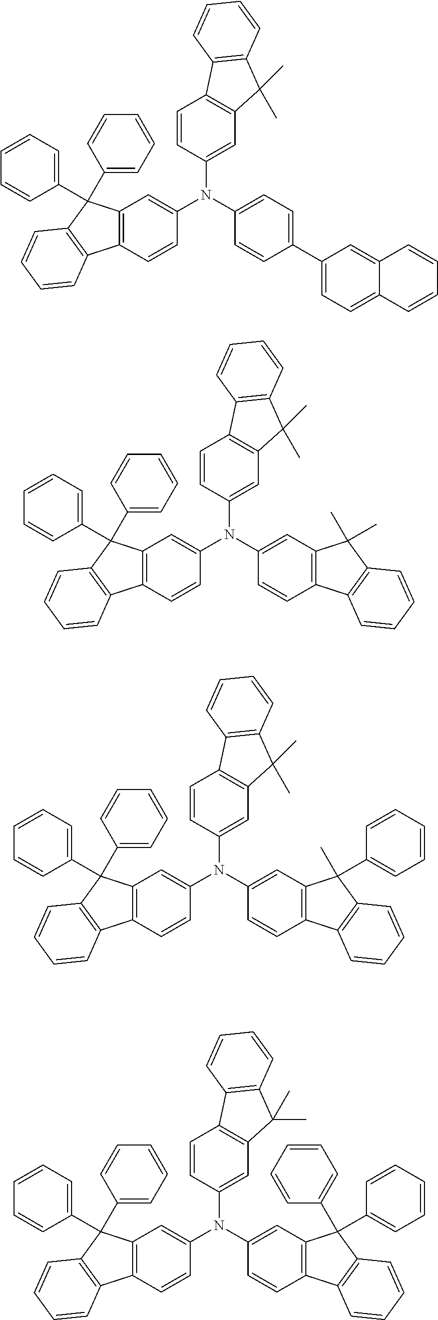 [SMILES: CC1(C)c2ccccc2-c2ccc(N(c3ccc(-c4ccc5ccccc5c4)cc3)c3ccc4c(c3)C(c3ccccc3)(c3ccccc3)c3ccccc3-4)cc21 ; CC1(C)c2ccccc2-c2ccc(N(c3ccc4c(c3)C(C)(C)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(C)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

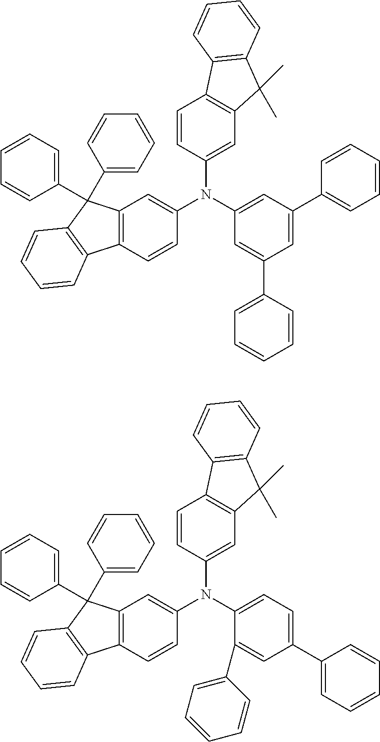

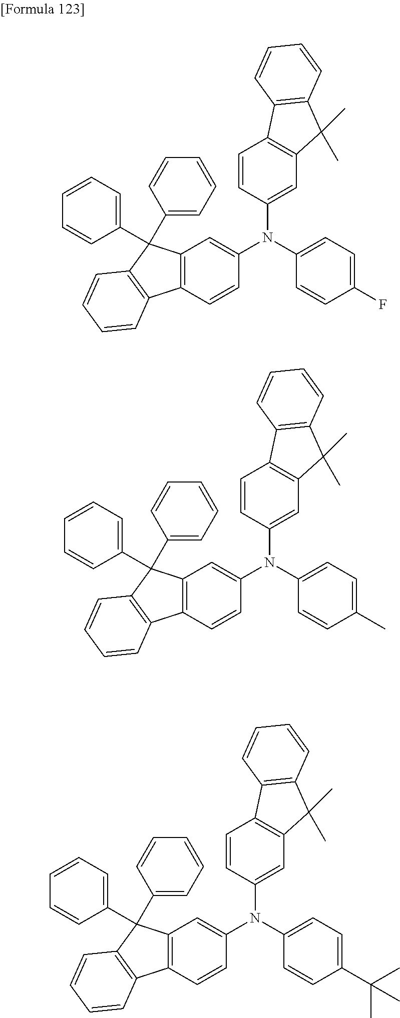 [SMILES: CC1(C)c2ccccc2-c2ccc(N(c3ccc(F)cc3)c3ccc4c(c3)C(c3ccccc3)(c3ccccc3)c3ccccc3-4)cc21 ; Cc1ccc(N(c2ccc3c(c2)C(C)(C)c2ccccc2-3)c2ccc3c(c2)C(c2ccccc2)(c2ccccc2)c2ccccc2-3)cc1 ; CC(C)(C)c1ccc(N(c2ccc3c(c2)C(C)(C)c2ccccc2-3)c2ccc3c(c2)C(c2ccccc2)(c2ccccc2)c2ccccc2-3)cc1]

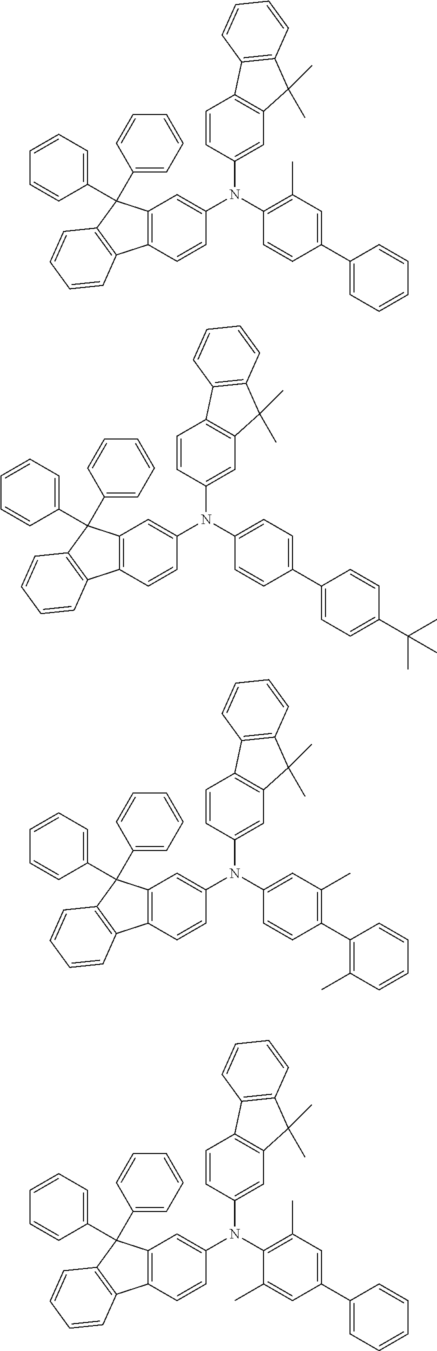 [SMILES: Cc1cc(-c2ccccc2)ccc1N(c1ccc2c(c1)C(C)(C)c1ccccc1-2)c1ccc2c(c1)C(c1ccccc1)(c1ccccc1)c1ccccc1-2 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(C)(C)c2ccccc2-3)c2ccc3c(c2)C(c2ccccc2)(c2ccccc2)c2ccccc2-3)cc1C ; Cc1cc(-c2ccccc2)cc(C)c1N(c1ccc2c(c1)C(C)(C)c1ccccc1-2)c1ccc2c(c1)C(c1ccccc1)(c1ccccc1)c1ccccc1-2]

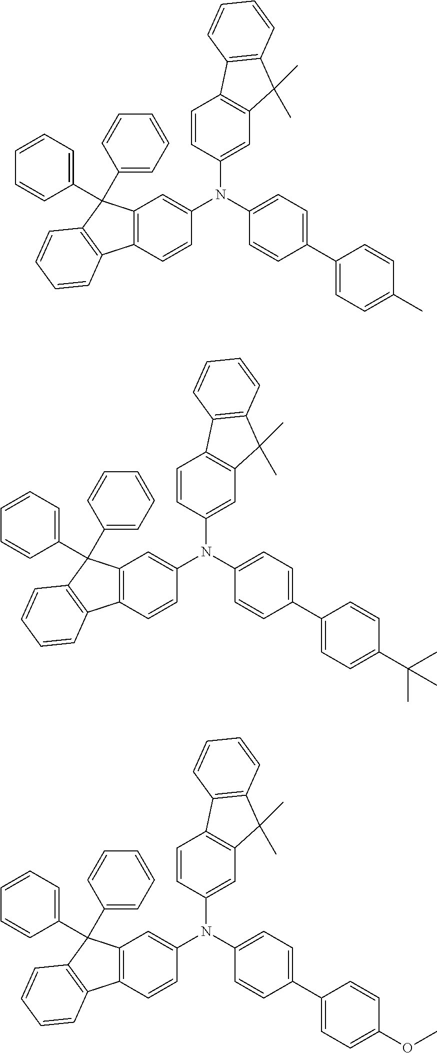 [SMILES: Cc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1]

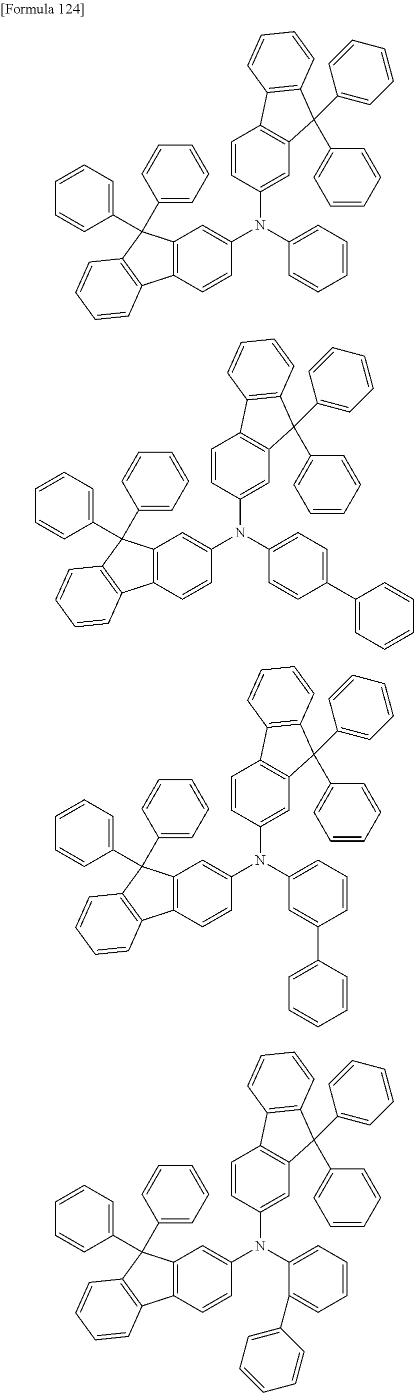

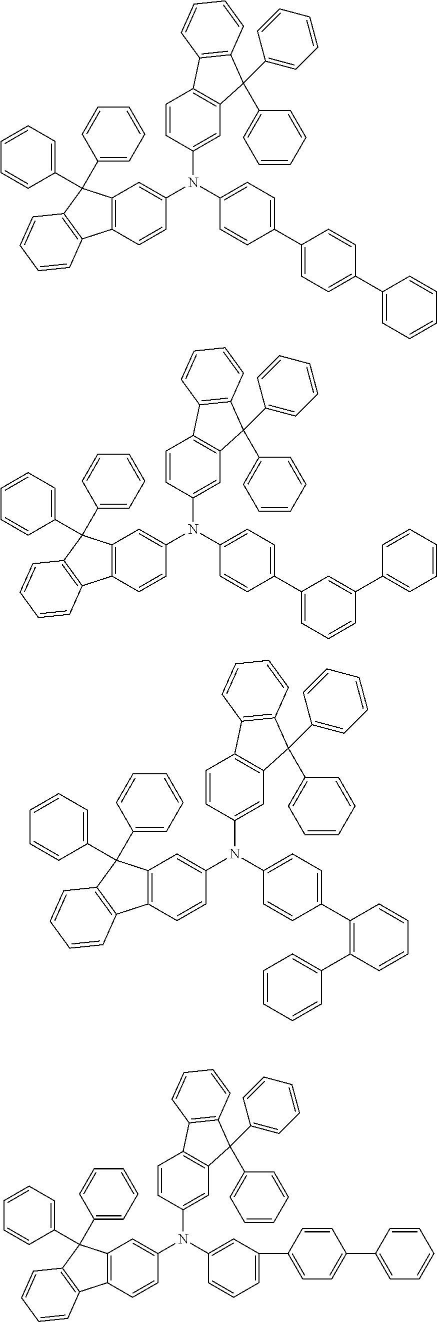

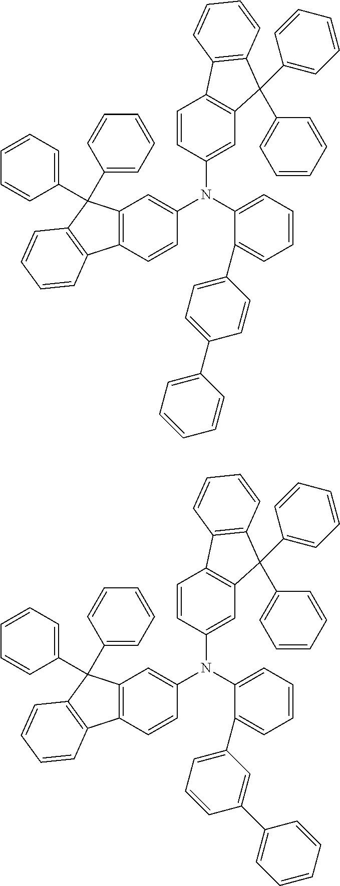

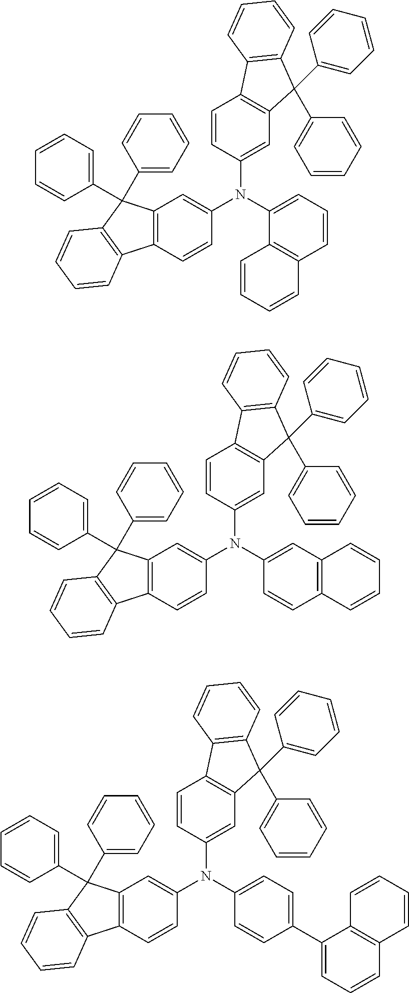

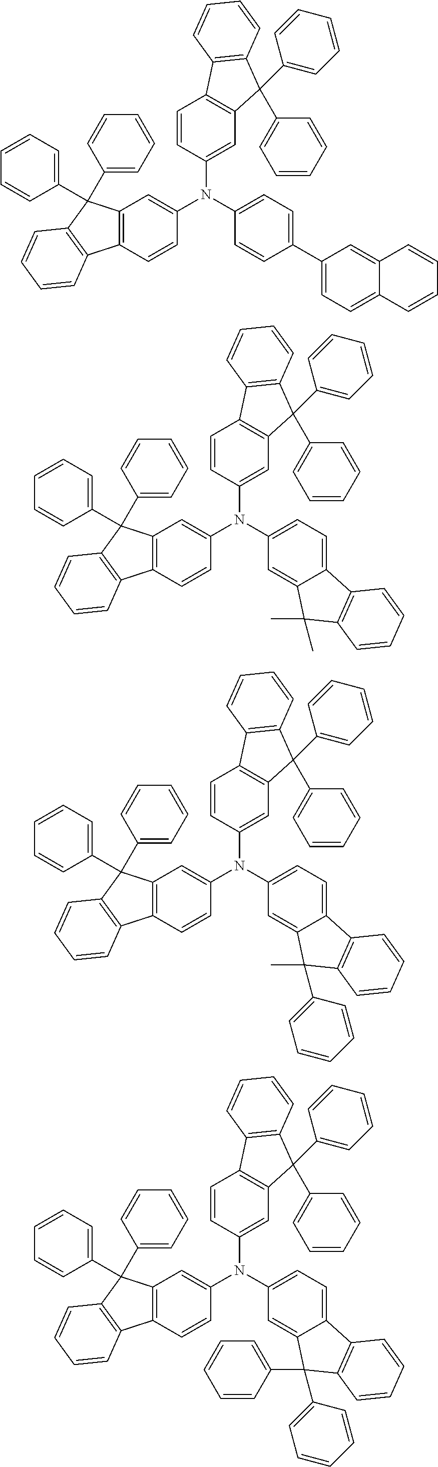

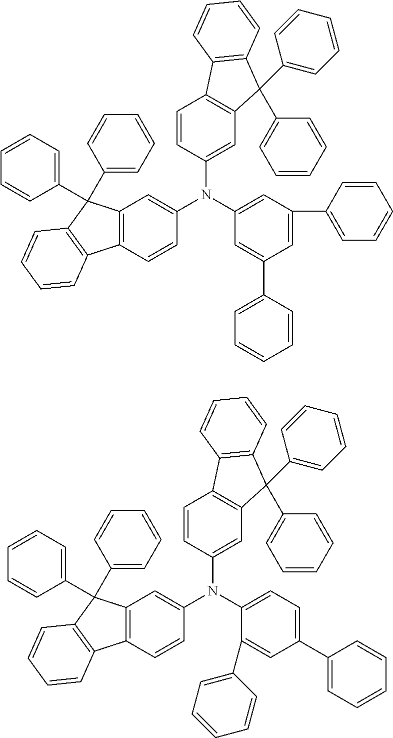

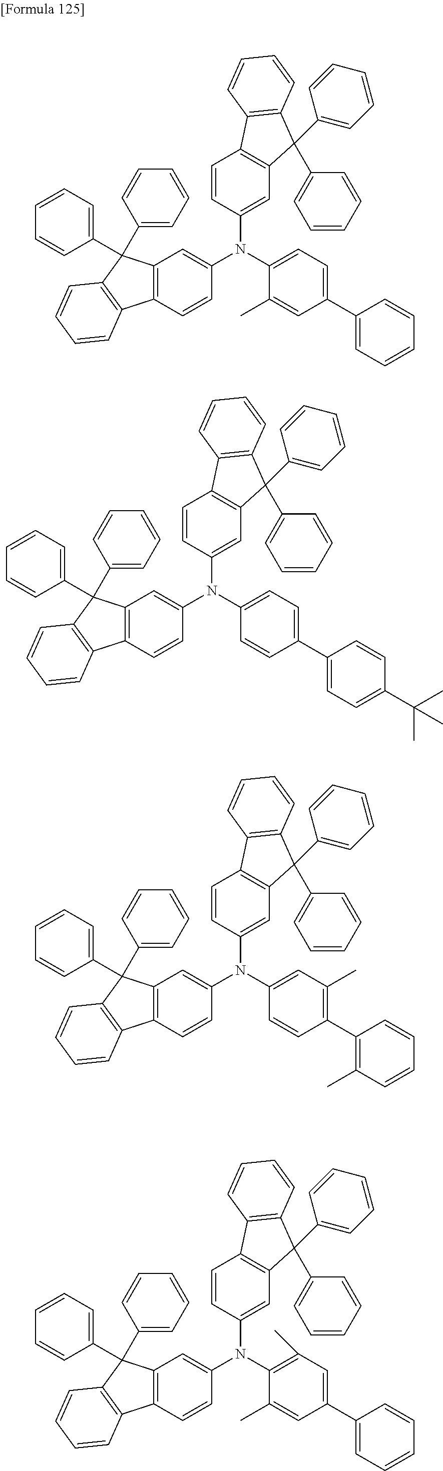 [SMILES: Cc1cc(-c2ccccc2)ccc1N(c1ccc2c(c1)C(c1ccccc1)(c1ccccc1)c1ccccc1-2)c1ccc2c(c1)C(c1ccccc1)(c1ccccc1)c1ccccc1-2 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(c2ccccc2)(c2ccccc2)c2ccccc2-3)c2ccc3c(c2)C(c2ccccc2)(c2ccccc2)c2ccccc2-3)cc1C ; Cc1cc(-c2ccccc2)cc(C)c1N(c1ccc2c(c1)C(c1ccccc1)(c1ccccc1)c1ccccc1-2)c1ccc2c(c1)C(c1ccccc1)(c1ccccc1)c1ccccc1-2]

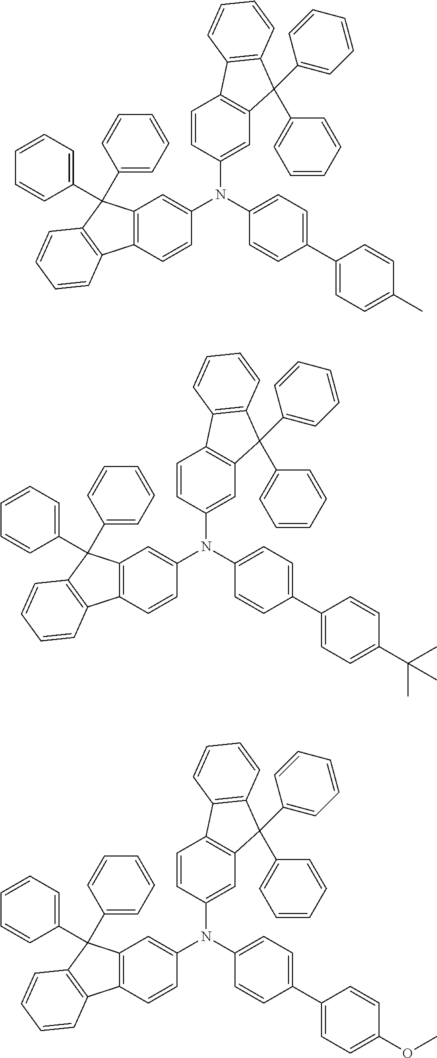 [SMILES: Cc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

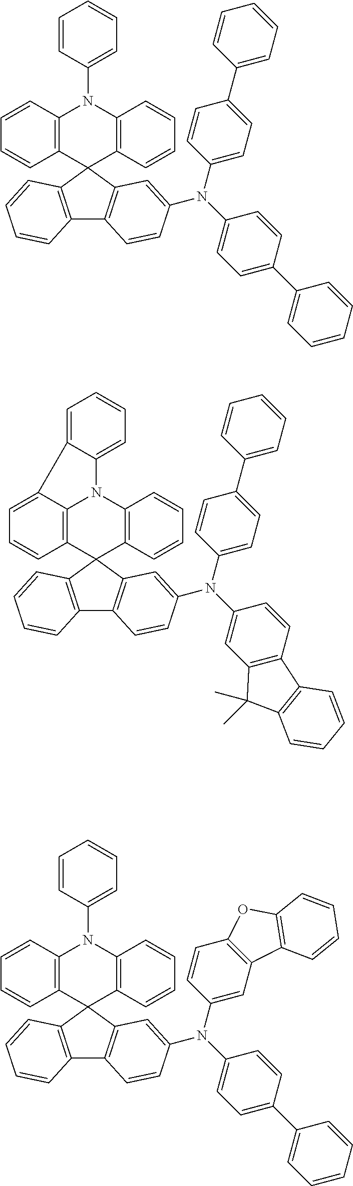 [SMILES: c1ccc(-c2ccc(N(c3ccc(-c4ccccc4)cc3)c3ccc4c(c3)C3(c5ccccc5-4)c4ccccc4N(c4ccccc4)c4ccccc43)cc2)cc1 ; CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; c1ccc(-c2ccc(N(c3ccc4c(c3)C3(c5ccccc5-4)c4ccccc4N(c4ccccc4)c4ccccc43)c3ccc4oc5ccccc5c4c3)cc2)cc1]

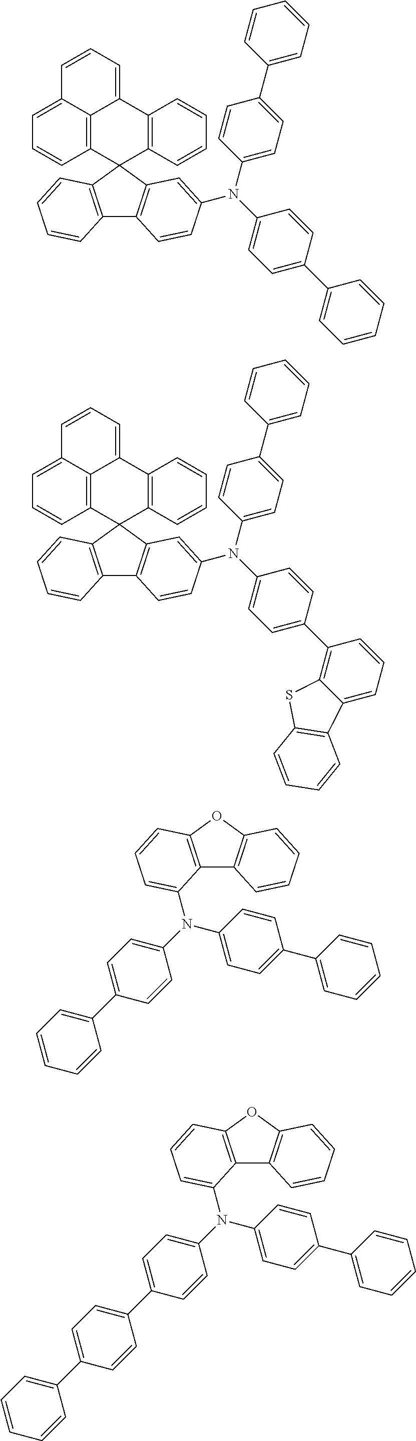

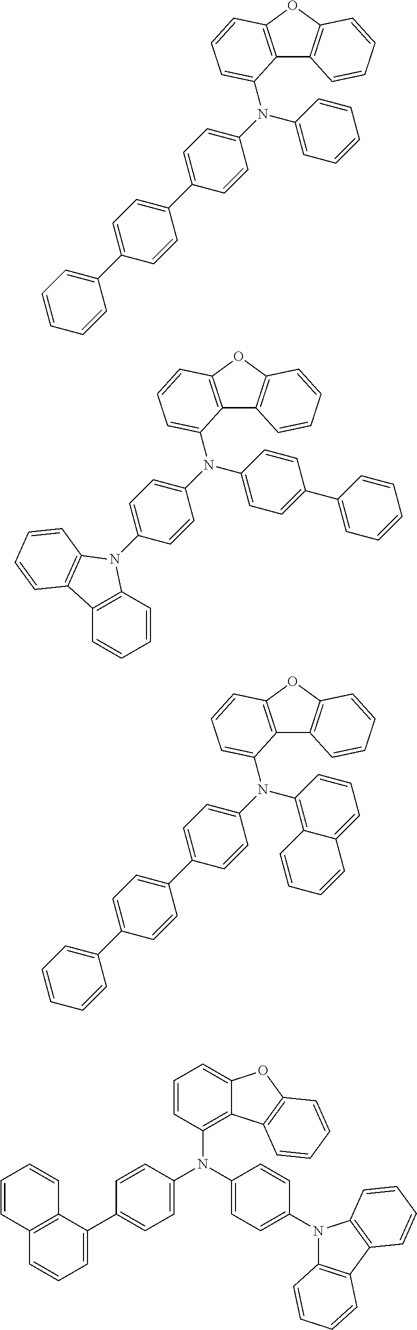 [SMILES: c1ccc(-c2ccc(-c3ccc(N(c4ccccc4)c4cccc5oc6ccccc6c45)cc3)cc2)cc1 ; c1ccc(-c2ccc(N(c3ccc(-n4c5ccccc5c5ccccc54)cc3)c3cccc4oc5ccccc5c34)cc2)cc1 ; c1ccc(-c2ccc(-c3ccc(N(c4cccc5ccccc45)c4cccc5oc6ccccc6c45)cc3)cc2)cc1 ; c1ccc2c(-c3ccc(N(c4ccc(-n5c6ccccc6c6ccccc65)cc4)c4cccc5oc6ccccc6c45)cc3)cccc2c1]

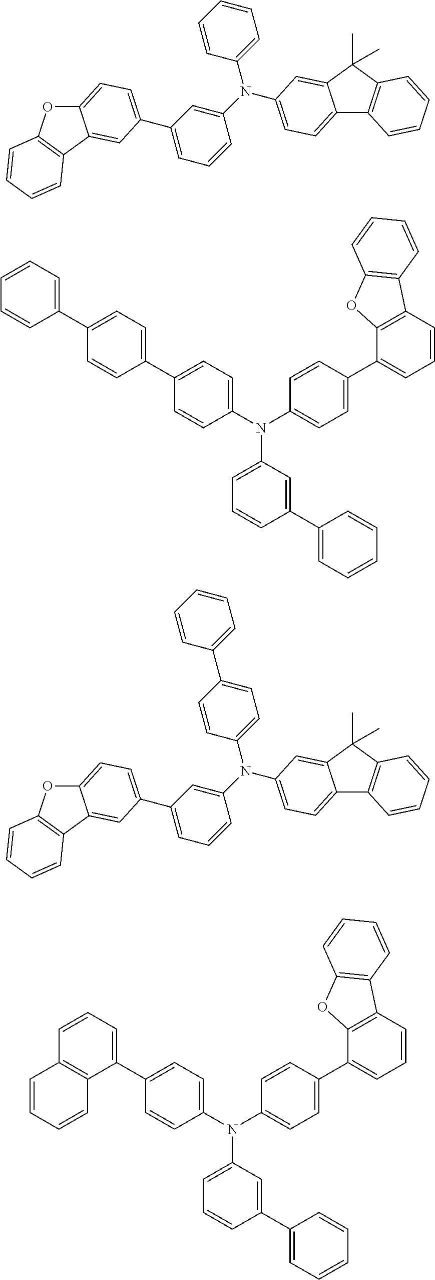 [SMILES: CC1(C)c2ccccc2-c2ccc(N(c3ccccc3)c3cccc(-c4ccc5oc6ccccc6c5c4)c3)cc21 ; c1ccc(-c2ccc(-c3ccc(N(c4ccc(-c5cccc6c5oc5ccccc56)cc4)c4cccc(-c5ccccc5)c4)cc3)cc2)cc1 ; CC1(C)c2ccccc2-c2ccc(N(c3ccc(-c4ccccc4)cc3)c3cccc(-c4ccc5oc6ccccc6c5c4)c3)cc21 ; c1ccc(-c2cccc(N(c3ccc(-c4cccc5ccccc45)cc3)c3ccc(-c4cccc5c4oc4ccccc45)cc3)c2)cc1]

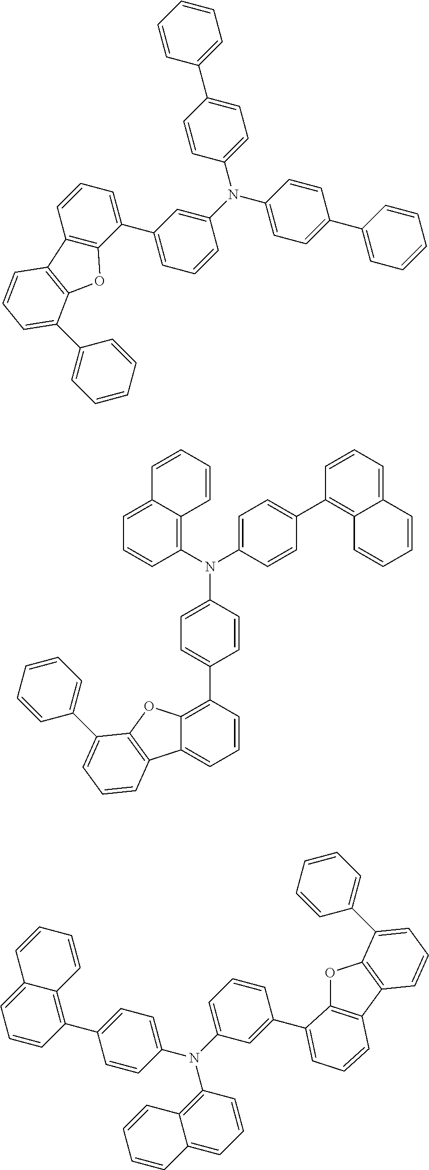 [SMILES: c1ccc(-c2ccc(N(c3ccc(-c4ccccc4)cc3)c3cccc(-c4cccc5c4oc4c(-c6ccccc6)cccc45)c3)cc2)cc1 ; c1ccc(-c2cccc3c2oc2c(-c4ccc(N(c5ccc(-c6cccc7ccccc67)cc5)c5cccc6ccccc56)cc4)cccc23)cc1 ; c1ccc(-c2cccc3c2oc2c(-c4cccc(N(c5ccc(-c6cccc7ccccc67)cc5)c5cccc6ccccc56)c4)cccc23)cc1]

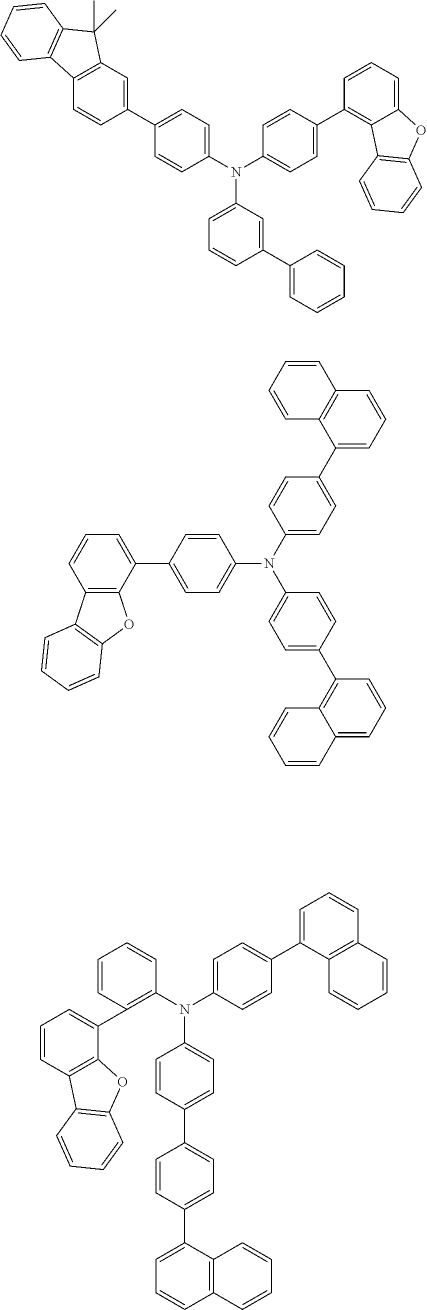 [SMILES: CC1(C)c2ccccc2-c2ccc(-c3ccc(N(c4ccc(-c5cccc6oc7ccccc7c56)cc4)c4cccc(-c5ccccc5)c4)cc3)cc21 ; c1ccc2c(-c3ccc(N(c4ccc(-c5cccc6ccccc56)cc4)c4ccc(-c5cccc6c5oc5ccccc56)cc4)cc3)cccc2c1 ; c1ccc(N(c2ccc(-c3ccc(-c4cccc5ccccc45)cc3)cc2)c2ccc(-c3cccc4ccccc34)cc2)c(-c2cccc3c2oc2ccccc23)c1]

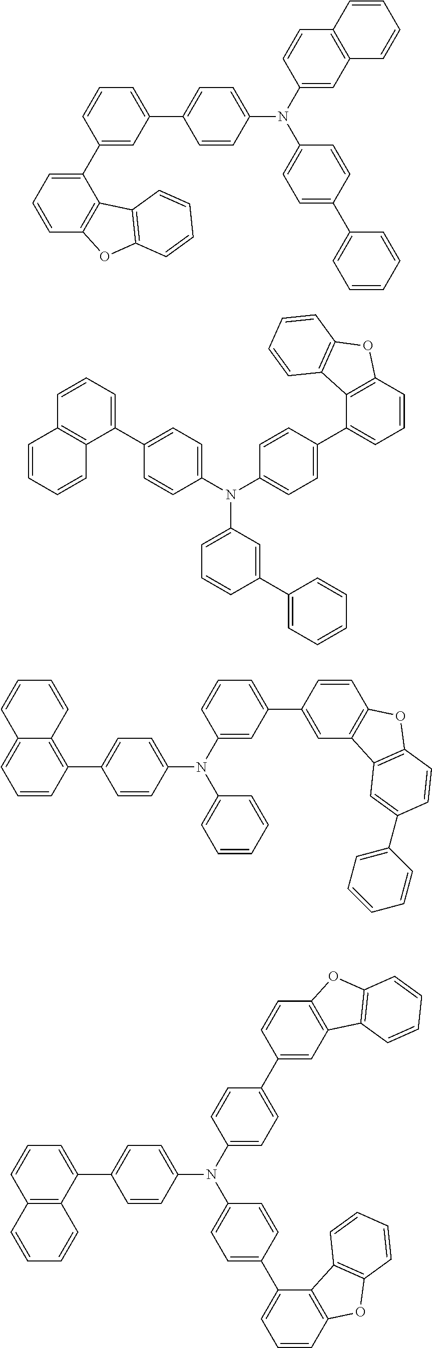

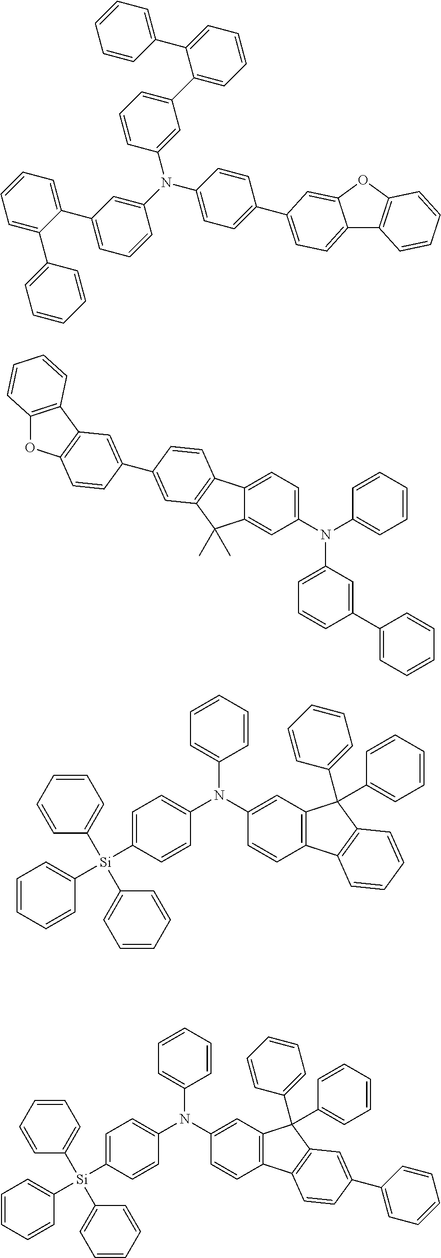

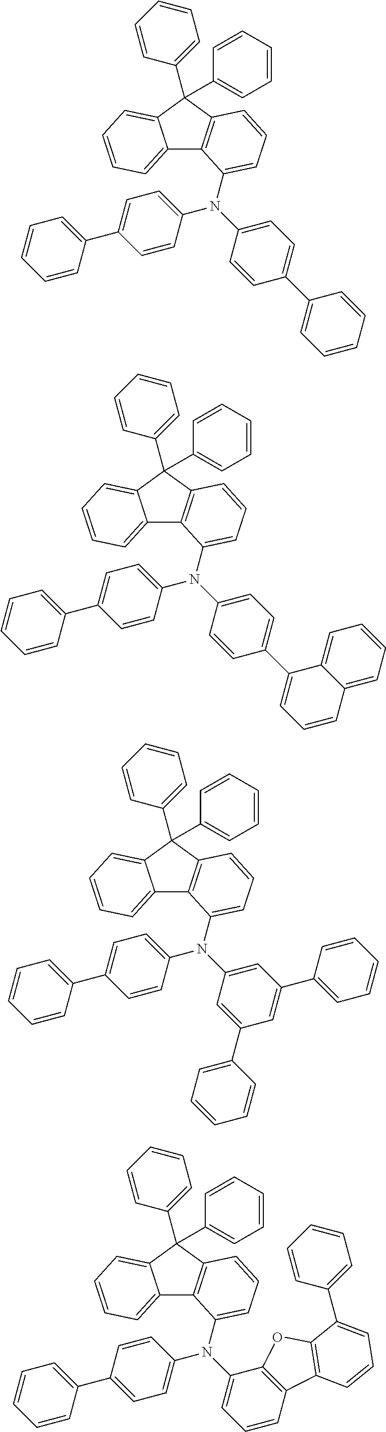

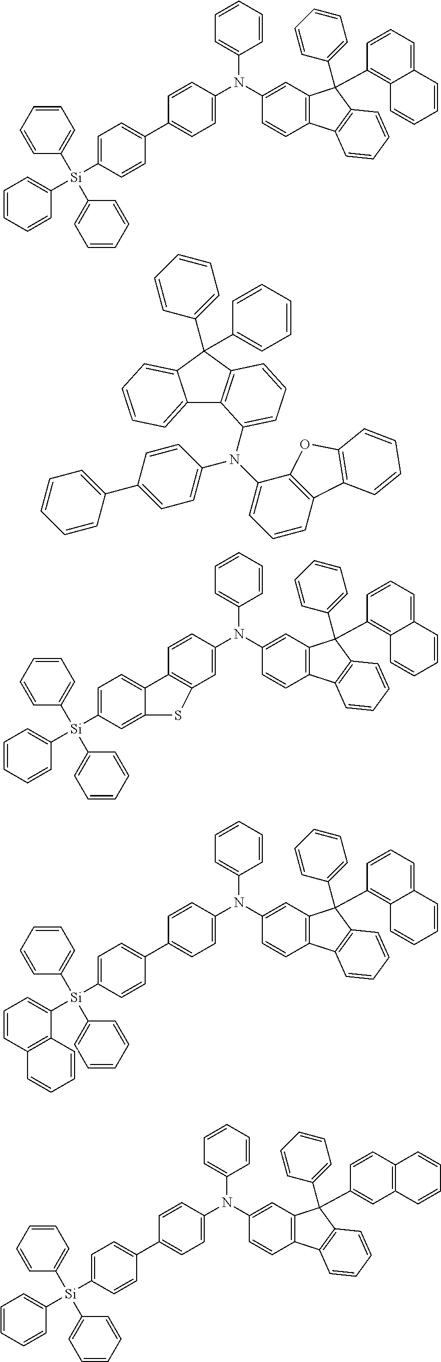

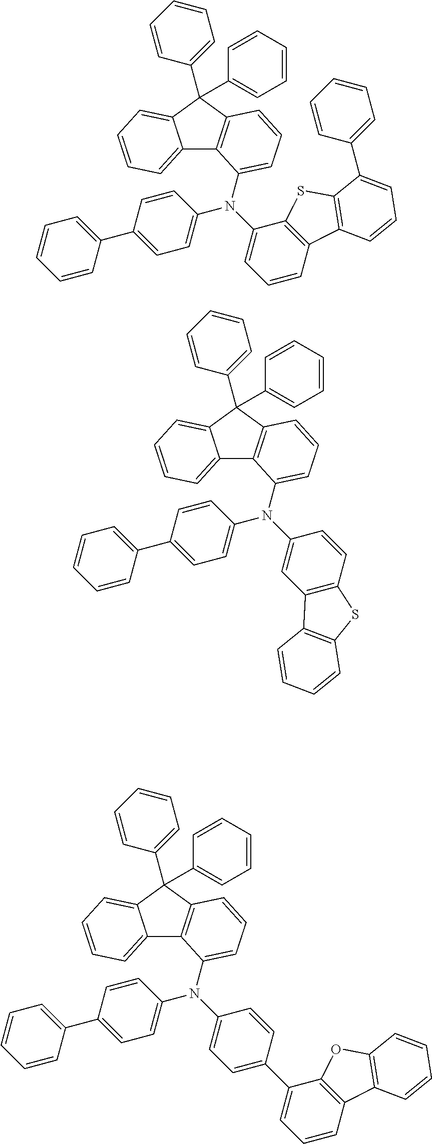

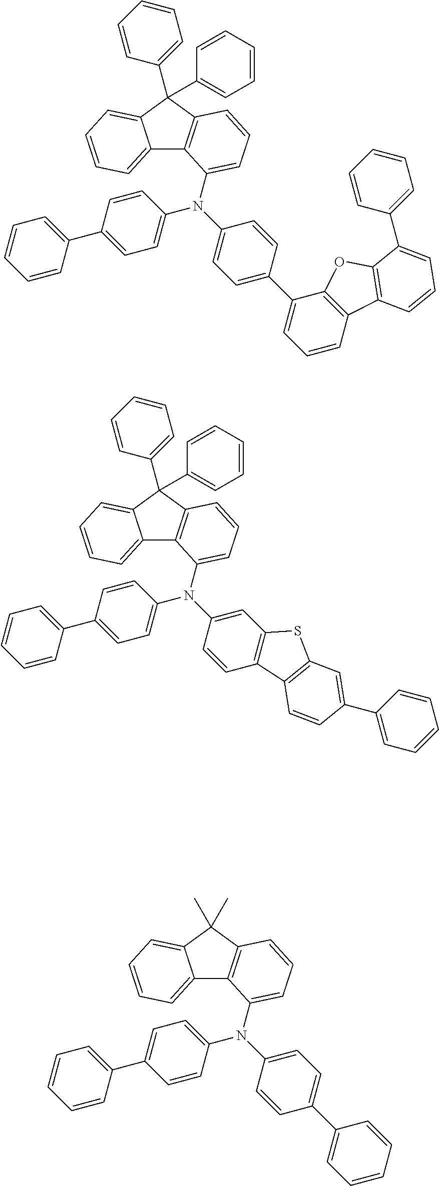 [SMILES: c1ccc(-c2ccc(N(c3ccc(-c4cccc5c4oc4c(-c6ccccc6)cccc45)cc3)c3cccc4c3-c3ccccc3C4(c3ccccc3)c3ccccc3)cc2)cc1 ; c1ccc(-c2ccc(N(c3ccc4c(c3)sc3cc(-c5ccccc5)ccc34)c3cccc4c3-c3ccccc3C4(c3ccccc3)c3ccccc3)cc2)cc1 ; CC1(C)c2ccccc2-c2c(N(c3ccc(-c4ccccc4)cc3)c3ccc(-c4ccccc4)cc3)cccc21]

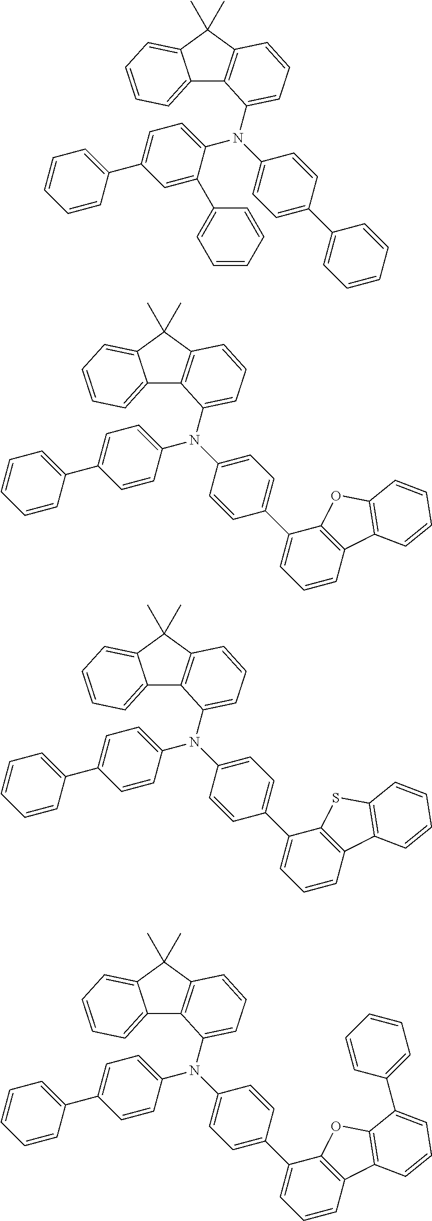 [SMILES: CC1(C)c2ccccc2-c2c(N(c3ccc(-c4ccccc4)cc3)c3ccc(-c4ccccc4)cc3-c3ccccc3)cccc21 ; CC1(C)c2ccccc2-c2c(N(c3ccc(-c4ccccc4)cc3)c3ccc(-c4cccc5c4oc4ccccc45)cc3)cccc21 ; CC1(C)c2ccccc2-c2c(N(c3ccc(-c4ccccc4)cc3)c3ccc(-c4cccc5c4sc4ccccc45)cc3)cccc21 ; CC1(C)c2ccccc2-c2c(N(c3ccc(-c4ccccc4)cc3)c3ccc(-c4cccc5c4oc4c(-c6ccccc6)cccc45)cc3)cccc21]

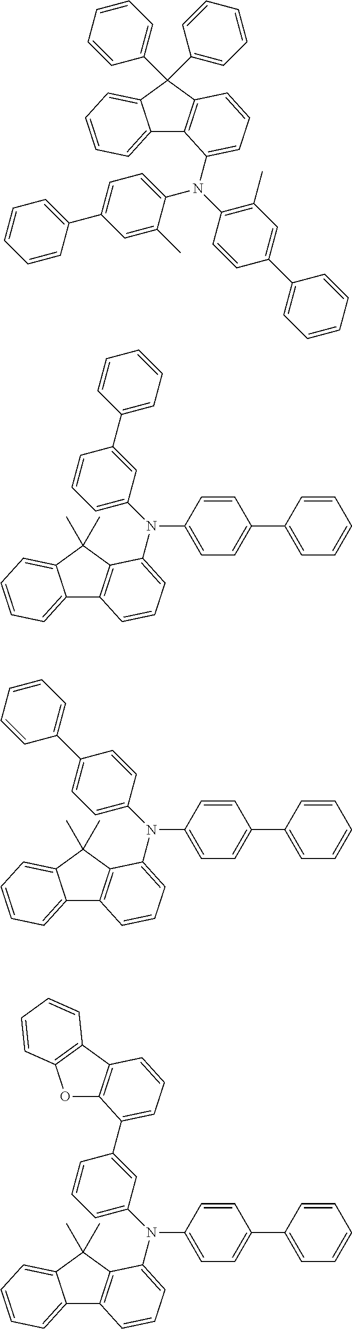 [SMILES: Cc1cc(-c2ccccc2)ccc1N(c1ccc(-c2ccccc2)cc1C)c1cccc2c1-c1ccccc1C2(c1ccccc1)c1ccccc1 ; CC1(C)c2ccccc2-c2cccc(N(c3ccc(-c4ccccc4)cc3)c3cccc(-c4ccccc4)c3)c21 ; CC1(C)c2ccccc2-c2cccc(N(c3ccc(-c4ccccc4)cc3)c3ccc(-c4ccccc4)cc3)c21 ; CC1(C)c2ccccc2-c2cccc(N(c3ccc(-c4ccccc4)cc3)c3cccc(-c4cccc5c4oc4ccccc45)c3)c21]

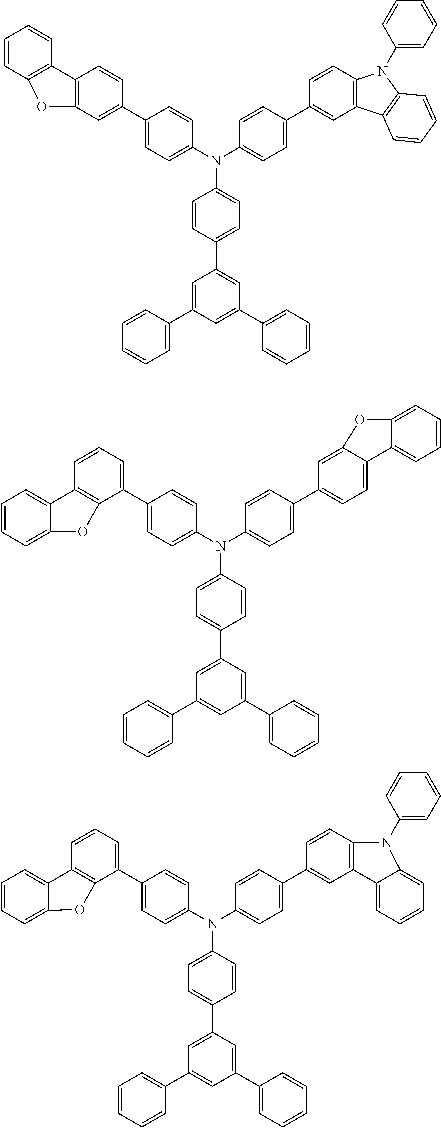 [SMILES: c1ccc(-c2cc(-c3ccccc3)cc(-c3ccc(N(c4ccc(-c5ccc6c(c5)oc5ccccc56)cc4)c4ccc(-c5ccc6c(c5)c5ccccc5n6-c5ccccc5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6c(c5)c5ccccc5n6-c5ccccc5)cc4)c4ccc(-c5cccc6c5oc5ccccc56)cc4)cc3)c2)cc1]

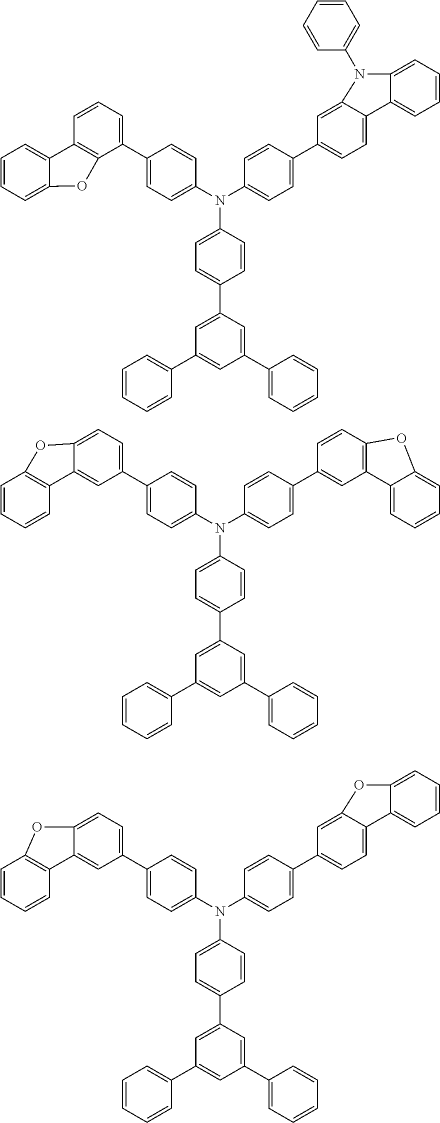 [SMILES: c1ccc(-c2cc(-c3ccccc3)cc(-c3ccc(N(c4ccc(-c5ccc6c7ccccc7n(-c7ccccc7)c6c5)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6oc7ccccc7c6c5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5ccc6oc7ccccc7c6c5)cc4)cc3)c2)cc1]

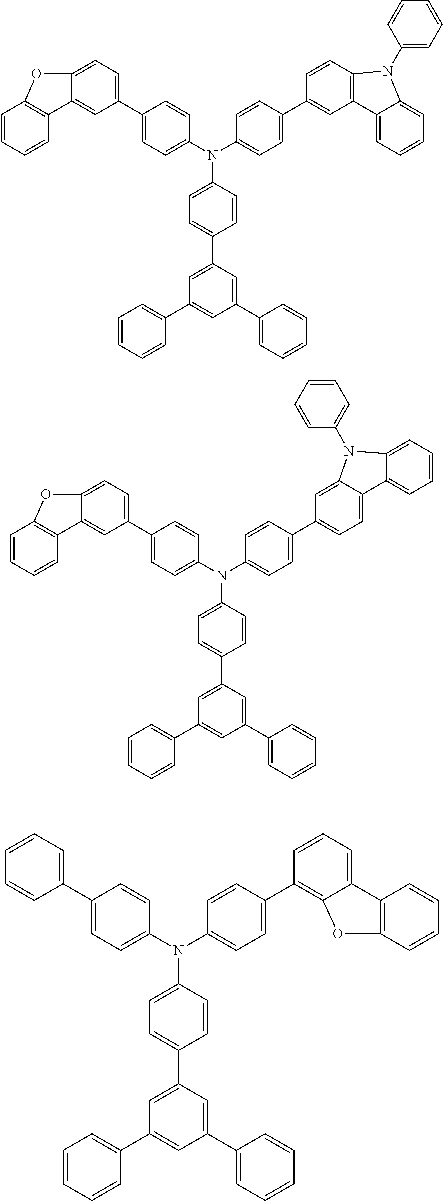

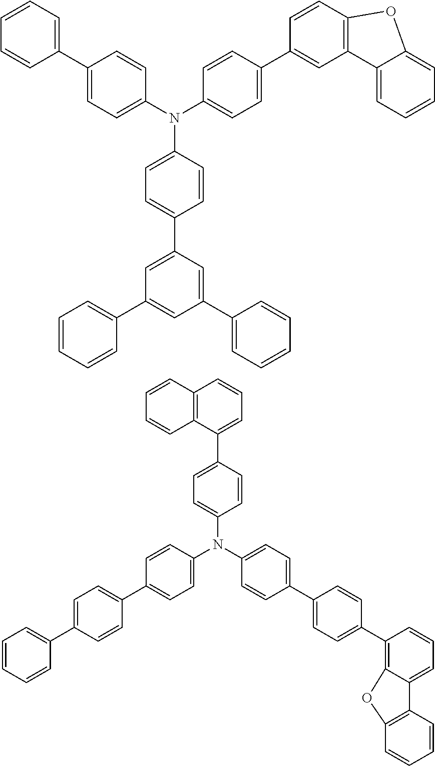

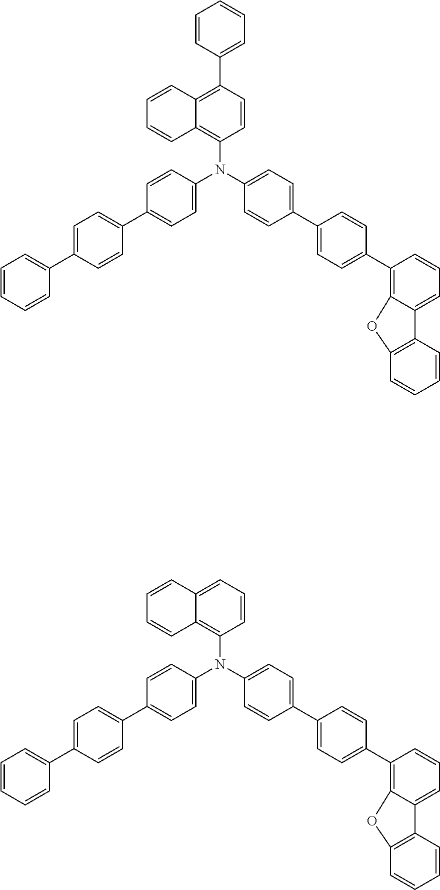 [SMILES: c1ccc(-c2ccc(-c3ccc(N(c4ccc(-c5ccc(-c6cccc7c6oc6ccccc67)cc5)cc4)c4ccc(-c5ccccc5)c5ccccc45)cc3)cc2)cc1 ; c1ccc(-c2ccc(-c3ccc(N(c4ccc(-c5ccc(-c6cccc7c6oc6ccccc67)cc5)cc4)c4cccc5ccccc45)cc3)cc2)cc1]

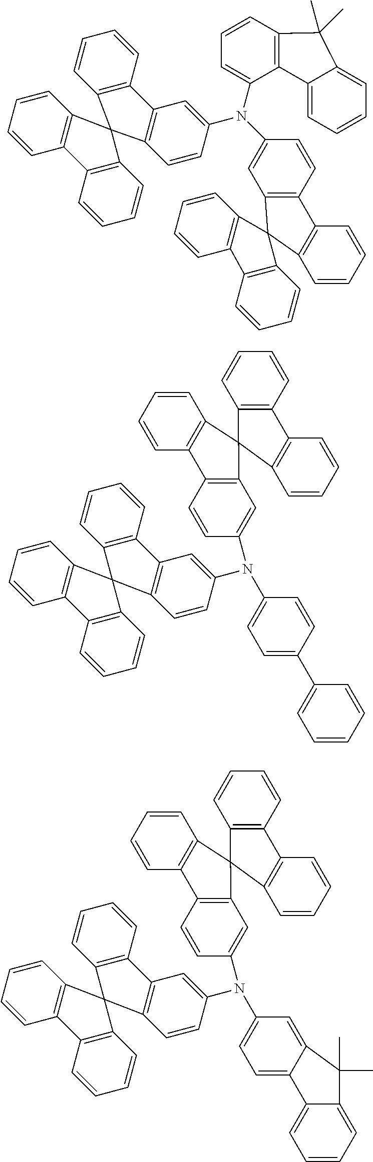

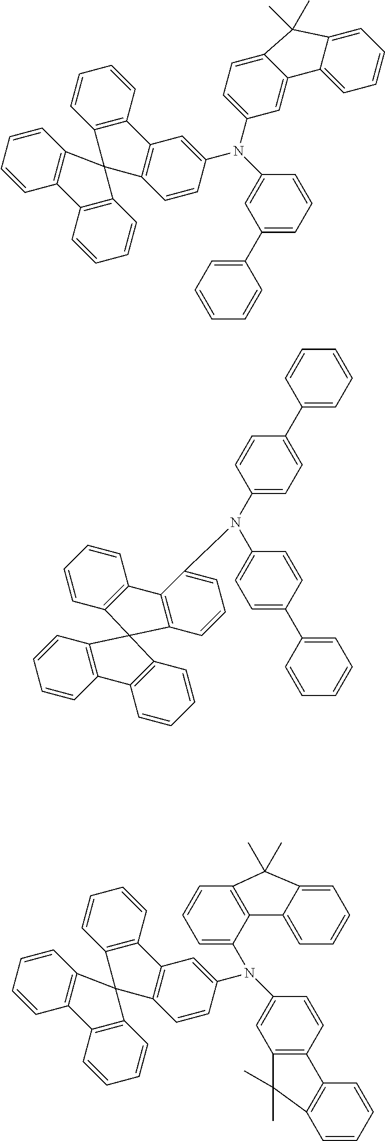 [SMILES: CC1(C)c2ccccc2-c2cc(N(c3cccc(-c4ccccc4)c3)c3ccc4c(c3)-c3ccccc3C43c4ccccc4-c4ccccc43)ccc21 ; c1ccc(-c2ccc(N(c3ccc(-c4ccccc4)cc3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3cccc4c3-c3ccccc3C4(C)C)cc21]

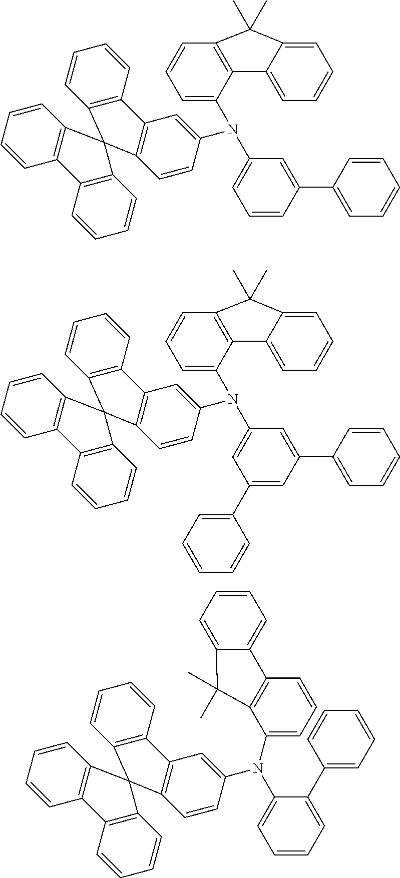

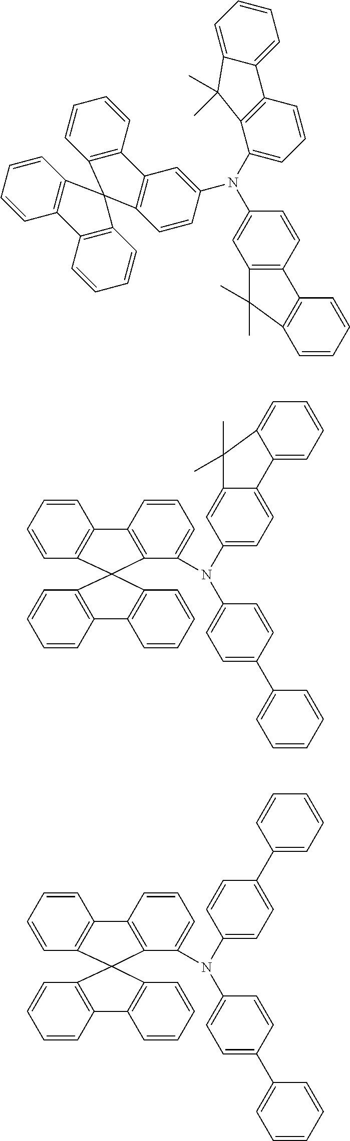

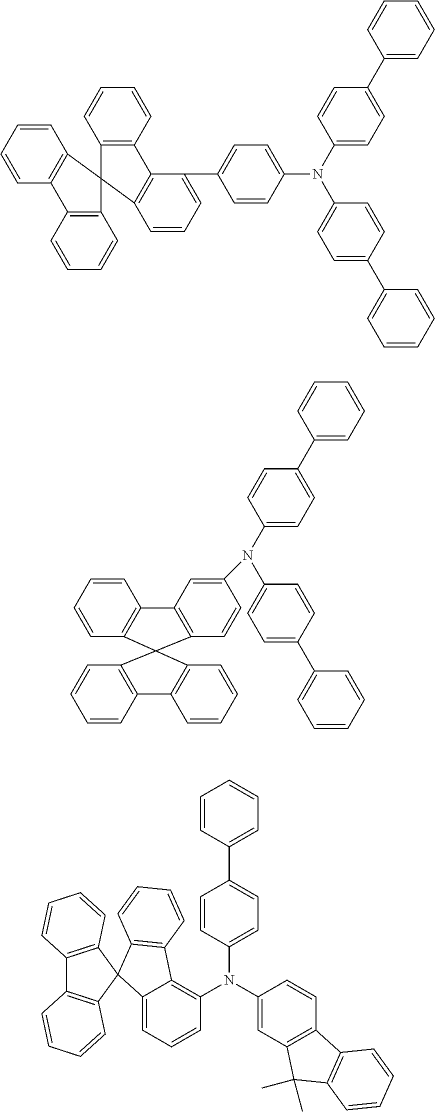 [SMILES: c1ccc(-c2ccc(N(c3ccc(-c4ccccc4)cc3)c3ccc(-c4cccc5c4-c4ccccc4C54c5ccccc5-c5ccccc54)cc3)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C43c4ccccc4-c4ccccc43)cc21]

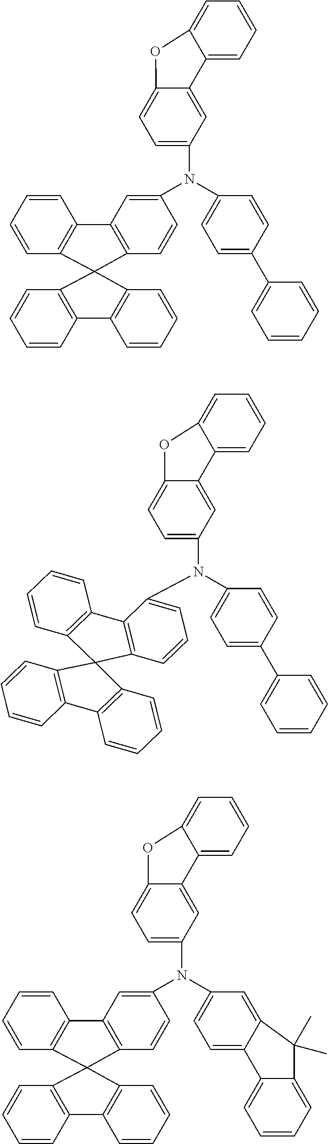 [SMILES: c1ccc(-c2ccc(N(c3ccc4c(c3)-c3ccccc3C43c4ccccc4-c4ccccc43)c3ccc4oc5ccccc5c4c3)cc2)cc1 ; c1ccc(-c2ccc(N(c3ccc4oc5ccccc5c4c3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3ccc4oc5ccccc5c4c3)cc21]

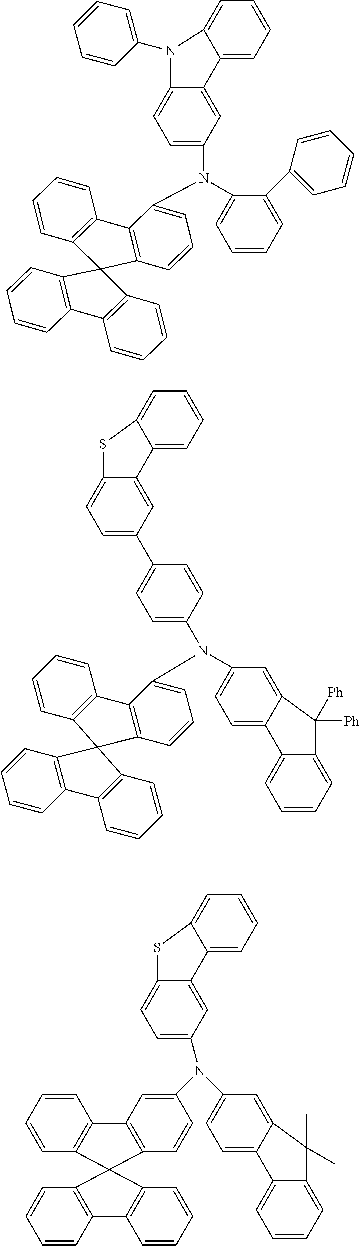

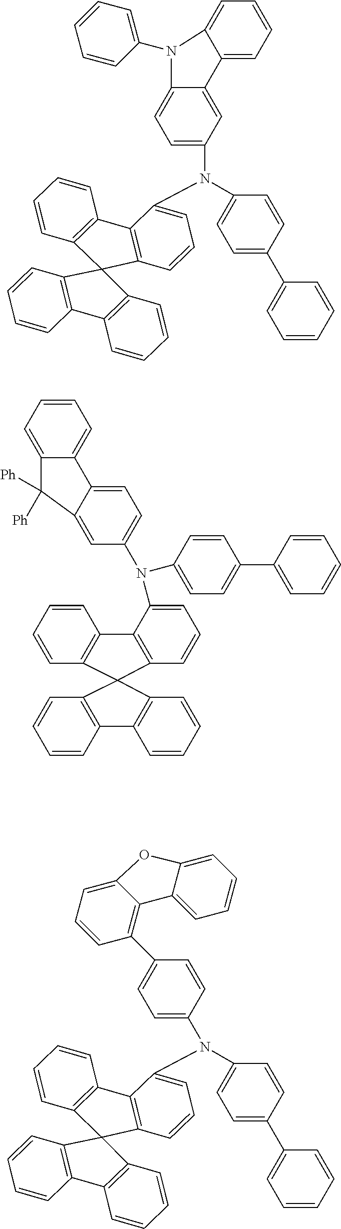 [SMILES: c1ccc(-c2ccc(N(c3ccc4c(c3)c3ccccc3n4-c3ccccc3)c3cccc4c3-c3ccccc3C43c4ccccc4-c4ccccc43)cc2)cc1 ; c1ccc(-c2ccc(N(c3ccc4c(c3)C(c3ccccc3)(c3ccccc3)c3ccccc3-4)c3cccc4c3-c3ccccc3C43c4ccccc4-c4ccccc43)cc2)cc1 ; c1ccc(-c2ccc(N(c3ccc(-c4cccc5oc6ccccc6c45)cc3)c3cccc4c3-c3ccccc3C43c4ccccc4-c4ccccc43)cc2)cc1]

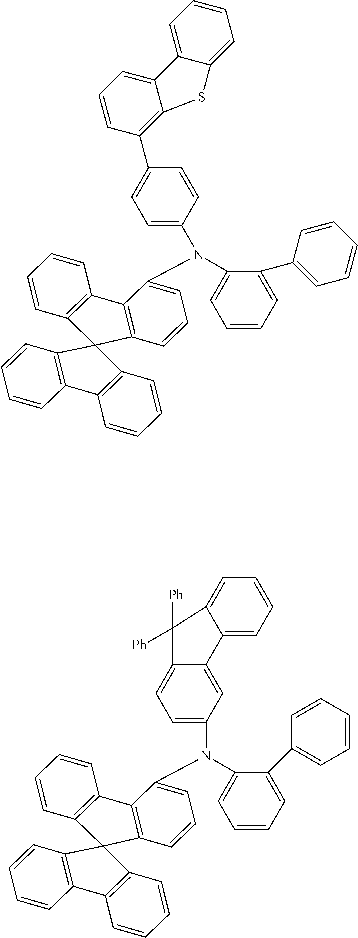 [SMILES: c1ccc(-c2ccccc2N(c2ccc(-c3cccc4c3sc3ccccc34)cc2)c2cccc3c2-c2ccccc2C32c3ccccc3-c3ccccc32)cc1 ; c1ccc(-c2ccccc2N(c2ccc3c(c2)-c2ccccc2C3(c2ccccc2)c2ccccc2)c2cccc3c2-c2ccccc2C32c3ccccc3-c3ccccc32)cc1]

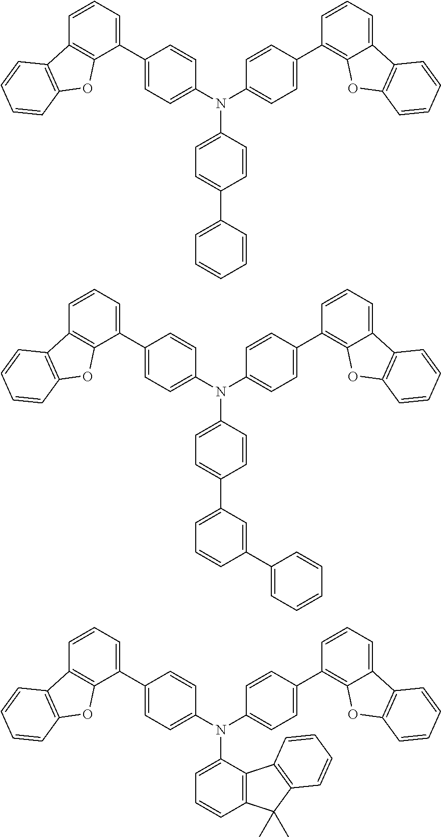

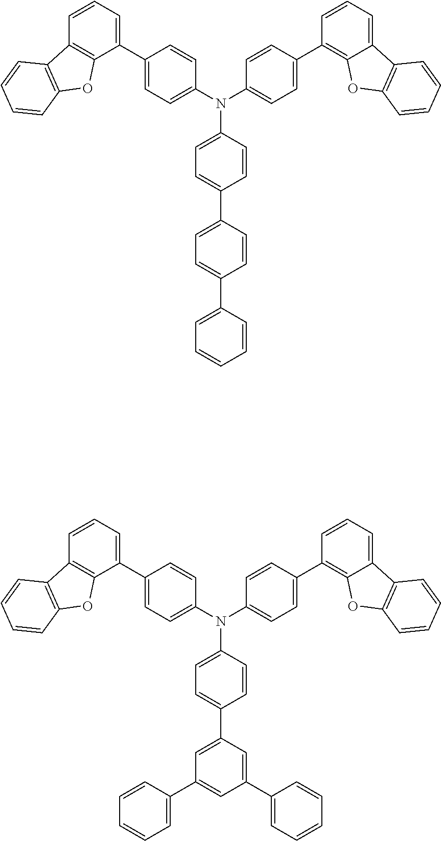 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

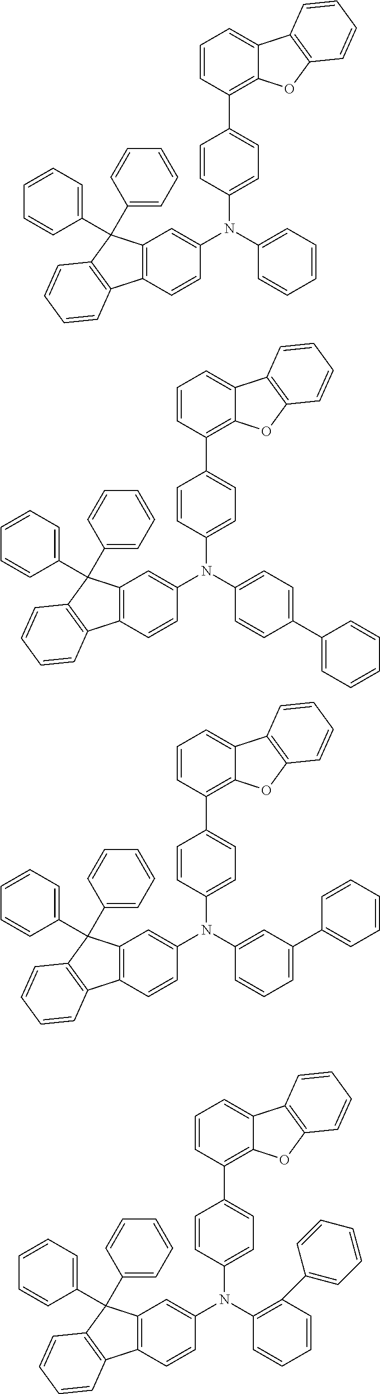

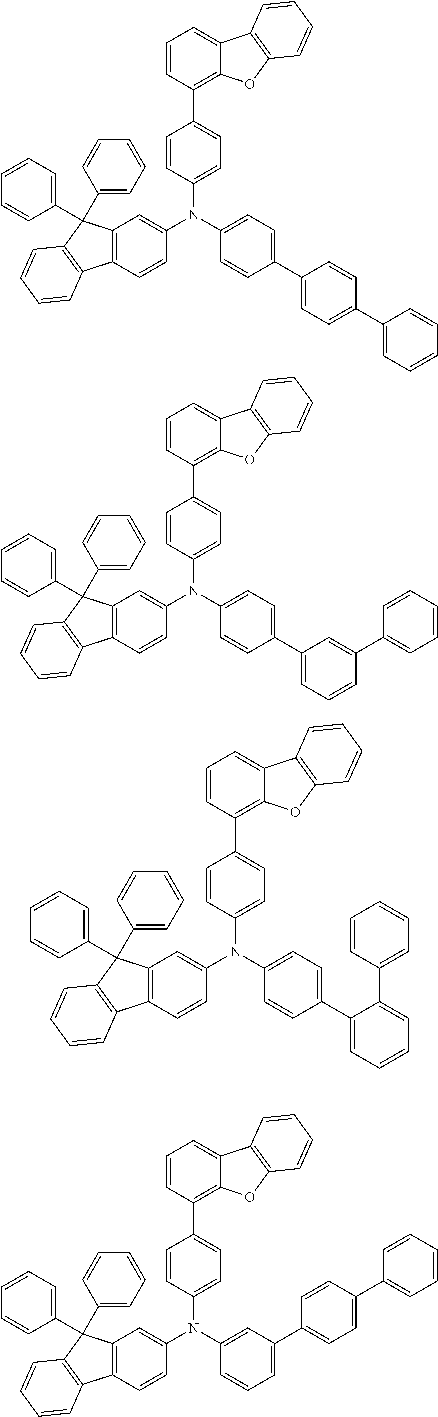

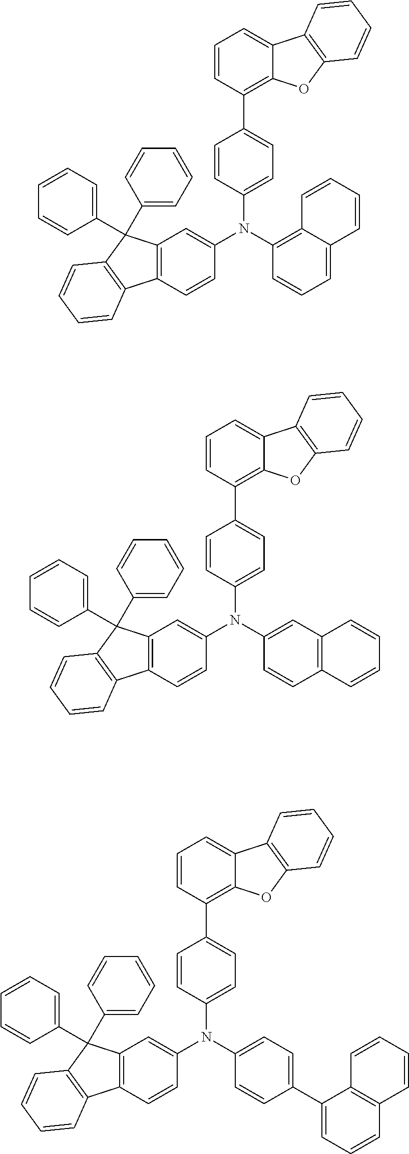 [SMILES: c1ccc(C2(c3ccccc3)c3ccccc3-c3ccc(N(c4ccc(-c5cccc6c5oc5ccccc56)cc4)c4cccc5ccccc45)cc32)cc1 ; c1ccc(C2(c3ccccc3)c3ccccc3-c3ccc(N(c4ccc(-c5cccc6c5oc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5oc5ccccc56)cc4)cc32)cc1]

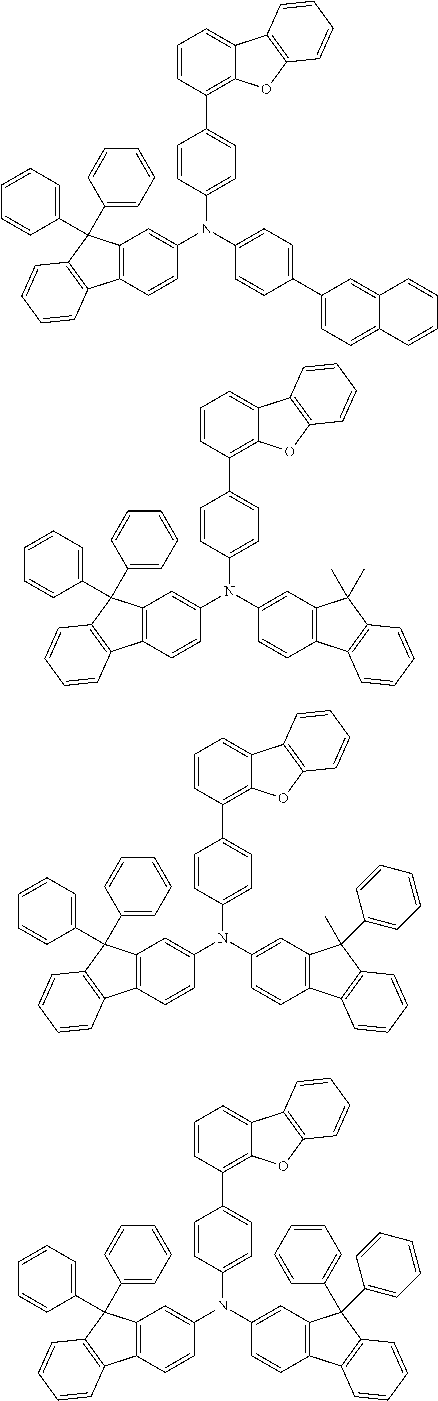

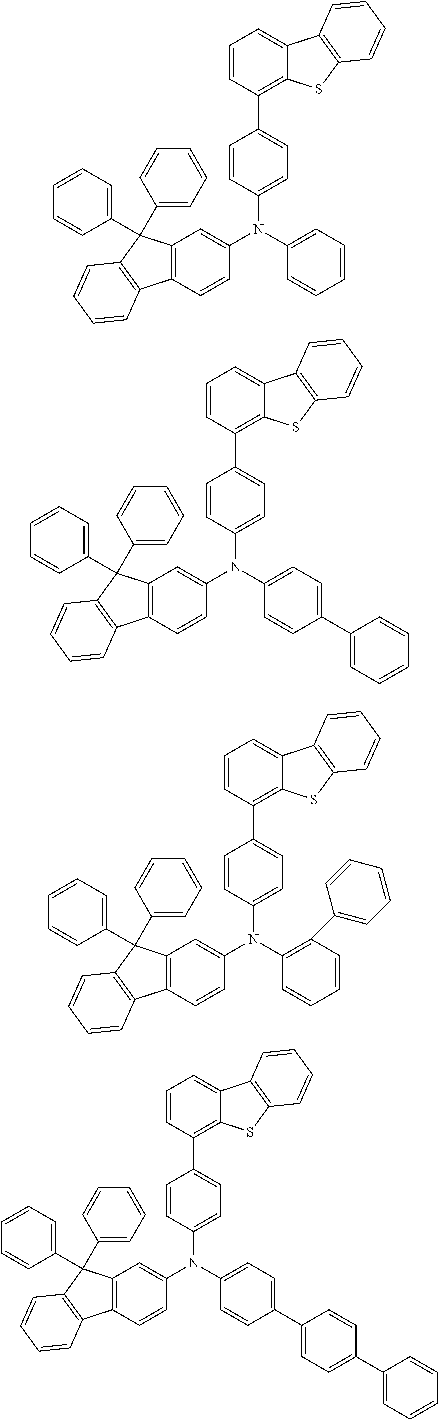

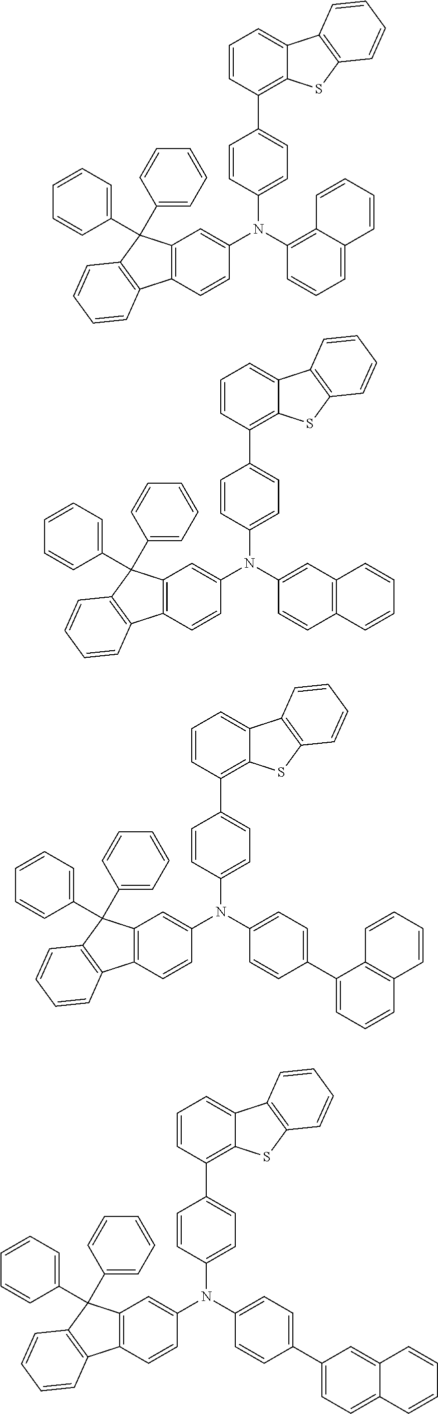

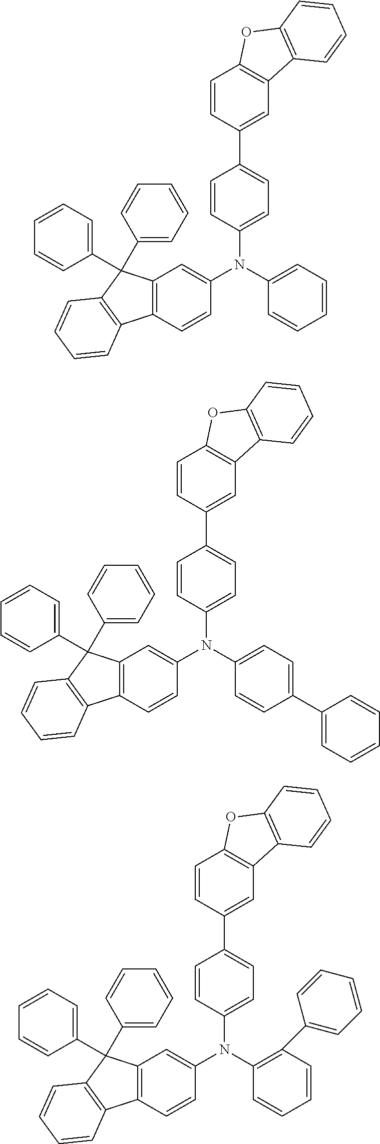

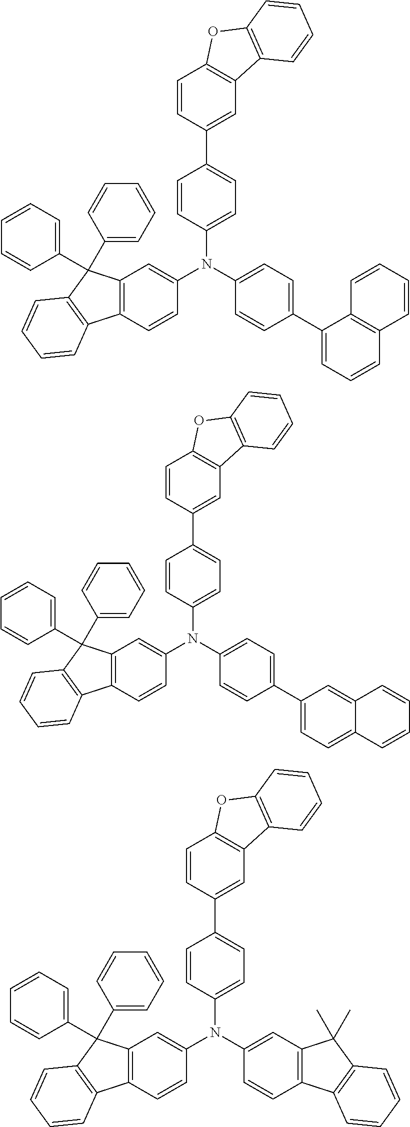

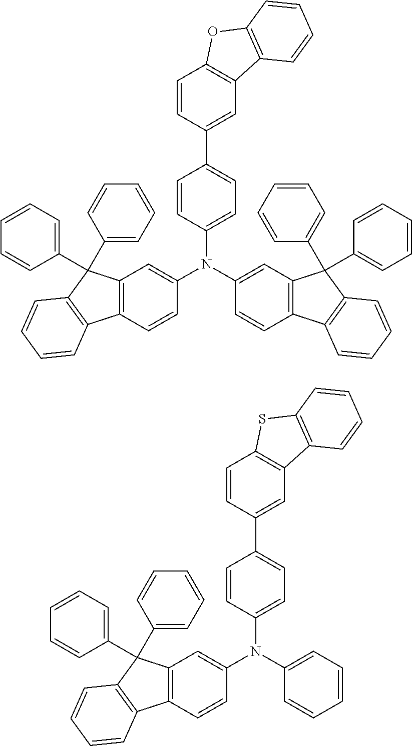

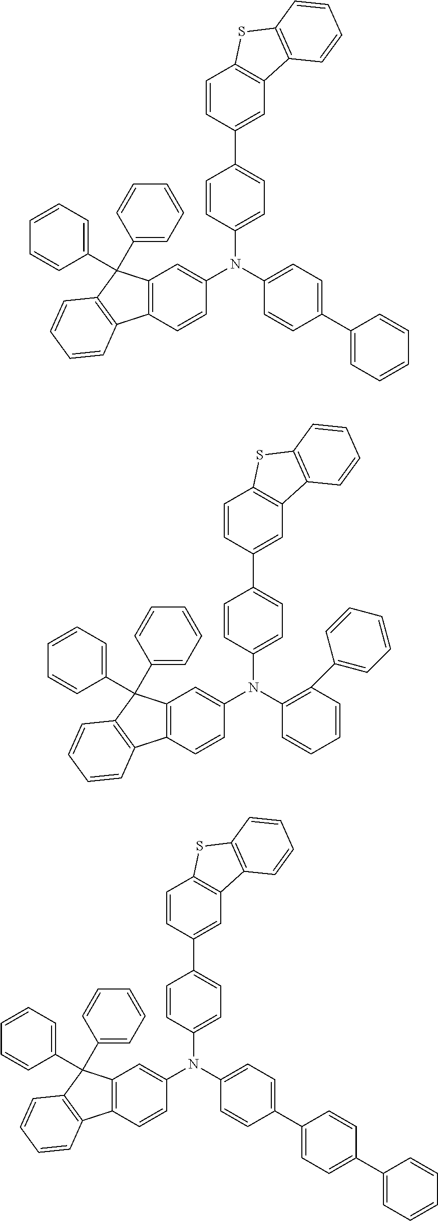 [SMILES: c1ccc(-c2ccc(N(c3ccc(-c4ccc5sc6ccccc6c5c4)cc3)c3ccc4c(c3)C(c3ccccc3)(c3ccccc3)c3ccccc3-4)cc2)cc1 ; c1ccc(-c2ccccc2N(c2ccc(-c3ccc4sc5ccccc5c4c3)cc2)c2ccc3c(c2)C(c2ccccc2)(c2ccccc2)c2ccccc2-3)cc1 ; c1ccc(-c2ccc(-c3ccc(N(c4ccc(-c5ccc6sc7ccccc7c6c5)cc4)c4ccc5c(c4)C(c4ccccc4)(c4ccccc4)c4ccccc4-5)cc3)cc2)cc1]

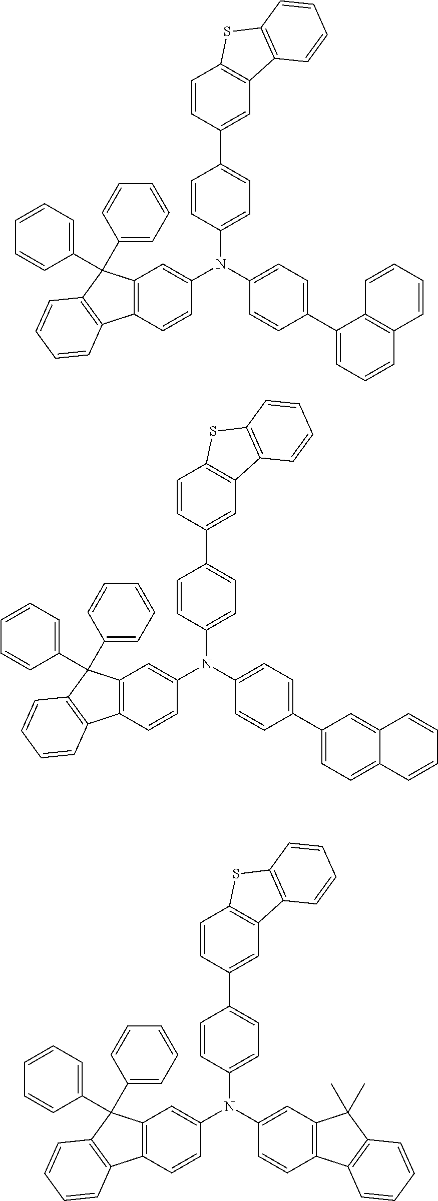 [SMILES: c1ccc(C2(c3ccccc3)c3ccccc3-c3ccc(N(c4ccc(-c5ccc6sc7ccccc7c6c5)cc4)c4ccc(-c5cccc6ccccc56)cc4)cc32)cc1 ; c1ccc(C2(c3ccccc3)c3ccccc3-c3ccc(N(c4ccc(-c5ccc6ccccc6c5)cc4)c4ccc(-c5ccc6sc7ccccc7c6c5)cc4)cc32)cc1 ; CC1(C)c2ccccc2-c2ccc(N(c3ccc(-c4ccc5sc6ccccc6c5c4)cc3)c3ccc4c(c3)C(c3ccccc3)(c3ccccc3)c3ccccc3-4)cc21]

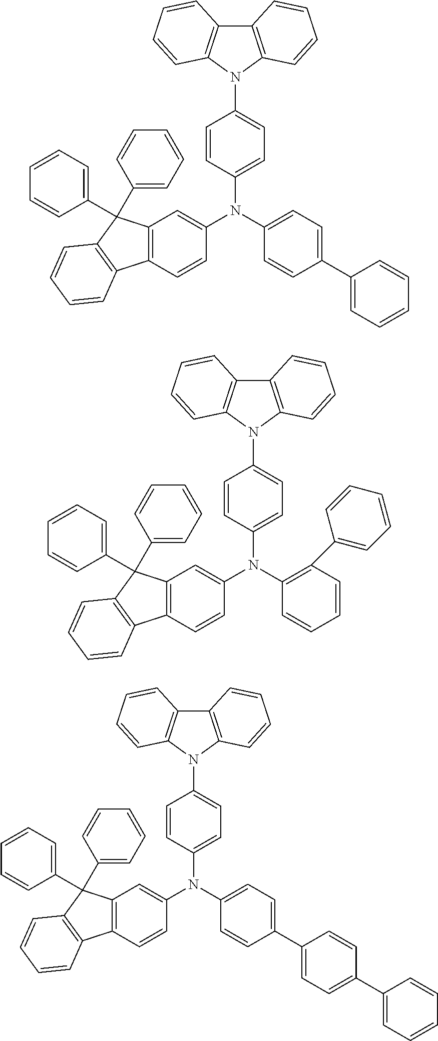

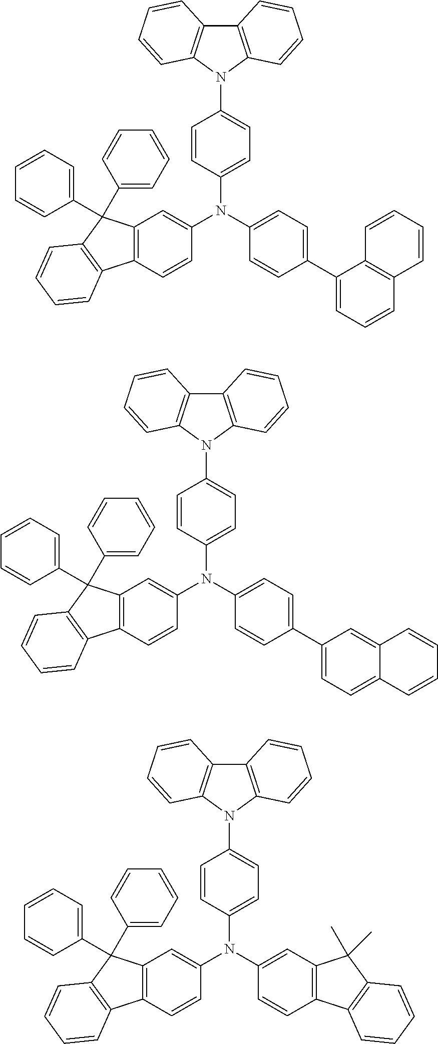 [SMILES: c1ccc(C2(c3ccccc3)c3ccccc3-c3ccc(N(c4ccc(-c5cccc6ccccc56)cc4)c4ccc(-n5c6ccccc6c6ccccc65)cc4)cc32)cc1 ; c1ccc(C2(c3ccccc3)c3ccccc3-c3ccc(N(c4ccc(-c5ccc6ccccc6c5)cc4)c4ccc(-n5c6ccccc6c6ccccc65)cc4)cc32)cc1 ; CC1(C)c2ccccc2-c2ccc(N(c3ccc(-n4c5ccccc5c5ccccc54)cc3)c3ccc4c(c3)C(c3ccccc3)(c3ccccc3)c3ccccc3-4)cc21]

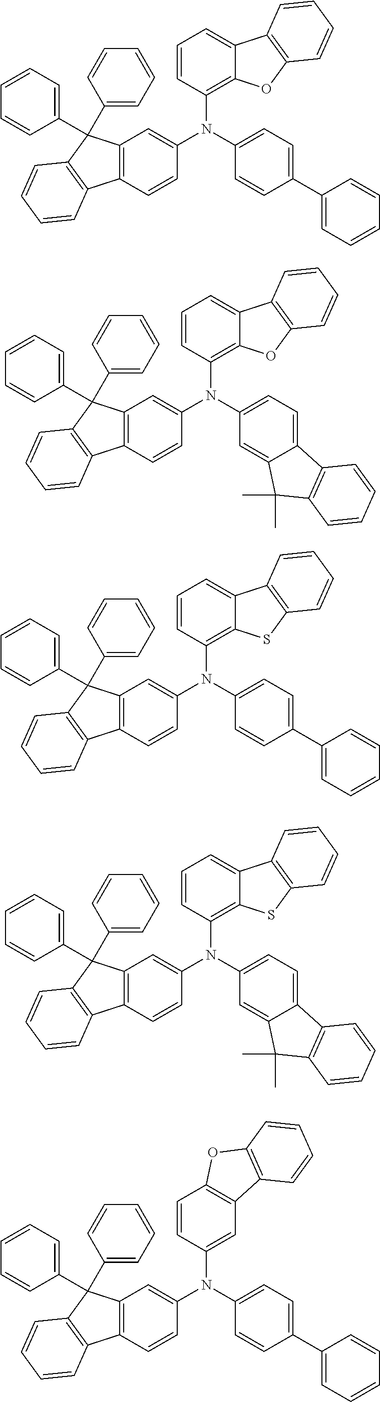

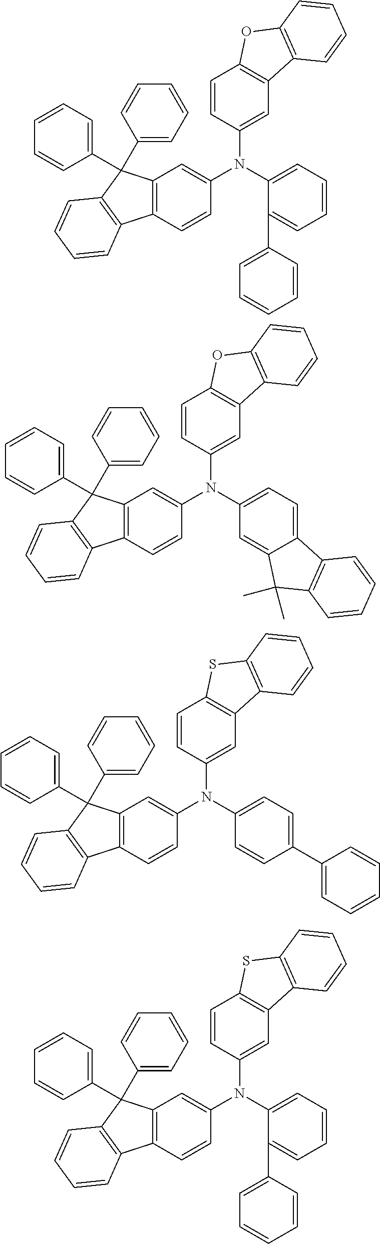

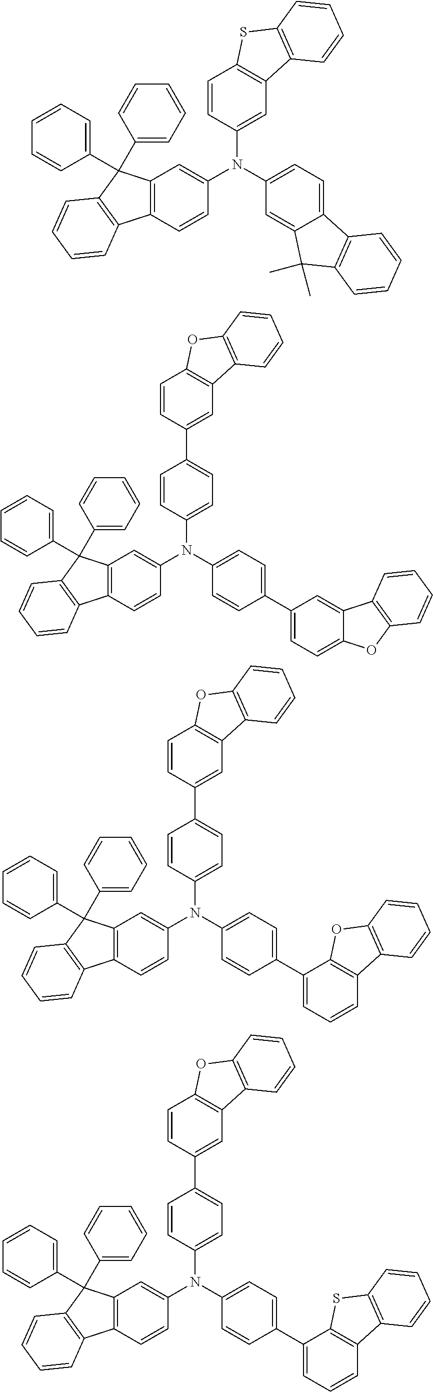

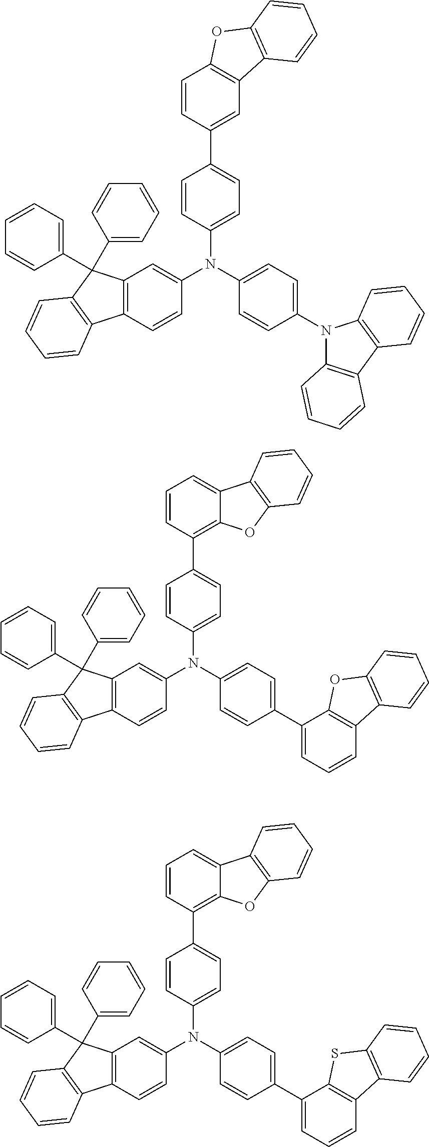

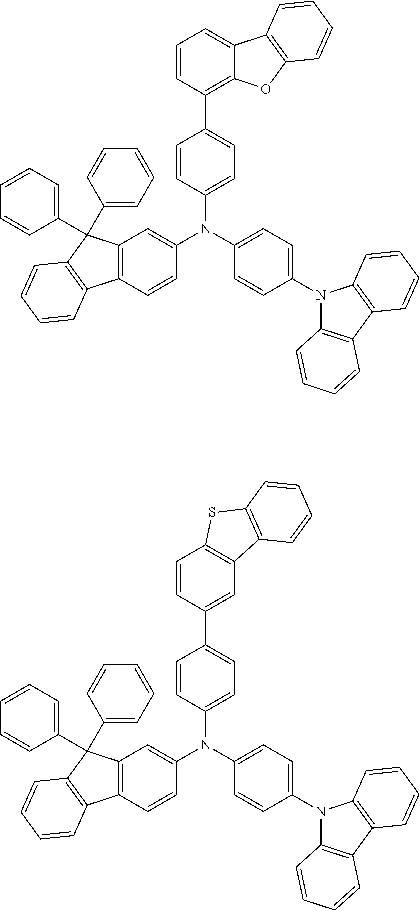 [SMILES: c1ccc(C2(c3ccccc3)c3ccccc3-c3ccc(N(c4ccc(-c5cccc6c5oc5ccccc56)cc4)c4ccc(-n5c6ccccc6c6ccccc65)cc4)cc32)cc1 ; c1ccc(C2(c3ccccc3)c3ccccc3-c3ccc(N(c4ccc(-c5ccc6sc7ccccc7c6c5)cc4)c4ccc(-n5c6ccccc6c6ccccc65)cc4)cc32)cc1]

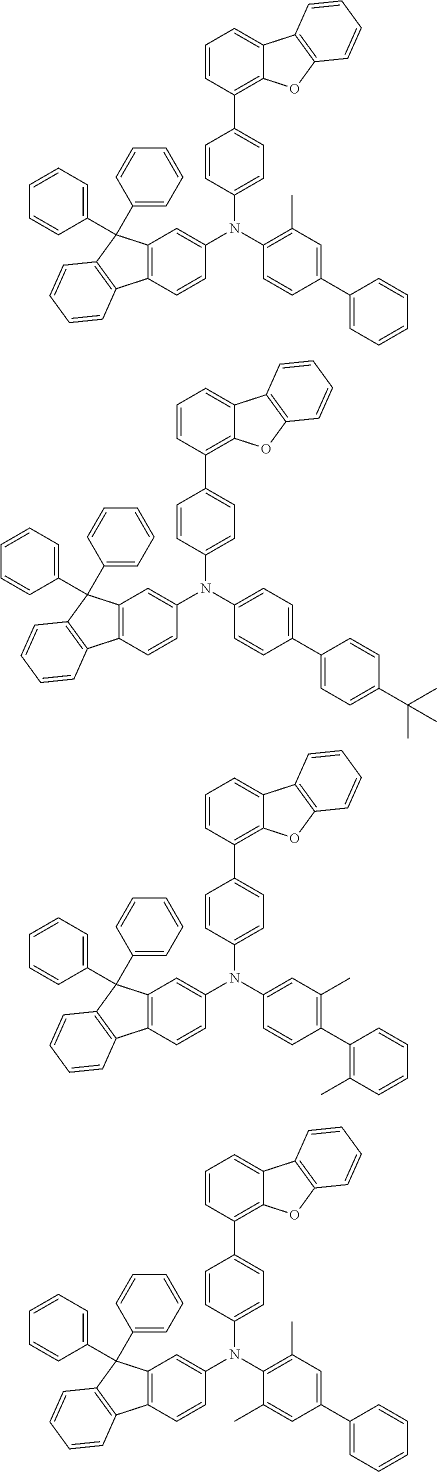

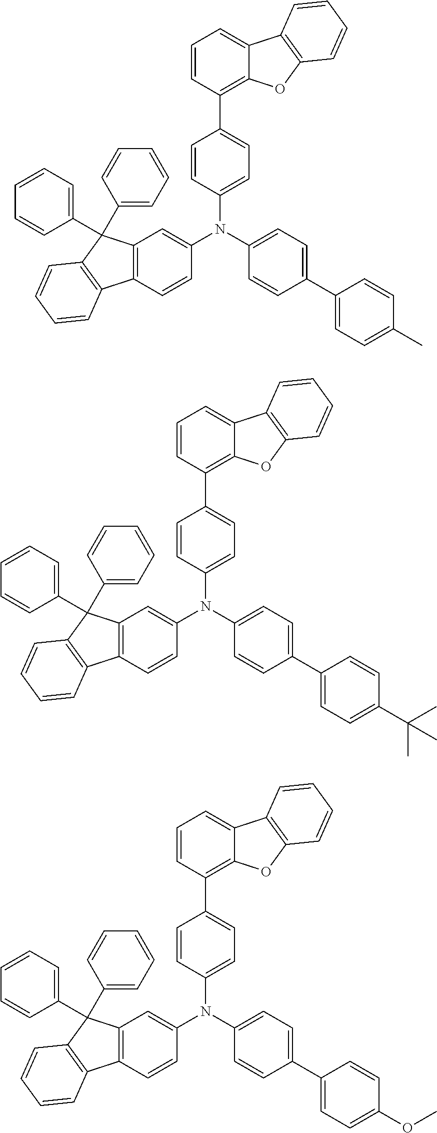 [SMILES: Cc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; COc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1]

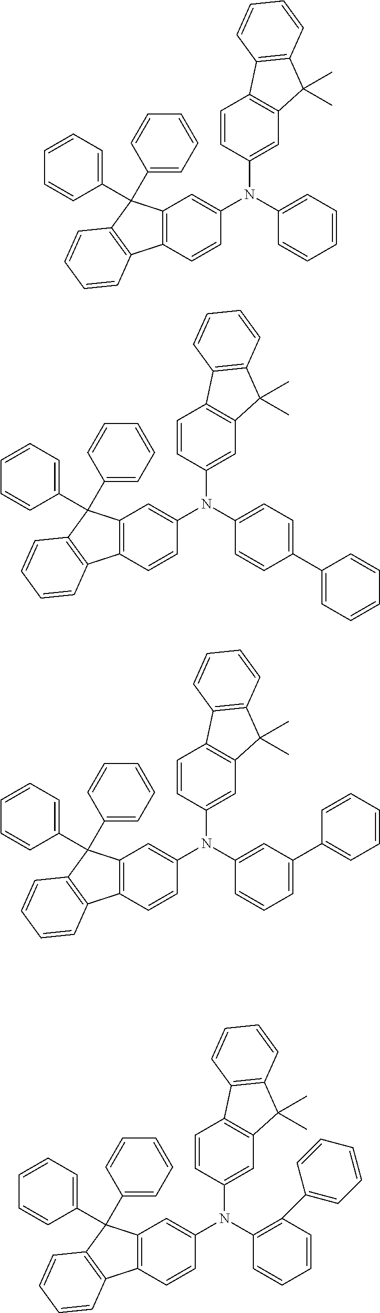 [SMILES: CC1(C)c2ccccc2-c2ccc(N(c3ccccc3)c3ccc4c(c3)C(c3ccccc3)(c3ccccc3)c3ccccc3-4)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3cccc(-c4ccccc4)c3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21]

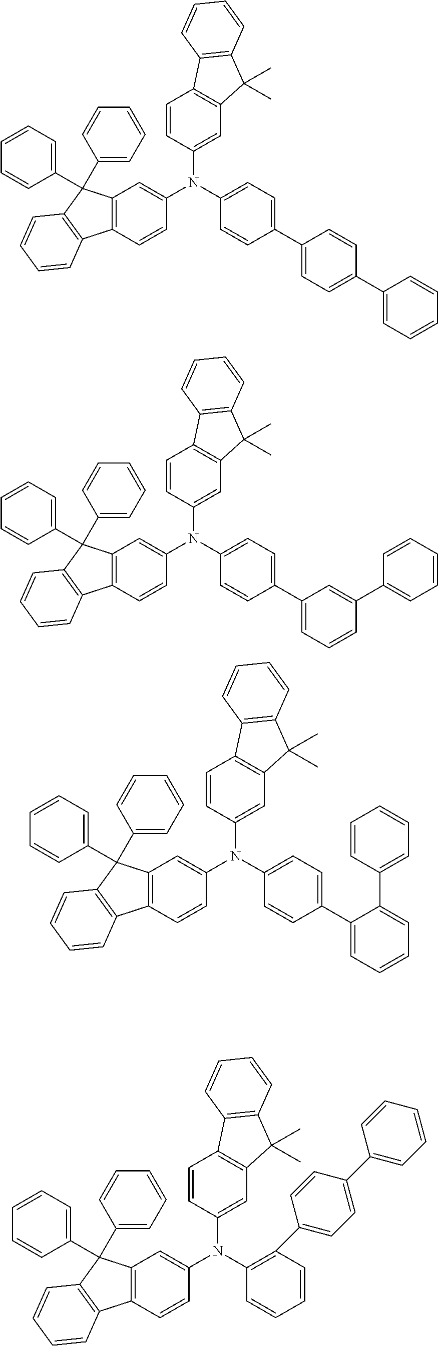

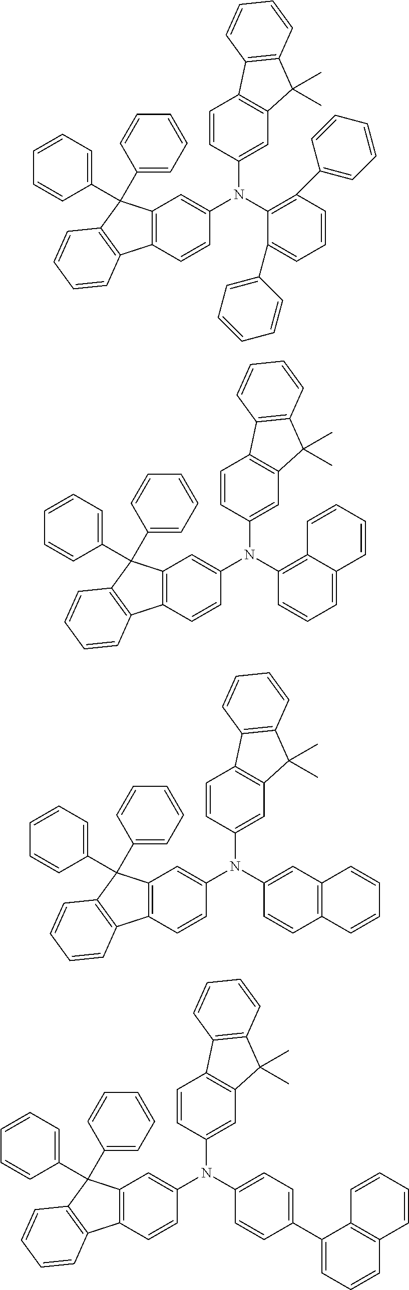

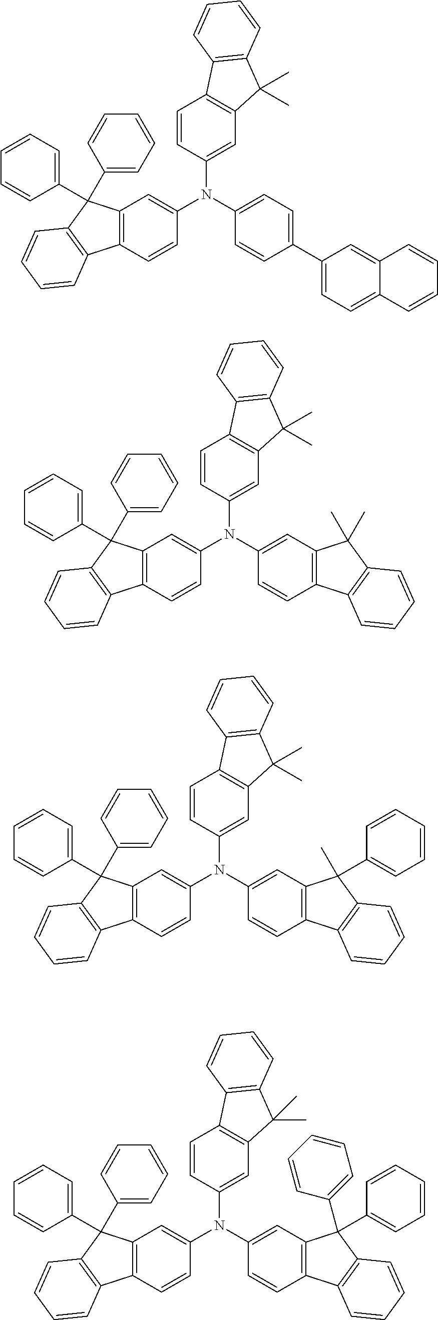 [SMILES: CC1(C)c2ccccc2-c2ccc(N(c3ccc(-c4ccc5ccccc5c4)cc3)c3ccc4c(c3)C(c3ccccc3)(c3ccccc3)c3ccccc3-4)cc21 ; CC1(C)c2ccccc2-c2ccc(N(c3ccc4c(c3)C(C)(C)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(C)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

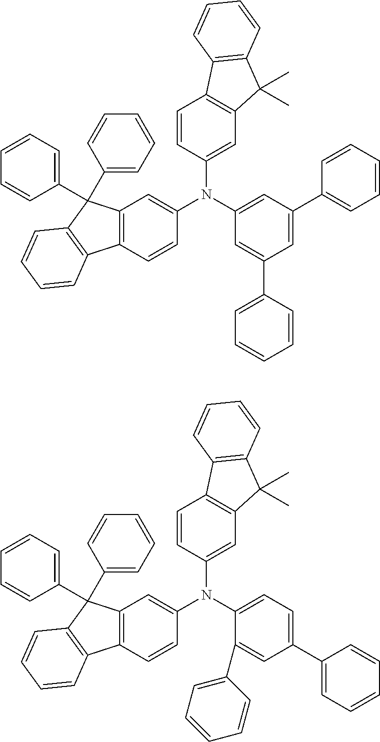

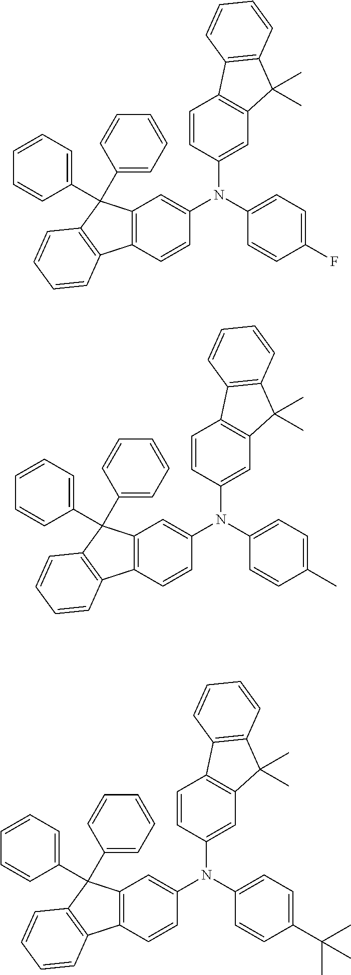 [SMILES: CC1(C)c2ccccc2-c2ccc(N(c3ccc(F)cc3)c3ccc4c(c3)C(c3ccccc3)(c3ccccc3)c3ccccc3-4)cc21 ; Cc1ccc(N(c2ccc3c(c2)C(C)(C)c2ccccc2-3)c2ccc3c(c2)C(c2ccccc2)(c2ccccc2)c2ccccc2-3)cc1 ; CC(C)(C)c1ccc(N(c2ccc3c(c2)C(C)(C)c2ccccc2-3)c2ccc3c(c2)C(c2ccccc2)(c2ccccc2)c2ccccc2-3)cc1]

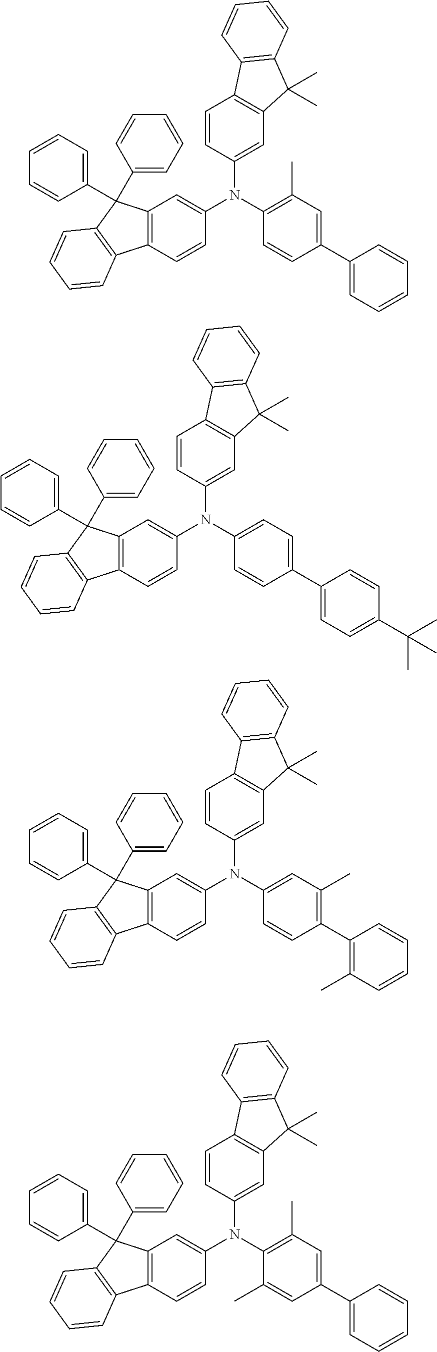 [SMILES: Cc1cc(-c2ccccc2)ccc1N(c1ccc2c(c1)C(C)(C)c1ccccc1-2)c1ccc2c(c1)C(c1ccccc1)(c1ccccc1)c1ccccc1-2 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(C)(C)c2ccccc2-3)c2ccc3c(c2)C(c2ccccc2)(c2ccccc2)c2ccccc2-3)cc1C ; Cc1cc(-c2ccccc2)cc(C)c1N(c1ccc2c(c1)C(C)(C)c1ccccc1-2)c1ccc2c(c1)C(c1ccccc1)(c1ccccc1)c1ccccc1-2]

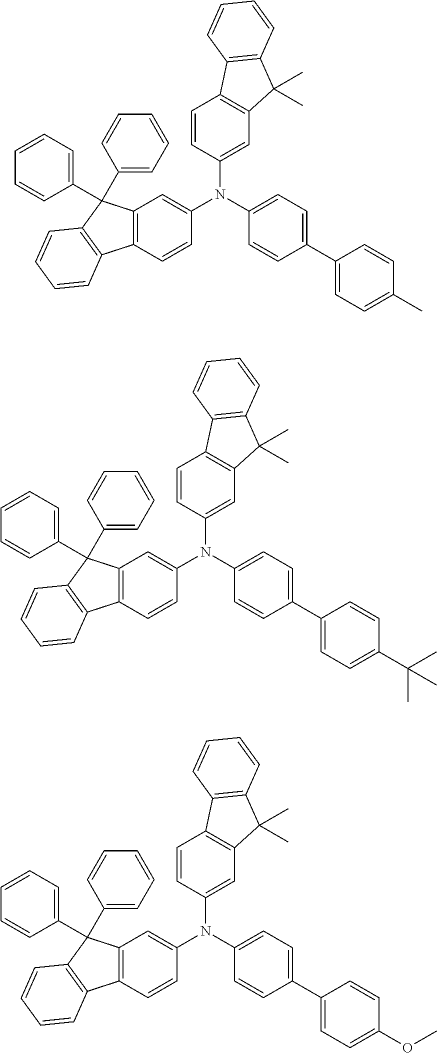 [SMILES: Cc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1]

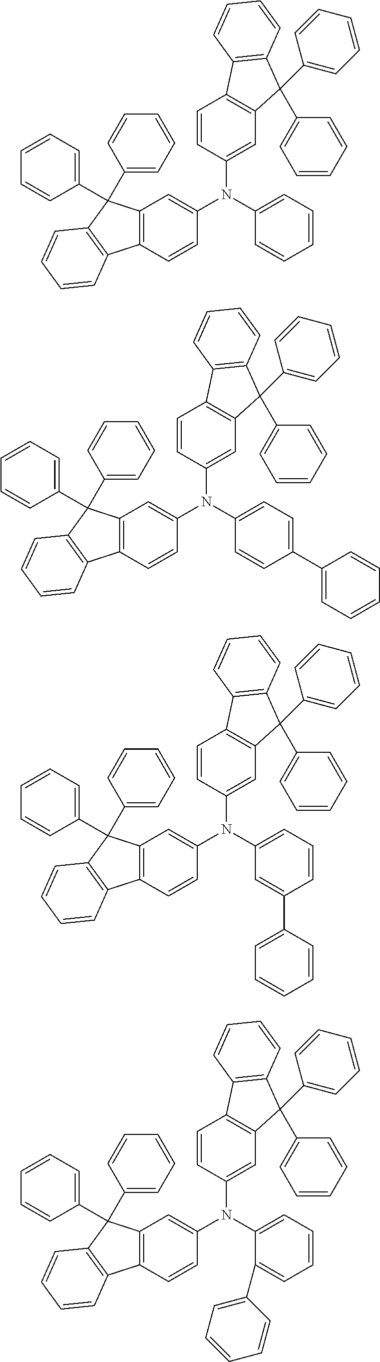

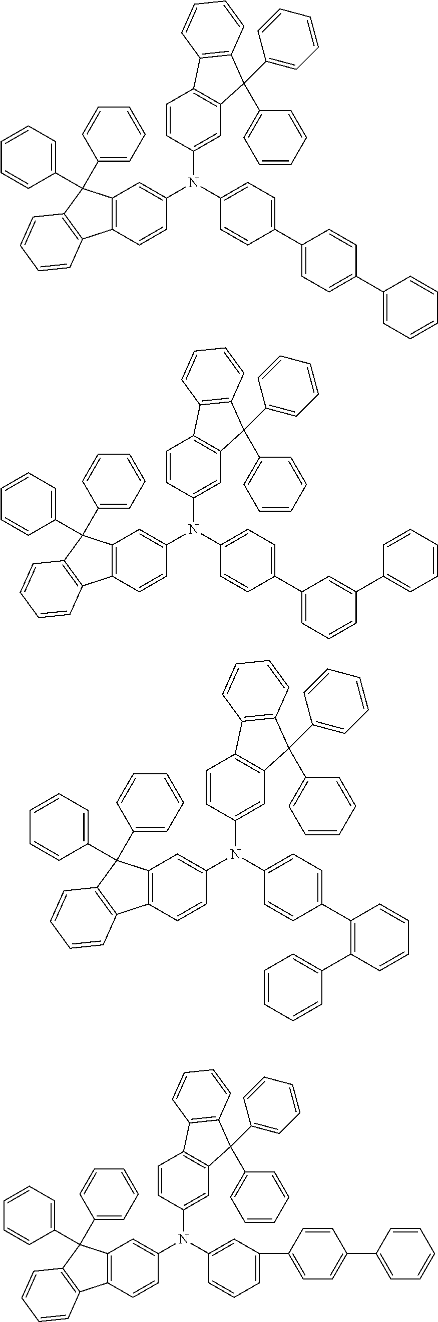

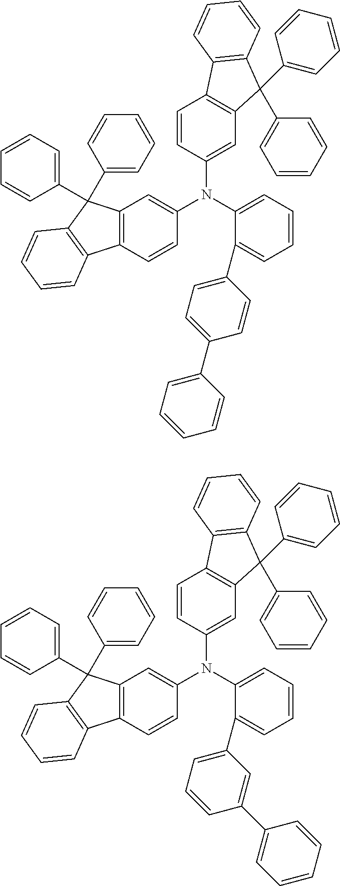

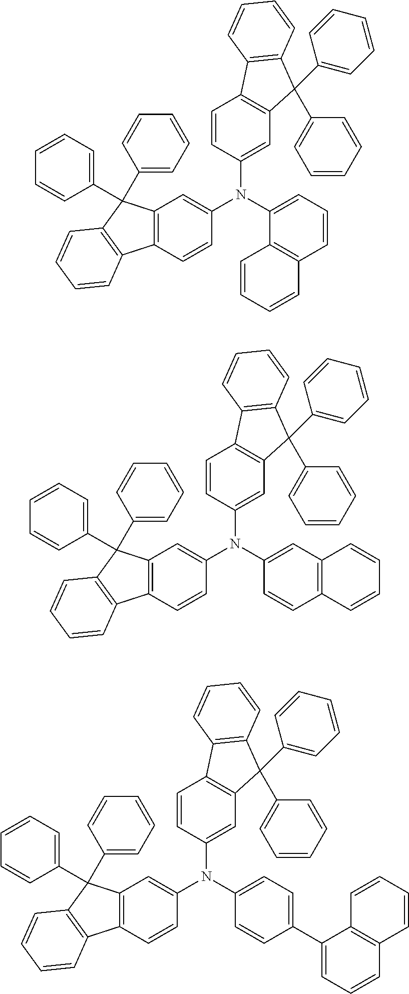

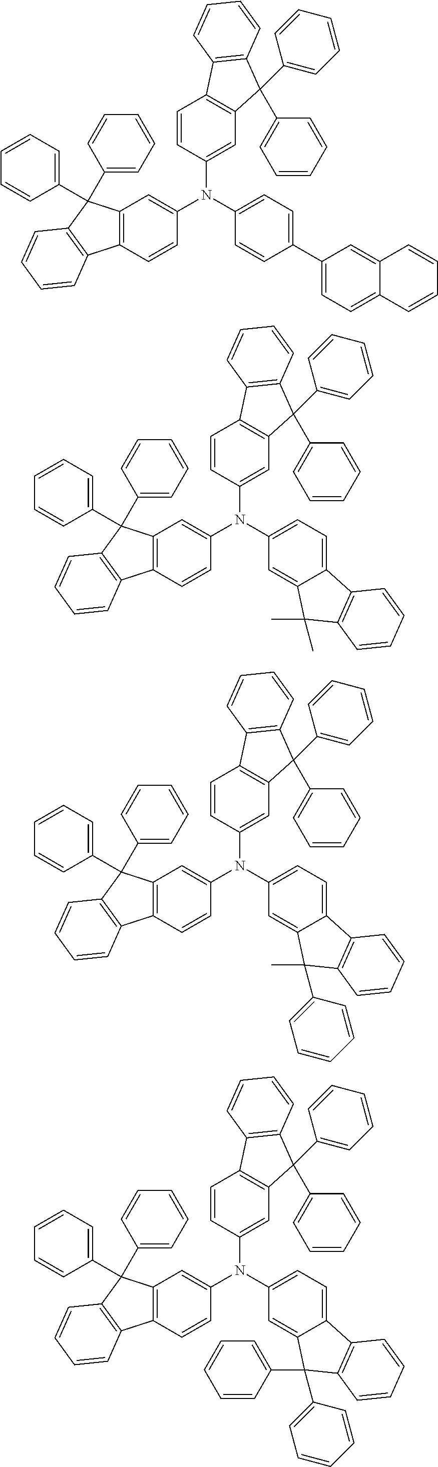

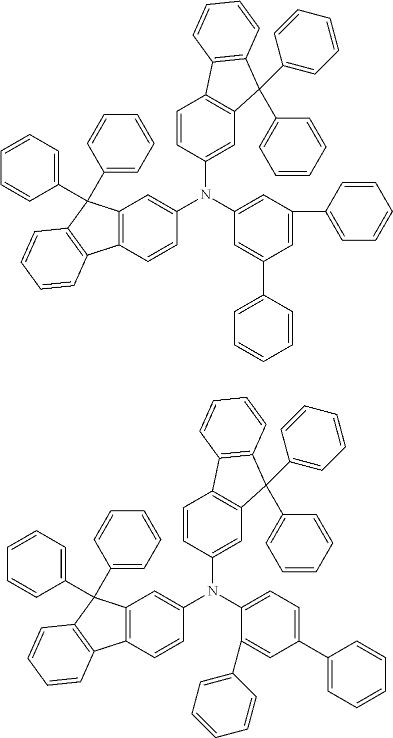

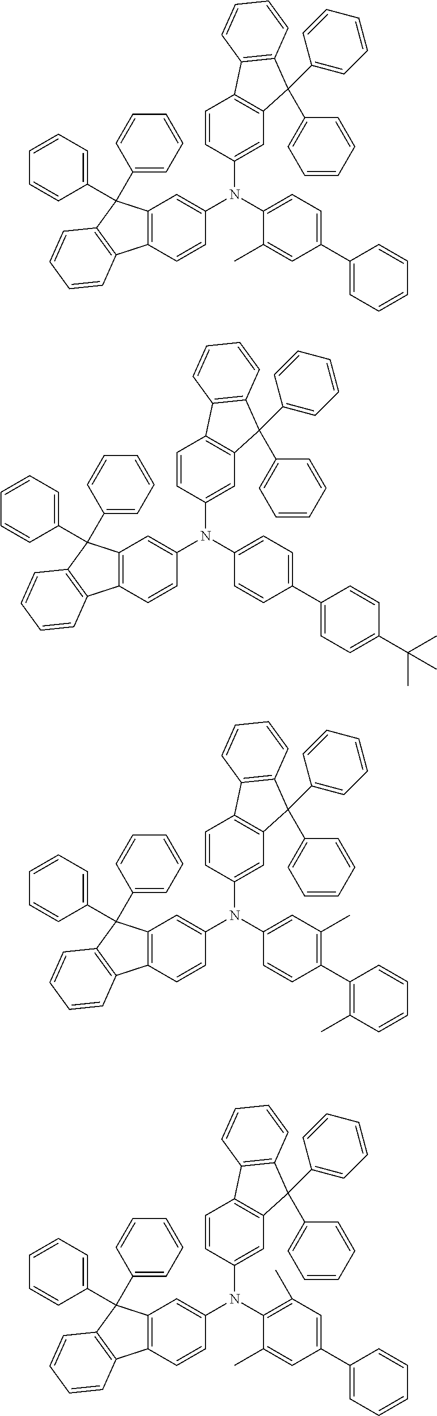 [SMILES: Cc1cc(-c2ccccc2)ccc1N(c1ccc2c(c1)C(c1ccccc1)(c1ccccc1)c1ccccc1-2)c1ccc2c(c1)C(c1ccccc1)(c1ccccc1)c1ccccc1-2 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(c2ccccc2)(c2ccccc2)c2ccccc2-3)c2ccc3c(c2)C(c2ccccc2)(c2ccccc2)c2ccccc2-3)cc1C ; Cc1cc(-c2ccccc2)cc(C)c1N(c1ccc2c(c1)C(c1ccccc1)(c1ccccc1)c1ccccc1-2)c1ccc2c(c1)C(c1ccccc1)(c1ccccc1)c1ccccc1-2]

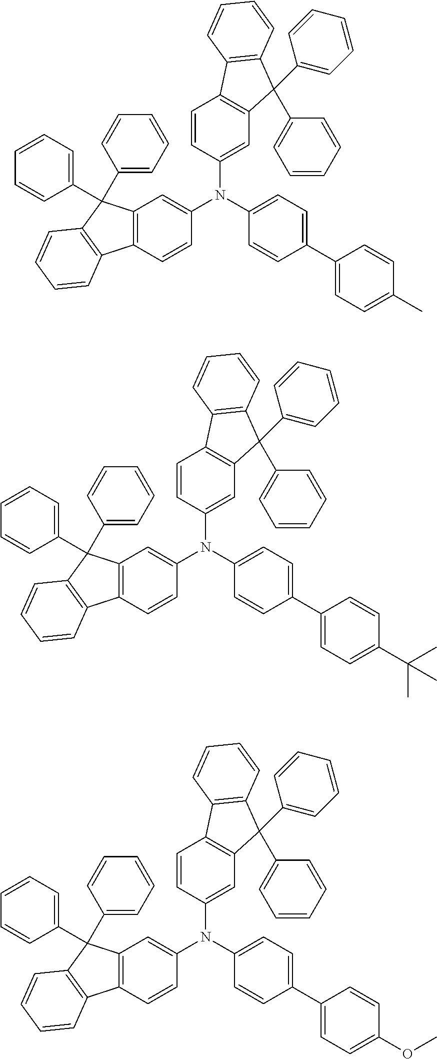 [SMILES: Cc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

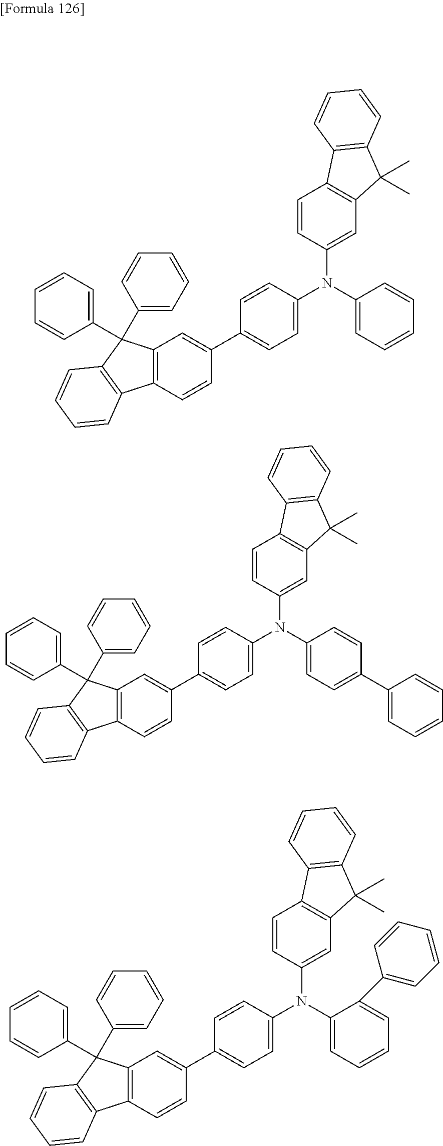 [SMILES: CC1(C)c2ccccc2-c2ccc(N(c3ccccc3)c3ccc(-c4ccc5c(c4)C(c4ccccc4)(c4ccccc4)c4ccccc4-5)cc3)cc21 ; CC1(C)c2ccccc2-c2ccc(N(c3ccc(-c4ccccc4)cc3)c3ccc(-c4ccc5c(c4)C(c4ccccc4)(c4ccccc4)c4ccccc4-5)cc3)cc21 ; CC1(C)c2ccccc2-c2ccc(N(c3ccc(-c4ccc5c(c4)C(c4ccccc4)(c4ccccc4)c4ccccc4-5)cc3)c3ccccc3-c3ccccc3)cc21]

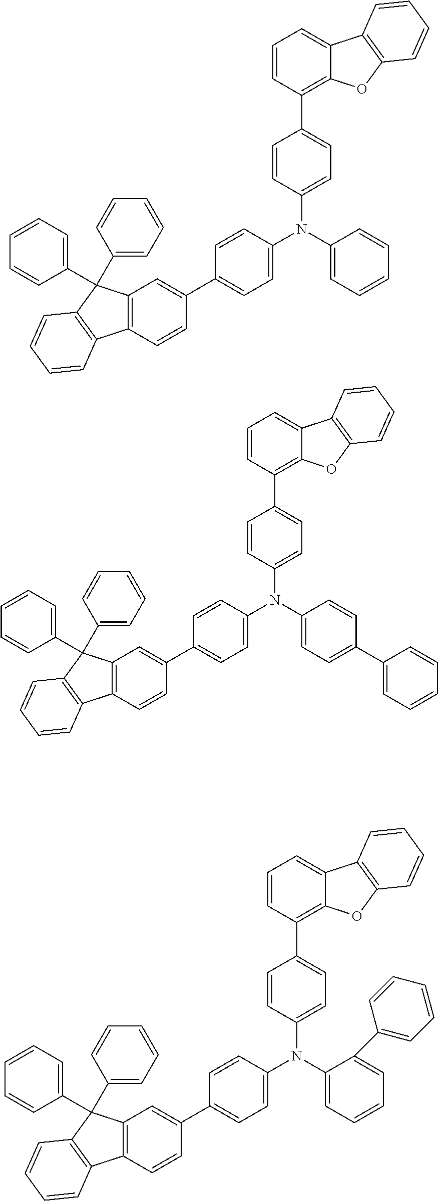 [SMILES: c1ccc(N(c2ccc(-c3ccc4c(c3)C(c3ccccc3)(c3ccccc3)c3ccccc3-4)cc2)c2ccc(-c3cccc4c3oc3ccccc34)cc2)cc1 ; c1ccc(-c2ccc(N(c3ccc(-c4ccc5c(c4)C(c4ccccc4)(c4ccccc4)c4ccccc4-5)cc3)c3ccc(-c4cccc5c4oc4ccccc45)cc3)cc2)cc1 ; c1ccc(-c2ccccc2N(c2ccc(-c3ccc4c(c3)C(c3ccccc3)(c3ccccc3)c3ccccc3-4)cc2)c2ccc(-c3cccc4c3oc3ccccc34)cc2)cc1]

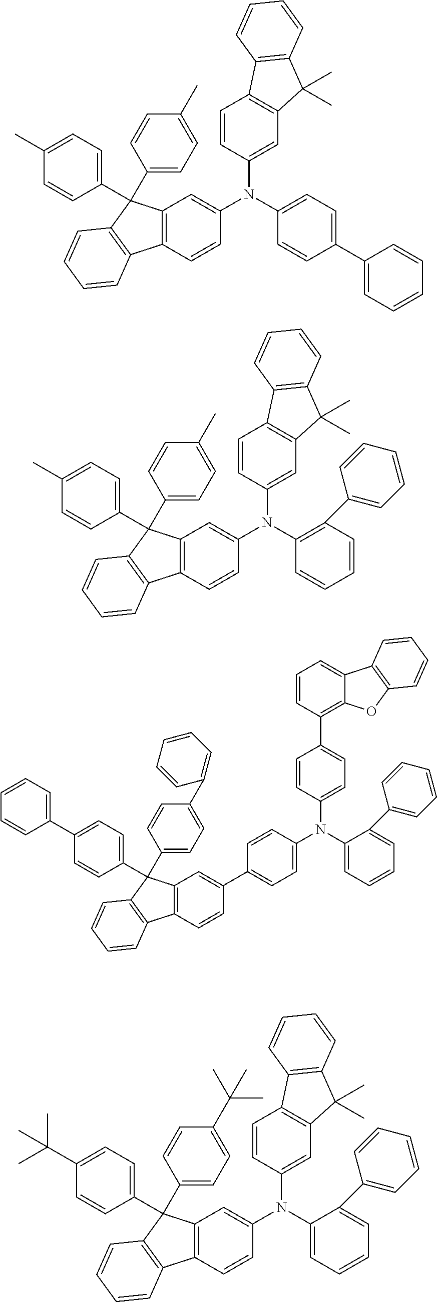 [SMILES: Cc1ccc(C2(c3ccc(C)cc3)c3ccccc3-c3ccc(N(c4ccc(-c5ccccc5)cc4)c4ccc5c(c4)C(C)(C)c4ccccc4-5)cc32)cc1 ; Cc1ccc(C2(c3ccc(C)cc3)c3ccccc3-c3ccc(N(c4ccc5c(c4)C(C)(C)c4ccccc4-5)c4ccccc4-c4ccccc4)cc32)cc1 ; c1ccc(-c2ccc(C3(c4ccc(-c5ccccc5)cc4)c4ccccc4-c4ccc(-c5ccc(N(c6ccc(-c7cccc8c7oc7ccccc78)cc6)c6ccccc6-c6ccccc6)cc5)cc43)cc2)cc1 ; CC(C)(C)c1ccc(C2(c3ccc(C(C)(C)C)cc3)c3ccccc3-c3ccc(N(c4ccc5c(c4)C(C)(C)c4ccccc4-5)c4ccccc4-c4ccccc4)cc32)cc1]

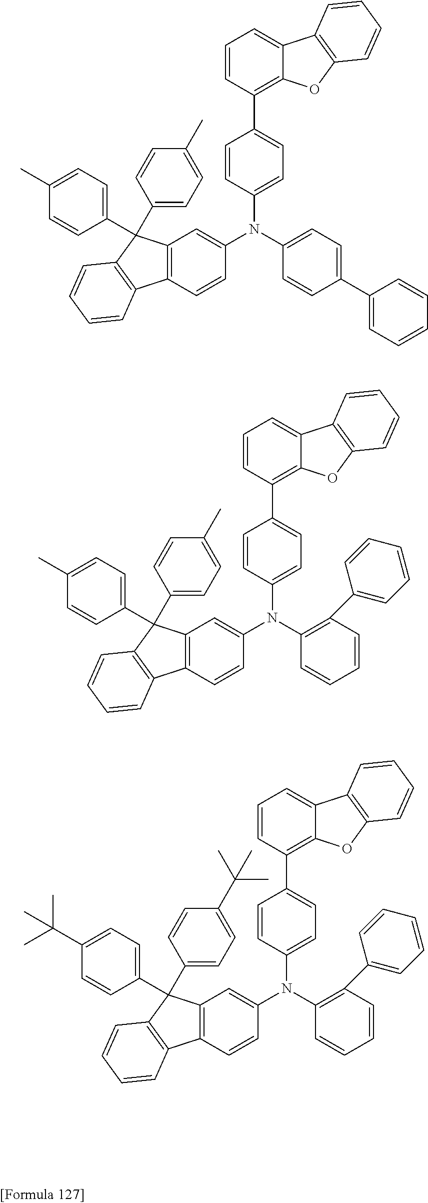 [SMILES: Cc1ccc(C2(c3ccc(C)cc3)c3ccccc3-c3ccc(N(c4ccc(-c5ccccc5)cc4)c4ccc(-c5cccc6c5oc5ccccc56)cc4)cc32)cc1 ; Cc1ccc(C2(c3ccc(C)cc3)c3ccccc3-c3ccc(N(c4ccc(-c5cccc6c5oc5ccccc56)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5cccc6c5oc5ccccc56)cc4)c4ccccc4-c4ccccc4)cc32)cc1]

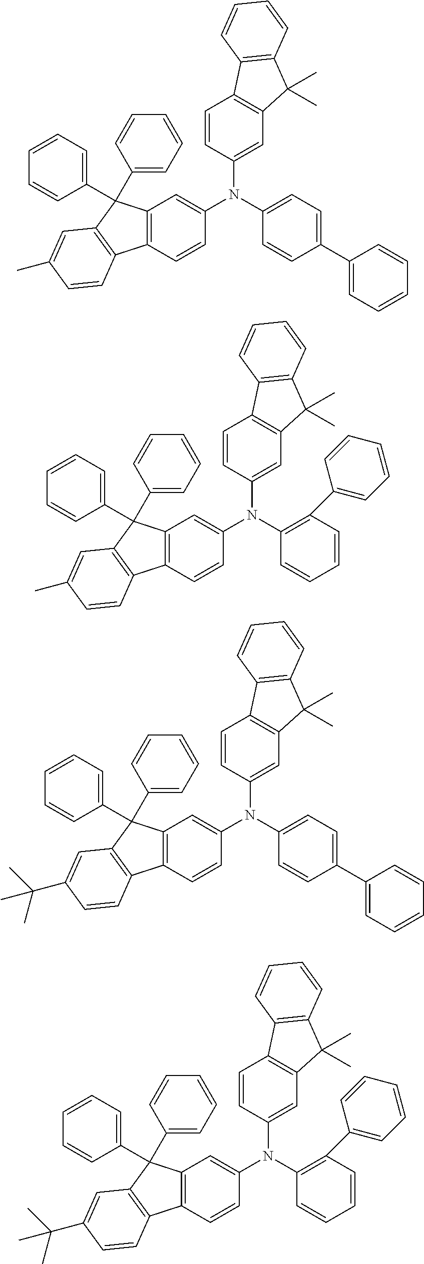 [SMILES: Cc1ccc2c(c1)C(c1ccccc1)(c1ccccc1)c1cc(N(c3ccc(-c4ccccc4)cc3)c3ccc4c(c3)C(C)(C)c3ccccc3-4)ccc1-2 ; Cc1ccc2c(c1)C(c1ccccc1)(c1ccccc1)c1cc(N(c3ccc4c(c3)C(C)(C)c3ccccc3-4)c3ccccc3-c3ccccc3)ccc1-2 ; CC(C)(C)c1ccc2c(c1)C(c1ccccc1)(c1ccccc1)c1cc(N(c3ccc(-c4ccccc4)cc3)c3ccc4c(c3)C(C)(C)c3ccccc3-4)ccc1-2 ; CC(C)(C)c1ccc2c(c1)C(c1ccccc1)(c1ccccc1)c1cc(N(c3ccc4c(c3)C(C)(C)c3ccccc3-4)c3ccccc3-c3ccccc3)ccc1-2]

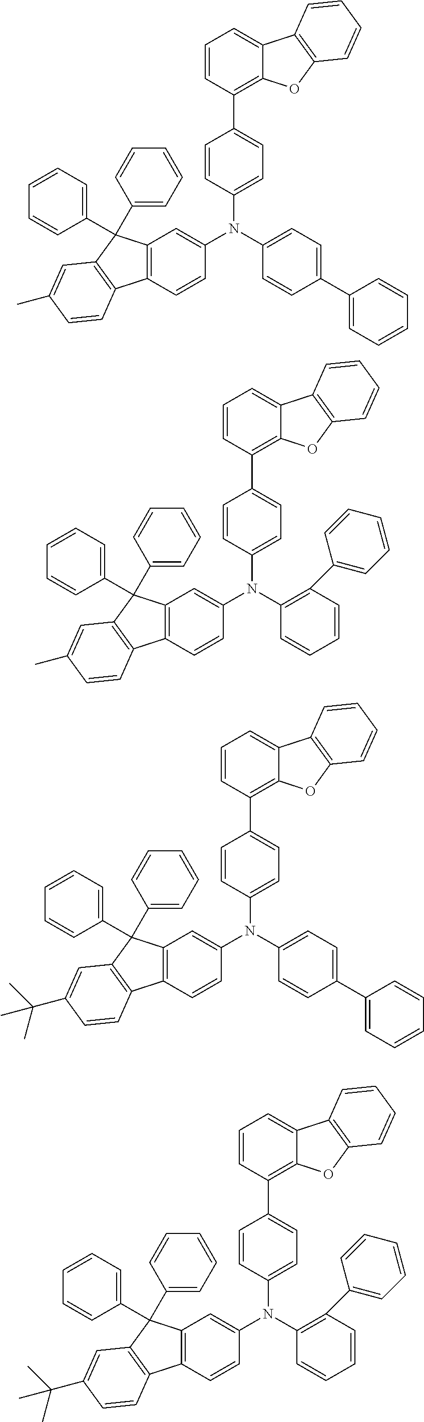

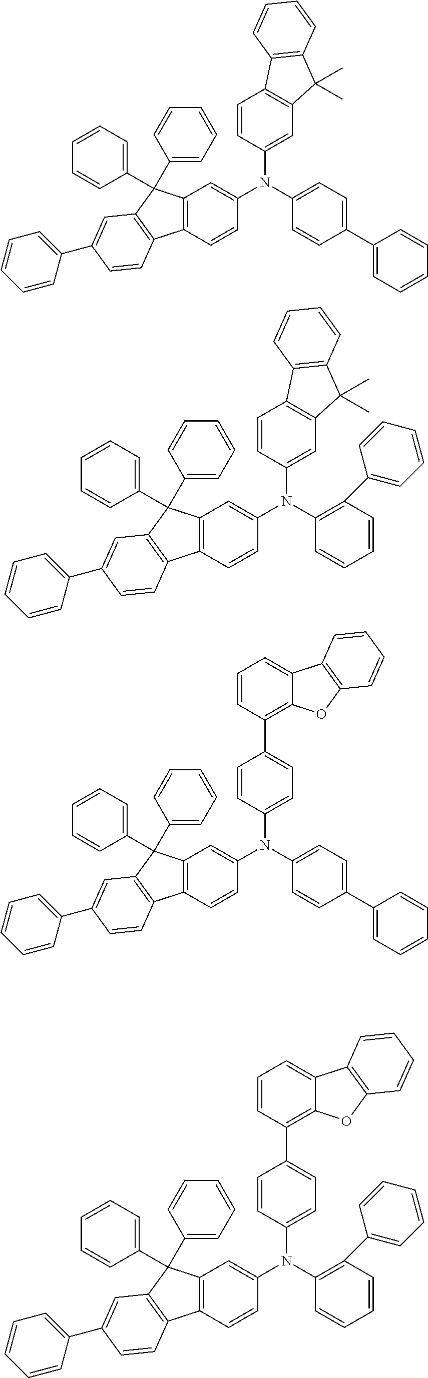 [SMILES: CC1(C)c2ccccc2-c2ccc(N(c3ccc(-c4ccccc4)cc3)c3ccc4c(c3)C(c3ccccc3)(c3ccccc3)c3cc(-c5ccccc5)ccc3-4)cc21 ; CC1(C)c2ccccc2-c2ccc(N(c3ccc4c(c3)C(c3ccccc3)(c3ccccc3)c3cc(-c5ccccc5)ccc3-4)c3ccccc3-c3ccccc3)cc21 ; c1ccc(-c2ccc(N(c3ccc(-c4cccc5c4oc4ccccc45)cc3)c3ccc4c(c3)C(c3ccccc3)(c3ccccc3)c3cc(-c5ccccc5)ccc3-4)cc2)cc1 ; c1ccc(-c2ccc3c(c2)C(c2ccccc2)(c2ccccc2)c2cc(N(c4ccc(-c5cccc6c5oc5ccccc56)cc4)c4ccccc4-c4ccccc4)ccc2-3)cc1]

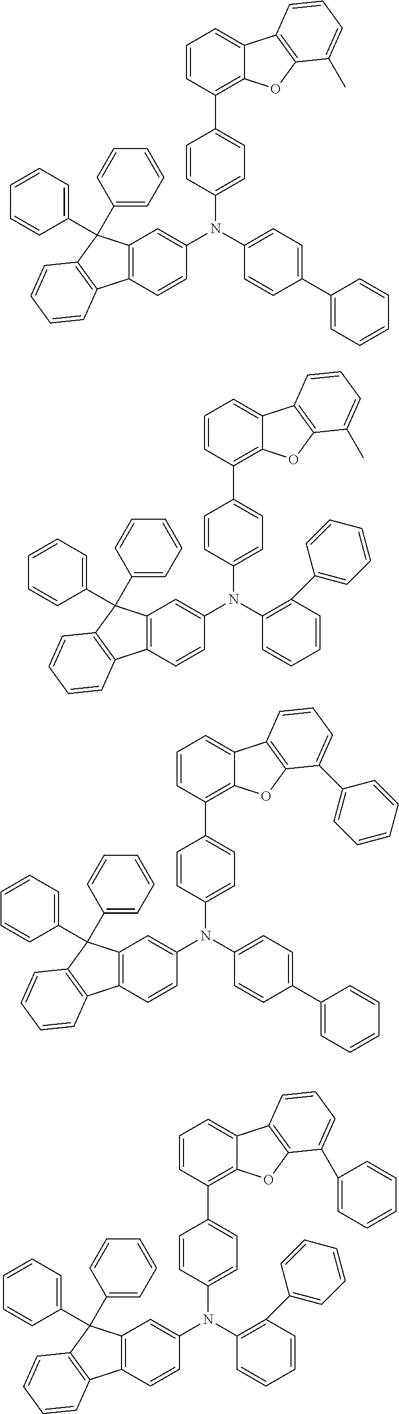

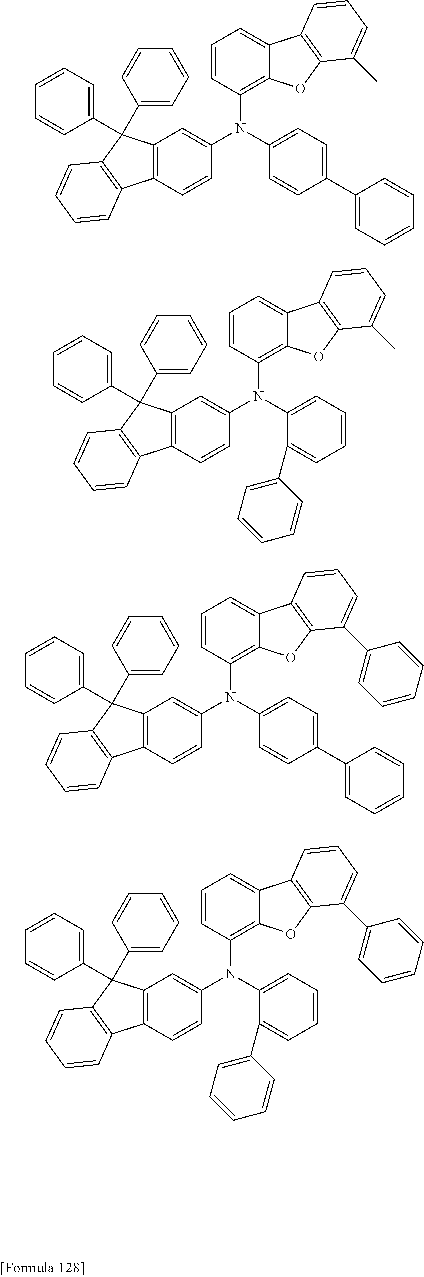

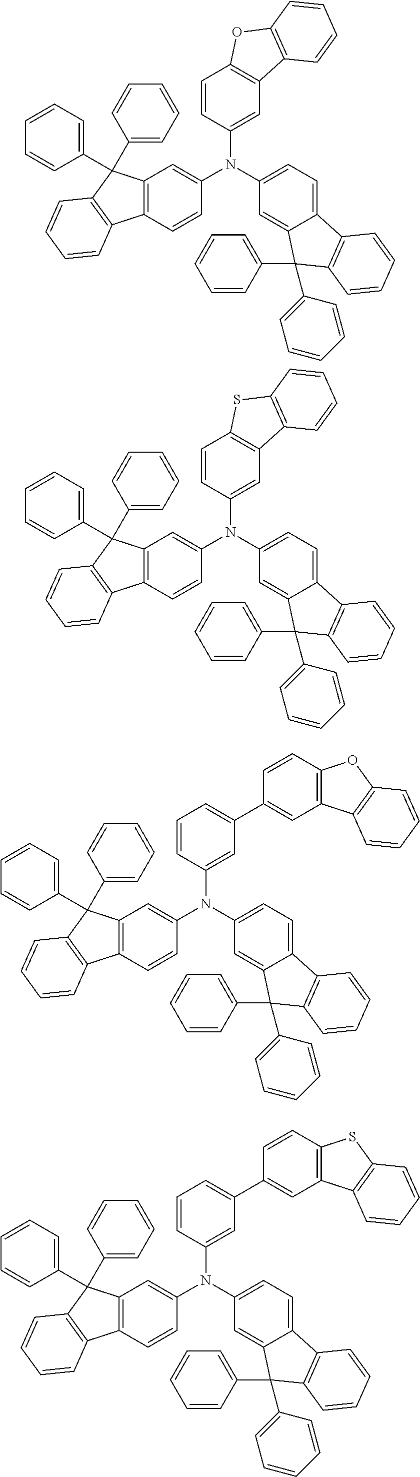

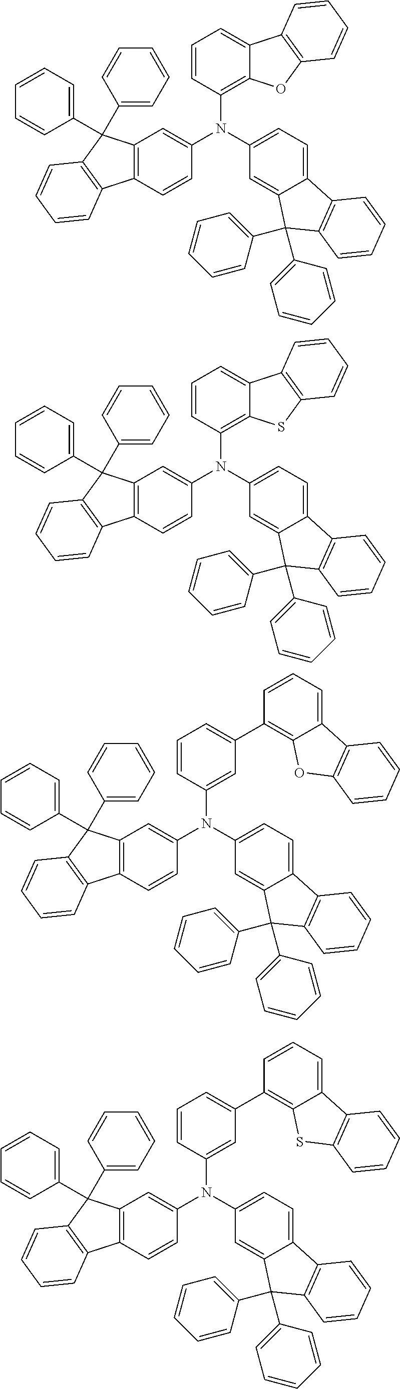

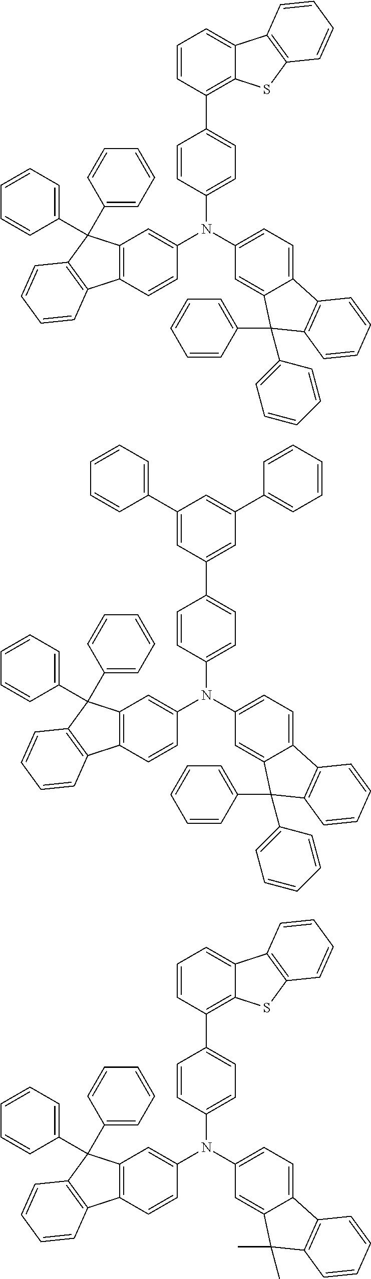

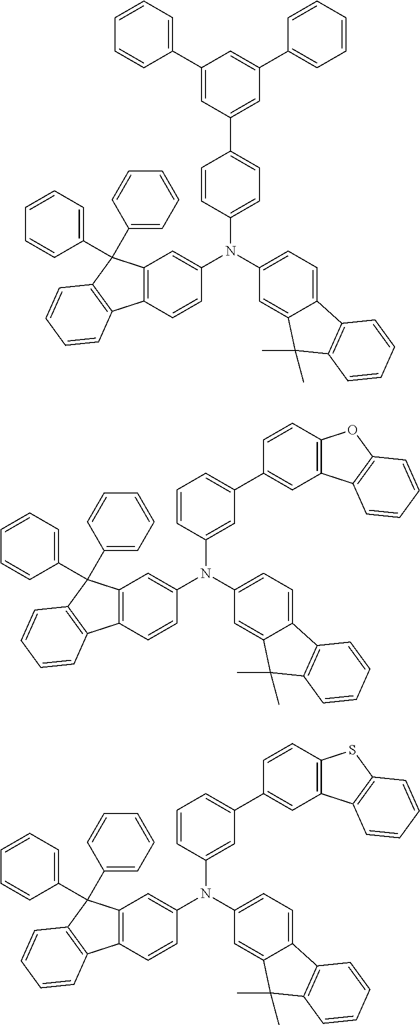

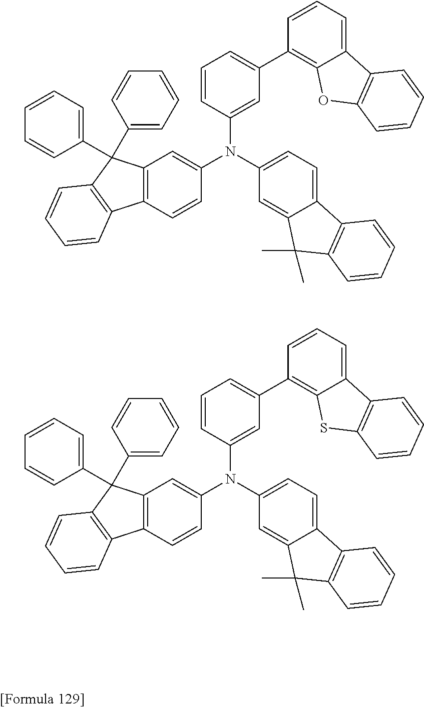 [SMILES: CC1(C)c2ccccc2-c2ccc(N(c3cccc(-c4cccc5c4oc4ccccc45)c3)c3ccc4c(c3)C(c3ccccc3)(c3ccccc3)c3ccccc3-4)cc21 ; CC1(C)c2ccccc2-c2ccc(N(c3cccc(-c4cccc5c4sc4ccccc45)c3)c3ccc4c(c3)C(c3ccccc3)(c3ccccc3)c3ccccc3-4)cc21]

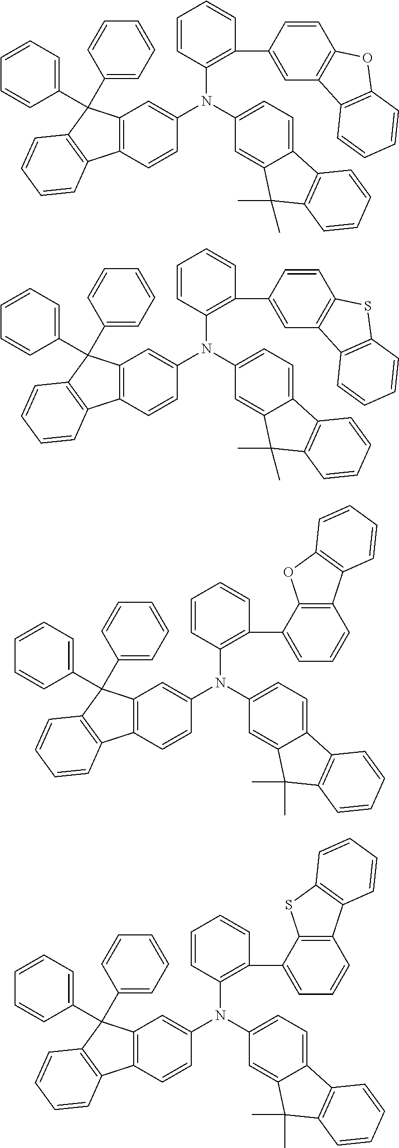

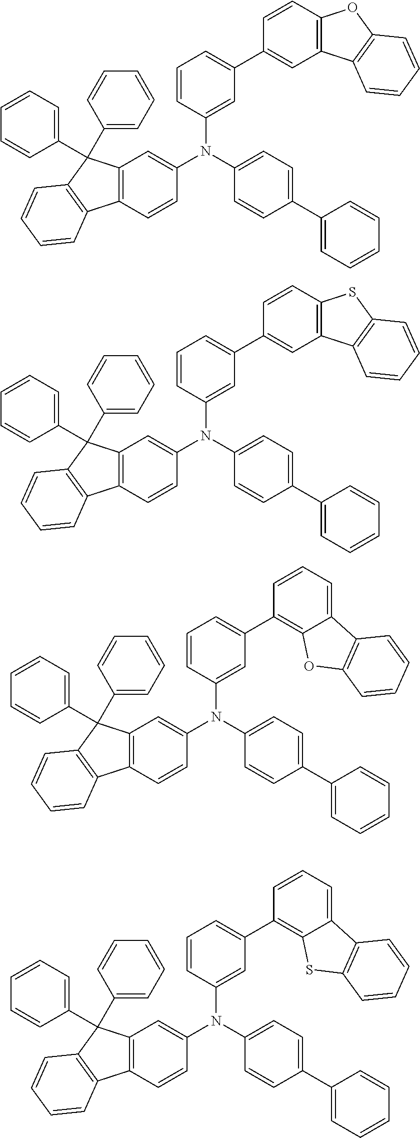

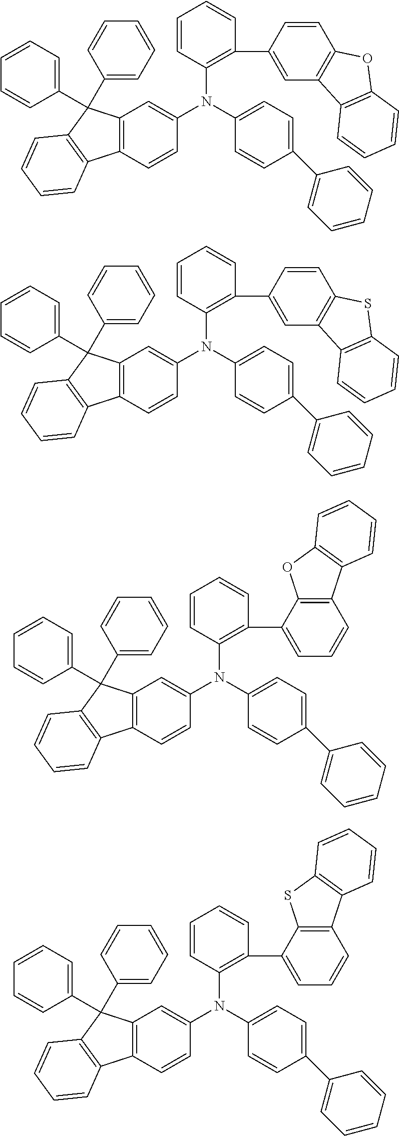

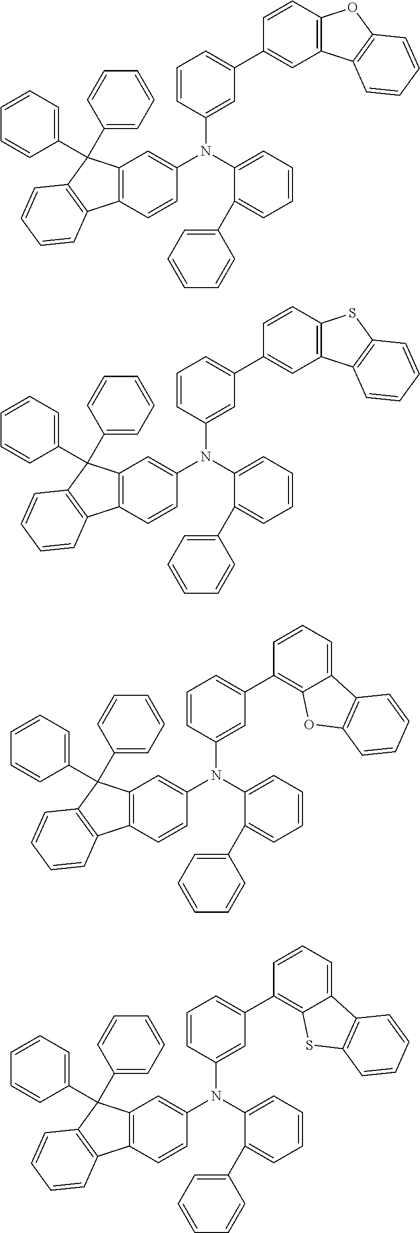 [SMILES: c1ccc(-c2ccccc2N(c2cccc(-c3ccc4oc5ccccc5c4c3)c2)c2ccc3c(c2)C(c2ccccc2)(c2ccccc2)c2ccccc2-3)cc1 ; c1ccc(-c2ccccc2N(c2cccc(-c3ccc4sc5ccccc5c4c3)c2)c2ccc3c(c2)C(c2ccccc2)(c2ccccc2)c2ccccc2-3)cc1 ; c1ccc(-c2ccccc2N(c2cccc(-c3cccc4c3oc3ccccc34)c2)c2ccc3c(c2)C(c2ccccc2)(c2ccccc2)c2ccccc2-3)cc1 ; c1ccc(-c2ccccc2N(c2cccc(-c3cccc4c3sc3ccccc34)c2)c2ccc3c(c2)C(c2ccccc2)(c2ccccc2)c2ccccc2-3)cc1]

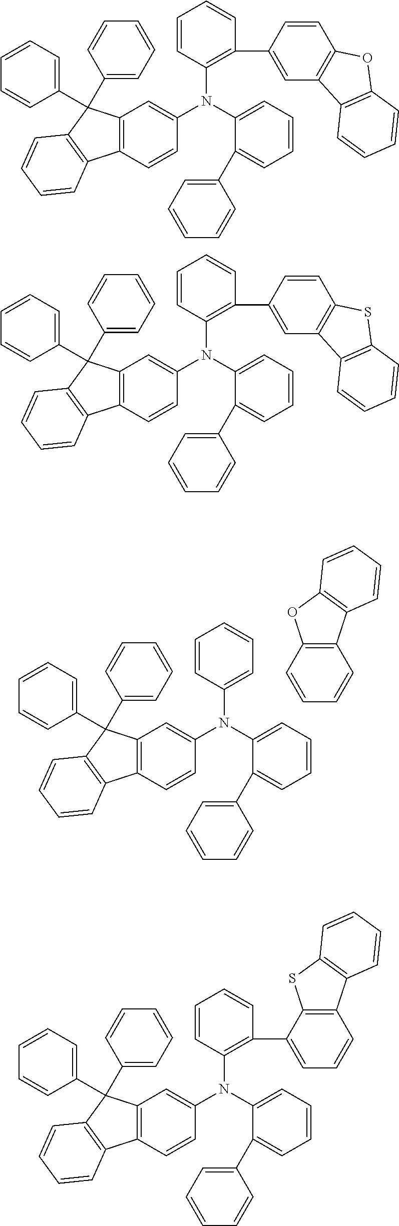

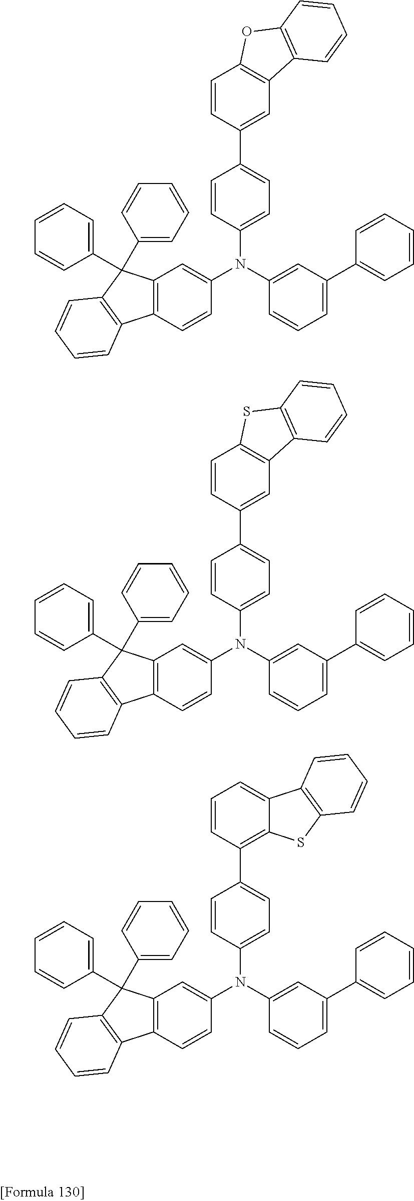 [SMILES: c1ccc(-c2cccc(N(c3ccc(-c4ccc5oc6ccccc6c5c4)cc3)c3ccc4c(c3)C(c3ccccc3)(c3ccccc3)c3ccccc3-4)c2)cc1 ; c1ccc(-c2cccc(N(c3ccc(-c4ccc5sc6ccccc6c5c4)cc3)c3ccc4c(c3)C(c3ccccc3)(c3ccccc3)c3ccccc3-4)c2)cc1 ; c1ccc(-c2cccc(N(c3ccc(-c4cccc5c4sc4ccccc45)cc3)c3ccc4c(c3)C(c3ccccc3)(c3ccccc3)c3ccccc3-4)c2)cc1]

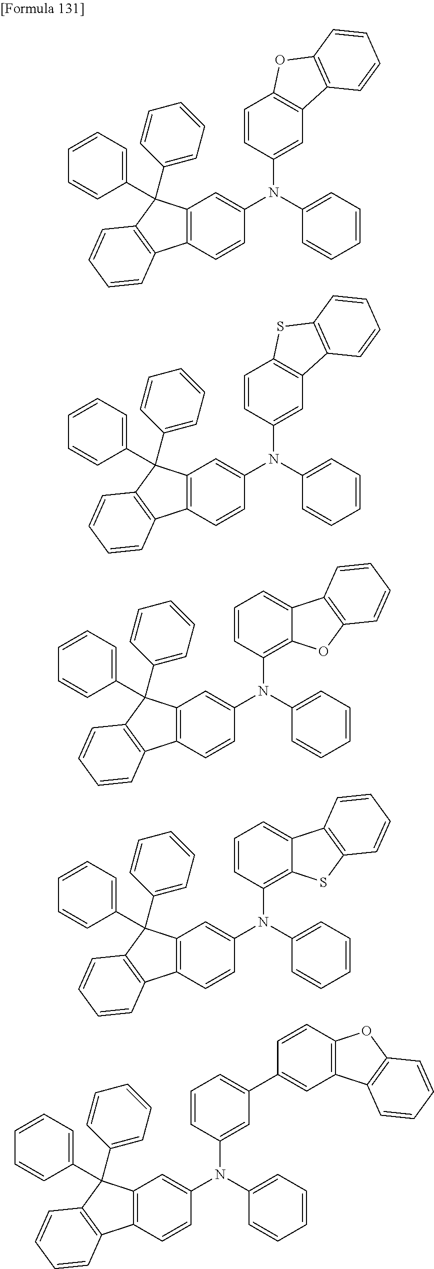

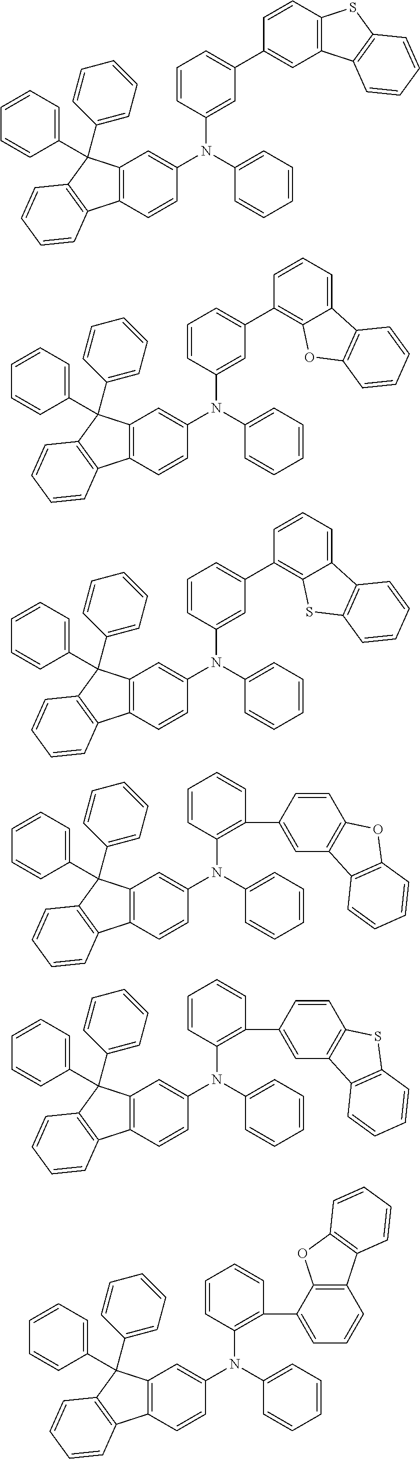

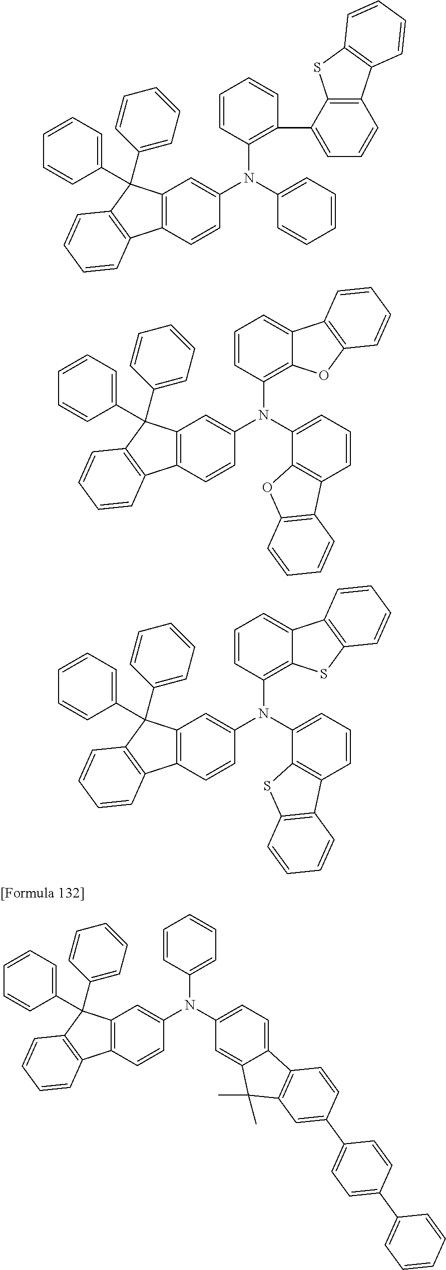

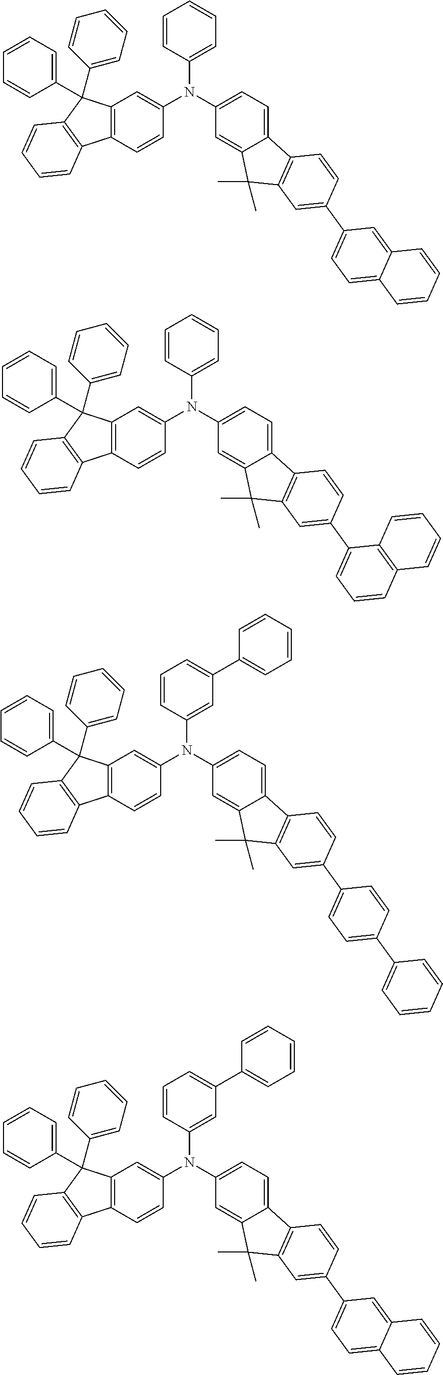 [SMILES: CC1(C)c2cc(-c3ccc4ccccc4c3)ccc2-c2ccc(N(c3ccccc3)c3ccc4c(c3)C(c3ccccc3)(c3ccccc3)c3ccccc3-4)cc21 ; CC1(C)c2cc(-c3cccc4ccccc34)ccc2-c2ccc(N(c3ccccc3)c3ccc4c(c3)C(c3ccccc3)(c3ccccc3)c3ccccc3-4)cc21 ; CC1(C)c2cc(-c3ccc(-c4ccccc4)cc3)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3ccc4ccccc4c3)ccc2-c2ccc(N(c3cccc(-c4ccccc4)c3)c3ccc4c(c3)C(c3ccccc3)(c3ccccc3)c3ccccc3-4)cc21]

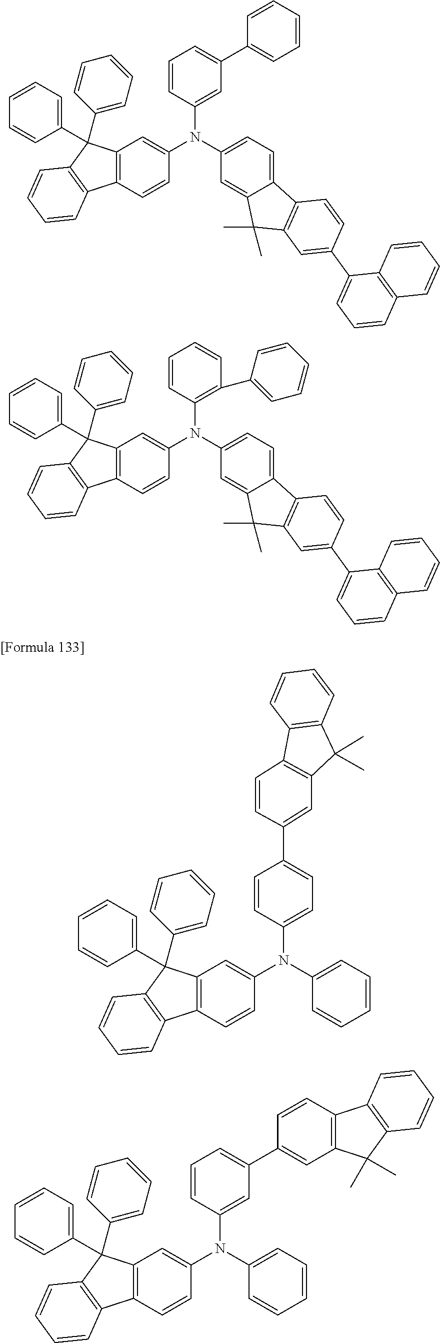 [SMILES: CC1(C)c2cc(-c3cccc4ccccc34)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3cccc4ccccc34)ccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(-c3ccc(N(c4ccccc4)c4ccc5c(c4)C(c4ccccc4)(c4ccccc4)c4ccccc4-5)cc3)cc21 ; CC1(C)c2ccccc2-c2ccc(-c3cccc(N(c4ccccc4)c4ccc5c(c4)C(c4ccccc4)(c4ccccc4)c4ccccc4-5)c3)cc21]

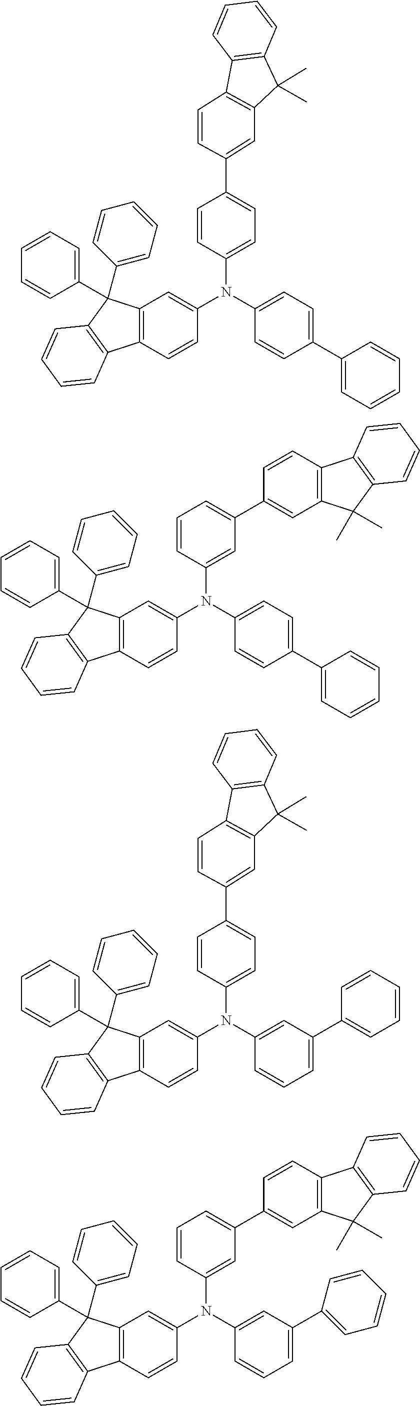

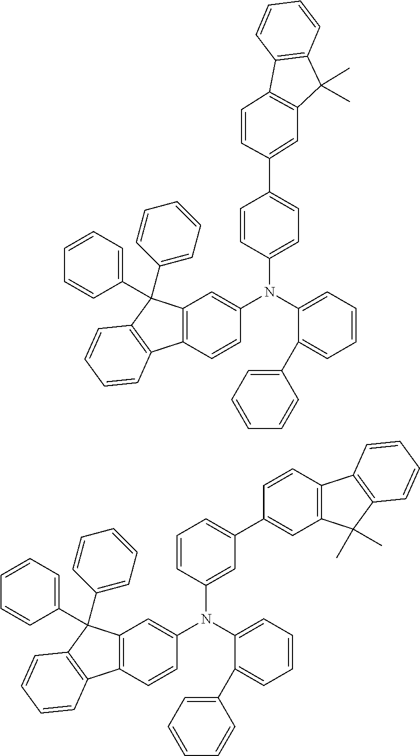

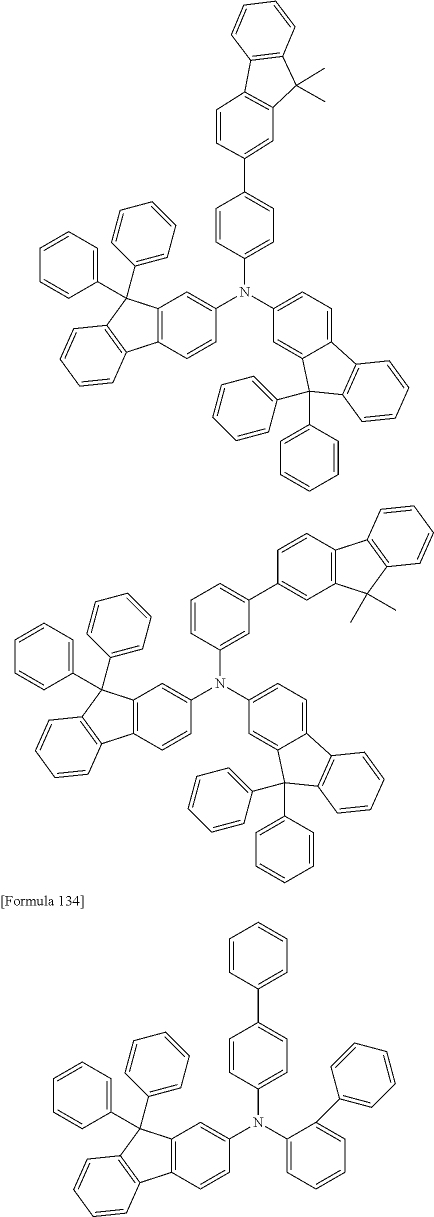

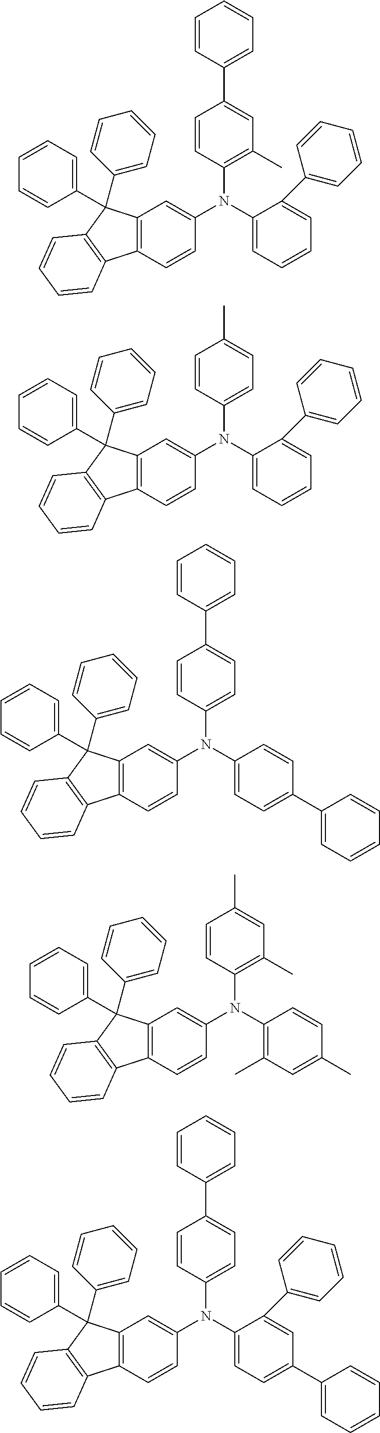 [SMILES: Cc1cc(-c2ccccc2)ccc1N(c1ccc2c(c1)C(c1ccccc1)(c1ccccc1)c1ccccc1-2)c1ccccc1-c1ccccc1 ; Cc1ccc(N(c2ccc3c(c2)C(c2ccccc2)(c2ccccc2)c2ccccc2-3)c2ccccc2-c2ccccc2)cc1 ; c1ccc(-c2ccc(N(c3ccc(-c4ccccc4)cc3)c3ccc4c(c3)C(c3ccccc3)(c3ccccc3)c3ccccc3-4)cc2)cc1 ; Cc1ccc(N(c2ccc3c(c2)C(c2ccccc2)(c2ccccc2)c2ccccc2-3)c2ccc(C)cc2C)c(C)c1 ; c1ccc(-c2ccc(N(c3ccc4c(c3)C(c3ccccc3)(c3ccccc3)c3ccccc3-4)c3ccc(-c4ccccc4)cc3-c3ccccc3)cc2)cc1]

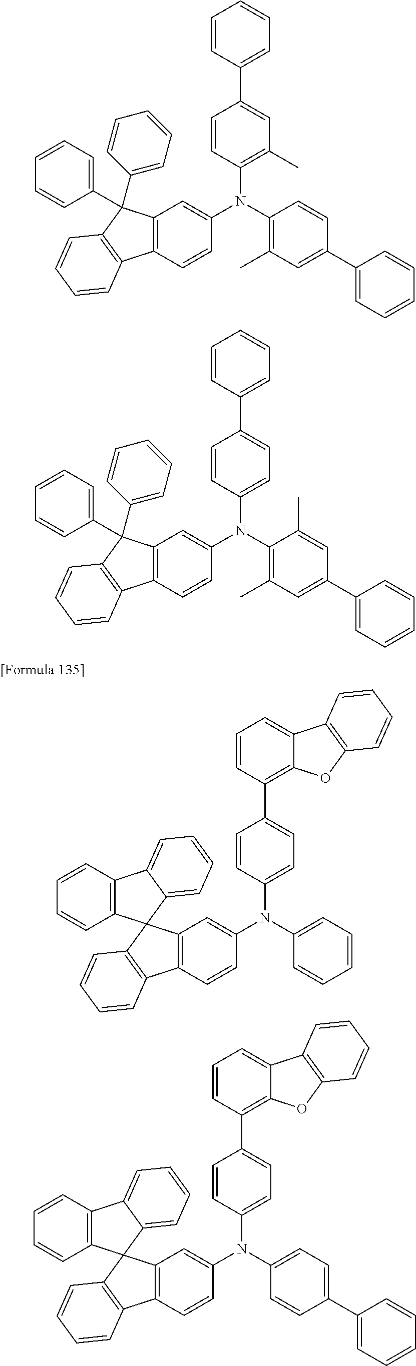

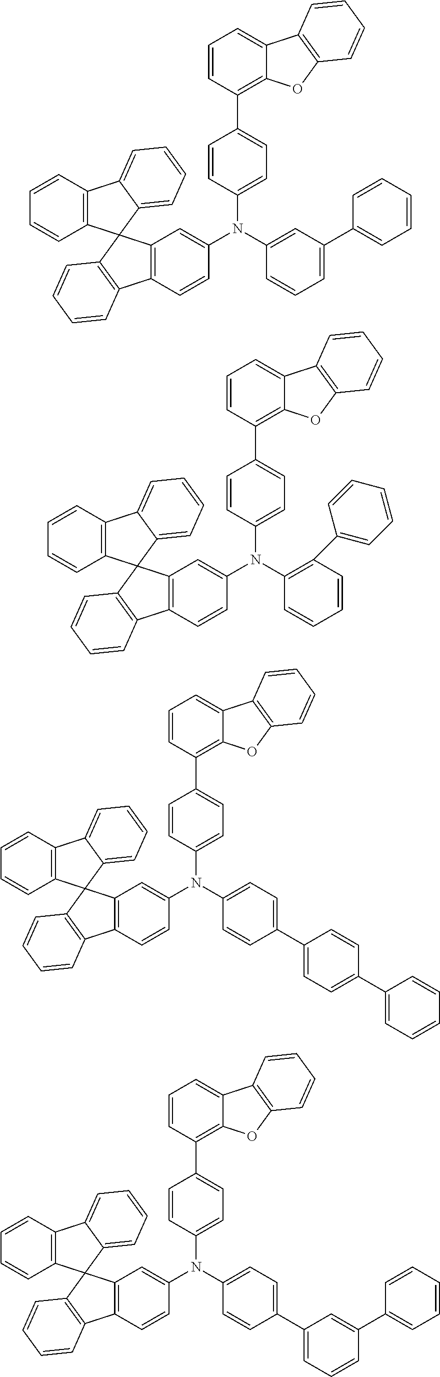 [SMILES: c1ccc(-c2cccc(N(c3ccc(-c4cccc5c4oc4ccccc45)cc3)c3ccc4c(c3)C3(c5ccccc5-c5ccccc53)c3ccccc3-4)c2)cc1 ; c1ccc(-c2ccccc2N(c2ccc(-c3cccc4c3oc3ccccc34)cc2)c2ccc3c(c2)C2(c4ccccc4-c4ccccc42)c2ccccc2-3)cc1 ; c1ccc(-c2ccc(-c3ccc(N(c4ccc(-c5cccc6c5oc5ccccc56)cc4)c4ccc5c(c4)C4(c6ccccc6-c6ccccc64)c4ccccc4-5)cc3)cc2)cc1 ; c1ccc(-c2cccc(-c3ccc(N(c4ccc(-c5cccc6c5oc5ccccc56)cc4)c4ccc5c(c4)C4(c6ccccc6-c6ccccc64)c4ccccc4-5)cc3)c2)cc1]

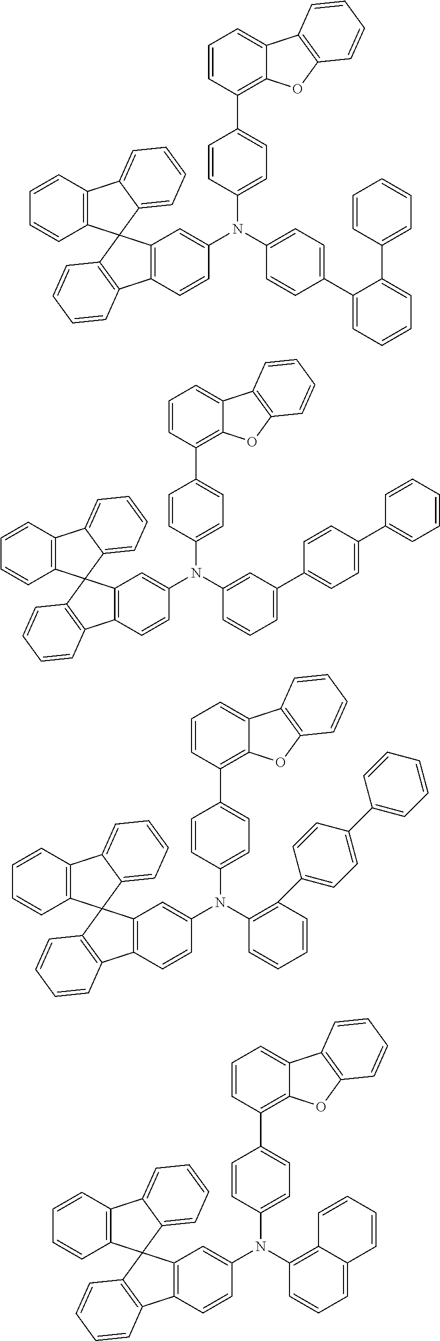 [SMILES: c1ccc(-c2ccccc2-c2ccc(N(c3ccc(-c4cccc5c4oc4ccccc45)cc3)c3ccc4c(c3)C3(c5ccccc5-c5ccccc53)c3ccccc3-4)cc2)cc1 ; c1ccc(-c2ccc(-c3cccc(N(c4ccc(-c5cccc6c5oc5ccccc56)cc4)c4ccc5c(c4)C4(c6ccccc6-c6ccccc64)c4ccccc4-5)c3)cc2)cc1 ; c1ccc(-c2ccc(-c3ccccc3N(c3ccc(-c4cccc5c4oc4ccccc45)cc3)c3ccc4c(c3)C3(c5ccccc5-c5ccccc53)c3ccccc3-4)cc2)cc1 ; c1ccc2c(c1)-c1ccccc1C21c2ccccc2-c2ccc(N(c3ccc(-c4cccc5c4oc4ccccc45)cc3)c3cccc4ccccc34)cc21]

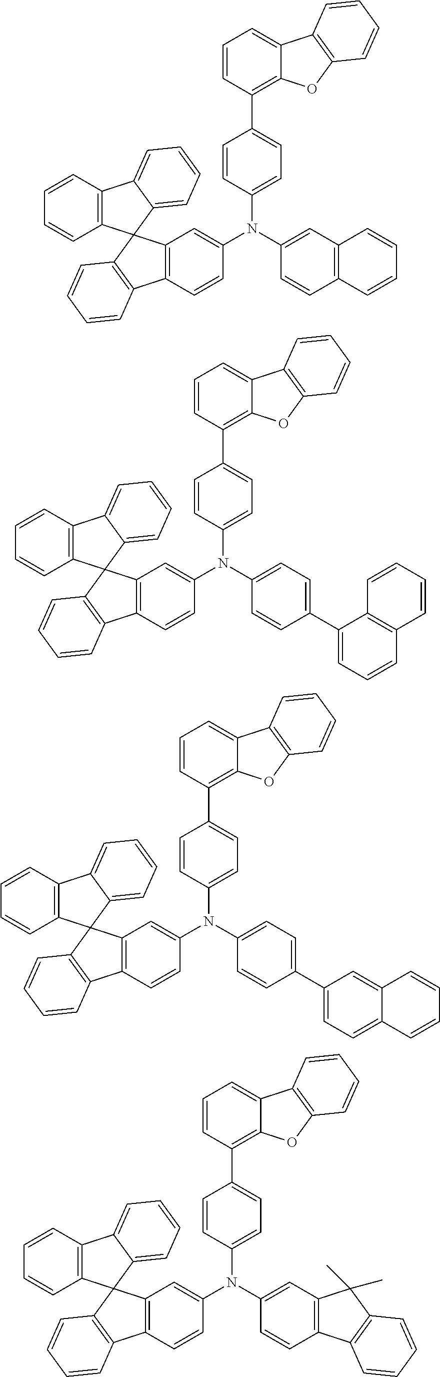

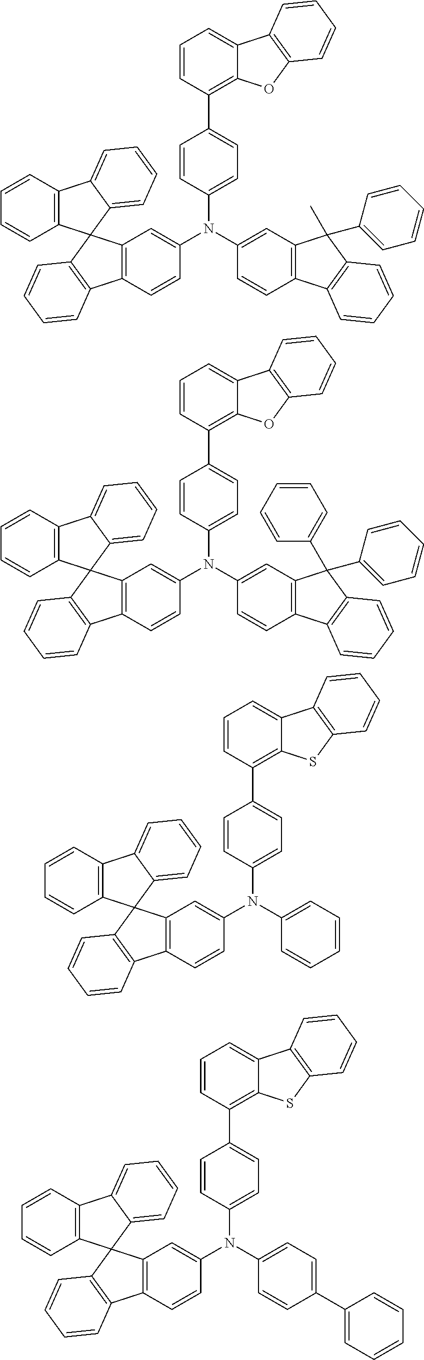

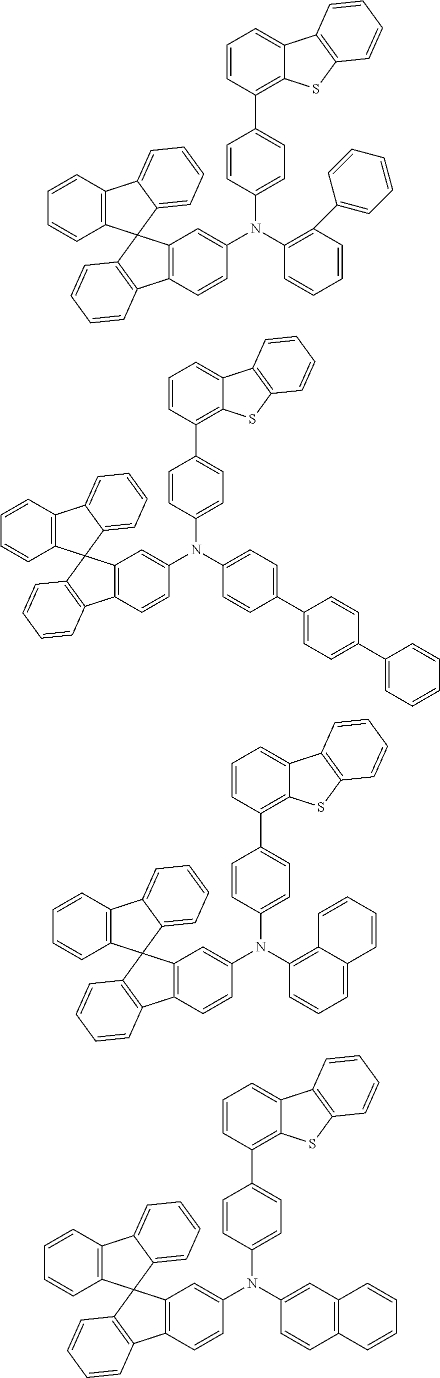

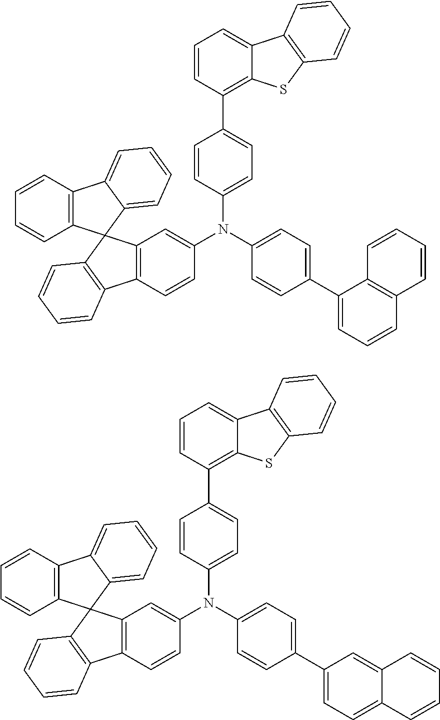 [SMILES: c1ccc2c(c1)-c1ccccc1C21c2ccccc2-c2ccc(N(c3ccc(-c4cccc5ccccc45)cc3)c3ccc(-c4cccc5c4sc4ccccc45)cc3)cc21 ; c1ccc2c(c1)-c1ccccc1C21c2ccccc2-c2ccc(N(c3ccc(-c4ccc5ccccc5c4)cc3)c3ccc(-c4cccc5c4sc4ccccc45)cc3)cc21]

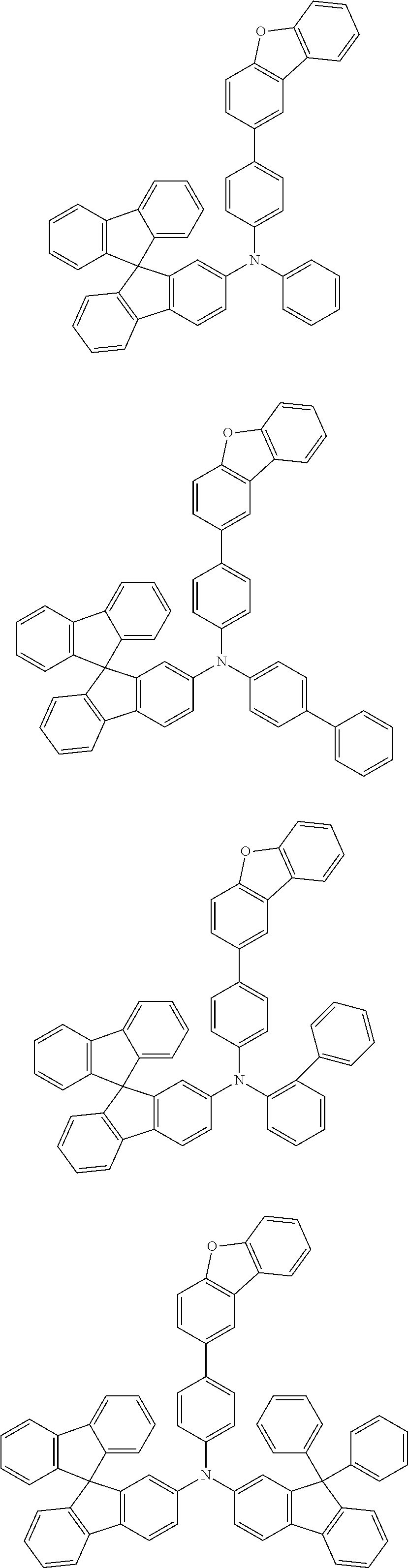 [SMILES: c1ccc(N(c2ccc(-c3ccc4oc5ccccc5c4c3)cc2)c2ccc3c(c2)C2(c4ccccc4-c4ccccc42)c2ccccc2-3)cc1 ; c1ccc(-c2ccc(N(c3ccc(-c4ccc5oc6ccccc6c5c4)cc3)c3ccc4c(c3)C3(c5ccccc5-c5ccccc53)c3ccccc3-4)cc2)cc1 ; c1ccc(-c2ccccc2N(c2ccc(-c3ccc4oc5ccccc5c4c3)cc2)c2ccc3c(c2)C2(c4ccccc4-c4ccccc42)c2ccccc2-3)cc1 ; c1ccc(C2(c3ccccc3)c3ccccc3-c3ccc(N(c4ccc(-c5ccc6oc7ccccc7c6c5)cc4)c4ccc5c(c4)C4(c6ccccc6-c6ccccc64)c4ccccc4-5)cc32)cc1]

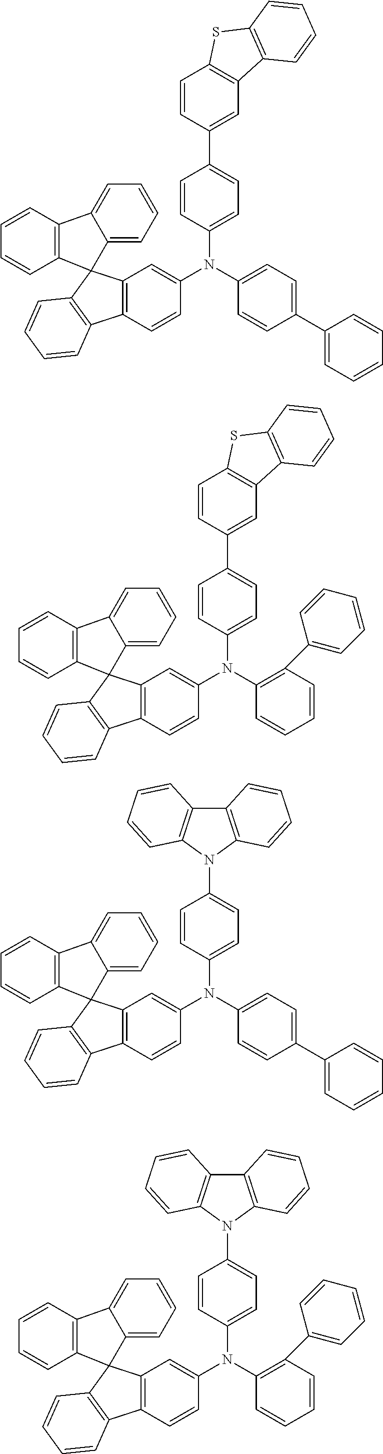

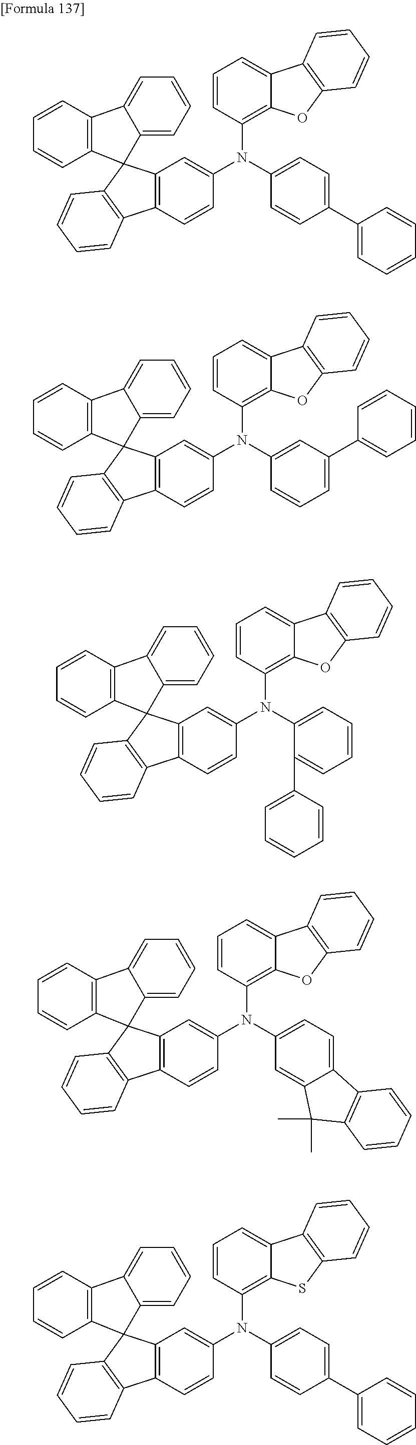 [SMILES: c1ccc(-c2ccc(N(c3ccc4c(c3)C3(c5ccccc5-c5ccccc53)c3ccccc3-4)c3cccc4c3oc3ccccc34)cc2)cc1 ; c1ccc(-c2cccc(N(c3ccc4c(c3)C3(c5ccccc5-c5ccccc53)c3ccccc3-4)c3cccc4c3oc3ccccc34)c2)cc1 ; c1ccc(-c2ccccc2N(c2ccc3c(c2)C2(c4ccccc4-c4ccccc42)c2ccccc2-3)c2cccc3c2oc2ccccc23)cc1 ; CC1(C)c2ccccc2-c2ccc(N(c3ccc4c(c3)C3(c5ccccc5-c5ccccc53)c3ccccc3-4)c3cccc4c3oc3ccccc34)cc21 ; c1ccc(-c2ccc(N(c3ccc4c(c3)C3(c5ccccc5-c5ccccc53)c3ccccc3-4)c3cccc4c3sc3ccccc34)cc2)cc1]

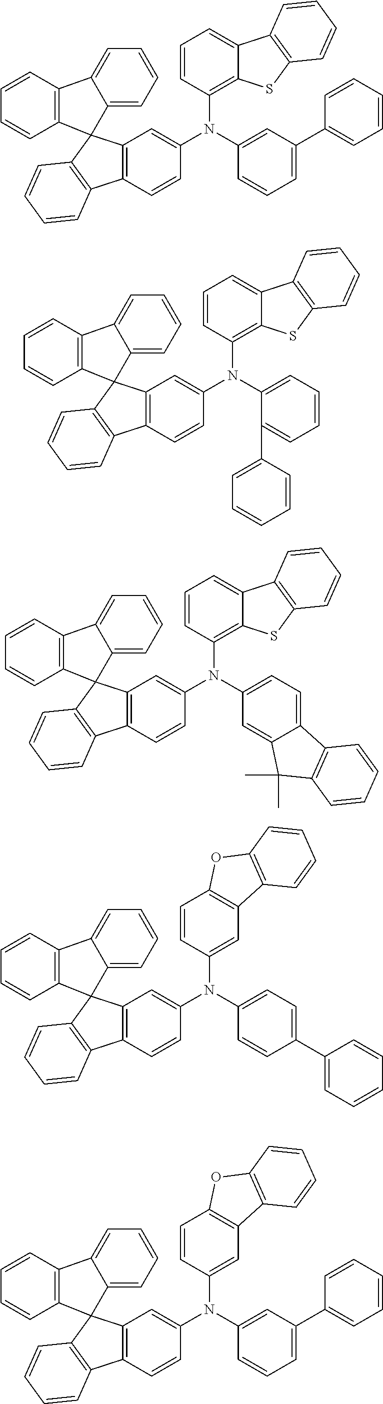

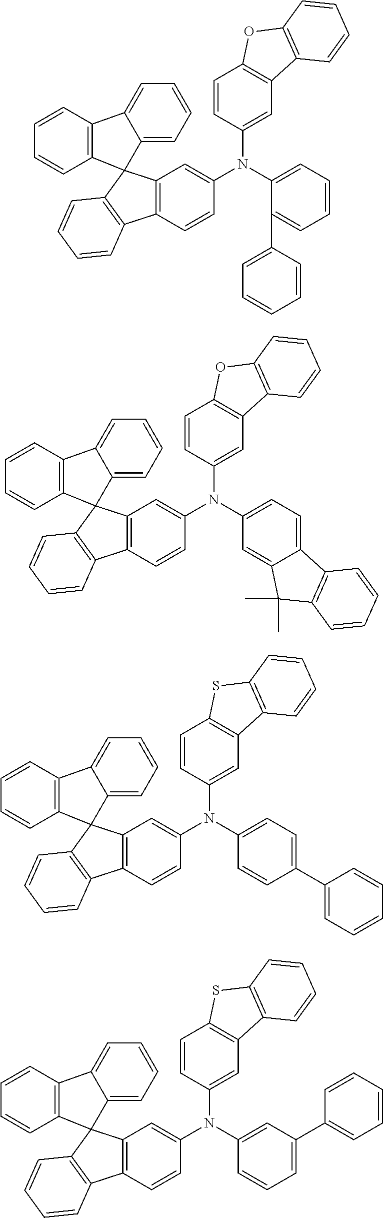

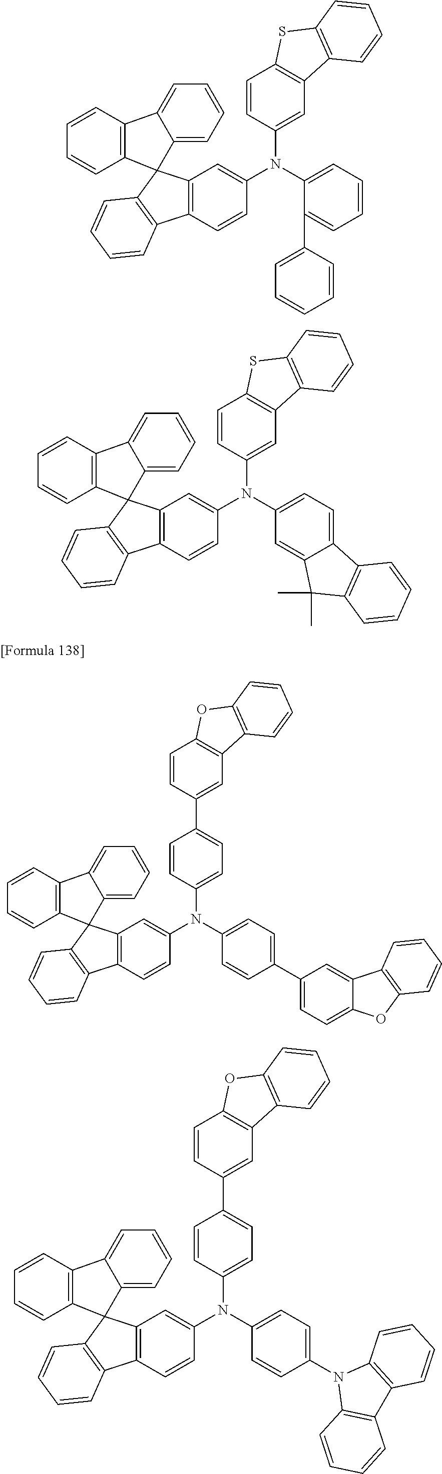

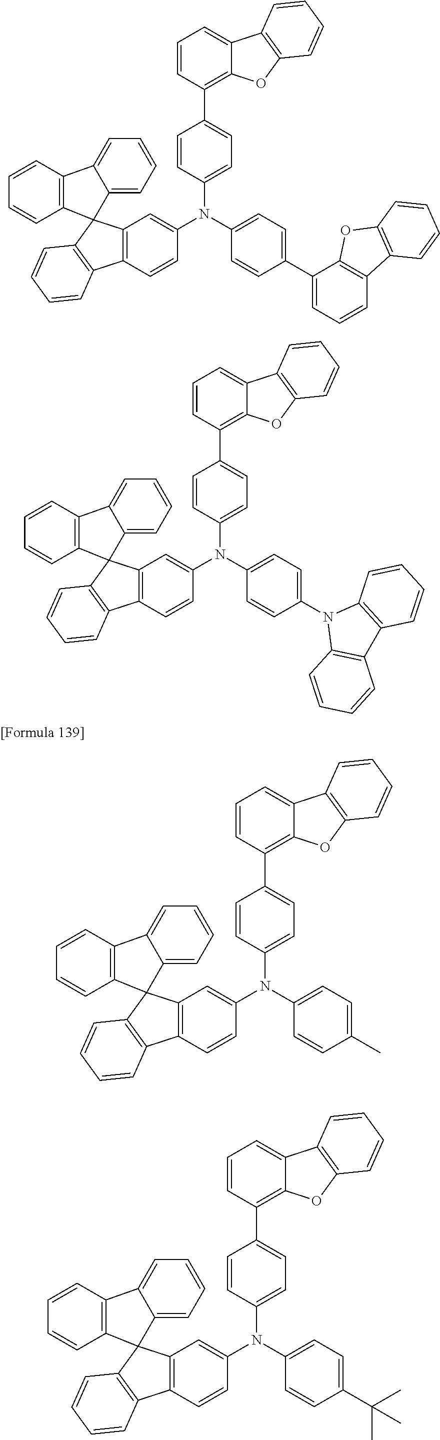

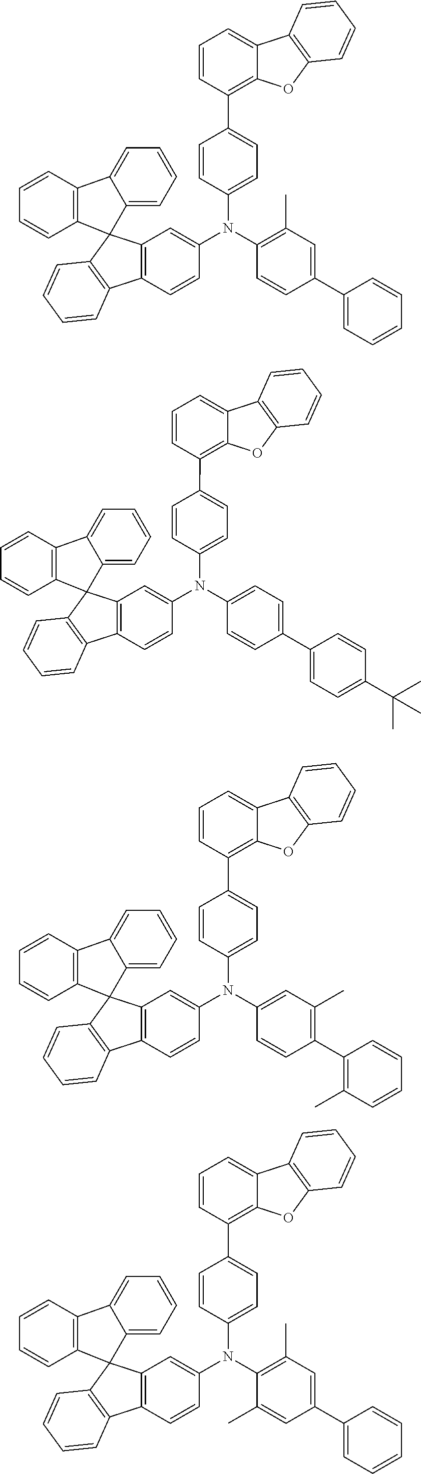

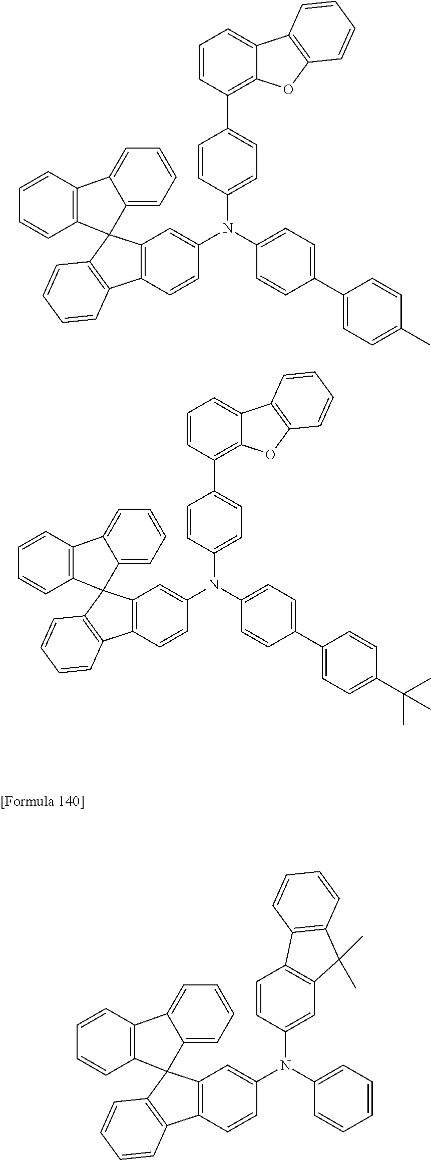 [SMILES: Cc1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; CC(C)(C)c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; CC1(C)c2ccccc2-c2ccc(N(c3ccccc3)c3ccc4c(c3)C3(c5ccccc5-c5ccccc53)c3ccccc3-4)cc21]

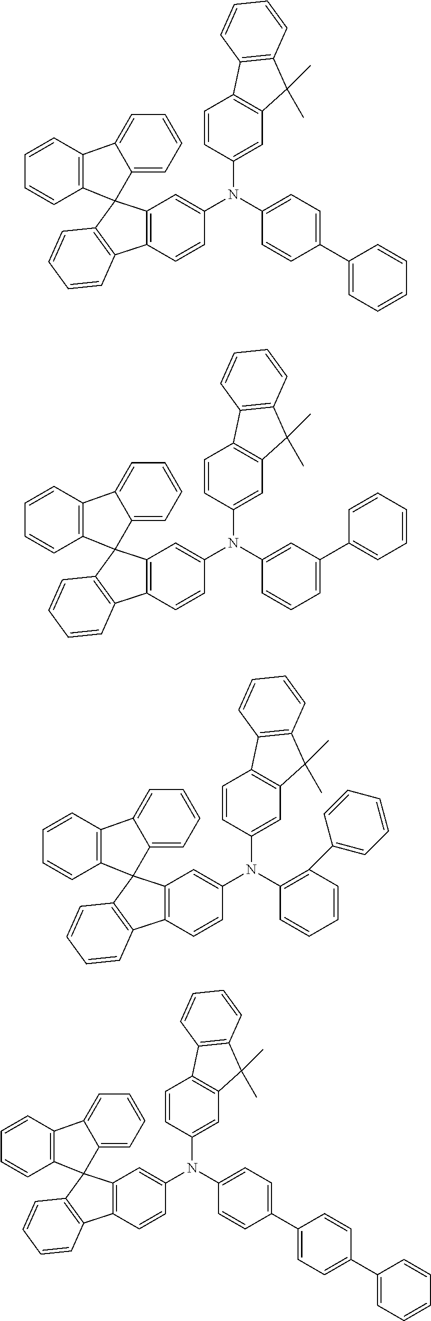 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccc(-c5ccccc5)cc4)cc3)c3ccc4c(c3)C3(c5ccccc5-c5ccccc53)c3ccccc3-4)cc21]

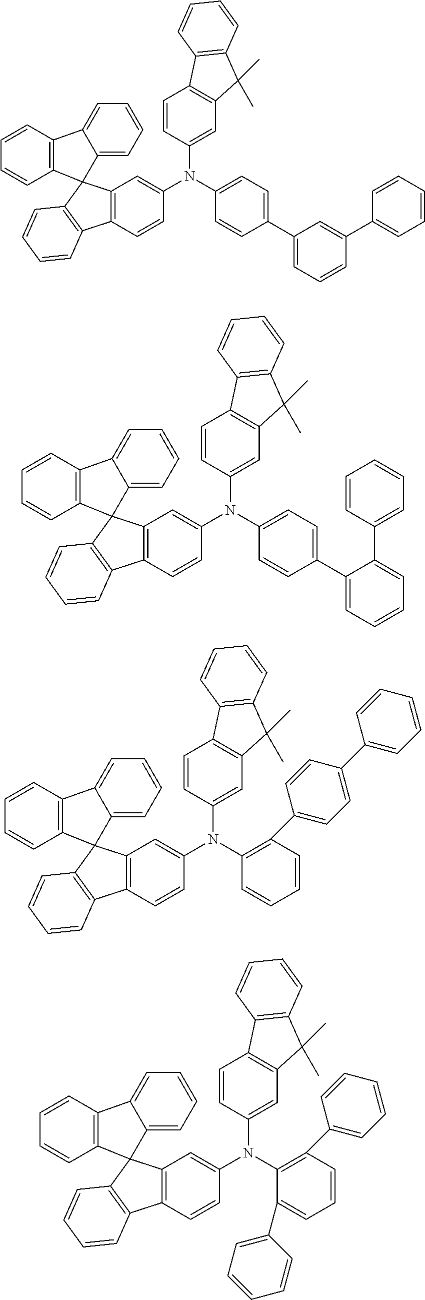 [SMILES: CC1(C)c2ccccc2-c2ccc(N(c3ccc(-c4cccc(-c5ccccc5)c4)cc3)c3ccc4c(c3)C3(c5ccccc5-c5ccccc53)c3ccccc3-4)cc21 ; CC1(C)c2ccccc2-c2ccc(N(c3ccc(-c4ccccc4-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccc(-c4ccccc4)cc3)cc21 ; CC1(C)c2ccccc2-c2ccc(N(c3ccc4c(c3)C3(c5ccccc5-c5ccccc53)c3ccccc3-4)c3c(-c4ccccc4)cccc3-c3ccccc3)cc21]

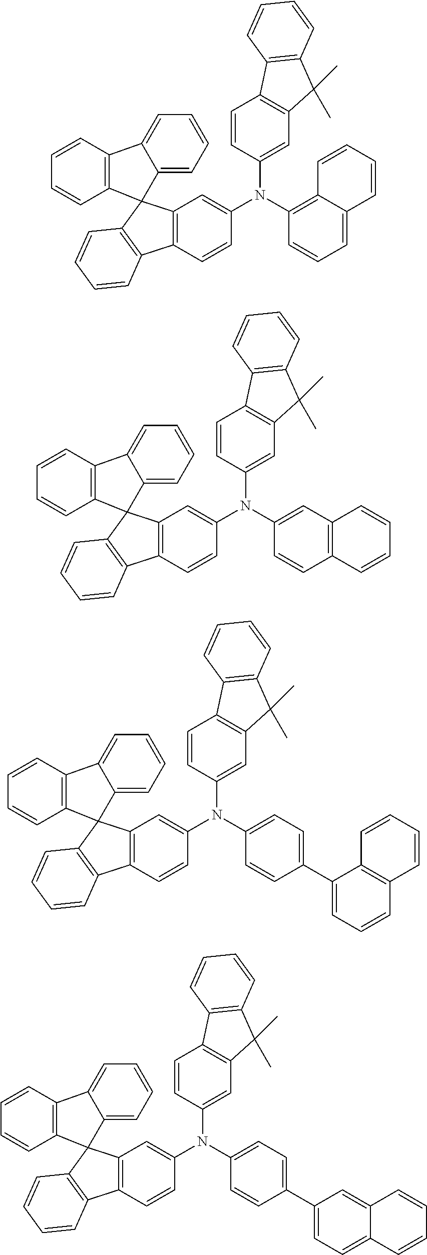 [SMILES: CC1(C)c2ccccc2-c2ccc(N(c3ccc4c(c3)C3(c5ccccc5-c5ccccc53)c3ccccc3-4)c3cccc4ccccc34)cc21 ; CC1(C)c2ccccc2-c2ccc(N(c3ccc4c(c3)C3(c5ccccc5-c5ccccc53)c3ccccc3-4)c3ccc4ccccc4c3)cc21 ; CC1(C)c2ccccc2-c2ccc(N(c3ccc(-c4cccc5ccccc45)cc3)c3ccc4c(c3)C3(c5ccccc5-c5ccccc53)c3ccccc3-4)cc21 ; CC1(C)c2ccccc2-c2ccc(N(c3ccc(-c4ccc5ccccc5c4)cc3)c3ccc4c(c3)C3(c5ccccc5-c5ccccc53)c3ccccc3-4)cc21]

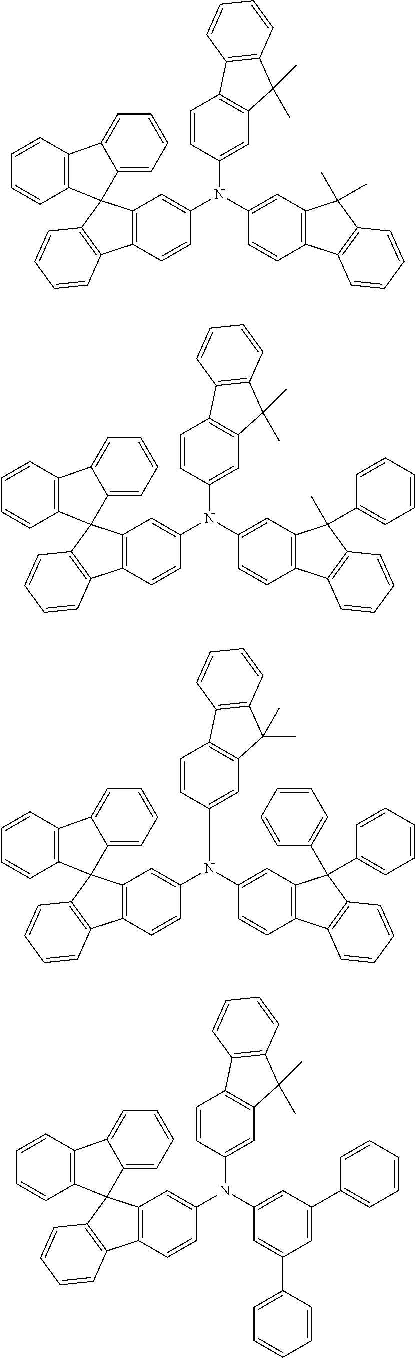 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(c3ccccc3)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc21 ; CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21]

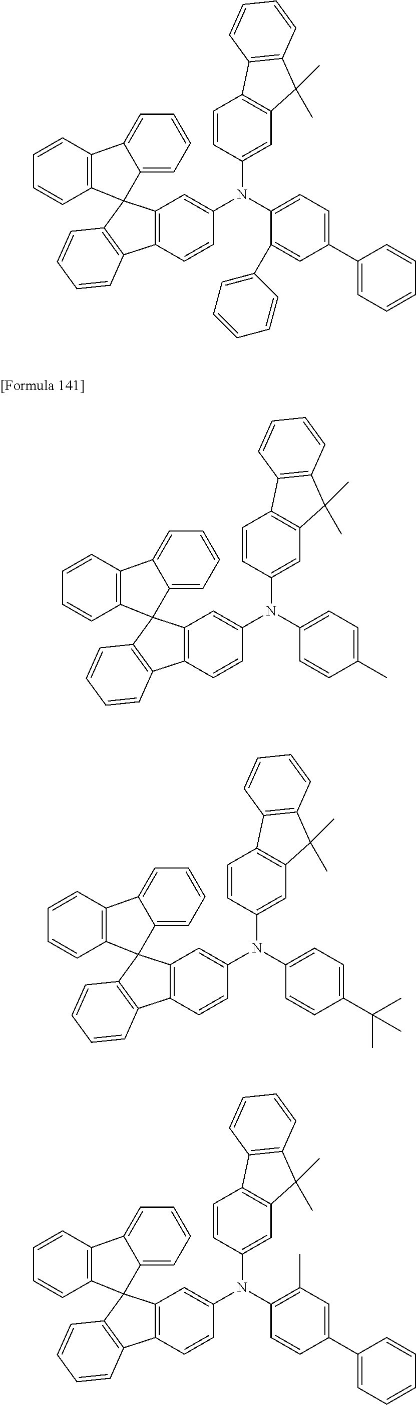 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21 ; Cc1ccc(N(c2ccc3c(c2)C(C)(C)c2ccccc2-3)c2ccc3c(c2)C2(c4ccccc4-c4ccccc42)c2ccccc2-3)cc1 ; CC(C)(C)c1ccc(N(c2ccc3c(c2)C(C)(C)c2ccccc2-3)c2ccc3c(c2)C2(c4ccccc4-c4ccccc42)c2ccccc2-3)cc1 ; Cc1cc(-c2ccccc2)ccc1N(c1ccc2c(c1)C(C)(C)c1ccccc1-2)c1ccc2c(c1)C1(c3ccccc3-c3ccccc31)c1ccccc1-2]

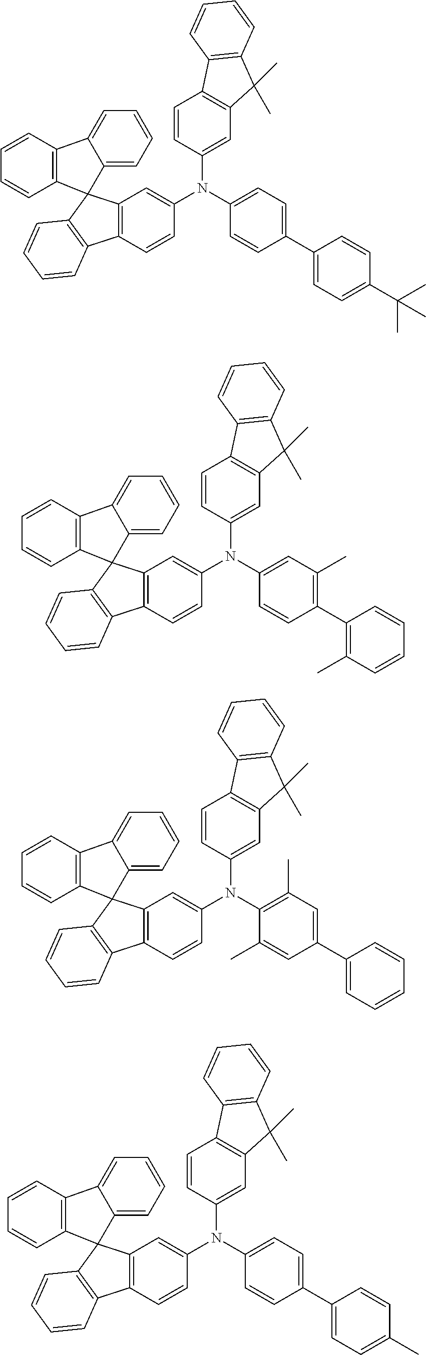 [SMILES: CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; Cc1ccccc1-c1ccc(N(c2ccc3c(c2)C(C)(C)c2ccccc2-3)c2ccc3c(c2)C2(c4ccccc4-c4ccccc42)c2ccccc2-3)cc1C ; Cc1cc(-c2ccccc2)cc(C)c1N(c1ccc2c(c1)C(C)(C)c1ccccc1-2)c1ccc2c(c1)C1(c3ccccc3-c3ccccc31)c1ccccc1-2 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

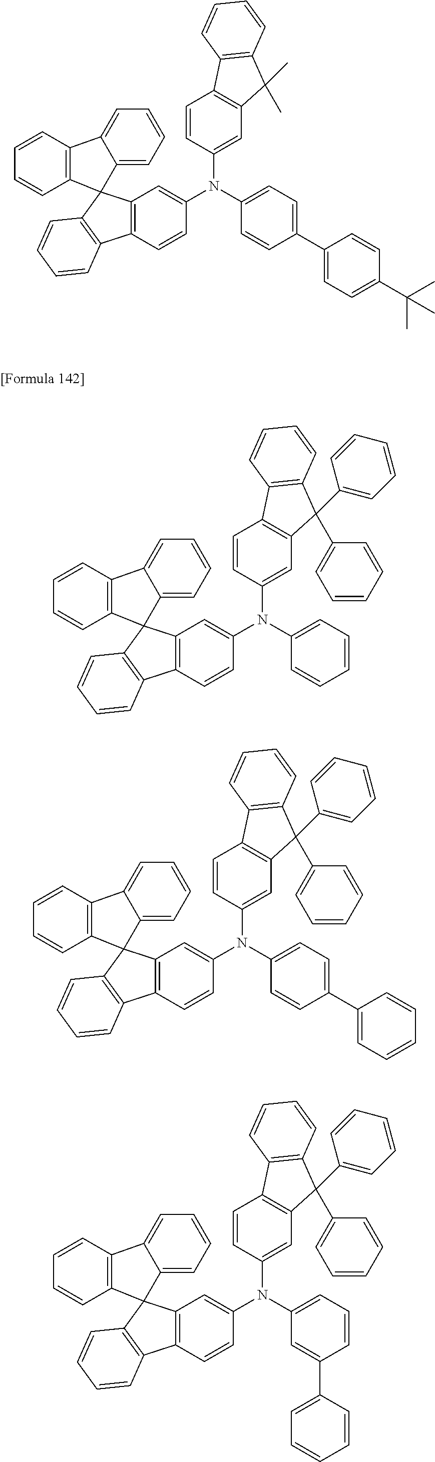 [SMILES: CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1 ; c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; c1ccc(-c2cccc(N(c3ccc4c(c3)C(c3ccccc3)(c3ccccc3)c3ccccc3-4)c3ccc4c(c3)C3(c5ccccc5-c5ccccc53)c3ccccc3-4)c2)cc1]

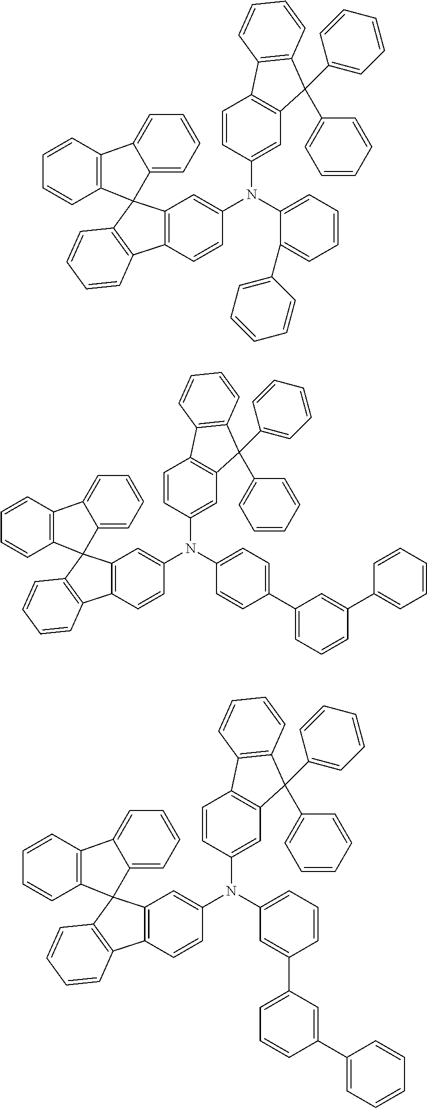

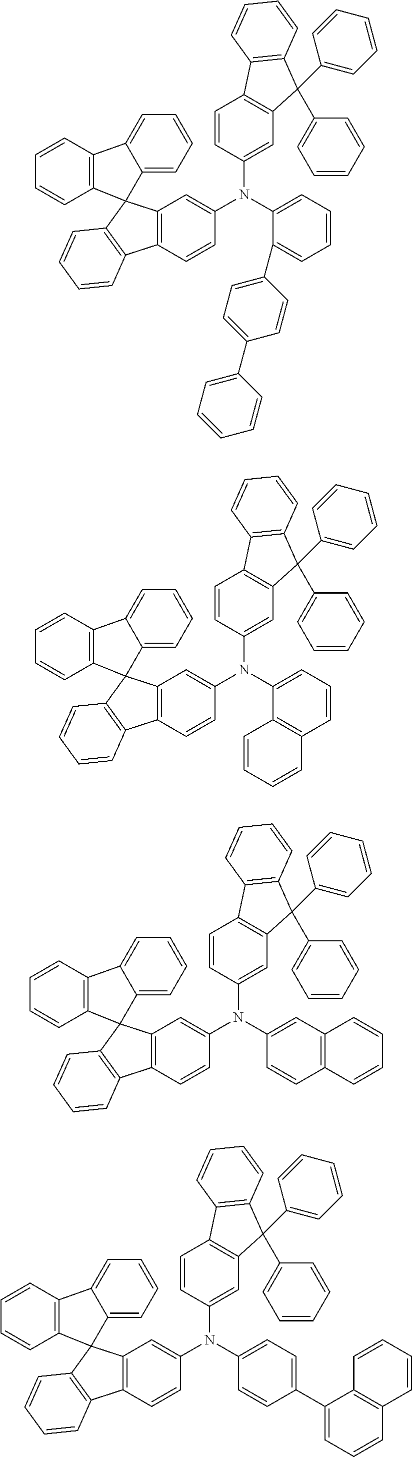

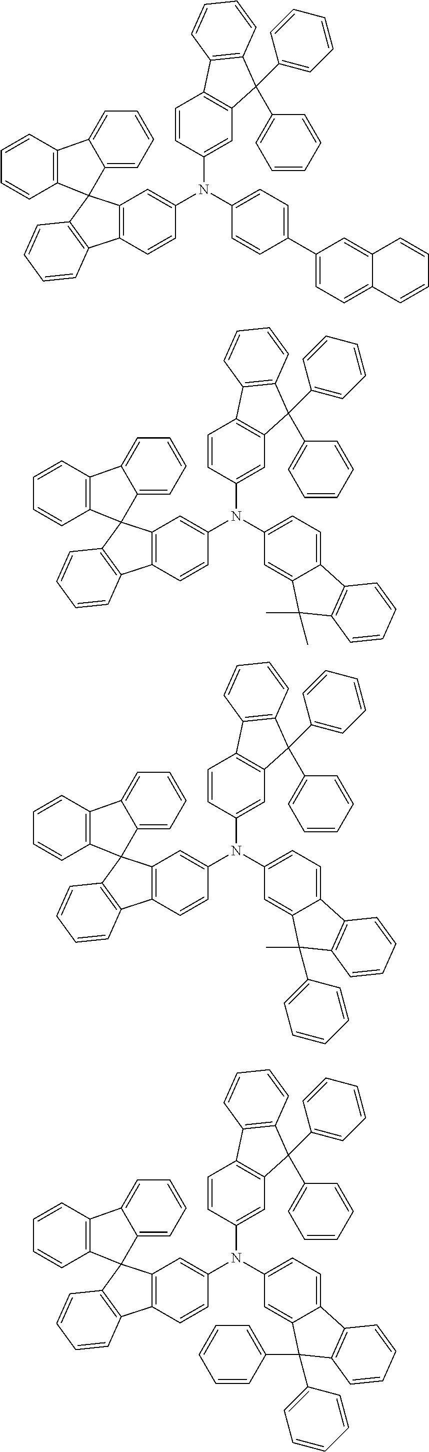

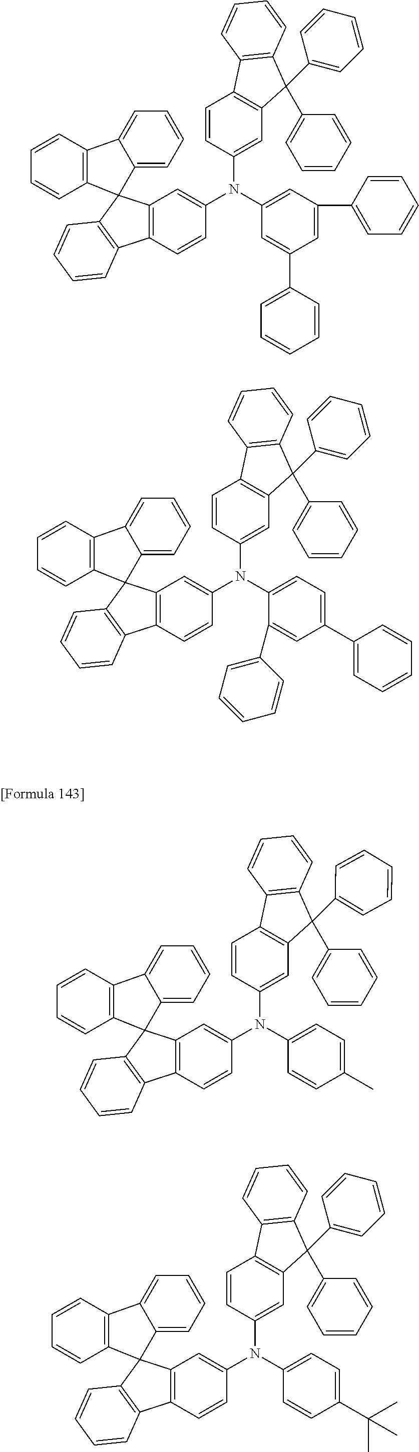

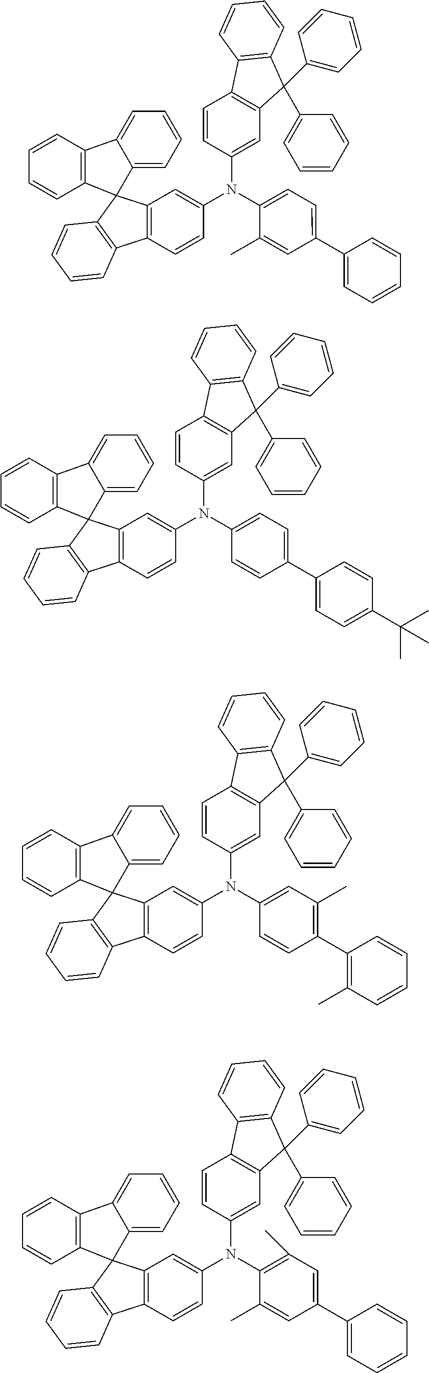 [SMILES: Cc1cc(-c2ccccc2)ccc1N(c1ccc2c(c1)C(c1ccccc1)(c1ccccc1)c1ccccc1-2)c1ccc2c(c1)C1(c3ccccc3-c3ccccc31)c1ccccc1-2 ; CC(C)(C)c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; Cc1ccccc1-c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1C ; Cc1cc(-c2ccccc2)cc(C)c1N(c1ccc2c(c1)C(c1ccccc1)(c1ccccc1)c1ccccc1-2)c1ccc2c(c1)C1(c3ccccc3-c3ccccc31)c1ccccc1-2]

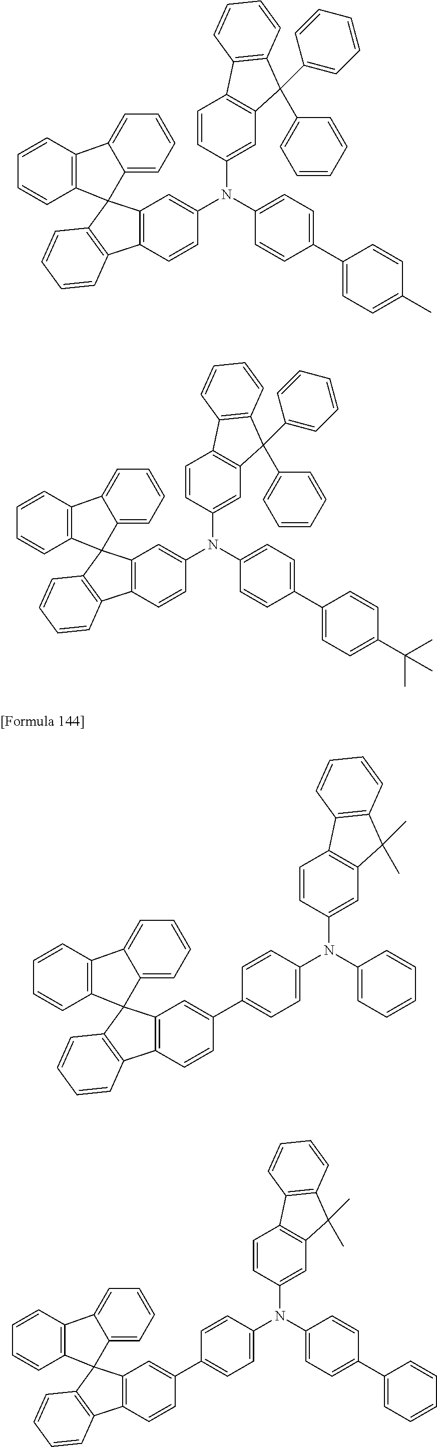 [SMILES: Cc1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; CC1(C)c2ccccc2-c2ccc(N(c3ccccc3)c3ccc(-c4ccc5c(c4)C4(c6ccccc6-c6ccccc64)c4ccccc4-5)cc3)cc21 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

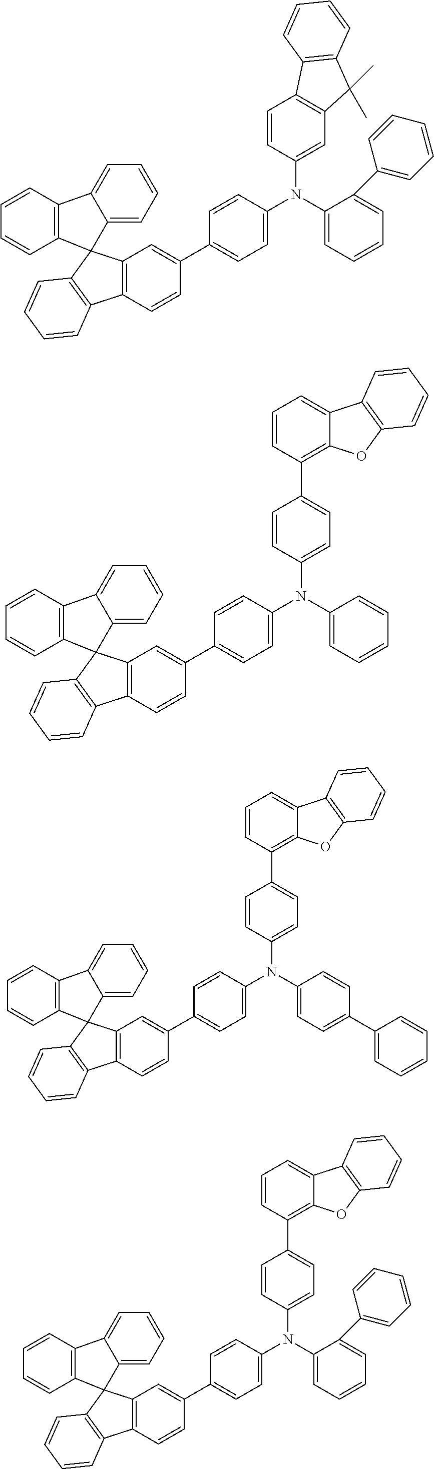 [SMILES: CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21 ; c1ccc(N(c2ccc(-c3ccc4c(c3)C3(c5ccccc5-c5ccccc53)c3ccccc3-4)cc2)c2ccc(-c3cccc4c3oc3ccccc34)cc2)cc1 ; c1ccc(-c2ccc(N(c3ccc(-c4ccc5c(c4)C4(c6ccccc6-c6ccccc64)c4ccccc4-5)cc3)c3ccc(-c4cccc5c4oc4ccccc45)cc3)cc2)cc1 ; c1ccc(-c2ccccc2N(c2ccc(-c3ccc4c(c3)C3(c5ccccc5-c5ccccc53)c3ccccc3-4)cc2)c2ccc(-c3cccc4c3oc3ccccc34)cc2)cc1]

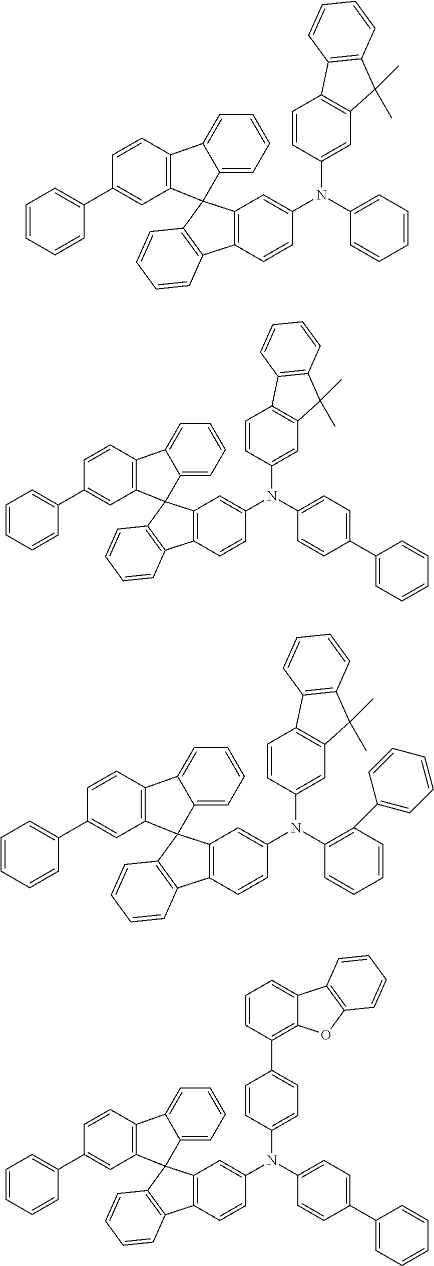 [SMILES: CC1(C)c2ccccc2-c2ccc(N(c3ccccc3)c3ccc4c(c3)C3(c5ccccc5-c5ccc(-c6ccccc6)cc53)c3ccccc3-4)cc21 ; CC1(C)c2ccccc2-c2ccc(N(c3ccc(-c4ccccc4)cc3)c3ccc4c(c3)C3(c5ccccc5-c5ccc(-c6ccccc6)cc53)c3ccccc3-4)cc21 ; CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21 ; c1ccc(-c2ccc(N(c3ccc(-c4cccc5c4oc4ccccc45)cc3)c3ccc4c(c3)C3(c5ccccc5-c5ccc(-c6ccccc6)cc53)c3ccccc3-4)cc2)cc1]

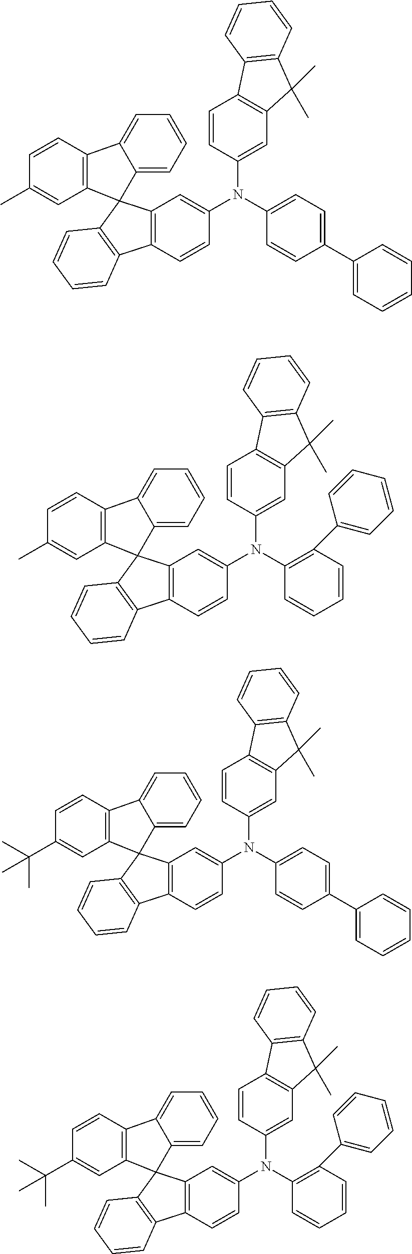 [SMILES: Cc1ccc2c(c1)C1(c3ccccc3-2)c2ccccc2-c2ccc(N(c3ccc(-c4ccccc4)cc3)c3ccc4c(c3)C(C)(C)c3ccccc3-4)cc21 ; Cc1ccc2c(c1)C1(c3ccccc3-2)c2ccccc2-c2ccc(N(c3ccc4c(c3)C(C)(C)c3ccccc3-4)c3ccccc3-c3ccccc3)cc21 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1ccccc1-2 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1ccccc1-2]

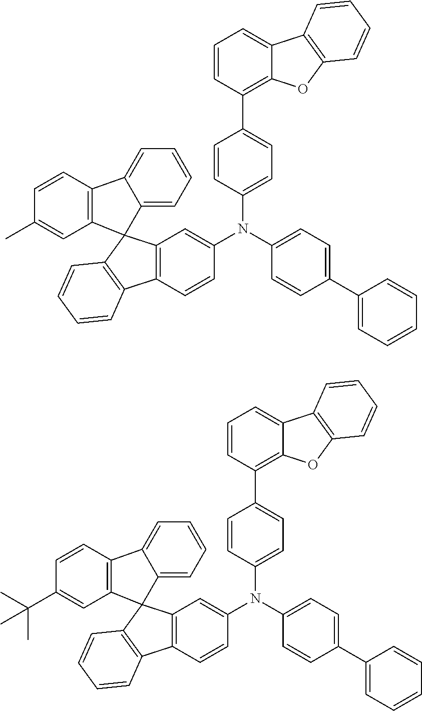

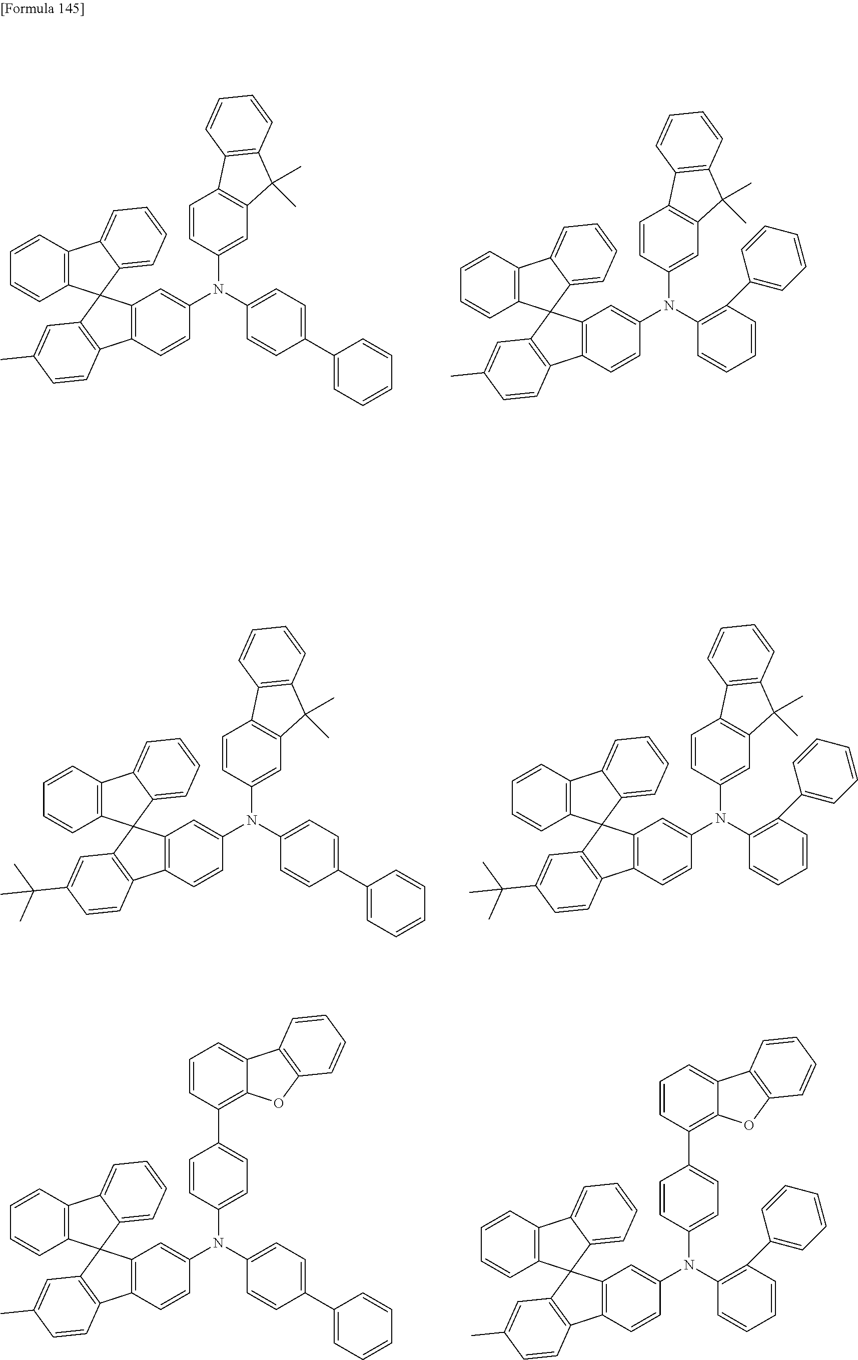

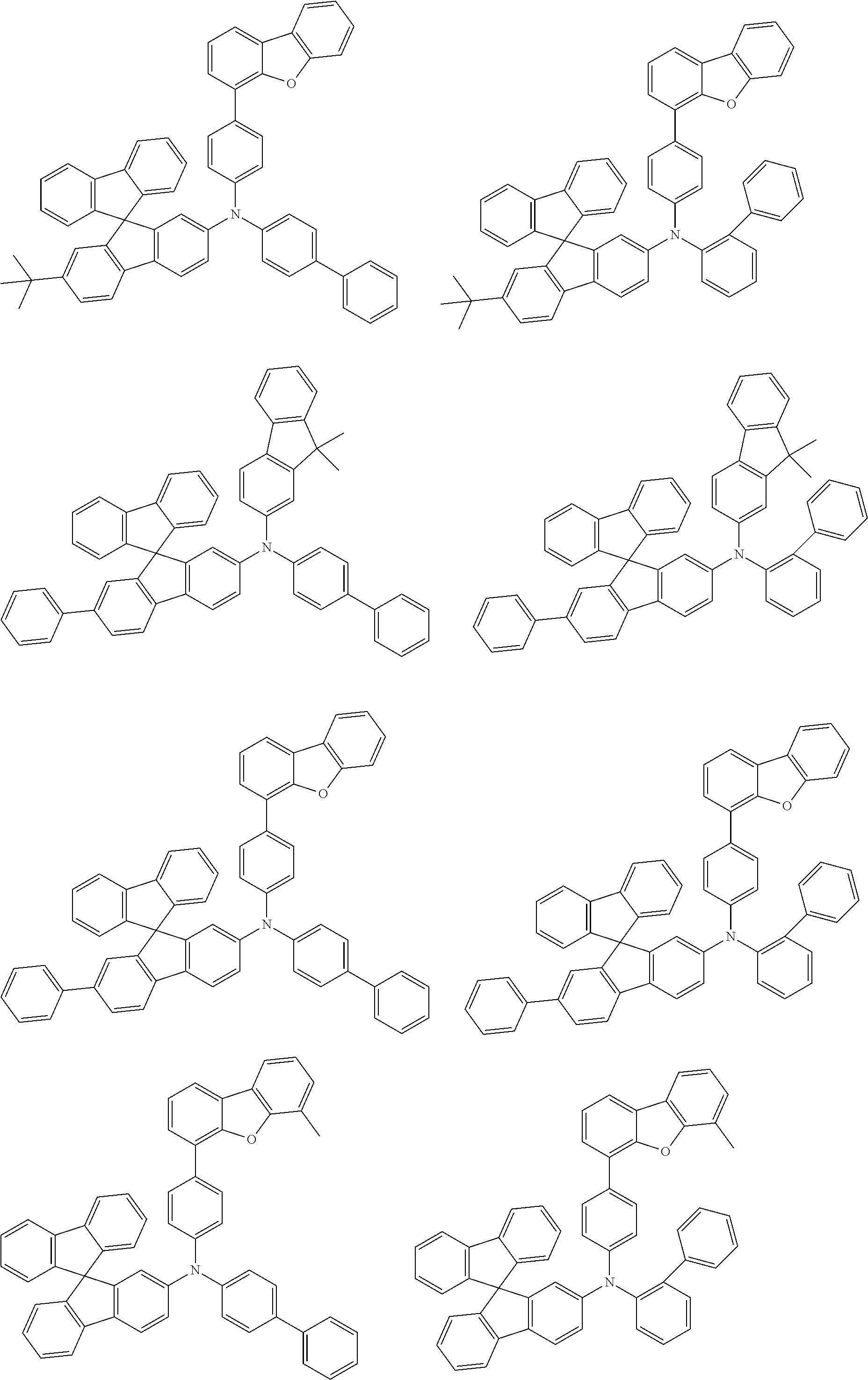

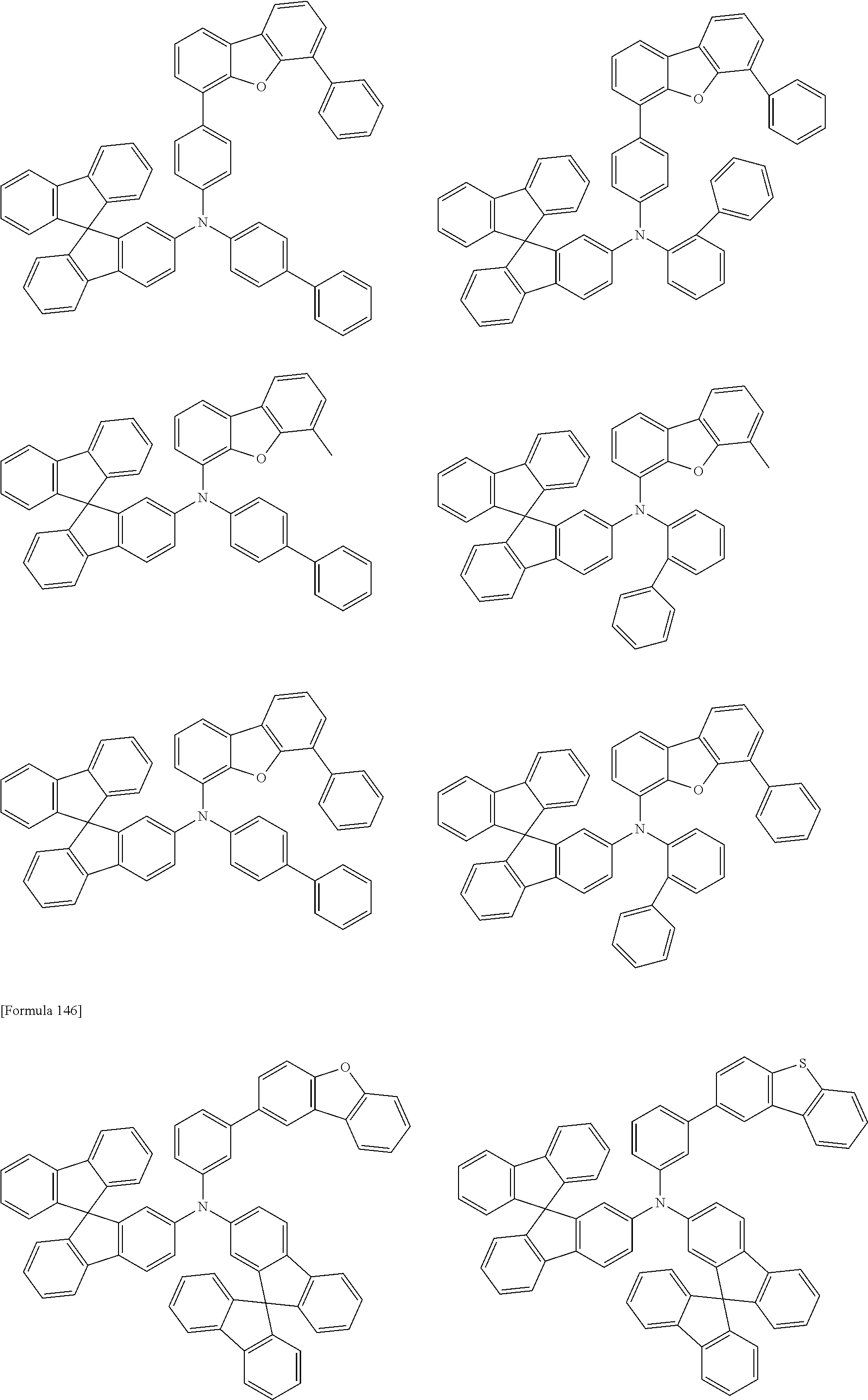

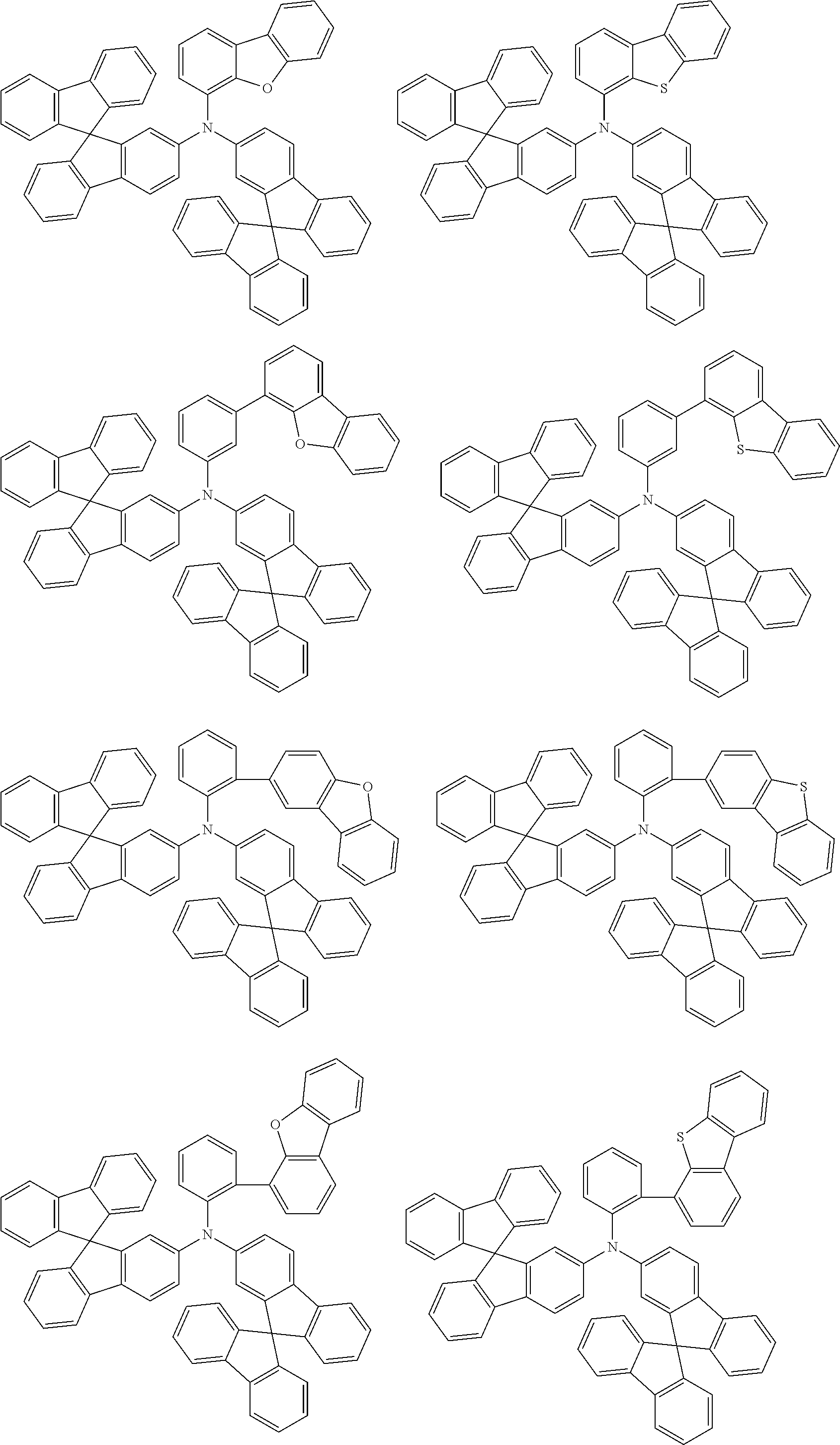

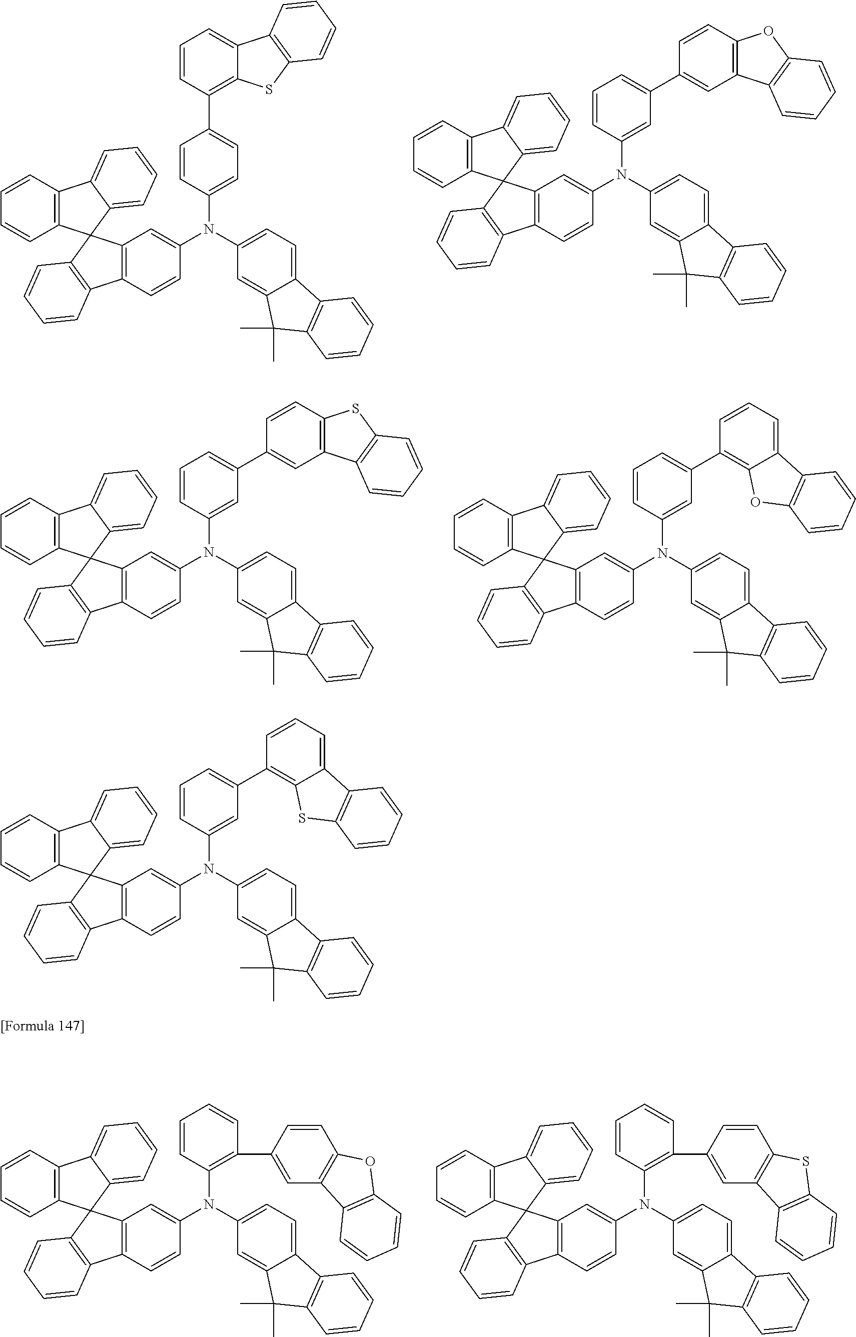

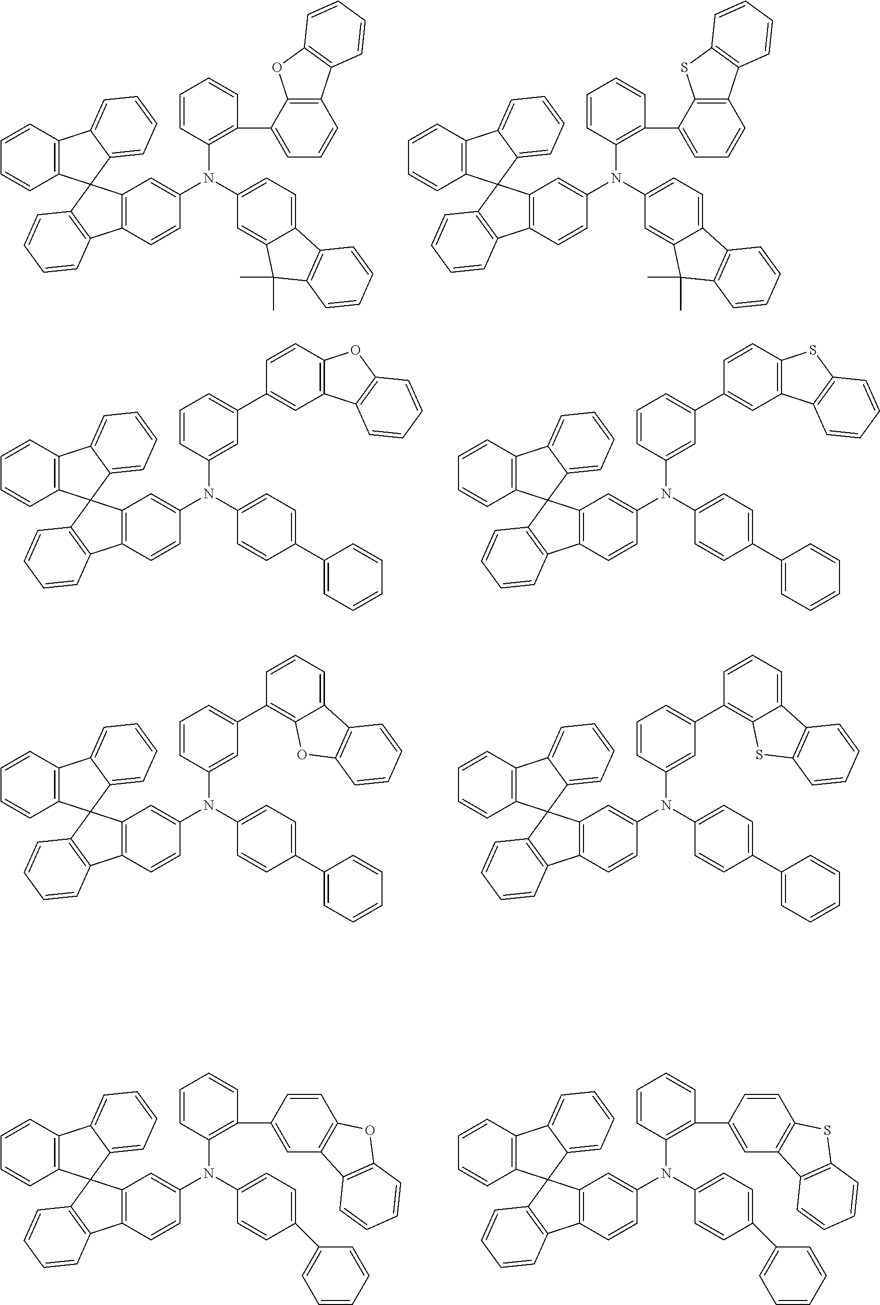

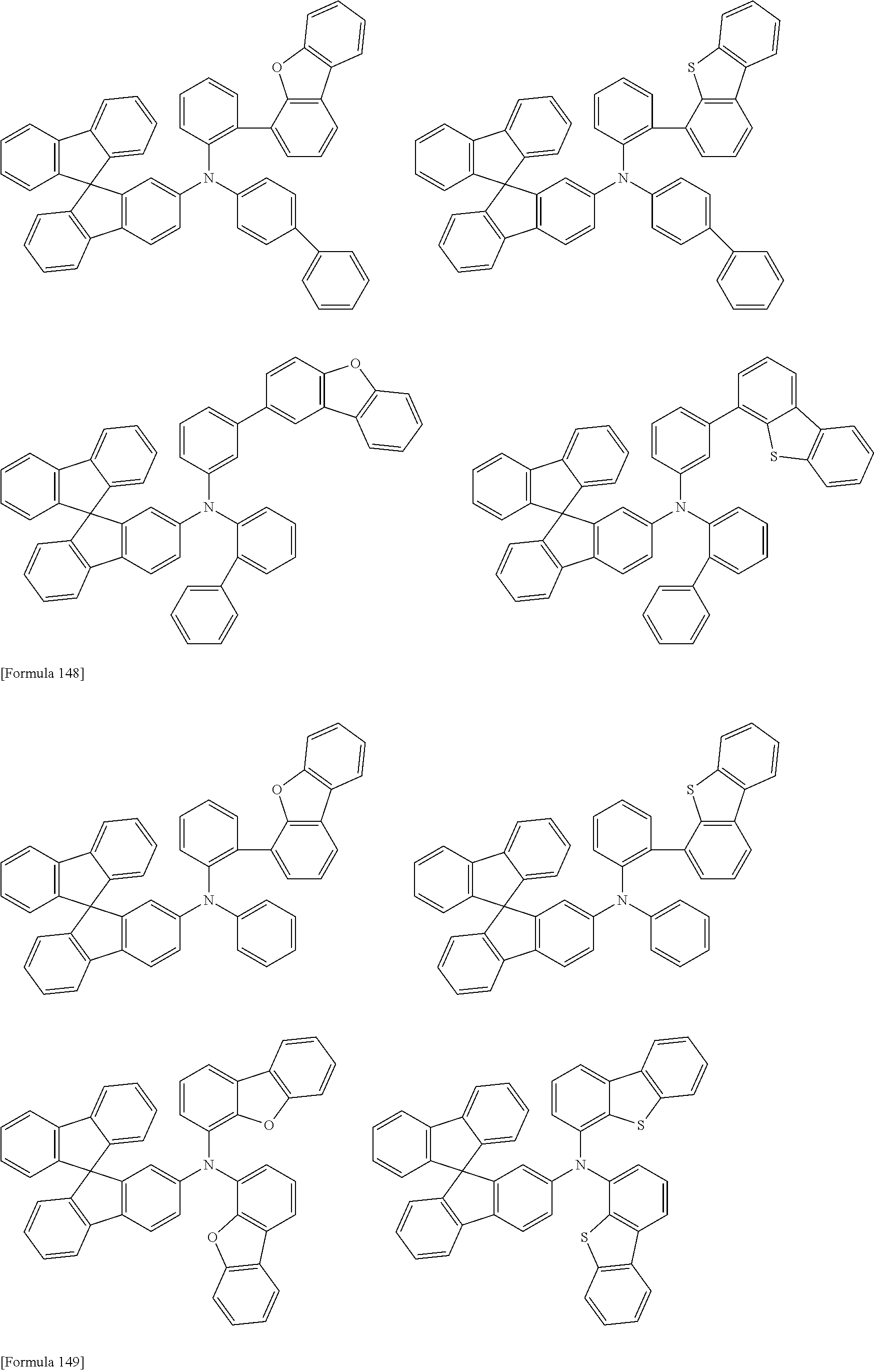

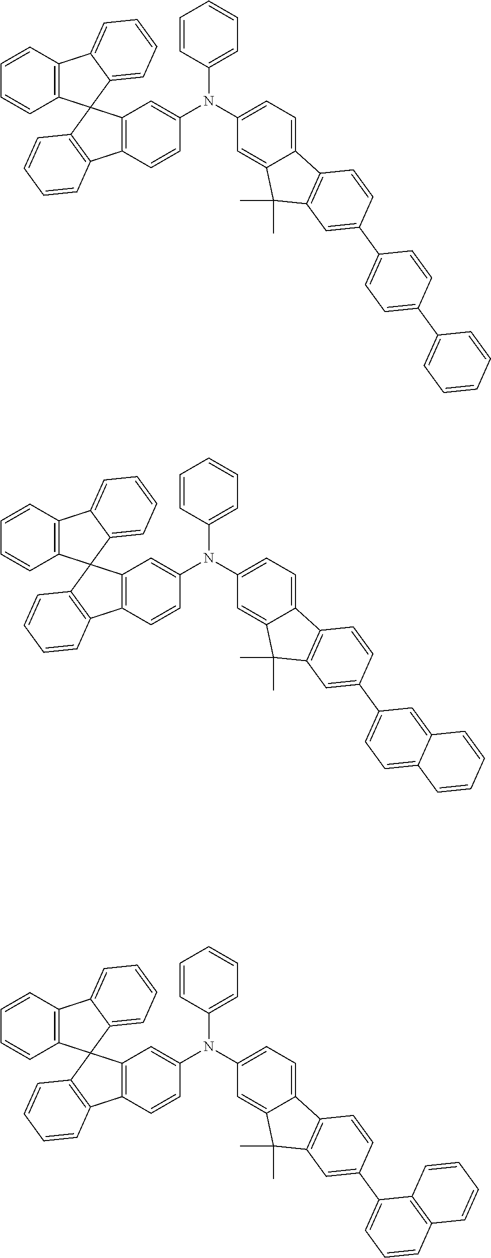 [SMILES: CC1(C)c2cc(-c3ccc(-c4ccccc4)cc3)ccc2-c2ccc(N(c3ccccc3)c3ccc4c(c3)C3(c5ccccc5-c5ccccc53)c3ccccc3-4)cc21 ; CC1(C)c2cc(-c3ccc4ccccc4c3)ccc2-c2ccc(N(c3ccccc3)c3ccc4c(c3)C3(c5ccccc5-c5ccccc53)c3ccccc3-4)cc21 ; CC1(C)c2cc(-c3cccc4ccccc34)ccc2-c2ccc(N(c3ccccc3)c3ccc4c(c3)C3(c5ccccc5-c5ccccc53)c3ccccc3-4)cc21]

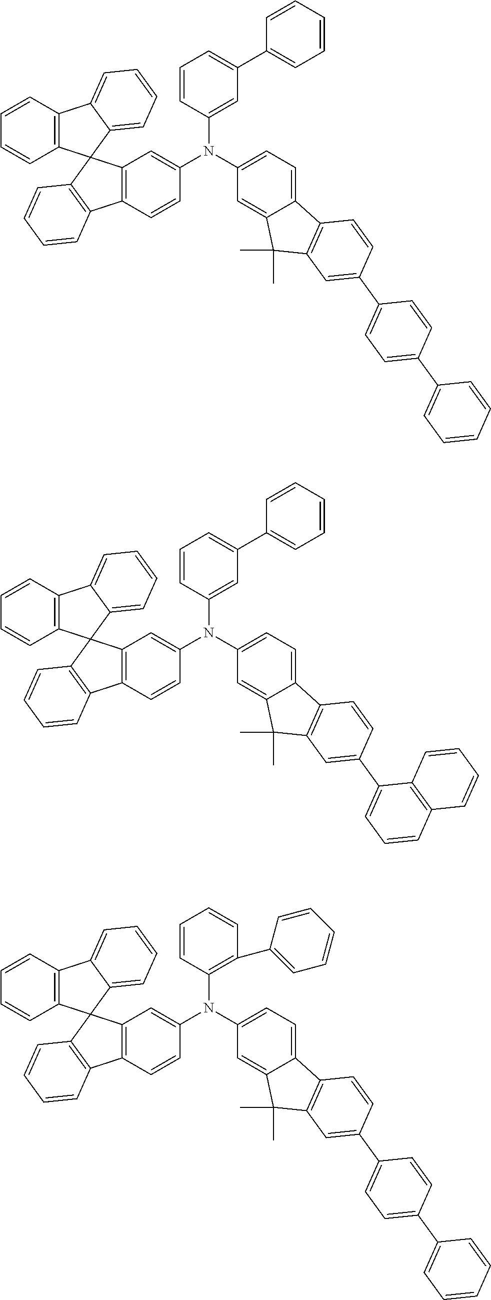 [SMILES: CC1(C)c2cc(-c3ccc(-c4ccccc4)cc3)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3cccc4ccccc34)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3ccc(-c4ccccc4)cc3)ccc2-c2ccc(N(c3ccc4c(c3)C3(c5ccccc5-c5ccccc53)c3ccccc3-4)c3ccccc3-c3ccccc3)cc21]

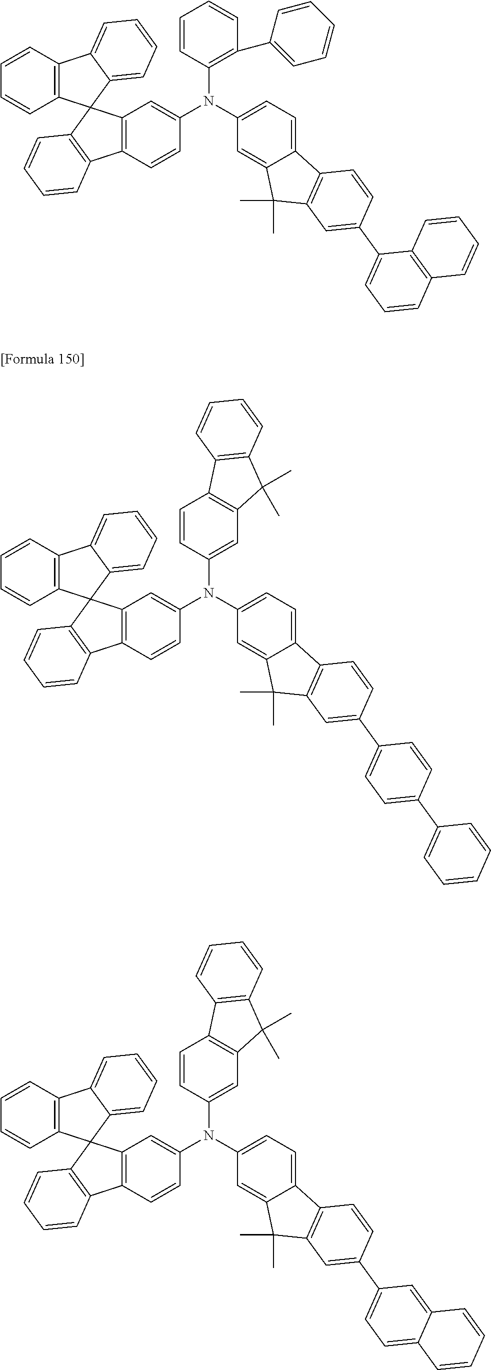 [SMILES: CC1(C)c2cc(-c3cccc4ccccc34)ccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc4c(c3)C(C)(C)c3cc(-c5ccc(-c6ccccc6)cc5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5ccc6ccccc6c5)ccc3-4)c3ccc4c(c3)C3(c5ccccc5-c5ccccc53)c3ccccc3-4)cc21]

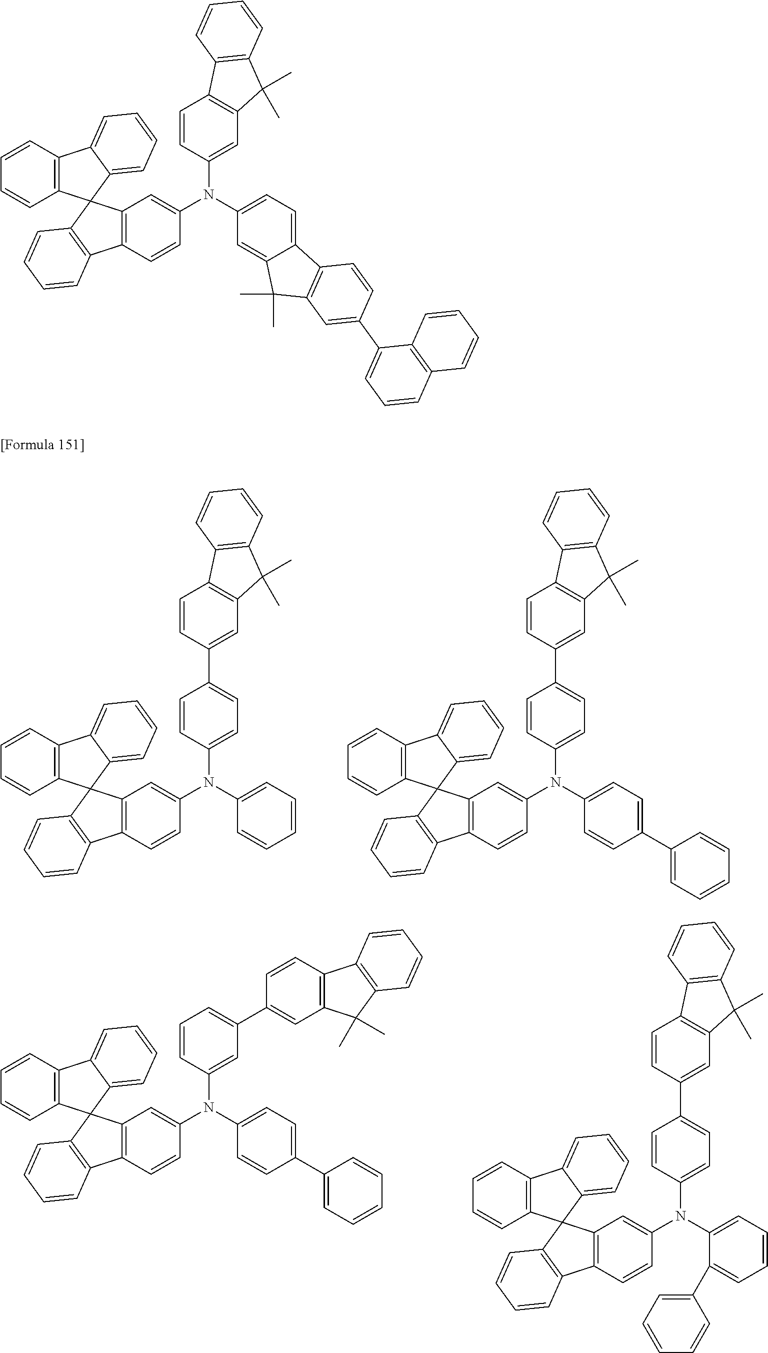

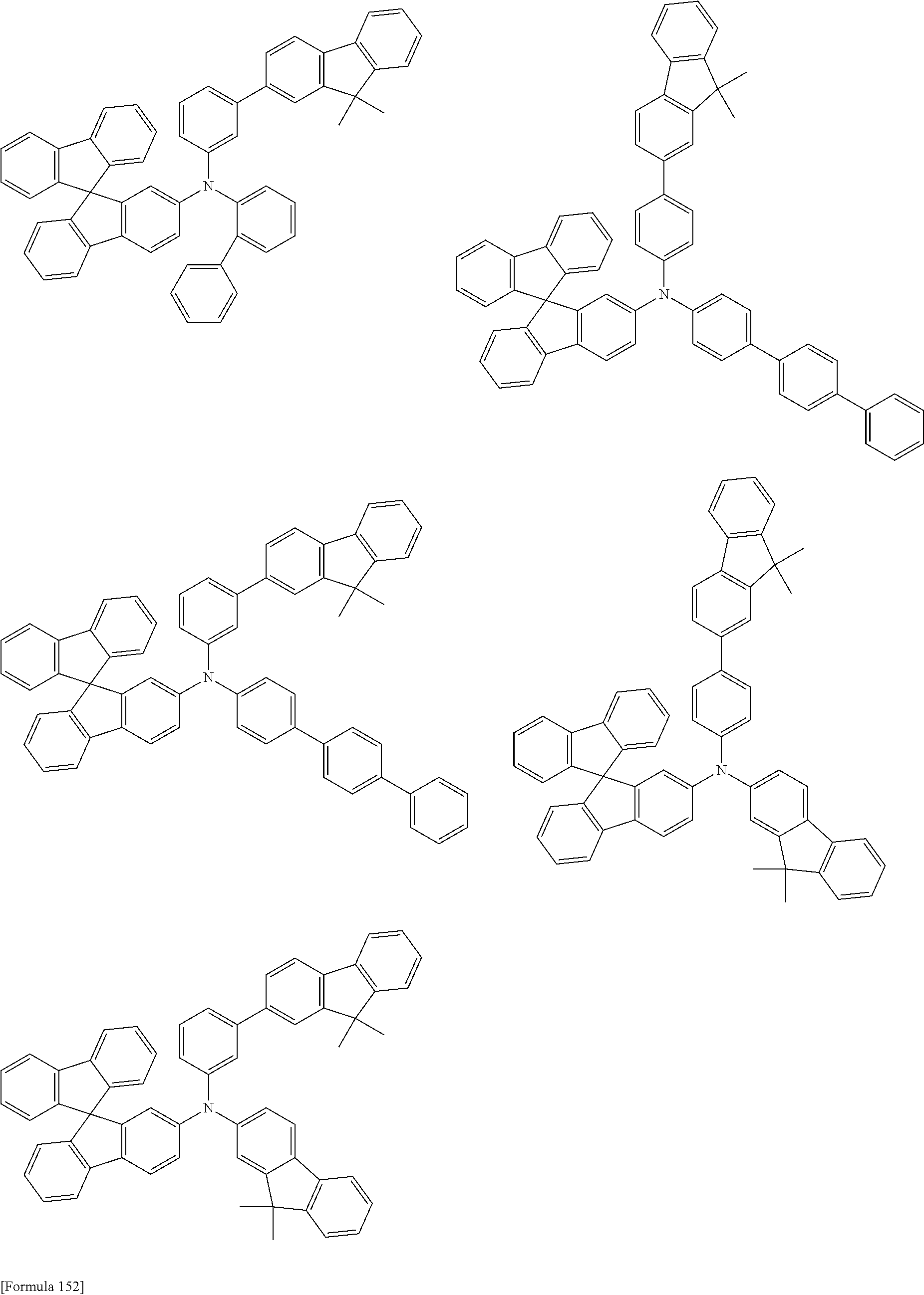

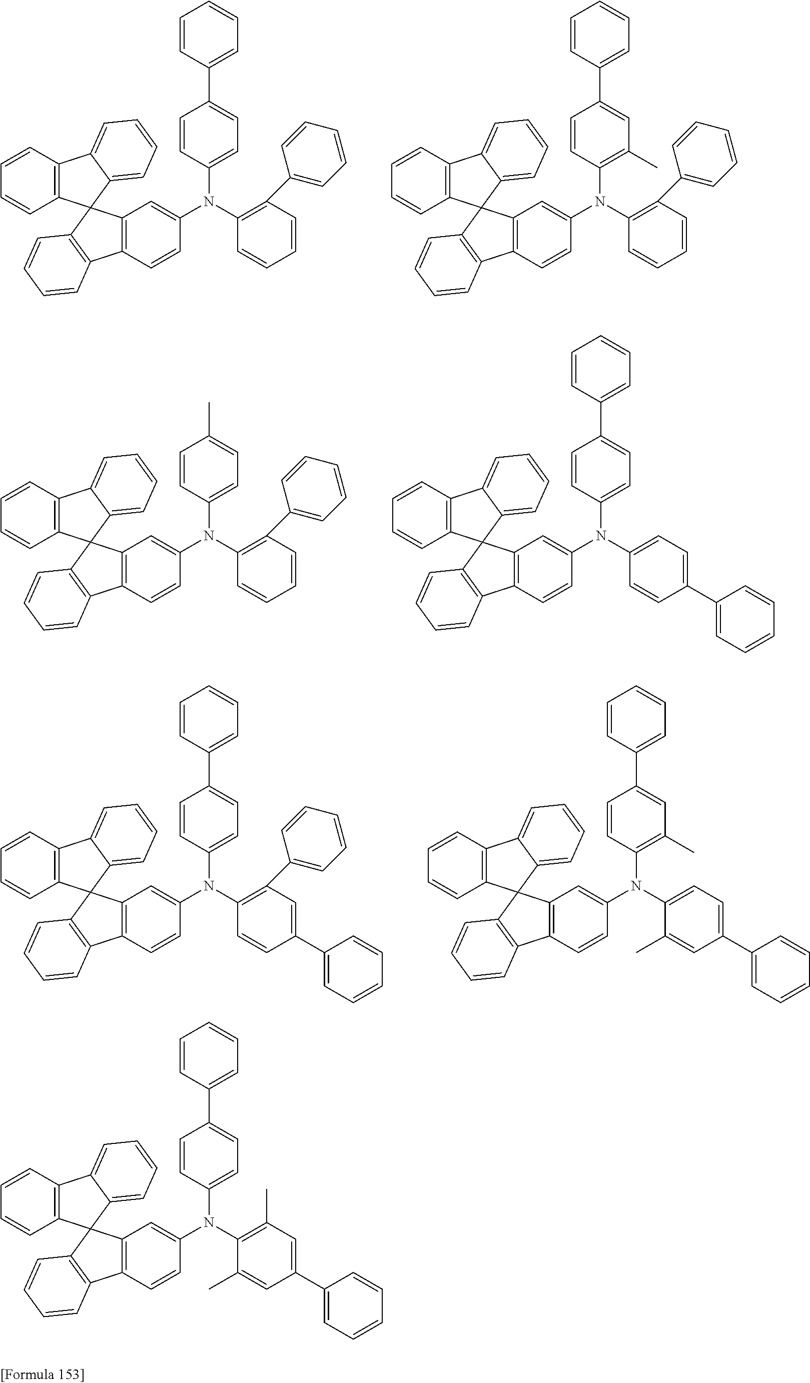

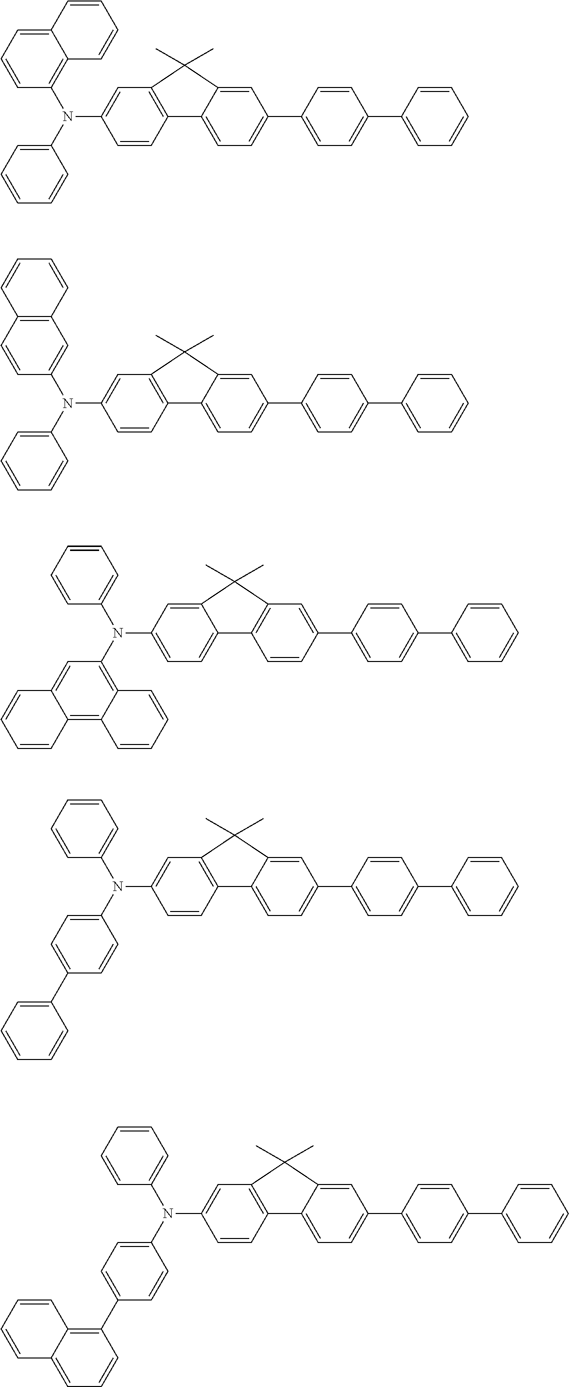 [SMILES: CC1(C)c2cc(-c3ccc(-c4ccccc4)cc3)ccc2-c2ccc(N(c3ccccc3)c3cccc4ccccc34)cc21 ; CC1(C)c2cc(-c3ccc(-c4ccccc4)cc3)ccc2-c2ccc(N(c3ccccc3)c3ccc4ccccc4c3)cc21 ; CC1(C)c2cc(-c3ccc(-c4ccccc4)cc3)ccc2-c2ccc(N(c3ccccc3)c3cc4ccccc4c4ccccc34)cc21 ; CC1(C)c2cc(-c3ccc(-c4ccccc4)cc3)ccc2-c2ccc(N(c3ccccc3)c3ccc(-c4ccccc4)cc3)cc21 ; CC1(C)c2cc(-c3ccc(-c4ccccc4)cc3)ccc2-c2ccc(N(c3ccccc3)c3ccc(-c4cccc5ccccc45)cc3)cc21]

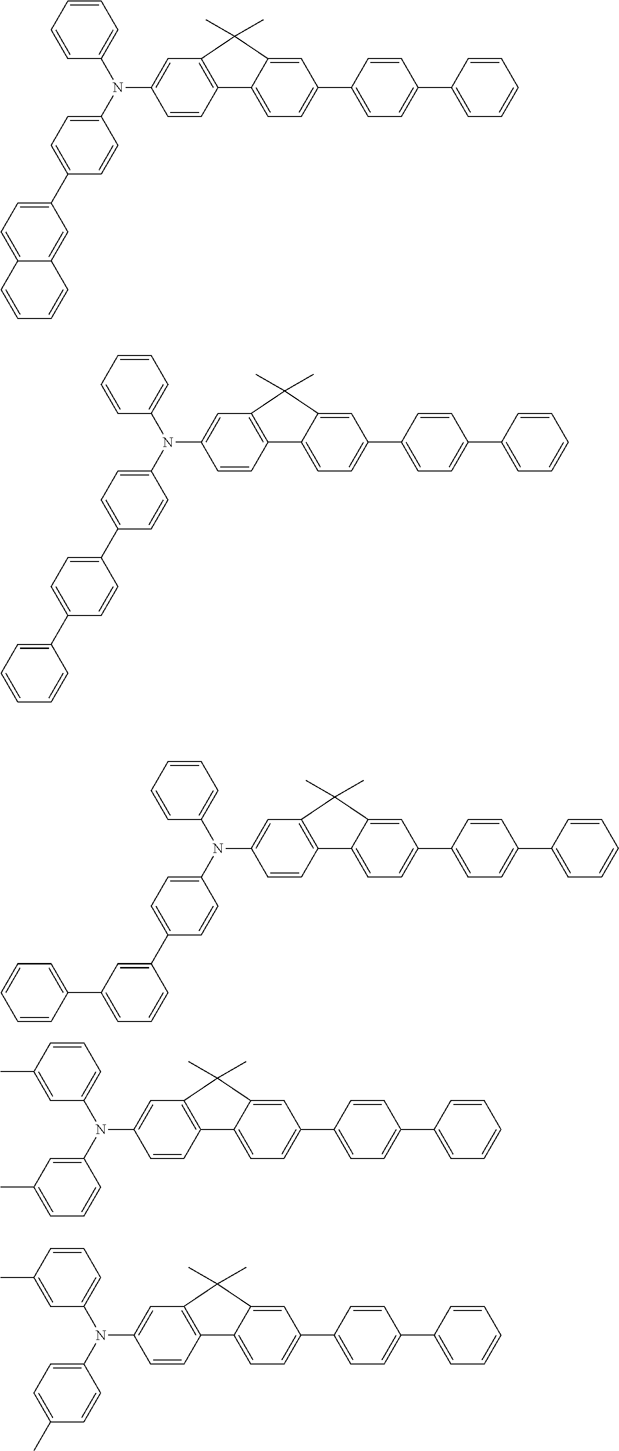

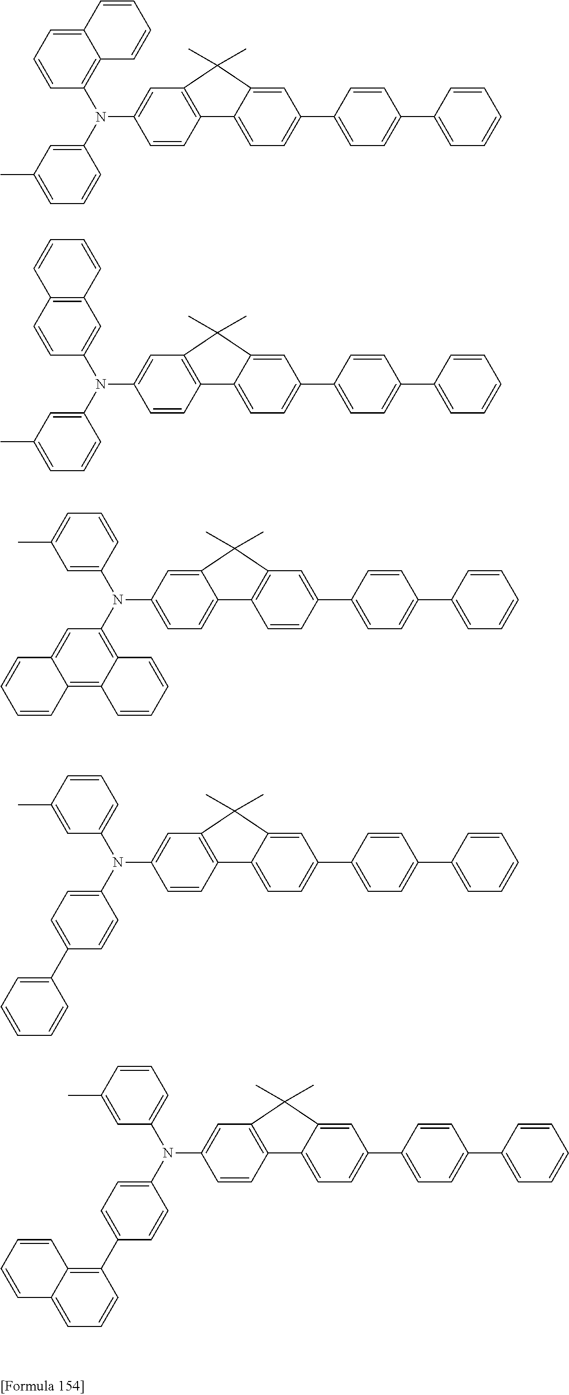

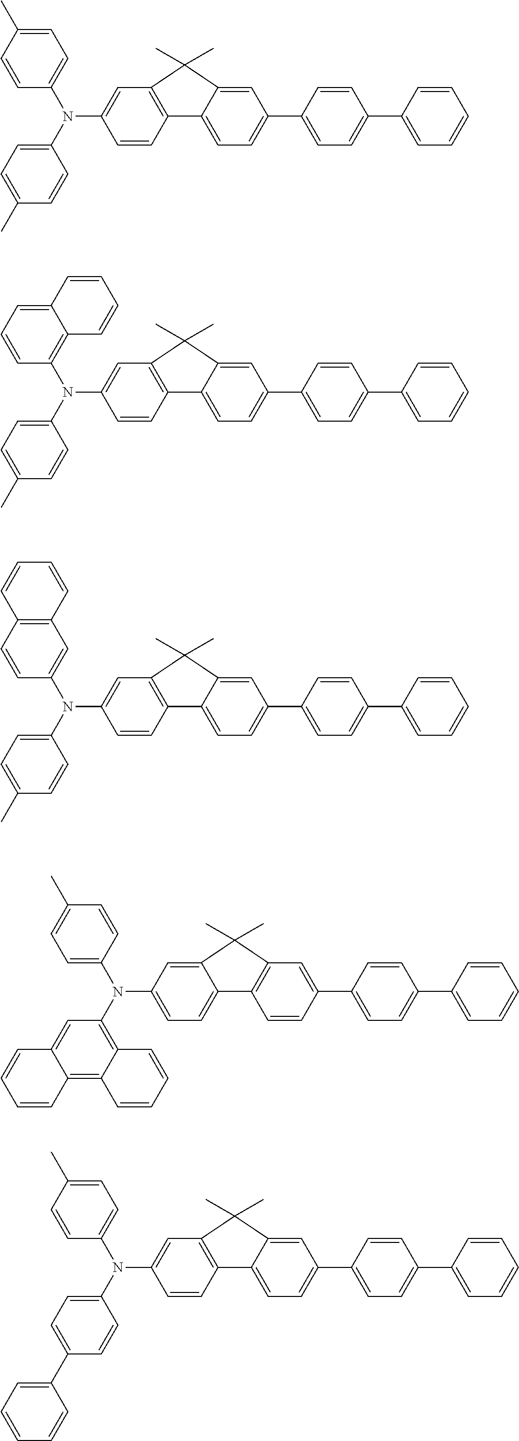

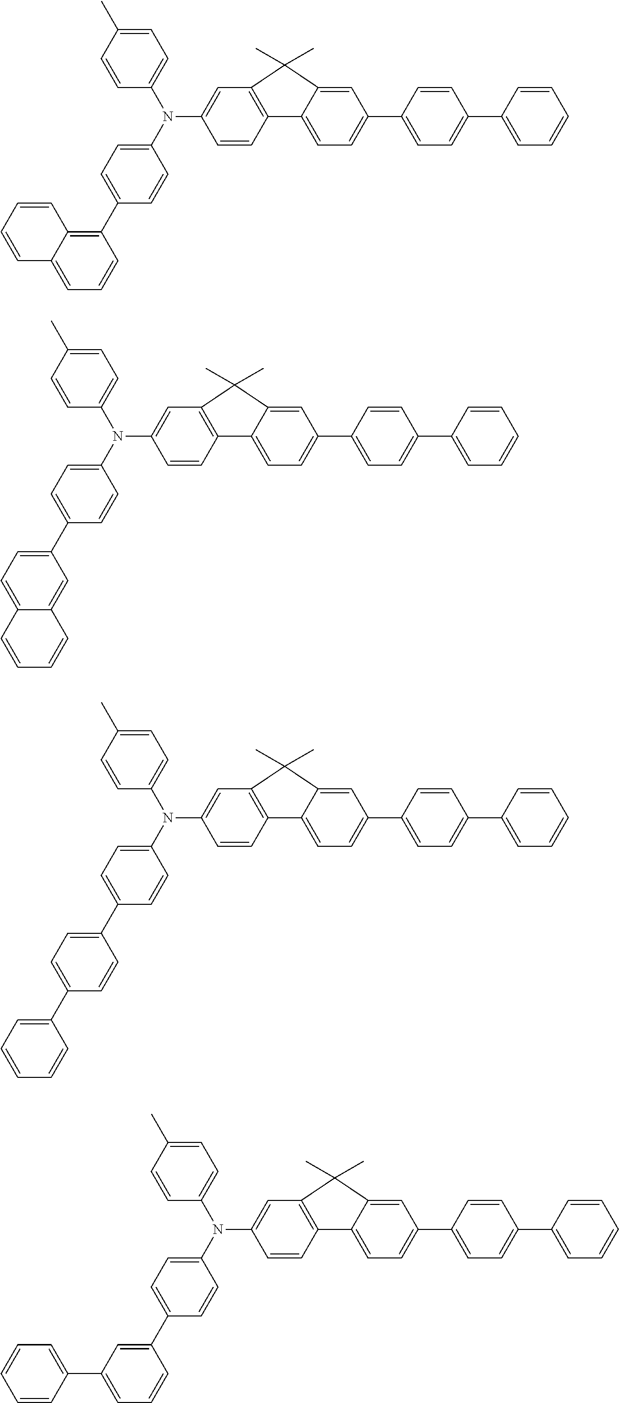

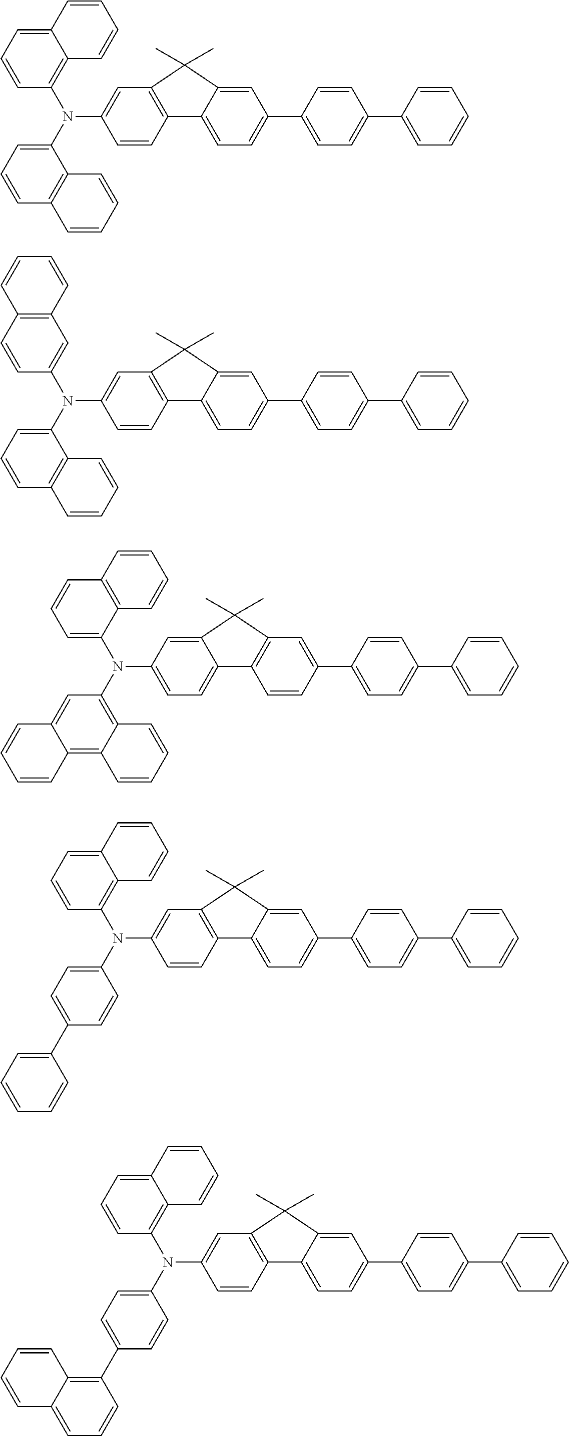

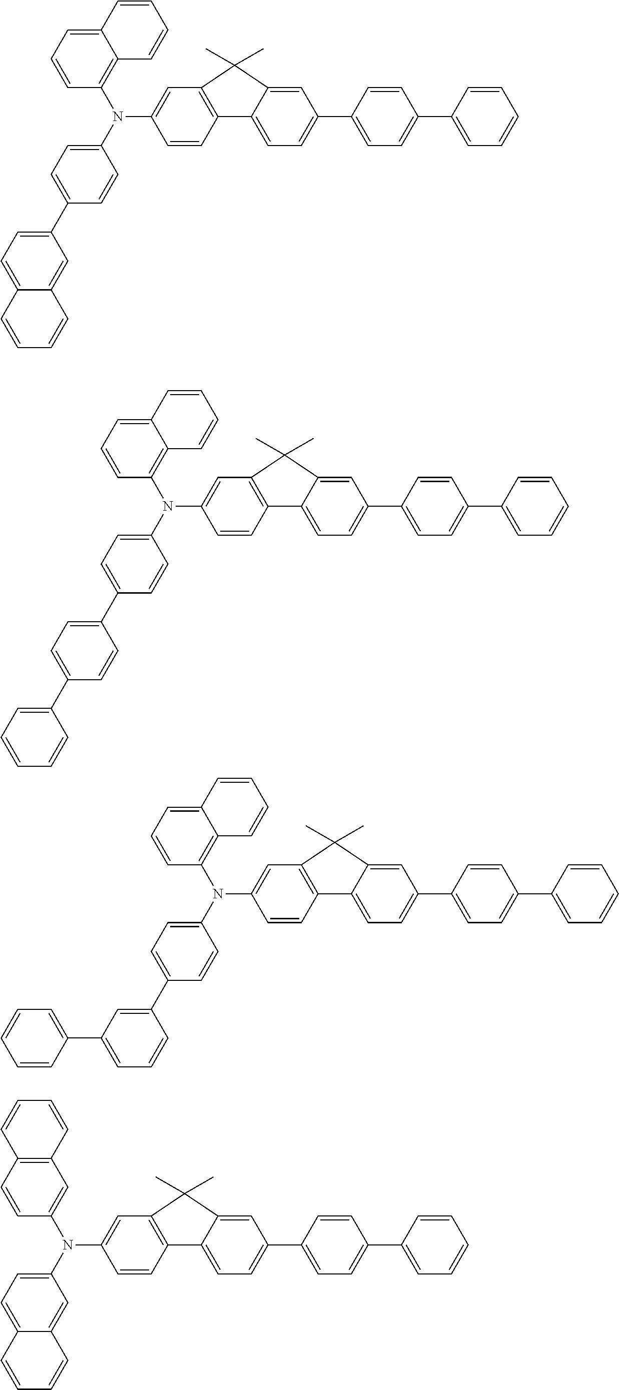

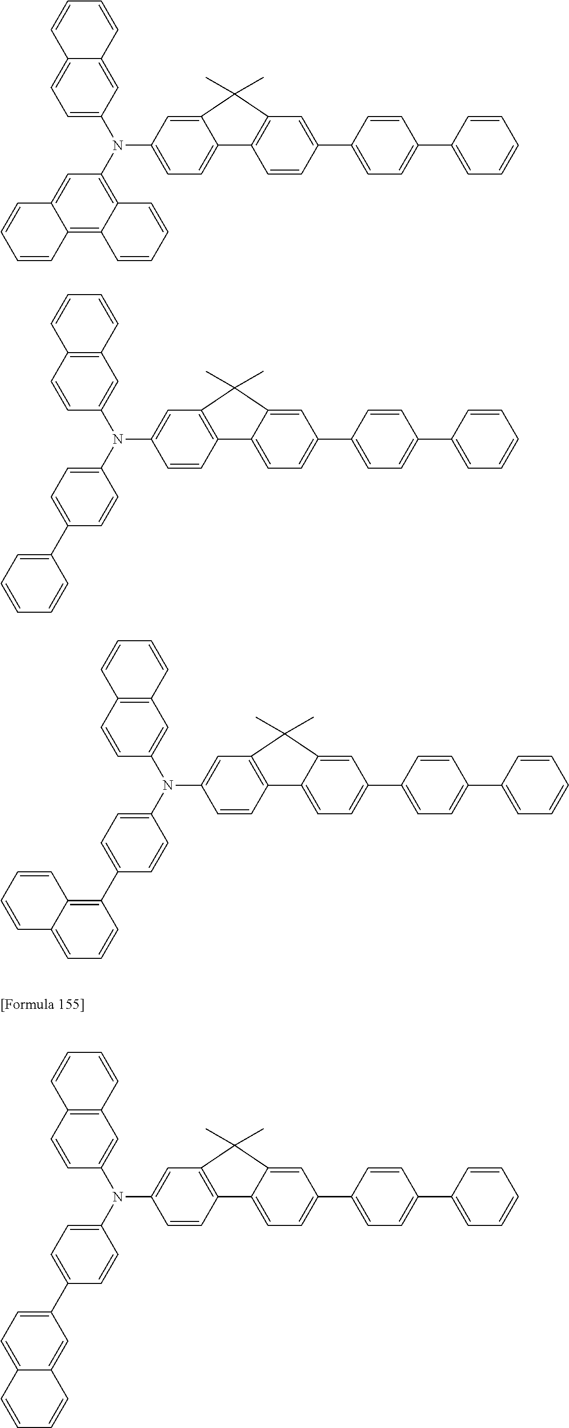

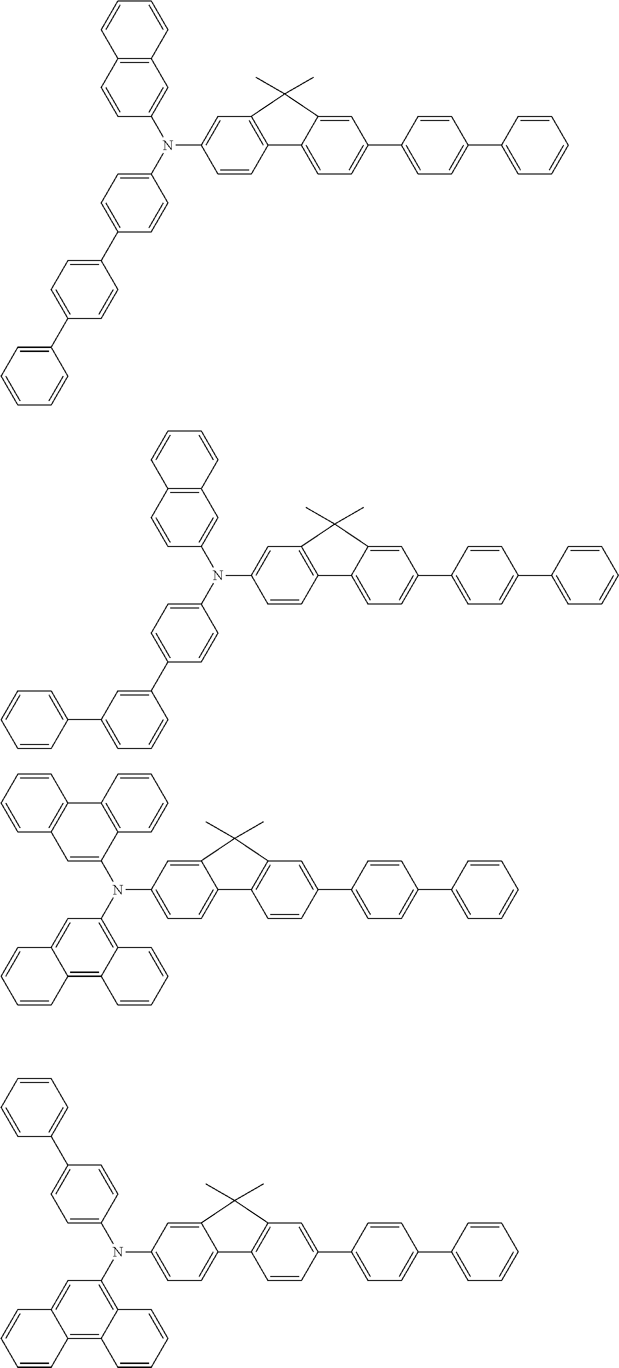

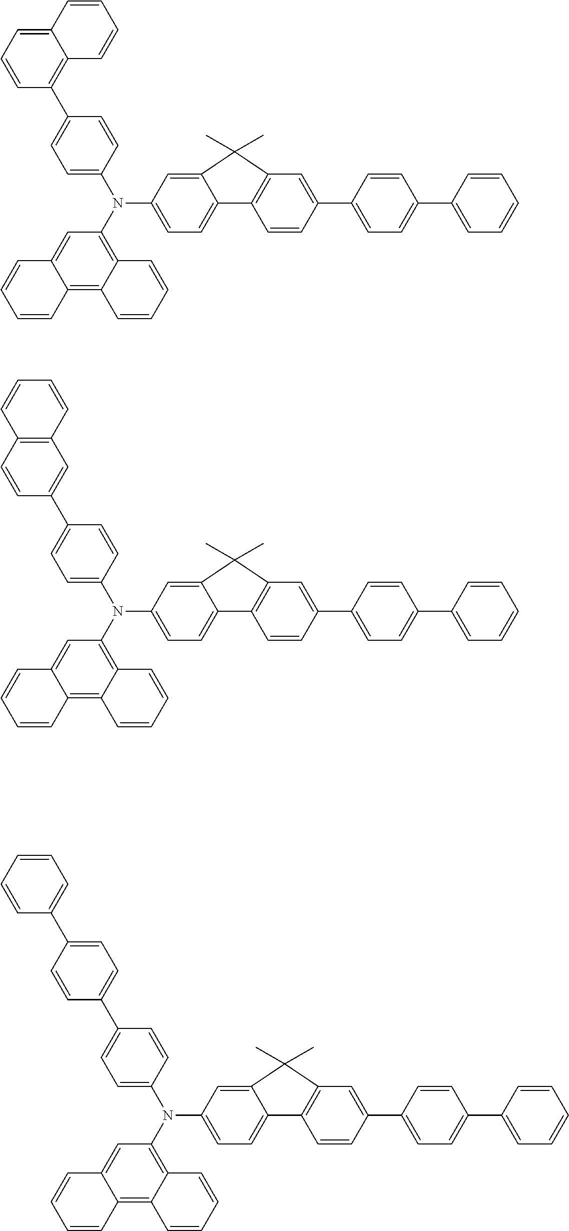 [SMILES: CC1(C)c2cc(-c3ccc(-c4ccccc4)cc3)ccc2-c2ccc(N(c3ccc(-c4cccc5ccccc45)cc3)c3cc4ccccc4c4ccccc34)cc21 ; CC1(C)c2cc(-c3ccc(-c4ccccc4)cc3)ccc2-c2ccc(N(c3ccc(-c4ccc5ccccc5c4)cc3)c3cc4ccccc4c4ccccc34)cc21 ; CC1(C)c2cc(-c3ccc(-c4ccccc4)cc3)ccc2-c2ccc(N(c3ccc(-c4ccc(-c5ccccc5)cc4)cc3)c3cc4ccccc4c4ccccc34)cc21]

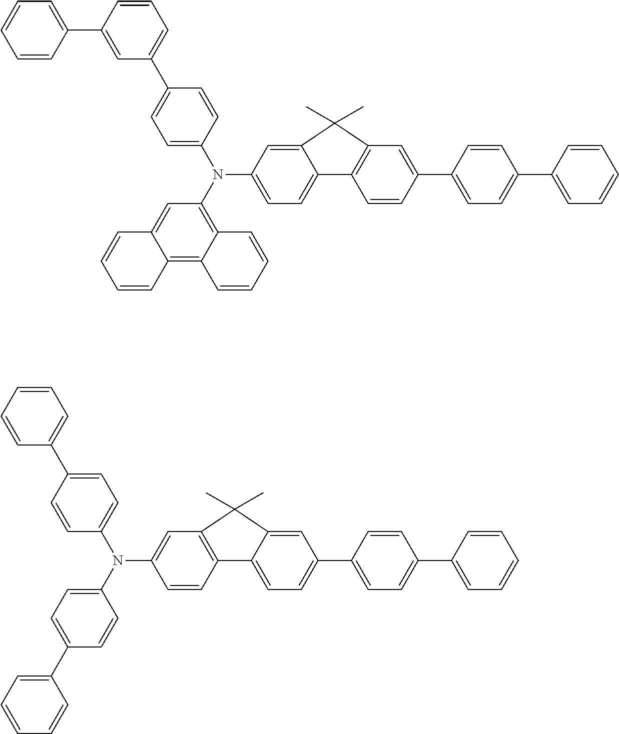 [SMILES: CC1(C)c2cc(-c3ccc(-c4ccccc4)cc3)ccc2-c2ccc(N(c3ccc(-c4cccc(-c5ccccc5)c4)cc3)c3cc4ccccc4c4ccccc34)cc21 ; CC1(C)c2cc(-c3ccc(-c4ccccc4)cc3)ccc2-c2ccc(N(c3ccc(-c4ccccc4)cc3)c3ccc(-c4ccccc4)cc3)cc21]

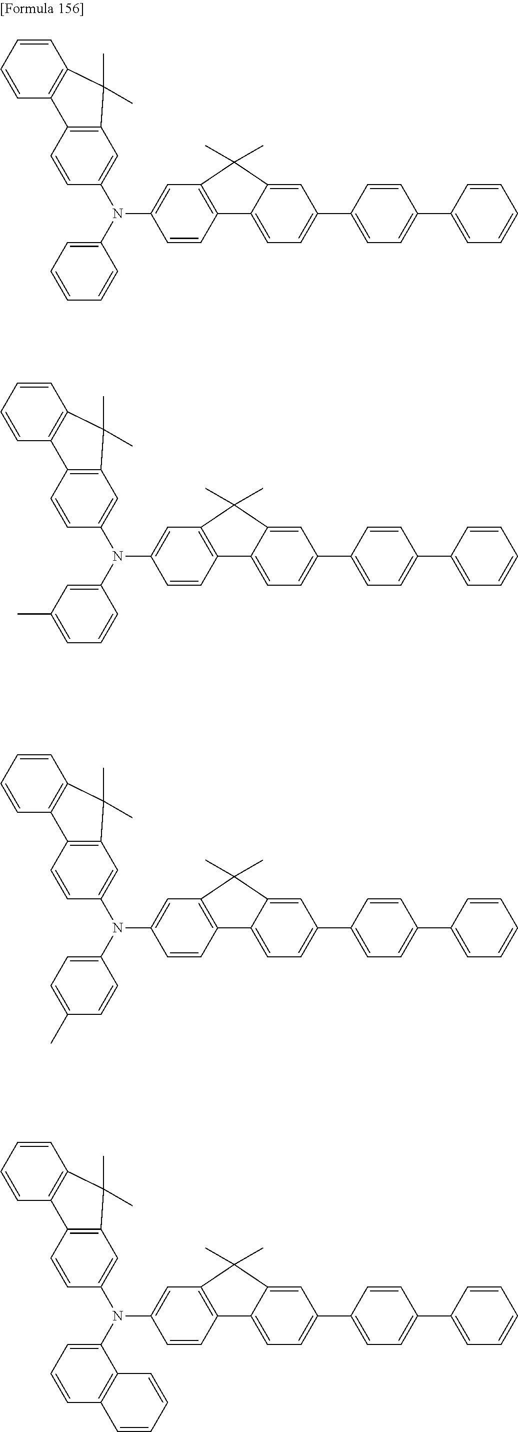 [SMILES: CC1(C)c2ccccc2-c2ccc(N(c3ccccc3)c3ccc4c(c3)C(C)(C)c3cc(-c5ccc(-c6ccccc6)cc5)ccc3-4)cc21 ; Cc1cccc(N(c2ccc3c(c2)C(C)(C)c2ccccc2-3)c2ccc3c(c2)C(C)(C)c2cc(-c4ccc(-c5ccccc5)cc4)ccc2-3)c1 ; Cc1ccc(N(c2ccc3c(c2)C(C)(C)c2ccccc2-3)c2ccc3c(c2)C(C)(C)c2cc(-c4ccc(-c5ccccc5)cc4)ccc2-3)cc1 ; CC1(C)c2ccccc2-c2ccc(N(c3ccc4c(c3)C(C)(C)c3cc(-c5ccc(-c6ccccc6)cc5)ccc3-4)c3cccc4ccccc34)cc21]

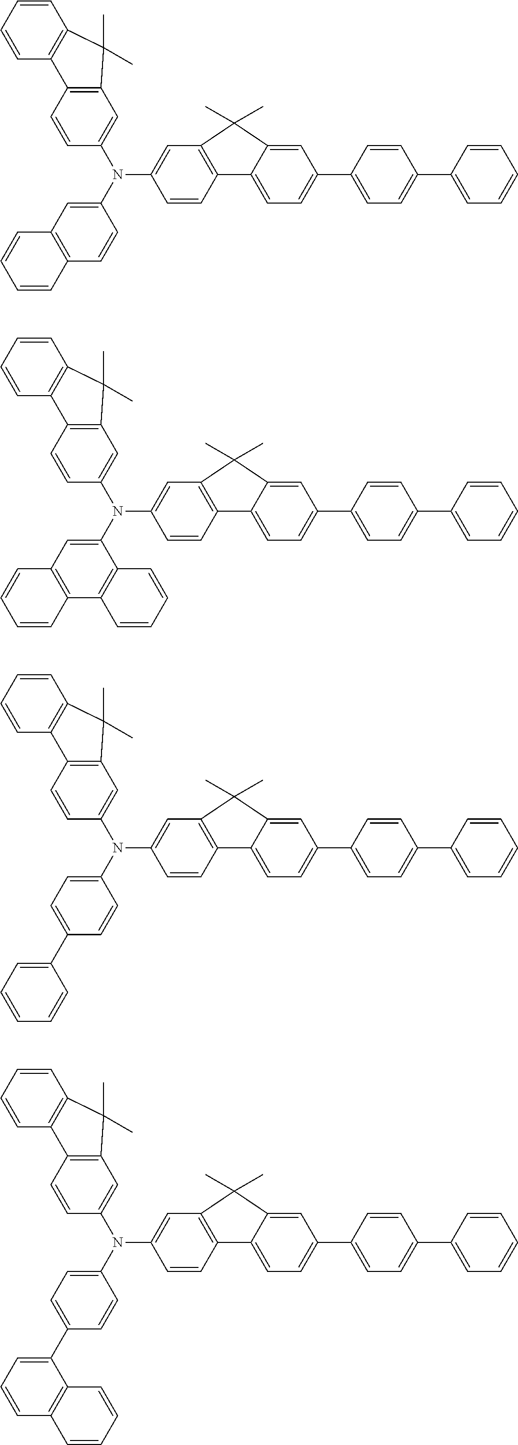 [SMILES: CC1(C)c2ccccc2-c2ccc(N(c3ccc4c(c3)C(C)(C)c3cc(-c5ccc(-c6ccccc6)cc5)ccc3-4)c3ccc4ccccc4c3)cc21 ; CC1(C)c2ccccc2-c2ccc(N(c3ccc4c(c3)C(C)(C)c3cc(-c5ccc(-c6ccccc6)cc5)ccc3-4)c3cc4ccccc4c4ccccc34)cc21 ; CC1(C)c2ccccc2-c2ccc(N(c3ccc(-c4ccccc4)cc3)c3ccc4c(c3)C(C)(C)c3cc(-c5ccc(-c6ccccc6)cc5)ccc3-4)cc21 ; CC1(C)c2ccccc2-c2ccc(N(c3ccc(-c4cccc5ccccc45)cc3)c3ccc4c(c3)C(C)(C)c3cc(-c5ccc(-c6ccccc6)cc5)ccc3-4)cc21]

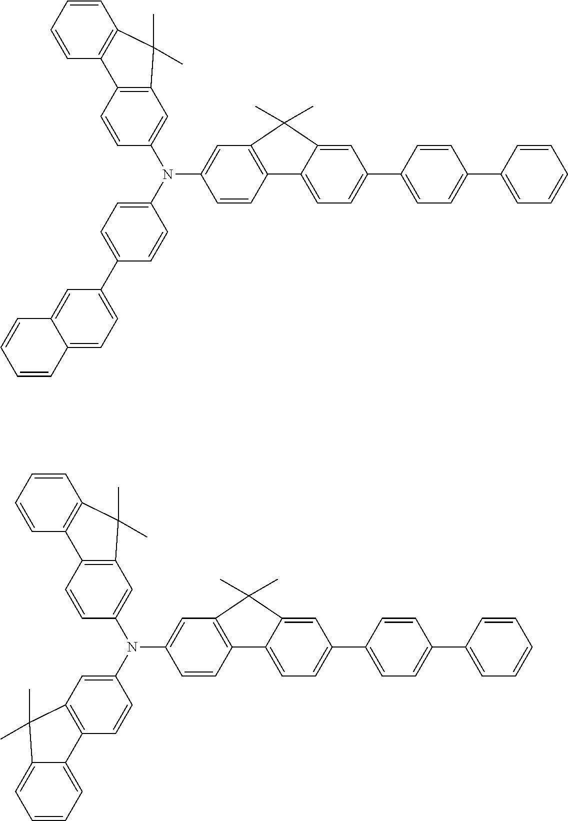 [SMILES: CC1(C)c2ccccc2-c2ccc(N(c3ccc(-c4ccc5ccccc5c4)cc3)c3ccc4c(c3)C(C)(C)c3cc(-c5ccc(-c6ccccc6)cc5)ccc3-4)cc21 ; CC1(C)c2ccccc2-c2ccc(N(c3ccc4c(c3)C(C)(C)c3ccccc3-4)c3ccc4c(c3)C(C)(C)c3cc(-c5ccc(-c6ccccc6)cc5)ccc3-4)cc21]

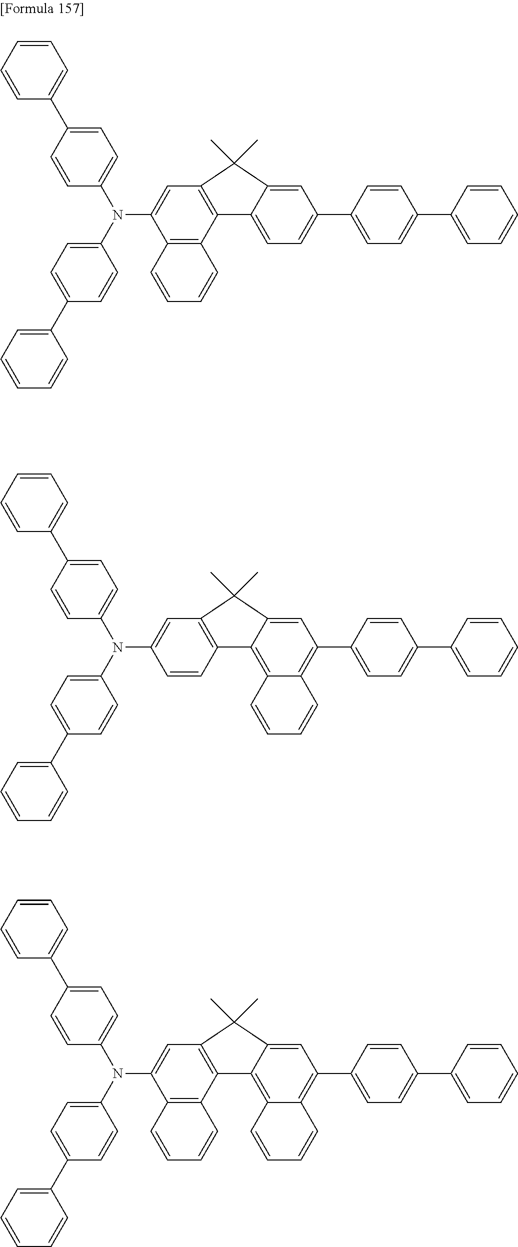 [SMILES: CC1(C)c2cc(-c3ccc(-c4ccccc4)cc3)ccc2-c2c1cc(N(c1ccc(-c3ccccc3)cc1)c1ccc(-c3ccccc3)cc1)c1ccccc21 ; CC1(C)c2cc(N(c3ccc(-c4ccccc4)cc3)c3ccc(-c4ccccc4)cc3)ccc2-c2c1cc(-c1ccc(-c3ccccc3)cc1)c1ccccc21 ; CC1(C)c2cc(-c3ccc(-c4ccccc4)cc3)c3ccccc3c2-c2c1cc(N(c1ccc(-c3ccccc3)cc1)c1ccc(-c3ccccc3)cc1)c1ccccc21]

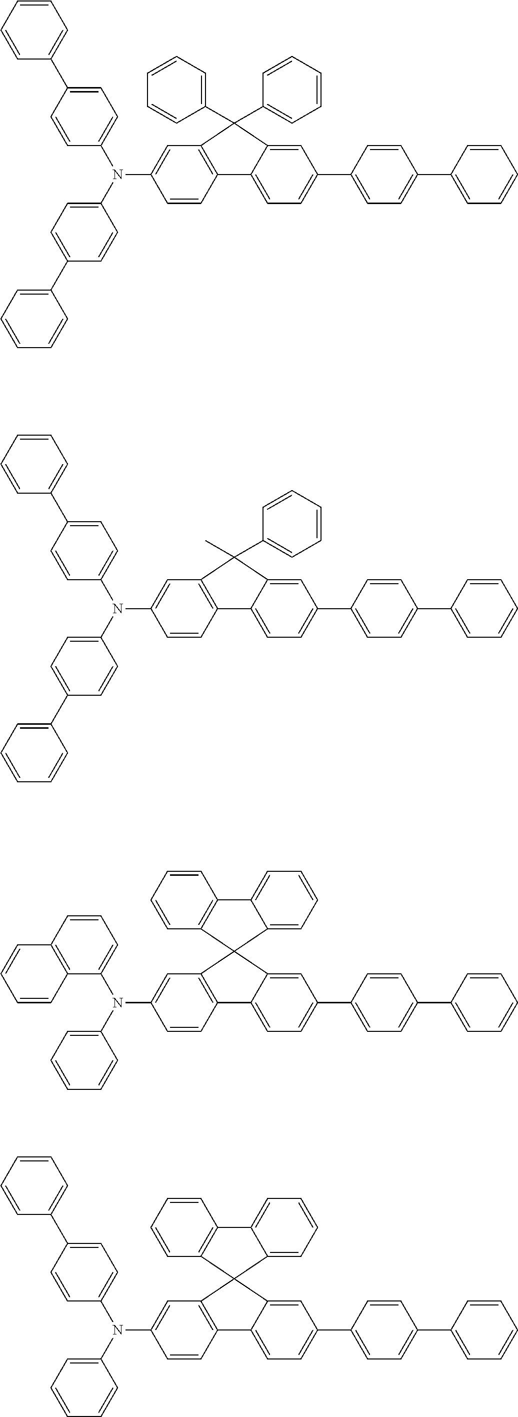 [SMILES: c1ccc(-c2ccc(-c3ccc4c(c3)C(c3ccccc3)(c3ccccc3)c3cc(N(c5ccc(-c6ccccc6)cc5)c5ccc(-c6ccccc6)cc5)ccc3-4)cc2)cc1 ; CC1(c2ccccc2)c2cc(-c3ccc(-c4ccccc4)cc3)ccc2-c2ccc(N(c3ccc(-c4ccccc4)cc3)c3ccc(-c4ccccc4)cc3)cc21 ; c1ccc(-c2ccc(-c3ccc4c(c3)C3(c5ccccc5-c5ccccc53)c3cc(N(c5ccccc5)c5cccc6ccccc56)ccc3-4)cc2)cc1 ; c1ccc(-c2ccc(-c3ccc4c(c3)C3(c5ccccc5-c5ccccc53)c3cc(N(c5ccccc5)c5ccc(-c6ccccc6)cc5)ccc3-4)cc2)cc1]

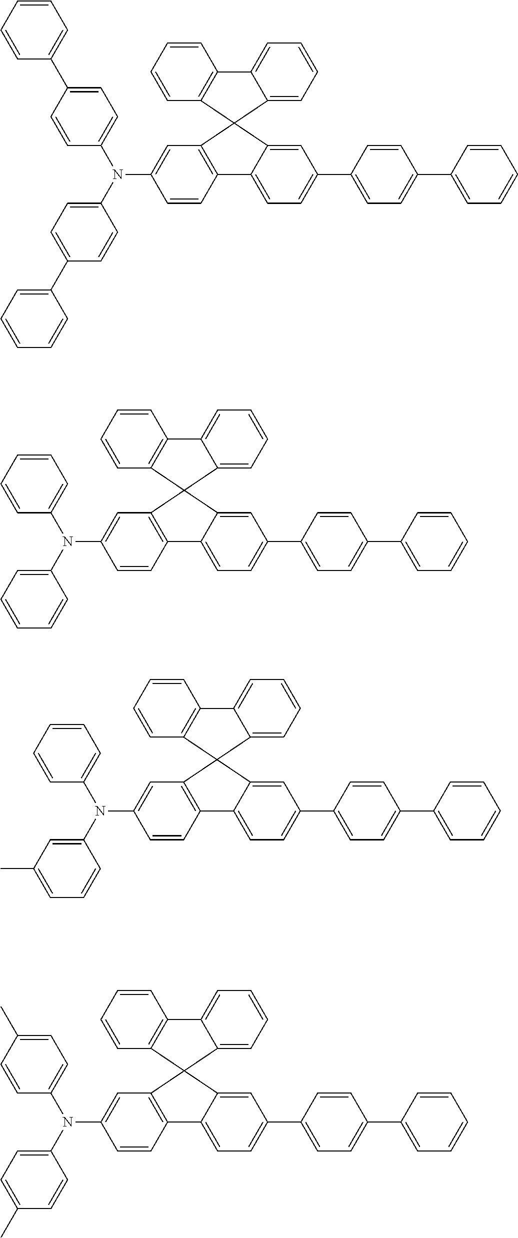 [SMILES: c1ccc(-c2ccc(-c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(-c2ccc(-c3ccc4c(c3)C3(c5ccccc5-c5ccccc53)c3cc(N(c5ccccc5)c5ccccc5)ccc3-4)cc2)cc1 ; Cc1cccc(N(c2ccccc2)c2ccc3c(c2)C2(c4ccccc4-c4ccccc42)c2cc(-c4ccc(-c5ccccc5)cc4)ccc2-3)c1 ; Cc1ccc(N(c2ccc(C)cc2)c2ccc3c(c2)C2(c4ccccc4-c4ccccc42)c2cc(-c4ccc(-c5ccccc5)cc4)ccc2-3)cc1]

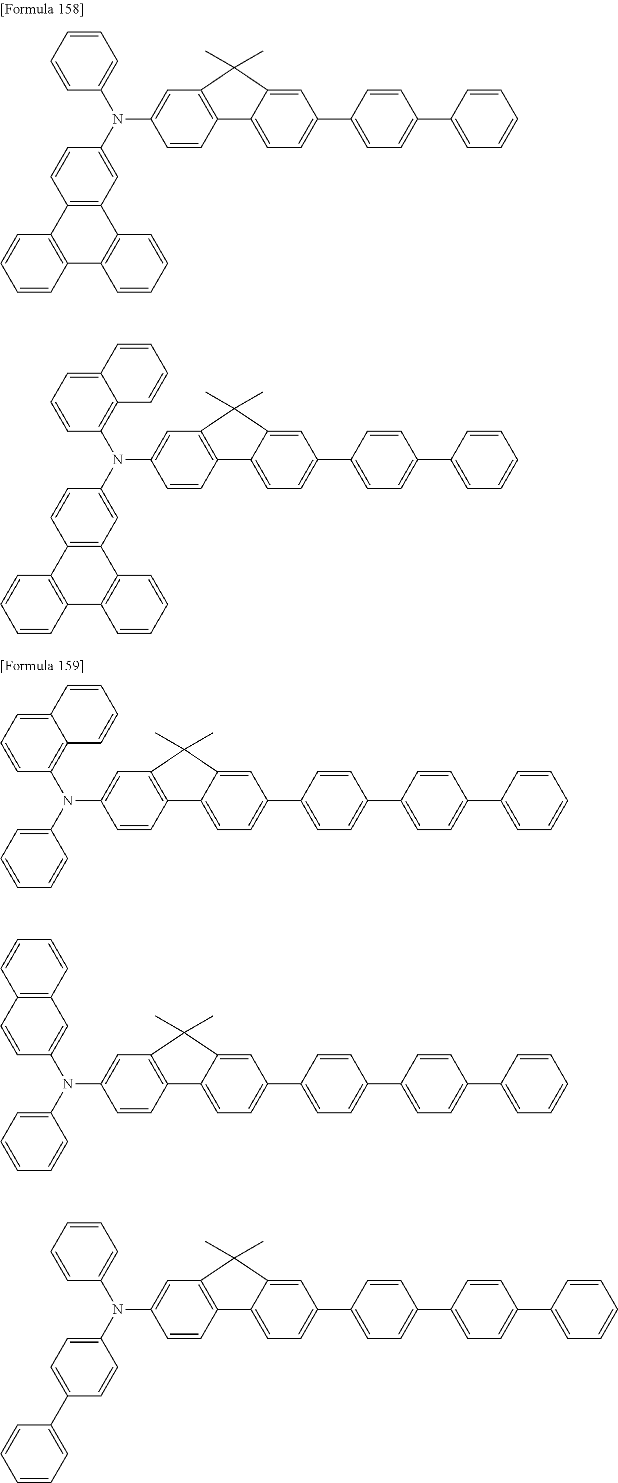 [SMILES: CC1(C)c2cc(-c3ccc(-c4ccccc4)cc3)ccc2-c2ccc(N(c3ccccc3)c3ccc4c5ccccc5c5ccccc5c4c3)cc21 ; CC1(C)c2cc(-c3ccc(-c4ccccc4)cc3)ccc2-c2ccc(N(c3ccc4c5ccccc5c5ccccc5c4c3)c3cccc4ccccc34)cc21 ; CC1(C)c2cc(-c3ccc(-c4ccc(-c5ccccc5)cc4)cc3)ccc2-c2ccc(N(c3ccccc3)c3cccc4ccccc34)cc21 ; CC1(C)c2cc(-c3ccc(-c4ccc(-c5ccccc5)cc4)cc3)ccc2-c2ccc(N(c3ccccc3)c3ccc4ccccc4c3)cc21 ; CC1(C)c2cc(-c3ccc(-c4ccc(-c5ccccc5)cc4)cc3)ccc2-c2ccc(N(c3ccccc3)c3ccc(-c4ccccc4)cc3)cc21]

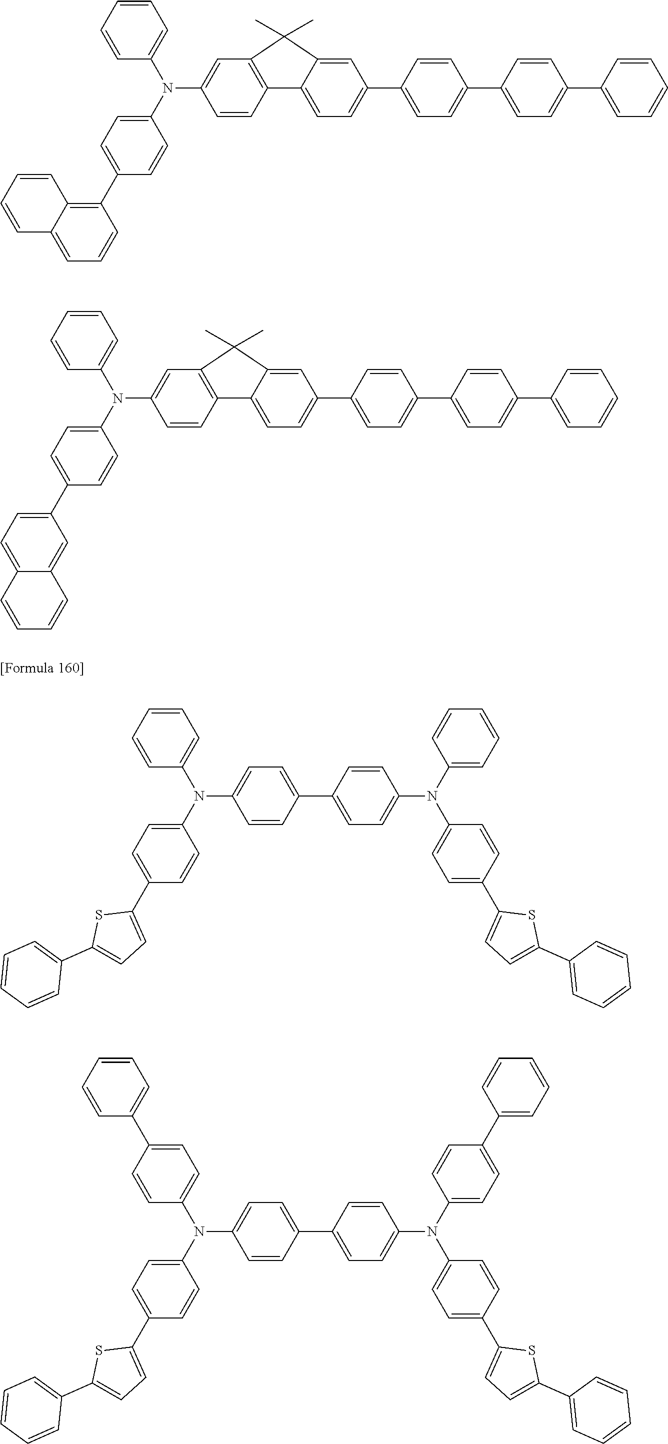 [SMILES: CC1(C)c2cc(-c3ccc(-c4ccc(-c5ccccc5)cc4)cc3)ccc2-c2ccc(N(c3ccccc3)c3ccc(-c4cccc5ccccc45)cc3)cc21 ; CC1(C)c2cc(-c3ccc(-c4ccc(-c5ccccc5)cc4)cc3)ccc2-c2ccc(N(c3ccccc3)c3ccc(-c4ccc5ccccc5c4)cc3)cc21 ; c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1 ; c1ccc(-c2ccc(N(c3ccc(-c4ccc(N(c5ccc(-c6ccccc6)cc5)c5ccc(-c6ccc(-c7ccccc7)s6)cc5)cc4)cc3)c3ccc(-c4ccc(-c5ccccc5)s4)cc3)cc2)cc1]

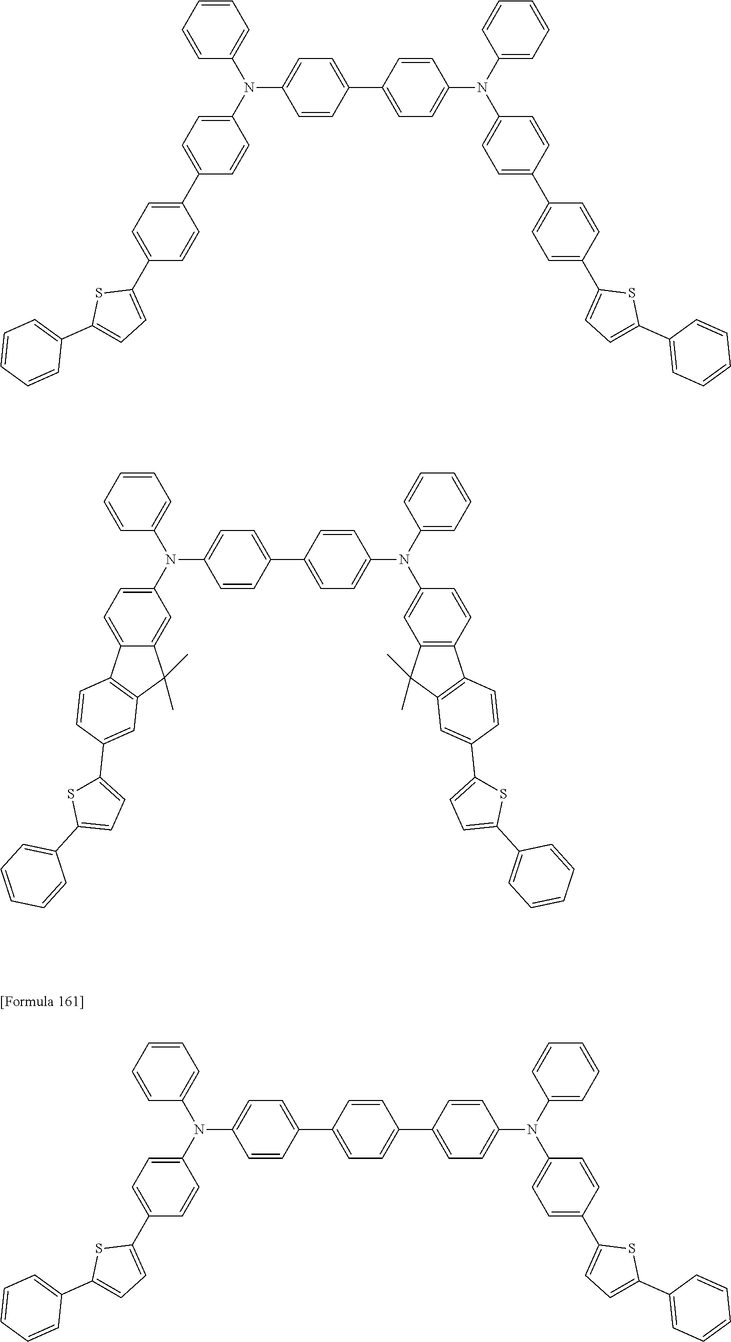 [SMILES: c1ccc(-c2ccc(-c3ccc(-c4ccc(N(c5ccccc5)c5ccc(-c6ccc(N(c7ccccc7)c7ccc(-c8ccc(-c9ccc(-c%10ccccc%10)s9)cc8)cc7)cc6)cc5)cc4)cc3)s2)cc1 ; CC1(C)c2cc(-c3ccc(-c4ccccc4)s3)ccc2-c2ccc(N(c3ccccc3)c3ccc(-c4ccc(N(c5ccccc5)c5ccc6c(c5)C(C)(C)c5cc(-c7ccc(-c8ccccc8)s7)ccc5-6)cc4)cc3)cc21 ; c1ccc(-c2ccc(-c3ccc(N(c4ccccc4)c4ccc(-c5ccc(-c6ccc(N(c7ccccc7)c7ccc(-c8ccc(-c9ccccc9)s8)cc7)cc6)cc5)cc4)cc3)s2)cc1]

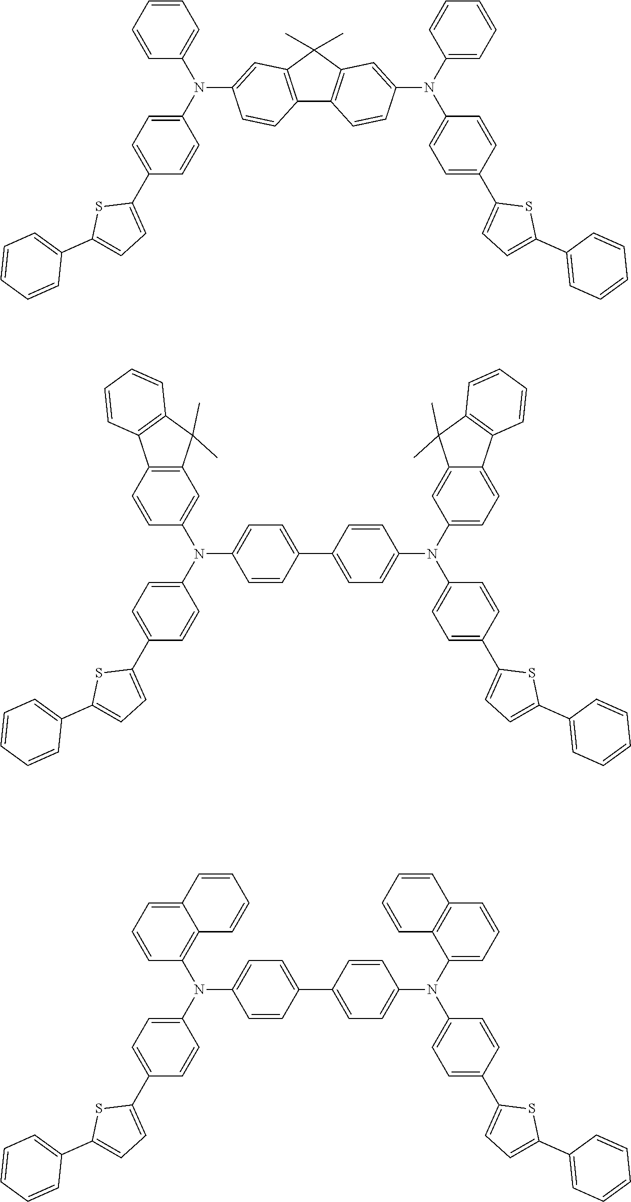 [SMILES: CC1(C)c2cc(N(c3ccccc3)c3ccc(-c4ccc(-c5ccccc5)s4)cc3)ccc2-c2ccc(N(c3ccccc3)c3ccc(-c4ccc(-c5ccccc5)s4)cc3)cc21 ; CC1(C)c2ccccc2-c2ccc(N(c3ccc(-c4ccc(N(c5ccc(-c6ccc(-c7ccccc7)s6)cc5)c5ccc6c(c5)C(C)(C)c5ccccc5-6)cc4)cc3)c3ccc(-c4ccc(-c5ccccc5)s4)cc3)cc21 ; c1ccc(-c2ccc(-c3ccc(N(c4ccc(-c5ccc(N(c6ccc(-c7ccc(-c8ccccc8)s7)cc6)c6cccc7ccccc67)cc5)cc4)c4cccc5ccccc45)cc3)s2)cc1]

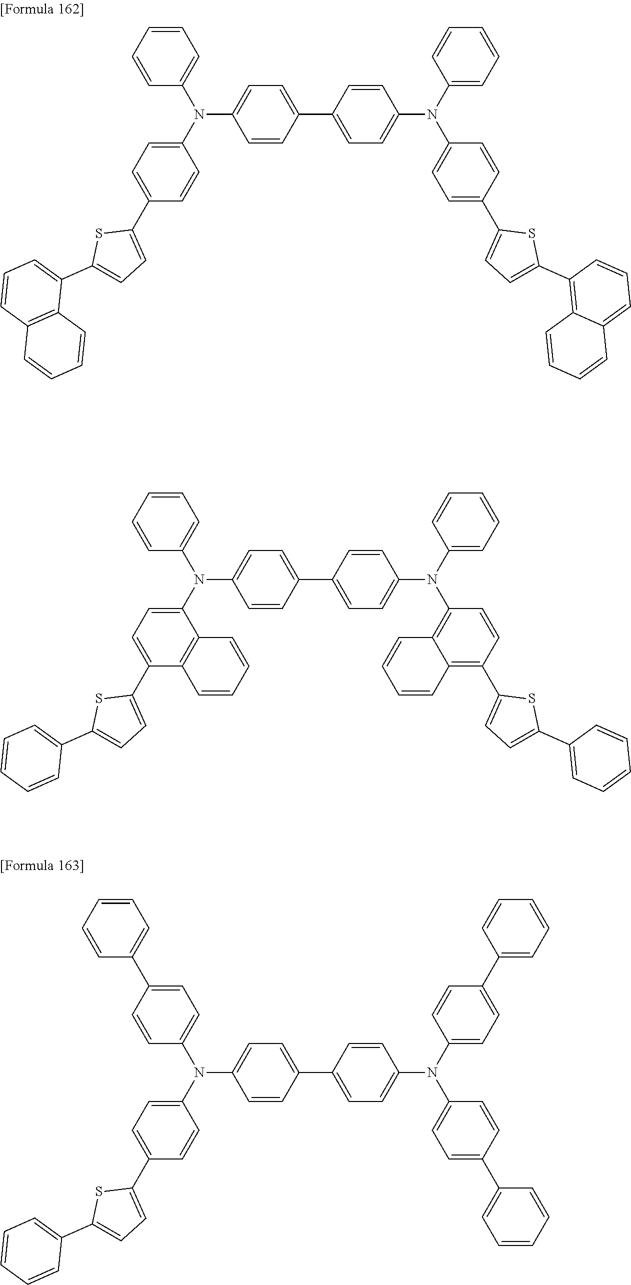 [SMILES: c1ccc(N(c2ccc(-c3ccc(N(c4ccccc4)c4ccc(-c5ccc(-c6cccc7ccccc67)s5)cc4)cc3)cc2)c2ccc(-c3ccc(-c4cccc5ccccc45)s3)cc2)cc1 ; c1ccc(-c2ccc(-c3ccc(N(c4ccccc4)c4ccc(-c5ccc(N(c6ccccc6)c6ccc(-c7ccc(-c8ccccc8)s7)c7ccccc67)cc5)cc4)c4ccccc34)s2)cc1 ; c1ccc(-c2ccc(N(c3ccc(-c4ccccc4)cc3)c3ccc(-c4ccc(N(c5ccc(-c6ccccc6)cc5)c5ccc(-c6ccc(-c7ccccc7)s6)cc5)cc4)cc3)cc2)cc1]

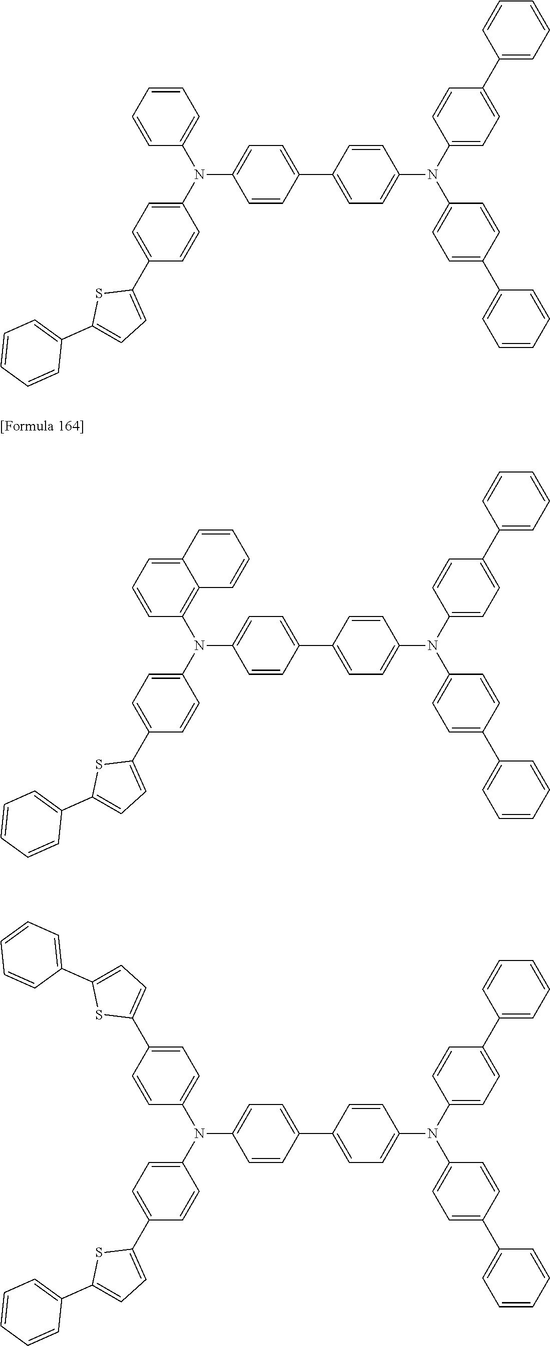 [SMILES: c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1 ; c1ccc(-c2ccc(N(c3ccc(-c4ccccc4)cc3)c3ccc(-c4ccc(N(c5ccc(-c6ccc(-c7ccccc7)s6)cc5)c5cccc6ccccc56)cc4)cc3)cc2)cc1 ; c1ccc(-c2ccc(N(c3ccc(-c4ccccc4)cc3)c3ccc(-c4ccc(N(c5ccc(-c6ccc(-c7ccccc7)s6)cc5)c5ccc(-c6ccc(-c7ccccc7)s6)cc5)cc4)cc3)cc2)cc1]

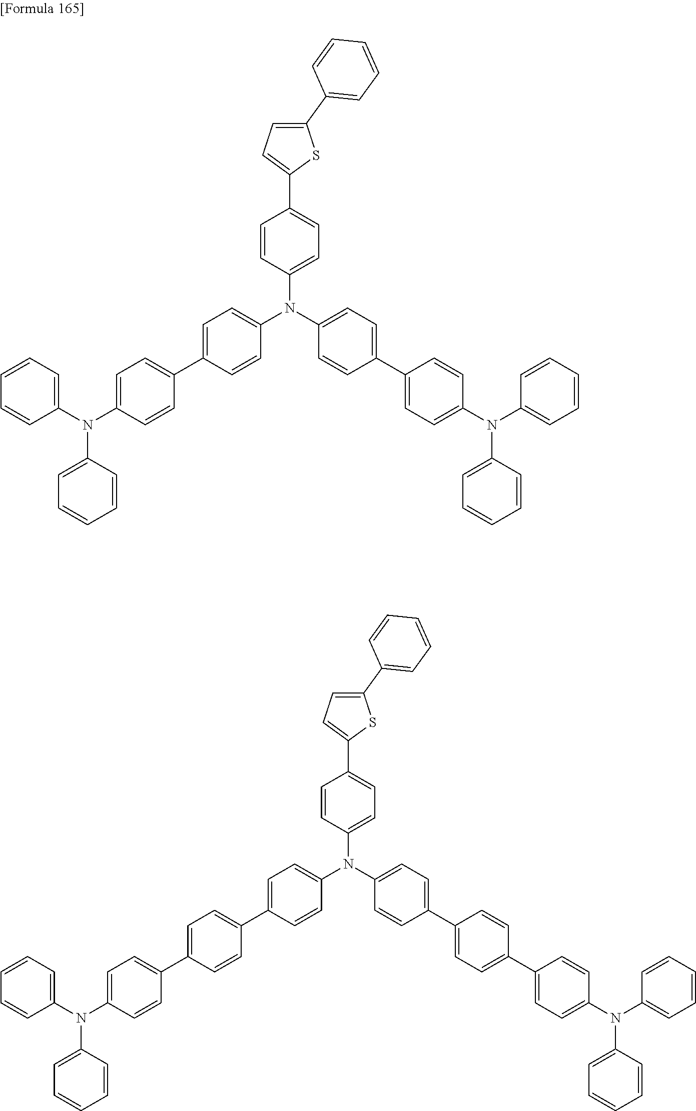 [SMILES: c1ccc(-c2ccc(-c3ccc(N(c4ccc(-c5ccc(N(c6ccccc6)c6ccccc6)cc5)cc4)c4ccc(-c5ccc(N(c6ccccc6)c6ccccc6)cc5)cc4)cc3)s2)cc1 ; c1ccc(-c2ccc(-c3ccc(N(c4ccc(-c5ccc(-c6ccc(N(c7ccccc7)c7ccccc7)cc6)cc5)cc4)c4ccc(-c5ccc(-c6ccc(N(c7ccccc7)c7ccccc7)cc6)cc5)cc4)cc3)s2)cc1]

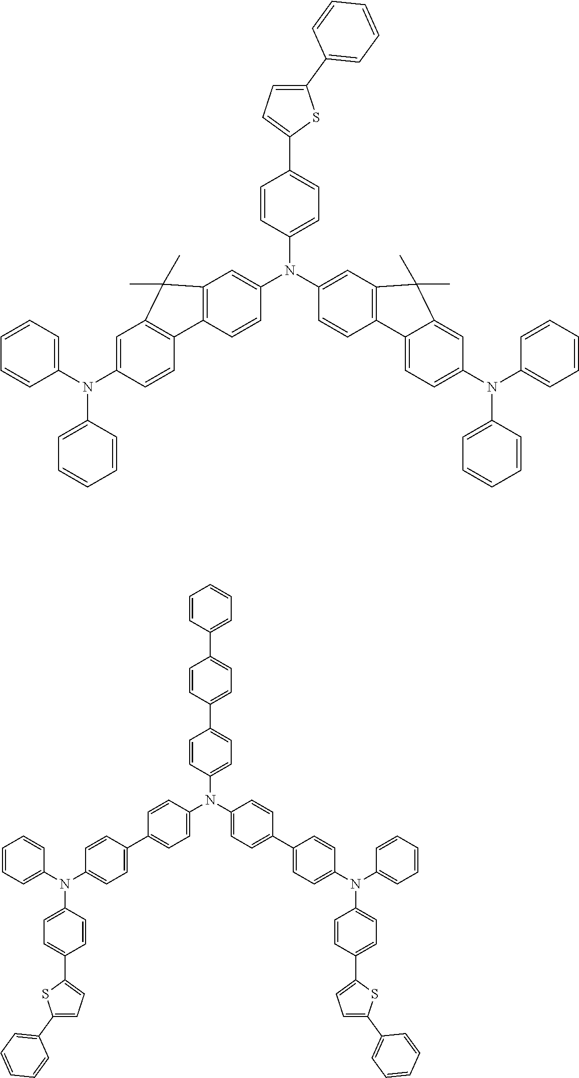 [SMILES: CC1(C)c2cc(N(c3ccccc3)c3ccccc3)ccc2-c2ccc(N(c3ccc(-c4ccc(-c5ccccc5)s4)cc3)c3ccc4c(c3)C(C)(C)c3cc(N(c5ccccc5)c5ccccc5)ccc3-4)cc21 ; c1ccc(-c2ccc(-c3ccc(N(c4ccc(-c5ccc(N(c6ccccc6)c6ccc(-c7ccc(-c8ccccc8)s7)cc6)cc5)cc4)c4ccc(-c5ccc(N(c6ccccc6)c6ccc(-c7ccc(-c8ccccc8)s7)cc6)cc5)cc4)cc3)cc2)cc1]

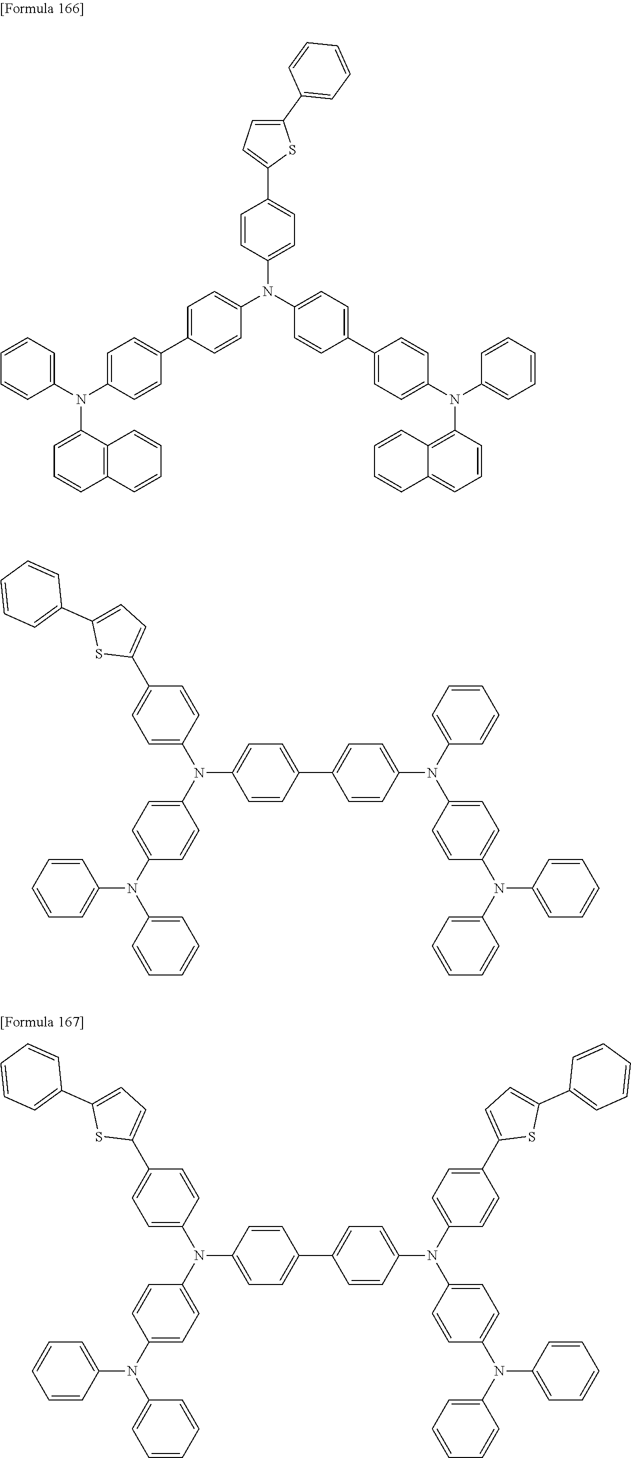 [SMILES: c1ccc(-c2ccc(-c3ccc(N(c4ccc(-c5ccc(N(c6ccccc6)c6cccc7ccccc67)cc5)cc4)c4ccc(-c5ccc(N(c6ccccc6)c6cccc7ccccc67)cc5)cc4)cc3)s2)cc1 ; c1ccc(-c2ccc(-c3ccc(N(c4ccc(-c5ccc(N(c6ccccc6)c6ccc(N(c7ccccc7)c7ccccc7)cc6)cc5)cc4)c4ccc(N(c5ccccc5)c5ccccc5)cc4)cc3)s2)cc1 ; c1ccc(-c2ccc(-c3ccc(N(c4ccc(-c5ccc(N(c6ccc(-c7ccc(-c8ccccc8)s7)cc6)c6ccc(N(c7ccccc7)c7ccccc7)cc6)cc5)cc4)c4ccc(N(c5ccccc5)c5ccccc5)cc4)cc3)s2)cc1]

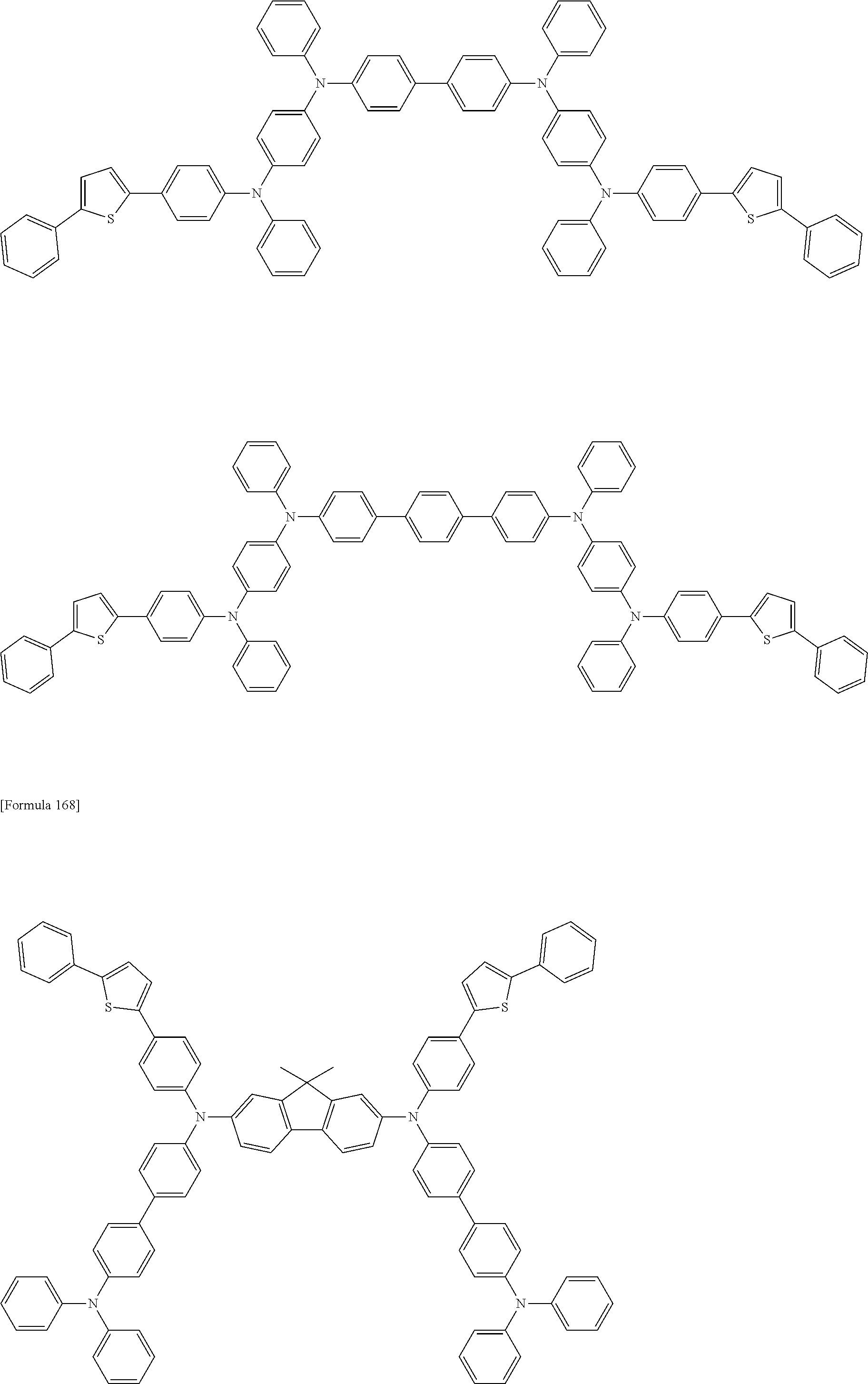 [SMILES: c1ccc(-c2ccc(-c3ccc(N(c4ccccc4)c4ccc(N(c5ccccc5)c5ccc(-c6ccc(N(c7ccccc7)c7ccc(N(c8ccccc8)c8ccc(-c9ccc(-c%10ccccc%10)s9)cc8)cc7)cc6)cc5)cc4)cc3)s2)cc1 ; c1ccc(-c2ccc(-c3ccc(N(c4ccccc4)c4ccc(N(c5ccccc5)c5ccc(-c6ccc(-c7ccc(N(c8ccccc8)c8ccc(N(c9ccccc9)c9ccc(-c%10ccc(-c%11ccccc%11)s%10)cc9)cc8)cc7)cc6)cc5)cc4)cc3)s2)cc1 ; CC1(C)c2cc(N(c3ccc(-c4ccc(N(c5ccccc5)c5ccccc5)cc4)cc3)c3ccc(-c4ccc(-c5ccccc5)s4)cc3)ccc2-c2ccc(N(c3ccc(-c4ccc(N(c5ccccc5)c5ccccc5)cc4)cc3)c3ccc(-c4ccc(-c5ccccc5)s4)cc3)cc21]

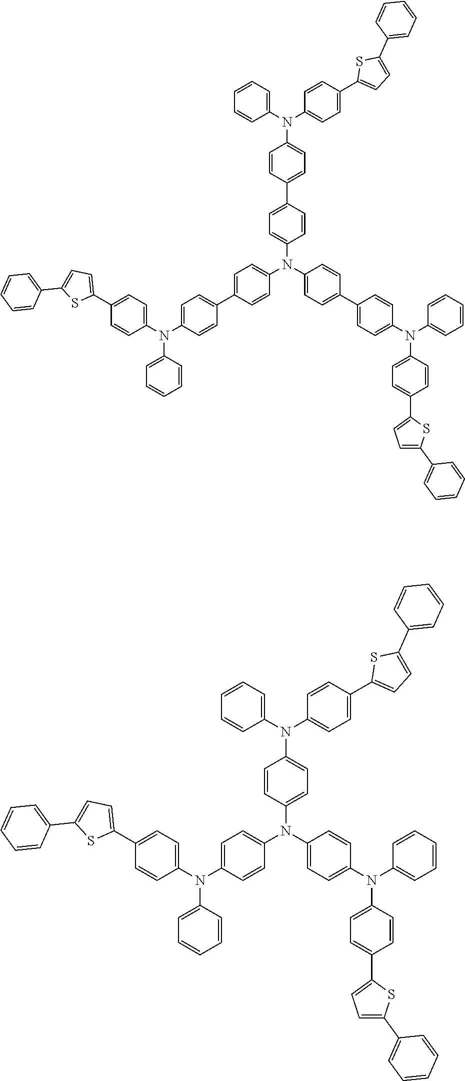 [SMILES: c1ccc(-c2ccc(-c3ccc(N(c4ccccc4)c4ccc(-c5ccc(N(c6ccc(-c7ccc(N(c8ccccc8)c8ccc(-c9ccc(-c%10ccccc%10)s9)cc8)cc7)cc6)c6ccc(-c7ccc(N(c8ccccc8)c8ccc(-c9ccc(-c%10ccccc%10)s9)cc8)cc7)cc6)cc5)cc4)cc3)s2)cc1 ; c1ccc(-c2ccc(-c3ccc(N(c4ccccc4)c4ccc(N(c5ccc(N(c6ccccc6)c6ccc(-c7ccc(-c8ccccc8)s7)cc6)cc5)c5ccc(N(c6ccccc6)c6ccc(-c7ccc(-c8ccccc8)s7)cc6)cc5)cc4)cc3)s2)cc1]

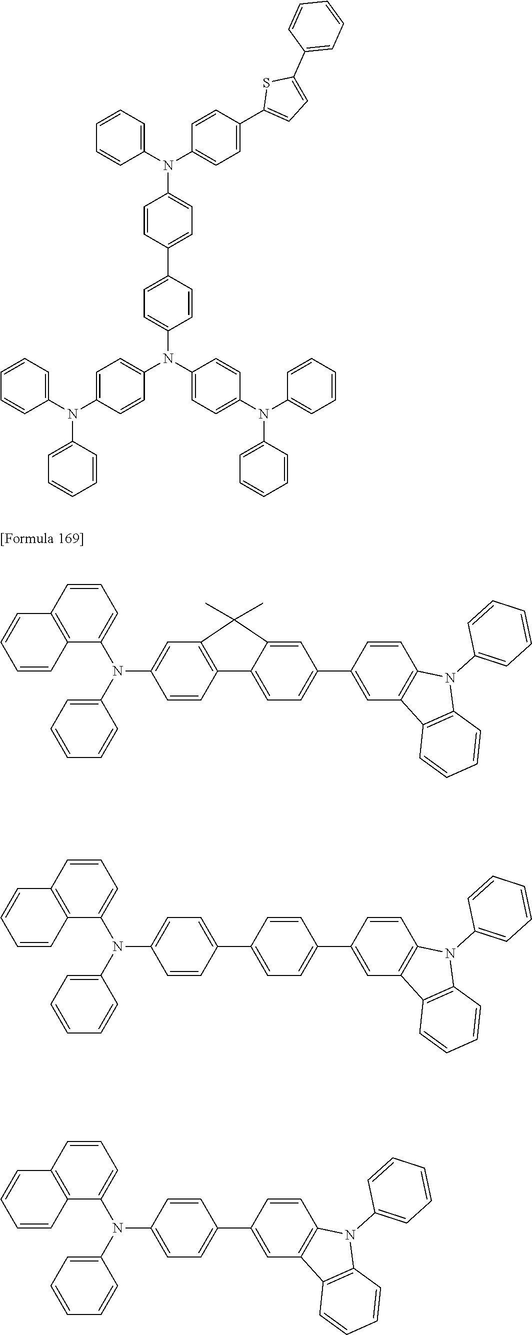 [SMILES: c1ccc(-c2ccc(-c3ccc(N(c4ccccc4)c4ccc(-c5ccc(N(c6ccc(N(c7ccccc7)c7ccccc7)cc6)c6ccc(N(c7ccccc7)c7ccccc7)cc6)cc5)cc4)cc3)s2)cc1 ; CC1(C)c2cc(-c3ccc4c(c3)c3ccccc3n4-c3ccccc3)ccc2-c2ccc(N(c3ccccc3)c3cccc4ccccc34)cc21 ; c1ccc(N(c2ccc(-c3ccc(-c4ccc5c(c4)c4ccccc4n5-c4ccccc4)cc3)cc2)c2cccc3ccccc23)cc1 ; c1ccc(N(c2ccc(-c3ccc4c(c3)c3ccccc3n4-c3ccccc3)cc2)c2cccc3ccccc23)cc1]

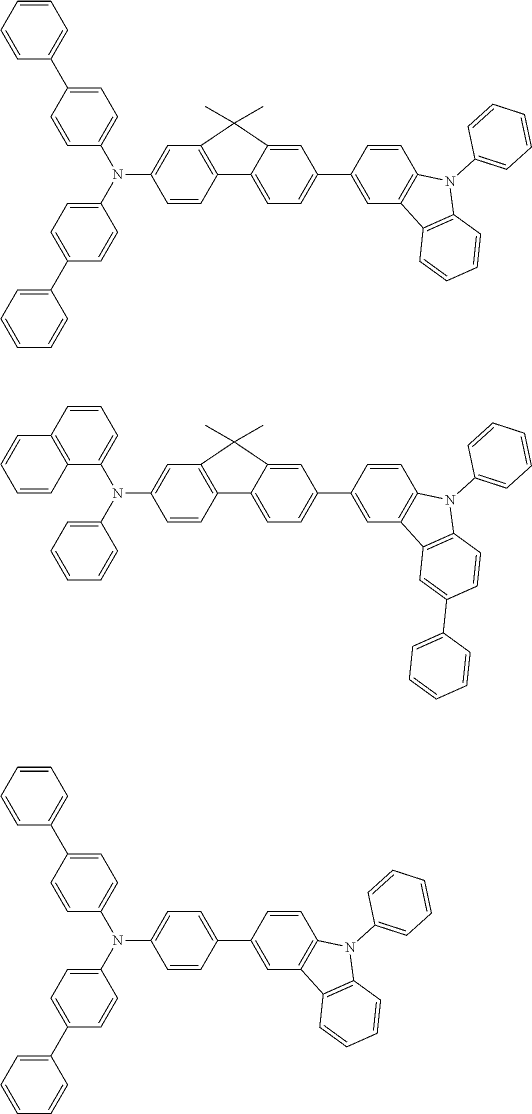 [SMILES: CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21 ; CC1(C)c2cc(-c3ccc4c(c3)c3cc(-c5ccccc5)ccc3n4-c3ccccc3)ccc2-c2ccc(N(c3ccccc3)c3cccc4ccccc34)cc21 ; c1ccc(-c2ccc(N(c3ccc(-c4ccccc4)cc3)c3ccc(-c4ccc5c(c4)c4ccccc4n5-c4ccccc4)cc3)cc2)cc1]

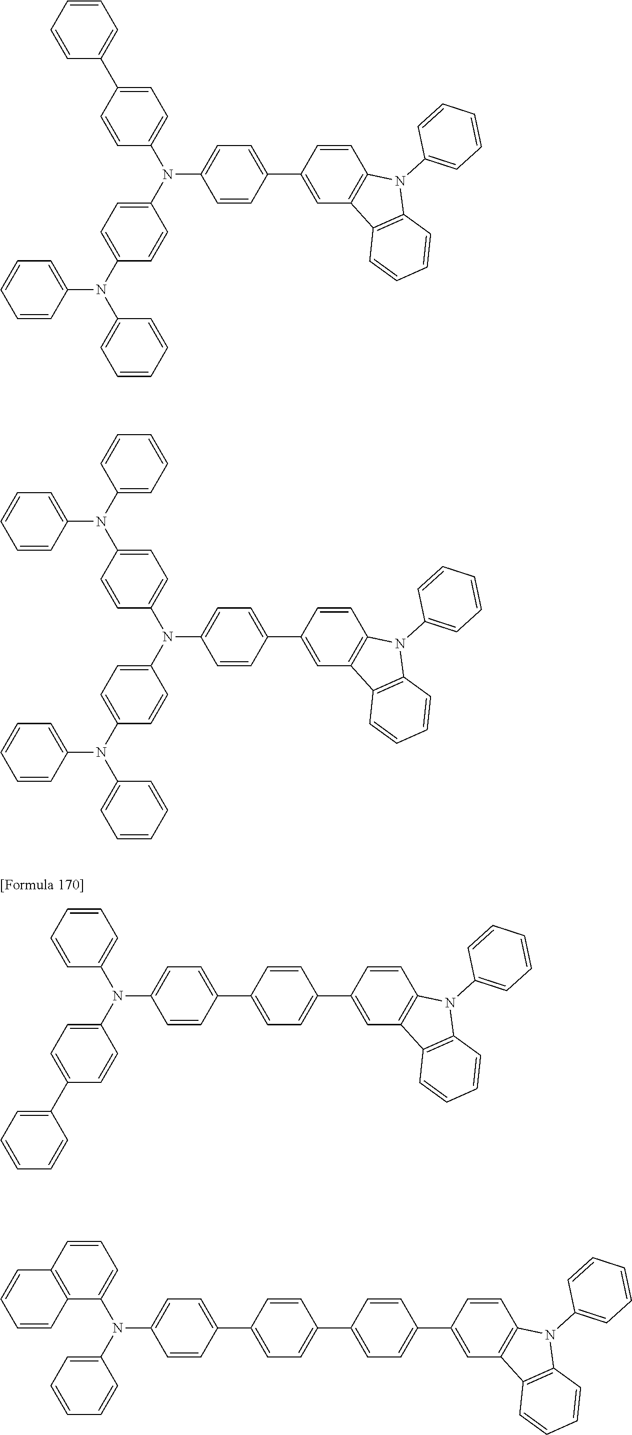 [SMILES: c1ccc(-c2ccc(N(c3ccc(-c4ccc5c(c4)c4ccccc4n5-c4ccccc4)cc3)c3ccc(N(c4ccccc4)c4ccccc4)cc3)cc2)cc1 ; c1ccc(N(c2ccccc2)c2ccc(N(c3ccc(-c4ccc5c(c4)c4ccccc4n5-c4ccccc4)cc3)c3ccc(N(c4ccccc4)c4ccccc4)cc3)cc2)cc1 ; c1ccc(-c2ccc(N(c3ccccc3)c3ccc(-c4ccc(-c5ccc6c(c5)c5ccccc5n6-c5ccccc5)cc4)cc3)cc2)cc1 ; c1ccc(N(c2ccc(-c3ccc(-c4ccc(-c5ccc6c(c5)c5ccccc5n6-c5ccccc5)cc4)cc3)cc2)c2cccc3ccccc23)cc1]

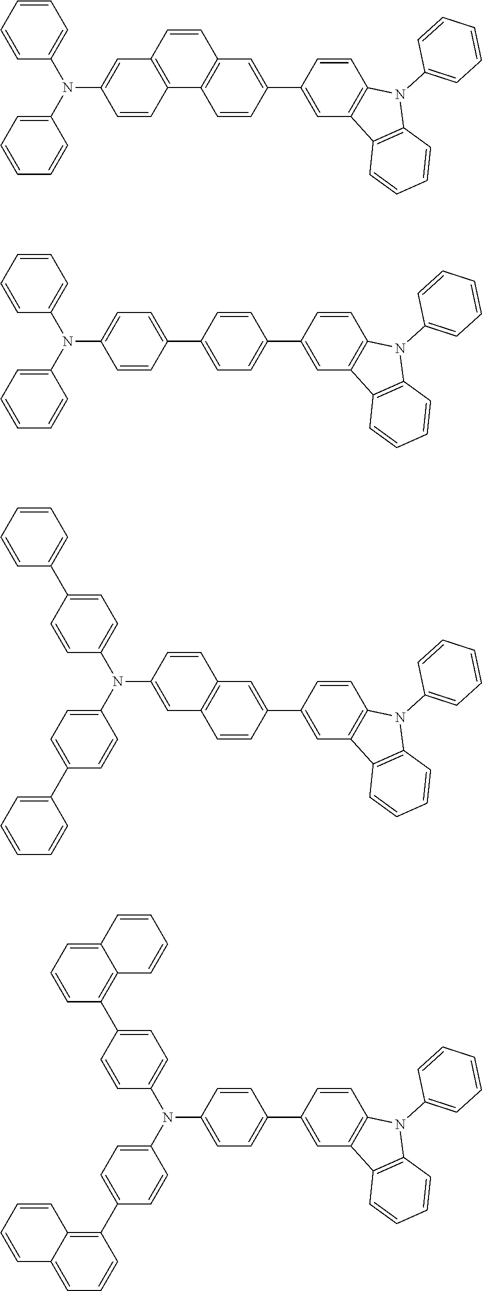 [SMILES: c1ccc(N(c2ccccc2)c2ccc3c(ccc4cc(-c5ccc6c(c5)c5ccccc5n6-c5ccccc5)ccc43)c2)cc1 ; c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4cc(-c5ccc6c(c5)c5ccccc5n6-c5ccccc5)ccc4c3)cc2)cc1 ; c1ccc(-n2c3ccccc3c3cc(-c4ccc(N(c5ccc(-c6cccc7ccccc67)cc5)c5ccc(-c6cccc7ccccc67)cc5)cc4)ccc32)cc1]

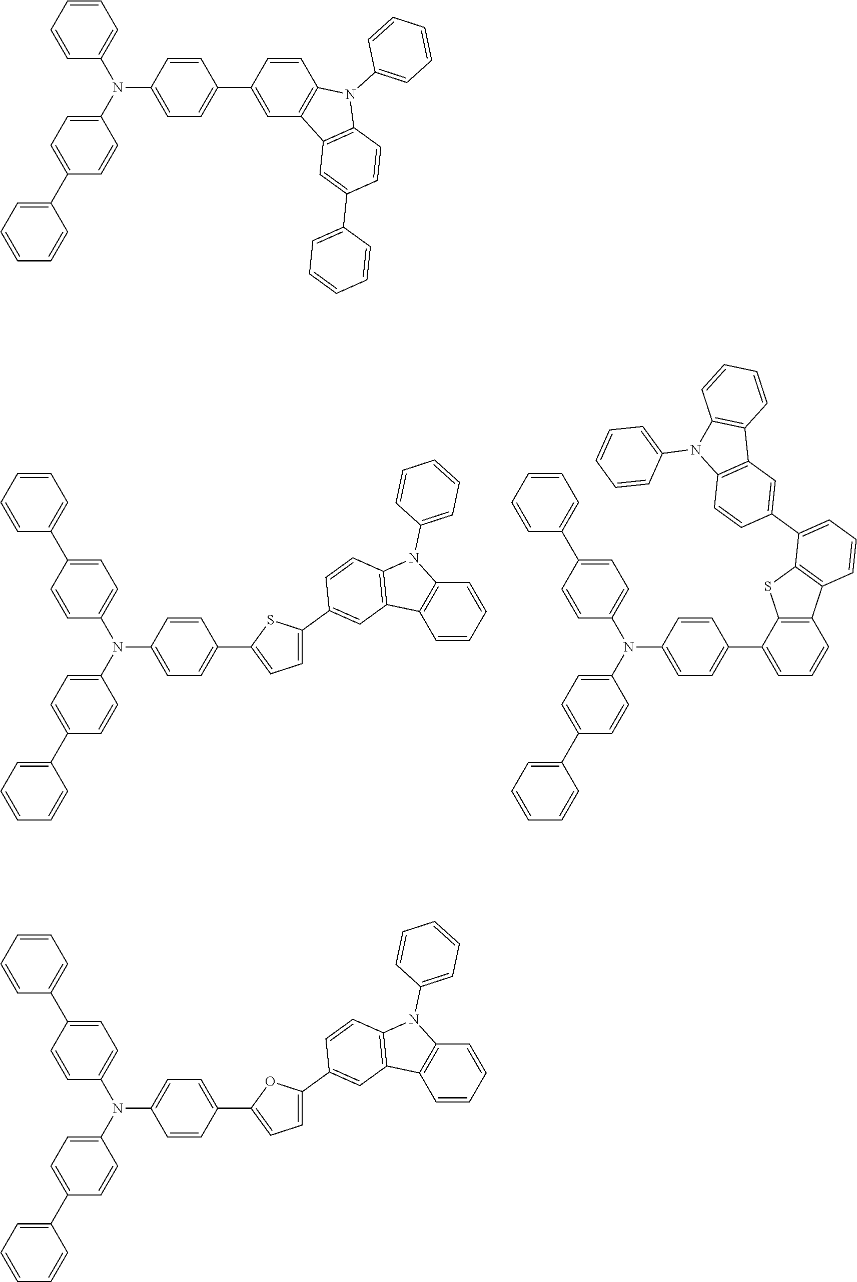 [SMILES: c1ccc(-c2ccc(N(c3ccccc3)c3ccc(-c4ccc5c(c4)c4cc(-c6ccccc6)ccc4n5-c4ccccc4)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)s4)cc3)cc2)cc1 ; c1ccc(-c2ccc(N(c3ccc(-c4ccccc4)cc3)c3ccc(-c4cccc5c4sc4c(-c6ccc7c(c6)c6ccccc6n7-c6ccccc6)cccc45)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)o4)cc3)cc2)cc1]

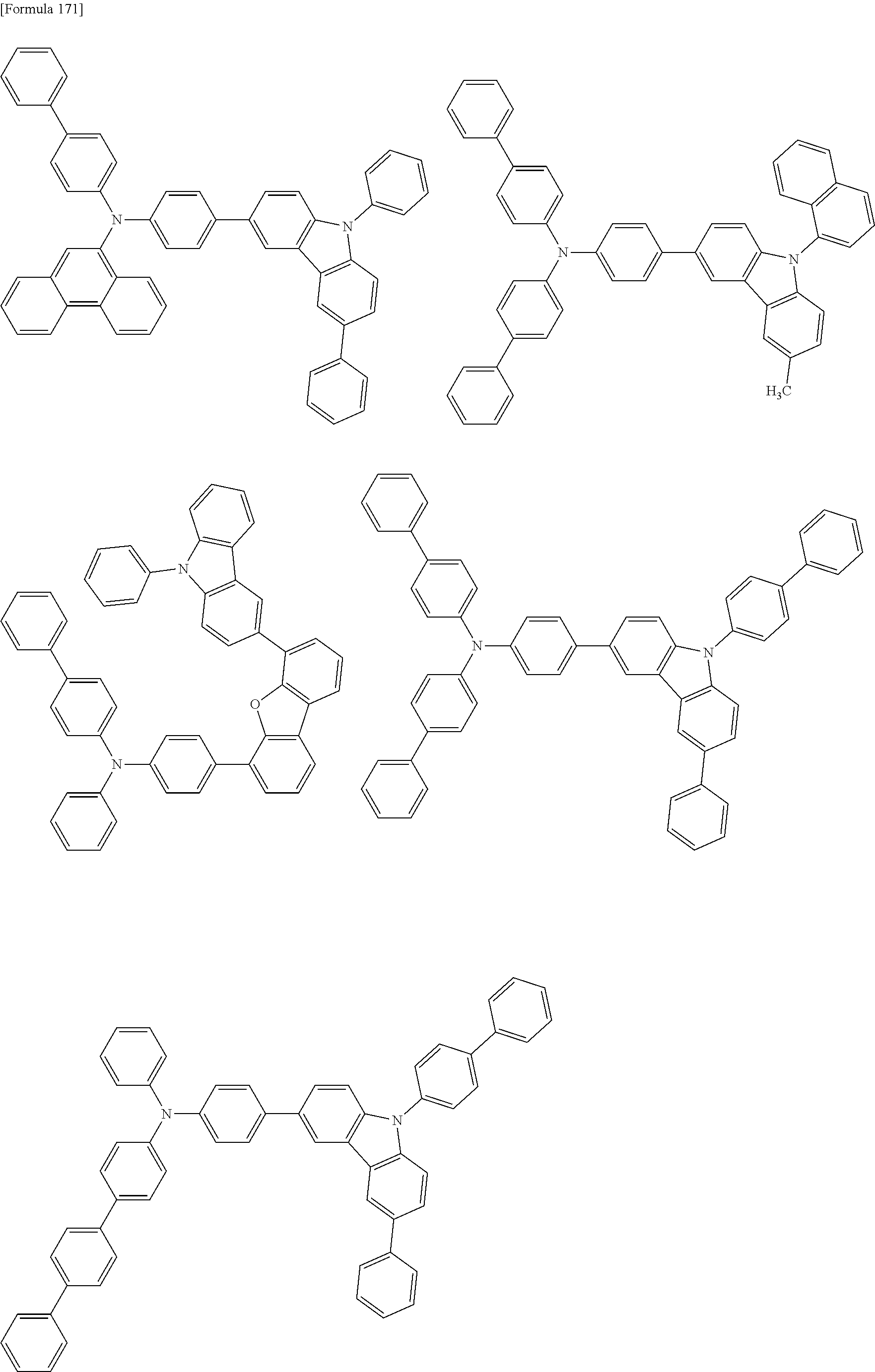

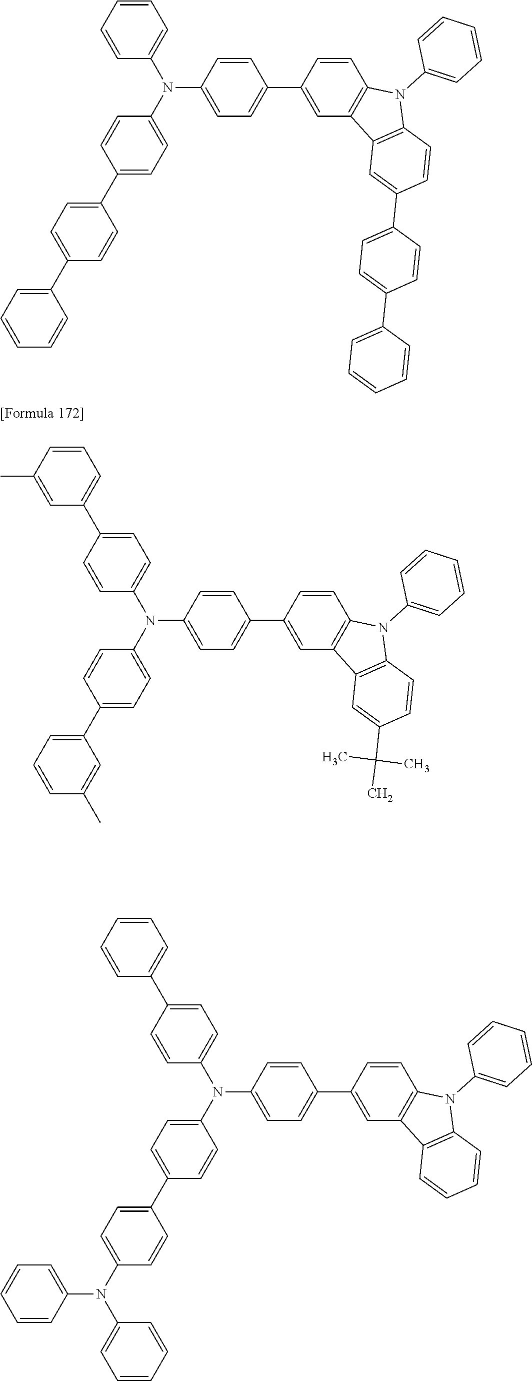 [SMILES: c1ccc(-c2ccc(-c3ccc(N(c4ccccc4)c4ccc(-c5ccc6c(c5)c5cc(-c7ccc(-c8ccccc8)cc7)ccc5n6-c5ccccc5)cc4)cc3)cc2)cc1 ; Cc1cccc(-c2ccc(N(c3ccc(-c4cccc(C)c4)cc3)c3ccc(-c4ccc5c(c4)c4cc(C(C)(C)C)ccc4n5-c4ccccc4)cc3)cc2)c1 ; c1ccc(-c2ccc(N(c3ccc(-c4ccc(N(c5ccccc5)c5ccccc5)cc4)cc3)c3ccc(-c4ccc5c(c4)c4ccccc4n5-c4ccccc4)cc3)cc2)cc1]

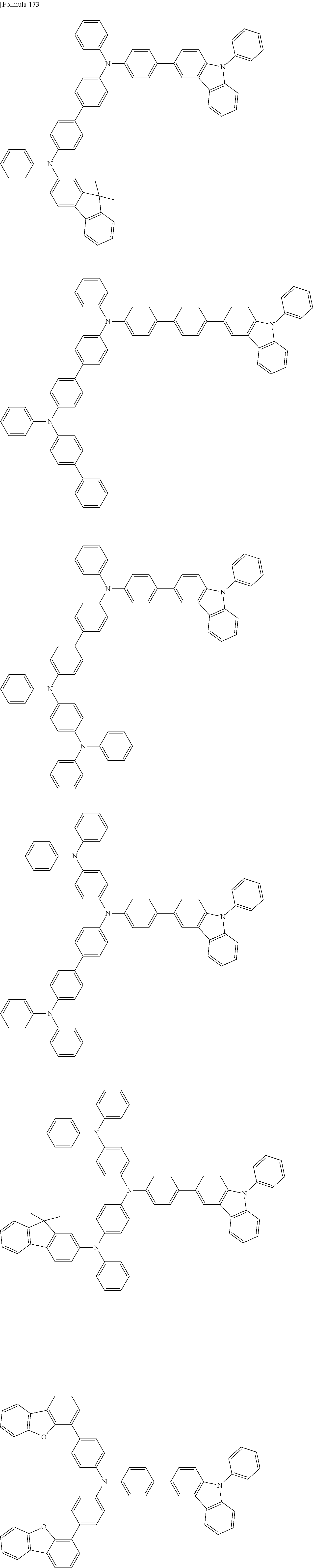

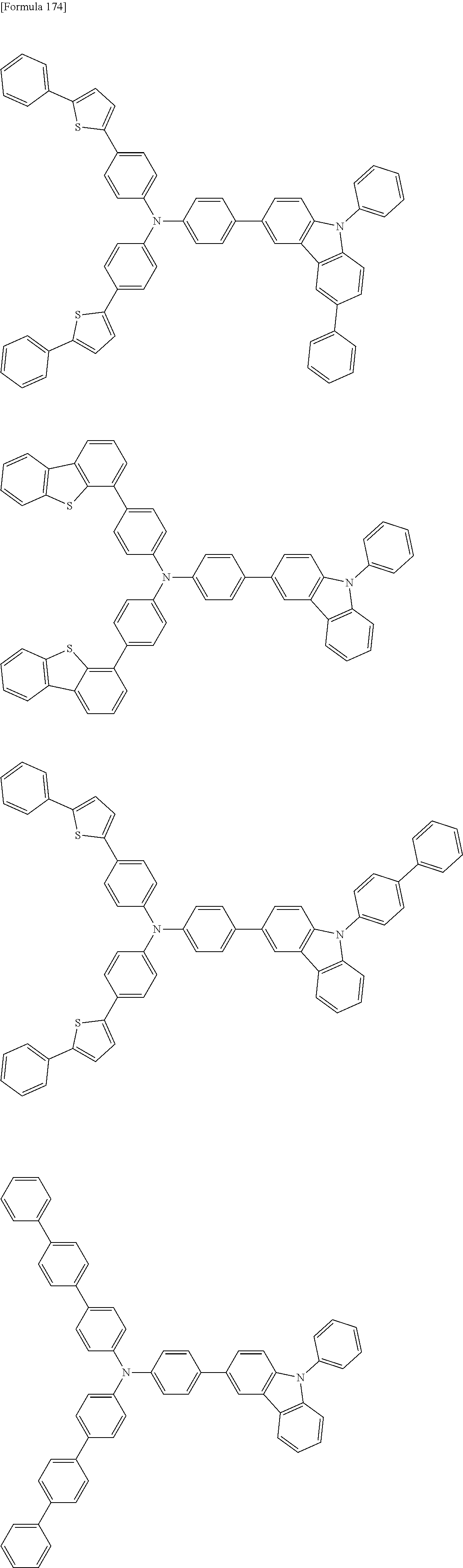 [SMILES: c1ccc(-c2ccc3c(c2)c2cc(-c4ccc(N(c5ccc(-c6ccc(-c7ccccc7)s6)cc5)c5ccc(-c6ccc(-c7ccccc7)s6)cc5)cc4)ccc2n3-c2ccccc2)cc1 ; c1ccc(-n2c3ccccc3c3cc(-c4ccc(N(c5ccc(-c6cccc7c6sc6ccccc67)cc5)c5ccc(-c6cccc7c6sc6ccccc67)cc5)cc4)ccc32)cc1 ; c1ccc(-c2ccc(-n3c4ccccc4c4cc(-c5ccc(N(c6ccc(-c7ccc(-c8ccccc8)s7)cc6)c6ccc(-c7ccc(-c8ccccc8)s7)cc6)cc5)ccc43)cc2)cc1 ; c1ccc(-c2ccc(-c3ccc(N(c4ccc(-c5ccc(-c6ccccc6)cc5)cc4)c4ccc(-c5ccc6c(c5)c5ccccc5n6-c5ccccc5)cc4)cc3)cc2)cc1]

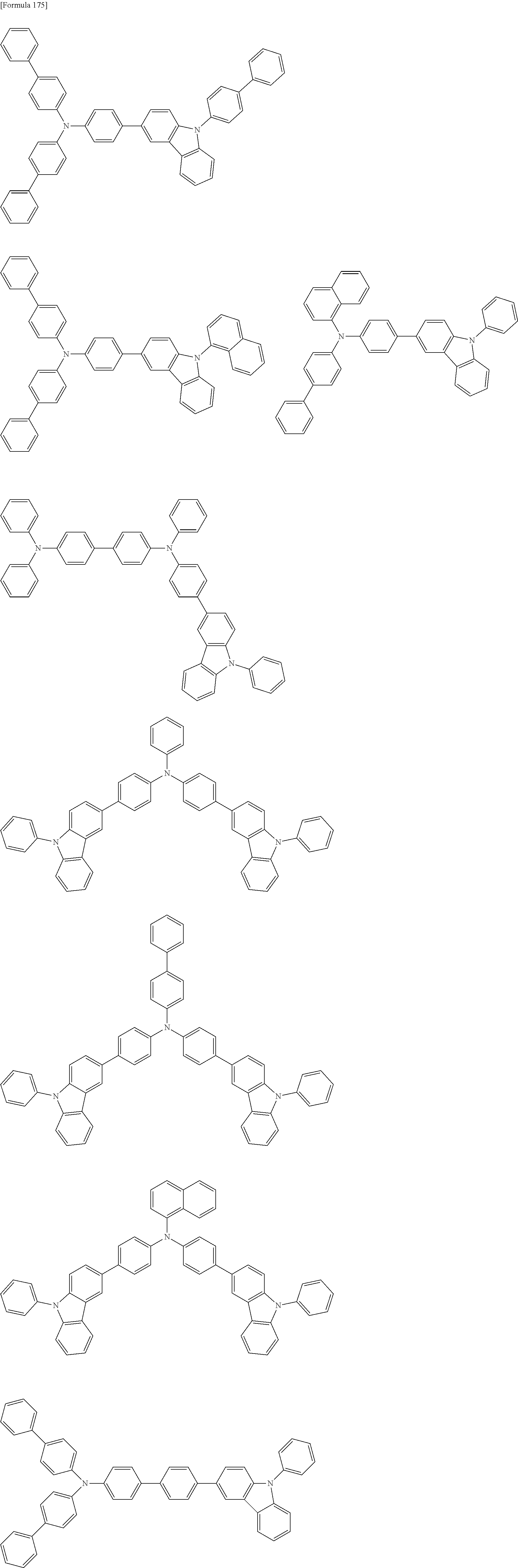

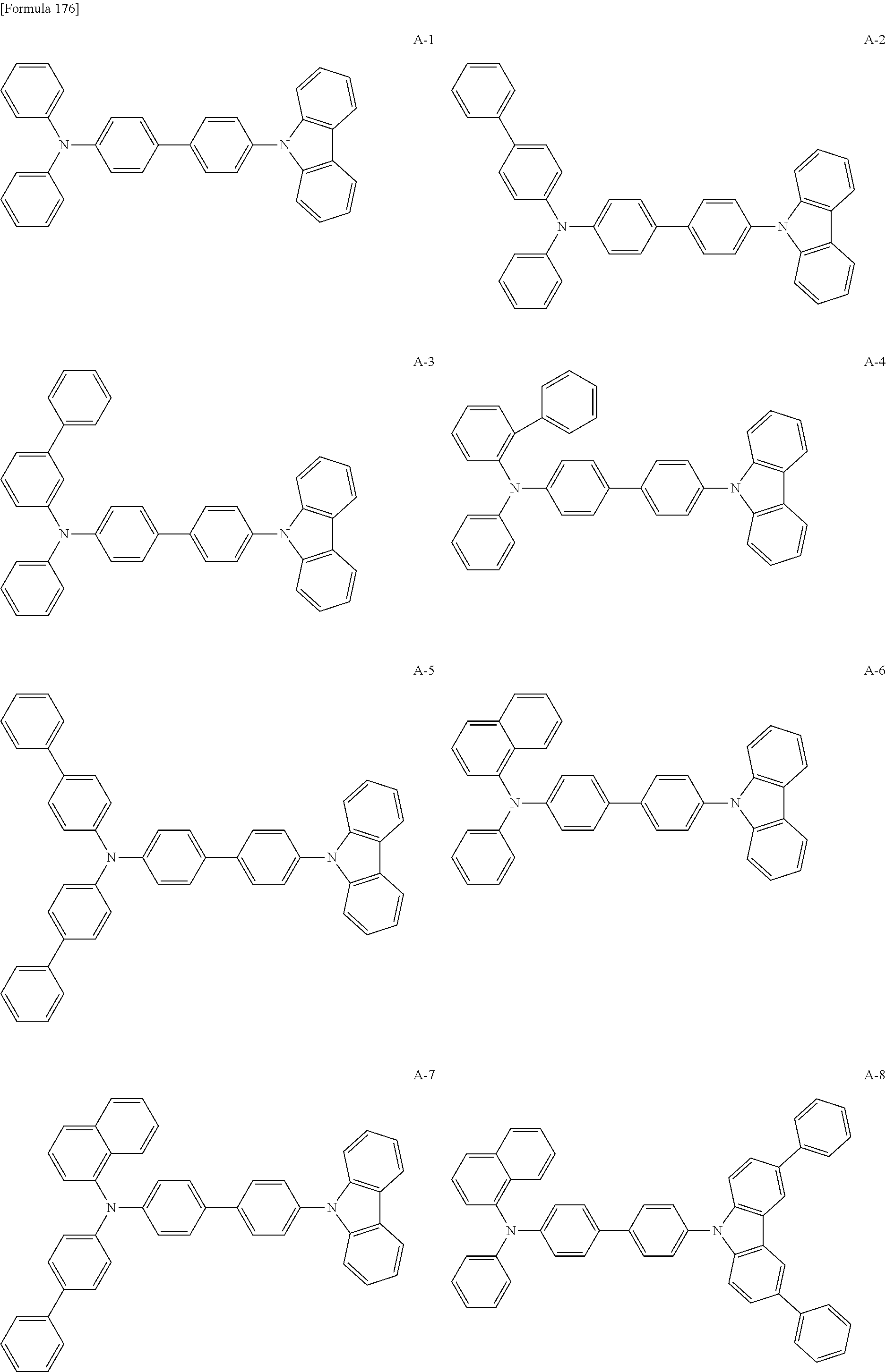

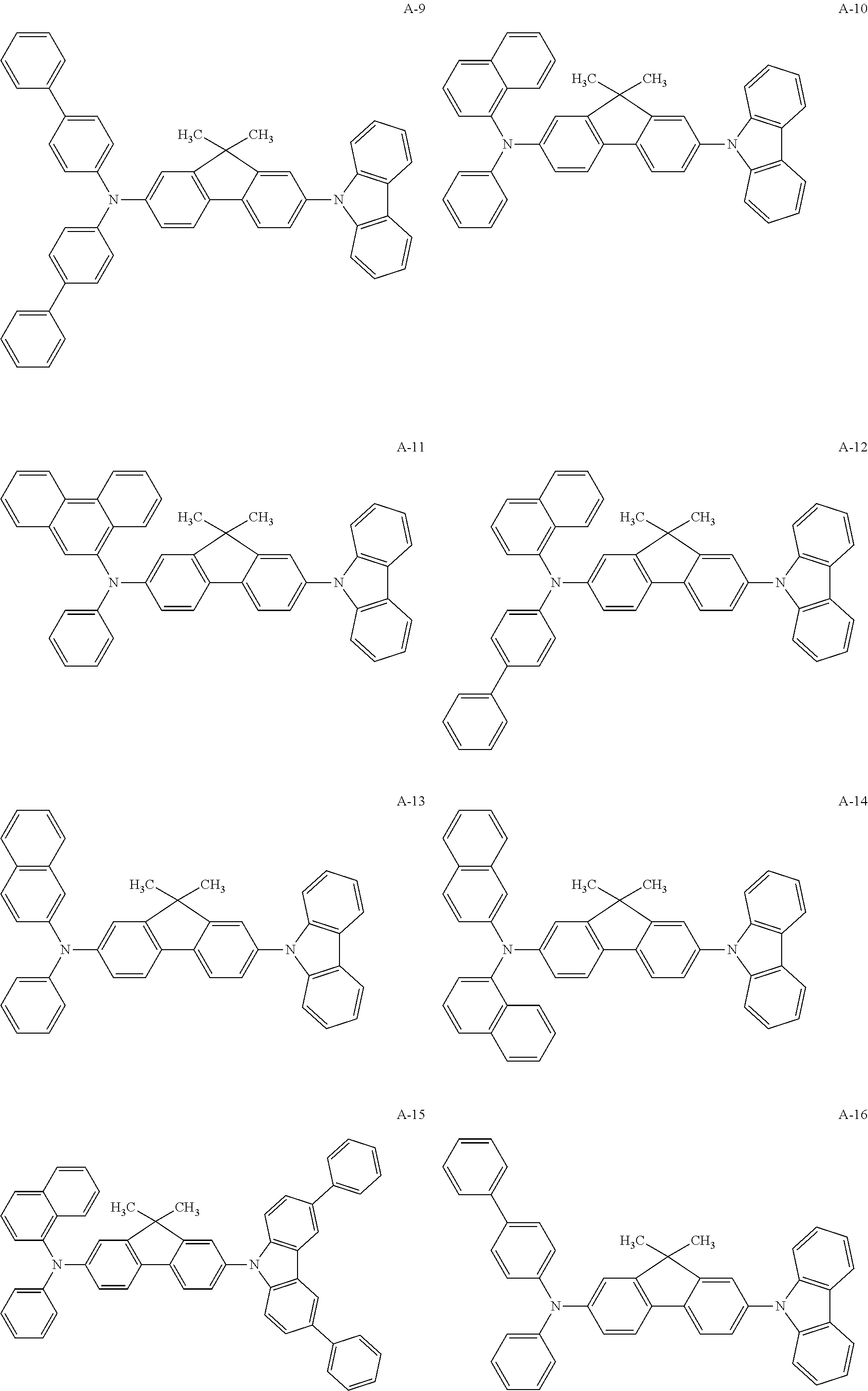

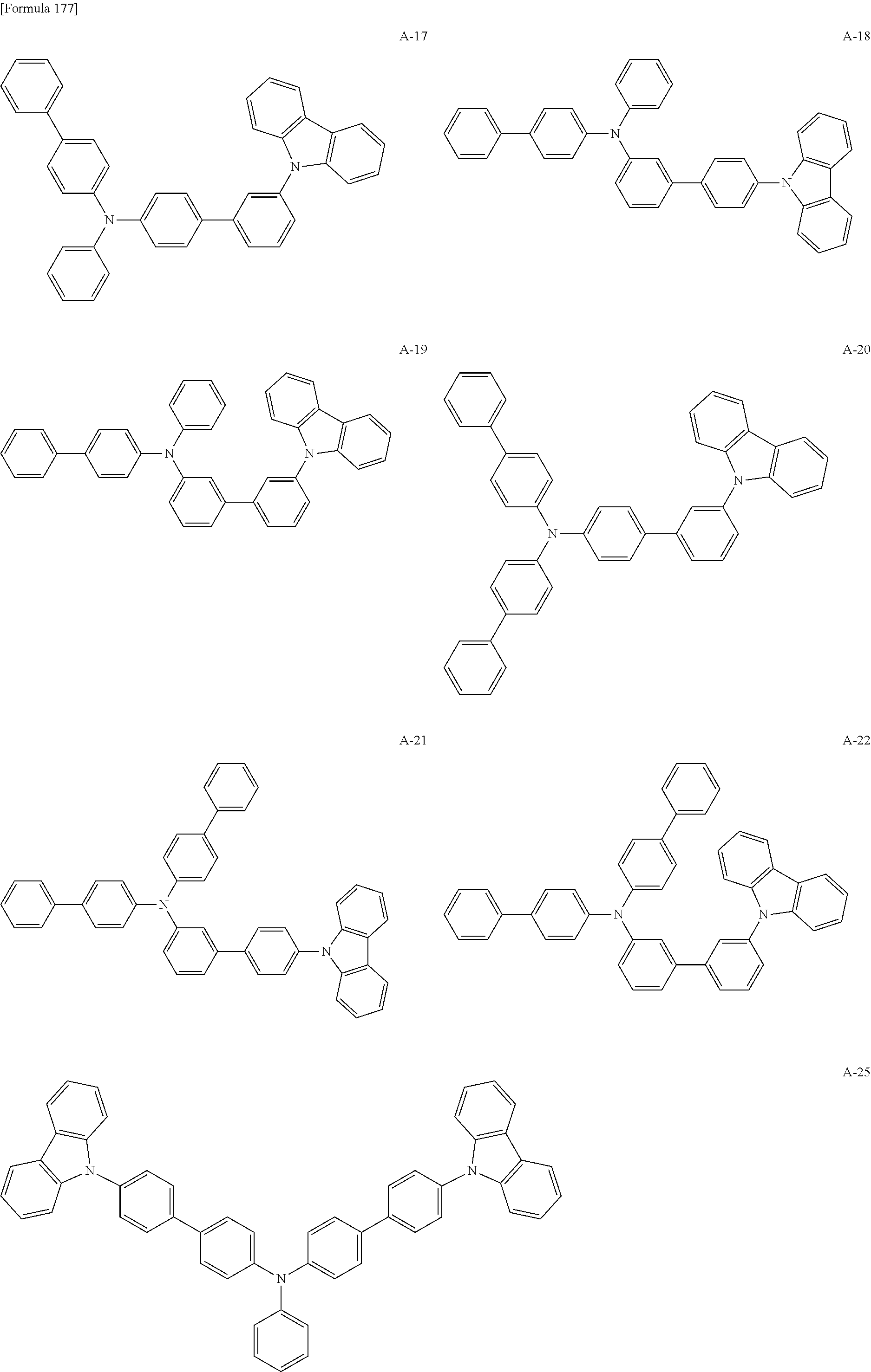

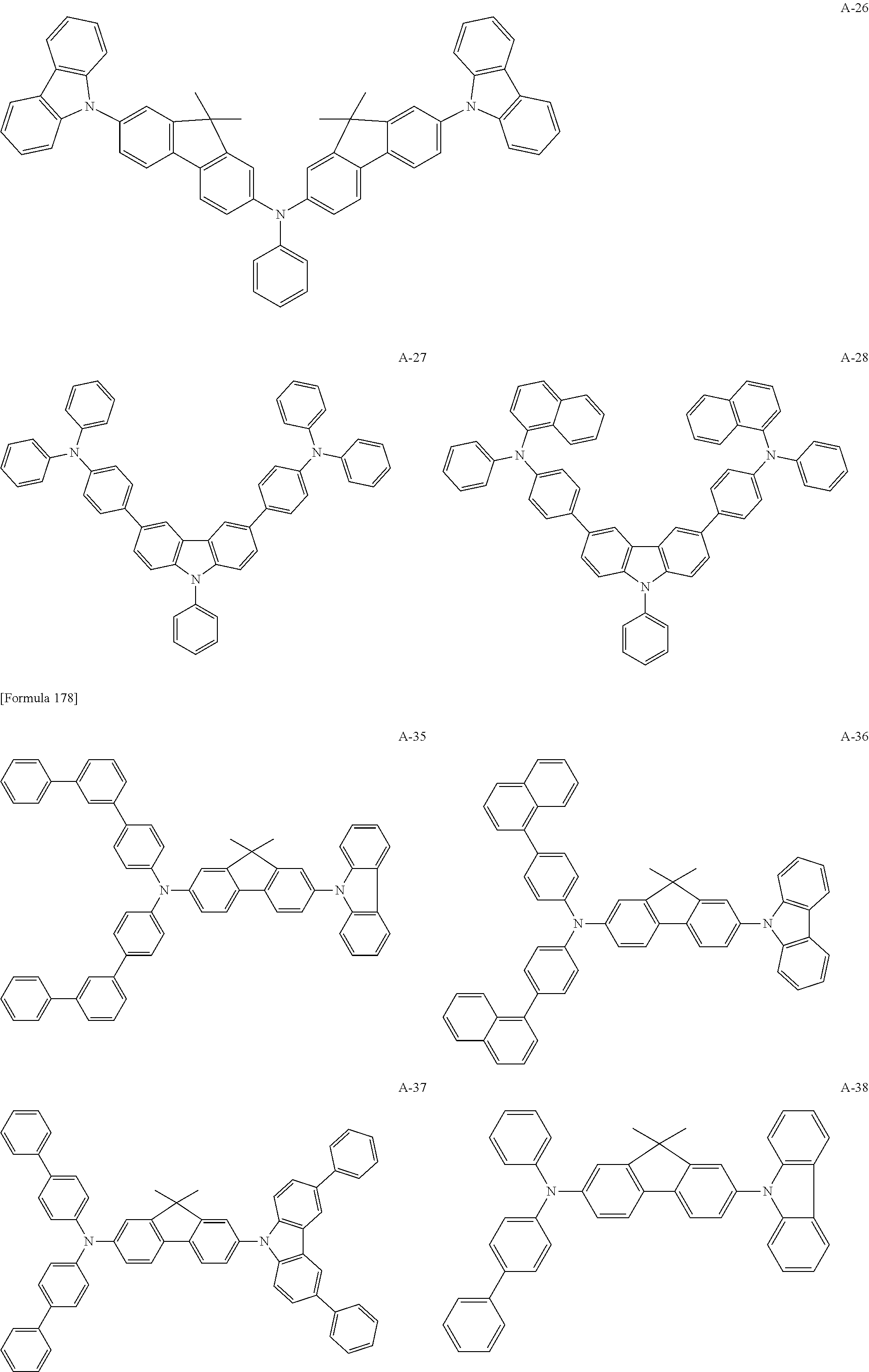

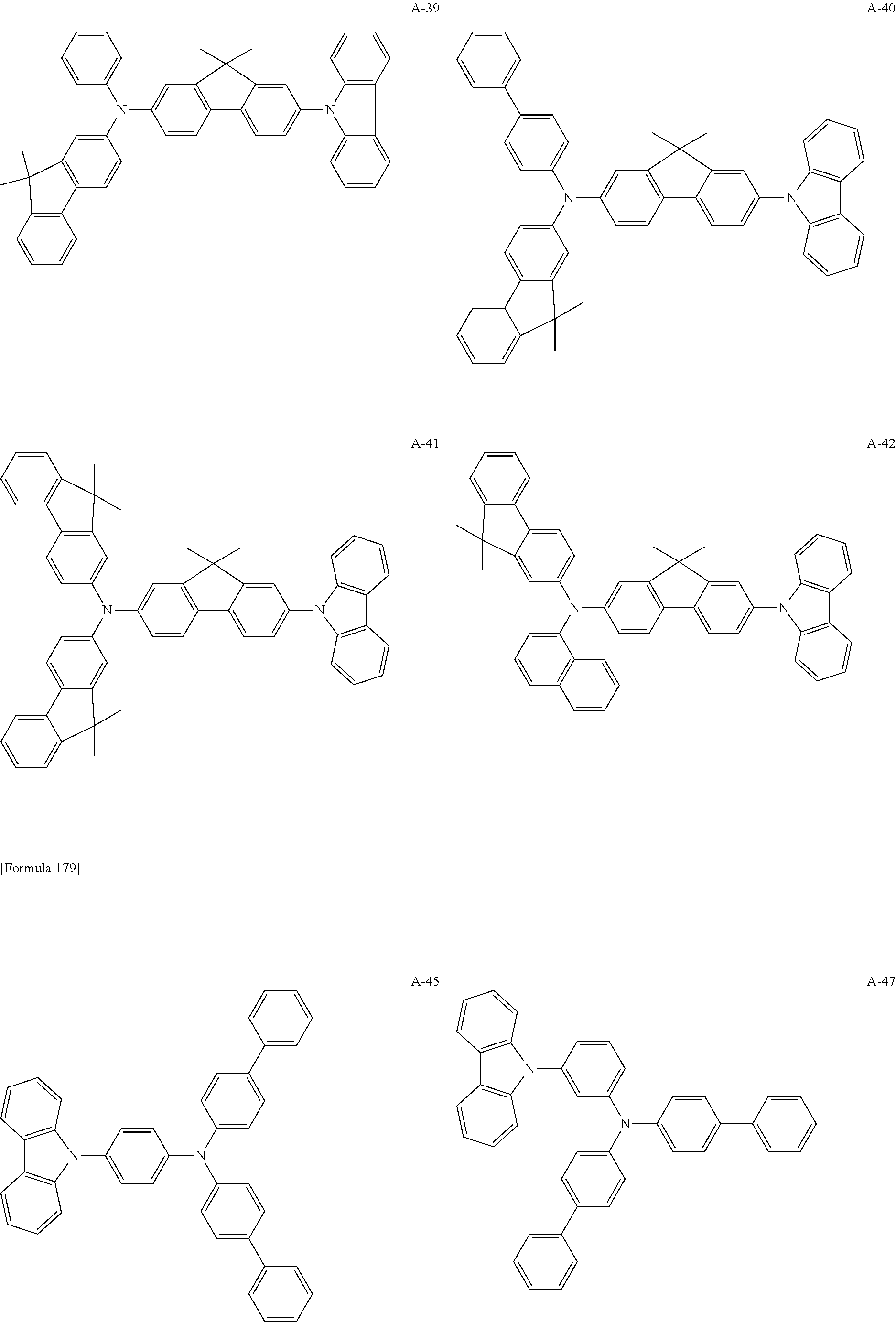

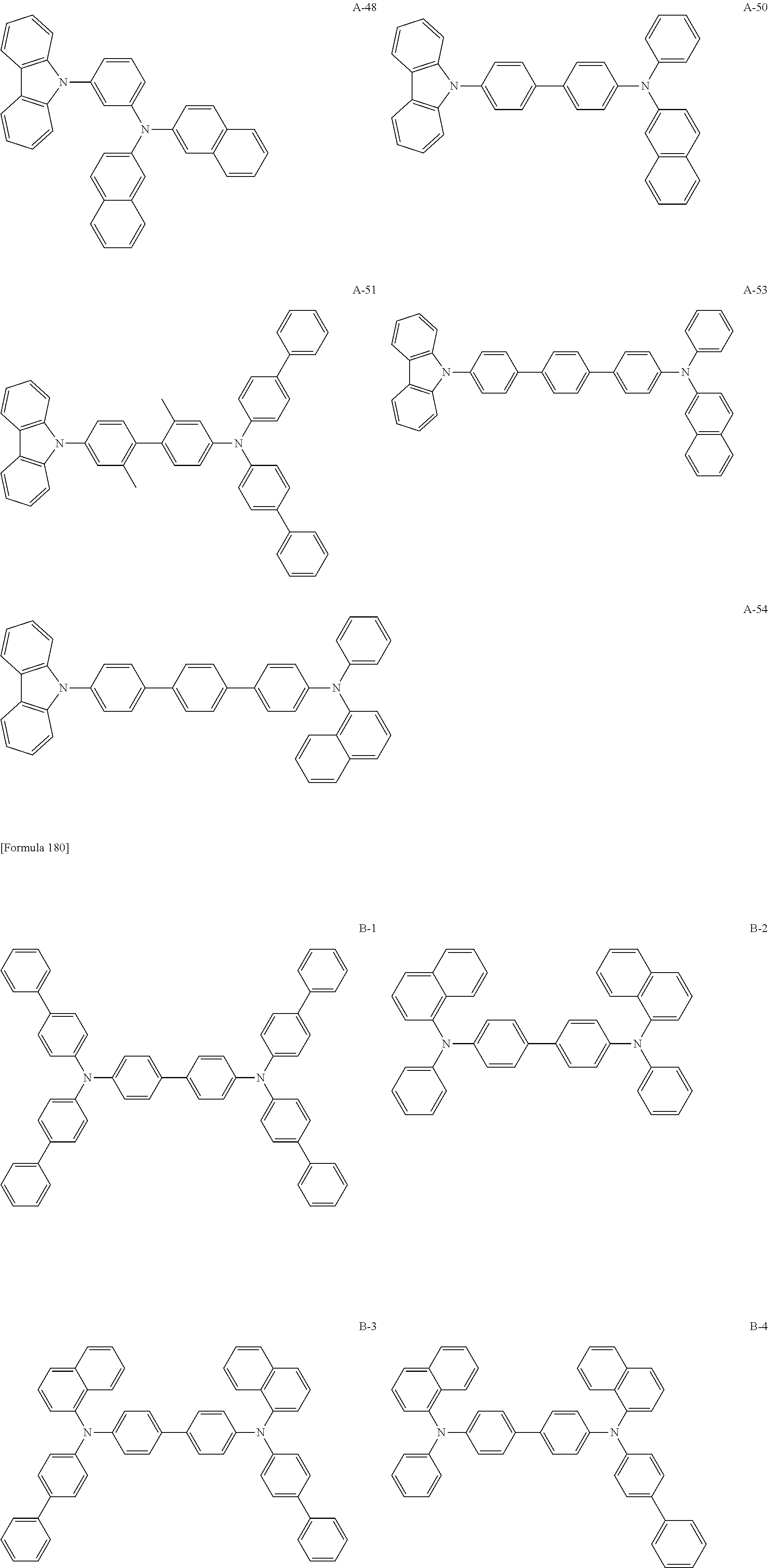

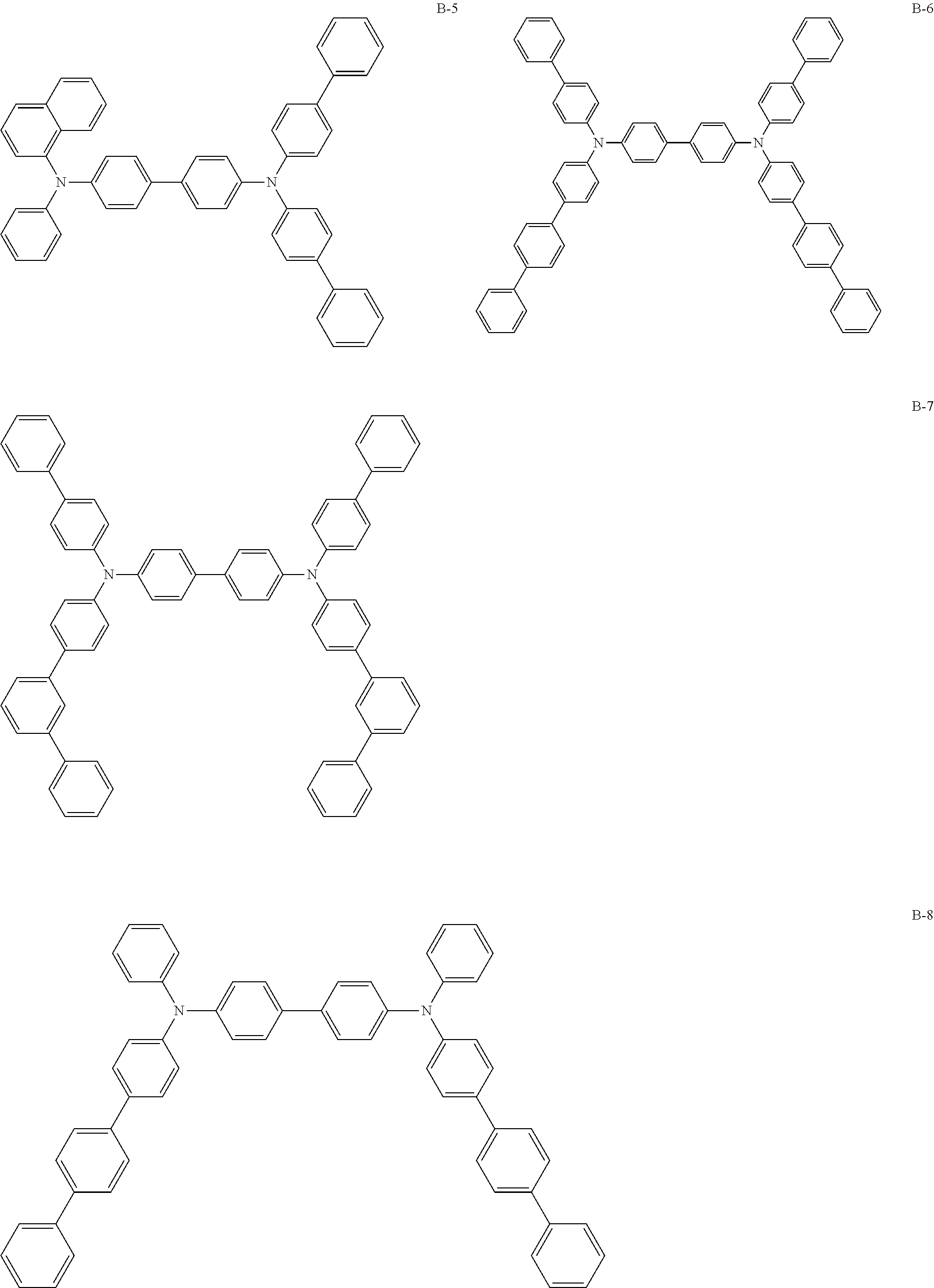 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(-c3ccc(N(c4ccc(-c5ccccc5)cc4)c4ccc(-c5ccc(N(c6ccc(-c7ccccc7)cc6)c6ccc(-c7ccc(-c8ccccc8)cc7)cc6)cc5)cc4)cc3)cc2)cc1 ; c1ccc(-c2ccc(N(c3ccc(-c4ccc(N(c5ccc(-c6ccccc6)cc5)c5ccc(-c6cccc(-c7ccccc7)c6)cc5)cc4)cc3)c3ccc(-c4cccc(-c5ccccc5)c4)cc3)cc2)cc1 ; c1ccc(-c2ccc(-c3ccc(N(c4ccccc4)c4ccc(-c5ccc(N(c6ccccc6)c6ccc(-c7ccc(-c8ccccc8)cc7)cc6)cc5)cc4)cc3)cc2)cc1]

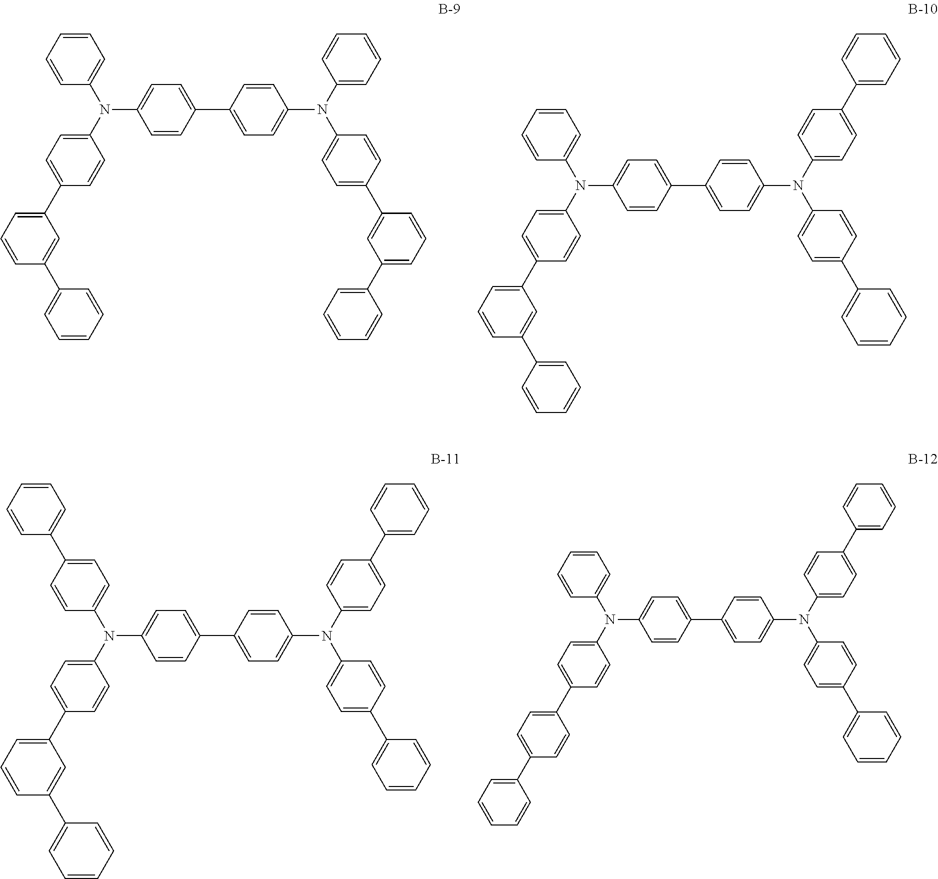 [SMILES: c1ccc(-c2cccc(-c3ccc(N(c4ccccc4)c4ccc(-c5ccc(N(c6ccccc6)c6ccc(-c7cccc(-c8ccccc8)c7)cc6)cc5)cc4)cc3)c2)cc1 ; c1ccc(-c2ccc(N(c3ccc(-c4ccccc4)cc3)c3ccc(-c4ccc(N(c5ccccc5)c5ccc(-c6cccc(-c7ccccc7)c6)cc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6cccc(-c7ccccc7)c6)cc5)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

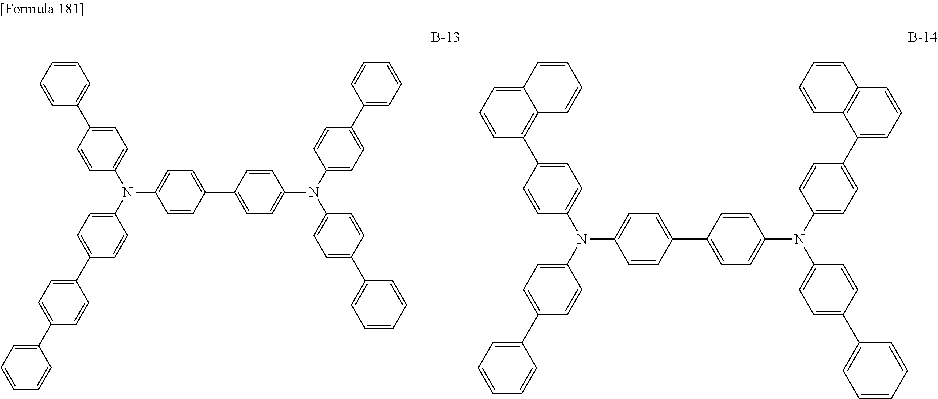 [SMILES: c1ccc(-c2ccc(-c3ccc(N(c4ccc(-c5ccccc5)cc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(N(c5ccc(-c6ccccc6)cc5)c5ccc(-c6cccc7ccccc67)cc5)cc4)cc3)c3ccc(-c4cccc5ccccc45)cc3)cc2)cc1]

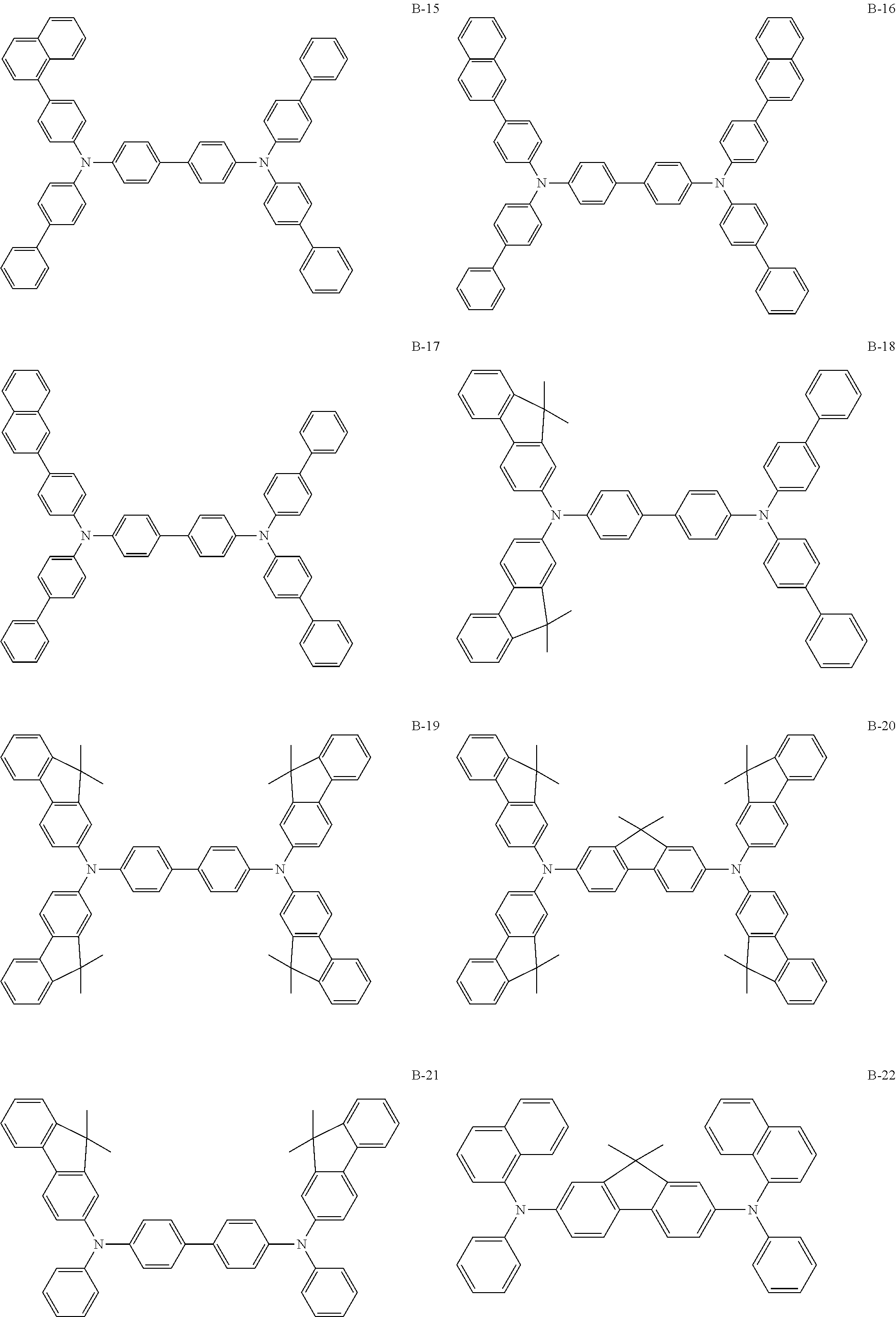

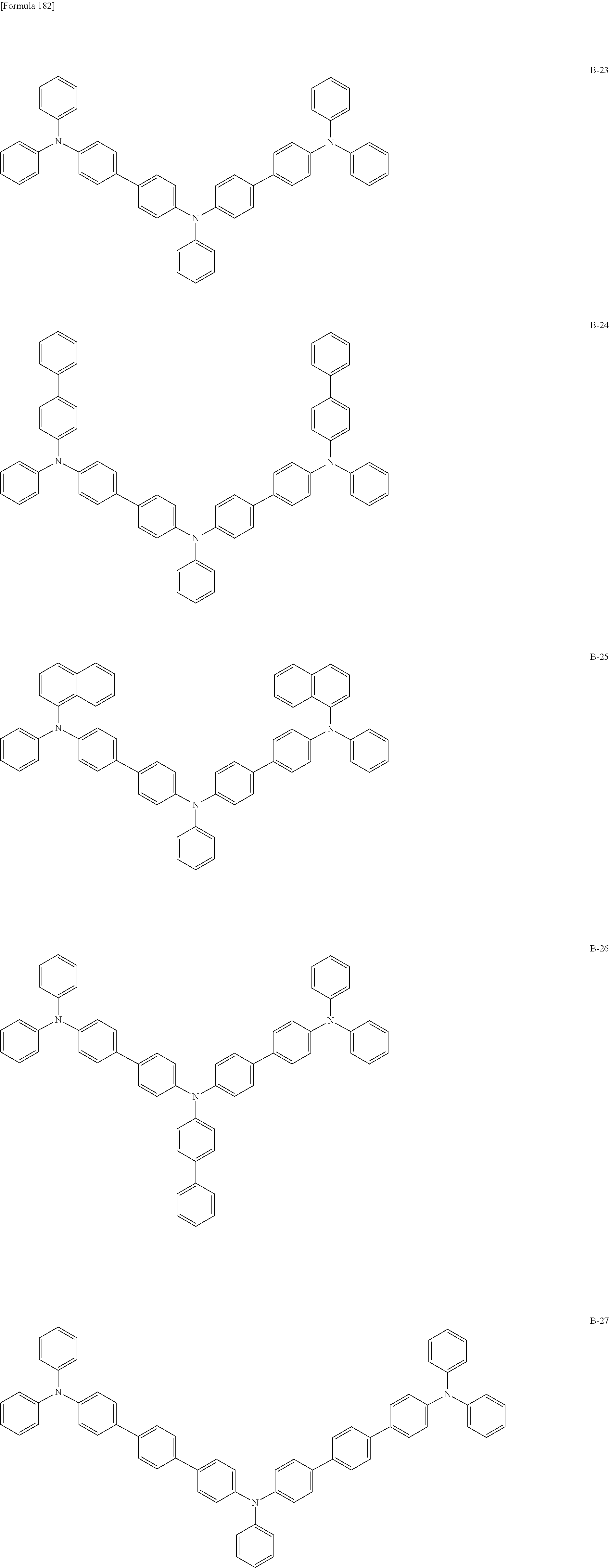

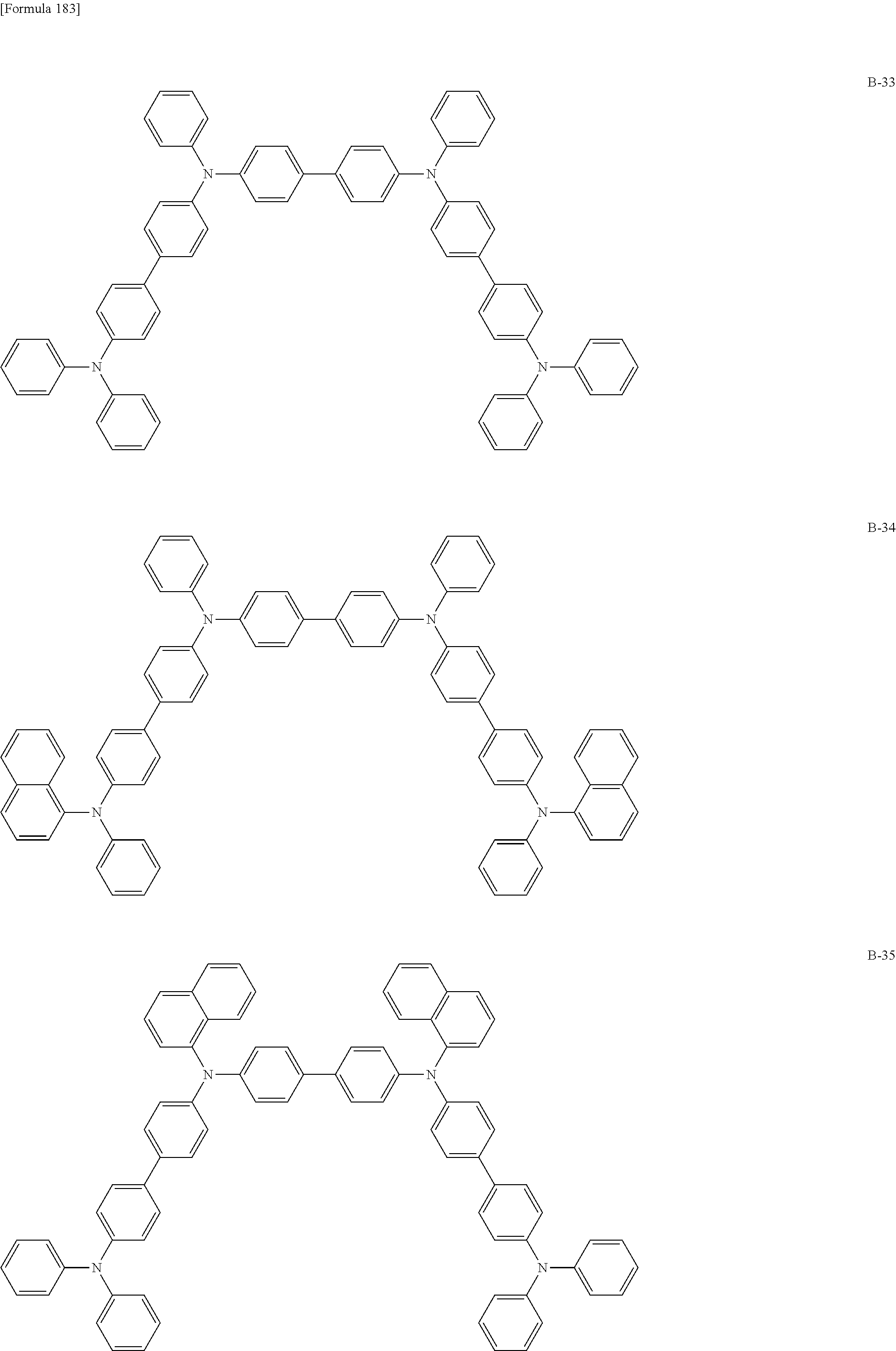 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccc(-c3ccc(N(c4ccccc4)c4ccc(-c5ccc(N(c6ccccc6)c6cccc7ccccc67)cc5)cc4)cc3)cc2)c2ccc(-c3ccc(N(c4ccccc4)c4cccc5ccccc45)cc3)cc2)cc1 ; c1ccc(N(c2ccccc2)c2ccc(-c3ccc(N(c4ccc(-c5ccc(N(c6ccc(-c7ccc(N(c8ccccc8)c8ccccc8)cc7)cc6)c6cccc7ccccc67)cc5)cc4)c4cccc5ccccc45)cc3)cc2)cc1]

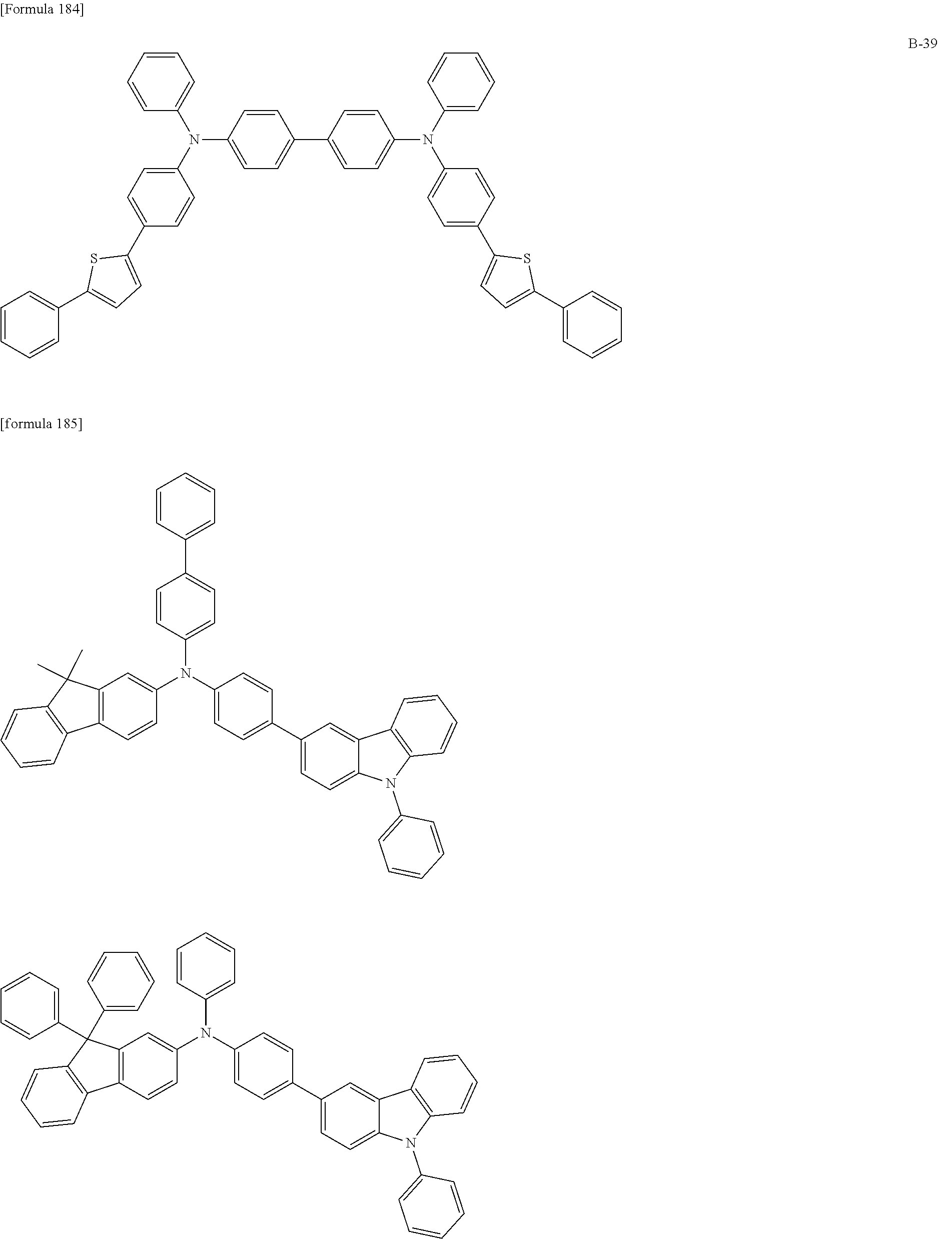 [SMILES: c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1]

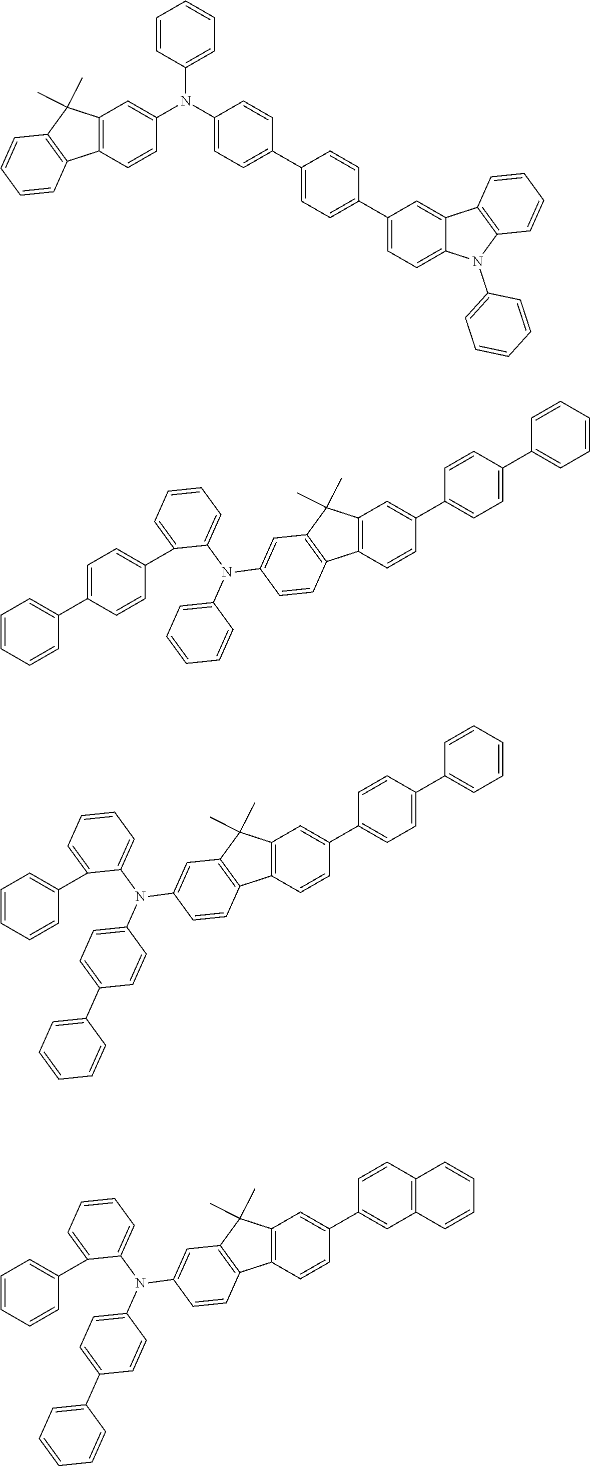 [SMILES: CC1(C)c2ccccc2-c2ccc(N(c3ccccc3)c3ccc(-c4ccc(-c5ccc6c(c5)c5ccccc5n6-c5ccccc5)cc4)cc3)cc21 ; CC1(C)c2cc(-c3ccc(-c4ccccc4)cc3)ccc2-c2ccc(N(c3ccccc3)c3ccccc3-c3ccc(-c4ccccc4)cc3)cc21 ; CC1(C)c2cc(-c3ccc(-c4ccccc4)cc3)ccc2-c2ccc(N(c3ccc(-c4ccccc4)cc3)c3ccccc3-c3ccccc3)cc21 ; CC1(C)c2cc(-c3ccc4ccccc4c3)ccc2-c2ccc(N(c3ccc(-c4ccccc4)cc3)c3ccccc3-c3ccccc3)cc21]

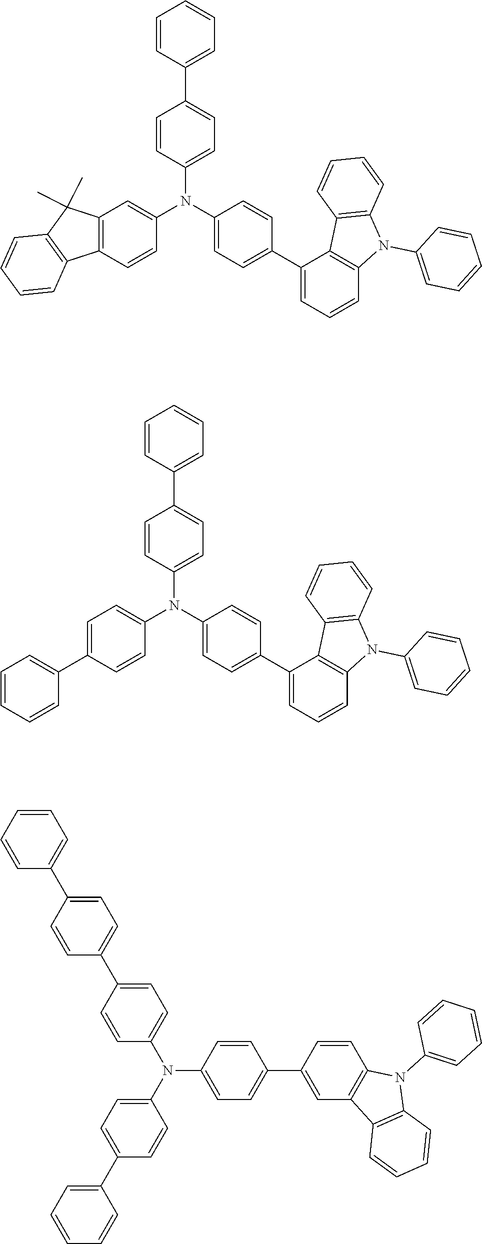 [SMILES: CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc(-c4cccc5c4c4ccccc4n5-c4ccccc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

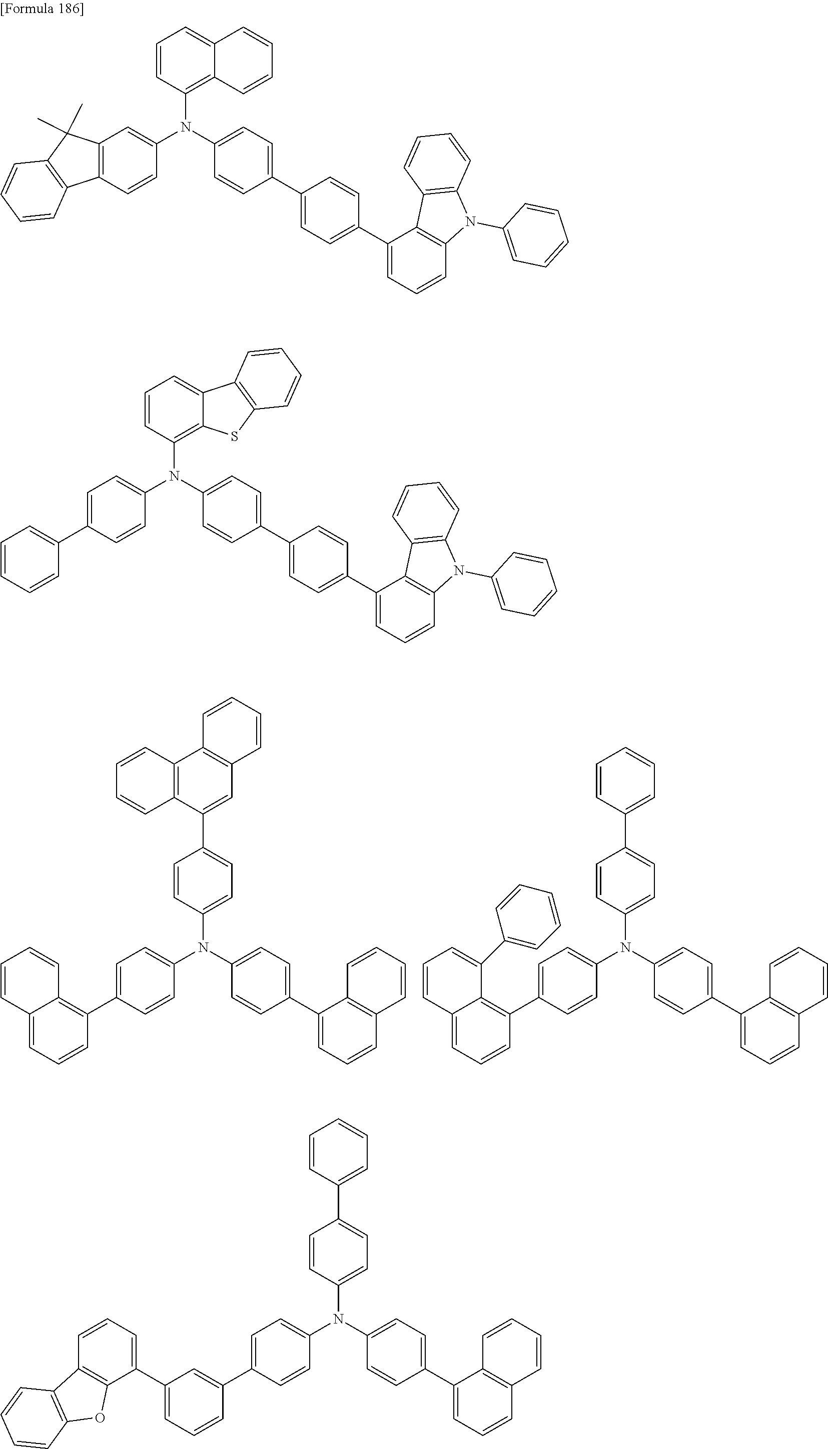

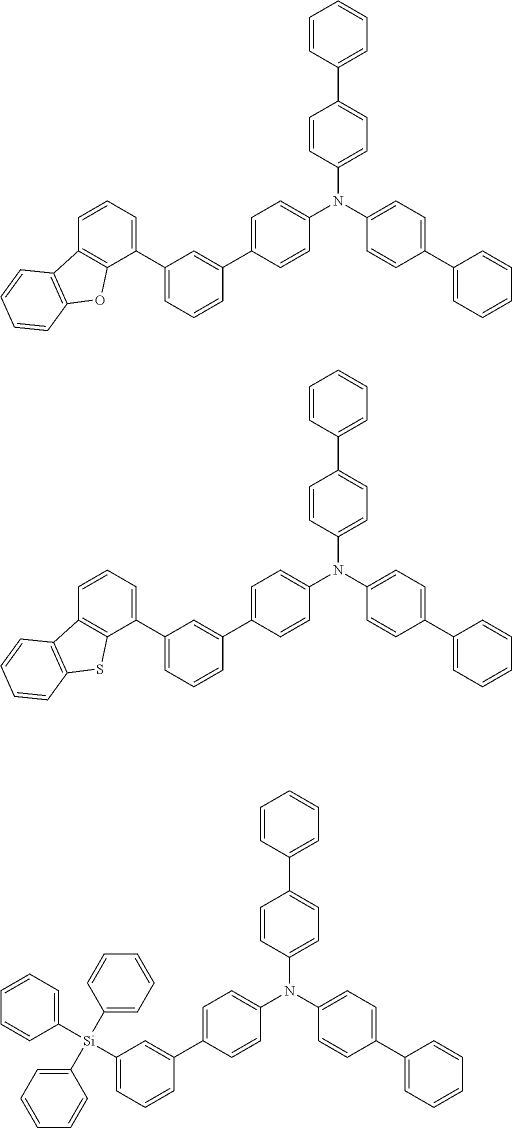 [SMILES: c1ccc(-c2ccc(N(c3ccc(-c4ccccc4)cc3)c3ccc(-c4cccc(-c5cccc6c5oc5ccccc56)c4)cc3)cc2)cc1 ; c1ccc(-c2ccc(N(c3ccc(-c4ccccc4)cc3)c3ccc(-c4cccc(-c5cccc6c5sc5ccccc56)c4)cc3)cc2)cc1 ; c1ccc(-c2ccc(N(c3ccc(-c4ccccc4)cc3)c3ccc(-c4cccc([Si](c5ccccc5)(c5ccccc5)c5ccccc5)c4)cc3)cc2)cc1]

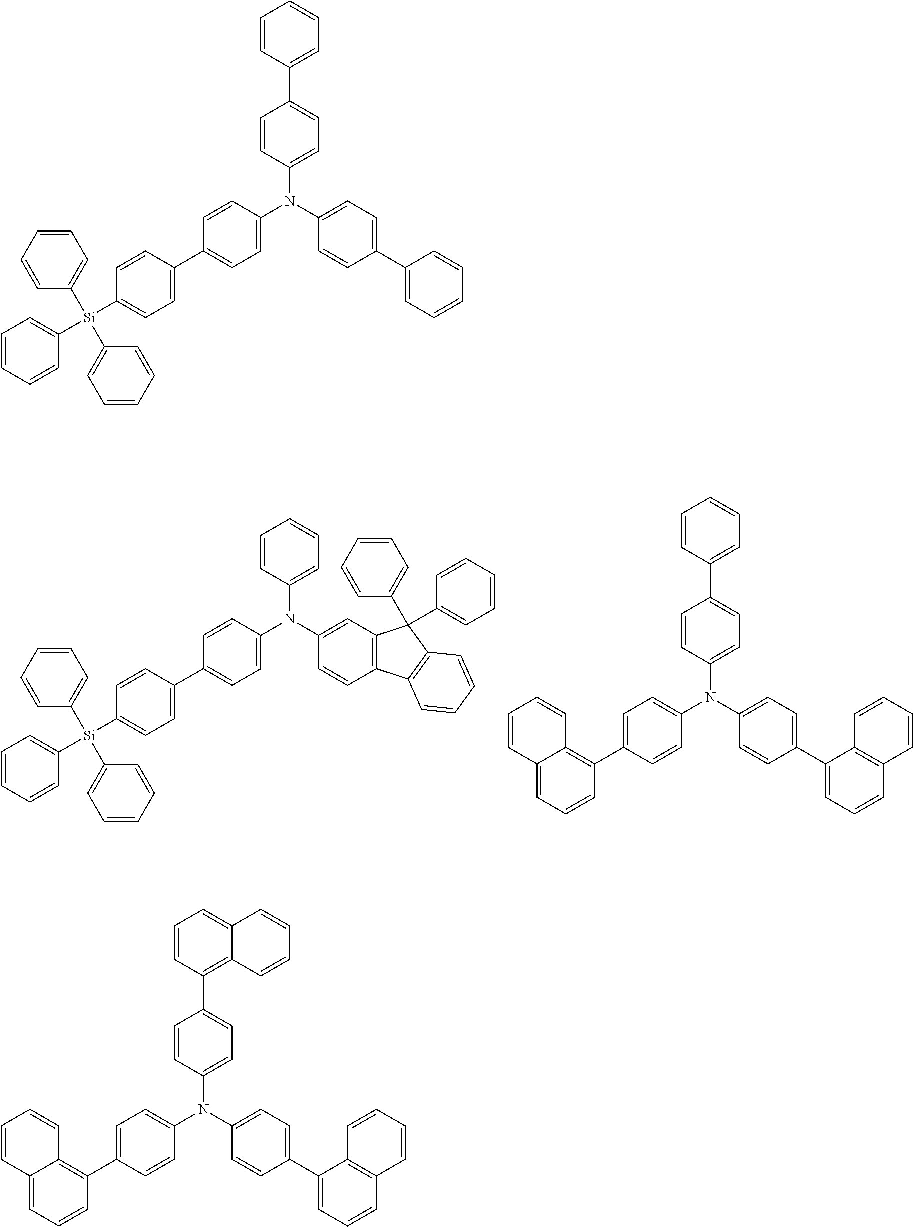

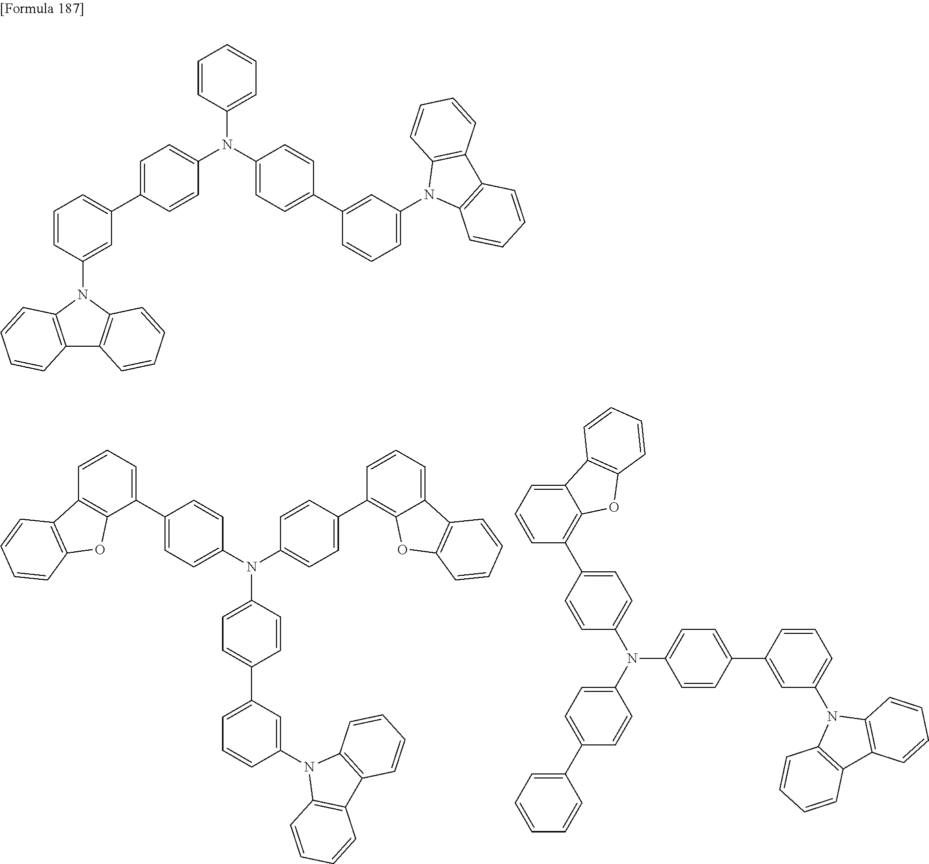

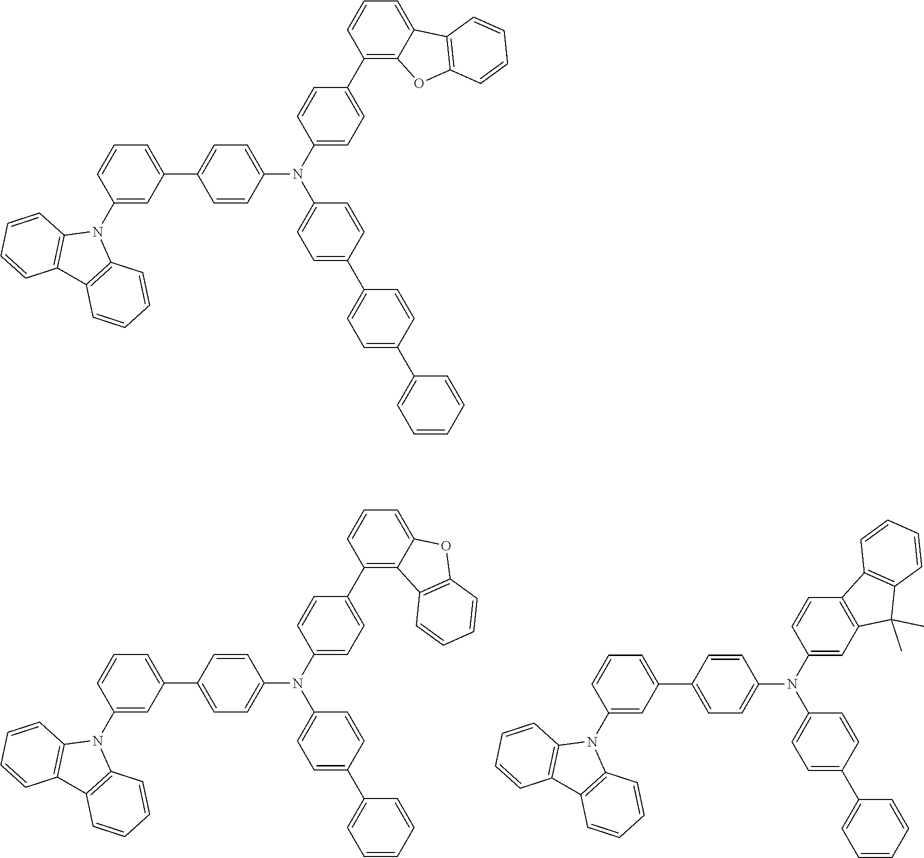 [SMILES: c1ccc(-c2ccc(-c3ccc(N(c4ccc(-c5cccc(-n6c7ccccc7c7ccccc76)c5)cc4)c4ccc(-c5cccc6c5oc5ccccc56)cc4)cc3)cc2)cc1 ; c1ccc(-c2ccc(N(c3ccc(-c4cccc(-n5c6ccccc6c6ccccc65)c4)cc3)c3ccc(-c4cccc5oc6ccccc6c45)cc3)cc2)cc1 ; CC1(C)c2ccccc2-c2ccc(N(c3ccc(-c4ccccc4)cc3)c3ccc(-c4cccc(-n5c6ccccc6c6ccccc65)c4)cc3)cc21]

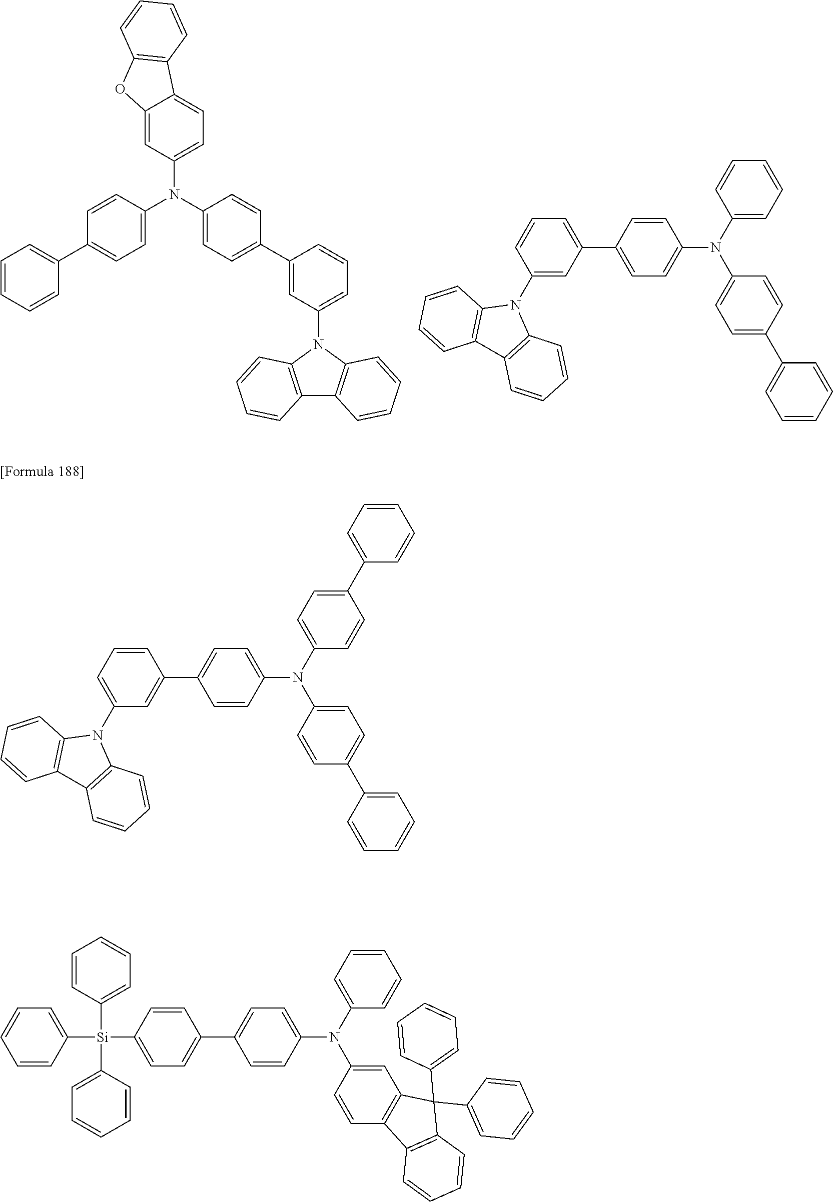 [SMILES: c1ccc(-c2ccc(N(c3ccc(-c4cccc(-n5c6ccccc6c6ccccc65)c4)cc3)c3ccc4c(c3)oc3ccccc34)cc2)cc1 ; c1ccc(-c2ccc(N(c3ccccc3)c3ccc(-c4cccc(-n5c6ccccc6c6ccccc65)c4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1]

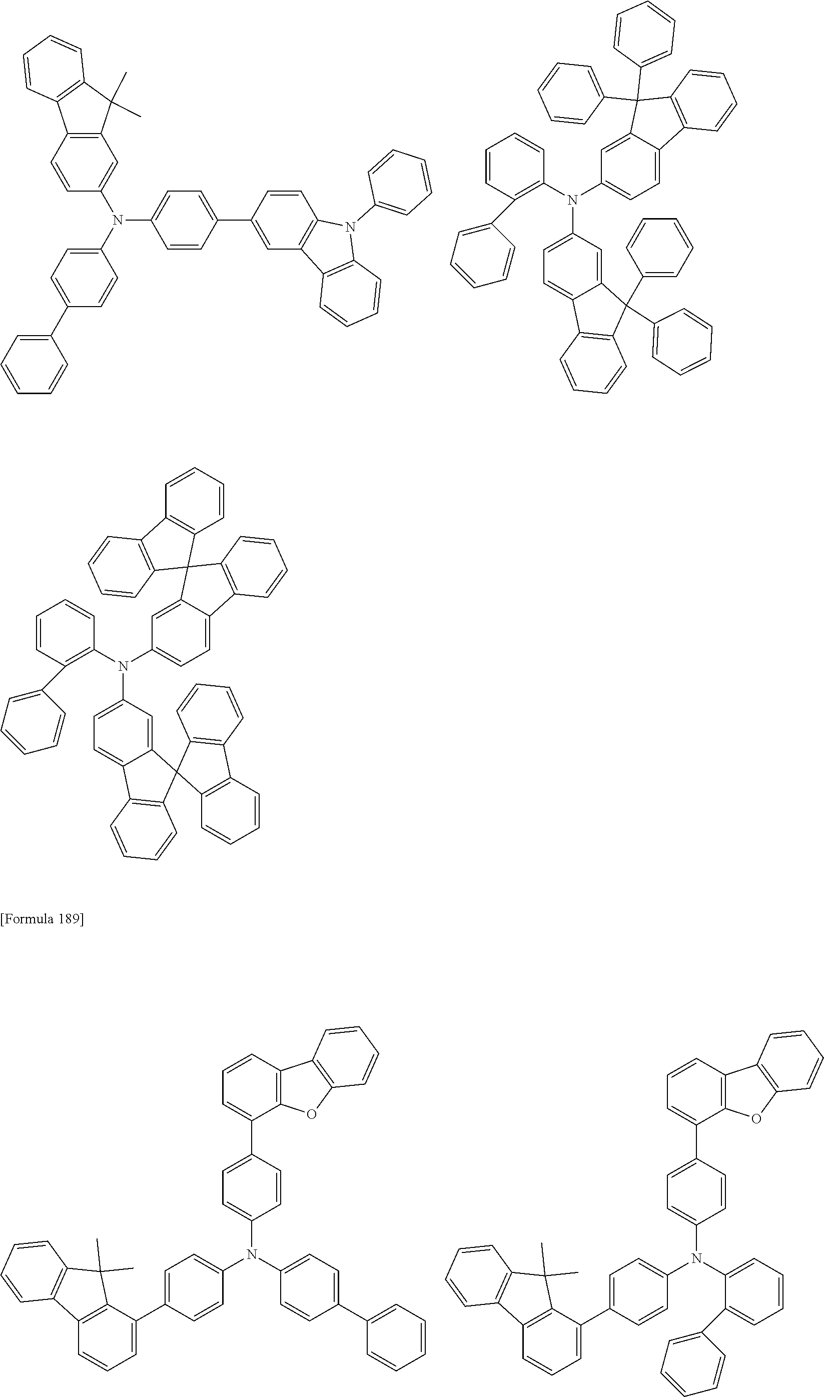

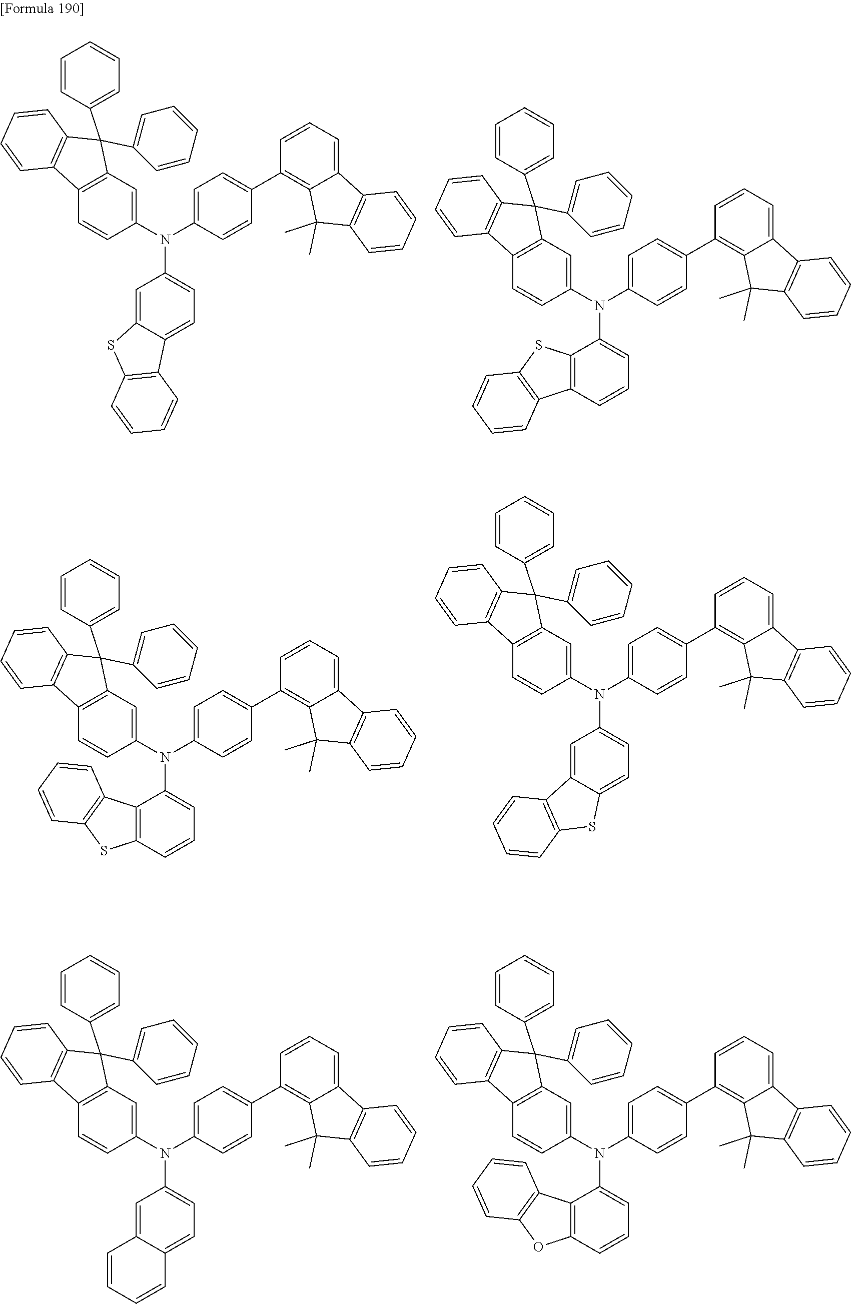

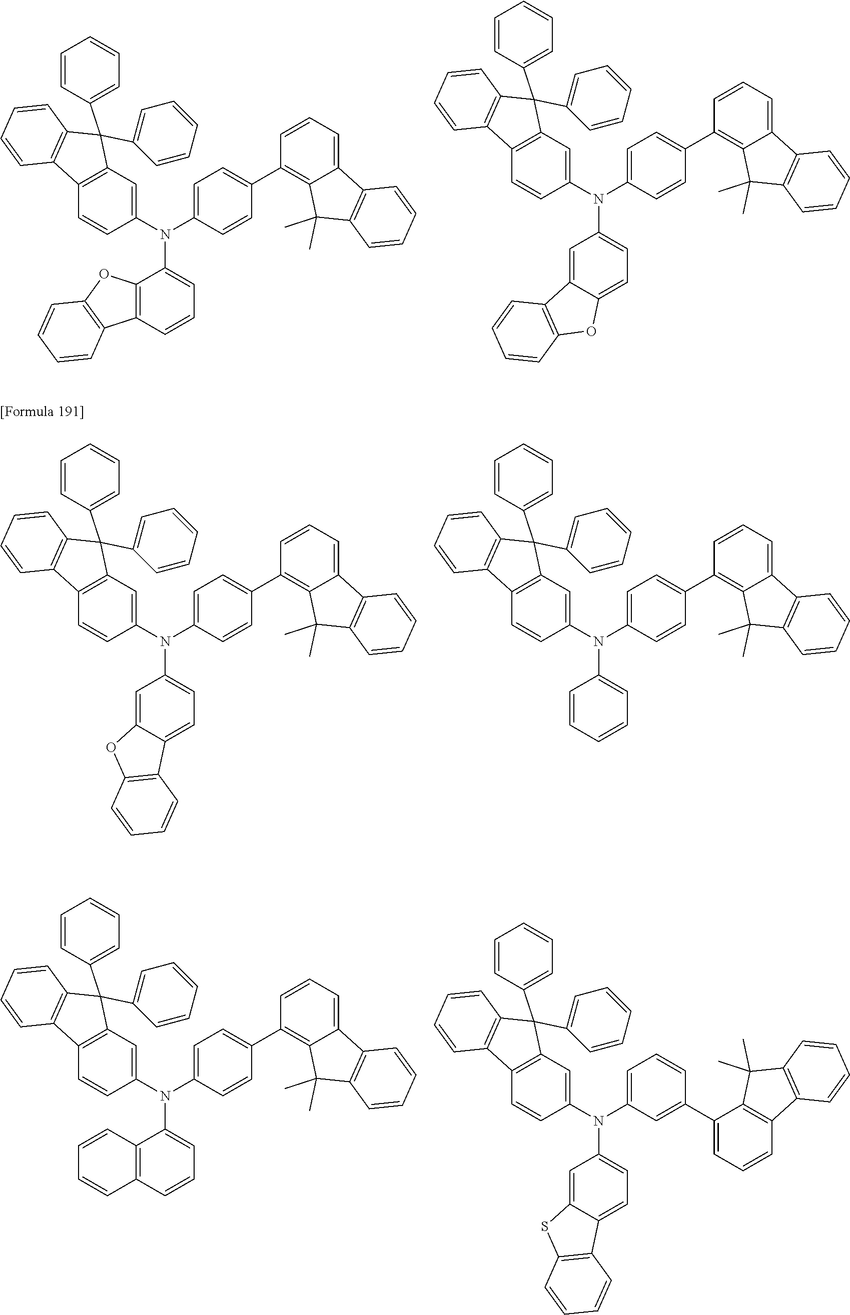

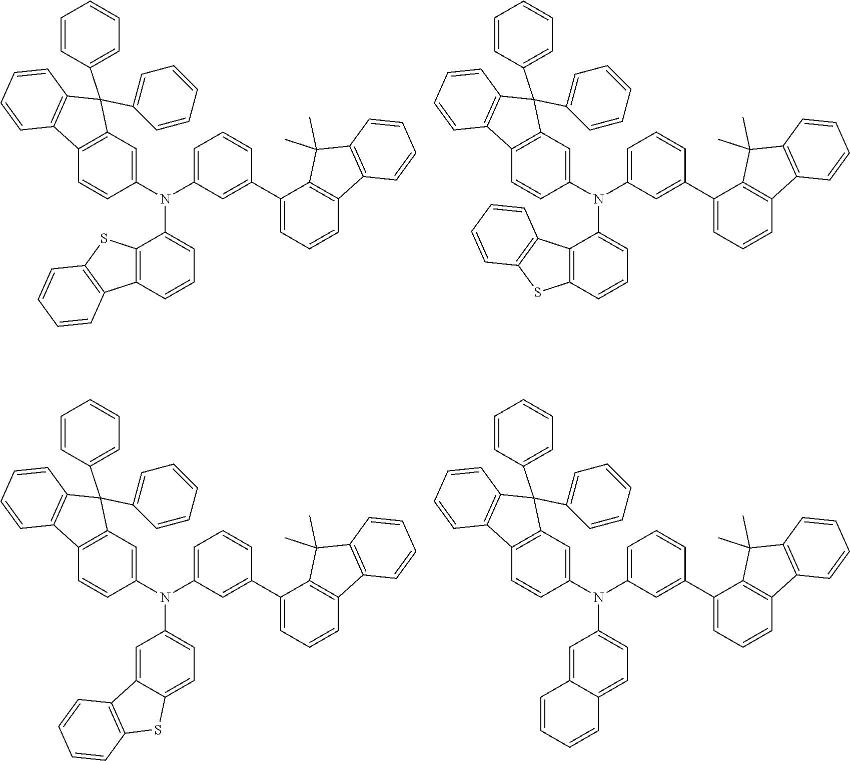

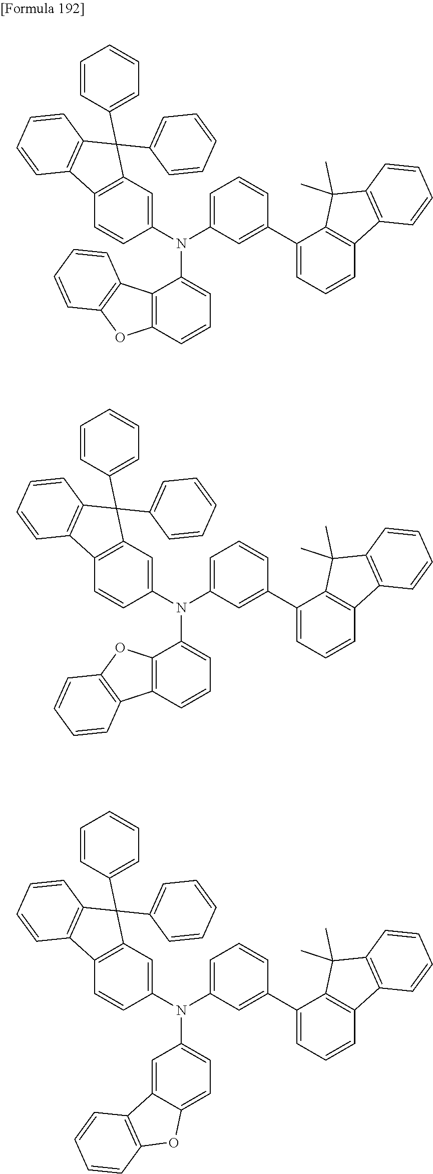 [SMILES: CC1(C)c2ccccc2-c2cccc(-c3cccc(N(c4ccc5c(c4)C(c4ccccc4)(c4ccccc4)c4ccccc4-5)c4cccc5oc6ccccc6c45)c3)c21 ; CC1(C)c2ccccc2-c2cccc(-c3cccc(N(c4ccc5c(c4)C(c4ccccc4)(c4ccccc4)c4ccccc4-5)c4cccc5c4oc4ccccc45)c3)c21 ; CC1(C)c2ccccc2-c2cccc(-c3cccc(N(c4ccc5c(c4)C(c4ccccc4)(c4ccccc4)c4ccccc4-5)c4ccc5oc6ccccc6c5c4)c3)c21]

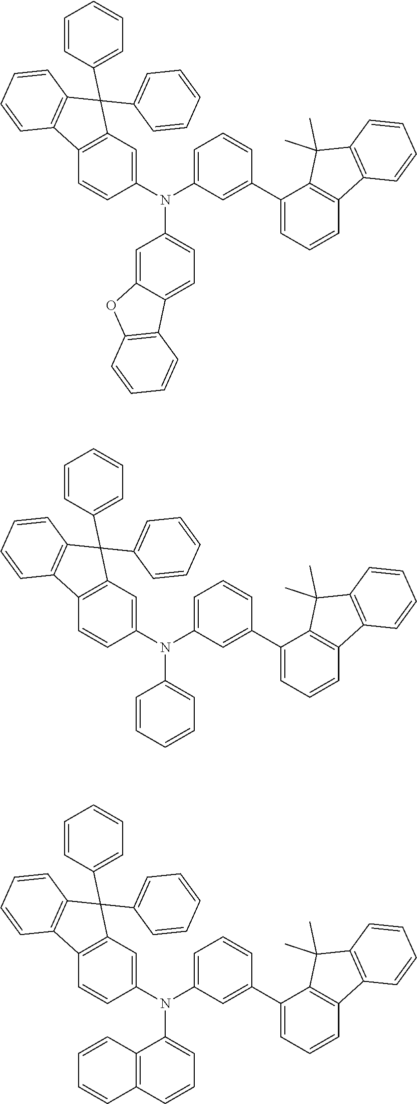 [SMILES: CC1(C)c2ccccc2-c2cccc(-c3cccc(N(c4ccc5c(c4)C(c4ccccc4)(c4ccccc4)c4ccccc4-5)c4ccc5c(c4)oc4ccccc45)c3)c21 ; CC1(C)c2ccccc2-c2cccc(-c3cccc(N(c4ccccc4)c4ccc5c(c4)C(c4ccccc4)(c4ccccc4)c4ccccc4-5)c3)c21 ; CC1(C)c2ccccc2-c2cccc(-c3cccc(N(c4ccc5c(c4)C(c4ccccc4)(c4ccccc4)c4ccccc4-5)c4cccc5ccccc45)c3)c21]

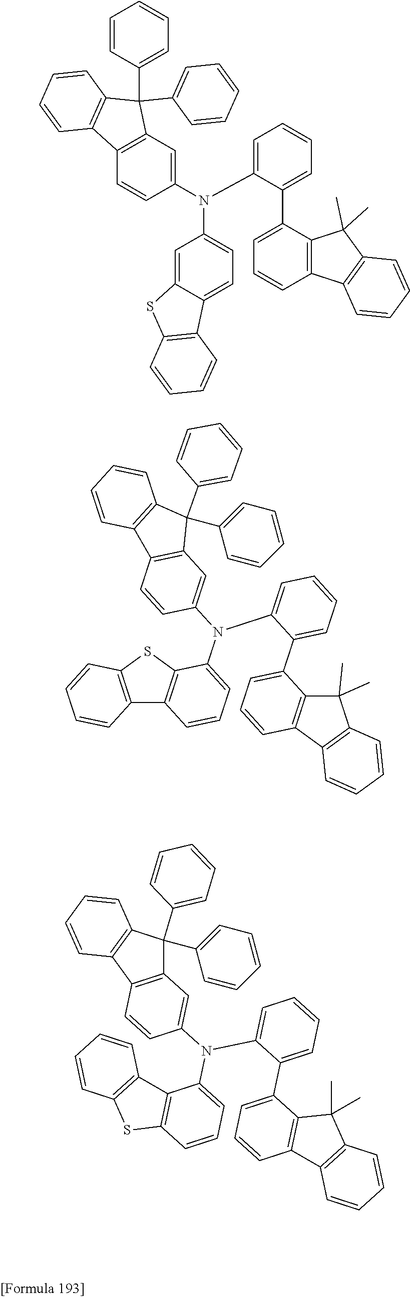

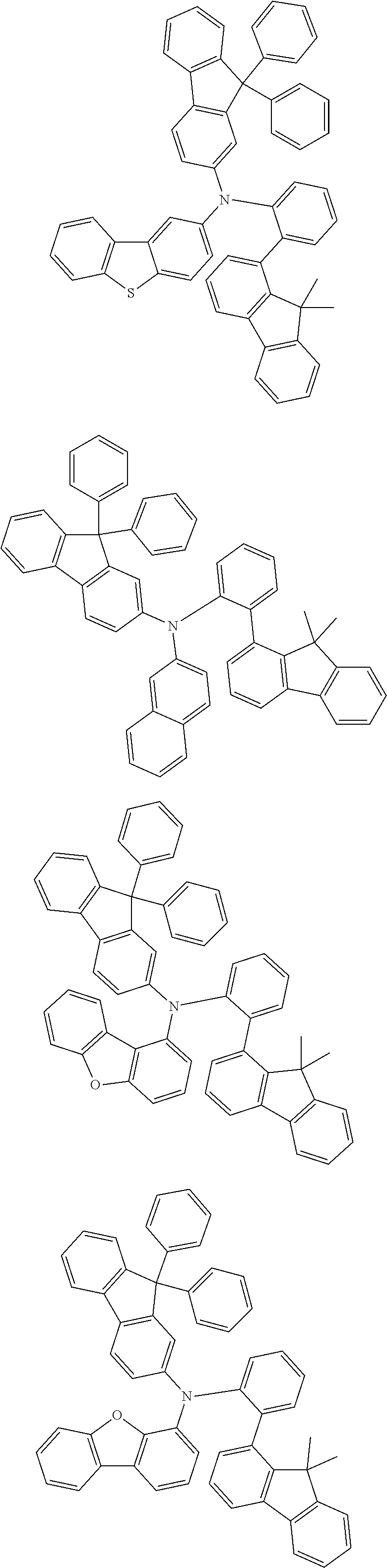

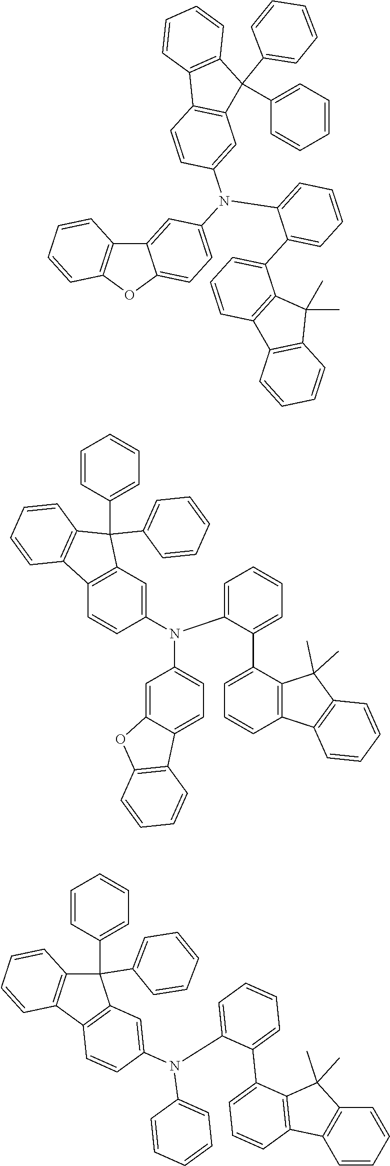 [SMILES: CC1(C)c2ccccc2-c2cccc(-c3ccccc3N(c3ccc4c(c3)C(c3ccccc3)(c3ccccc3)c3ccccc3-4)c3ccc4oc5ccccc5c4c3)c21 ; CC1(C)c2ccccc2-c2cccc(-c3ccccc3N(c3ccc4c(c3)C(c3ccccc3)(c3ccccc3)c3ccccc3-4)c3ccc4c(c3)oc3ccccc34)c21 ; CC1(C)c2ccccc2-c2cccc(-c3ccccc3N(c3ccccc3)c3ccc4c(c3)C(c3ccccc3)(c3ccccc3)c3ccccc3-4)c21]

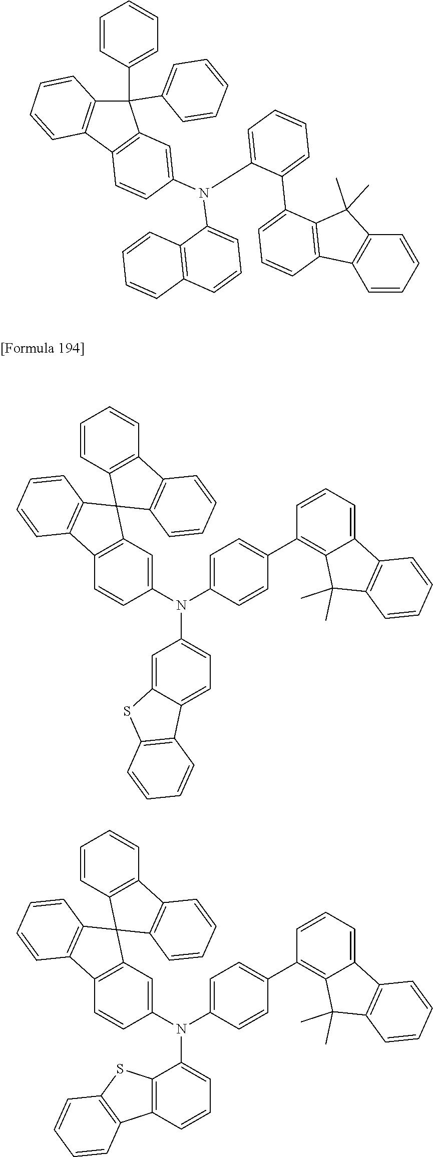 [SMILES: CC1(C)c2ccccc2-c2cccc(-c3ccccc3N(c3ccc4c(c3)C(c3ccccc3)(c3ccccc3)c3ccccc3-4)c3cccc4ccccc34)c21 ; CC1(C)c2ccccc2-c2cccc(-c3ccc(N(c4ccc5c(c4)C4(c6ccccc6-c6ccccc64)c4ccccc4-5)c4ccc5c(c4)sc4ccccc45)cc3)c21 ; CC1(C)c2ccccc2-c2cccc(-c3ccc(N(c4ccc5c(c4)C4(c6ccccc6-c6ccccc64)c4ccccc4-5)c4cccc5c4sc4ccccc45)cc3)c21]

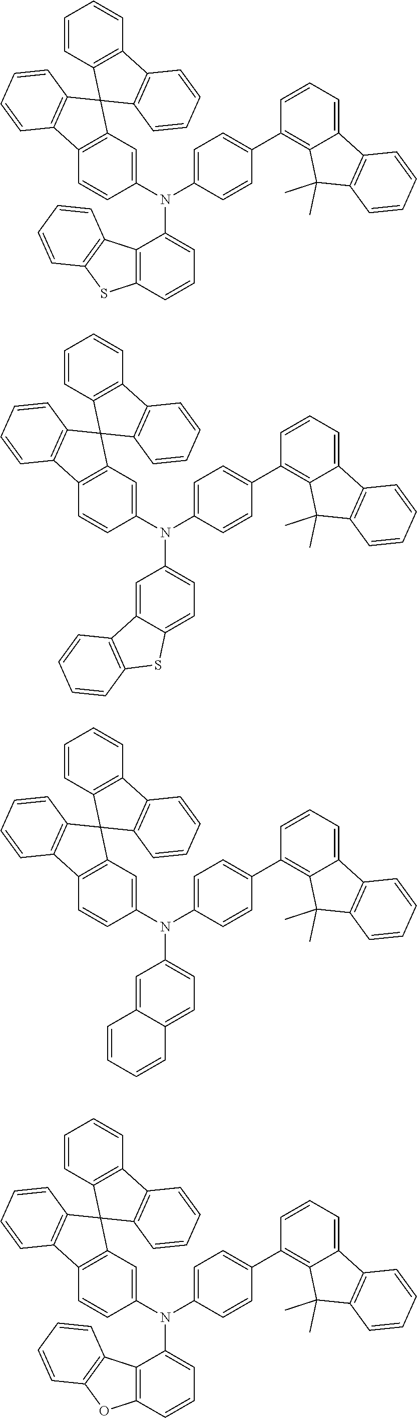

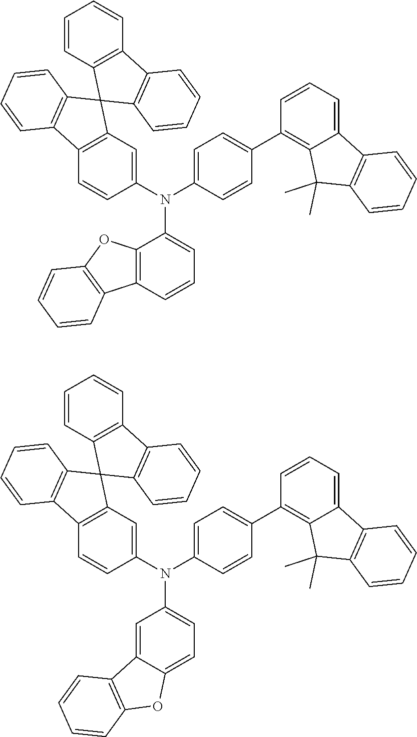 [SMILES: CC1(C)c2ccccc2-c2cccc(-c3ccc(N(c4ccc5c(c4)C4(c6ccccc6-c6ccccc64)c4ccccc4-5)c4cccc5c4oc4ccccc45)cc3)c21 ; CC1(C)c2ccccc2-c2cccc(-c3ccc(N(c4ccc5c(c4)C4(c6ccccc6-c6ccccc64)c4ccccc4-5)c4ccc5oc6ccccc6c5c4)cc3)c21]

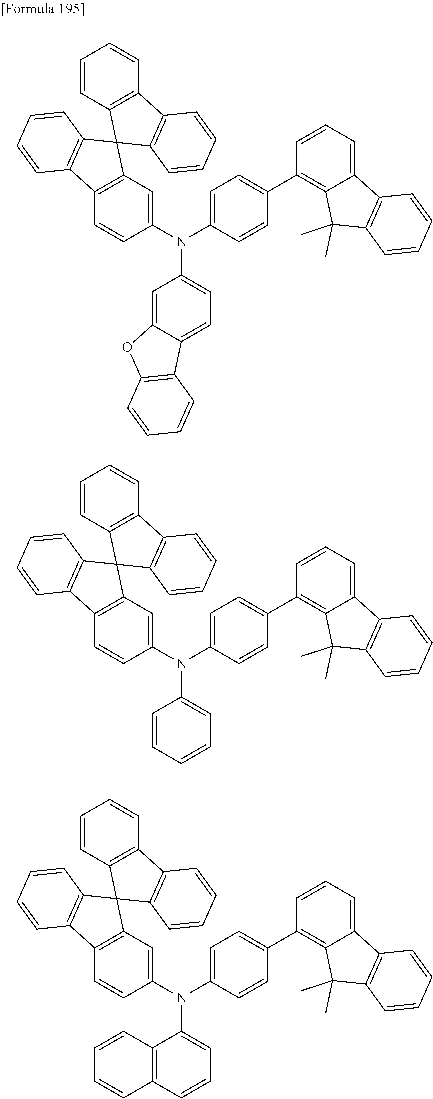 [SMILES: CC1(C)c2ccccc2-c2cccc(-c3ccc(N(c4ccc5c(c4)C4(c6ccccc6-c6ccccc64)c4ccccc4-5)c4ccc5c(c4)oc4ccccc45)cc3)c21 ; CC1(C)c2ccccc2-c2cccc(-c3ccc(N(c4ccccc4)c4ccc5c(c4)C4(c6ccccc6-c6ccccc64)c4ccccc4-5)cc3)c21 ; CC1(C)c2ccccc2-c2cccc(-c3ccc(N(c4ccc5c(c4)C4(c6ccccc6-c6ccccc64)c4ccccc4-5)c4cccc5ccccc45)cc3)c21]

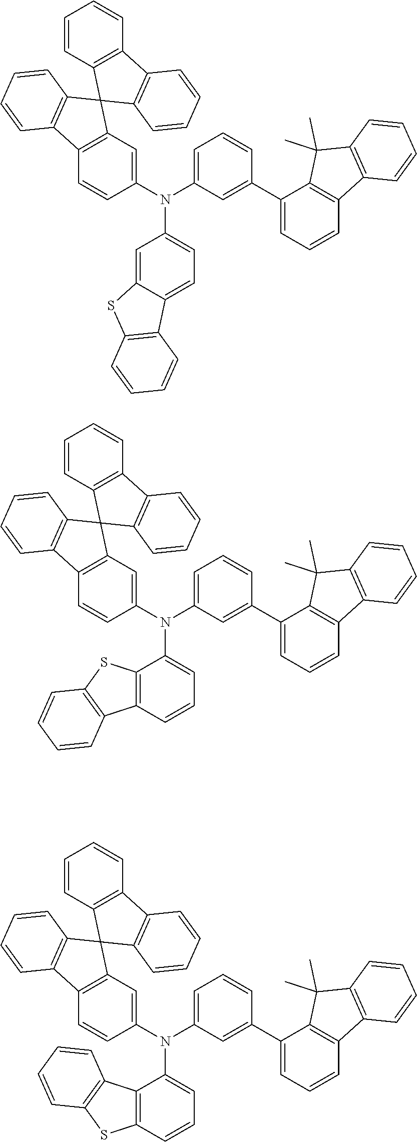 [SMILES: CC1(C)c2ccccc2-c2cccc(-c3cccc(N(c4ccc5c(c4)C4(c6ccccc6-c6ccccc64)c4ccccc4-5)c4ccc5c(c4)sc4ccccc45)c3)c21 ; CC1(C)c2ccccc2-c2cccc(-c3cccc(N(c4ccc5c(c4)C4(c6ccccc6-c6ccccc64)c4ccccc4-5)c4cccc5c4sc4ccccc45)c3)c21 ; CC1(C)c2ccccc2-c2cccc(-c3cccc(N(c4ccc5c(c4)C4(c6ccccc6-c6ccccc64)c4ccccc4-5)c4cccc5sc6ccccc6c45)c3)c21]

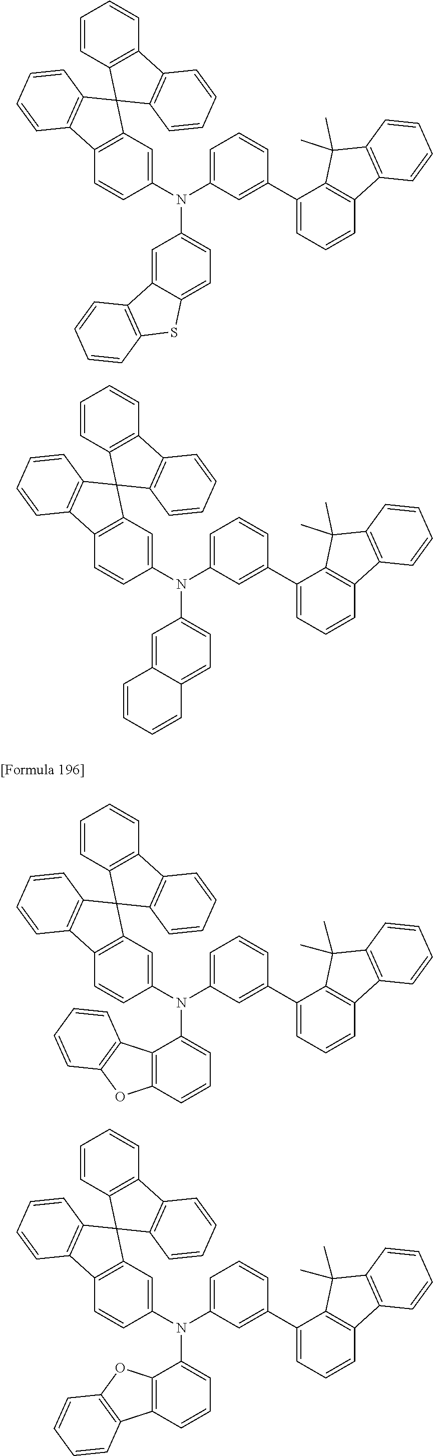

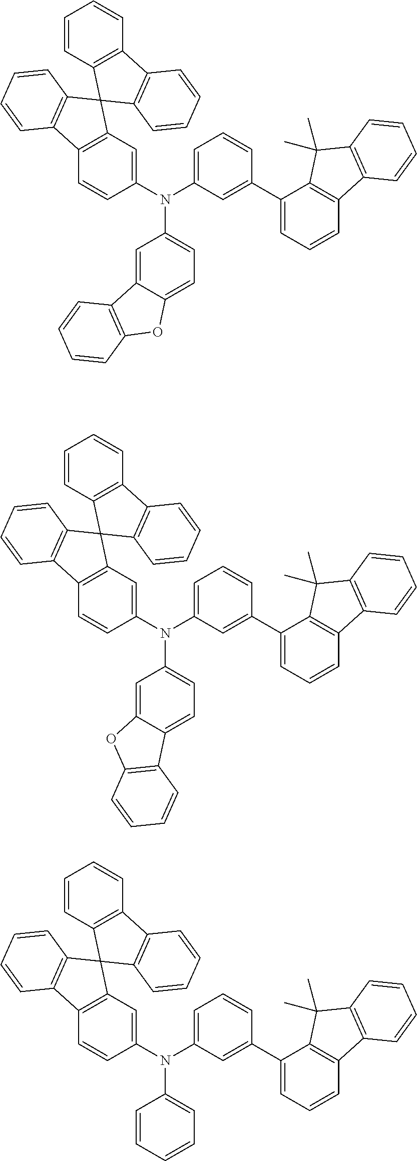 [SMILES: CC1(C)c2ccccc2-c2cccc(-c3cccc(N(c4ccc5c(c4)C4(c6ccccc6-c6ccccc64)c4ccccc4-5)c4ccc5oc6ccccc6c5c4)c3)c21 ; CC1(C)c2ccccc2-c2cccc(-c3cccc(N(c4ccc5c(c4)C4(c6ccccc6-c6ccccc64)c4ccccc4-5)c4ccc5c(c4)oc4ccccc45)c3)c21 ; CC1(C)c2ccccc2-c2cccc(-c3cccc(N(c4ccccc4)c4ccc5c(c4)C4(c6ccccc6-c6ccccc64)c4ccccc4-5)c3)c21]

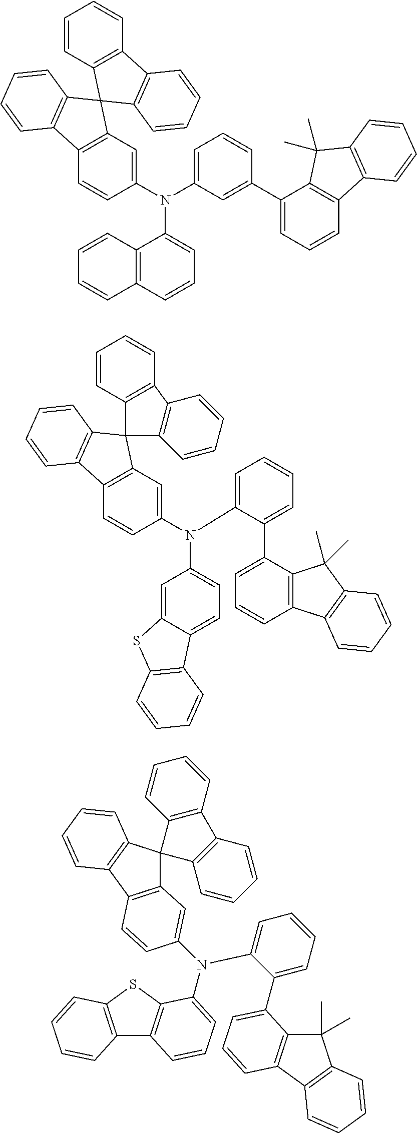

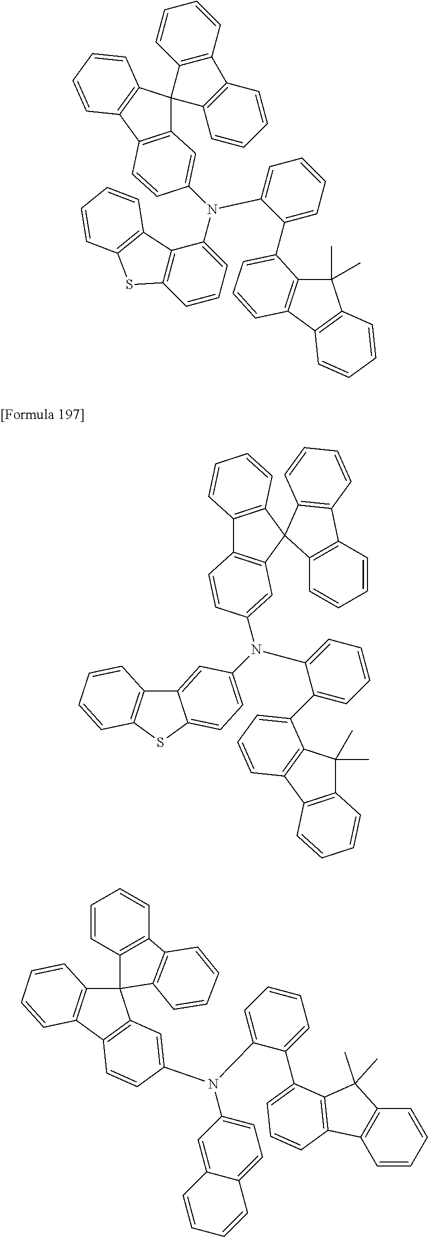 [SMILES: CC1(C)c2ccccc2-c2cccc(-c3ccccc3N(c3ccc4c(c3)C3(c5ccccc5-c5ccccc53)c3ccccc3-4)c3cccc4sc5ccccc5c34)c21 ; CC1(C)c2ccccc2-c2cccc(-c3ccccc3N(c3ccc4c(c3)C3(c5ccccc5-c5ccccc53)c3ccccc3-4)c3ccc4sc5ccccc5c4c3)c21 ; CC1(C)c2ccccc2-c2cccc(-c3ccccc3N(c3ccc4c(c3)C3(c5ccccc5-c5ccccc53)c3ccccc3-4)c3ccc4ccccc4c3)c21]

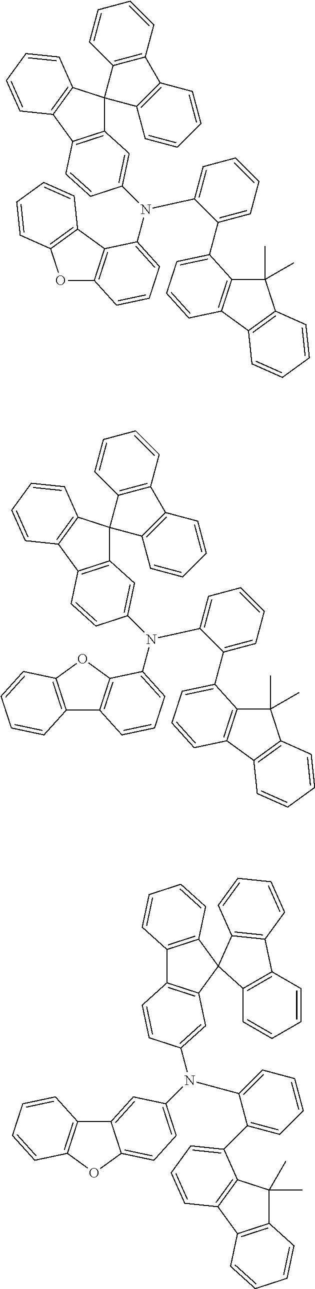 [SMILES: CC1(C)c2ccccc2-c2cccc(-c3ccccc3N(c3ccc4c(c3)C3(c5ccccc5-c5ccccc53)c3ccccc3-4)c3cccc4oc5ccccc5c34)c21 ; CC1(C)c2ccccc2-c2cccc(-c3ccccc3N(c3ccc4c(c3)C3(c5ccccc5-c5ccccc53)c3ccccc3-4)c3cccc4c3oc3ccccc34)c21 ; CC1(C)c2ccccc2-c2cccc(-c3ccccc3N(c3ccc4c(c3)C3(c5ccccc5-c5ccccc53)c3ccccc3-4)c3ccc4oc5ccccc5c4c3)c21]

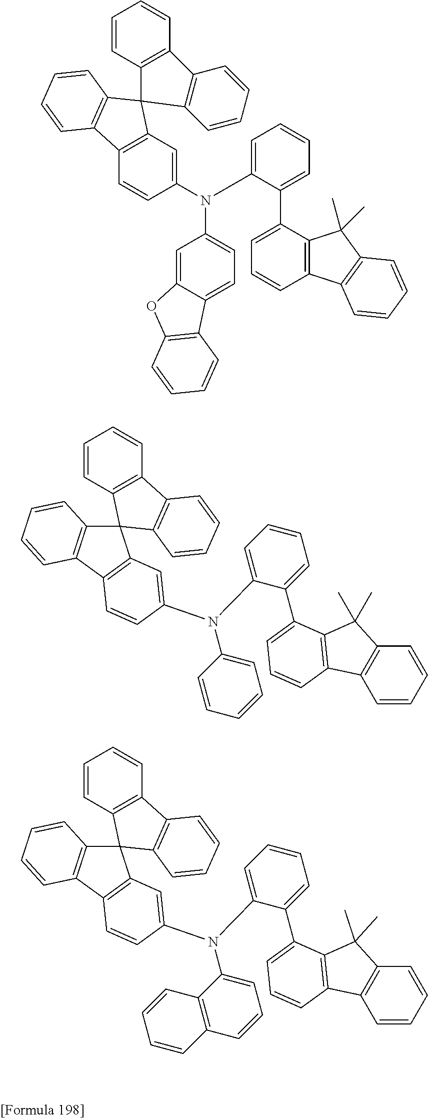 [SMILES: CC1(C)c2ccccc2-c2cccc(-c3ccccc3N(c3ccc4c(c3)C3(c5ccccc5-c5ccccc53)c3ccccc3-4)c3ccc4c(c3)oc3ccccc34)c21 ; CC1(C)c2ccccc2-c2cccc(-c3ccccc3N(c3ccccc3)c3ccc4c(c3)C3(c5ccccc5-c5ccccc53)c3ccccc3-4)c21 ; CC1(C)c2ccccc2-c2cccc(-c3ccccc3N(c3ccc4c(c3)C3(c5ccccc5-c5ccccc53)c3ccccc3-4)c3cccc4ccccc34)c21]

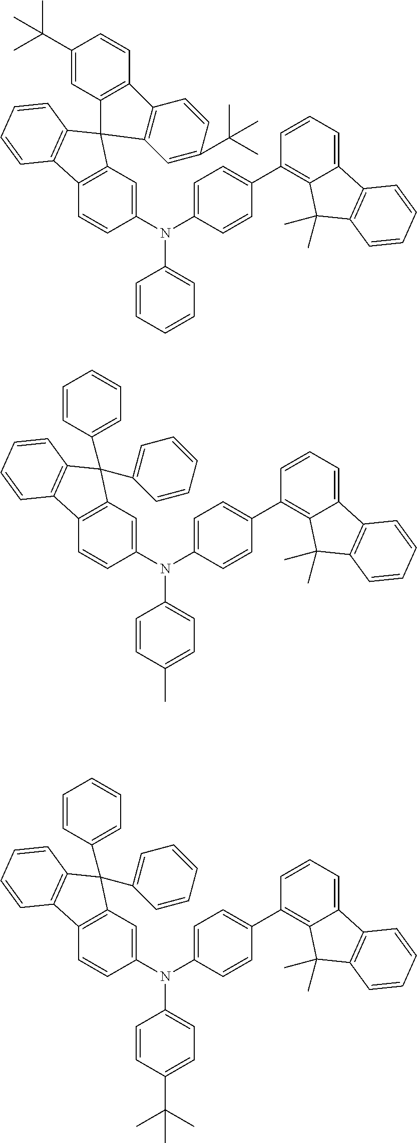 [SMILES: CC(C)(C)c1ccc2c(c1)C1(c3ccccc3-c3ccc(N(c4ccccc4)c4ccc(-c5cccc6c5C(C)(C)c5ccccc5-6)cc4)cc31)c1cc(C(C)(C)C)ccc1-2 ; Cc1ccc(N(c2ccc(-c3cccc4c3C(C)(C)c3ccccc3-4)cc2)c2ccc3c(c2)C(c2ccccc2)(c2ccccc2)c2ccccc2-3)cc1 ; CC(C)(C)c1ccc(N(c2ccc(-c3cccc4c3C(C)(C)c3ccccc3-4)cc2)c2ccc3c(c2)C(c2ccccc2)(c2ccccc2)c2ccccc2-3)cc1]

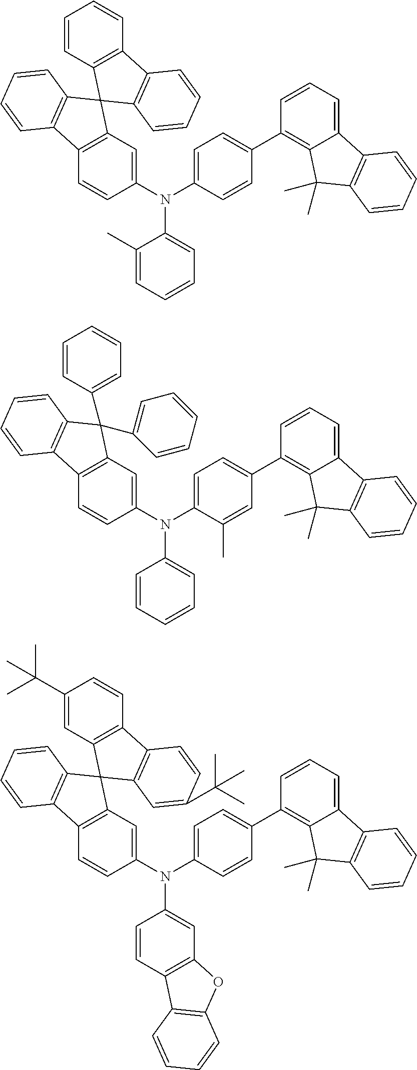 [SMILES: Cc1ccccc1N(c1ccc(-c2cccc3c2C(C)(C)c2ccccc2-3)cc1)c1ccc2c(c1)C1(c3ccccc3-c3ccccc31)c1ccccc1-2 ; Cc1cc(-c2cccc3c2C(C)(C)c2ccccc2-3)ccc1N(c1ccccc1)c1ccc2c(c1)C(c1ccccc1)(c1ccccc1)c1ccccc1-2 ; CC(C)(C)c1ccc2c(c1)C1(c3ccccc3-c3ccc(N(c4ccc(-c5cccc6c5C(C)(C)c5ccccc5-6)cc4)c4ccc5c(c4)oc4ccccc45)cc31)c1cc(C(C)(C)C)ccc1-2]

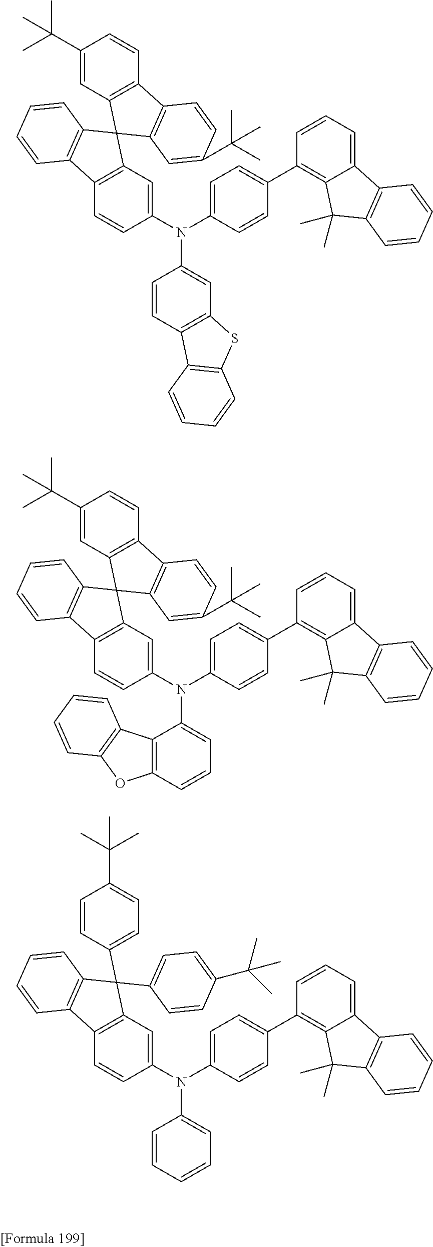

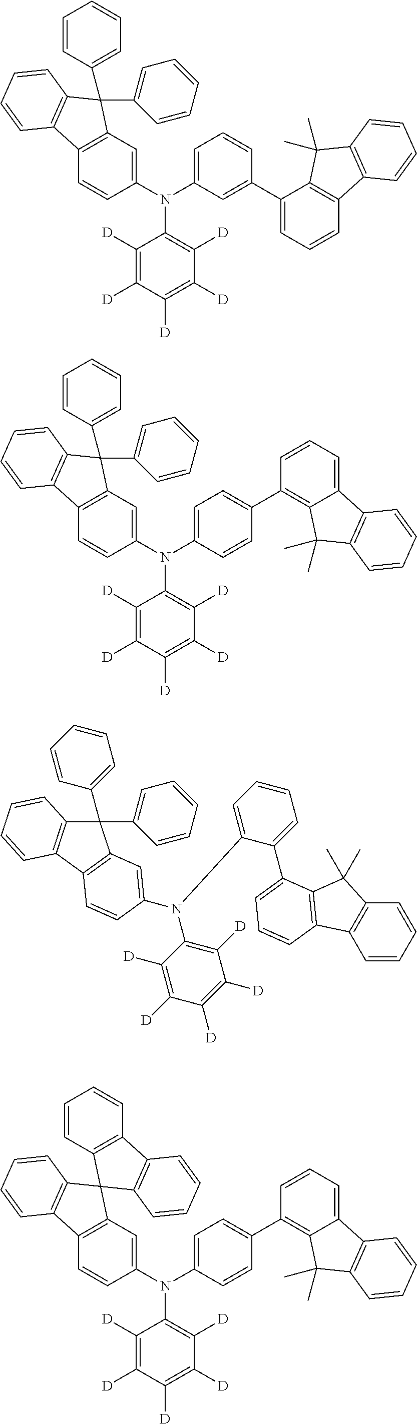 [SMILES: [2H]c1c([2H])c([2H])c(N(c2cccc(-c3cccc4c3C(C)(C)c3ccccc3-4)c2)c2ccc3c(c2)C(c2ccccc2)(c2ccccc2)c2ccccc2-3)c([2H])c1[2H] ; [2H]c1c([2H])c([2H])c(N(c2ccc(-c3cccc4c3C(C)(C)c3ccccc3-4)cc2)c2ccc3c(c2)C(c2ccccc2)(c2ccccc2)c2ccccc2-3)c([2H])c1[2H] ; [2H]c1c([2H])c([2H])c(N(c2ccc3c(c2)C(c2ccccc2)(c2ccccc2)c2ccccc2-3)c2ccccc2-c2cccc3c2C(C)(C)c2ccccc2-3)c([2H])c1[2H] ; [2H]c1c([2H])c([2H])c(N(c2ccc(-c3cccc4c3C(C)(C)c3ccccc3-4)cc2)c2ccc3c(c2)C2(c4ccccc4-c4ccccc42)c2ccccc2-3)c([2H])c1[2H]]

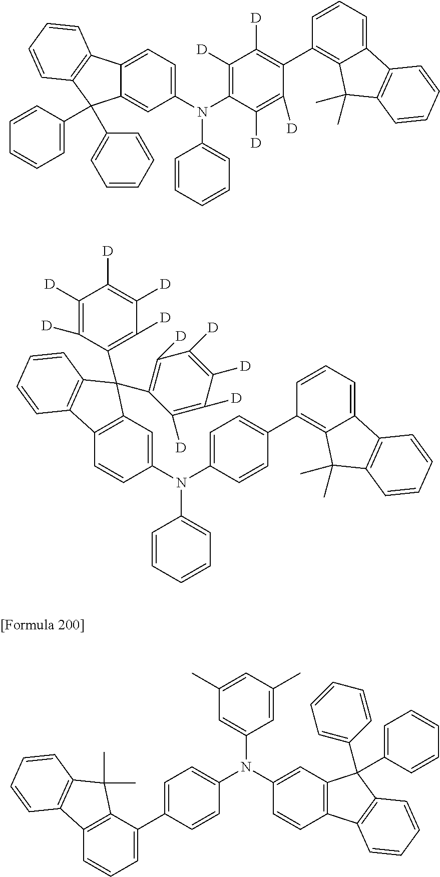 [SMILES: [2H]c1c([2H])c(N(c2ccccc2)c2ccc3c(c2)C(c2ccccc2)(c2ccccc2)c2ccccc2-3)c([2H])c([2H])c1-c1cccc2c1C(C)(C)c1ccccc1-2 ; [2H]c1c([2H])c([2H])c(C2(c3c([2H])c([2H])c([2H])c([2H])c3[2H])c3ccccc3-c3ccc(N(c4ccccc4)c4ccc(-c5cccc6c5C(C)(C)c5ccccc5-6)cc4)cc32)c([2H])c1[2H] ; Cc1cc(C)cc(N(c2ccc(-c3cccc4c3C(C)(C)c3ccccc3-4)cc2)c2ccc3c(c2)C(c2ccccc2)(c2ccccc2)c2ccccc2-3)c1]

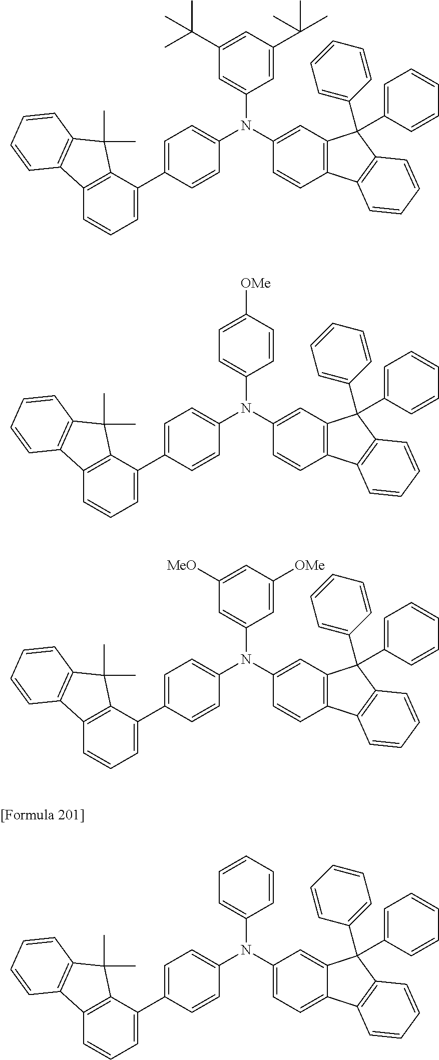 [SMILES: CC(C)(C)c1cc(N(c2ccc(-c3cccc4c3C(C)(C)c3ccccc3-4)cc2)c2ccc3c(c2)C(c2ccccc2)(c2ccccc2)c2ccccc2-3)cc(C(C)(C)C)c1 ; COc1ccc(N(c2ccc(-c3cccc4c3C(C)(C)c3ccccc3-4)cc2)c2ccc3c(c2)C(c2ccccc2)(c2ccccc2)c2ccccc2-3)cc1 ; COc1cc(OC)cc(N(c2ccc(-c3cccc4c3C(C)(C)c3ccccc3-4)cc2)c2ccc3c(c2)C(c2ccccc2)(c2ccccc2)c2ccccc2-3)c1 ; CC1(C)c2ccccc2-c2cccc(-c3ccc(N(c4ccccc4)c4ccc5c(c4)C(c4ccccc4)(c4ccccc4)c4ccccc4-5)cc3)c21]

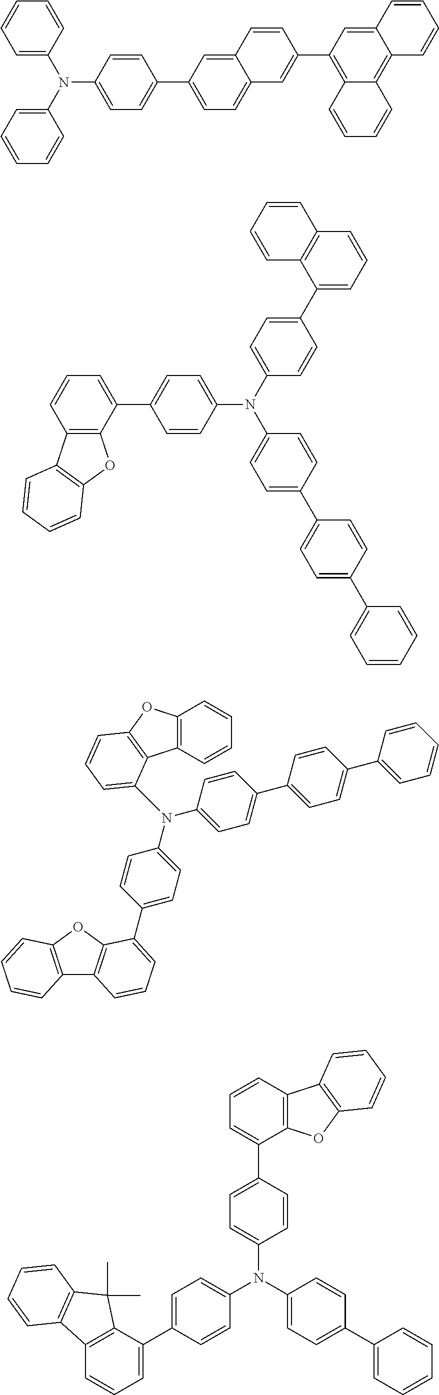 [SMILES: c1ccc(N(c2ccccc2)c2ccc(-c3ccc4cc(-c5cc6ccccc6c6ccccc56)ccc4c3)cc2)cc1 ; c1ccc(-c2ccc(-c3ccc(N(c4ccc(-c5cccc6ccccc56)cc4)c4ccc(-c5cccc6c5oc5ccccc56)cc4)cc3)cc2)cc1 ; c1ccc(-c2ccc(-c3ccc(N(c4ccc(-c5cccc6c5oc5ccccc56)cc4)c4cccc5oc6ccccc6c45)cc3)cc2)cc1 ; CC1(C)c2ccccc2-c2cccc(-c3ccc(N(c4ccc(-c5ccccc5)cc4)c4ccc(-c5cccc6c5oc5ccccc56)cc4)cc3)c21]

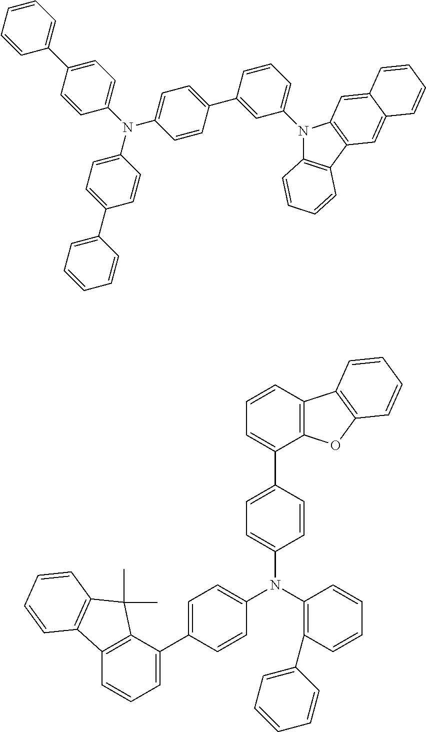 [SMILES: c1ccc(-c2ccc(N(c3ccc(-c4ccccc4)cc3)c3ccc(-c4cccc(-n5c6ccccc6c6cc7ccccc7cc65)c4)cc3)cc2)cc1 ; CC1(C)c2ccccc2-c2cccc(-c3ccc(N(c4ccc(-c5cccc6c5oc5ccccc56)cc4)c4ccccc4-c4ccccc4)cc3)c21]

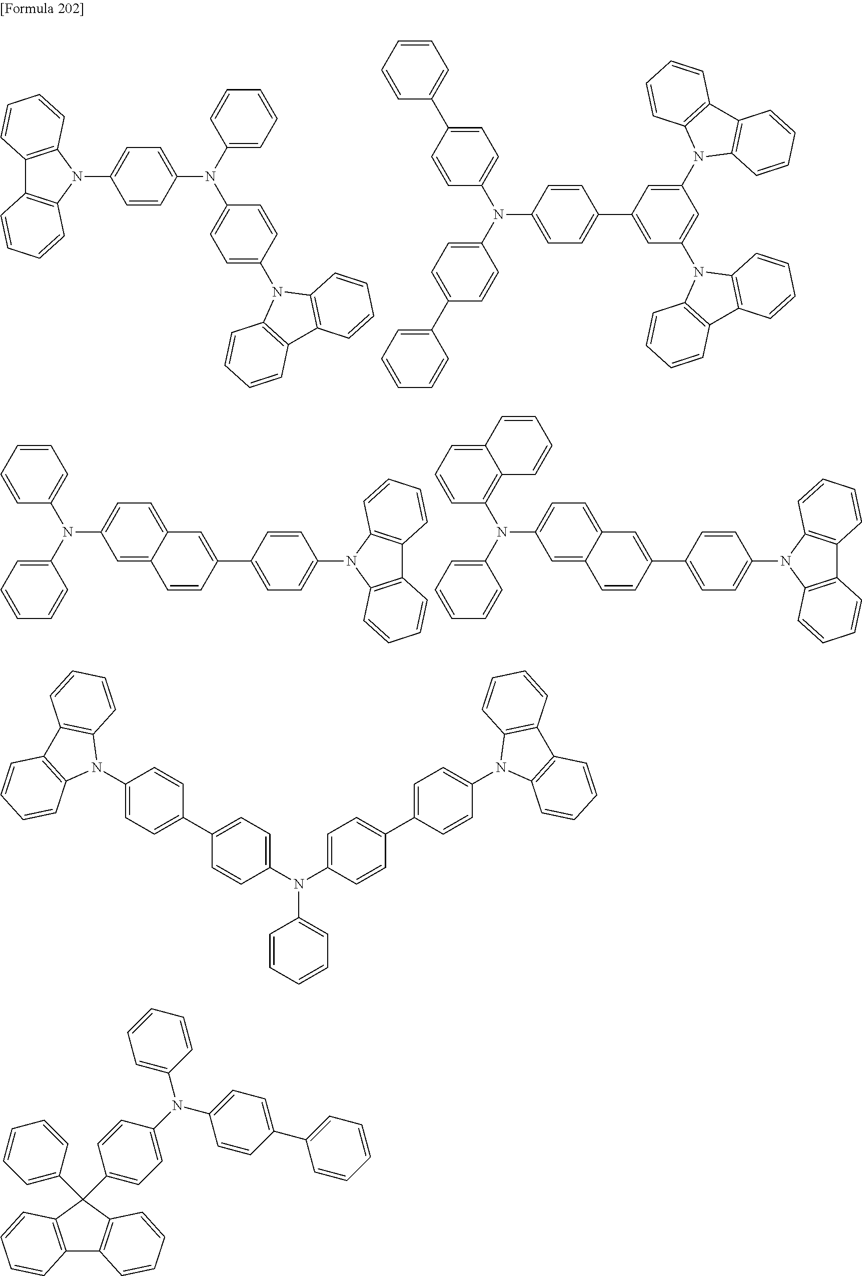

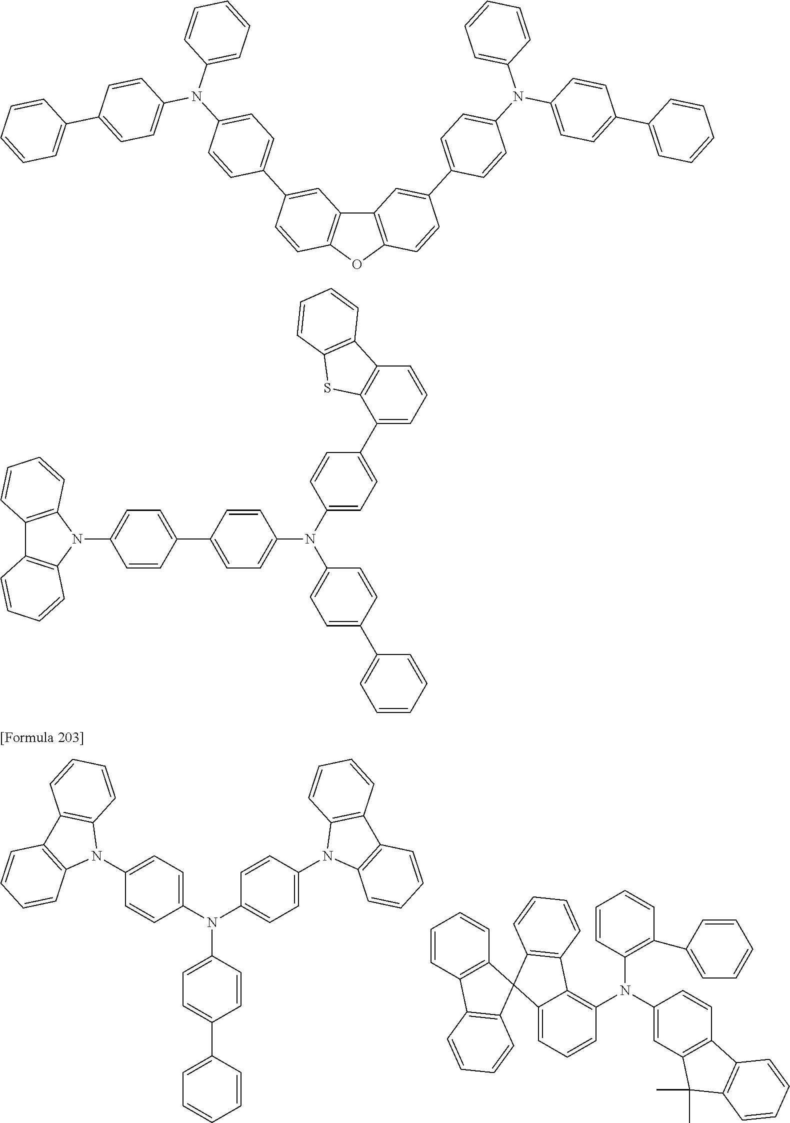

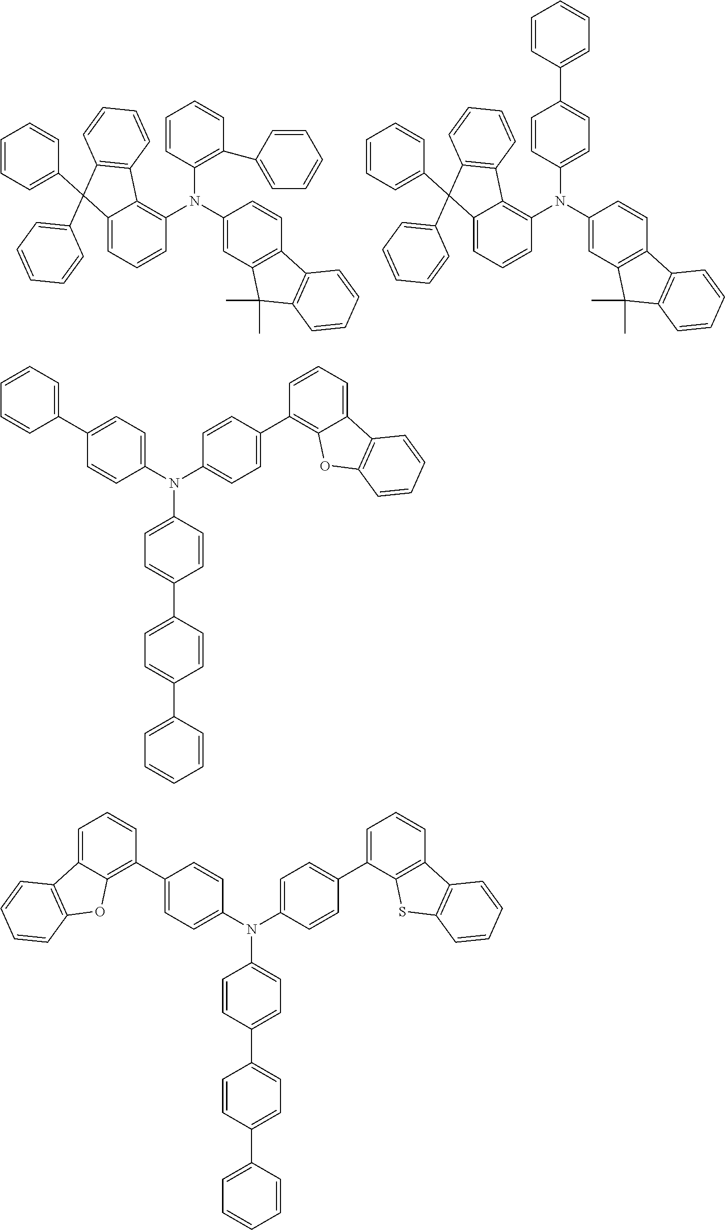

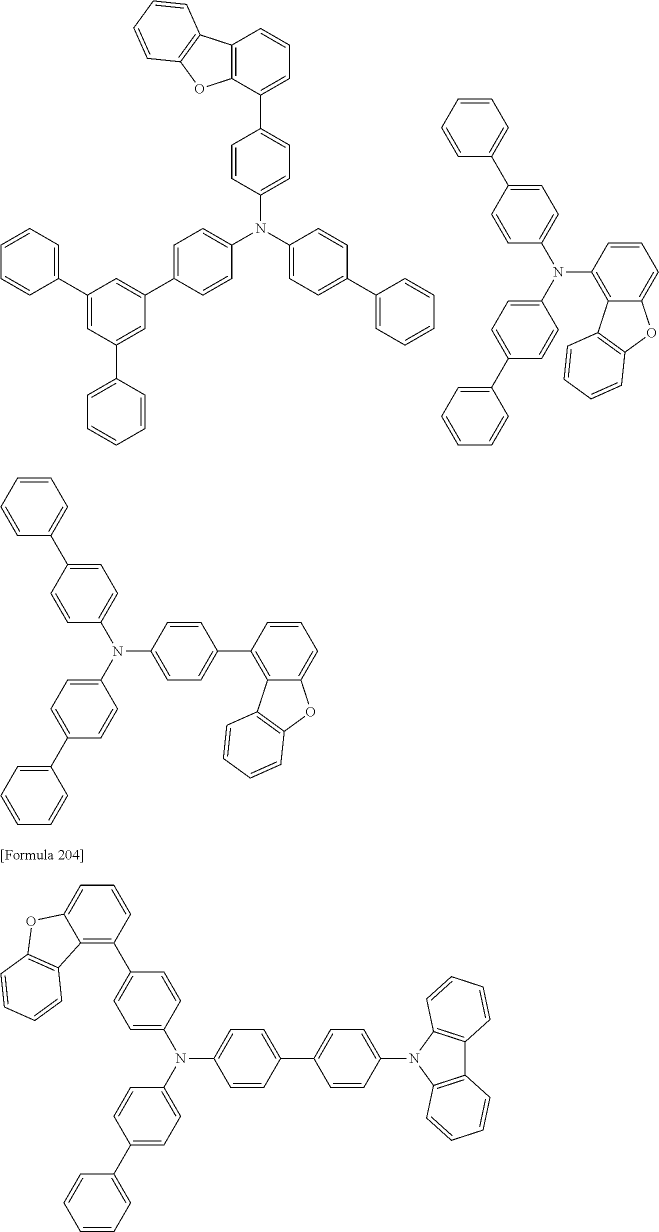 [SMILES: c1ccc(-c2ccc(N(c3ccc(-c4cc(-c5ccccc5)cc(-c5ccccc5)c4)cc3)c3ccc(-c4cccc5c4oc4ccccc45)cc3)cc2)cc1 ; c1ccc(-c2ccc(N(c3ccc(-c4ccccc4)cc3)c3cccc4oc5ccccc5c34)cc2)cc1 ; c1ccc(-c2ccc(N(c3ccc(-c4ccccc4)cc3)c3ccc(-c4cccc5oc6ccccc6c45)cc3)cc2)cc1 ; c1ccc(-c2ccc(N(c3ccc(-c4ccc(-n5c6ccccc6c6ccccc65)cc4)cc3)c3ccc(-c4cccc5oc6ccccc6c45)cc3)cc2)cc1]

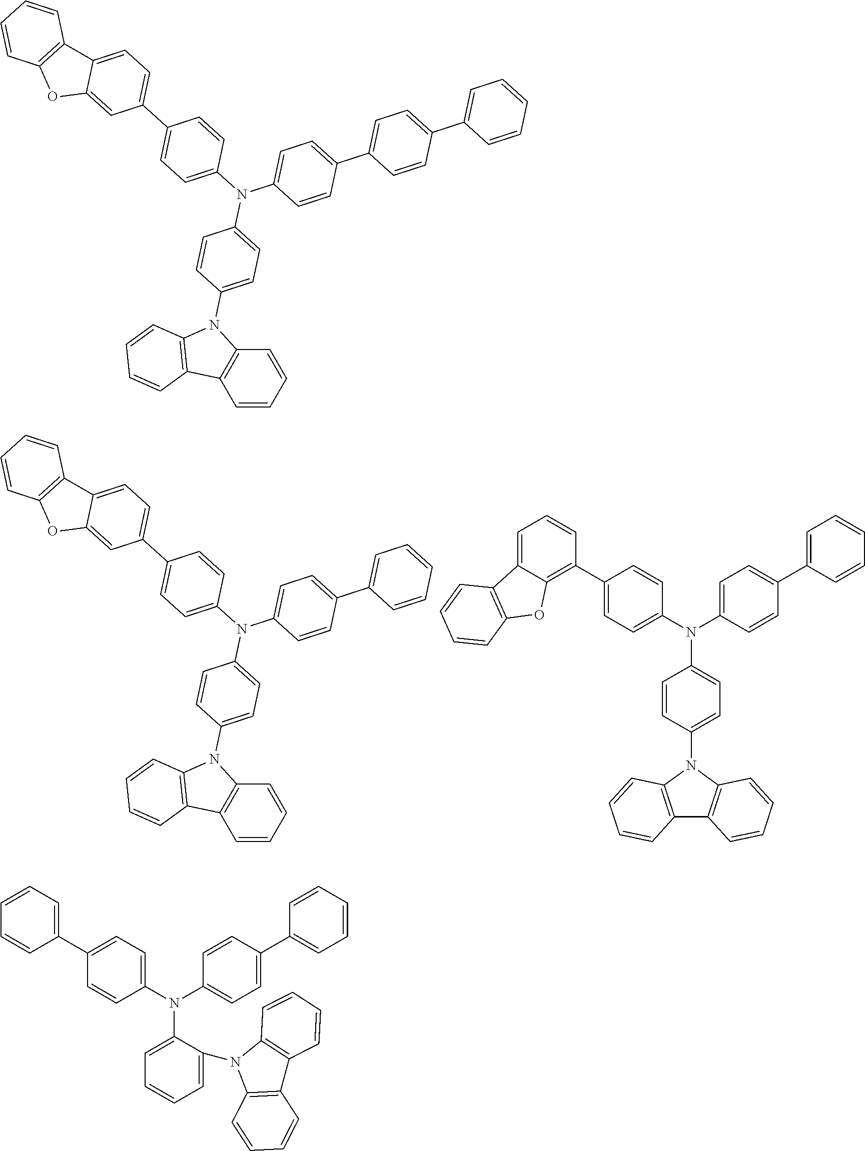

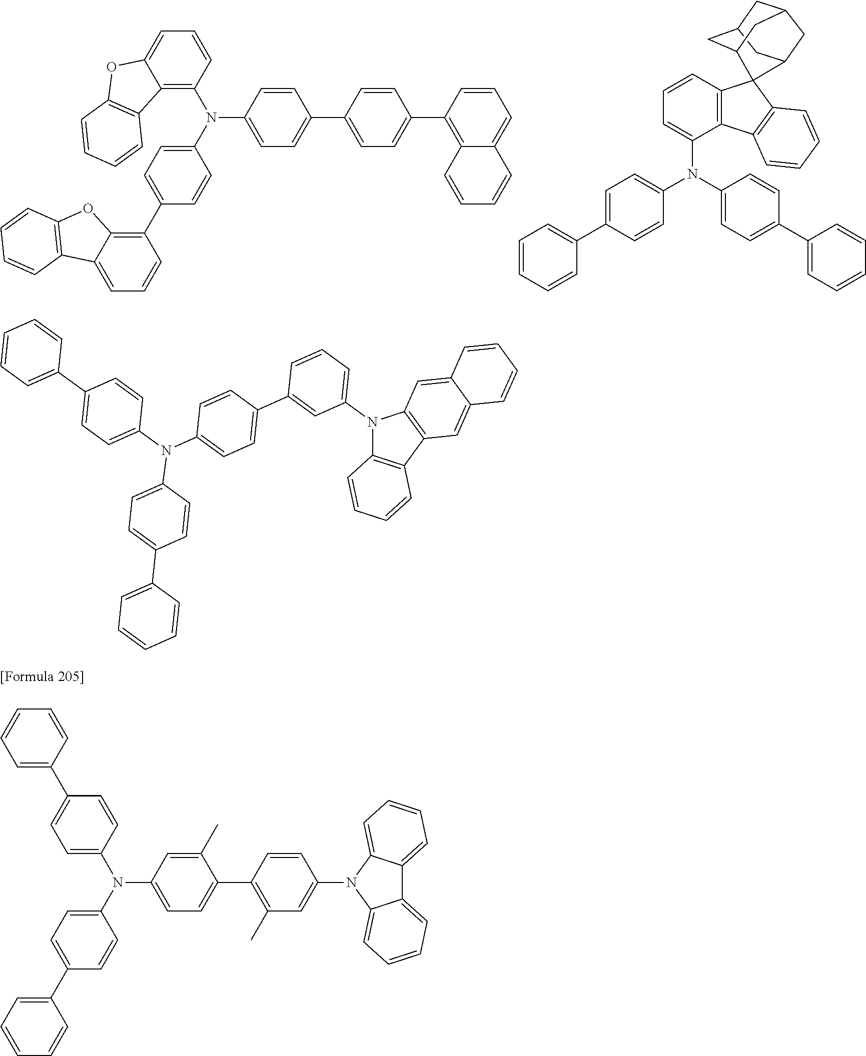

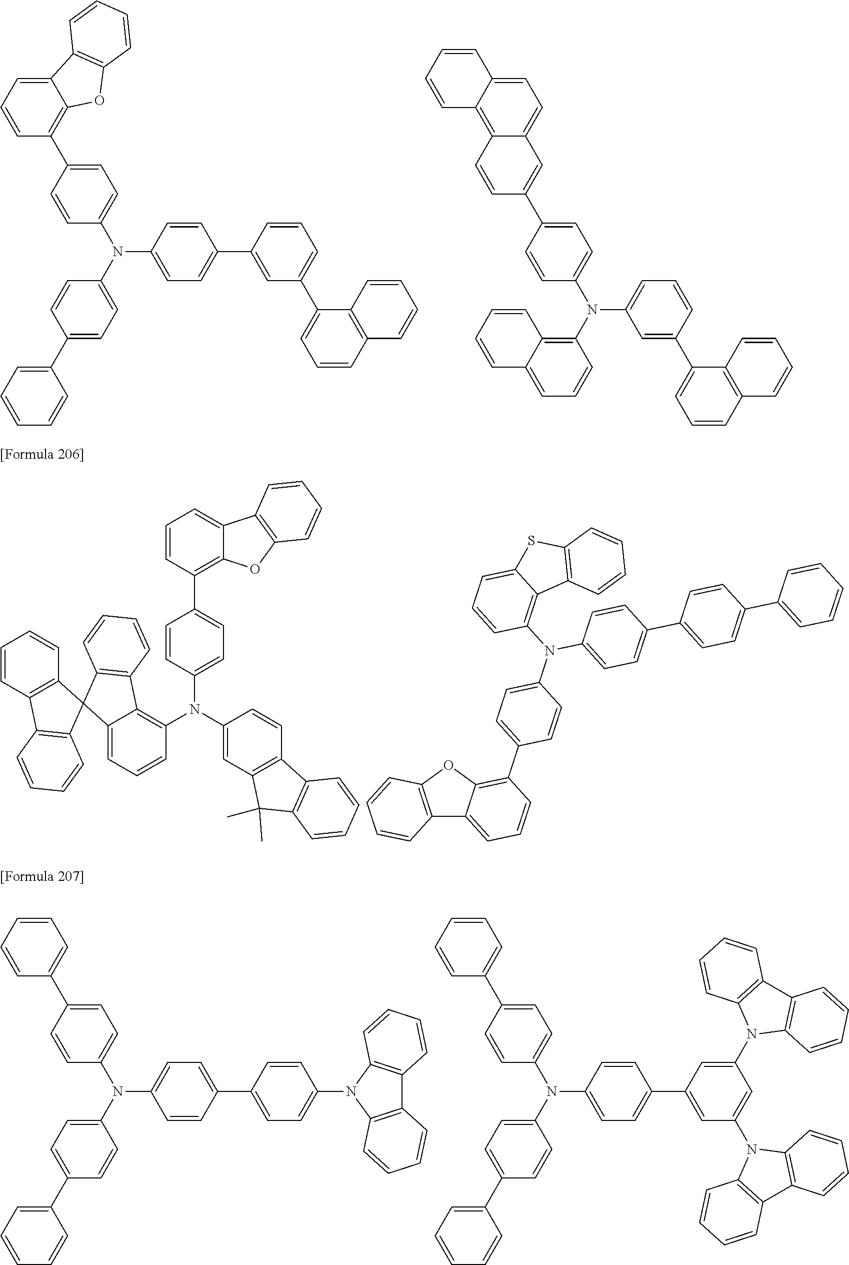

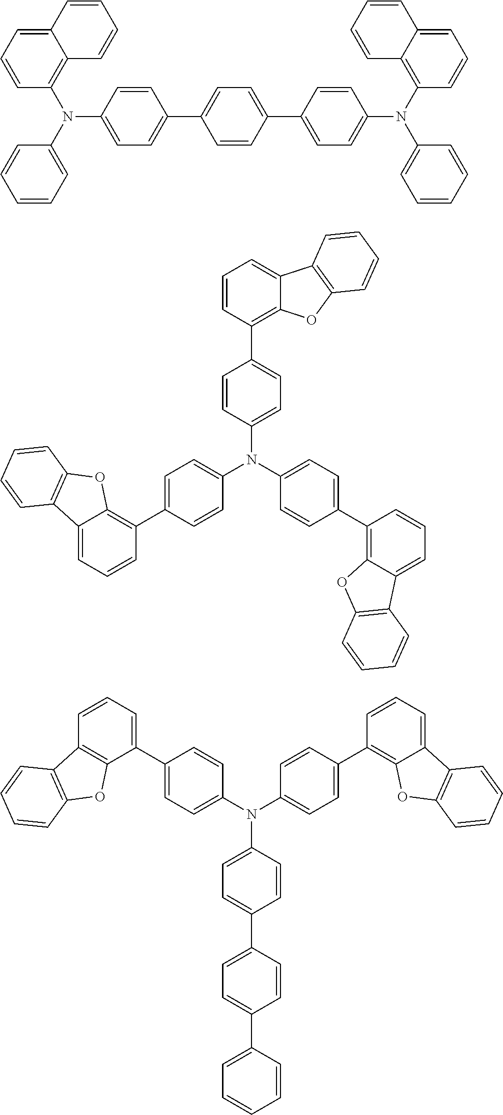

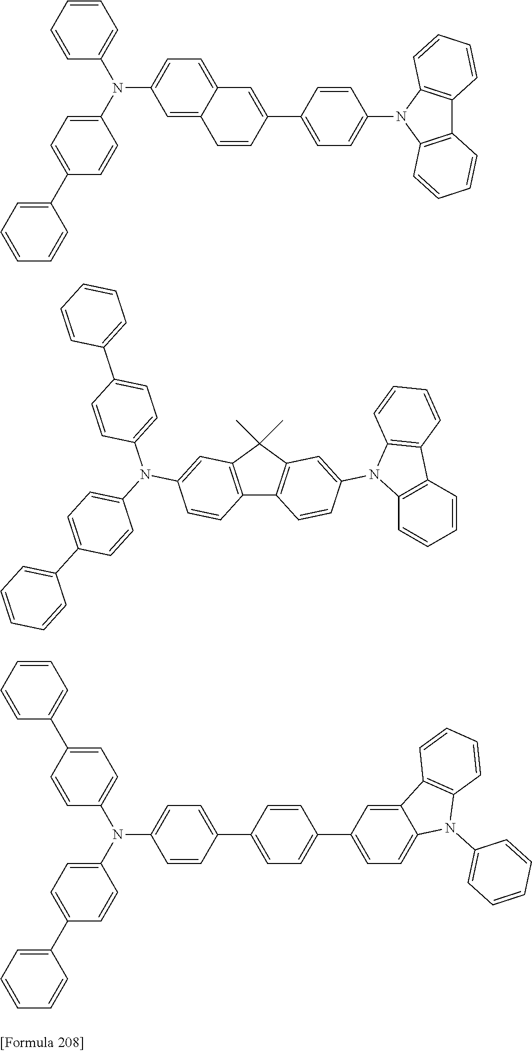

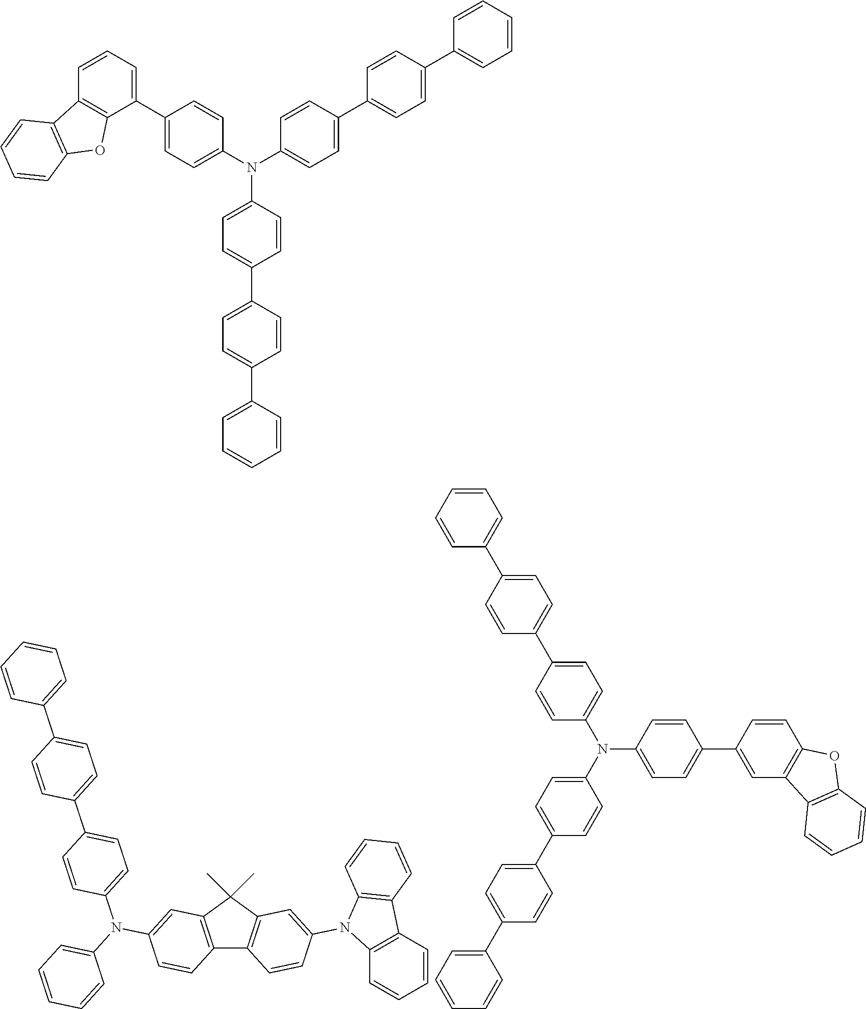

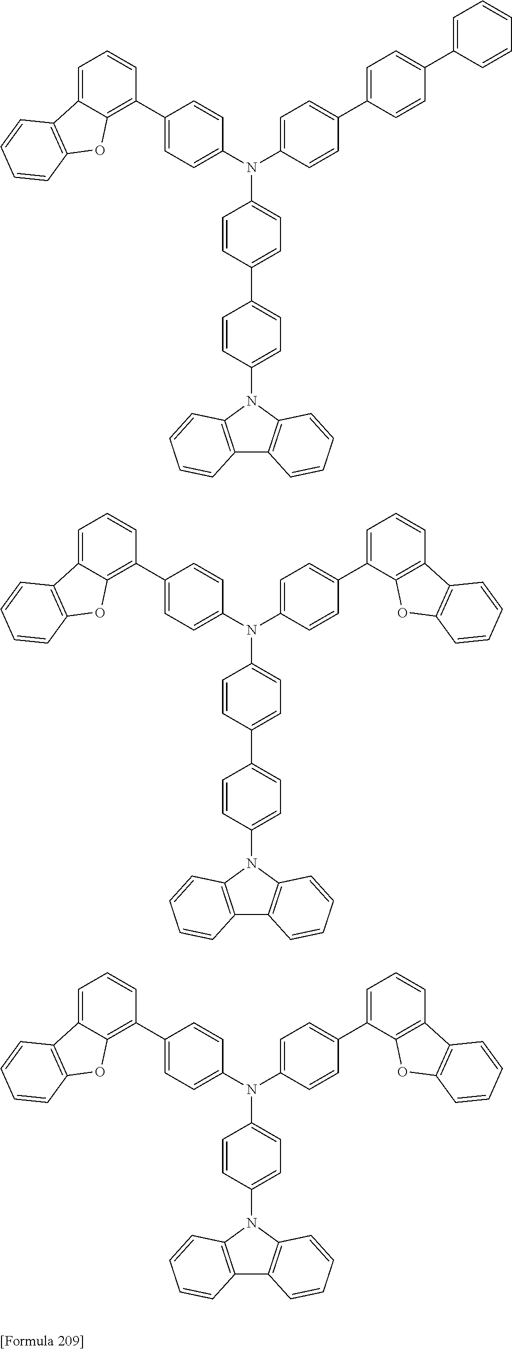 [SMILES: c1ccc(-c2ccc(-c3ccc(N(c4ccc(-c5ccc(-n6c7ccccc7c7ccccc76)cc5)cc4)c4ccc(-c5cccc6c5oc5ccccc56)cc4)cc3)cc2)cc1 ; c1ccc2c(c1)oc1c(-c3ccc(N(c4ccc(-c5ccc(-n6c7ccccc7c7ccccc76)cc5)cc4)c4ccc(-c5cccc6c5oc5ccccc56)cc4)cc3)cccc12 ; c1ccc2c(c1)oc1c(-c3ccc(N(c4ccc(-c5cccc6c5oc5ccccc56)cc4)c4ccc(-n5c6ccccc6c6ccccc65)cc4)cc3)cccc12]

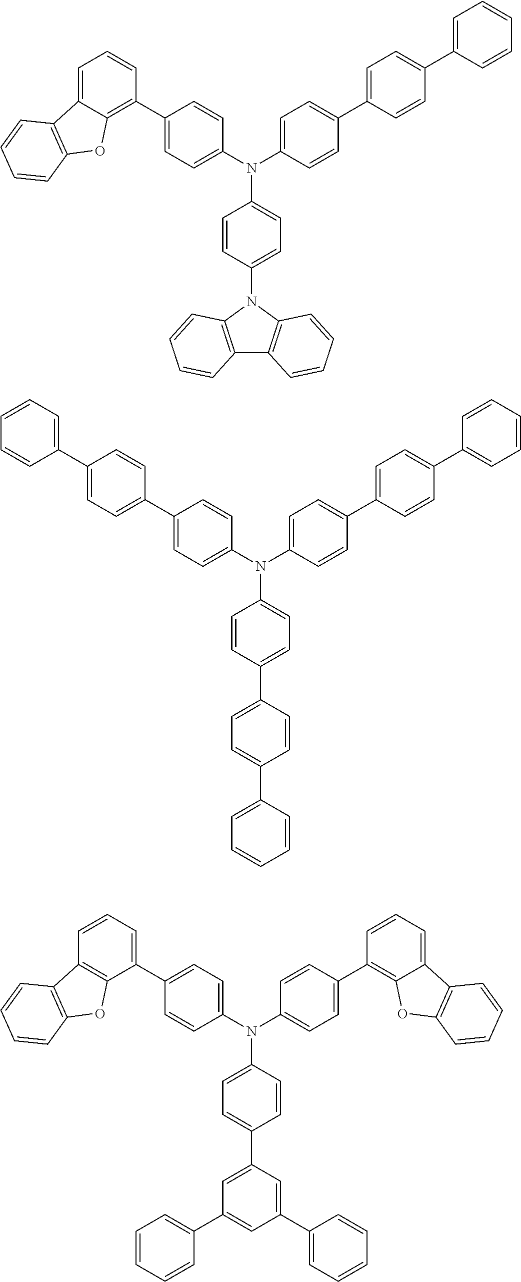 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

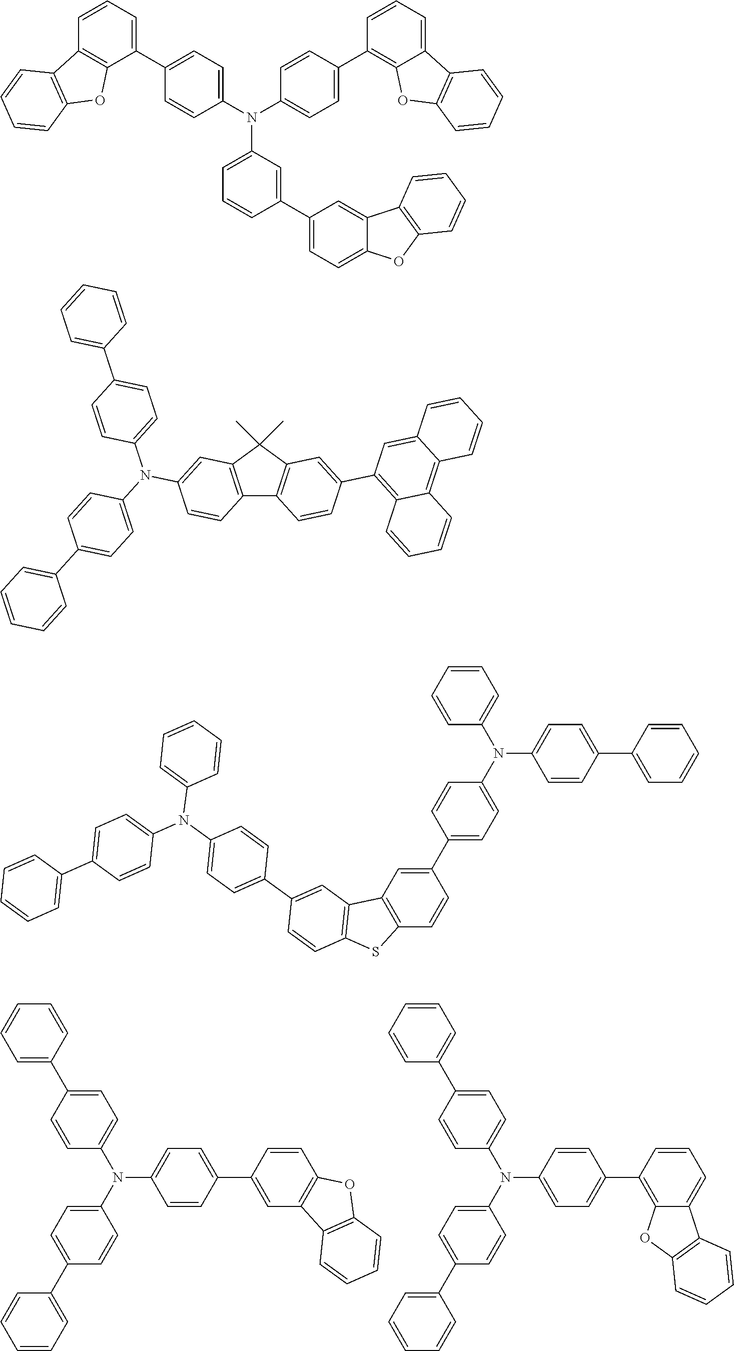

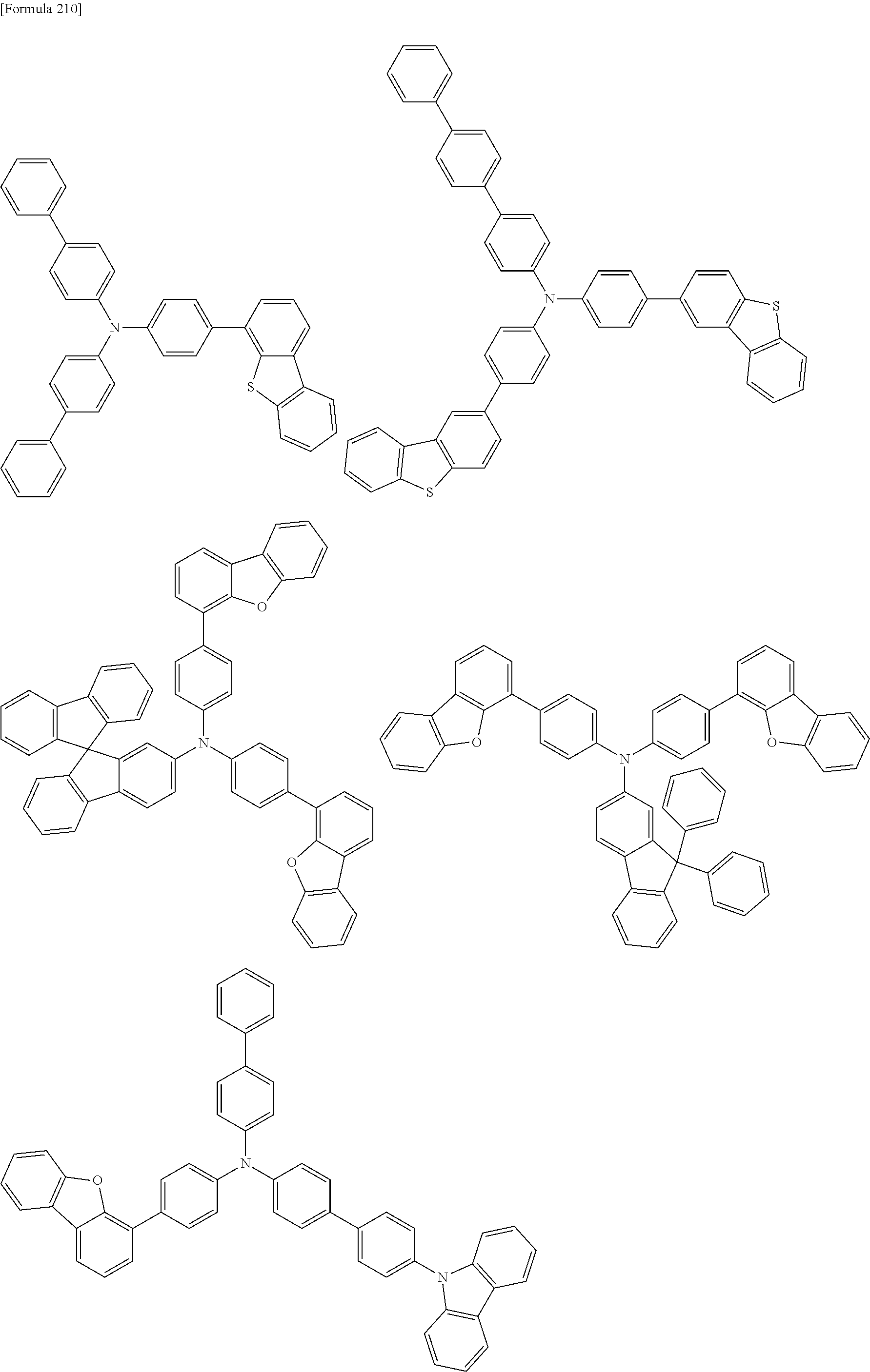

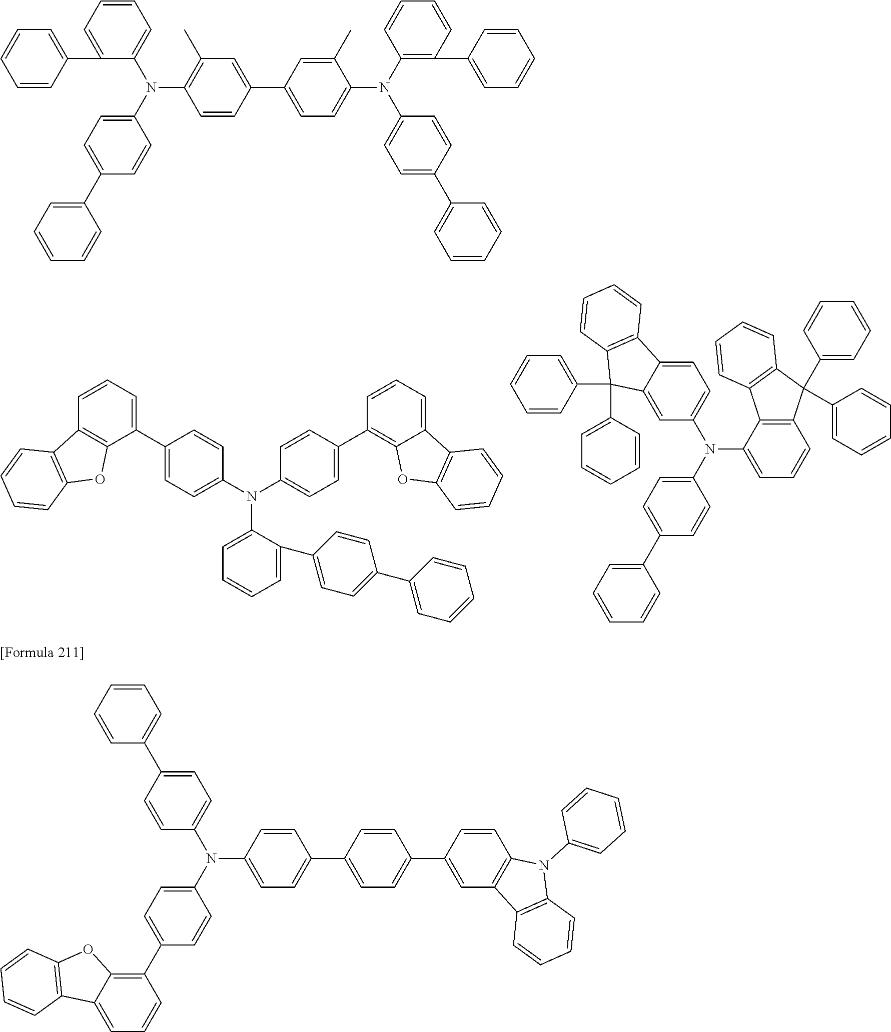 [SMILES: Cc1cc(-c2ccc(N(c3ccc(-c4ccccc4)cc3)c3ccccc3-c3ccccc3)c(C)c2)ccc1N(c1ccc(-c2ccccc2)cc1)c1ccccc1-c1ccccc1 ; c1ccc(-c2ccc(-c3ccccc3N(c3ccc(-c4cccc5c4oc4ccccc45)cc3)c3ccc(-c4cccc5c4oc4ccccc45)cc3)cc2)cc1 ; c1ccc(-c2ccc(N(c3ccc4c(c3)C(c3ccccc3)(c3ccccc3)c3ccccc3-4)c3cccc4c3-c3ccccc3C4(c3ccccc3)c3ccccc3)cc2)cc1 ; c1ccc(-c2ccc(N(c3ccc(-c4ccc(-c5ccc6c(c5)c5ccccc5n6-c5ccccc5)cc4)cc3)c3ccc(-c4cccc5c4oc4ccccc45)cc3)cc2)cc1]

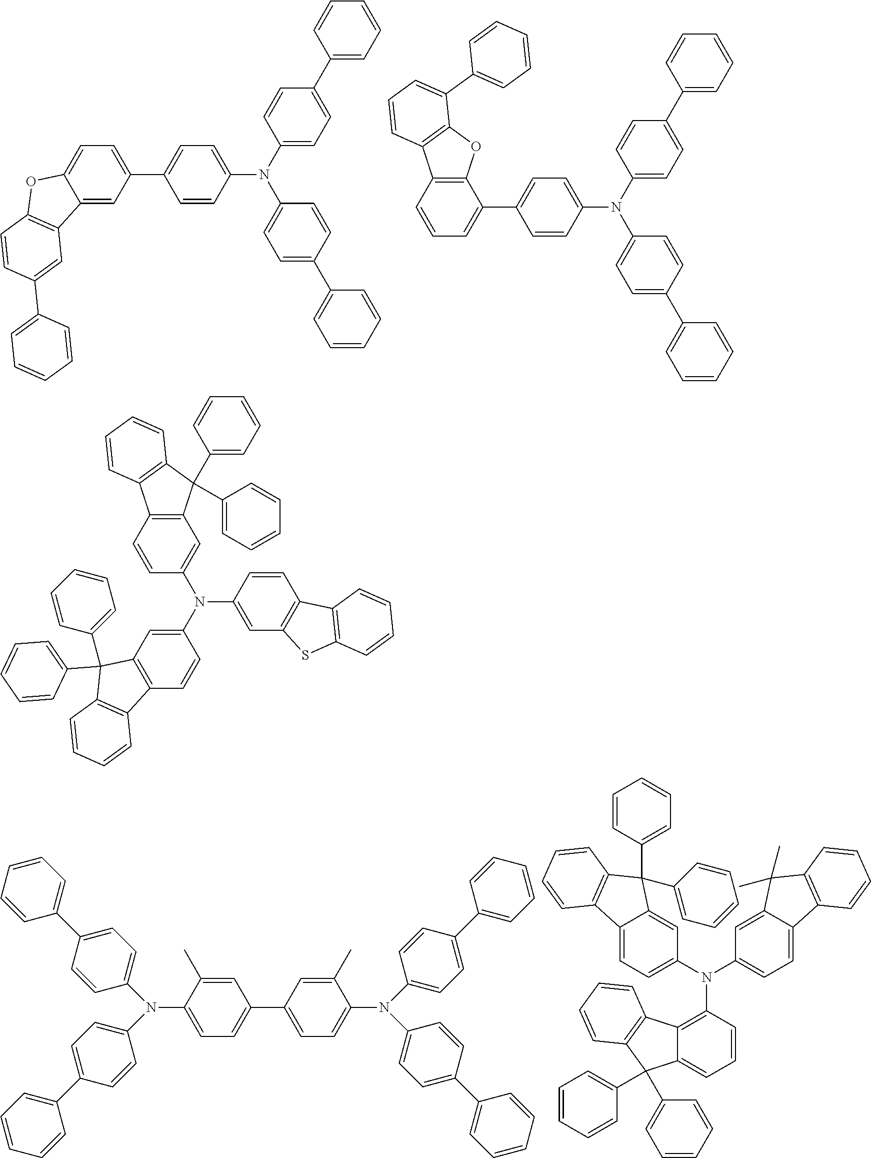

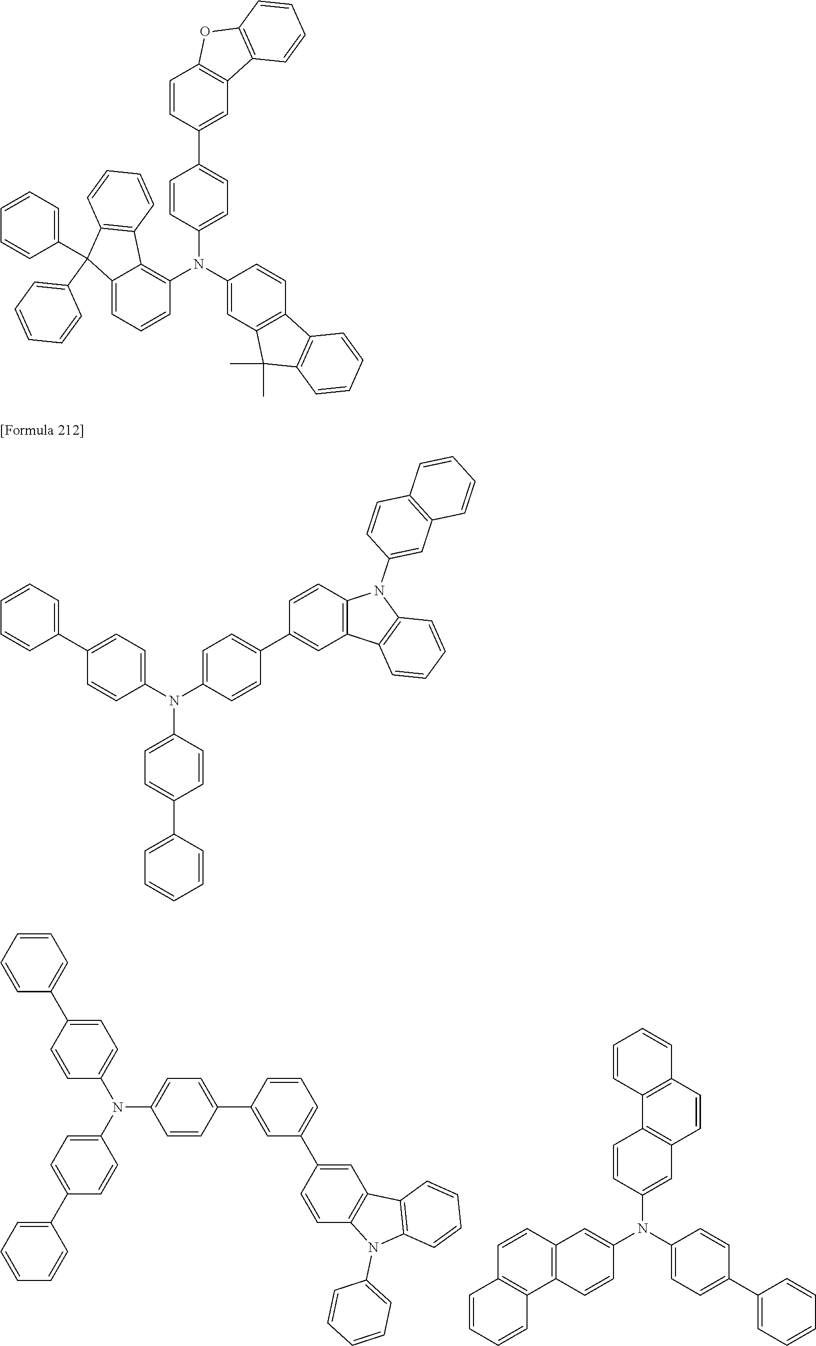

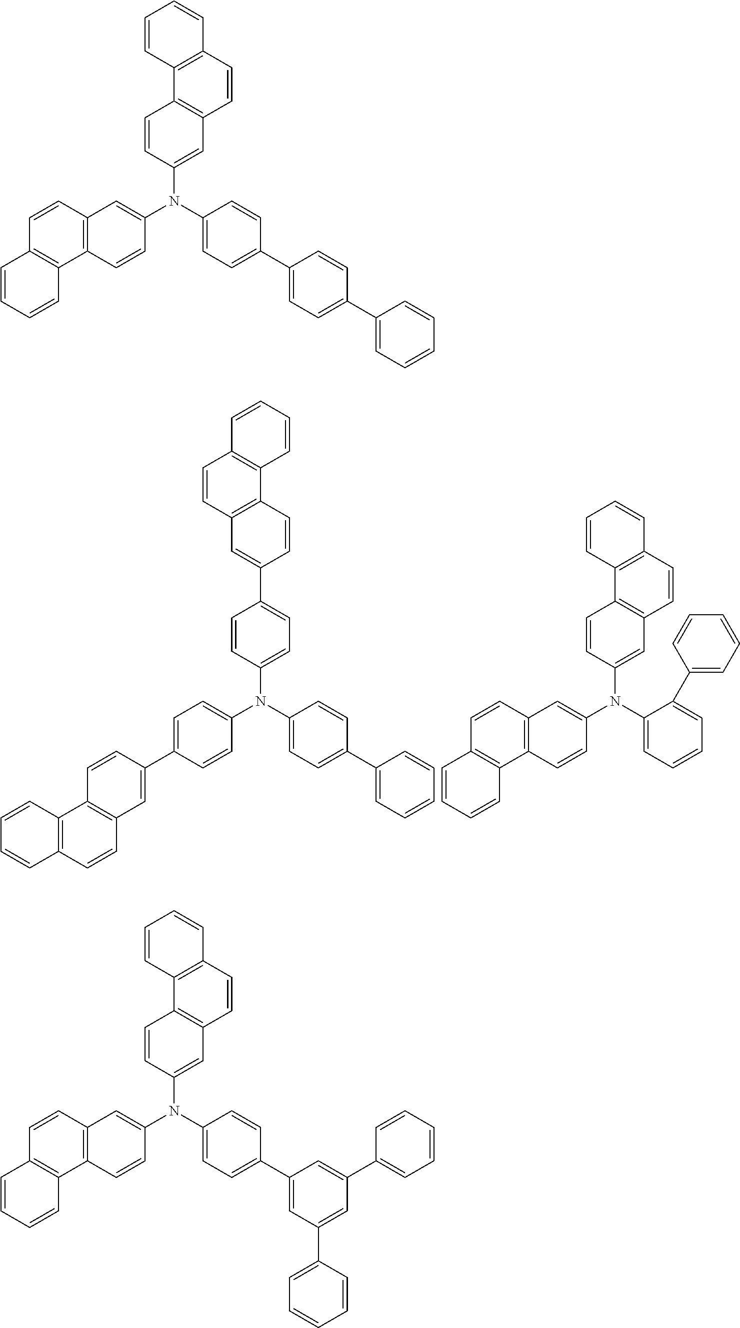

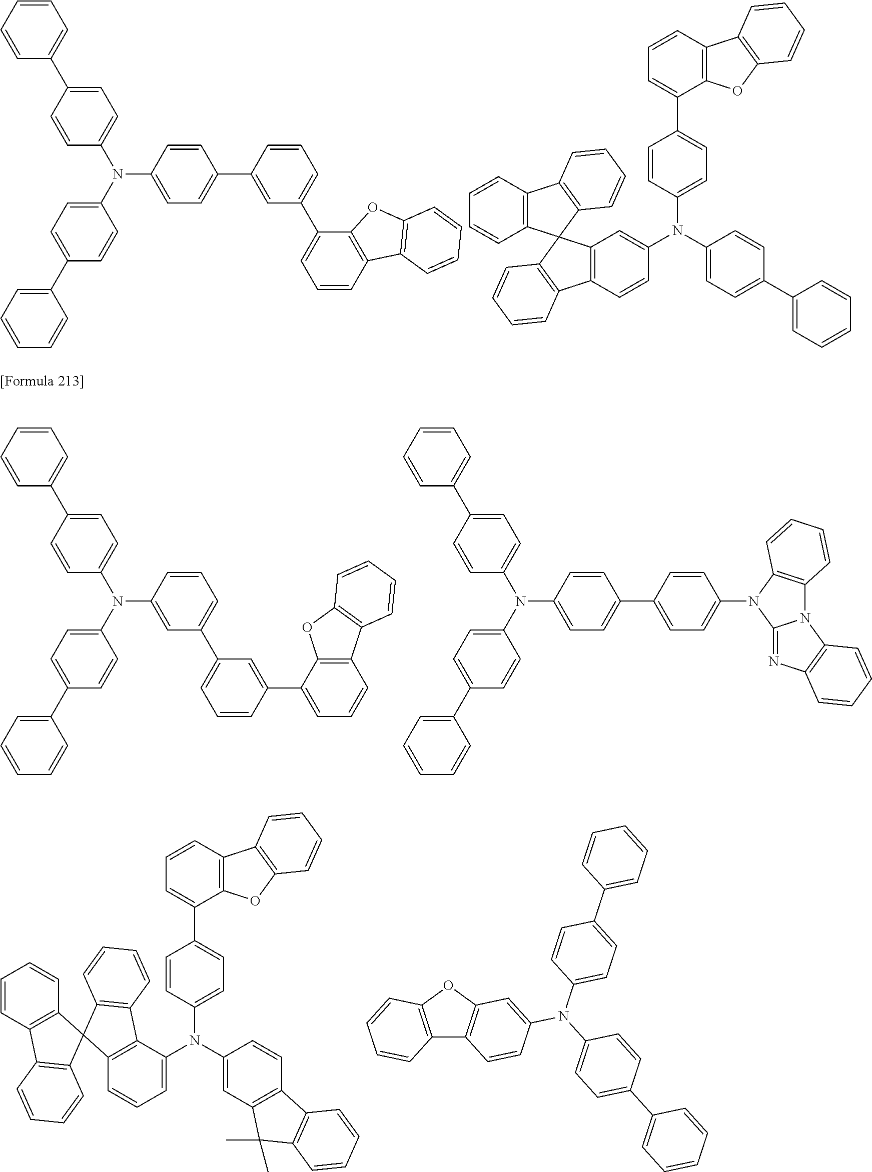

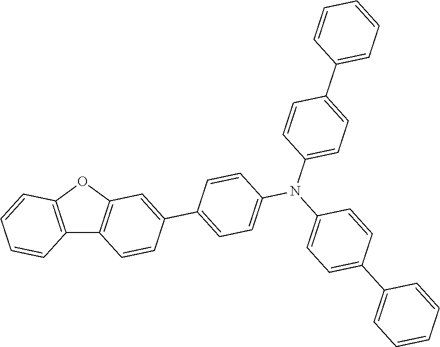 [SMILES: c1ccc(-c2ccc(N(c3ccc(-c4ccccc4)cc3)c3ccc(-c4ccc5c(c4)oc4ccccc45)cc3)cc2)cc1]

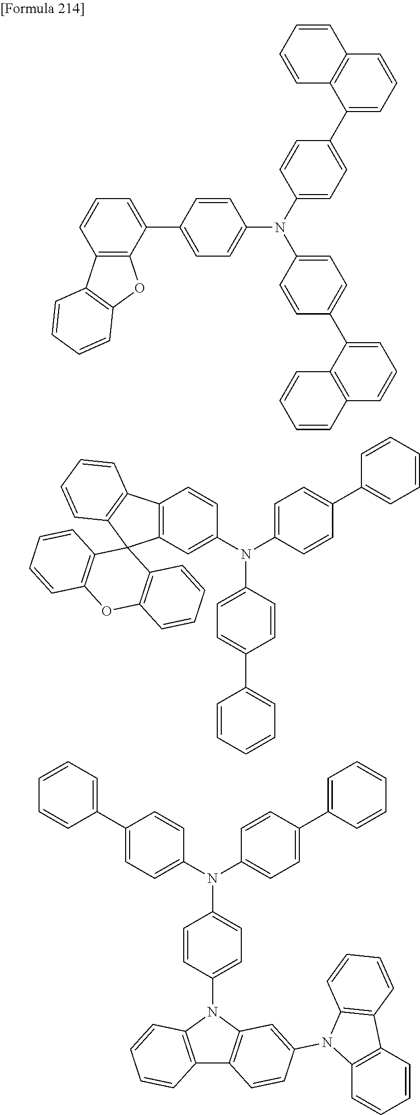

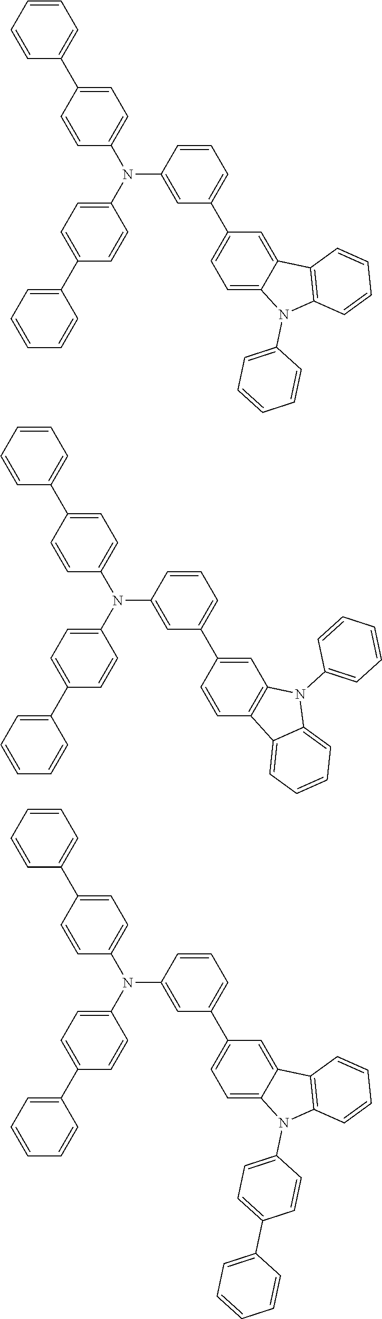

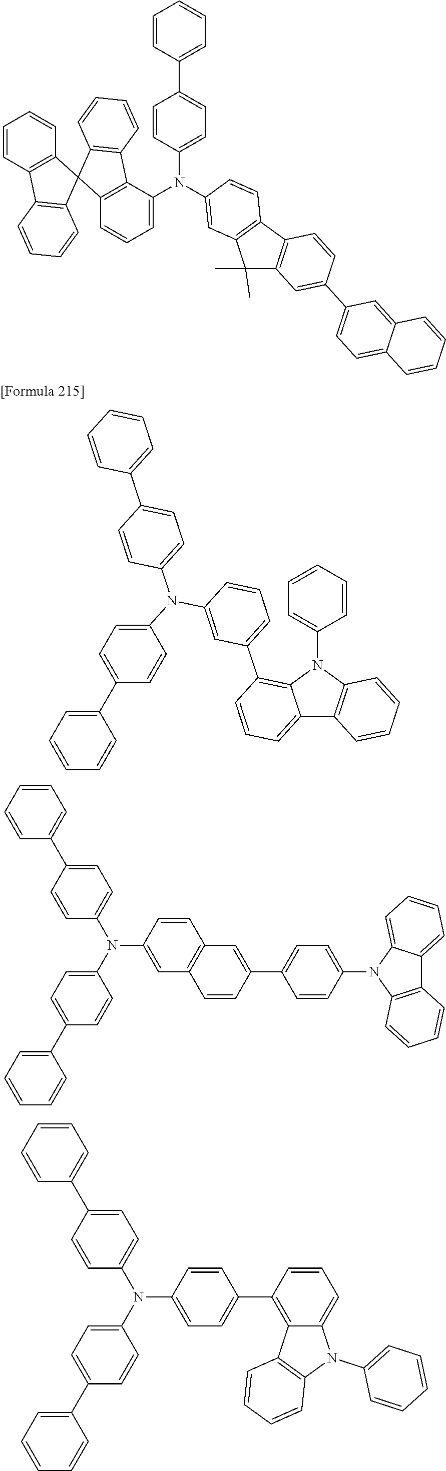

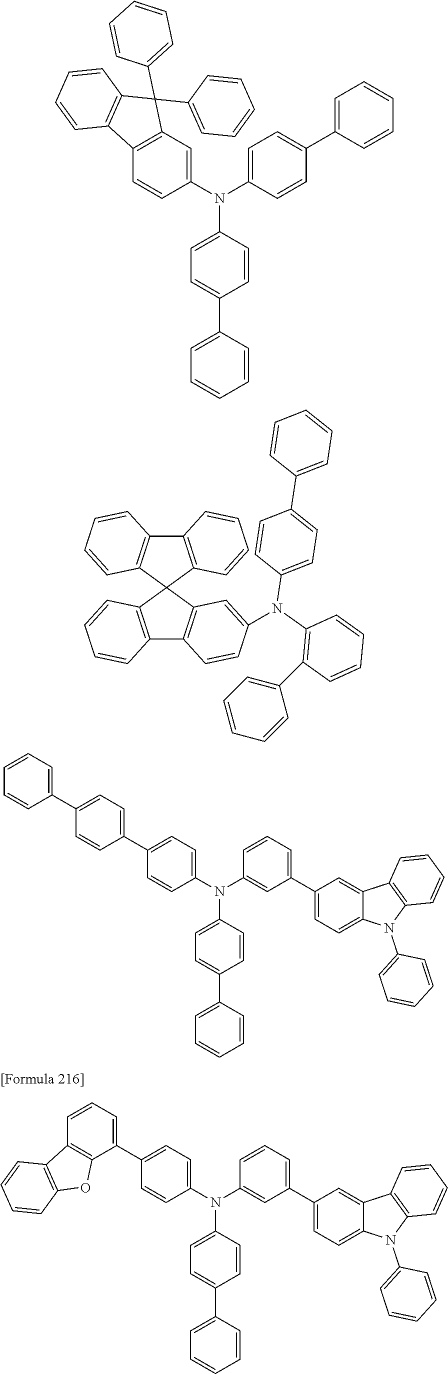 [SMILES: c1ccc(-c2ccc(N(c3ccc(-c4ccccc4)cc3)c3ccc4c(c3)C(c3ccccc3)(c3ccccc3)c3ccccc3-4)cc2)cc1 ; c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccc(-c3ccc(N(c4ccc(-c5ccccc5)cc4)c4cccc(-c5ccc6c(c5)c5ccccc5n6-c5ccccc5)c4)cc3)cc2)cc1 ; c1ccc(-c2ccc(N(c3ccc(-c4cccc5c4oc4ccccc45)cc3)c3cccc(-c4ccc5c(c4)c4ccccc4n5-c4ccccc4)c3)cc2)cc1]

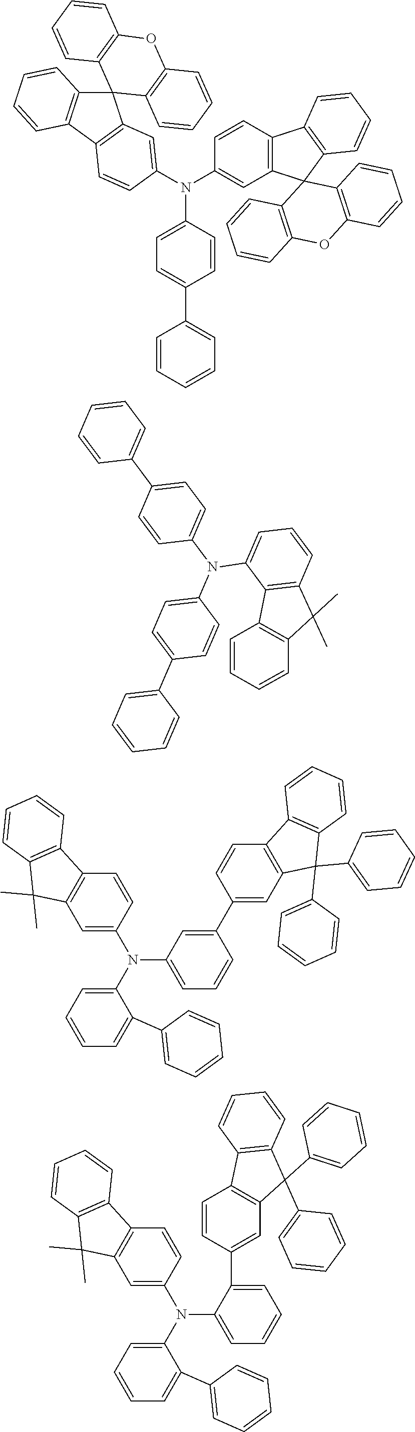

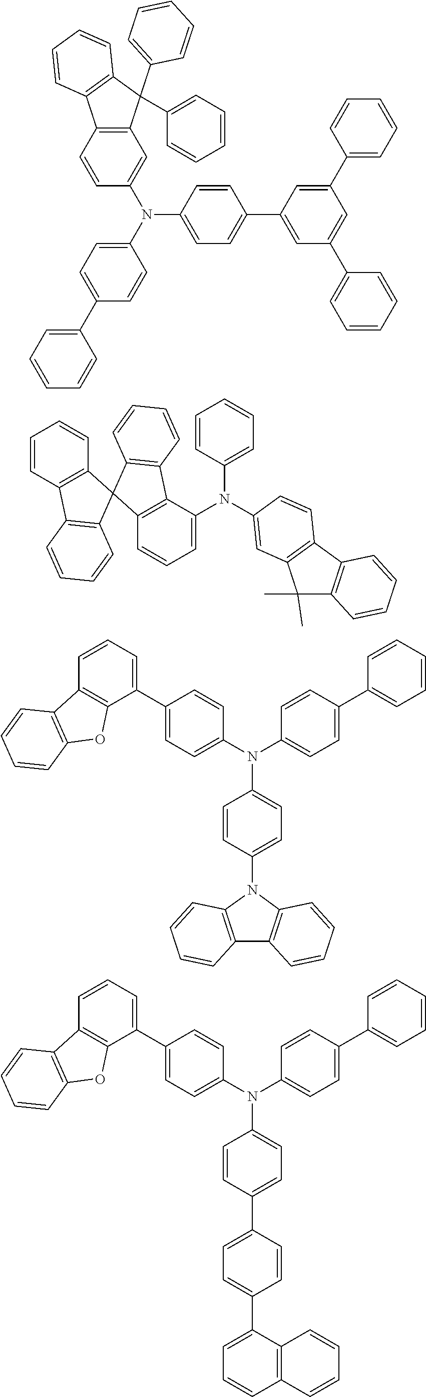

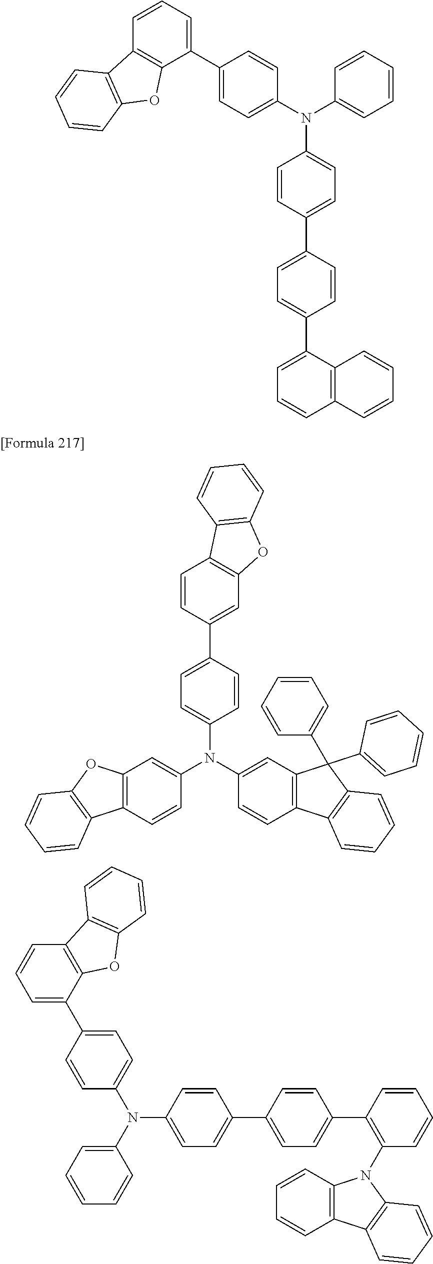

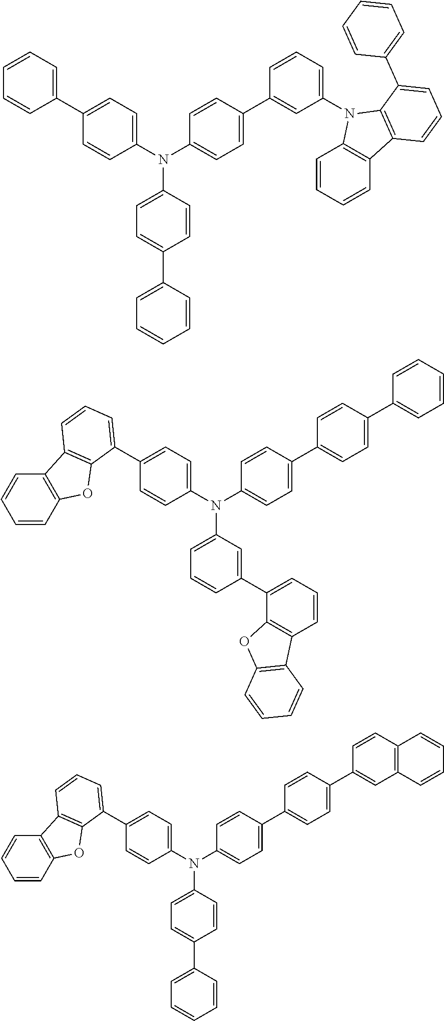 [SMILES: c1ccc(-c2ccc(N(c3ccc(-c4ccccc4)cc3)c3ccc(-c4cccc(-n5c6ccccc6c6cccc(-c7ccccc7)c65)c4)cc3)cc2)cc1 ; c1ccc(-c2ccc(-c3ccc(N(c4ccc(-c5cccc6c5oc5ccccc56)cc4)c4cccc(-c5cccc6c5oc5ccccc56)c4)cc3)cc2)cc1 ; c1ccc(-c2ccc(N(c3ccc(-c4ccc(-c5ccc6ccccc6c5)cc4)cc3)c3ccc(-c4cccc5c4oc4ccccc45)cc3)cc2)cc1]

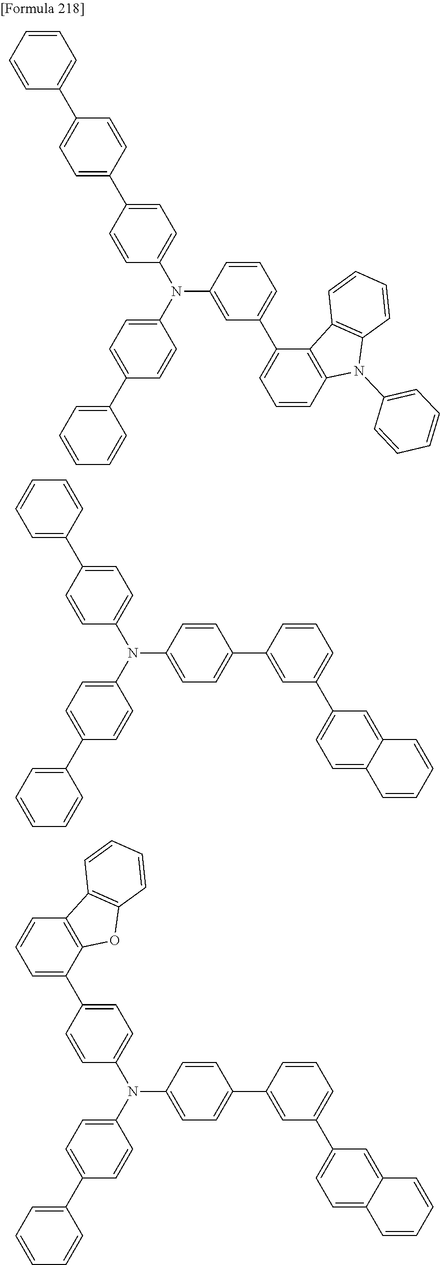

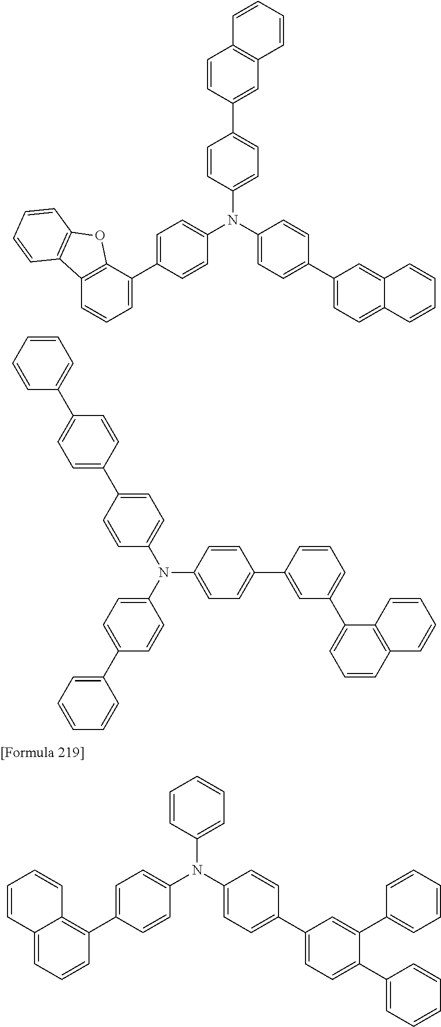

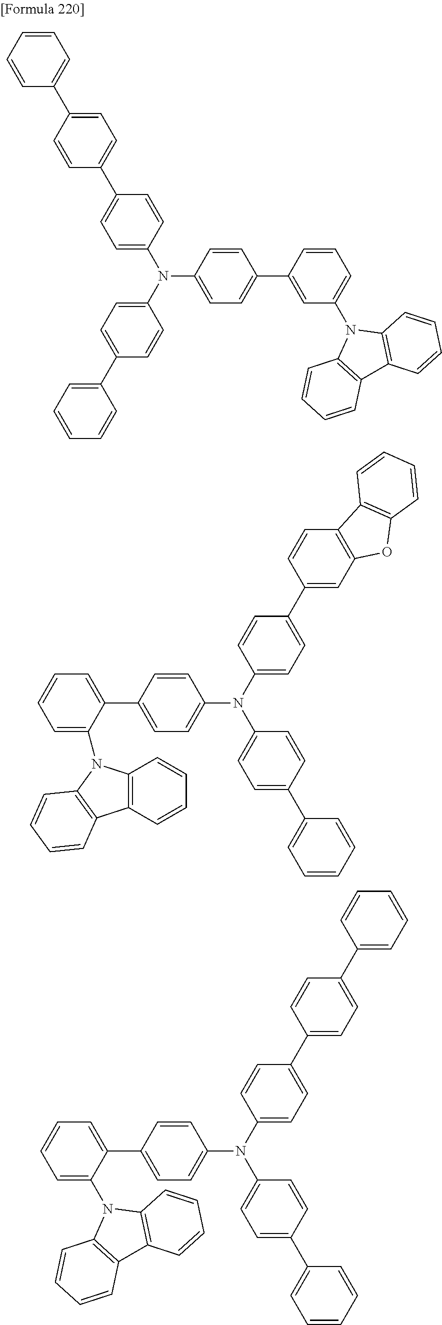

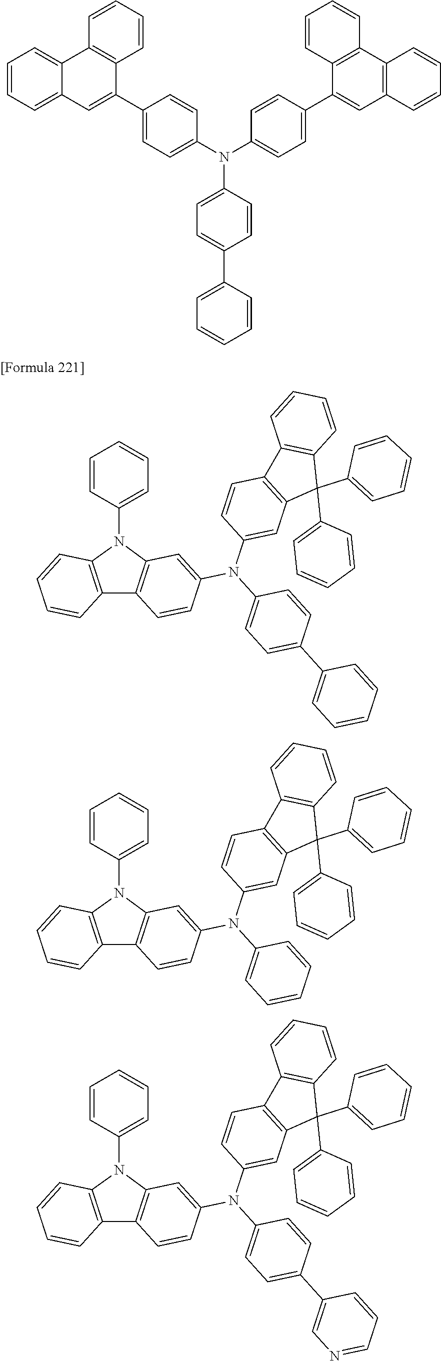

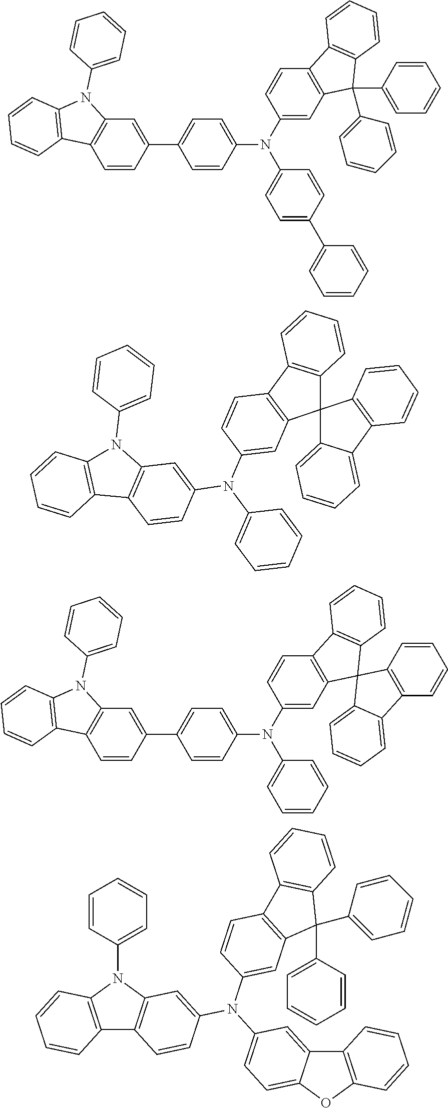

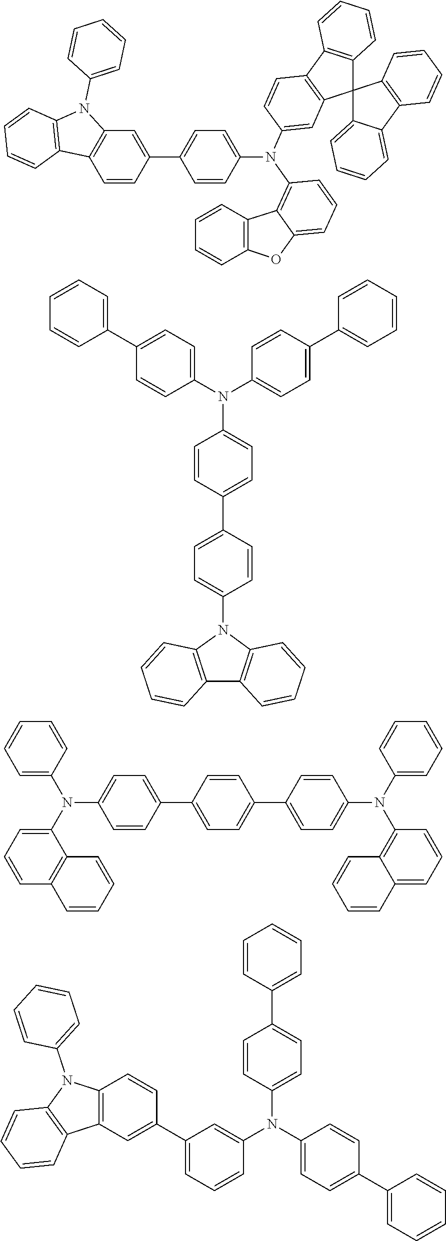 [SMILES: c1ccc(-n2c3ccccc3c3ccc(-c4ccc(N(c5ccc6c(c5)C5(c7ccccc7-c7ccccc75)c5ccccc5-6)c5cccc6oc7ccccc7c56)cc4)cc32)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(-c4ccc(N(c5ccccc5)c5cccc6ccccc56)cc4)cc3)cc2)c2cccc3ccccc23)cc1 ; c1ccc(-c2ccc(N(c3ccc(-c4ccccc4)cc3)c3cccc(-c4ccc5c(c4)c4ccccc4n5-c4ccccc4)c3)cc2)cc1]

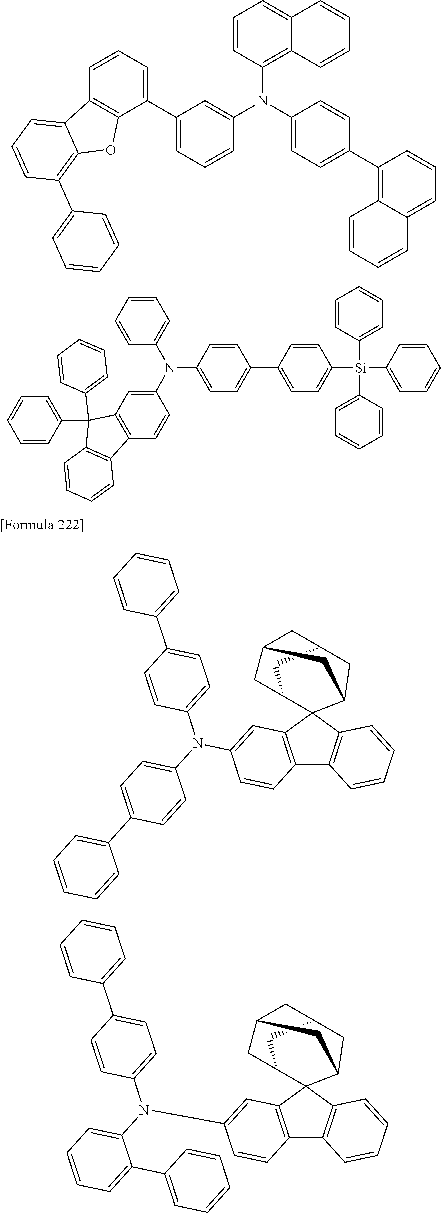

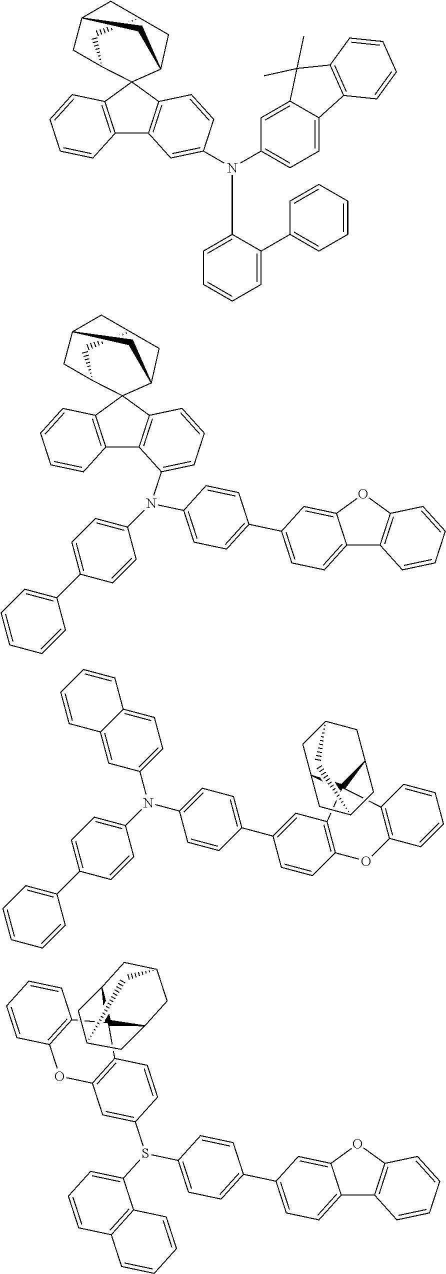

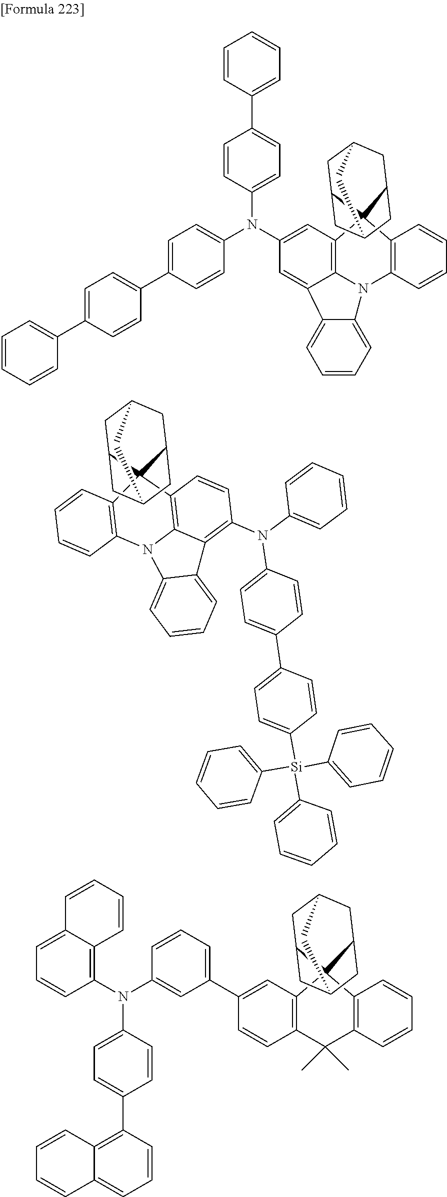

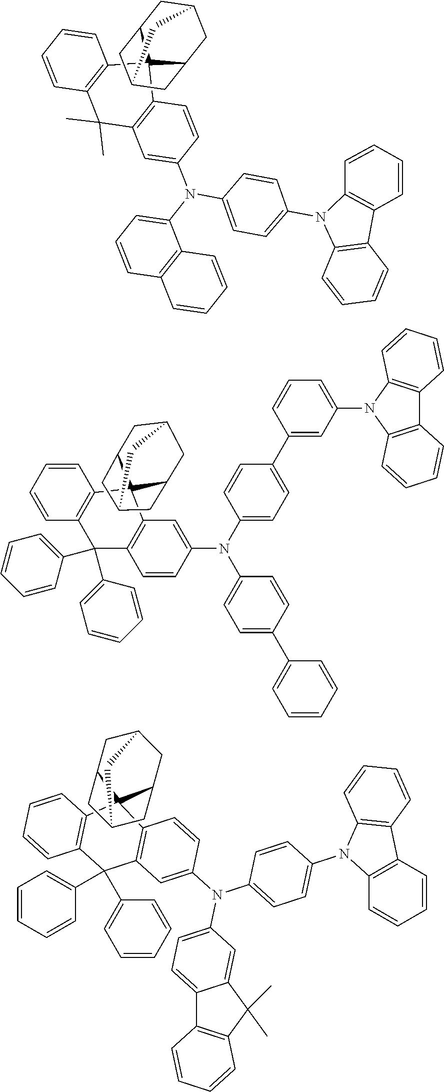

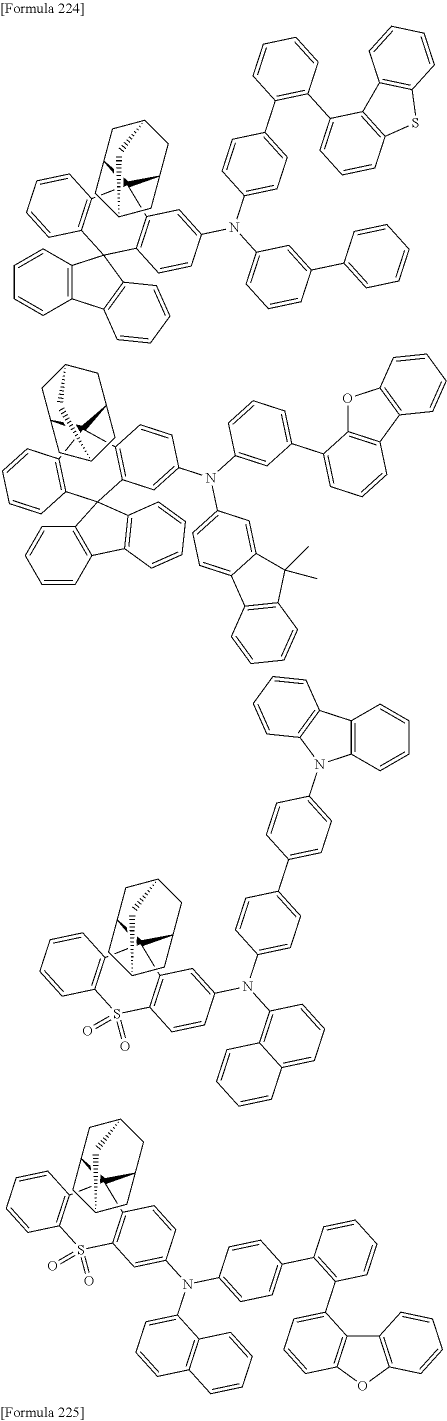

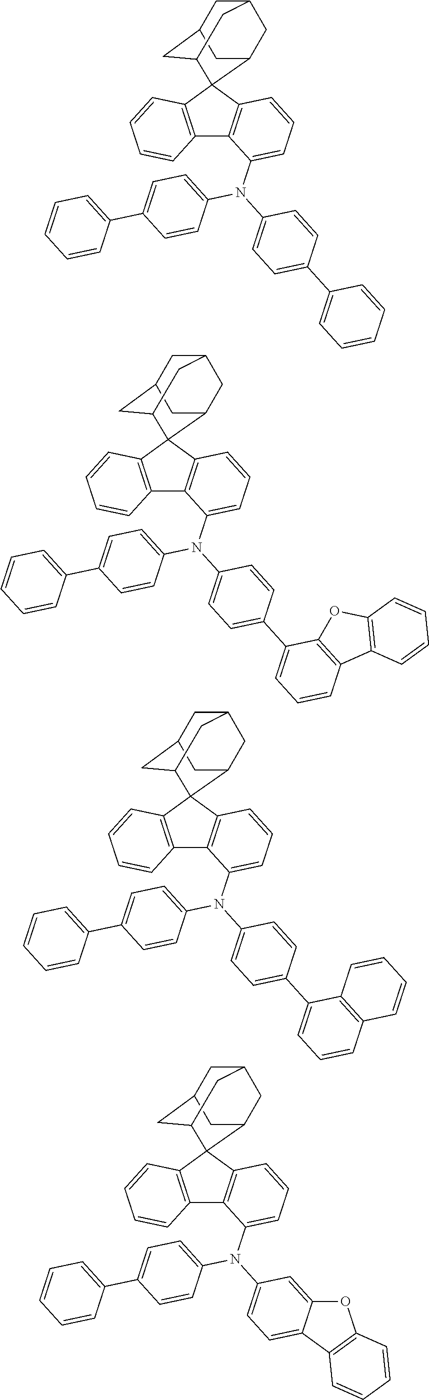 [SMILES: c1ccc(-c2ccc(N(c3ccc(-c4ccccc4)cc3)c3cccc4c3-c3ccccc3C43C4CC5CC(C4)CC3C5)cc2)cc1 ; c1ccc(-c2ccc(N(c3ccc(-c4cccc5c4oc4ccccc45)cc3)c3cccc4c3-c3ccccc3C43C4CC5CC(C4)CC3C5)cc2)cc1 ; c1ccc(-c2ccc(N(c3ccc(-c4cccc5ccccc45)cc3)c3cccc4c3-c3ccccc3C43C4CC5CC(C4)CC3C5)cc2)cc1 ; c1ccc(-c2ccc(N(c3ccc4c(c3)oc3ccccc34)c3cccc4c3-c3ccccc3C43C4CC5CC(C4)CC3C5)cc2)cc1]

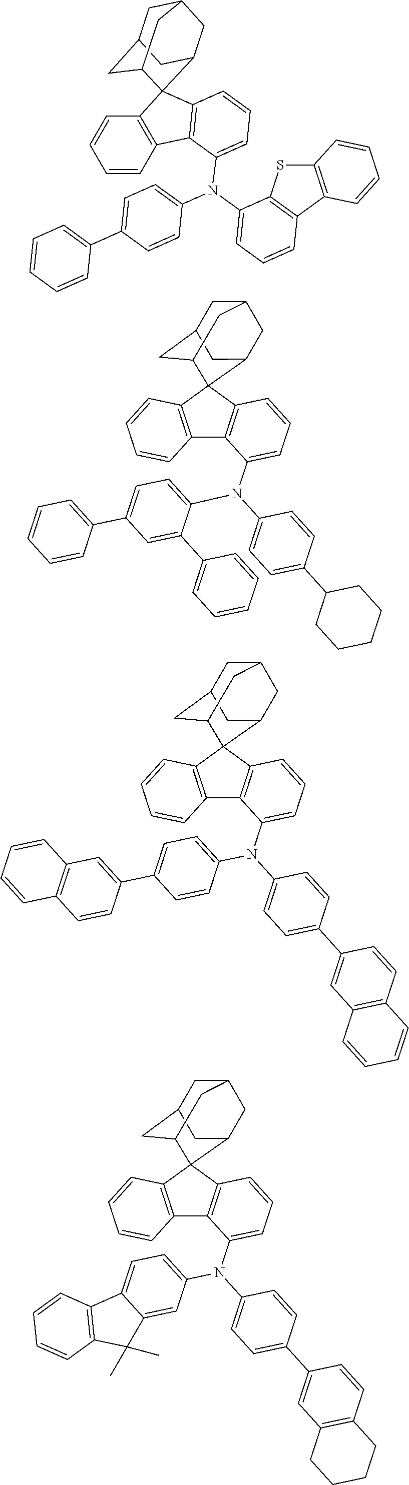

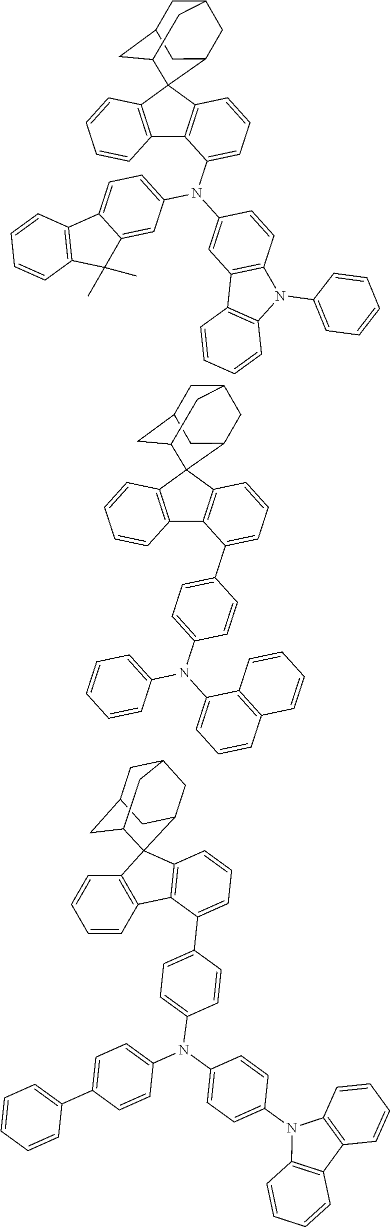

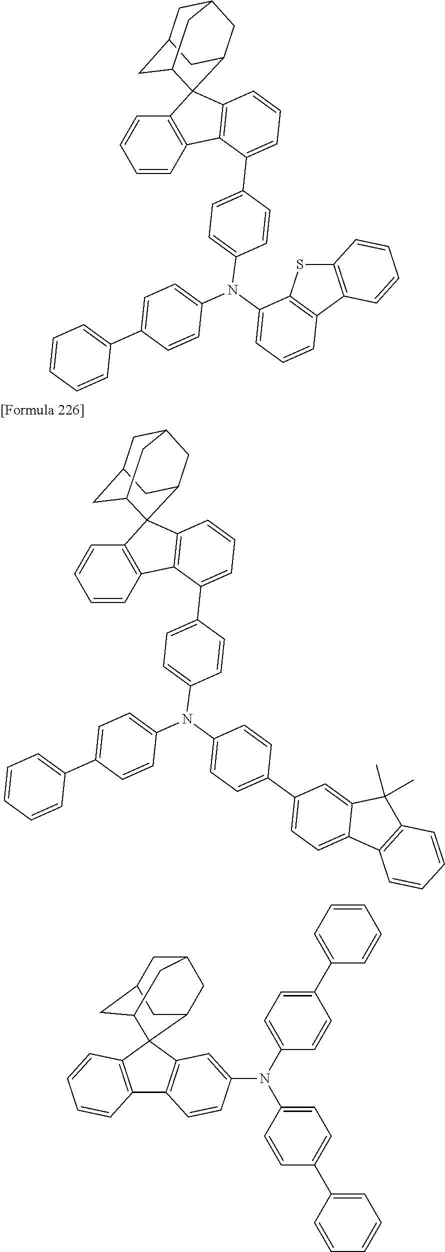

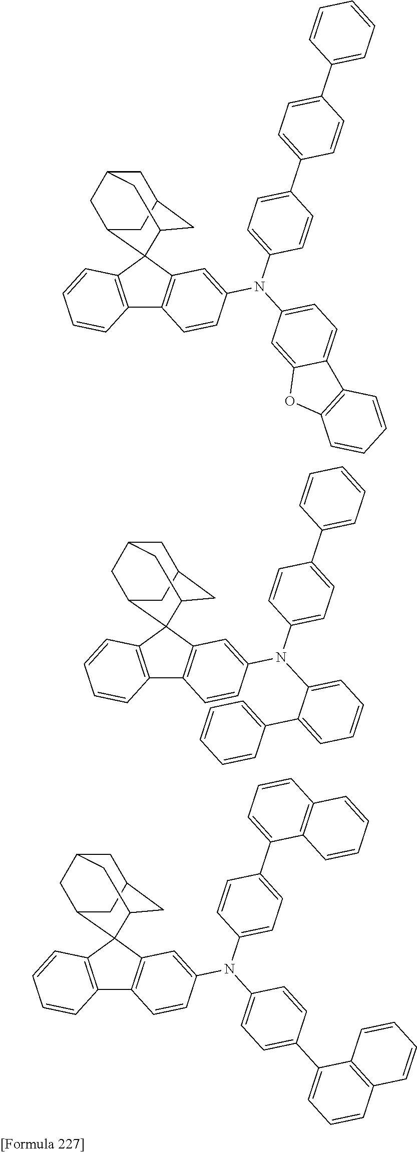

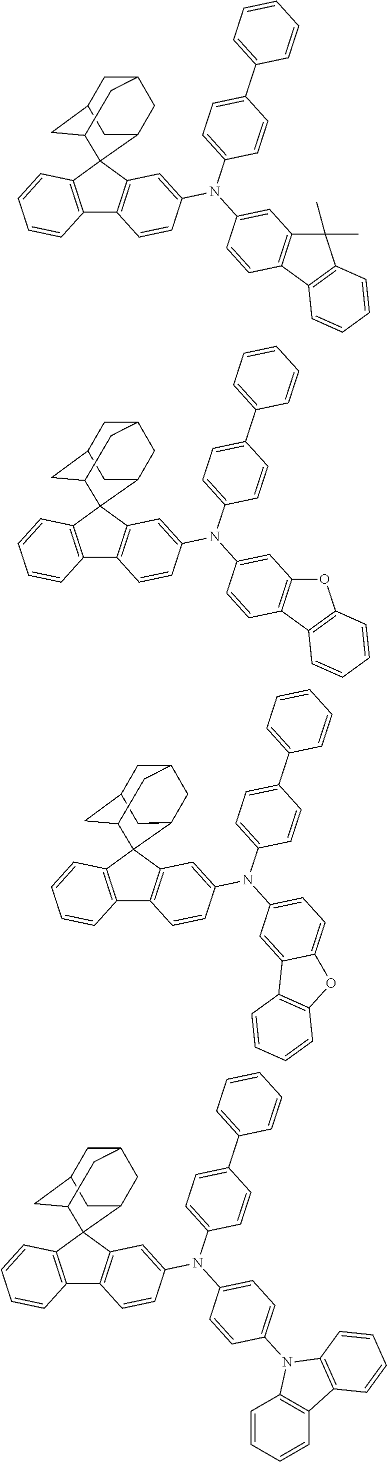

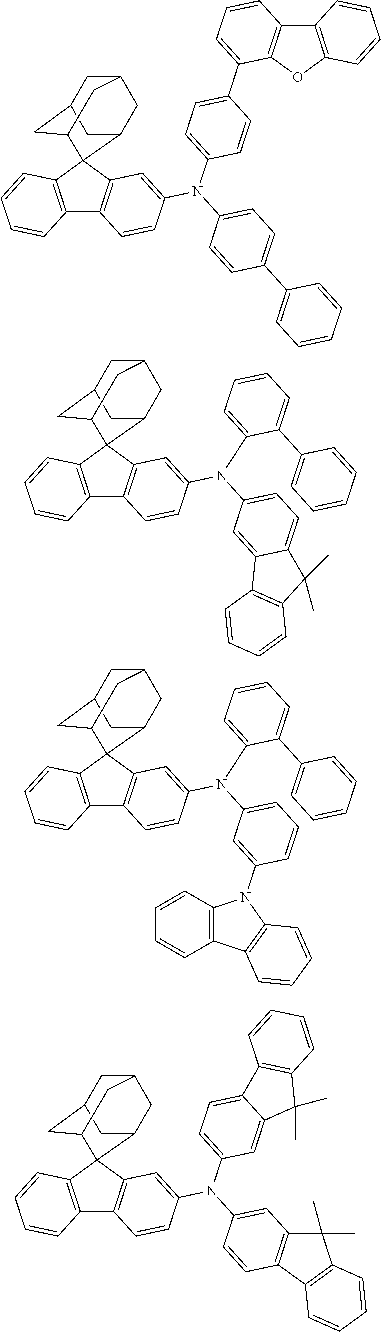

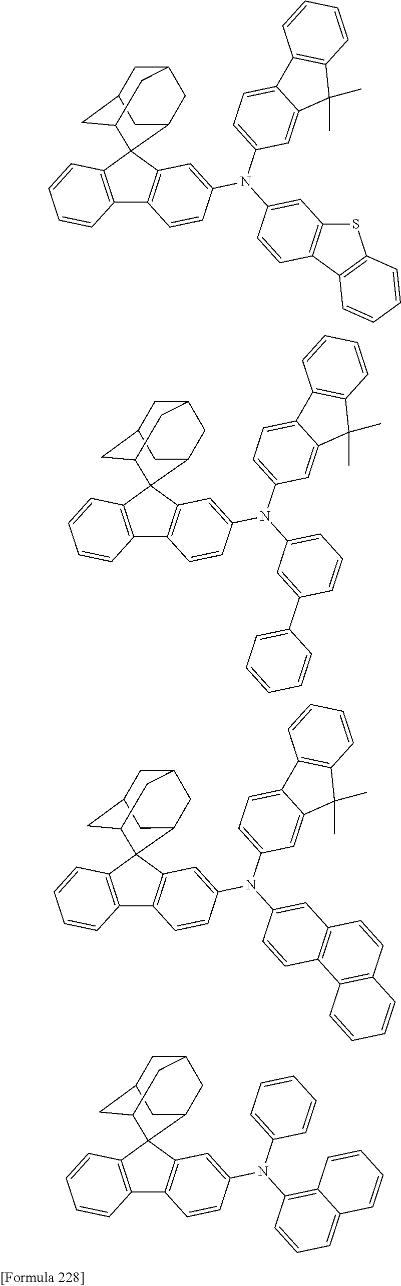

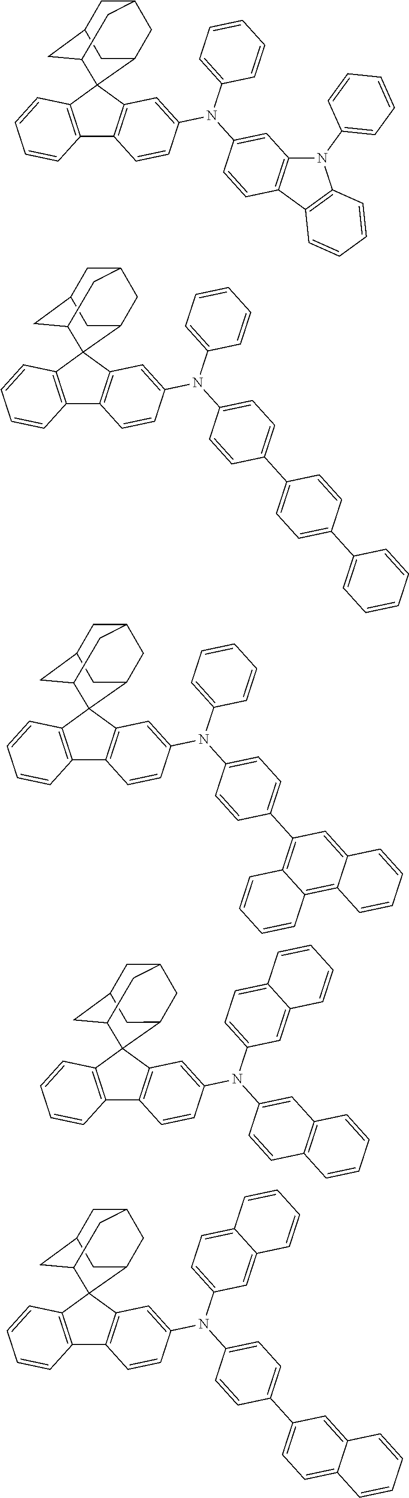

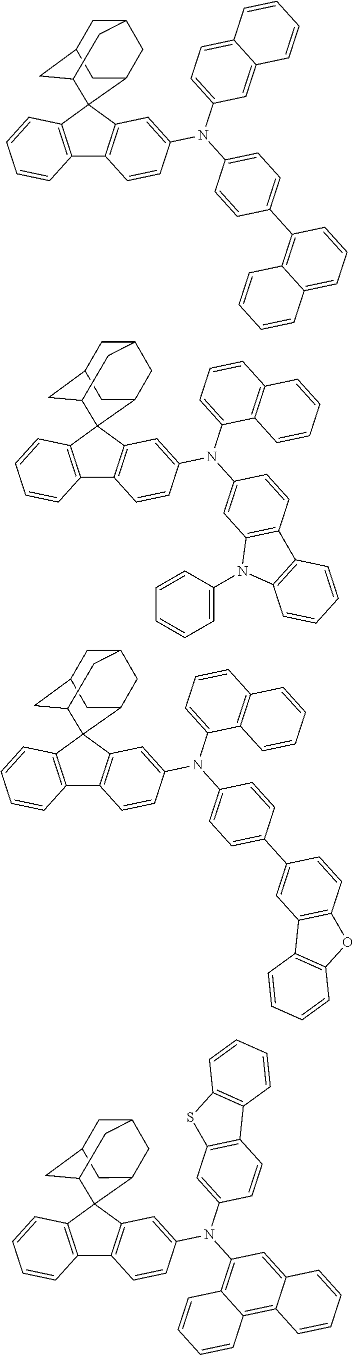

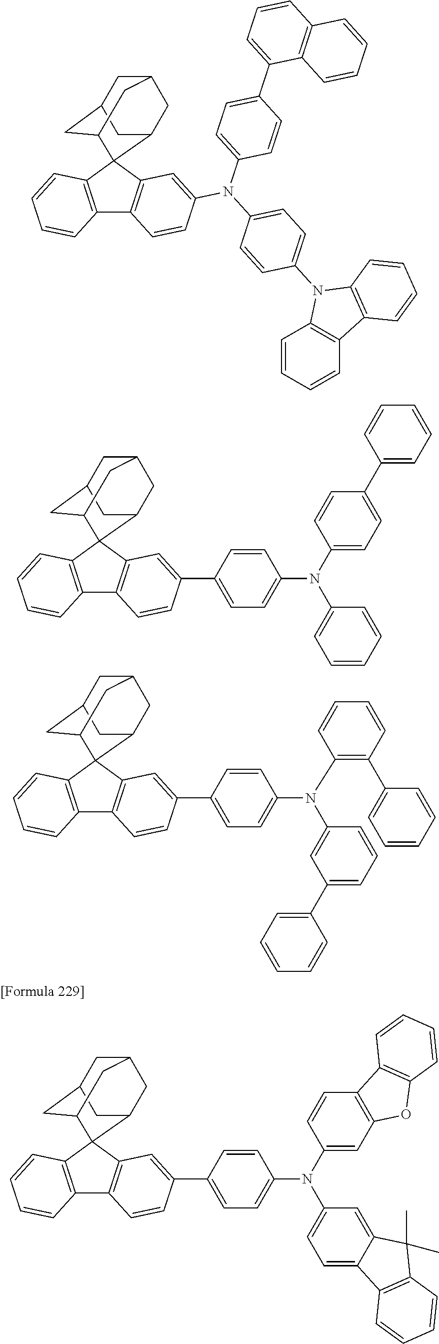

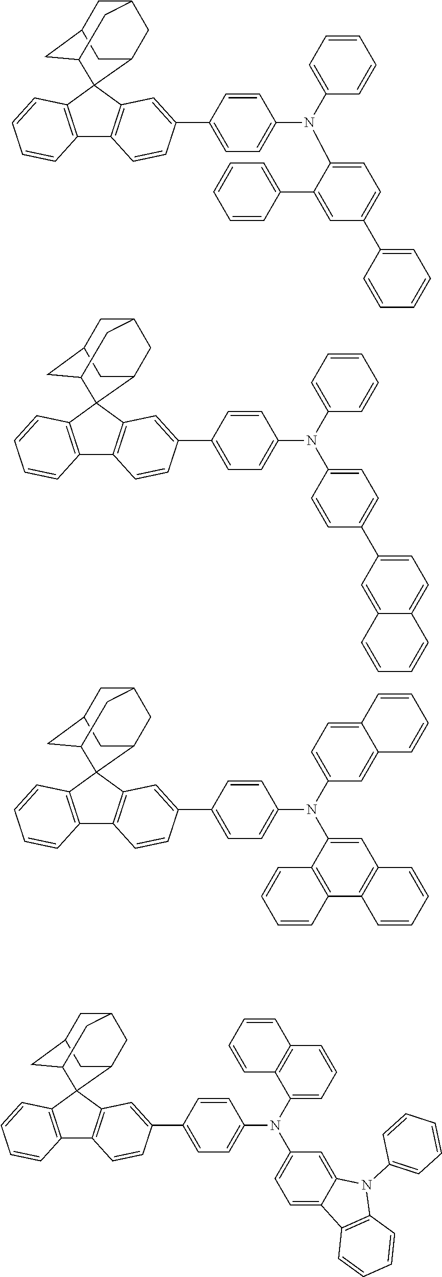

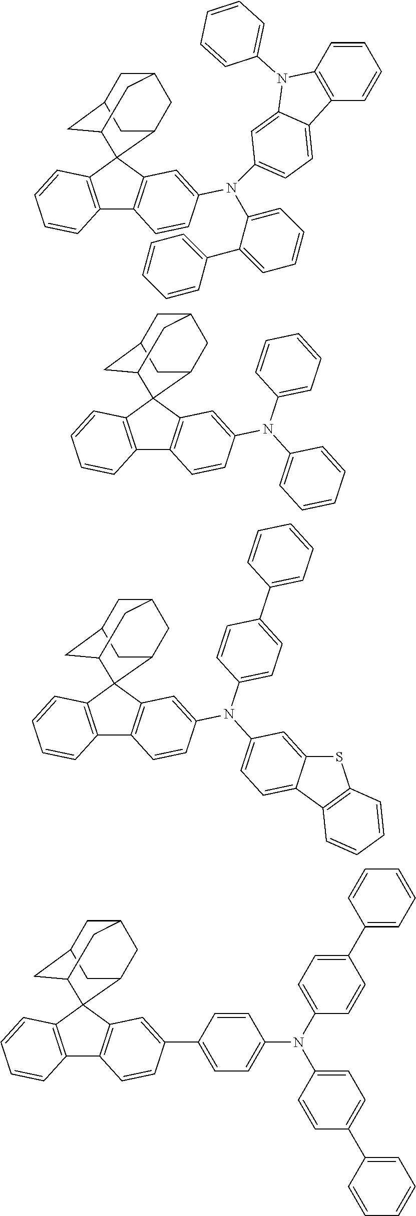

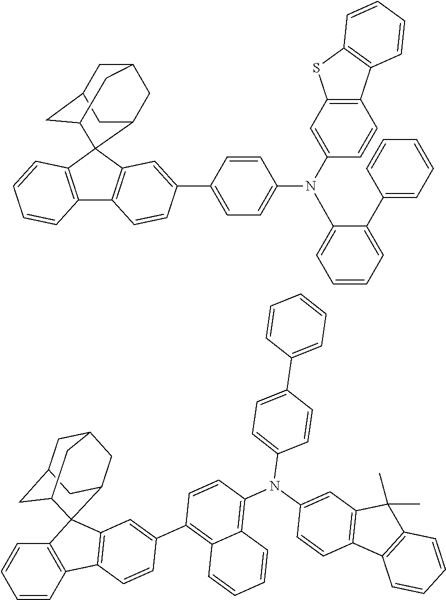

### Examples of Compounds Contained in Second Anode Side Organic Layer

In an exemplary arrangement of the organic EL device of the exemplary embodiment, the compound contained in the second anode side organic layer is preferably at least one compound selected from compounds below.

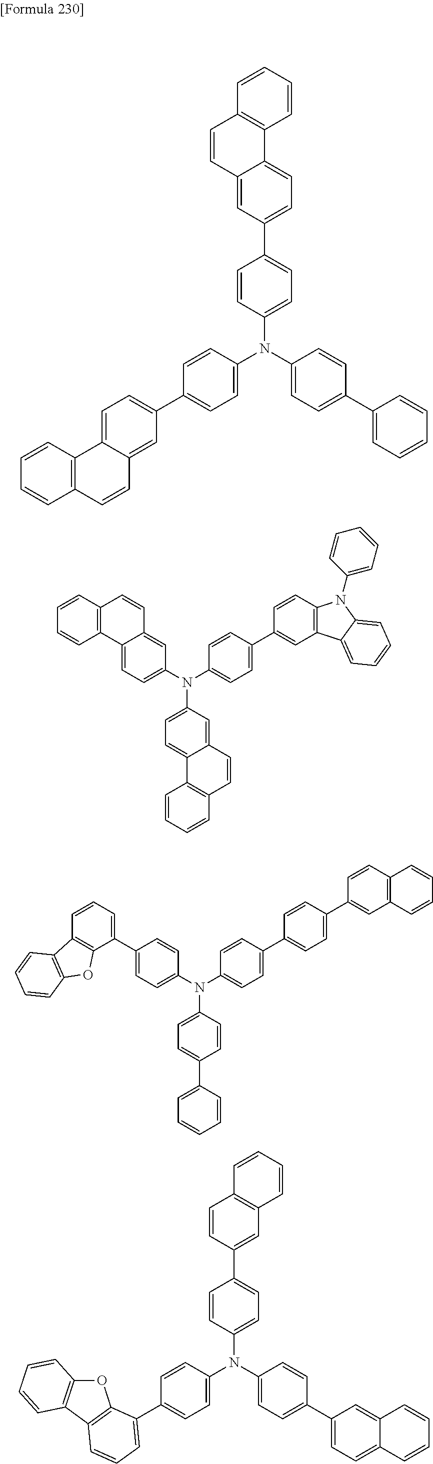 [SMILES: c1ccc(-c2ccc(N(c3ccc(-c4ccc5c(ccc6ccccc65)c4)cc3)c3ccc(-c4ccc5c(ccc6ccccc65)c4)cc3)cc2)cc1 ; c1ccc(-n2c3ccccc3c3cc(-c4ccc(N(c5ccc6c(ccc7ccccc76)c5)c5ccc6c(ccc7ccccc76)c5)cc4)ccc32)cc1 ; c1ccc(-c2ccc(N(c3ccc(-c4ccc(-c5ccc6ccccc6c5)cc4)cc3)c3ccc(-c4cccc5c4oc4ccccc45)cc3)cc2)cc1 ; c1ccc2cc(-c3ccc(N(c4ccc(-c5ccc6ccccc6c5)cc4)c4ccc(-c5cccc6c5oc5ccccc56)cc4)cc3)ccc2c1]

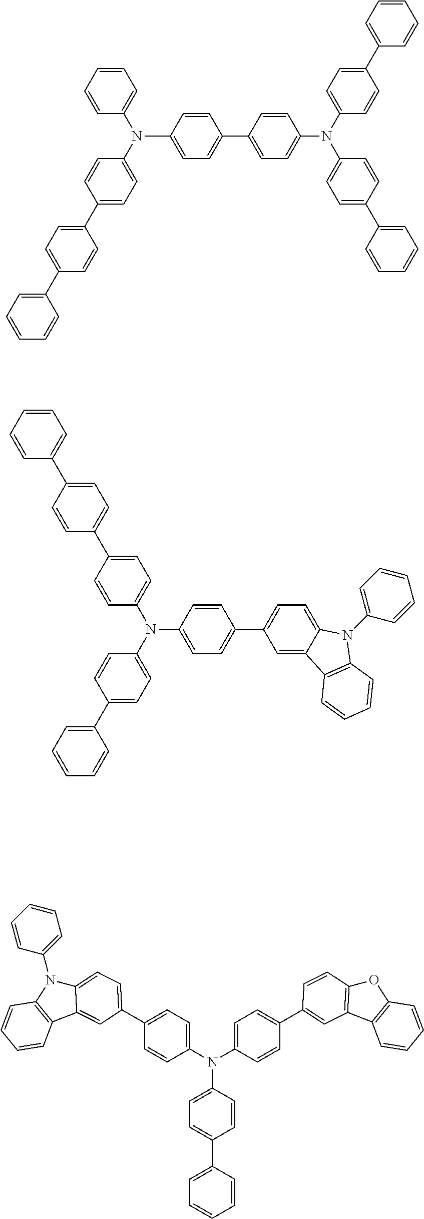 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; c1ccc(-c2ccc(N(c3ccc(-c4ccc5oc6ccccc6c5c4)cc3)c3ccc(-c4ccc5c(c4)c4ccccc4n5-c4ccccc4)cc3)cc2)cc1]

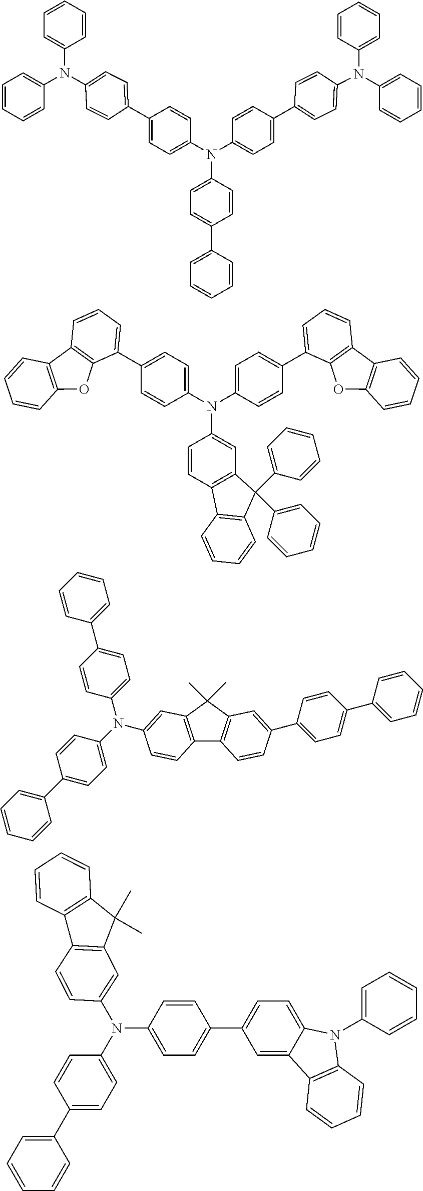

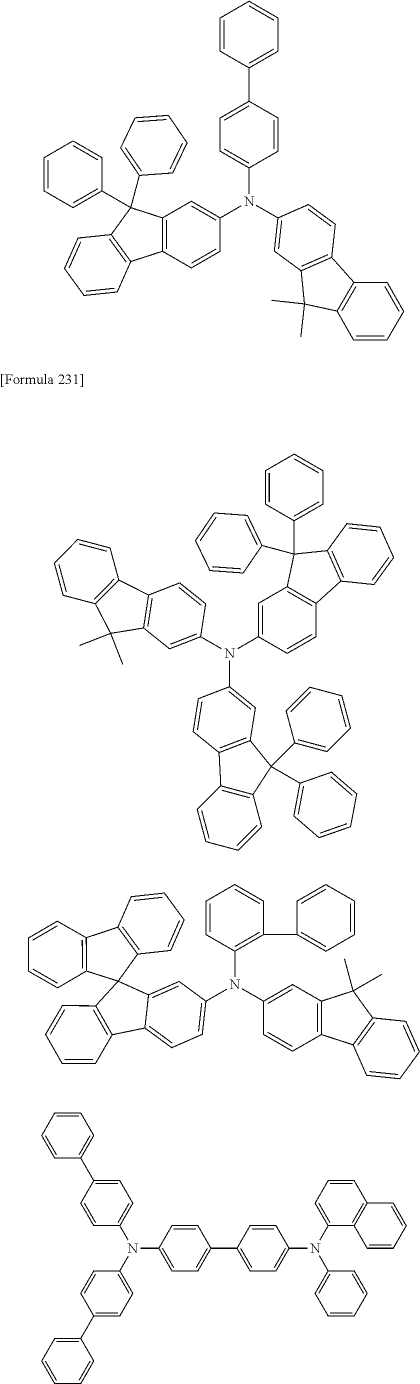

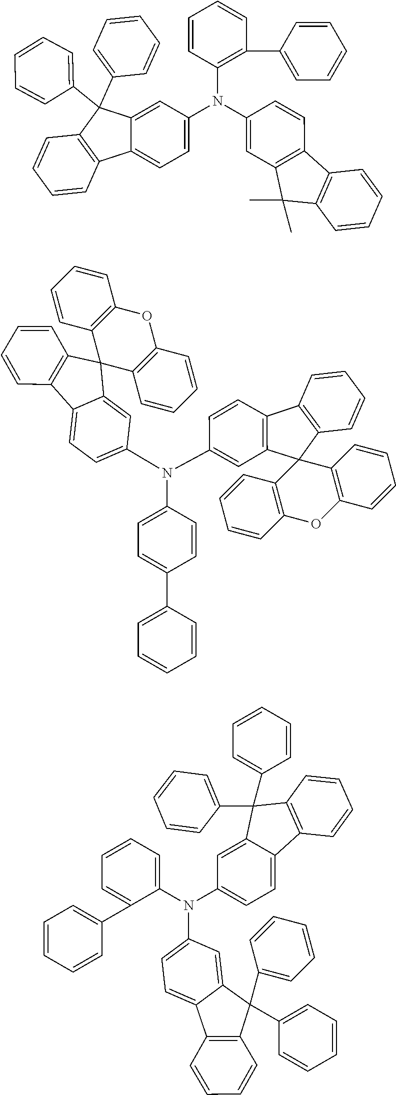 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; c1ccc(-c2ccc(N(c3ccc4c(c3)C3(c5ccccc5Oc5ccccc53)c3ccccc3-4)c3ccc4c(c3)C3(c5ccccc5Oc5ccccc53)c3ccccc3-4)cc2)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

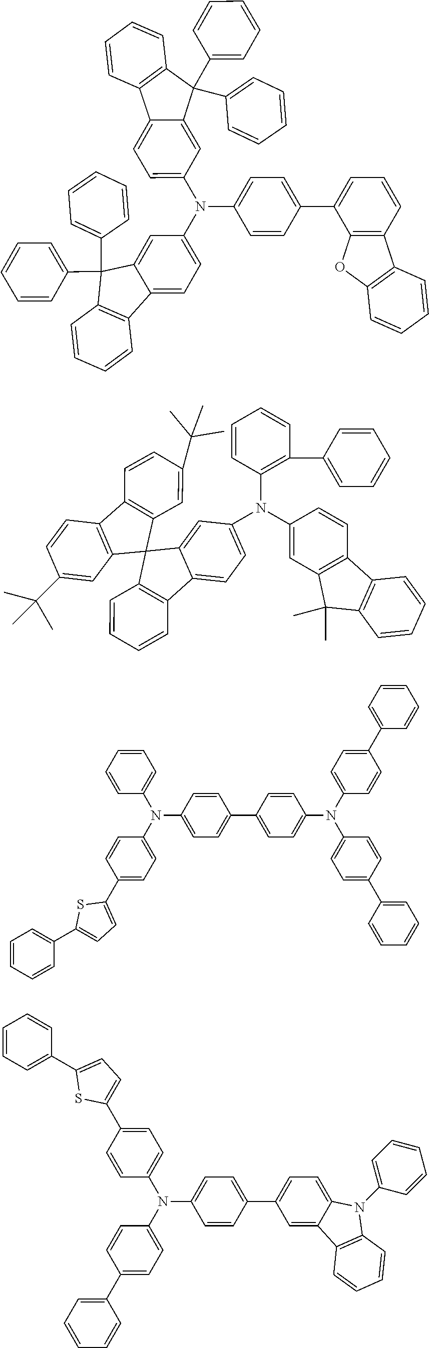

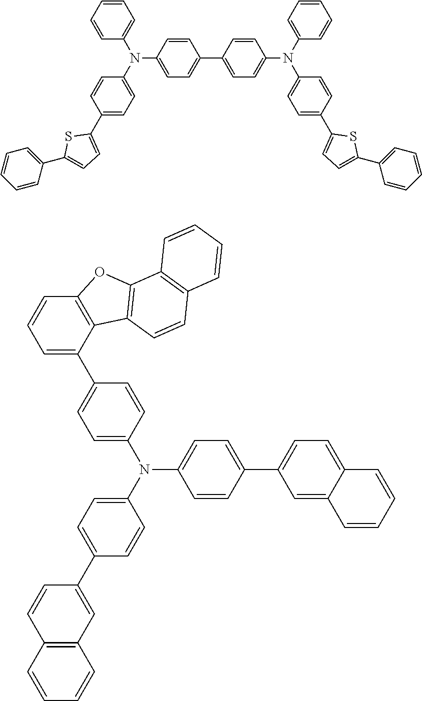 [SMILES: c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1 ; c1ccc2cc(-c3ccc(N(c4ccc(-c5ccc6ccccc6c5)cc4)c4ccc(-c5cccc6oc7c8ccccc8ccc7c56)cc4)cc3)ccc2c1]

### Examples of Compounds Contained in Third Anode Side Organic Layer

In an exemplary arrangement of the organic EL device of the exemplary embodiment, the compound contained in the third anode side organic layer is preferably at least one compound selected from compounds below.

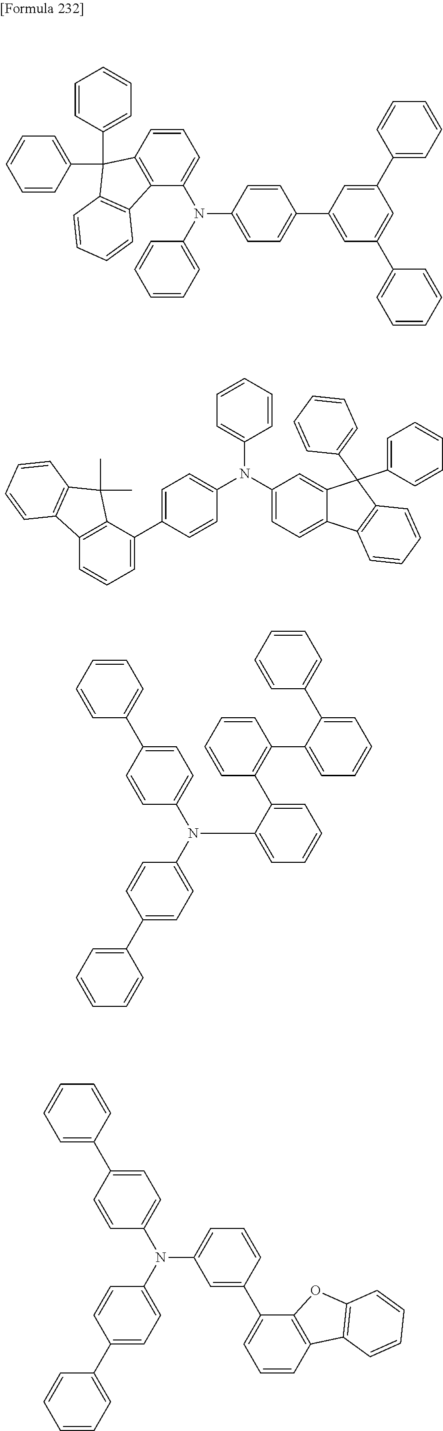 [SMILES: c1ccc(-c2cc(-c3ccccc3)cc(-c3ccc(N(c4ccccc4)c4cccc5c4-c4ccccc4C5(c4ccccc4)c4ccccc4)cc3)c2)cc1 ; CC1(C)c2ccccc2-c2cccc(-c3ccc(N(c4ccccc4)c4ccc5c(c4)C(c4ccccc4)(c4ccccc4)c4ccccc4-5)cc3)c21 ; c1ccc(-c2ccc(N(c3ccc(-c4ccccc4)cc3)c3ccccc3-c3ccccc3-c3ccccc3-c3ccccc3)cc2)cc1 ; c1ccc(-c2ccc(N(c3ccc(-c4ccccc4)cc3)c3cccc(-c4cccc5c4oc4ccccc45)c3)cc2)cc1]

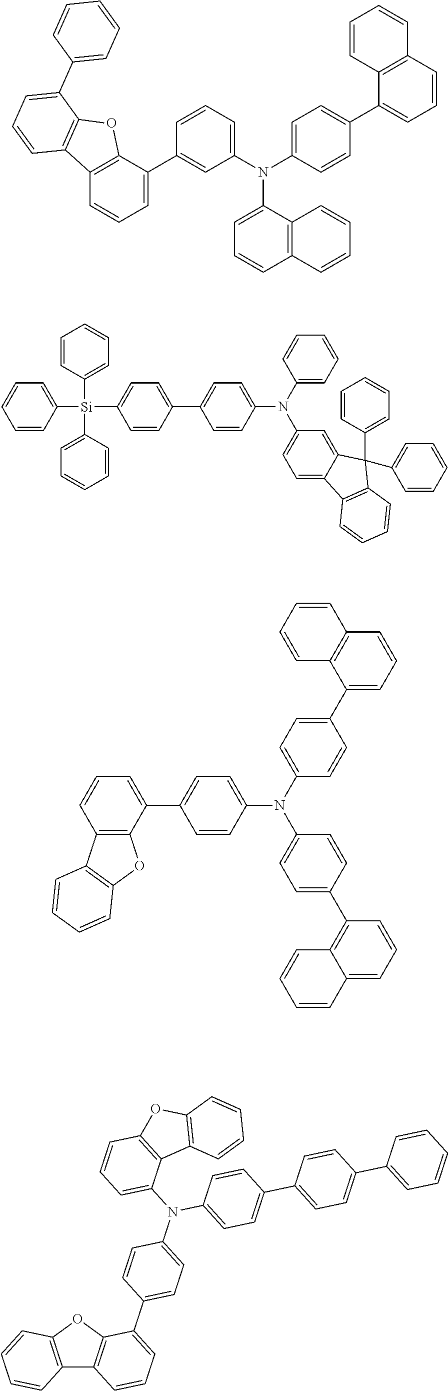 [SMILES: c1ccc(-c2cccc3c2oc2c(-c4cccc(N(c5ccc(-c6cccc7ccccc67)cc5)c5cccc6ccccc56)c4)cccc23)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1 ; c1ccc2c(-c3ccc(N(c4ccc(-c5cccc6ccccc56)cc4)c4ccc(-c5cccc6c5oc5ccccc56)cc4)cc3)cccc2c1 ; c1ccc(-c2ccc(-c3ccc(N(c4ccc(-c5cccc6c5oc5ccccc56)cc4)c4cccc5oc6ccccc6c45)cc3)cc2)cc1]

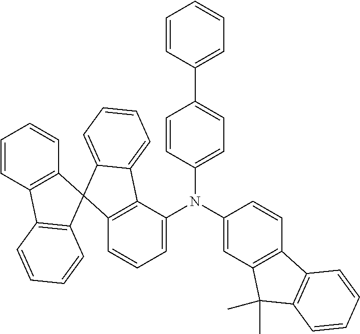 [SMILES: CC1(C)c2ccccc2-c2ccc(N(c3ccc(-c4ccccc4)cc3)c3cccc4c3-c3ccccc3C43c4ccccc4-c4ccccc43)cc21]

### Emitting Region

The emitting region includes at least one emitting layer.

In the organic EL device according to the exemplary embodiment, the emitting region preferably contains a fluorescent substance and an organic compound. The fluorescent substance contained in the emitting region is also preferably a fluorescent compound described later. The organic compound contained in the emitting region is also preferably a host material described later.

In an exemplary arrangement of the organic EL device of the exemplary embodiment, the emitting region includes a single emitting layer.

In an exemplary arrangement of the organic EL device of the exemplary embodiment, the emitting region consists of a single emitting layer.

In an exemplary arrangement of the organic EL device of the exemplary embodiment, the emitting region includes, as two emitting layers, a first emitting layer and a second emitting layer.

In an exemplary arrangement of the organic EL device of the exemplary embodiment, the emitting region consists of two emitting layers.

In the organic EL device according to the exemplary embodiment, the emitting layer preferably contains an emitting compound. The emitting compound, which is not particularly limited, may include, for instance, at least one emitting compound selected from the group consisting of a first emitting compound and a second emitting compound described below. In the organic EL device according to the exemplary embodiment, the emitting layer preferably contains 0.5 mass % or more of the emitting compound with respect to the total mass of the emitting layer. The emitting layer preferably contains 10 mass % or less of the emitting compound, more preferably 7 mass % or less of the emitting compound, and still more preferably 5 mass % or less of the emitting compound, with respect to the total mass of the emitting layer.

In an exemplary arrangement of the organic EL device of the exemplary embodiment, at least one emitting layer in the emitting region contains an emitting compound that emits light having a maximum peak wavelength of 500 nm or less. In an exemplary arrangement of the organic EL device of the exemplary embodiment, the emitting compound emits light having a maximum peak wavelength of 480 nm or less. In an exemplary arrangement of the organic EL device of the exemplary embodiment, the emitting compound emits light having a maximum peak wavelength in a range from 430 nm to 480 nm.

In an exemplary arrangement of the organic EL device of the exemplary embodiment, at least one emitting layer in the emitting region contains an emitting compound that emits fluorescence having a maximum peak wavelength of 500 nm or less. In an exemplary arrangement of the organic EL device of the exemplary embodiment, the emitting compound emits fluorescence having a maximum peak wavelength of 480 nm or less. In an exemplary arrangement of the organic EL device of the exemplary embodiment, the emitting compound emits fluorescence having a maximum peak wavelength in a range from 430 nm to 480 nm.

In the organic EL device according to the exemplary embodiment, it is also preferable that the emitting region includes at least the first emitting layer containing the first host material and the second emitting layer containing the second host material. The first host material and the second host material are different from each other.

Herein, the “host material” refers to, for instance, a material that accounts for “50 mass % or more of the layer.” Accordingly, for instance, the first emitting layer contains 50 mass % or more of the first host material with respect to the total mass of the first emitting layer. Further, for instance, the second emitting layer contains 50 mass % or more of the second host material with respect to the total mass of the second emitting layer. Moreover, for instance, the “host material” may account for 60 mass % or more of the layer, 70 mass % or more of the layer, 80 mass % or more of the layer, 90 mass % or more of the layer, or 95 mass % or more of the layer.

A triplet energy of the first host material T₁(H1) and a triplet energy of the second host material T₁(H2) preferably satisfy a relationship of a numerical formula (Numerical Formula 1) below.

$${T}_{1} ( H 1 ) > {T}_{1} ( H 2 ) \qquad ( Numerical Formula 1 )$$

In the organic EL device according to the exemplary embodiment, the triplet energy of the first host material T₁(H1) and the triplet energy of the second host material T₁(H2) preferably satisfy a relationship of a numerical formula (Numerical Formula 5) below.

$${T}_{1} ( H 1 ) - {T}_{1} ( H 2 ) > 0.03 eV \qquad ( Numerical Formula 5 )$$

When the organic EL device according to the exemplary embodiment includes the first emitting layer and the second emitting layer satisfying the relationship of the above numerical formula (Numerical Formula 1), luminous efficiency of the device is improved.

Conventionally, Triplet-Triplet-Annihilation (occasionally referred to as TTA) has been known as a technique for enhancing the luminous efficiency of the organic electroluminescence device. TTA is a mechanism in which triplet excitons collide with one another to generate singlet excitons. It should be noted that the TTA mechanism is also occasionally referred to as a TTF mechanism as described in WO2010/134350.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

$${}^{3} {A}^{*} + {}^{3} {A}^{*} \to {( 4 / 9 )}^{1} A + {( 1 / 9 )}^{1} {A}^{⋆} + ( 13 / 9 ) {}^{3} {A}^{*}$$

In other words, 5³A*→4¹A+1A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(⅕)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(½)=37.5%) to 25% (the amount ratio of initially generated singlet excitons). At this time, the TTF ratio is 37.5/62.5=60%.

It is considered that when the emitting region of the organic EL device according to the exemplary embodiment includes at least two emitting layers (i.e., the first emitting layer and the second emitting layer) and the triplet energy of the first host material T₁(H1) in the first emitting layer and the triplet energy of the second host material T₁(H2) in the second emitting layer satisfy the relationship of the above numerical formula (Numerical Formula 1), triplet excitons generated by recombination of holes and electrons in the first emitting layer and present on an interface between the first emitting layer and organic layer(s) in direct contact therewith are not likely to be quenched even under the presence of excessive carriers on the interface between the first emitting layer and the organic layer(s). For instance, the presence of a recombination region locally on an interface between the first emitting layer and a hole transporting layer or an electron blocking layer is considered to cause quenching by excessive electrons. Meanwhile, the presence of a recombination region locally on an interface between the first emitting layer and an electron transporting layer or a hole blocking layer is considered to cause quenching by excessive holes.

By including the first emitting layer and the second emitting layer so as to satisfy the relationship of the numerical formula (Numerical Formula 1), triplet excitons generated in the first emitting layer can transfer to the second emitting layer without being quenched by excessive carriers and be inhibited from back-transferring from the second emitting layer to the first emitting layer. Consequently, the second emitting layer exhibits the TTF mechanism to effectively generate singlet excitons, thereby improving the luminous efficiency.

Accordingly, the organic EL device according to the exemplary embodiment includes, as different regions, the first emitting layer mainly generating triplet excitons and the second emitting layer mainly exhibiting the TTF mechanism using triplet excitons having transferred from the first emitting layer, and a difference in triplet energy is provided by using a compound having a smaller triplet energy than that of the first host material in the first emitting layer as the second host material in the second emitting layer, thereby improving the luminous efficiency.

In the organic EL device according to the exemplary embodiment, it is also preferable that the first emitting layer is disposed between the anode and the cathode and the second emitting layer is disposed between the first emitting layer and the cathode. The organic EL device according to the exemplary embodiment may include the first emitting layer and the second emitting layer in this order from the side close to the anode, or may include the second emitting layer and the first emitting layer in this order from the side close to the anode. In either of the orders of including the first emitting layer and the second emitting layer, the effect of the laminate arrangement of the emitting layers can be expected by selecting a combination of materials that satisfy the relationship of the numerical formula (Numerical Formula 1).

In the organic EL device according to the exemplary embodiment, the first emitting layer is also preferably disposed closer to the anode than the second emitting layer.

In the organic EL device according to the exemplary embodiment, when the first emitting layer is disposed closer to the anode than the second emitting layer, the first emitting layer and the hole transporting zone are preferably in direct contact with each other. When the hole transporting zone does not include the fourth anode side organic layer, the first emitting layer and the third anode side organic layer are preferably in direct contact with each other. When the hole transporting zone includes the fourth anode side organic layer, the first emitting layer and the fourth anode side organic layer are preferably in direct contact with each other.

In the organic EL device according to the exemplary embodiment, the first emitting layer and the second emitting layer are also preferably in direct contact with each other.

Herein, a layer arrangement in which the first emitting layer and the second emitting layer are in direct contact with each other may include one of embodiments (LS1), (LS2) and (LS3) below.
(LS1) An embodiment in which a region containing both the first host material and the second host material is generated in a process of vapor-depositing the compound of the first emitting layer and vapor-depositing the compound of the second emitting layer, and is present on the interface between the first emitting layer and the second emitting layer.
(LS2) An embodiment in which in a case of containing an emitting compound in the first emitting layer and the second emitting layer, a region containing the first host material, the second host material and the emitting compound is generated in a process of vapor-depositing the compound of the first emitting layer and vapor-depositing the compound of the second emitting layer, and is present on the interface between the first emitting layer and the second emitting layer.
(LS3) An embodiment in which in a case of containing an emitting compound in the first emitting layer and the second emitting layer, a region containing the emitting compound, a region containing the first host material or a region containing the second host material is generated in a process of vapor-depositing the compound of the first emitting layer and vapor-depositing the compound of the second emitting layer, and is present on the interface between the first emitting layer and the second emitting layer.

### First Emitting Layer

The first emitting layer contains the first host material. The first host material is a compound different from the second host material contained in the second emitting layer.

The first emitting layer preferably contains the first emitting compound. The first emitting compound is not particularly limited. The first emitting compound is preferably a compound that emits light having a maximum peak wavelength of 500 nm or less, more preferably a compound that emits light having a maximum peak wavelength of 480 nm or less, and still more preferably a compound that emits light having a maximum peak wavelength in a range from 430 nm to 480 nm. The first emitting compound is preferably a fluorescent compound that emits fluorescence having a maximum peak wavelength of 500 nm or less, more preferably a fluorescent compound that emits fluorescence having a maximum peak wavelength of 480 nm or less, and still more preferably a fluorescent compound that emits fluorescence having a maximum peak wavelength in a range from 430 nm to 480 nm.

In the organic EL device according to the exemplary embodiment, the first emitting compound is preferably a compound containing no azine ring structure in a molecule.

In the organic EL device according to the exemplary embodiment, the first emitting compound is preferably not a boron-containing complex, more preferably not a complex.

For instance, examples of a fluorescent compound that emits blue fluorescence and is usable for the first emitting layer include a pyrene derivative, styrylamine derivative, chrysene derivative, fluoranthene derivative, fluorene derivative, diamine derivative, and triarylamine derivative.

Herein, the blue light emission refers to light emission in which a maximum peak wavelength of emission spectrum is in a range from 430 nm to 500 nm.

In the organic EL device according to the exemplary embodiment, the first emitting layer preferably does not contain a metal complex. Moreover, in the organic EL device according to the exemplary embodiment, the first emitting layer also preferably does not contain a boron-containing complex.

In the organic EL device according to the exemplary embodiment, the first emitting layer preferably does not contain a phosphorescent material (dopant material).

In addition, the first emitting layer preferably does not contain a heavy-metal complex and a phosphorescent rare earth metal complex. Examples of the heavy-metal complex herein include iridium complex, osmium complex, and platinum complex.

A measurement method of the maximum peak wavelength of the compound is as follows. A toluene solution of a measurement target compound at a concentration of 5 μmol/L is prepared and put in a quartz cell. An emission spectrum (ordinate axis: luminous intensity, abscissa axis: wavelength) of each of the samples is measured at a normal temperature (300K). The emission spectrum can be measured using a spectrophotometer (apparatus name: F-7000) produced by Hitachi High-Tech Science Corporation. It should be noted that the apparatus for measuring the emission spectrum is not limited to the apparatus used herein.

A peak wavelength of the emission spectrum exhibiting the maximum luminous intensity is defined as the maximum peak wavelength. Herein, the maximum peak wavelength of fluorescence is occasionally referred to as a maximum fluorescence peak wavelength (FL-peak).

In an emission spectrum of the first emitting compound, where a peak exhibiting a maximum luminous intensity is defined as a maximum peak and a height of the maximum peak is defined as 1, heights of other peaks appearing in the emission spectrum are preferably less than 0.6. It should be noted that the peaks in the emission spectrum are defined as local maximum values.

Moreover, in the emission spectrum of the first emitting compound, the number of peaks is preferably less than three.

In the organic EL device according to the exemplary embodiment, a singlet energy of the first host material S₁(H1) and a singlet energy of the first emitting compound S₁(D1) preferably satisfy a relationship of a numerical formula (Numerical Formula 20) below.

$${S}_{1} ( H 1 ) > {S}_{1} ( D 1 ) \qquad ( Numerical Formula 20 )$$

The singlet energy S₁ means an energy difference between the lowest singlet state and the ground state.

When the first host material and the first emitting compound satisfy the relationship of the numerical formula (Numerical Formula 20), singlet excitons generated on the first host material easily energy-transfer from the first host material to the first emitting compound, thereby contributing to fluorescence of the first emitting compound.

In the organic EL device according to the exemplary embodiment, the triplet energy of the first host material T₁(H1) and a triplet energy of the first emitting compound T₁(D1) preferably satisfy a relationship of a numerical formula (Numerical Formula 20A) below.

$${T}_{1} ( D 1 ) > {T}_{1} ( H 1 ) \qquad ( Numerical Formula 20 A )$$

When the first host material and the first emitting compound satisfy the relationship of the numerical formula (Numerical Formula 20A), triplet excitons generated in the first emitting layer are transferred not onto the first emitting compound having higher triplet energy but onto the first host material, thereby being easily transferred to the second emitting layer.

The organic EL device according to the exemplary embodiment preferably satisfies a relationship of a numerical formula (Numerical Formula 20B) below.

$${T}_{1} ( D 1 ) > {T}_{1} ( H 1 ) > {T}_{1} ( H 2 ) \qquad ( Numerical Formula 20 B )$$

### Triplet Energy T₁

A method of measuring triplet energy T₁ is exemplified by a method below.

A measurement target compound is dissolved in EPA (diethylether isopentane:ethanol=5:5:2 in volume ratio) so as to fall within a range from 10⁻⁵ mol/L to 10⁻⁴ mol/L, and the obtained solution is encapsulated in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value λ_{edge} [nm] at an intersection of the tangent and the abscissa axis. The calculated energy amount is defined as triplet energy T₁.

$$Conversion Equation ( F 1 ) : {T}_{1} [ eV ] = 1239 \text{.85} / {λ}_{edge}$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-7000 produced by Hitachi High-Tech Science Corporation or a spectrophotofluorometer body F-4500 produced by Hitachi High-Technologies Corporation is usable. The measurement apparatus is not limited to this arrangement. A combination of a cooling unit, a low temperature container, an excitation light source and a light-receiving unit may be used for measurement.

### Singlet Energy S₁

A method of measuring the singlet energy S₁ with use of a solution (occasionally referred to as a solution method) is exemplified by a method below.

A toluene solution of a measurement target compound at a concentration ranging from 10⁻⁵ mol/L to 10⁻⁴ mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} [nm] at an intersection of the tangent and the abscissa axis is assigned to a conversion equation (F2) below to calculate singlet energy.

$$Conversion Equation ( F 2 ) : {S}_{1} [ eV ] = 1239 \text{.85} / {λ}_{edge}$$

Any apparatus for measuring the absorption spectrum is usable. For instance, a spectrophotometer (U3310 produced by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the organic EL device according to the exemplary embodiment, the first emitting layer preferably contains 0.5 mass % or more of the first emitting compound with respect to the total mass of the first emitting layer.

The first emitting layer contains the first emitting compound preferably at 10 mass % or less, more preferably at 7 mass % or less, and still more preferably at 5 mass % less with respect to the total mass of the first emitting layer.

In the organic EL device according to the exemplary embodiment, the first emitting layer contains a first compound as the first host material preferably at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The first emitting layer preferably contains the first host material at 99.5 mass % or less with respect to the total mass of the first emitting layer.

When the first emitting layer contains the first host material and the first emitting compound, the upper limit of the total of the content ratios of the first host material and the first emitting compound is 100 mass %.

In the organic EL device according to the exemplary embodiment, the film thickness of the first emitting layer is preferably 3 nm or more, more preferably 5 nm or more. When the film thickness of the first emitting layer is 3 nm or more, the film thickness is sufficiently large to cause recombination of holes and electrons in the first emitting layer.

In the organic EL device according to the exemplary embodiment, the film thickness of the first emitting layer is preferably 15 nm or less, more preferably 10 nm or less. When the film thickness of the first emitting layer is 15 nm or less, the film thickness is sufficiently thin to allow for transfer of triplet excitons to the second emitting layer.

In the organic EL device according to the exemplary embodiment, the film thickness of the first emitting layer is more preferably in a range from 3 nm to 15 nm.

### Second Emitting Layer

The second emitting layer contains the second host material. The second host material is a compound different from the first host material contained in the first emitting layer.

The second emitting layer preferably contains the second emitting compound. The second emitting compound is not particularly limited. The second emitting compound is preferably a compound that emits light having a maximum peak wavelength of 500 nm or less, more preferably a compound that emits light having a maximum peak wavelength of 480 nm or less, and still more preferably a compound that emits light having a maximum peak wavelength in a range from 430 nm to 480 nm. The second emitting compound is preferably a fluorescent compound that emits fluorescence having a maximum peak wavelength of 500 nm or less, more preferably a fluorescent compound that emits fluorescence having a maximum peak wavelength of 480 nm or less, and still more preferably a fluorescent compound that emits fluorescence having a maximum peak wavelength in a range from 430 nm to 480 nm.

A measurement method of the maximum peak wavelength of the compound is as follows.

In the organic EL device according to the exemplary embodiment, the second emitting layer preferably emits light having a maximum peak wavelength of 500 nm or less when the device is driven.

In the organic EL device according to the exemplary embodiment, a half bandwidth of a maximum peak of the second emitting compound is preferably in a range from 1 nm to 20 nm.

In the organic EL device according to the exemplary embodiment, a Stokes shift of the second emitting compound preferably exceeds 7 nm.

When the Stokes shift of the second emitting compound exceeds 7 nm, a decrease in luminous efficiency due to self-absorption is easily inhibited.

The self-absorption is a phenomenon in which emitted light is absorbed by the same compound to reduce luminous efficiency. The self-absorption is notably observed in a compound having a small Stokes shift (i.e., a large overlap between an absorption spectrum and a fluorescence spectrum). Accordingly, in order to reduce the self-absorption, it is preferable to use a compound having a large Stokes shift (i.e., a small overlap between the absorption spectrum and the fluorescence spectrum). The Stokes shift can be measured by the following method. A measurement target compound is dissolved in toluene at a concentration of 2.0×10⁻⁵ mol/L to prepare a measurement sample. The measurement sample is put into a quartz cell and is irradiated with continuous light falling within an ultraviolet-to-visible region at a room temperature (300K) to measure an absorption spectrum (ordinate axis: absorbance, abscissa axis: wavelength). A spectrophotometer such as a spectrophotometer U-3900/3900H produced by Hitachi High-Tech Science Corporation can be used for the absorption spectrum measurement. Moreover, a measurement target compound is dissolved in toluene at a concentration of 4.9×10⁻⁶ mol/L to prepare a measurement sample. The measurement sample was put into a quartz cell and was irradiated with excited light at a room temperature (300K) to measure a fluorescence spectrum (ordinate axis: fluorescence intensity, abscissa axis: wavelength). A spectrophotometer can be used for the fluorescence spectrum measurement. For instance, a spectrophotofluorometer F-7000 produced by Hitachi High-Tech Science Corporation can be used for the measurement. A difference between an absorption local maximum wavelength and a fluorescence local maximum wavelength is calculated from the absorption spectrum and the fluorescence spectrum to obtain a Stokes shift (SS). A unit of the Stokes shift (SS) is denoted by nm.

In the organic EL device according to the exemplary embodiment, a triplet energy of the second emitting compound T₁(D2) and the triplet energy of the second host material T₁(H2) preferably satisfy a relationship of a numerical formula (Numerical Formula 30A) below.

$${T}_{1} ( D 2 ) > {T}_{1} ( H 2 ) \qquad ( Numerical Formula 30 A )$$

In the organic EL device according to the exemplary embodiment, when the second emitting compound and the second host material satisfy the relationship of the numerical formula (Numerical Formula 30A), in transfer of triplet excitons generated in the first emitting layer to the second emitting layer, the triplet excitons energy-transfer not onto the second emitting compound having higher triplet energy but onto molecules of the second host material. In addition, triplet excitons generated by recombination of holes and electrons on the second host material do not transfer to the second emitting compound having higher triplet energy. Triplet excitons generated by recombination on molecules of the second emitting compound quickly energy-transfer to molecules of the second host material.

Triplet excitons in the second host material do not transfer to the second emitting compound but efficiently collide with one another on the second host material to generate singlet excitons by the TTF phenomenon.

In the organic EL device according to the exemplary embodiment, a singlet energy of the second host material S₁(H2) and a singlet energy of the second emitting compound S₁(D2) preferably satisfy a relationship of a numerical formula (Numerical Formula 4) below.

$${S}_{1} ( H 2 ) > {S}_{1} ( D 2 ) \qquad ( Numerical Formula 4 )$$

In the organic EL device according to the exemplary embodiment, when the second emitting compound and the second host material satisfy the relationship of the numerical formula (Numerical formula 4), due to the singlet energy of the second emitting compound being smaller than the singlet energy of the second host material, singlet excitons generated by the TTF phenomenon energy-transfer from the second host material to the second emitting compound, thereby contributing to fluorescence of the second emitting compound.

In the organic EL device according to the exemplary embodiment, the second emitting compound is preferably a compound containing no azine ring structure in a molecule.

In the organic EL device according to the exemplary embodiment, the second emitting compound is preferably not a boron-containing complex, more preferably not a complex.

For instance, examples of a compound that emits blue fluorescence and is usable for the second emitting layer include a pyrene derivative, styrylamine derivative, chrysene derivative, fluoranthene derivative, fluorene derivative, diamine derivative, and triarylamine derivative.

In the organic EL device according to the exemplary embodiment, the second emitting layer preferably does not contain a metal complex. Moreover, in the organic EL device according to the exemplary embodiment, the second emitting layer also preferably does not contain a boron-containing complex.

In the organic EL device according to the exemplary embodiment, the second emitting layer preferably does not contain a phosphorescent material (dopant material).

In addition, the second emitting layer preferably does not contain a heavy-metal complex and a phosphorescent rare earth metal complex. Examples of the heavy-metal complex herein include iridium complex, osmium complex, and platinum complex.

In the organic EL device according to the exemplary embodiment, the second emitting layer further preferably contains 0.5 mass % or more of the second emitting compound with respect to the total mass of the second emitting layer.

The second emitting layer contains the second emitting compound preferably at 10 mass % or less, more preferably at 7 mass % or less, and still more preferably at 5 mass % less with respect to the total mass of the second emitting layer.

The second emitting layer contains a second compound as the second host material preferably at 60 mass % or more, more preferably at 70 mass % or more, still more preferably at 80 mass % or more, still further more preferably at 90 mass % or more, and yet still further more preferably at 95 mass % or more, with respect to the total mass of the second emitting layer.

The second emitting layer preferably contains the second host material at 99.5 mass % or less with respect to the total mass of the second emitting layer.

When the second emitting layer contains the second host material and the second emitting compound, the upper limit of the total of the content ratios of the second host material and the second emitting compound is 100 mass %.

In the organic EL device according to the exemplary embodiment, the film thickness of the second emitting layer is preferably 5 nm or more, more preferably nm or more, and still more preferably 15 nm or more. When the film thickness of the second emitting layer is 5 nm or more, it is easy to inhibit triplet excitons having transferred from the first emitting layer to the second emitting layer from returning to the first emitting layer. Further, when the film thickness of the second emitting layer is 5 nm or more, triplet excitons can be sufficiently separated from the recombination portion in the first emitting layer.

In the organic EL device according to the exemplary embodiment, the film thickness of the second emitting layer is preferably 20 nm or less. When the film thickness of the second emitting layer is 20 nm or less, a density of the triplet excitons in the second emitting layer is improved to cause the TTF phenomenon more easily.

In the organic EL device according to the exemplary embodiment, the film thickness of the second emitting layer is preferably in a range from 5 nm to 20 nm.

In the organic EL device according to the exemplary embodiment, a triplet energy of the first emitting compound or the second emitting compound T₁(DX), the triplet energy of the first host material T₁(H1) and the triplet energy of the second host material T₁(H2) preferably satisfy a relationship of a numerical formula (Numerical Formula 9) below, more preferably satisfy a relationship of a numerical formula (Numerical Formula 10) below.

$$2.7 eV > {T}_{1} ( DX ) > {T}_{1} ( H 1 ) > {T}_{1} ( H 2 ) \qquad ( Numerical Formula 9 )$$

$$2.6 eV > {T}_{1} ( DX ) > {T}_{1} ( H 1 ) > {T}_{1} ( H 2 ) \qquad ( Numerical Formula 10 )$$

The triplet energy of the first emitting compound T₁(D1) preferably satisfies a relationship of a numerical formula (Numerical Formula 9A) below, more preferably satisfies a relationship of a numerical formula (Numerical Formula 10A) below.

$$2.7 eV > {T}_{1} ( D 1 ) > {T}_{1} ( H 1 ) > {T}_{1} ( H 2 ) \qquad ( Numerical Formula 9 A )$$

$$2.6 eV > {T}_{1} ( D 1 ) > {T}_{1} ( H 1 ) > {T}_{1} ( H 2 ) \qquad ( Numerical Formula 10 A )$$

The triplet energy of the second emitting compound T₁(D2) preferably satisfies a relationship of a numerical formula (Numerical Formula 9B) below, more preferably satisfies a relationship of a numerical formula (Numerical Formula 10B) below.

$$2.7 eV > {T}_{1} ( D 2 ) > {T}_{1} ( H 1 ) > {T}_{1} ( H 2 ) \qquad ( Numerical Formula 9 B )$$

$$2.6 eV > {T}_{1} ( D 2 ) > {T}_{1} ( H 1 ) > {T}_{1} ( H 2 ) \qquad ( Numerical Formula 10 B )$$

In the organic EL device according to the exemplary embodiment, the triplet energy of the first emitting compound or the second emitting compound T₁(DX) and the triplet energy of the first host material T₁(H1) preferably satisfy a relationship of a numerical formula (Numerical Formula 11) below.

$$0 eV < {T}_{1} ( DX ) - {T}_{1} ( H 1 ) < 0.6 eV \qquad ( Numerical Formula 11 )$$

The triplet energy of the first emitting compound T₁(D1) preferably satisfies a relationship of a numerical formula (Numerical Formula 11A) below.

$$0 eV < {T}_{1} ( D 1 ) - {T}_{1} ( H 1 ) < 0.6 eV \qquad ( Numerical Formula 11 A )$$

The triplet energy of the second emitting compound T₁(D2) preferably satisfies a relationship of a numerical formula (Numerical Formula 11B) below.

$$0 eV < {T}_{1} ( D 2 ) - {T}_{1} ( H 2 ) < 0.8 eV \qquad ( Numerical Formula 11 B )$$

In the organic EL device according to the exemplary embodiment, the triplet energy of the first host material T₁(H1) preferably satisfies a relationship of a numerical formula (Numerical Formula 12) below.

$${T}_{1} ( H1 ) > 2. eV \qquad ( Numerical Formula 12 )$$

In the organic EL device according to the exemplary embodiment, the triplet energy of the first host material T₁(H1) also preferably satisfies a relationship of a numerical formula (Numerical Formula 12A) below, or also preferably satisfies a relationship of a numerical formula (Numerical Formula 12B) below.

$${T}_{1} ( H1 ) > 2.1 eV \qquad ( Numerical Formula 12 A )$$

$${T}_{1} ( H 1 ) > 2.15 eV \qquad ( Numerical Formula 12 B )$$

In the organic EL device according to the exemplary embodiment, when the triplet energy of the first host material T₁(H1) satisfies the relationship of the numerical formula (Numerical Formula 12A) or the numerical formula (Numerical Formula 12B), triplet excitons generated in the first emitting layer are easily transferred to the second emitting layer, and also easily inhibited from back-transferring from the second emitting layer to the first emitting layer. Consequently, singlet excitons are efficiently generated in the second emitting layer, thereby improving luminous efficiency.

In the organic EL device according to the exemplary embodiment, the triplet energy of the first host material T₁(H1) also preferably satisfies a relationship of a numerical formula (Numerical Formula 12C) below, or also preferably satisfies a relationship of a numerical formula (Numerical Formula 12D) below.

$$2.08 eV > {T}_{1} ( H 1 ) > 187 eV \qquad ( Numerical Formula 12 C )$$

$$2.05 eV > {T}_{1} ( H 1 ) > 190 eV \qquad ( Numerical Formula 12 D )$$

In the organic EL device according to the exemplary embodiment, when the triplet energy of the first host material T₁(H1) satisfies the relationship of the numerical formula (Numerical Formula 12C) or the numerical formula (Numerical Formula 12D), energy of the triplet excitons generated in the first emitting layer is reduced, so that the organic EL device, specifically a blue-emitting organic EL device, can be expected to have a longer lifetime.

In the organic EL device according to the exemplary embodiment, the triplet energy of the first emitting compound T₁(D1) also preferably satisfies a relationship of a numerical formula (Numerical Formula 14A) below, or also preferably satisfies a relationship of a numerical formula (Numerical Formula 14B) below.

$$2.6 eV > {T}_{1} ( D 1 ) \qquad ( Numerical Formula 14 A )$$

$$2.5 eV > {T}_{1} ( D 1 ) \qquad ( Numerical Formula 14 B )$$

When the first emitting layer contains the first emitting compound that satisfies the relationship of the numerical formula (Numerical Formula 14A) or (Numerical Formula 14B), the organic EL device, specifically the blue-emitting organic EL device, has a longer lifetime.

In the organic EL device according to the exemplary embodiment, the triplet energy of the second emitting compound T₁(D2) also preferably satisfies a relationship of a numerical formula (Numerical Formula 14C) below, or also preferably satisfies a relationship of a numerical formula (Numerical Formula 14D) below.

$$2.6 eV > {T}_{1} ( D 2 ) \qquad ( Numerical Formula 14 C )$$

$$2.5 eV > {T}_{1} ( D2 ) \qquad ( Numerical Formula 14 D )$$

When the second emitting layer contains a compound that satisfies the relationship of the numerical formula (Numerical Formula 14C) or (Numerical Formula 14D), the organic EL device, specifically the blue-emitting organic EL device, has a longer lifetime.

In the organic EL device according to the exemplary embodiment, the triplet energy of the second host material T₁(H2) preferably satisfies a relationship of a numerical formula (Numerical Formula 13) below.

$${T}_{1} ( H 2 ) \geq 19 eV \qquad ( Numerical Formula 13 )$$

In the organic EL device according to the exemplary embodiment, when the first emitting layer and the second emitting layer are layered in this order from the side close to the anode, it is also preferable that an electron mobility of the first host material μe(H1) and an electron mobility of the second host material μe(H2) satisfy a relationship of a numerical formula (Numerical Formula 30) below.

$$μ e ( H 2 ) > μ e ( H 1 ) \qquad ( Numerical Formula 30 )$$

When the first host material and the second host material satisfy a relationship of the numerical formula (Numerical Formula 30), a recombination ability between holes and electrons in the first emitting layer is improved.

In the organic EL device according to the exemplary embodiment, when the first emitting layer and the second emitting layer are layered in this order from the side close to the anode, it is also preferable that a hole mobility of the first host material μh(H1) and a hole mobility of the second host material μh(H2) satisfy a relationship of a numerical formula (Numerical Formula 31) below.

$$μ h ( H 1 ) > μ h ( H 2 ) \qquad ( Numerical Formula 31 )$$

In the organic EL device according to the exemplary embodiment, when the first emitting layer and the second emitting layer are layered in this order from the side close to the anode, it is also preferable that the hole mobility of the first host material μh(H1), the electron mobility of the first host material μe(H1), the hole mobility of the second host material μh(H2) and the electron mobility of the second host material μe(H2) satisfy a relationship of a numerical formula (Numerical Formula 32) below.

$$( μ e ( H 2 ) / μ h ( H 2 ) ) > ( μ e ( H 1 ) / μ h ( H 2 ) ) \qquad ( Numerical Formula 32 )$$

### First Host Material and Second Host Material

In the organic EL device according to the exemplary embodiment, it is also preferable that the first host material and the second host material are each, for instance, a compound selected from the group consisting of the first compound represented by a formula (1) below, the first compound represented by a formula (1X), (12X), (13X), (14X), (15X), or (16X) below, and the second compound represented by a formula (2) below. Further, the first compound can be also used as the first host material and the second host material. In this case, the compound represented by the formula (1), (1X), (12X), (13X), (14X), (15X), or (16X) used as the second host material may be referred to as the second compound for convenience.

### First Compound

In the organic EL device according to the exemplary embodiment, the first compound is exemplified by a compound represented by the formula (1), (1X), (12X), (13X), (14X), (15X), or (16X).

### Compound Represented by Formula (1)

In the organic EL device according to the exemplary embodiment, the first compound is also preferably a compound represented by the formula (1). The first compound represented by the formula (1) has at least one group represented by a formula (11) below.

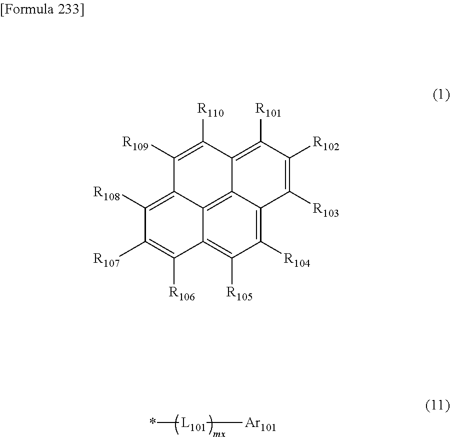

In the formula (1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (11);
at least one of R₁₀₁ to R₁₁₀ is a group represented by the formula (11);
when a plurality of groups represented by the formula (11) are present, the plurality of groups represented by the formula (11) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (11) represents a bonding position to a pyrene ring in the formula (1).

In the first compound represented by the formula (1), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary embodiment, Ar₁₀₁ is preferably a substituted or unsubstituted aryl group having 6 to 50 ring carbon atoms.

In an exemplary embodiment, Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted pyrenyl group, a substituted or unsubstituted phenanthryl group, or a substituted or unsubstituted fluorenyl group.

In an exemplary embodiment, the first compound is preferably represented by a formula (101) below.

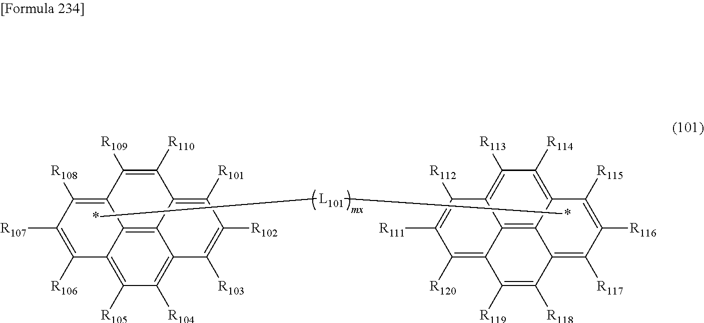

In the formula (101):
R₁₀₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
one of R₁₀₁ to R₁₁₀ represents a bonding position to L₁₀₁, and one of R₁₁₁ to R₁₂₀ represents a bonding position to L₁₀₁;
L₁₀₁ is a single bond, a substituted or unsubstituted arylene group having 6 to 50 ring carbon atoms, or a substituted or unsubstituted divalent heterocyclic group having 5 to 50 ring atoms;
mx is 0, 1, 2, 3, 4, or 5; and
when two or more L₁₀₁ are present, the two or more L₁₀₁ are mutually the same or different.

In an exemplary embodiment, L₁₀₁ is preferably a single bond or a substituted or unsubstituted arylene group having 6 to 50 ring carbon atoms.

In an exemplary embodiment, two or more of R₁₀₁ to R₁₁₀ are preferably a group represented by the formula (11).

In an exemplary embodiment, it is preferable that two or more of R₁₀₁ to R₁₁₀ are each a group represented by the formula (11) and Ar₁₀₁ is a substituted or unsubstituted aryl group having 6 to 50 ring carbon atoms.

In an exemplary embodiment, it is preferable that Ar₁₀₁ is not a substituted or unsubstituted pyrenyl group, L₁₀₁ is not a substituted or unsubstituted pyrenylene group, and the substituted or unsubstituted aryl group having 6 to 50 ring carbon atoms for R₁₀₁ to R₁₁₀ not being the group represented by the formula (11) is not a substituted or unsubstituted pyrenyl group.

In an exemplary embodiment, R₁₀₁ to R₁₁₀ not being the group represented by the formula (11) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary embodiment, R₁₀₁ to R₁₁₀ not being the group represented by the formula (11) are preferably each independently a hydrogen atom, a substituted or unsubstituted alkyl group having 1 to 50 carbon atoms, or a substituted or unsubstituted cycloalkyl group having 3 to 50 ring carbon atoms.

In an exemplary embodiment, R₁₀₁ to R₁₁₀ not being the group represented by the formula (11) are each preferably a hydrogen atom.

### Compound Represented by Formula (1X)

In the organic EL device according to the exemplary embodiment, the first compound is also preferably a compound represented by the formula (1X).

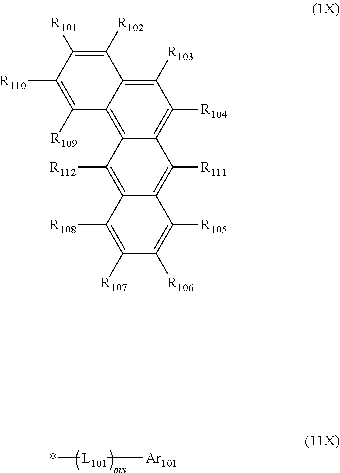

In the formula (1X):
R₁₀₁ to R₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (11X);
at least one of R₁₀₁ to R₁₁₂ is a group represented by the formula (11X);
when a plurality of groups represented by the formula (11X) are present, the plurality of groups represented by the formula (11X) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (11X) represents a bonding position to a benz[a]anthracene ring in the formula (1X).

In the organic EL device according to the exemplary embodiment, the group represented by the formula (11X) is preferably a group represented by a formula (111X) below.

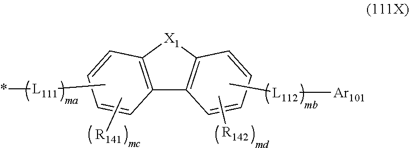

In the formula (111X):
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 1, 2, 3 or 4;
mb is 1, 2, 3 or 4;
ma+mb is 2, 3, or 4;
Ar₁₀₁ represents the same as Ar₁₀₁ in the formula (11X);
R₁₄₁, R₁₄₂, R₁₄₃, R₁₄₄ and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

Among positions *1 to *8 of carbon atoms in a cyclic structure represented by a formula (111aX) below in the group represented by the formula (111X), L₁₁₁ is bonded to one of the positions *1 to *4, R₁₄₁ is bonded to each of three positions of the rest of *1 to *4, L₁₁₂ is bonded to one of the positions *5 to *8, and R₁₄₂ is bonded to each of three positions of the rest of *5 to *8.

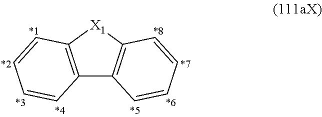

For instance, in the group represented by the formula (111X), when L₁₁₁ is bonded to a carbon atom at *2 in the cyclic structure represented by the formula (111aX) and L₁₁₂ is bonded to a carbon atom at *7 in the cyclic structure represented by the formula (111aX), the group represented by the formula (111X) is represented by a formula (111 bX) below.

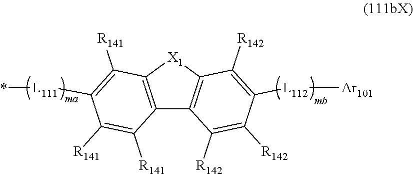

In the formula (111 bX):
X₁, L₁₁₁, L₁₁₂, ma, mb, Ar₁₀₁, R₁₄₁, R₁₄₂, R₁₄₃, R₁₄₄ and R₁₄₅ each independently represent the same as X₁, L₁₁₁, L₁₁₂, ma, mb, Ar₁₀₁, R₁₄₁, R₁₄₂, R₁₄₃, R₁₄₄ and R₁₄₅ in the formula (111X);
a plurality of R₁₄₁ are mutually the same or different; and
a plurality of R₁₄₂ are mutually the same or different.

In the organic EL device according to the exemplary embodiment, the group represented by the formula (111X) is preferably a group represented by the formula (111bX).

In the compound represented by the formula (1X), preferably, ma is 1 or 2 and mb is 1 or 2.

In the compound represented by the formula (1X), preferably, ma is 1 and mb is 1.

In the compound represented by the formula (1X), Ar₁₀₁ is preferably a substituted or unsubstituted aryl group having 6 to 50 ring carbon atoms.

In the compound represented by the formula (1X), Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted benz[a]anthryl group, a substituted or unsubstituted pyrenyl group, a substituted or unsubstituted phenanthryl group, or a substituted or unsubstituted fluorenyl group.

The compound represented by the formula (1X) is also preferably represented by a formula (101X) below.

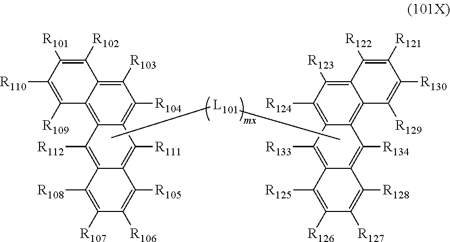

In the formula (101X):
one of R₁₁₁ and R₁₁₂ represents a bonding position to L₁₀₁ and one of R₁₃₃ and R₁₃₄ represents a bonding position to L₁₀₁;
R₁₀₁ to R₁₁₀, R₁₂₁ to R₁₃₀, R₁₁₁ or R₁₁₂ not being the bonding position to L₁₀₁, and R₁₃₃ or R₁₃₄ not being the bonding position to L₁₀₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₀₁ is a single bond, a substituted or unsubstituted arylene group having 6 to 50 ring carbon atoms, or a substituted or unsubstituted divalent heterocyclic group having 5 to 50 ring atoms;
mx is 1, 2, 3, 4, or 5; and
when two or more L₁₀₁ are present, the two or more L₁₀₁ are mutually the same or different.

In the compound represented by the formula (1X), L₁₀₁ is preferably a single bond, or a substituted or unsubstituted arylene group having 6 to 50 ring carbon atoms.

The compound represented by the formula (1X) is also preferably represented by a formula (102X) below.

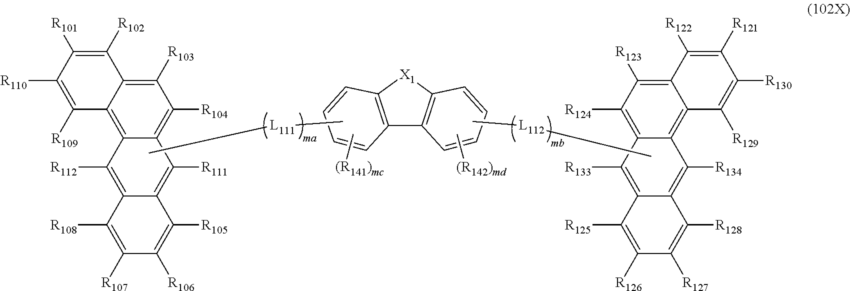

In the formula (102X):
one of R₁₁₁ and R₁₁₂ represents a bonding position to L₁₁ and one of R₁₃₃ and R₁₃₄ represents a bonding position to L₁₁₂;
R₁₀₁ to R₁₁₀, R₁₂₁ to R₁₃₀, R₁₁₁ or R₁₁₂ not being the bonding position to L₁₁₁, and R₁₃₃ or R₁₃₄ not being the bonding position to L₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 1, 2, 3 or 4;
mb is 1, 2, 3 or 4;
ma+mb is 2, 3, 4, or 5;
R₁₄₁, R₁₄₂, R₁₄₃, R₁₄₄ and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

In the compound represented by the formula (1X), preferably, ma is 1 or 2 and mb is 1 or 2 in the formula (102X).

In the compound represented by the formula (1X), preferably, ma is 1 and mb is 1 in the formula (102X).

In the compound represented by the formula (1X), the group represented by the formula (11X) is also preferably a group represented by a formula (11AX) or a group represented by a formula (11 BX) below.

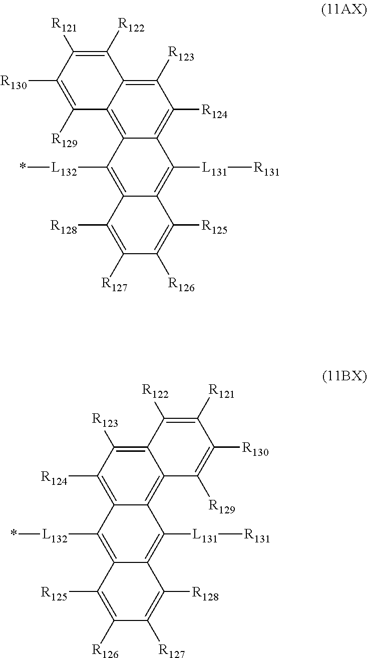

In the formulae (11 AX) and (11 BX):
R₁₂₁ to R₁₃₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
when a plurality of groups represented by the formula (11 AX) are present, the plurality of groups represented by the formula (11AX) are mutually the same or different;
when a plurality of groups represented by the formula (11 BX) are present, the plurality of groups represented by the formula (11 BX) are mutually the same or different;
L₁₃₁ and L₁₃₂ are each independently a single bond, a substituted or unsubstituted arylene group having 6 to 50 ring carbon atoms, or a substituted or unsubstituted divalent heterocyclic group having 5 to 50 ring atoms; and
* in each of the formulae (11 AX) and (11 BX) represents a bonding position to a benz[a]anthracene ring in the formula (1X).

The compound represented by the formula (1X) is also preferably represented by a formula (103X) below.

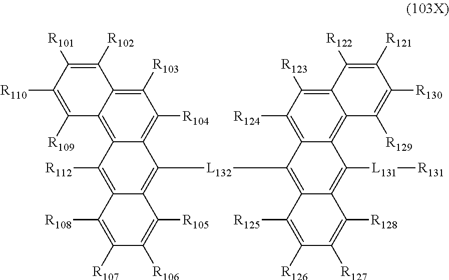

In the formula (103X):
R₁₀₁ to R₁₁₀ and R₁₁₂ respectively represent the same as R₁₀₁ to R₁₁₀ and R₁₁₂ in the formula (1X); and
R₁₂₁ to R₁₃₁, L₁₃₁, and L₁₃₂ respectively represent the same as R₁₂₁ to R₁₃₁, L₁₃₁, and L₁₃₂ in the formula (11BX).

In the compound represented by the formula (1X), L₁₃₁ is also preferably a substituted or unsubstituted arylene group having 6 to 50 ring carbon atoms.

In the compound represented by the formula (1X), L₁₃₂ is also preferably a substituted or unsubstituted arylene group having 6 to 50 ring carbon atoms.

In the compound represented by the formula (1X), two or more of R₁₀₁ to R₁₁₂ are each also preferably a group represented by the formula (11X).

In the compound represented by the formula (1X), it is preferable that two or more of R₁₀₁ to R₁₁₂ are each a group represented by the formula (11X) and Ar₁₀₁ in the formula (11X) is a substituted or unsubstituted aryl group having 6 to 50 ring carbon atoms.

In the compound represented by the formula (1X), it is also preferable that Ar₁₀₁ is not a substituted or unsubstituted benz[a]anthryl group, L₁₀₁ is not a substituted or unsubstituted benz[a]anthrylene group, and the substituted or unsubstituted aryl group having 6 to 50 ring carbon atoms for R₁₀₁ to R₁₁₀ not being the group represented by the formula (11X) is not a substituted or unsubstituted benz[a]anthryl group.

In the compound represented by the formula (1X), R₁₀₁ to R₁₁₂ not being the group represented by the formula (11X) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound represented by the formula (1X), R₁₀₁ to R₁₁₂ not being the group represented by the formula (11X) are each preferably a hydrogen atom, a substituted or unsubstituted alkyl group having 1 to 50 carbon atoms, or a substituted or unsubstituted cycloalkyl group having 3 to 50 ring carbon atoms.

In the compound represented by the formula (1X), R₁₀₁ to R₁₁₂ not being the group represented by the formula (11X) are each preferably a hydrogen atom.

Compound Represented by Formula (12X) In the organic EL device according to the exemplary embodiment, the first compound is also preferably a compound represented by the formula (12X).

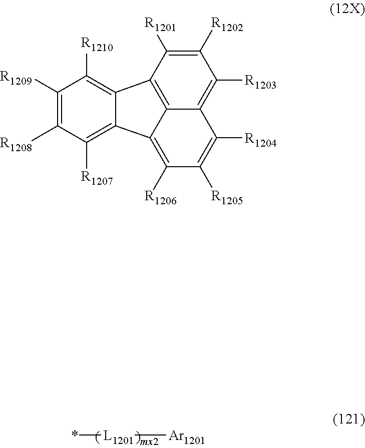

In the formula (12X):
at least one combination of adjacent two or more of R₁₂₀₁ to R₁₂₁₀ are mutually bonded to form a substituted or unsubstituted monocyclic ring, or mutually bonded to form a substituted or unsubstituted fused ring;
R₁₂₀₁ to R₁₂₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (121);
at least one of a substituent, if present, for the substituted or unsubstituted monocyclic ring, a substituent, if present, for the substituted or unsubstituted fused ring, or R₁₂₀₁ to R₁₂₁₀ is a group represented by the formula (121);
when a plurality of groups represented by the formula (121) are present, the plurality of groups represented by the formula (121) are mutually the same or different;
L₁₂₀₁ is a single bond, a substituted or unsubstituted arylene group having 6 to 50 ring carbon atoms, or a substituted or unsubstituted divalent heterocyclic group having 5 to 50 ring atoms;
Ar₁₂₀₁ is a substituted or unsubstituted aryl group having 6 to 50 ring carbon atoms, or a substituted or unsubstituted heterocyclic group having 5 to 50 ring atoms;
mx2 is 0, 1, 2, 3, 4, or 5;
when two or more L₁₂₀₁ are present, the two or more L₁₂₀₁ are mutually the same or different;
when two or more Ar₁₂₀₁ are present, the two or more Ar₁₂₀₁ are mutually the same or different; and
* in the formula (121) represents a bonding position to a ring represented by the formula (12X).

In the formula (12X), combinations of adjacent two of R₁₂₀₁ to R₁₂₁₀ refer to a combination of R₁₂₀₁ and R₁₂₀₂, a combination of R₁₂₀₂ and R₁₂₀₃, a combination of R₁₂₀₃ and R₁₂₀₄, a combination of R₁₂₀₄ and R₁₂₀₅, a combination of R₁₂₀₅ and R₁₂₀₆, a combination of R₁₂₀₇ and R₁₂₀₈, a combination of R₁₂₀₈ and R₁₂₀₉, and a combination of R₁₂₀₉ and R₁₂₁₀.

### Compound Represented by Formula (13X)

In the organic EL device according to the exemplary embodiment, the first compound is also preferably a compound represented by the formula (13X).

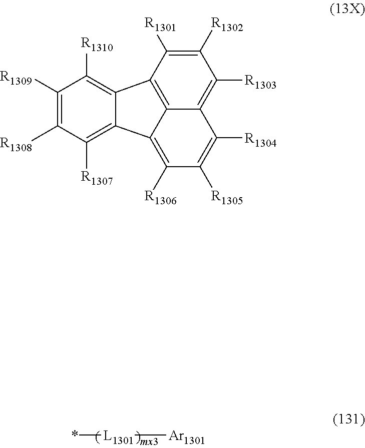

In the formula (13X):
R₁₃₀₁ to R₁₃₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (131);
at least one of R₁₃₀₁ to R₁₃₁₀ is a group represented by the formula (131);
when a plurality of groups represented by the formula (131) are present, the plurality of groups represented by the formula (131) are mutually the same or different;
L₁₃₀₁ is a single bond, a substituted or unsubstituted arylene group having 6 to 50 ring carbon atoms, or a substituted or unsubstituted divalent heterocyclic group having 5 to 50 ring atoms;
Ar₁₃₀₁ is a substituted or unsubstituted aryl group having 6 to 50 ring carbon atoms, or a substituted or unsubstituted heterocyclic group having 5 to 50 ring atoms;
mx3 is 0, 1, 2, 3, 4, or 5;
when two or more L₁₃₀₁ are present, the two or more L₁₃₀₁ are mutually the same or different;
when two or more Ar₁₃₀₁ are present, the two or more Ar₁₃₀₁ are mutually the same or different; and
* in the formula (131) represents a bonding position to a fluoranthene ring in the formula (13X).

In the organic EL device according to the exemplary embodiment, none of combinations of adjacent two or more of R₁₃₀₁ to R₁₃₁₀ not being the group represented by the formula (131) are bonded to each other. Combinations of adjacent two of R₁₃₀₁ to R₁₃₁₀ in the formula (13X) refer to a combination of R₁₃₀₁ and R₁₃₀₂, a combination of R₁₃₀₂ and R₁₃₀₃, a combination of R₁₃₀₃ and R₁₃₀₄, a combination of R₁₃₀₄ and R₁₃₀₅, a combination of R₁₃₀₅ and R₁₃₀₆, a combination of R₁₃₀₇ and R₁₃₀₈, a combination of R₁₃₀₈ and R₁₃₀₉, and a combination of R₁₃₀₉ and R₁₃₁₀.

### Compound Represented by Formula (14X)

In the organic EL device according to the exemplary embodiment, the first compound is also preferably a compound represented by the formula (14X).

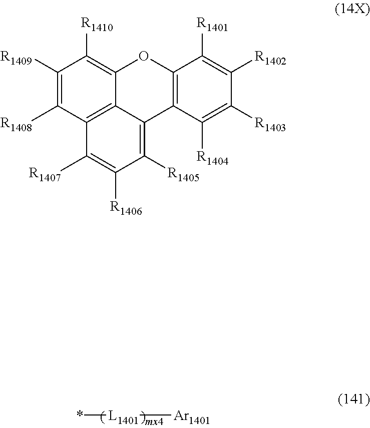

In the formula (14X):
R₁₄₀₁ to R₁₄₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (141);
at least one of R₁₄₀₁ to R₁₄₁₀ is a group represented by the formula (141);
when a plurality of groups represented by the formula (141) are present, the plurality of groups represented by the formula (141) are mutually the same or different;
L₁₄₀₁ is a single bond, a substituted or unsubstituted arylene group having 6 to 50 ring carbon atoms, or a substituted or unsubstituted divalent heterocyclic group having 5 to 50 ring atoms;
Ar₁₄₀₁ is a substituted or unsubstituted aryl group having 6 to 50 ring carbon atoms, or a substituted or unsubstituted heterocyclic group having 5 to 50 ring atoms;
mx4 is 0, 1, 2, 3, 4, or 5;
when two or more L₁₄₀₁ are present, the two or more L₁₄₀₁ are mutually the same or different;
when two or more Ar₁₄₀₁ are present, the two or more Ar₁₄₀₁ are mutually the same or different; and
* in the formula (141) represents a bonding position to a ring represented by the formula (14X).

### Compound Represented by Formula (15X)

In the organic EL device according to the exemplary embodiment, the first compound is also preferably a compound represented by the formula (15X).

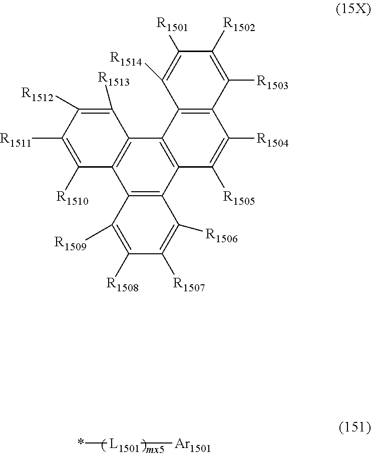

In the formula (15X):
R₁₅₀₁ to R₁₅₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (151);
at least one of R₁₅₀₁ to R₁₅₁₄ is a group represented by the formula (151);
when a plurality of groups represented by the formula (151) are present, the plurality of groups represented by the formula (151) are mutually the same or different;
L₁₅₀₁ is a single bond, a substituted or unsubstituted arylene group having 6 to 50 ring carbon atoms, or a substituted or unsubstituted divalent heterocyclic group having 5 to 50 ring atoms;
Ar₁₅₀₁ is a substituted or unsubstituted aryl group having 6 to 50 ring carbon atoms, or a substituted or unsubstituted heterocyclic group having 5 to 50 ring atoms;
mx5 is 0, 1, 2, 3, 4, or 5;
when two or more L₁₅₀₁ are present, the two or more L₁₅₀₁ are mutually the same or different;
when two or more Ar₁₅₀₁ are present, the two or more Ar₁₅₀₁ are mutually the same or different; and
* in the formula (151) represents a bonding position to a ring represented by the formula (15X).

### Compound Represented by Formula (16X)

In the organic EL device according to the exemplary embodiment, the first compound is also preferably a compound represented by the formula (16X).

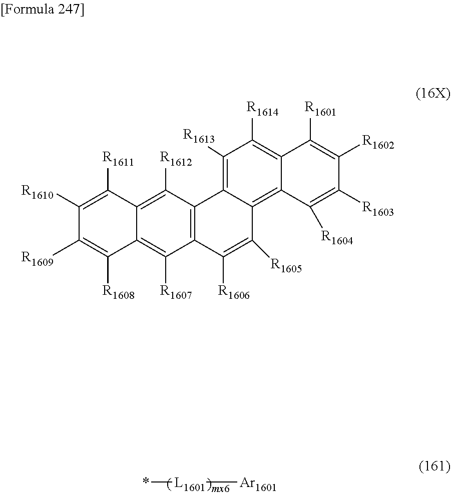

In the formula (16X):
R₁₆₀₁ to R₁₆₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (161);
at least one of R₁₆₀₁ to R₁₆₁₄ is a group represented by the formula (161);
when a plurality of groups represented by the formula (161) are present, the plurality of groups represented by the formula (161) are mutually the same or different;
L₁₆₀₁ is a single bond, a substituted or unsubstituted arylene group having 6 to 50 ring carbon atoms, or a substituted or unsubstituted divalent heterocyclic group having 5 to 50 ring atoms;
Ar₁₆₀₁ is a substituted or unsubstituted aryl group having 6 to 50 ring carbon atoms, or a substituted or unsubstituted heterocyclic group having 5 to 50 ring atoms;
mx6 is 0, 1, 2, 3, 4, or 5;
when two or more L₁₆₀₁ are present, the two or more L₁₆₀₁ are mutually the same or different;
when two or more Ar₁₆₀₁ are present, the two or more Ar₁₆₀₁ are mutually the same or different; and
* in the formula (161) represents a bonding position to a ring represented by the formula (16X).

In the organic EL device according to the exemplary embodiment, it is also preferable that the first host material has, in a molecule, a linking structure including a benzene ring and a naphthalene ring that are linked with a single bond, in which the benzene ring and the naphthalene ring in the linking structure are each independently fused or not fused with a further monocyclic ring or fused ring, and the benzene ring and the naphthalene ring in the linking structure are further linked to each other by cross-linking at at least one site other than the single bond.

When the first host material has the linking structure including such cross-linking, deterioration in the chromaticity of the organic EL device is expected to be inhibited.

The first host material in the above case is only required to have a linking structure as the minimum unit in a molecule, the linking structure including a benzene ring and a naphthalene ring linked to each other with a single bond (occasionally referred to as a benzene-naphthalene linking structure), the linking structure being as represented by a formula (X1) or a formula (X2) below. The benzene ring may be fused with a further monocyclic ring or fused ring, and the naphthalene ring may be fused with a further monocyclic ring or fused ring. For instance, also in a case where the first host material has, in a molecule, a linking structure including a naphthalene ring and a naphthalene ring linked to each other with a single bond (occasionally referred to as a naphthalene-naphthalene linking structure) and being as represented by a formula (X3), a formula (X4), or a formula (X5) below, the naphthalene-naphthalene linking structure is regarded as including the benzene-naphthalene linking structure since one of the naphthalene rings includes a benzene ring.

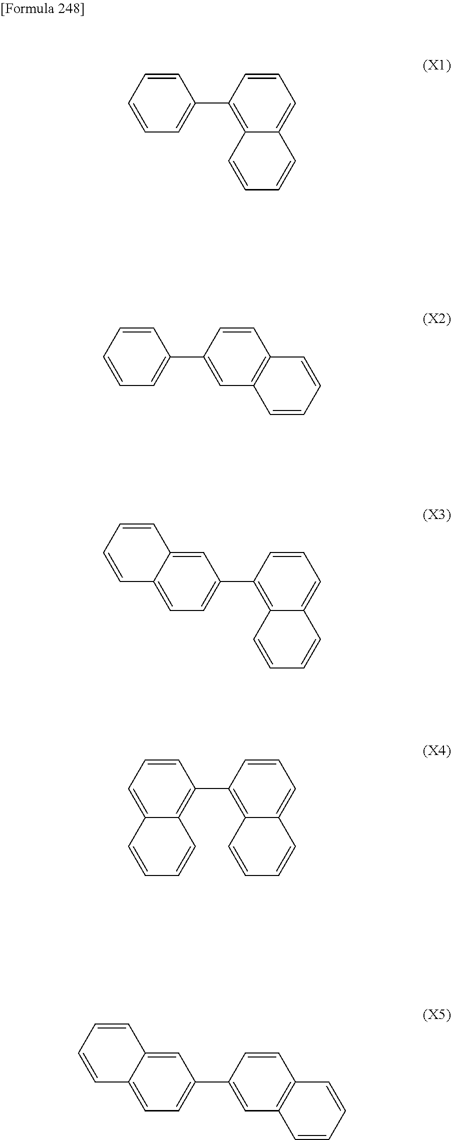

In the organic EL device according to the exemplary embodiment, the cross-linking also preferably includes a double bond.

Specifically, the first host material also preferably has a structure in which the benzene ring and the naphthalene ring are further linked to each other at any other site than the single bond by the cross-linking structure including a double bond.

Assuming that the benzene ring and the naphthalene ring in the benzene-naphthalene linking structure are further linked to each other at at least one site other than the single bond by cross-linking, for instance, a linking structure (fused ring) represented by a formula (X11) below is obtained in a case of the formula (X1), and a linking structure (fused ring) represented by a formula (X31) below is obtained in a case of the formula (X3).

Assuming that the benzene ring and the naphthalene ring in the benzene-naphthalene linking structure are further linked to each other at any other site than the single bond by cross-linking including a double bond, for instance, a linking structure (fused ring) represented by a formula (X12) below is obtained in a case of the formula (X1), a linking structure (fused ring) represented by a formula (X21) or formula (X22) below is obtained in a case of the formula (X2), a linking structure (fused ring) represented by a formula (X41) below is obtained in a case of the formula (X4), and a linking structure (fused ring) represented by a formula (X51) below is obtained in a case of the formula (X5).

Assuming that the benzene ring and the naphthalene ring in the benzene-naphthalene linking structure are further linked to each other at at least one site other than the single bond by cross-linking including a hetero atom (e.g., an oxygen atom), for instance, a linking structure (fused ring) represented by a formula (X13) below is obtained in a case of the formula (X1).

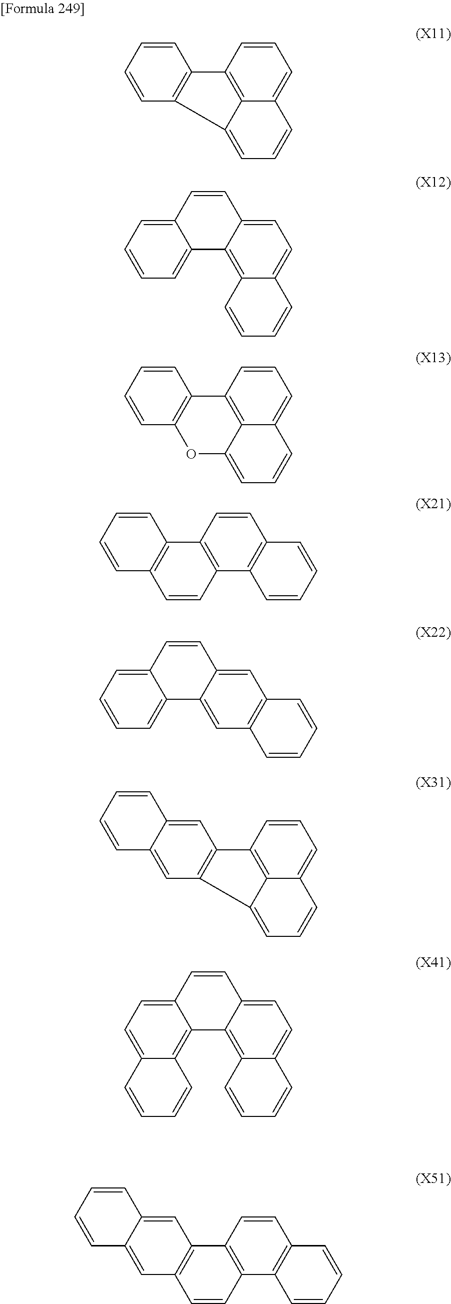

In the organic EL device according to the exemplary embodiment, also preferably, the first host material has, in a molecule, a biphenyl structure including a first benzene ring and a second benzene ring linked to each other with a single bond, and the first benzene ring and the second benzene ring in the biphenyl structure are further linked to each other by cross-linking at at least one site other than the single bond.

In the organic EL device according to the exemplary embodiment, also preferably, the first benzene ring and the second benzene ring in the biphenyl structure are further linked to each other by the cross-linking at one site other than the single bond. When the first host material has the biphenyl structure including such cross-linking, deterioration in the chromaticity of the organic EL device is expected to be inhibited.

In the organic EL device according to the exemplary embodiment, the cross-linking also preferably includes a double bond.

In the organic EL device according to the exemplary embodiment, the cross-linking also preferably includes no double bond.

Also preferably, the first benzene ring and the second benzene ring in the biphenyl structure are further linked to each other by the cross-linking at two sites other than the single bond.

In the organic EL device according to the exemplary embodiment, also preferably, the first benzene ring and the second benzene ring in the biphenyl structure are further linked to each other by the cross-linking at two sites other than the single bond, and the cross-linking includes no double bond. When the first host material has the biphenyl structure including such cross-linking, deterioration in the chromaticity of the organic EL device is expected to be inhibited.

For instance, assuming that the first benzene ring and the second benzene ring in the biphenyl structure represented by a formula (BP1) below are further linked to each other by cross-linking at at least one site other than the single bond, the biphenyl structure is exemplified by linking structures (fused rings) represented by formulae (BP11) to (BP15) below.

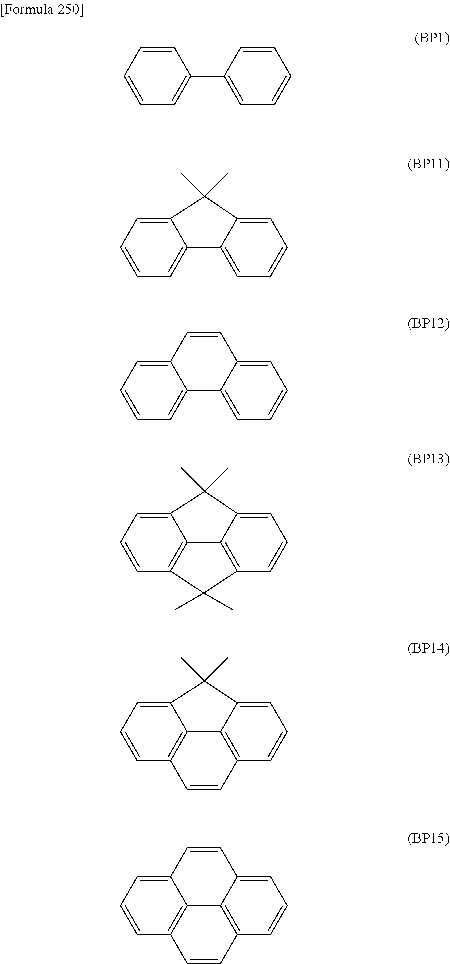

The formula (BP11) represents a linking structure in which the first benzene ring and the second benzene ring are linked to each other at one site other than the single bond by cross-linking including no double bond.

The formula (BP12) represents a linking structure in which the first benzene ring and the second benzene ring are linked to each other at one site other than the single bond by cross-linking including a double bond.

The formula (BP13) represents a linking structure in which the first benzene ring and the second benzene ring are linked to each other at two sites other than the single bond by cross-linking including no double bond.

The formula (BP14) represents a linking structure in which the first benzene ring and the second benzene ring are linked to each other by cross-linking including no double bond at one of two sites other than the single bond, and the first benzene ring and the second benzene ring are linked to each other by cross-linking including a double bond at the other of the two sites other than the single bond.

The formula (BP15) represents a linking structure in which the first benzene ring and the second benzene ring are linked to each other at two sites other than the single bond by cross-linking including a double bond.

In the first compound and the second compound, the groups specified to be “substituted or unsubstituted” are each preferably an “unsubstituted” group.

### Method of Producing First Compound

The first compound usable in the organic EL device according to the exemplary embodiment can be produced by a known method. The first compound can also be produced based on a known method through a known alternative reaction using a known material(s) tailored for the target compound.

### Specific Examples of First Compound

Specific examples of the first compound usable in the organic EL device according to the exemplary embodiment include the following compounds. It should however be noted that the invention is not limited to the specific examples of the first compound.

In the specific examples of the compound herein, D represents a deuterium atom, Me represents a methyl group, and tBu represents a tert-butyl group.

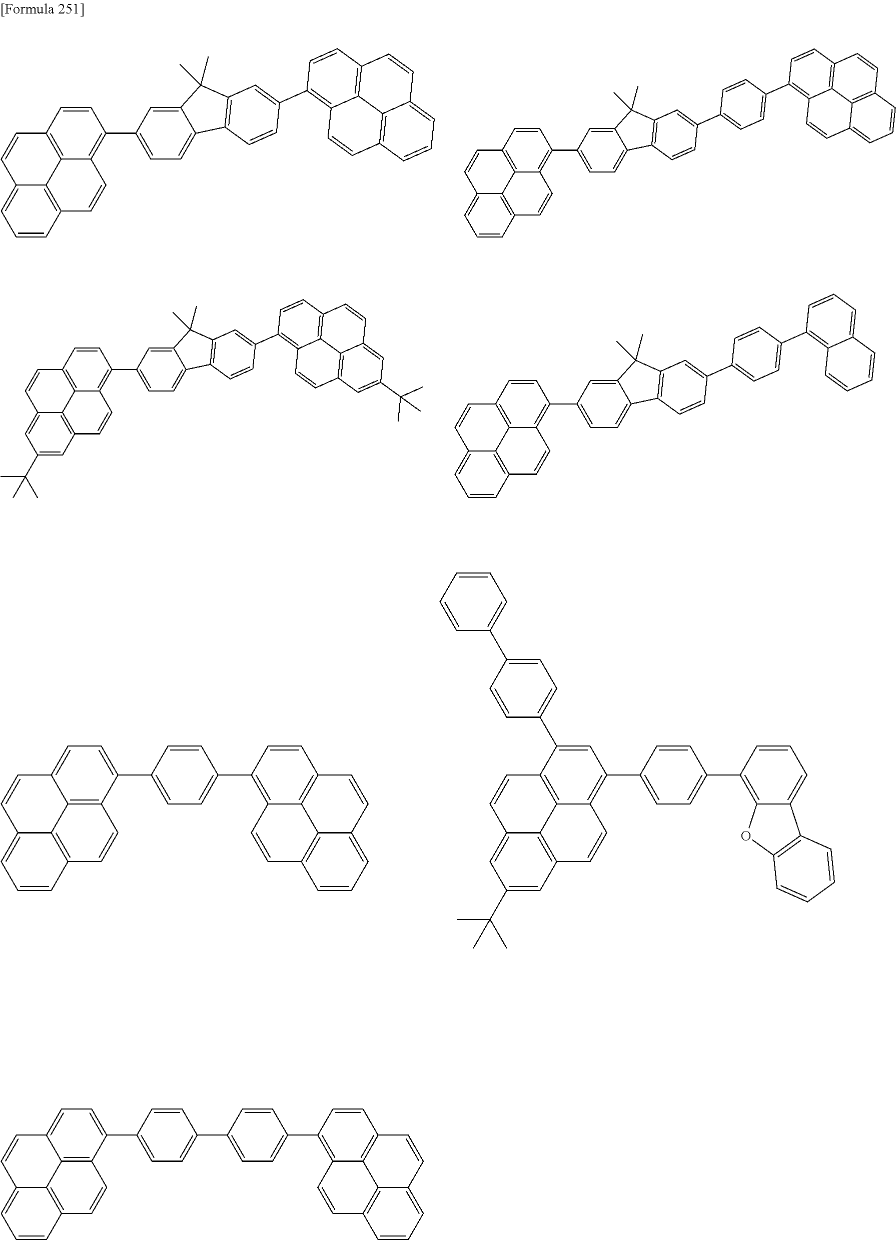

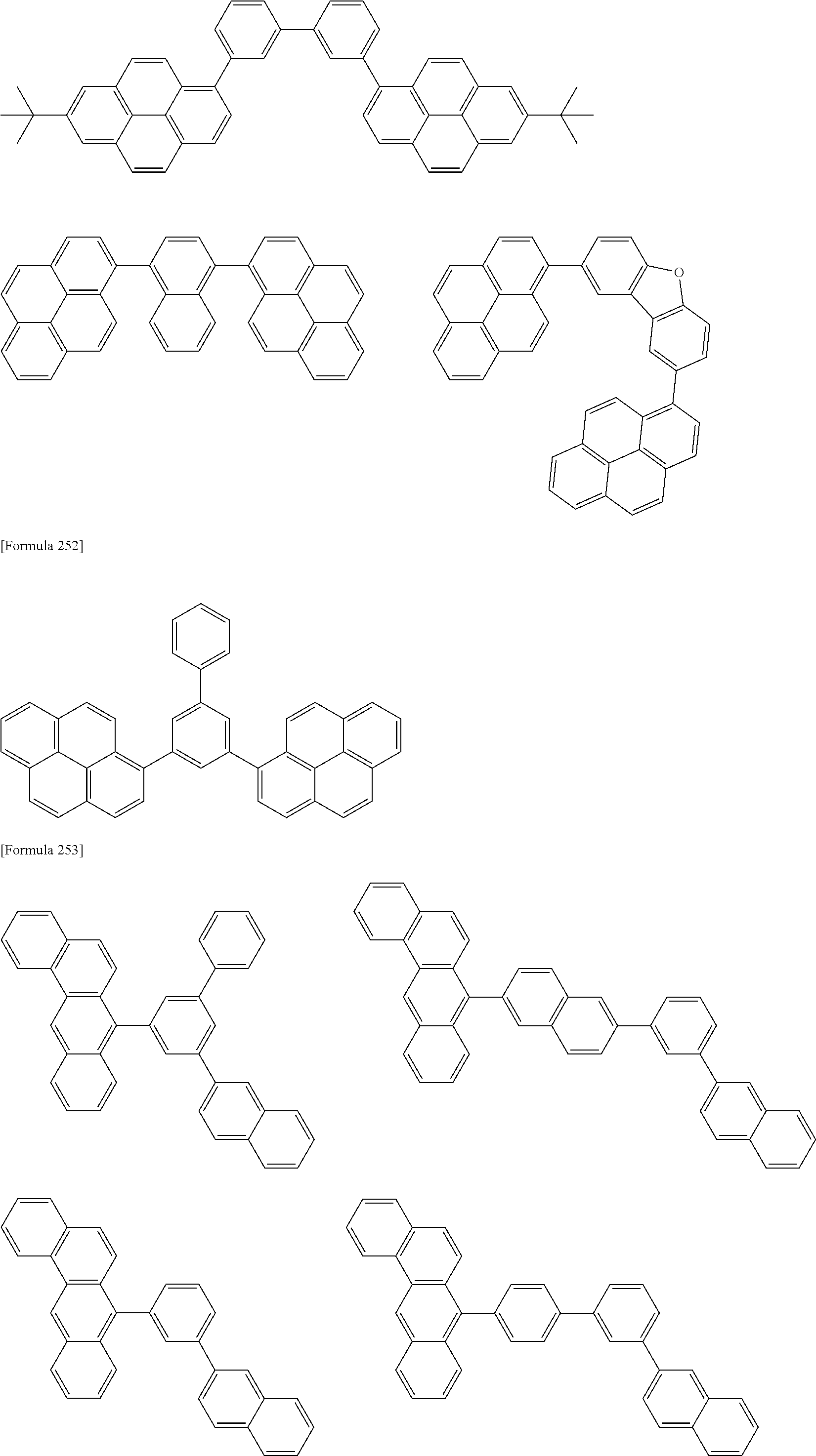

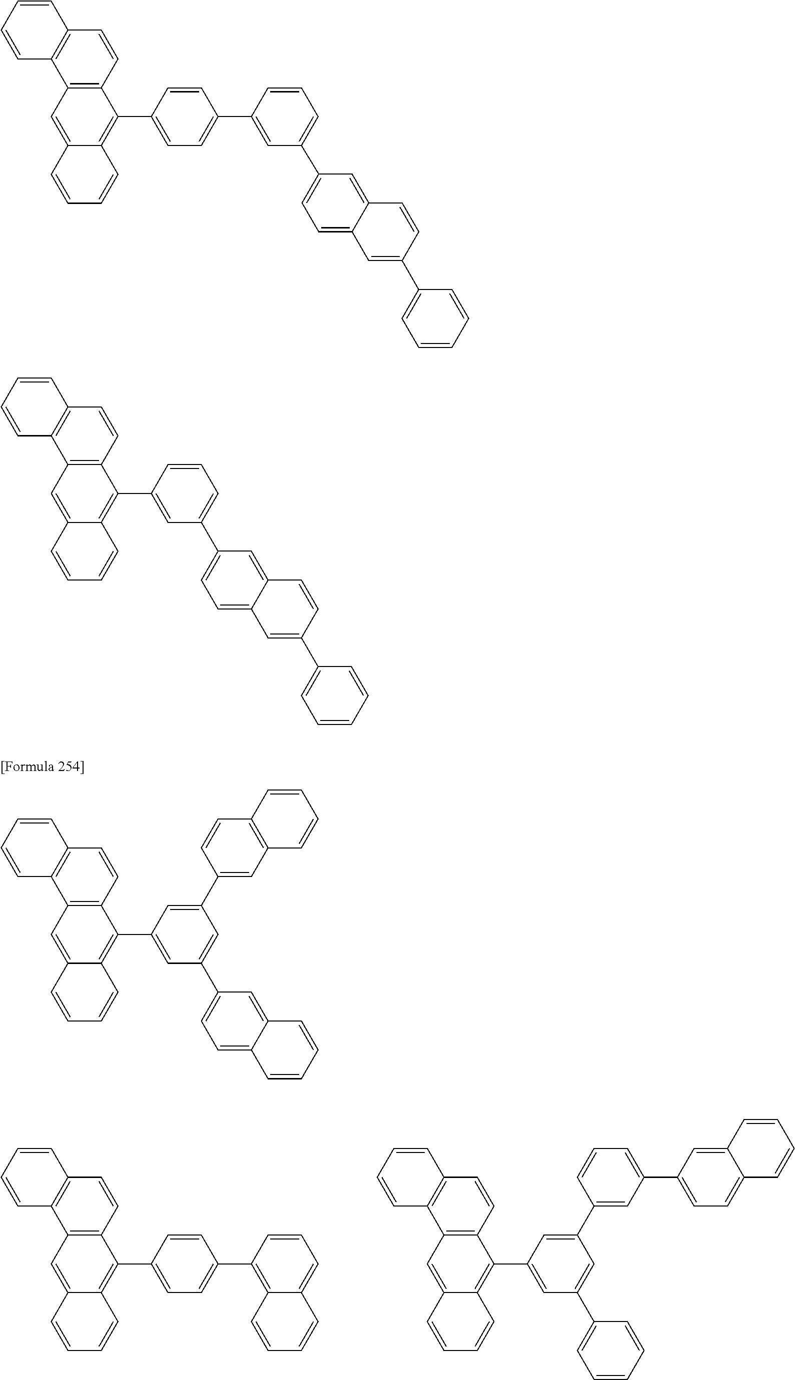

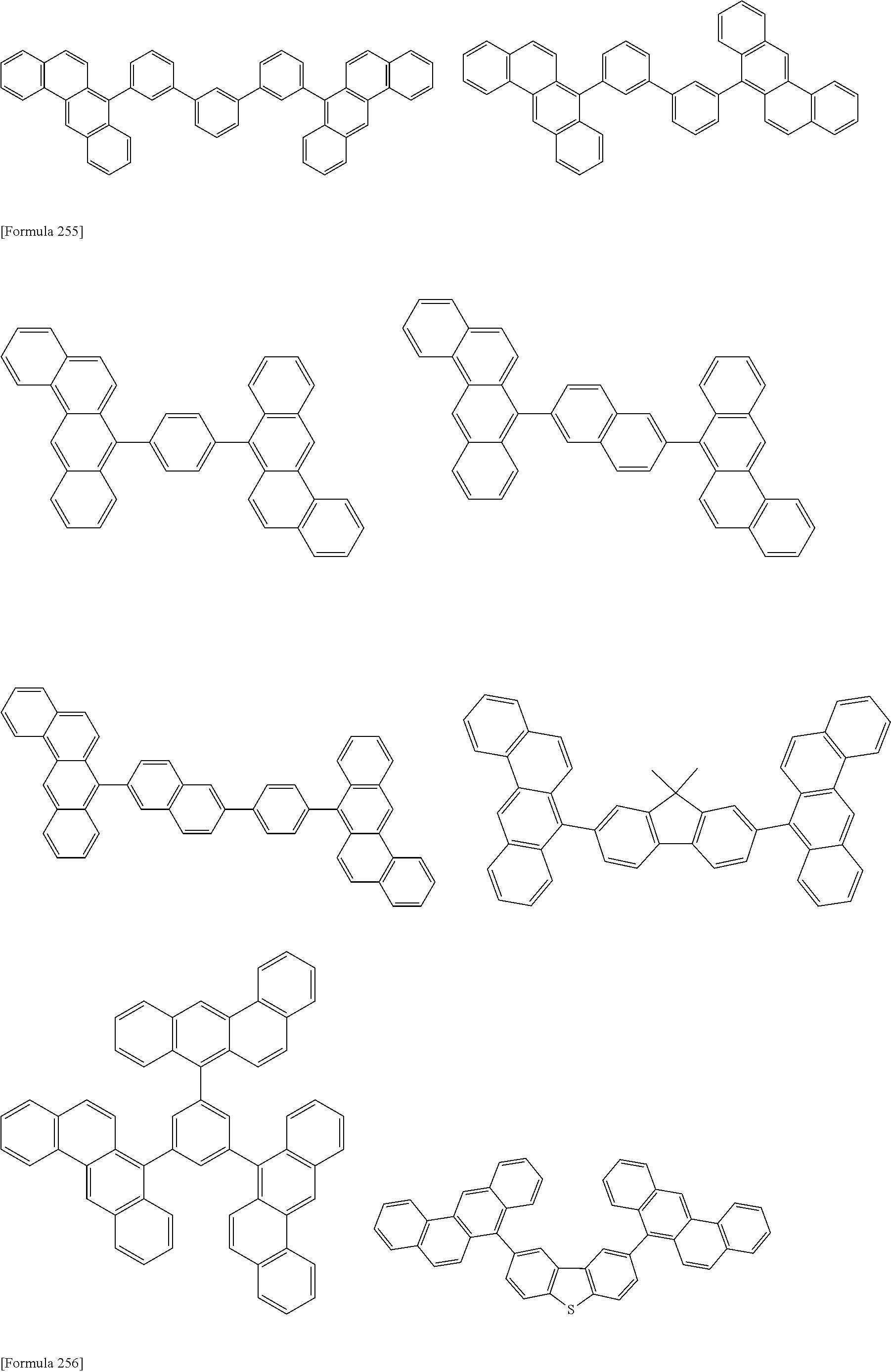

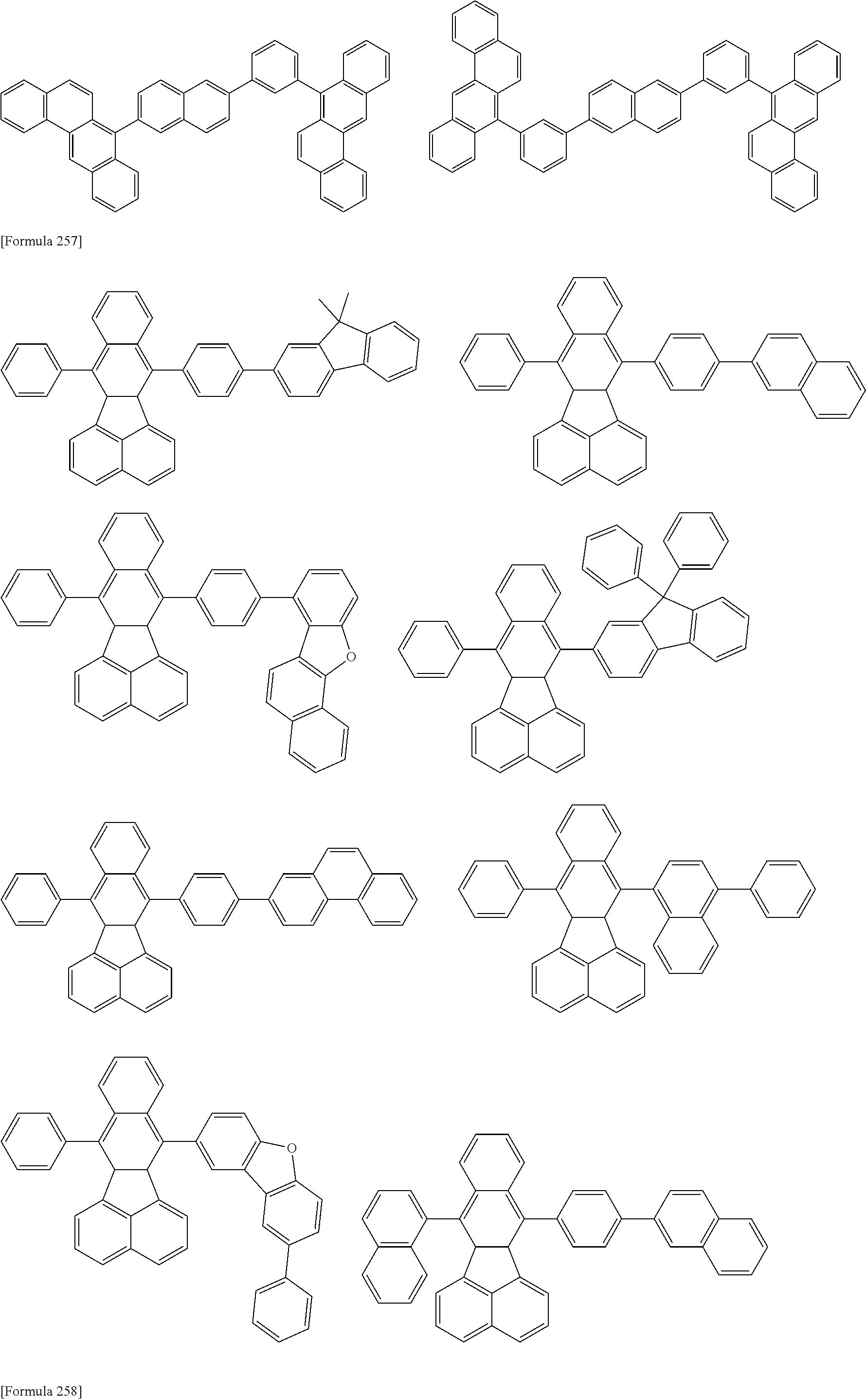

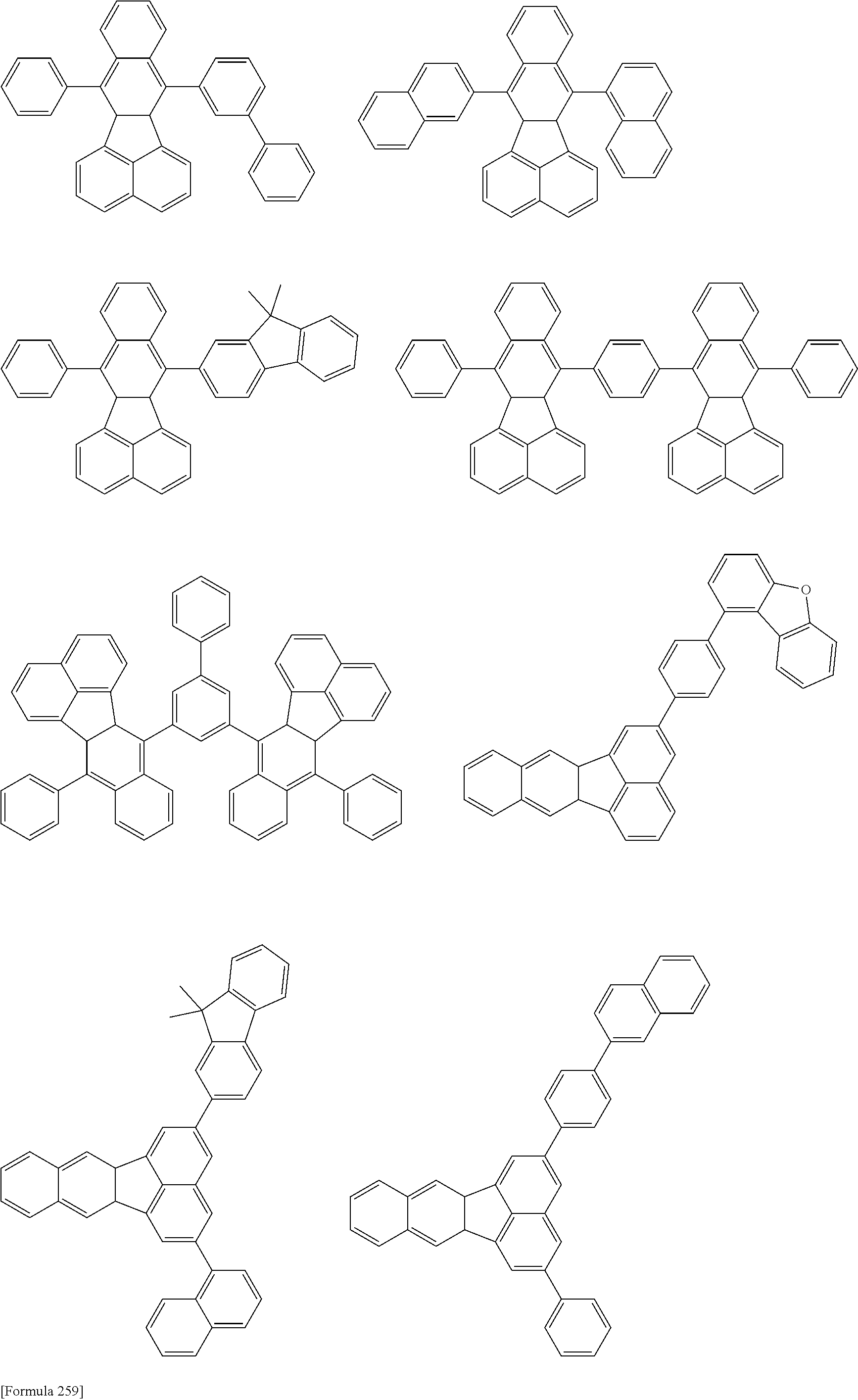

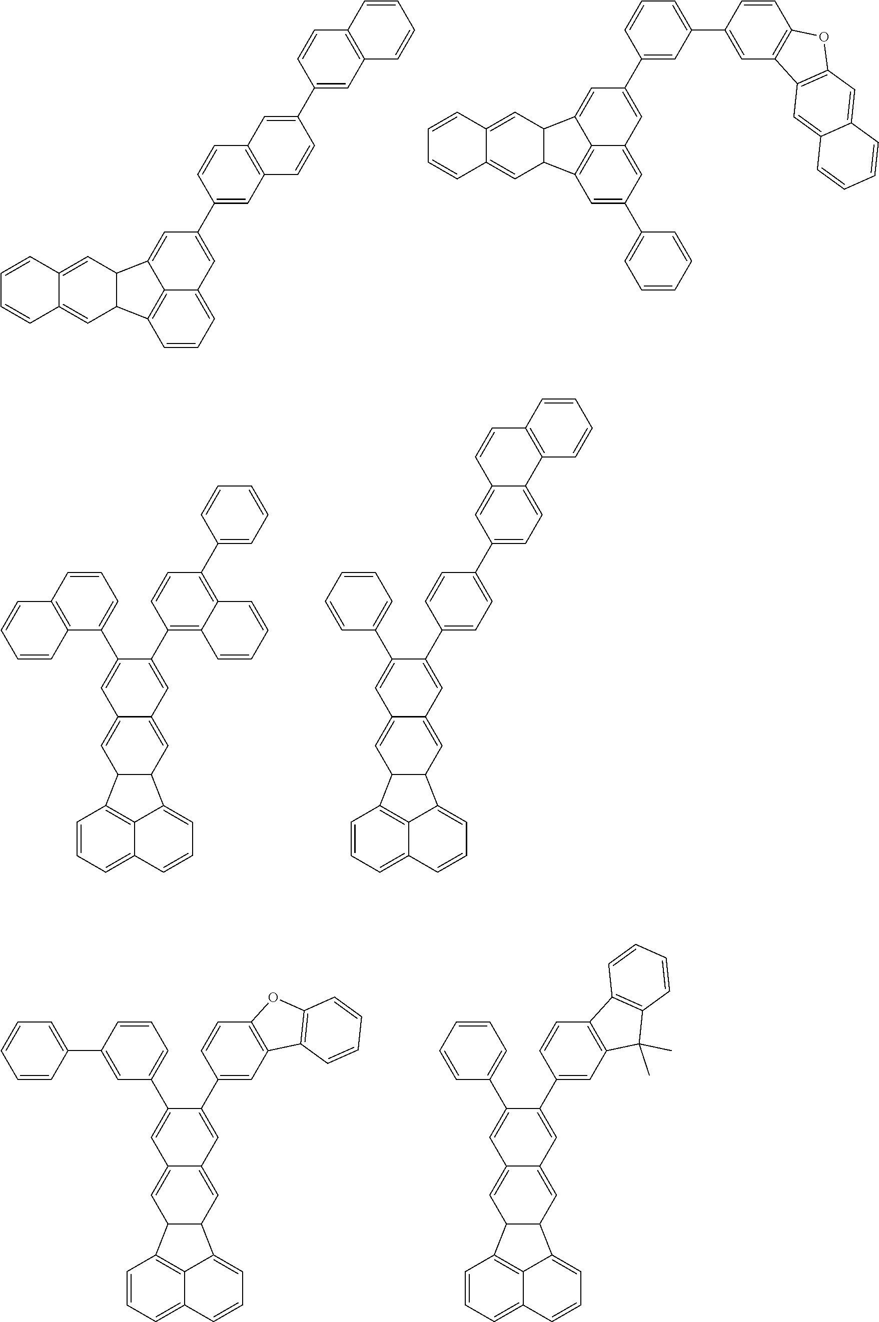

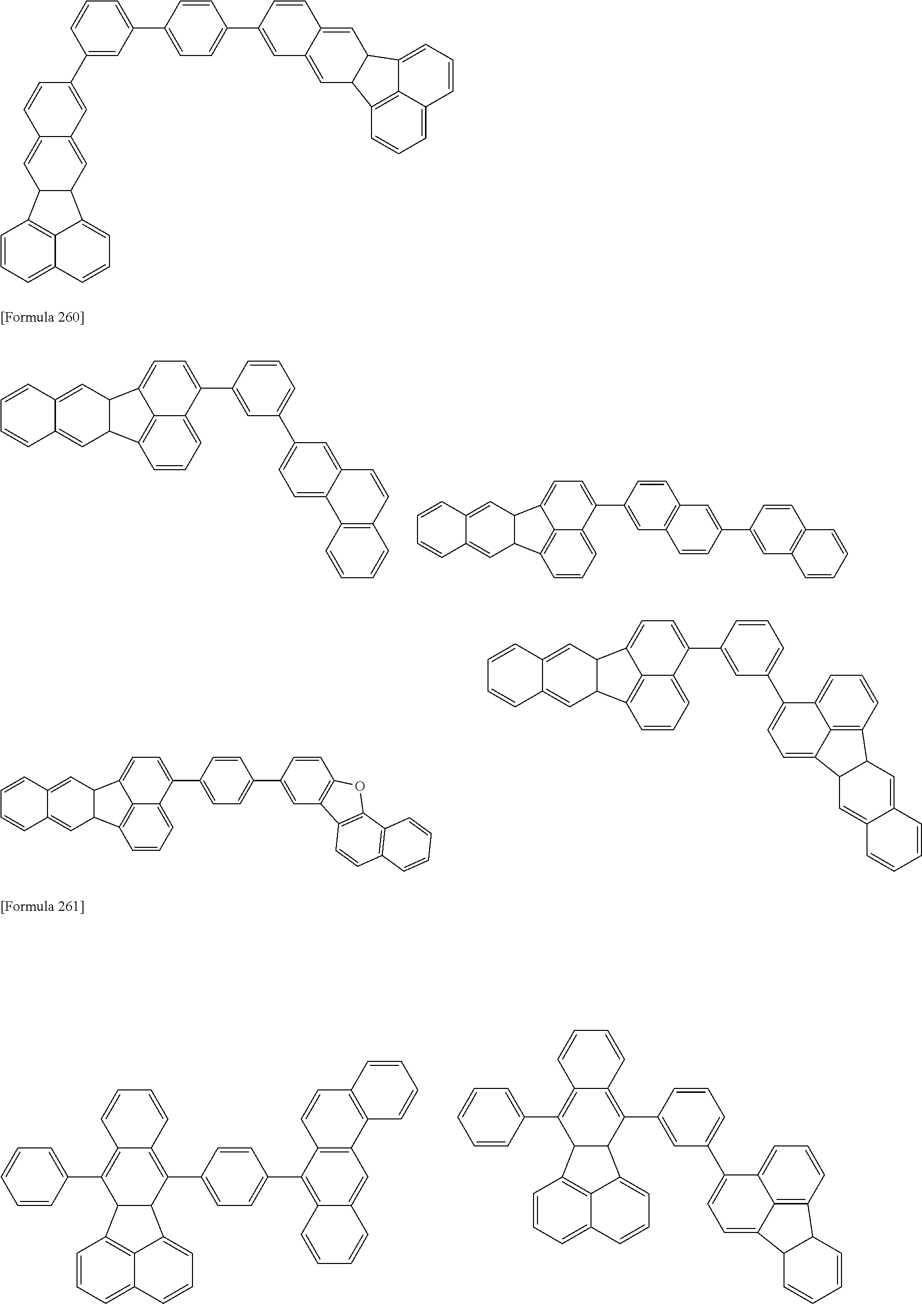

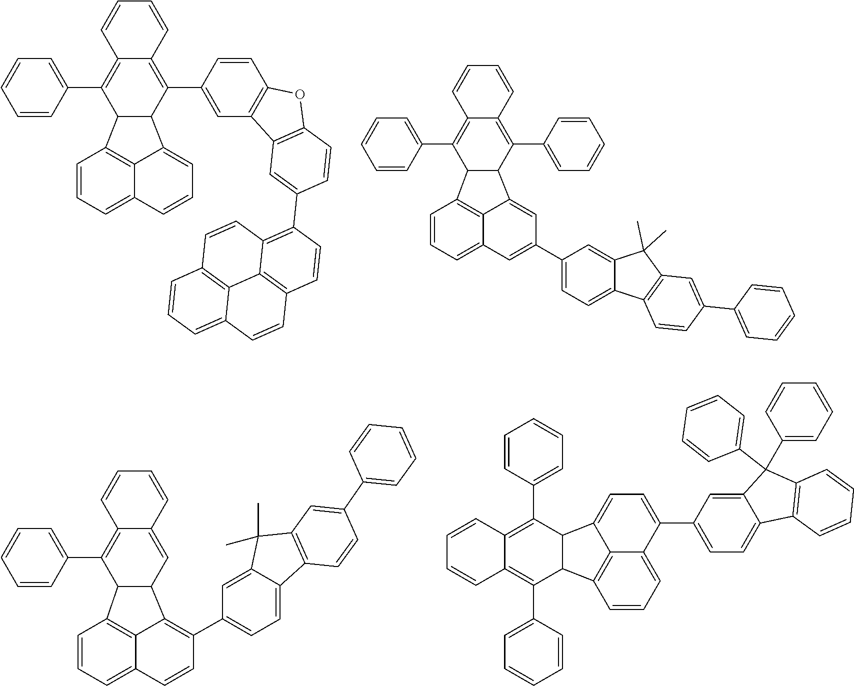

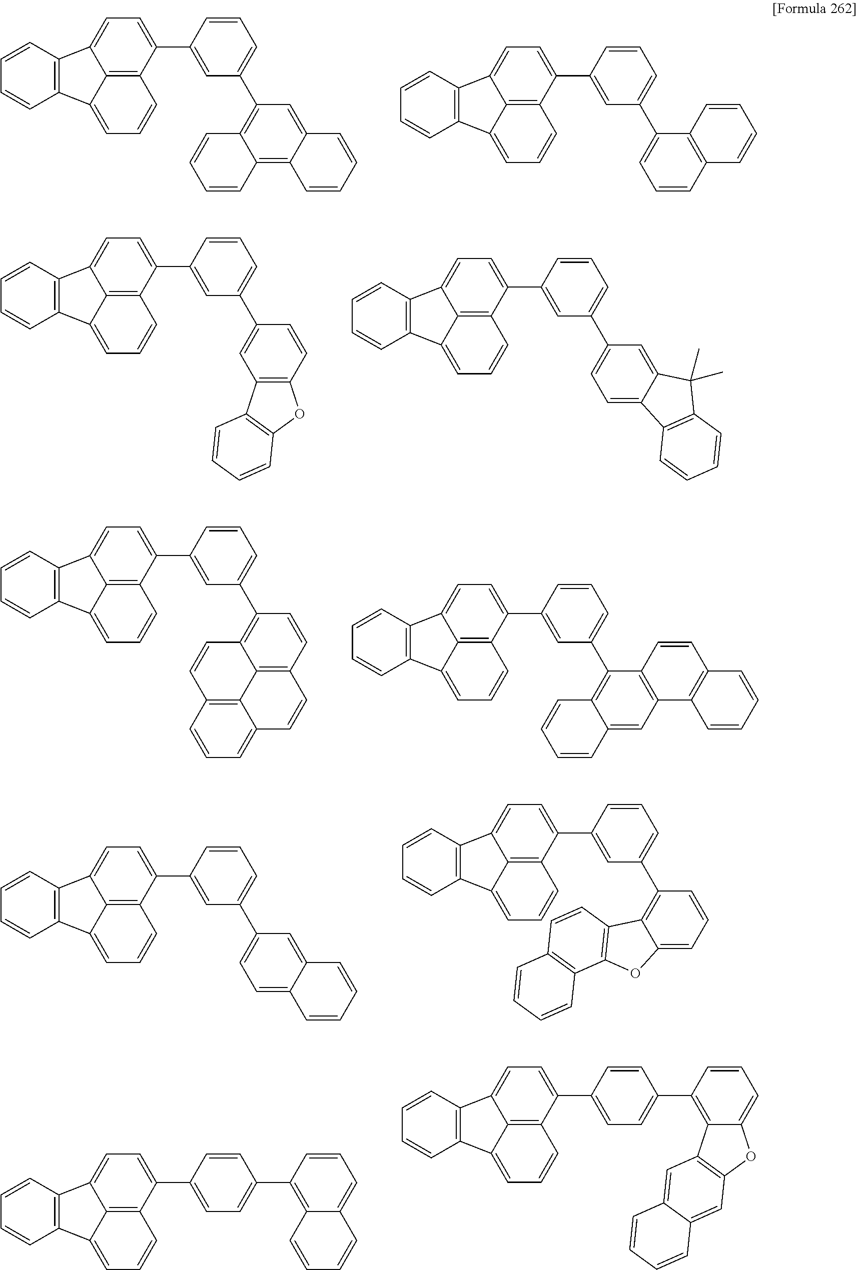

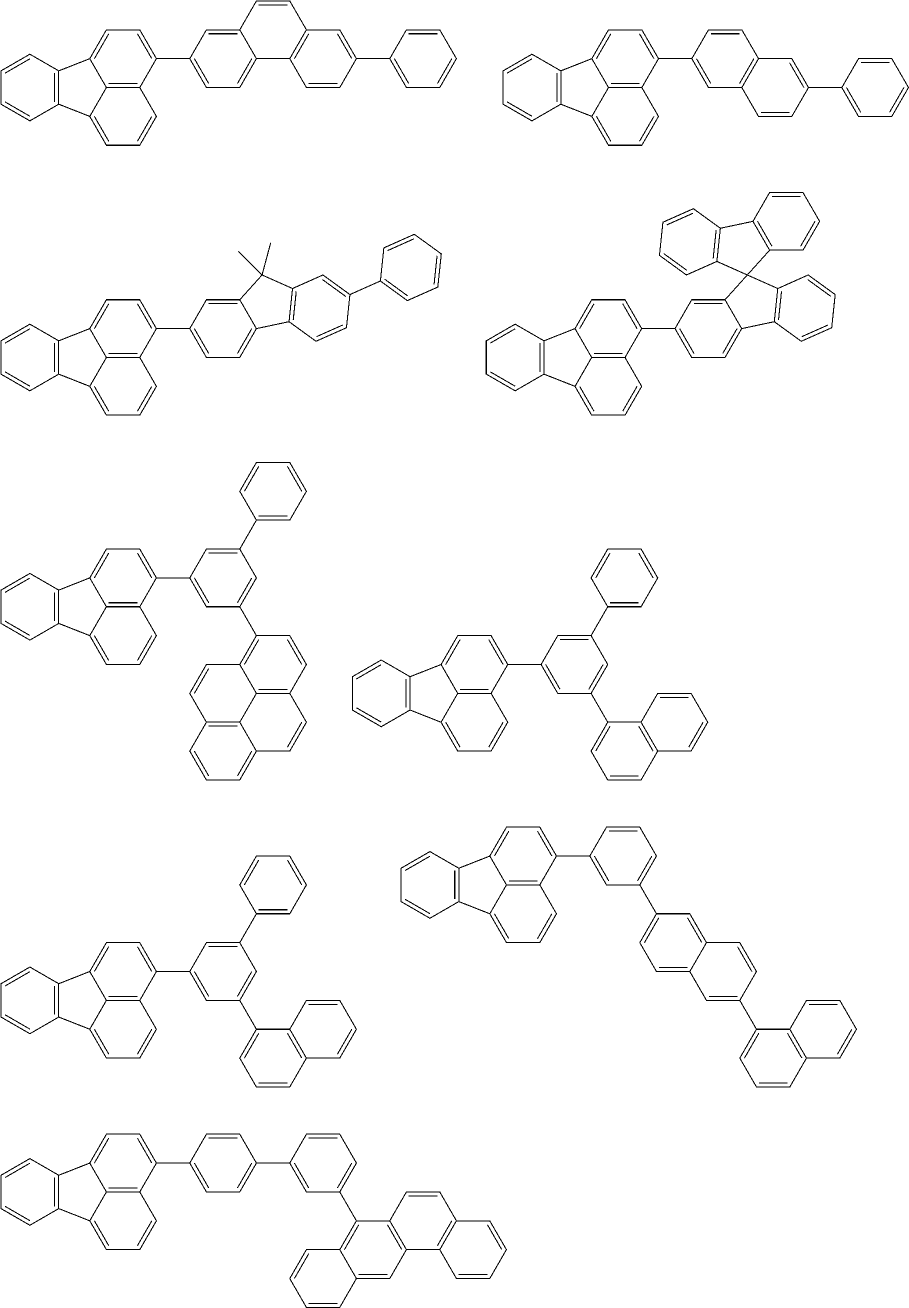

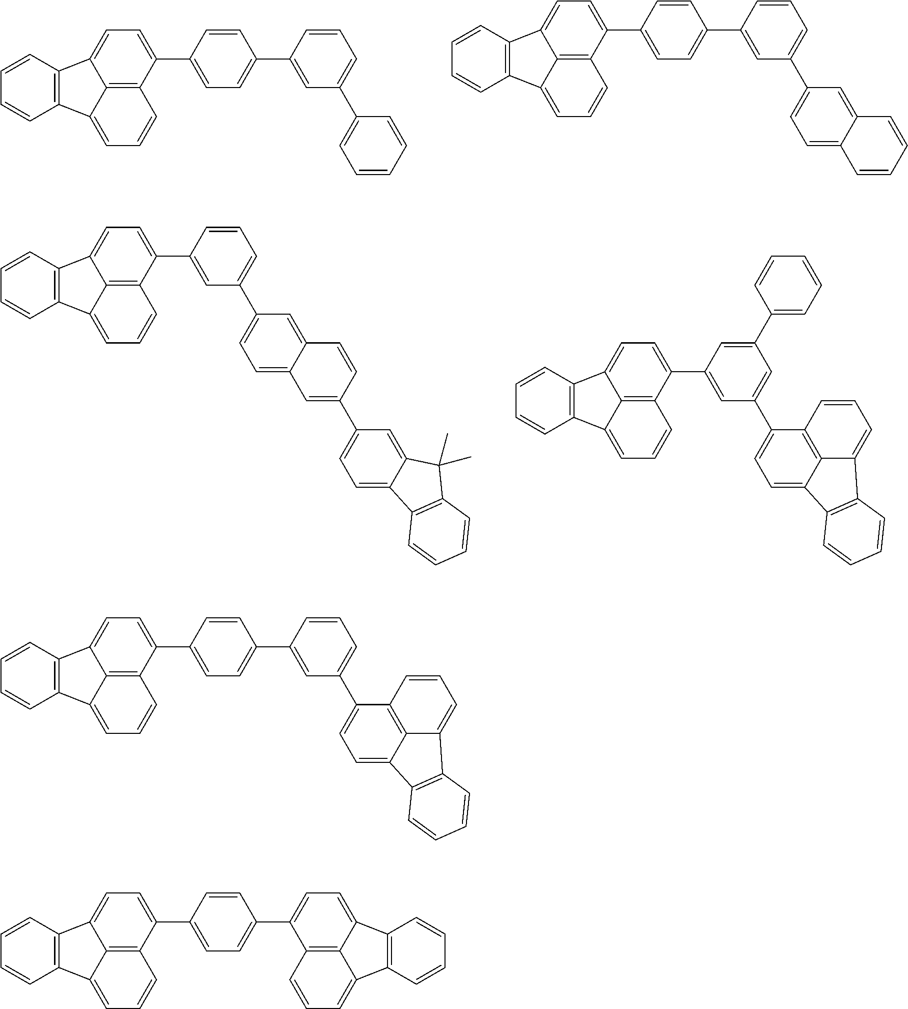

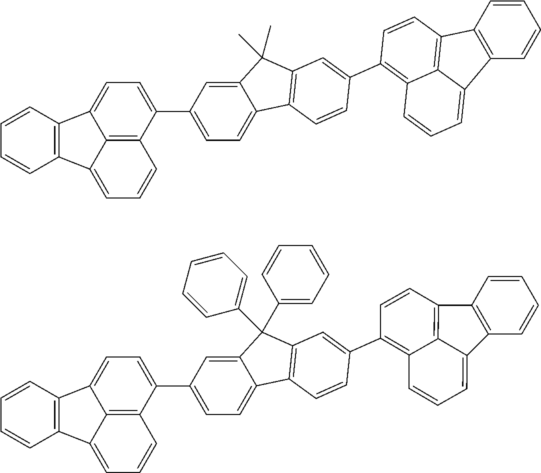

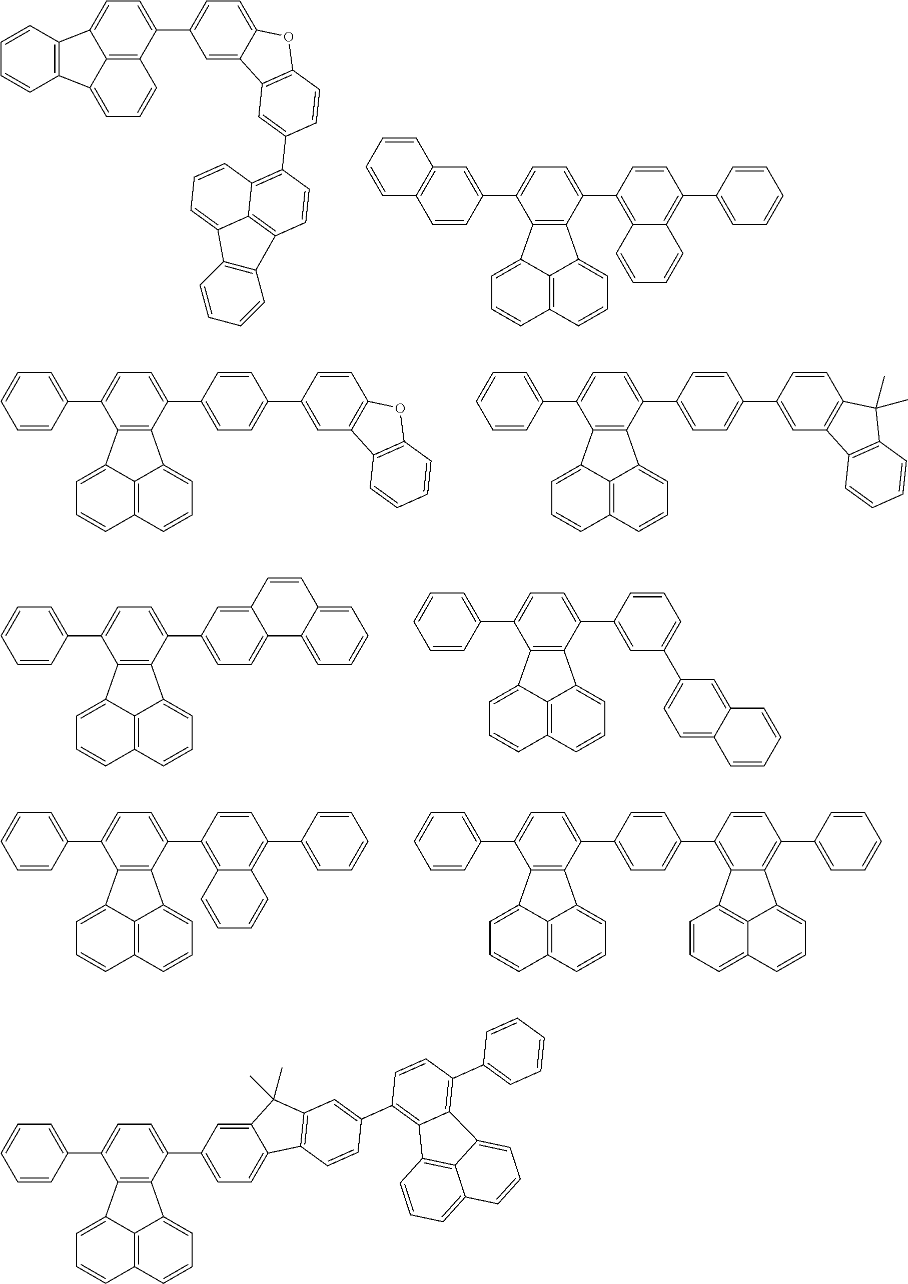

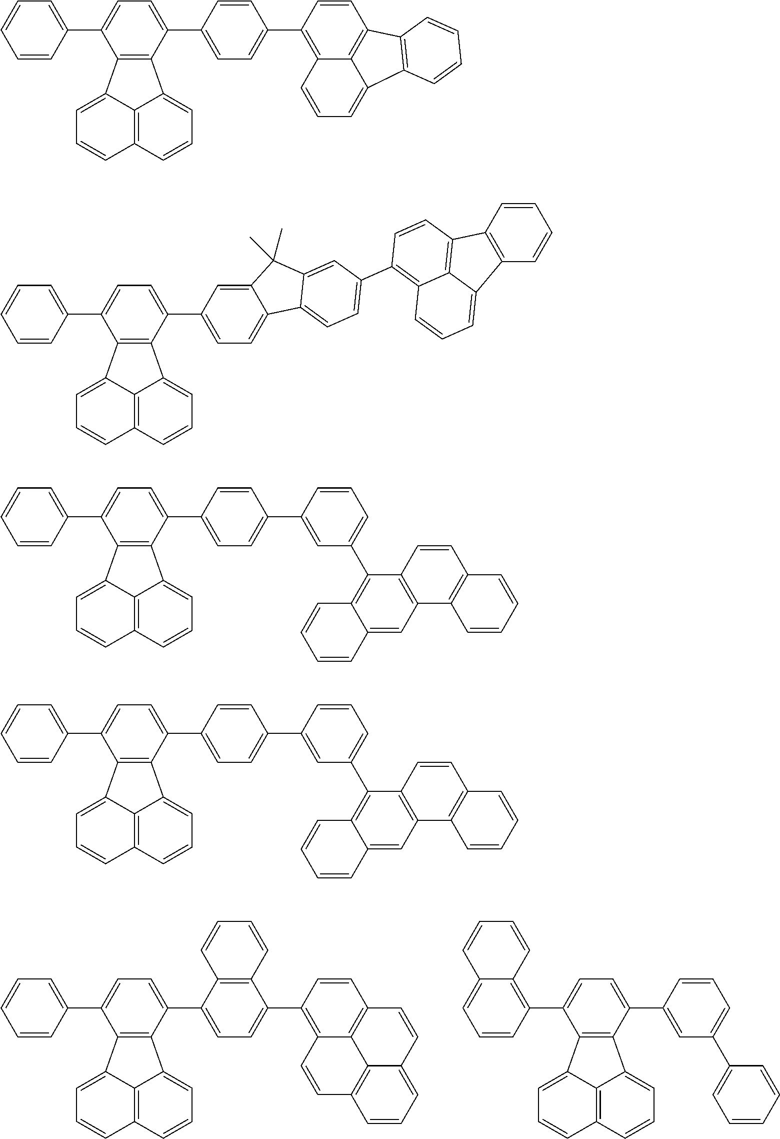

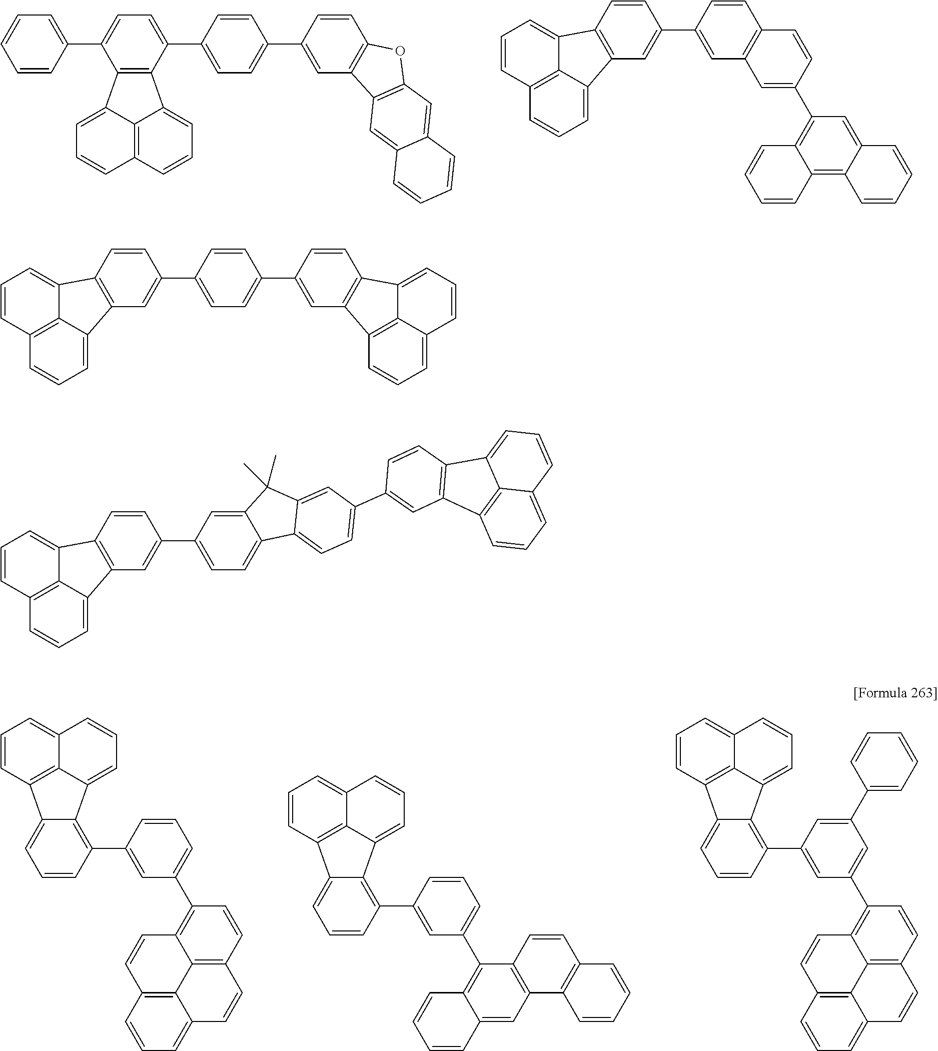

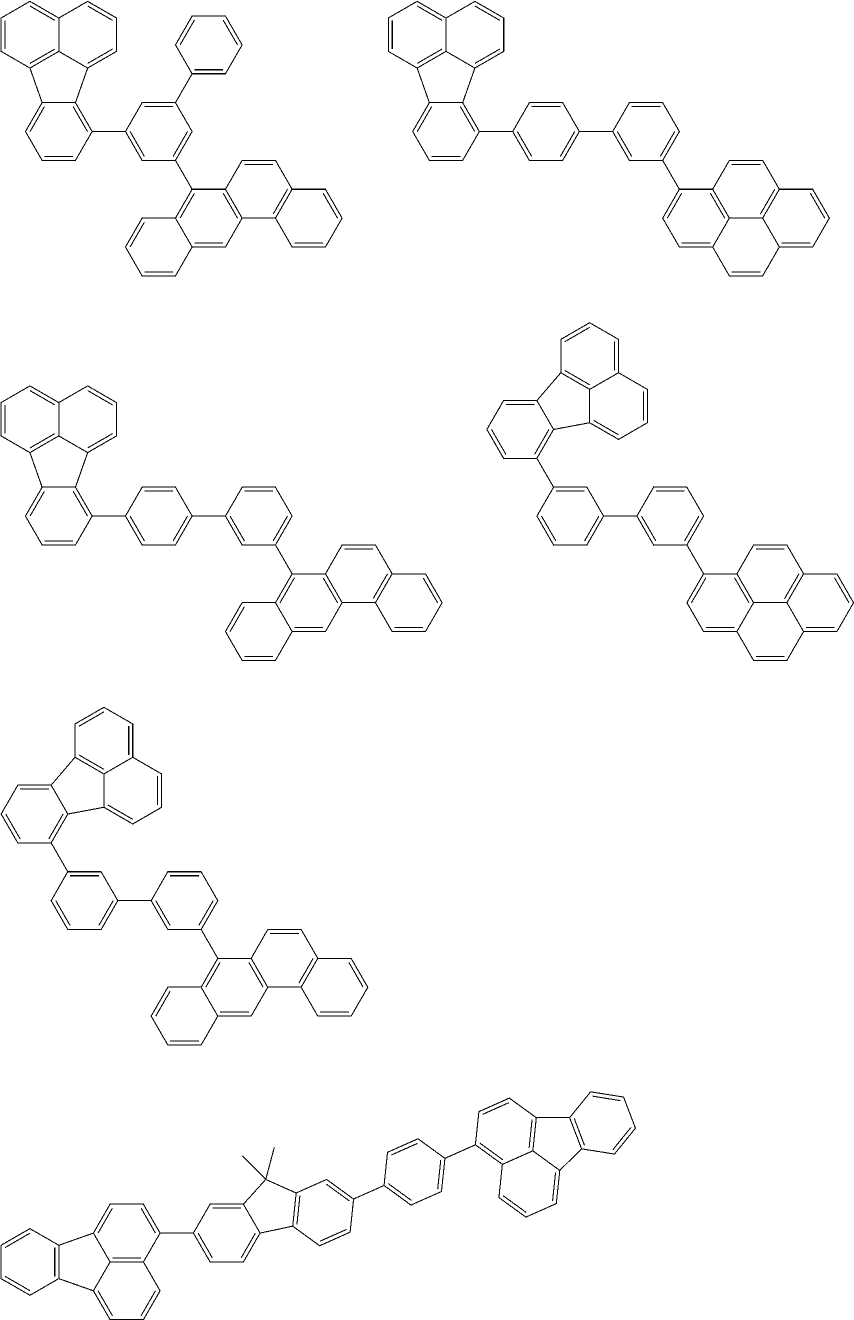

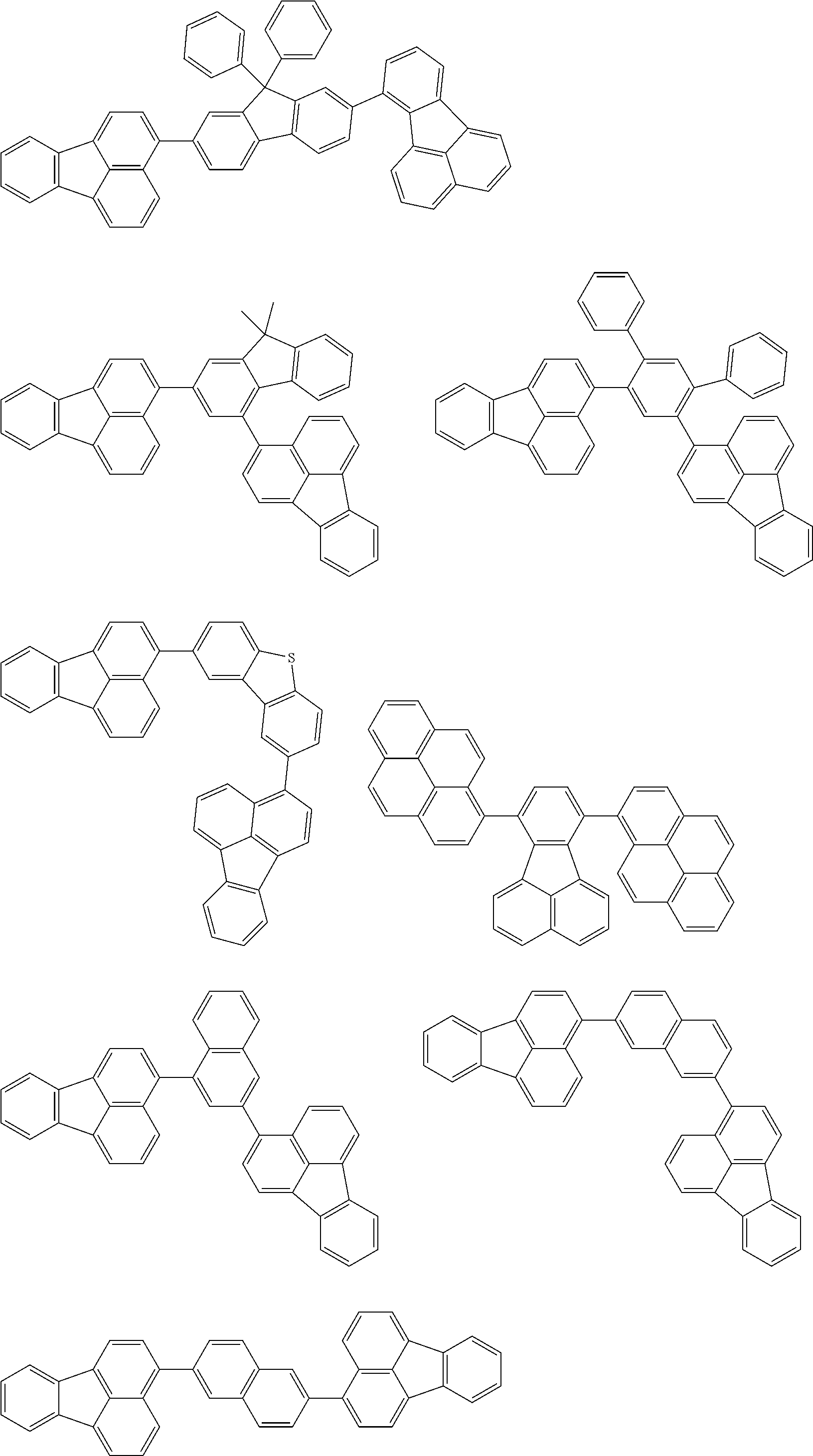

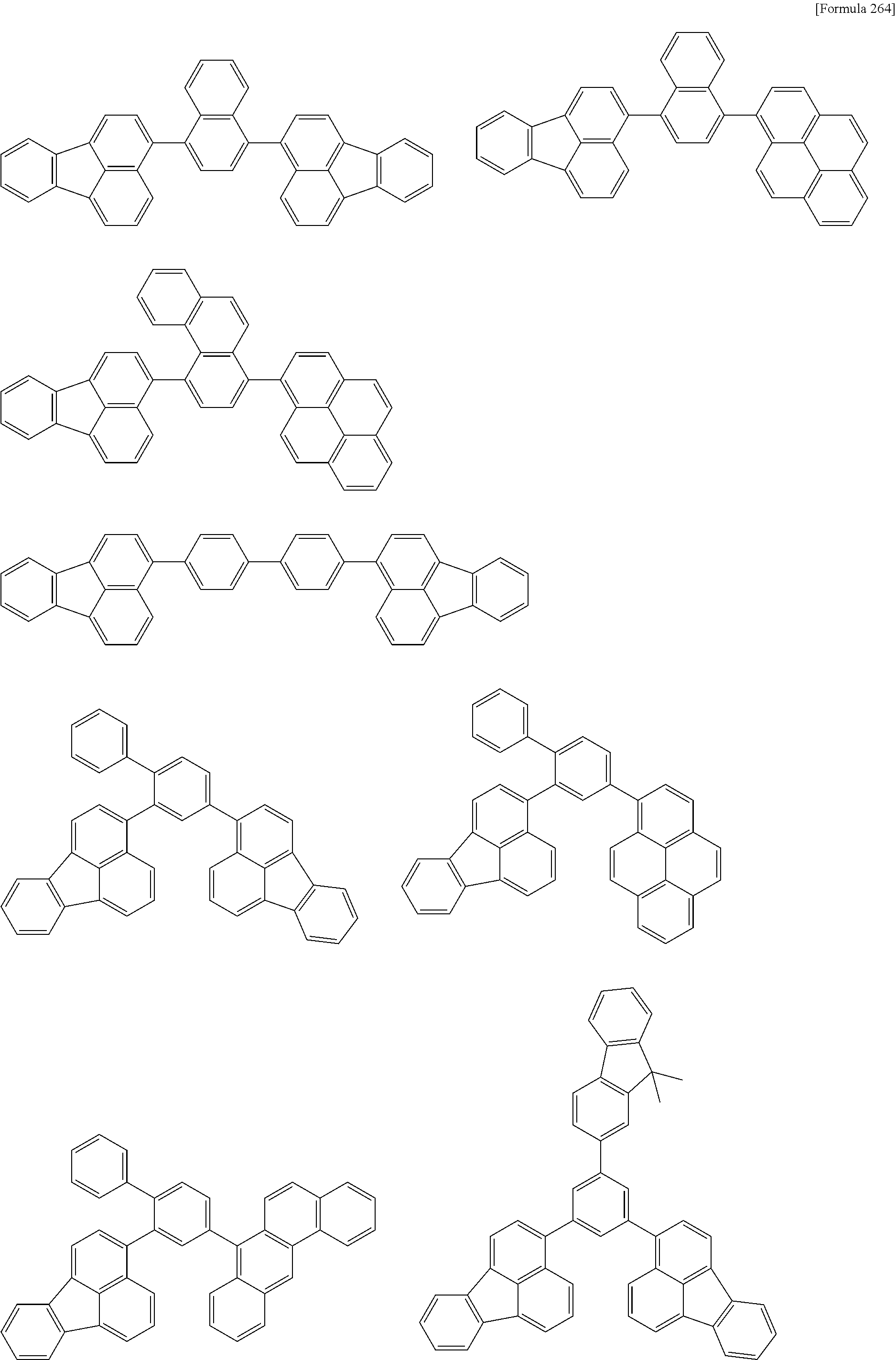

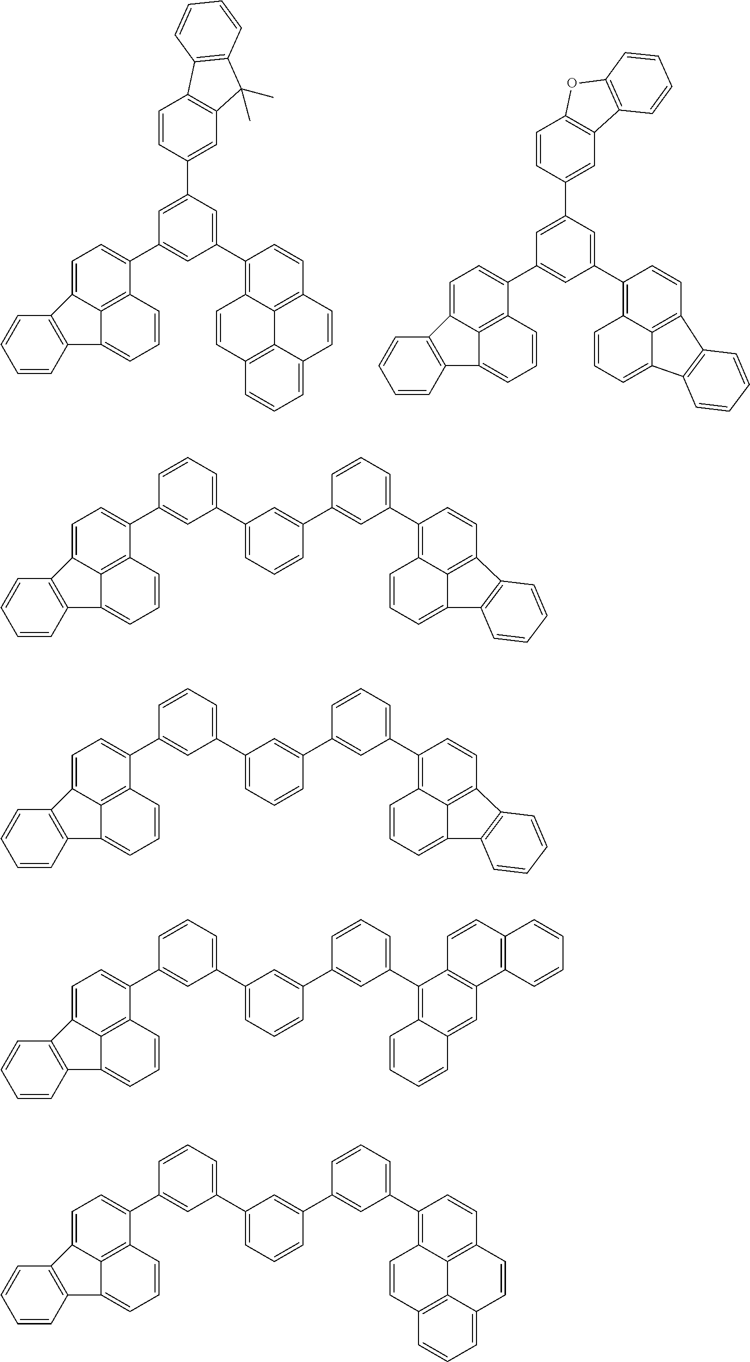

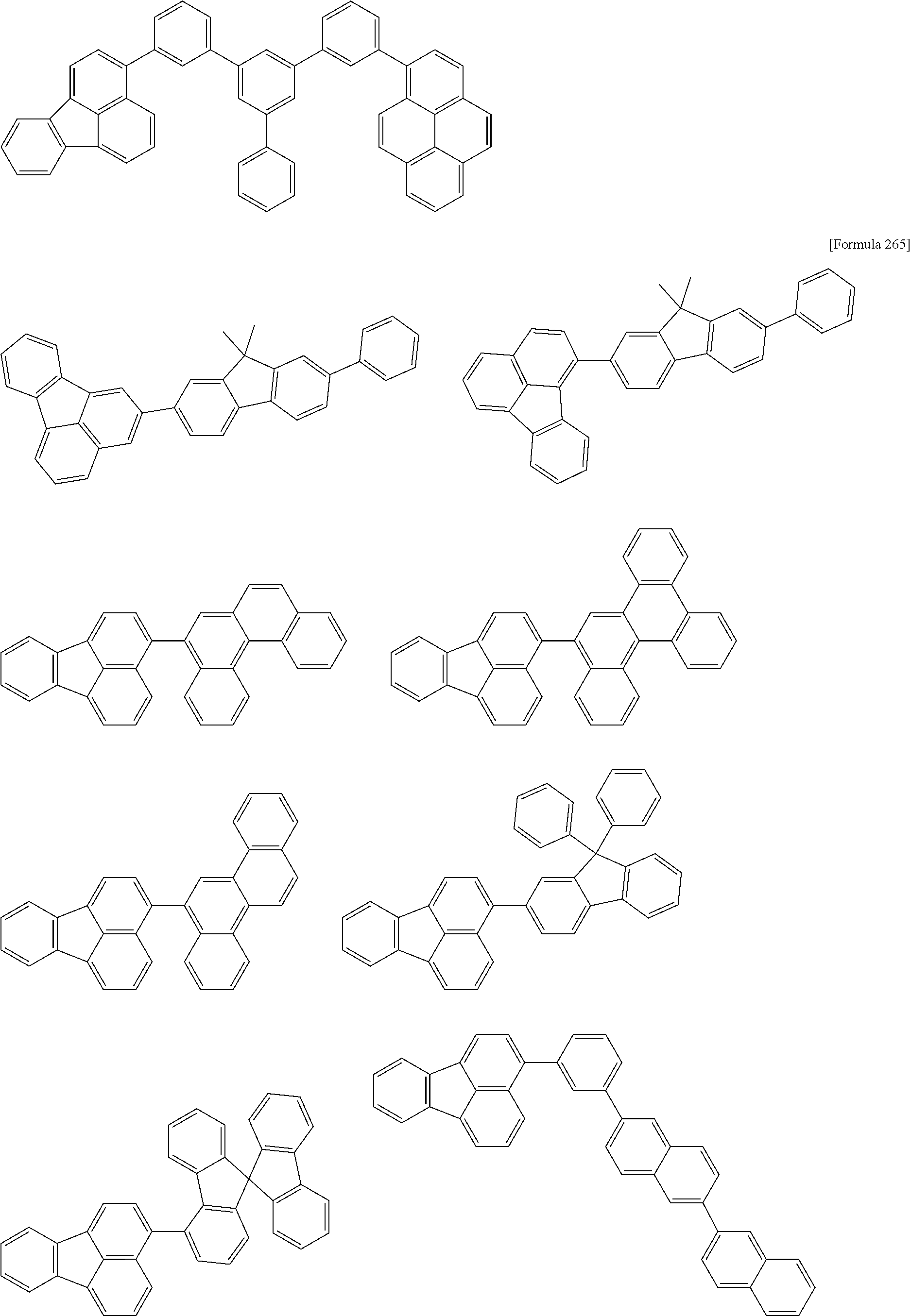

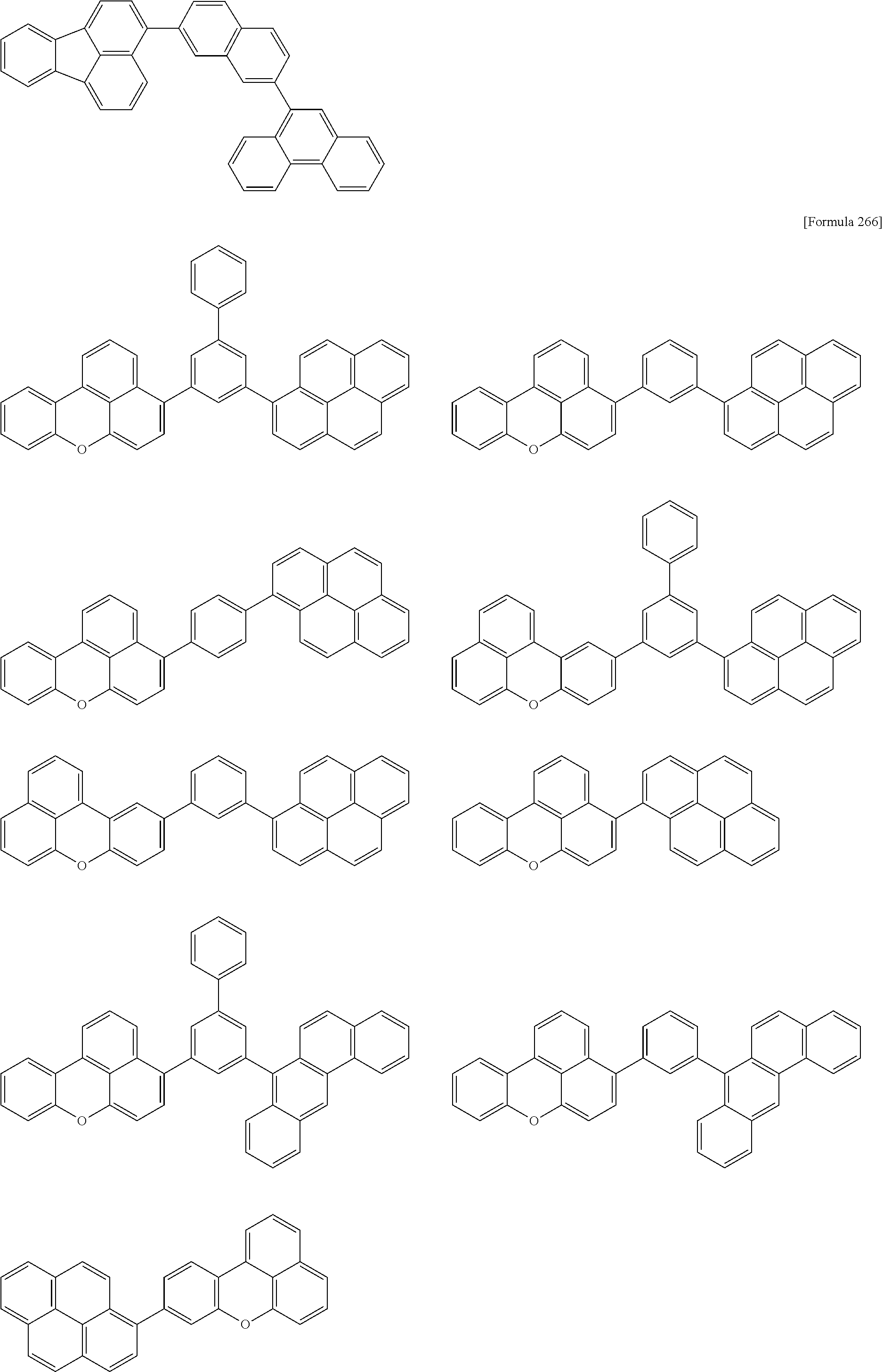

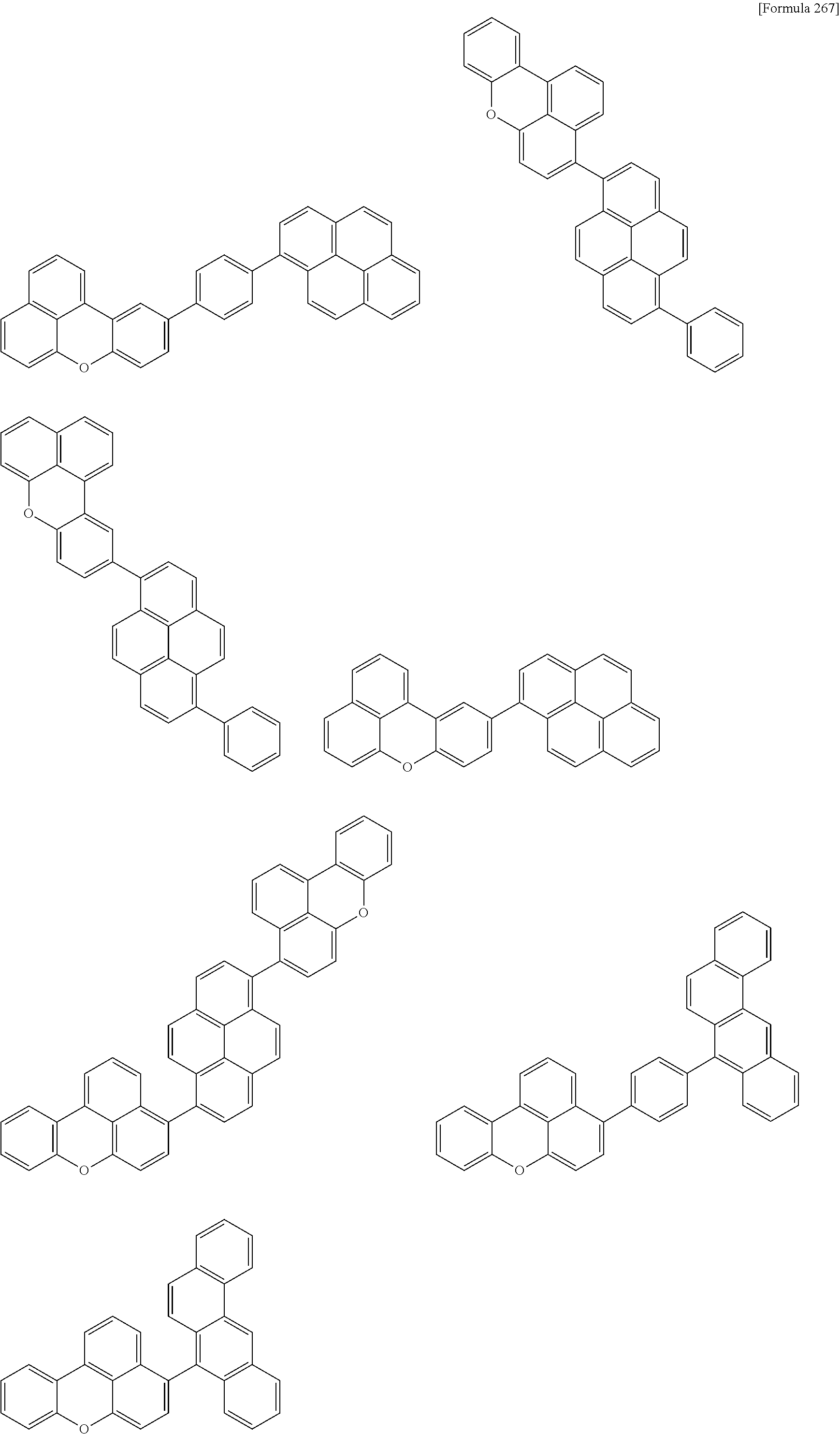

### Second Compound

The second compound represented by the formula (2) according to the exemplary embodiment will be described.

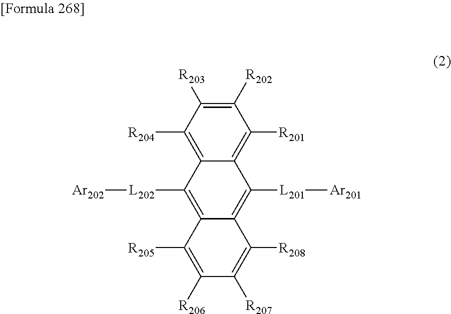

In the formula (2):
R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₂₀₁ and L₂₀₂ are each independently a single bond, a substituted or unsubstituted arylene group having 6 to 50 ring carbon atoms, or a substituted or unsubstituted divalent heterocyclic group having 5 to 50 ring atoms; and
Ar₂₀₁ and Ar₂₀₂ are each independently a substituted or unsubstituted aryl group having 6 to 50 ring carbon atoms, or a substituted or unsubstituted heterocyclic group having 5 to 50 ring atoms.

In the second compound according to the exemplary embodiment, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary embodiment, it is preferable that L₂₀₁ and L₂₀₂ are each independently a single bond, or a substituted or unsubstituted arylene group having 6 to 50 ring carbon atoms, and it is preferable that Ar₂₀₁ and Ar₂₀₂ are each independently a substituted or unsubstituted aryl group having 6 to 50 ring carbon atoms.

In an exemplary embodiment, Ar₂₀₁ and Ar₂₀₂ are preferably each independently a phenyl group, a naphthyl group, a phenanthryl group, a biphenyl group, a terphenyl group, a diphenylfluorenyl group, a dimethylfluorenyl group, a benzodiphenylfluorenyl group, a benzodimethylfluorenyl group, a dibenzofuranyl group, a dibenzothienyl group, a naphthobenzofuranyl group, or a naphthobenzothienyl group.

In an exemplary embodiment, in the second compound represented by the formula (2), R₂₀₁ to R₂₀₈ are preferably each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary embodiment, preferably, L₂₀₁ is a single bond or an unsubstituted arylene group having 6 to 22 ring carbon atoms and Ar₂₀₁ is a substituted or unsubstituted aryl group having 6 to 22 ring carbon atoms.

In an exemplary embodiment, in the second compound represented by the formula (2), R₂₀₁ to R₂₀₈ are preferably each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary embodiment, in the second compound represented by the formula (2), R₂₀₁ to R₂₀₈ each preferably are a hydrogen atom.

In an exemplary embodiment, the second compound is also preferably a compound represented by the formula (2) in which L₂₀₂ is a single bond and Ar₂₀₂ is an unsubstituted phenyl group.

In an exemplary embodiment, the second compound is also preferably a compound represented by the formula (2) in which L₂₀₂ is a single bond and Ar₂₀₂ is an unsubstituted 2-naphthyl group.

In an exemplary embodiment, the second compound is also preferably a compound represented by the formula (2) in which L₂₀₂ is a single bond and Ar₂₀₂ is an unsubstituted 1-naphthyl group.

In an exemplary embodiment, the second compound is also preferably a compound represented by the formula (2) in which L₂₀₂ is an unsubstituted p-phenylene group and Ar₂₀₂ is an unsubstituted phenyl group.

In an exemplary embodiment, the second compound is also preferably a compound represented by the formula (2) in which L₂₀₂ is an unsubstituted m-phenylene group and Ar₂₀₂ is an unsubstituted phenyl group.

In an exemplary embodiment, the second compound is also preferably a compound represented by the formula (2) in which L₂₀₂ is an unsubstituted o-phenylene group and Ar₂₀₂ is an unsubstituted phenyl group.

In an exemplary embodiment, the second compound is also preferably a compound represented by the formula (2) in which L₂₀₂ is an unsubstituted p-phenylene group and Ar₂₀₂ is an unsubstituted 1-naphthyl group.

In an exemplary embodiment, the second compound is also preferably a compound represented by the formula (2) in which L₂₀₂ is an unsubstituted p-phenylene group and Ar₂₀₂ is an unsubstituted 2-naphthyl group.

In an exemplary embodiment, the second compound is also preferably a compound represented by the formula (2) in which L₂₀₂ is an unsubstituted 1,4-naphthalene-diyl group and Ar₂₀₂ is an unsubstituted phenyl group.

In an exemplary embodiment, the second compound is also preferably a compound represented by the formula (2) in which L₂₀₂ is an unsubstituted m-phenylene group and Ar₂₀₂ is an unsubstituted 2-naphthyl group.

In an exemplary embodiment, the second compound is also preferably a compound represented by a formula (2X) below.

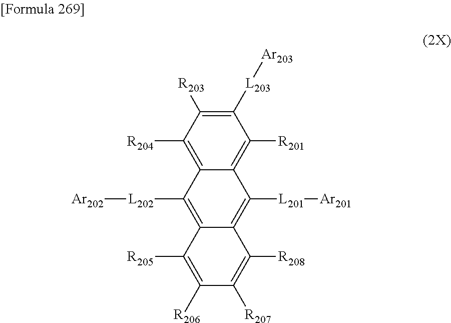

In the formula (2X):
R₂₀₁ and R₂₀₃ to R₂₀₈ each independently represent the same as R₂₀₁ and R₂₀₃ to R₂₀₈ in the formula (2);
L₂₀₁, L₂₀₂, Ar₂₀₁ and Ar₂₀₂ respectively represent the same as L₂₀₁, L₂₀₂, Ar₂₀₁ and Ar₂₀₂ in the formula (2);
L₂₀₃ represents the same as L₂₀₁ in the formula (2);
L₂₀₁, L₂₀₂ and L₂₀₃ are mutually the same or different;
Ar₂₀₃ represents the same as Ar₂₀₁ in the formula (2); and
Ar₂₀₁, Ar₂₀₂ and Ar₂₀₃ are mutually the same or different.

In an exemplary embodiment, the second compound is also preferably a compound represented by the formula (2X) in which L₂₀₂ is a single bond and Ar₂₀₂ is an unsubstituted phenyl group.

In an exemplary embodiment, the second compound is also preferably a compound represented by the formula (2X) in which L₂₀₂ is a single bond and Ar₂₀₂ is an unsubstituted 2-naphthyl group.

In an exemplary embodiment, the second compound is also preferably a compound represented by the formula (2X) in which L₂₀₂ is a single bond and Ar₂₀₂ is an unsubstituted 1-naphthyl group.

In an exemplary embodiment, the second compound is also preferably a compound represented by the formula (2X) in which L₂₀₂ is an unsubstituted p-phenylene group and Ar₂₀₂ is an unsubstituted phenyl group.

In an exemplary embodiment, the second compound is also preferably a compound represented by the formula (2X) in which L₂₀₂ is an unsubstituted m-phenylene group and Ar₂₀₂ is an unsubstituted phenyl group.

In an exemplary embodiment, the second compound is also preferably a compound represented by the formula (2X) in which L₂₀₂ is an unsubstituted o-phenylene group and Ar₂₀₂ is an unsubstituted phenyl group.

In an exemplary embodiment, the second compound is also preferably a compound represented by the formula (2X) in which L₂₀₂ is an unsubstituted p-phenylene group and Ar₂₀₂ is an unsubstituted 1-naphthyl group.

In an exemplary embodiment, the second compound is also preferably a compound represented by the formula (2X) in which L₂₀₂ is an unsubstituted p-phenylene group and Ar₂₀₂ is an unsubstituted 2-naphthyl group.

In an exemplary embodiment, the second compound is also preferably a compound represented by the formula (2X) in which L₂₀₂ is an unsubstituted 1,4-naphthalene-diyl group and Ar₂₀₂ is an unsubstituted phenyl group.

In an exemplary embodiment, the second compound is also preferably a compound represented by the formula (2X) in which L₂₀₂ is an unsubstituted m-phenylene group and Ar₂₀₂ is an unsubstituted 2-naphthyl group.

In an exemplary embodiment, the second compound is also preferably a compound represented by the formula (2X) in which L₂₀₁ is a single bond and Ar₂₀₁ is an unsubstituted phenyl group.

In an exemplary embodiment, the second compound is also preferably a compound represented by the formula (2X) in which L₂₀₁ is a single bond and Ar₂₀₁ is an unsubstituted 2-naphthyl group.

In an exemplary embodiment, the second compound is also preferably a compound represented by the formula (2X) in which L₂₀₁ is a single bond and Ar₂₀₁ is an unsubstituted 1-naphthyl group.

In an exemplary embodiment, the second compound is also preferably a compound represented by the formula (2X) in which L₂₀₁ is an unsubstituted p-phenylene group and Ar₂₀₁ is an unsubstituted phenyl group.

In an exemplary embodiment, the second compound is also preferably a compound represented by the formula (2X) in which L₂₀₁ is an unsubstituted m-phenylene group and Ar₂₀₁ is an unsubstituted phenyl group.

In an exemplary embodiment, the second compound is also preferably a compound represented by the formula (2X) in which L₂₀₁ is an unsubstituted o-phenylene group and Ar₂₀₁ is an unsubstituted phenyl group.

In an exemplary embodiment, the second compound is also preferably a compound represented by the formula (2X) in which L₂₀₁ is an unsubstituted p-phenylene group and Ar₂₀₁ is an unsubstituted 1-naphthyl group.

In an exemplary embodiment, the second compound is also preferably a compound represented by the formula (2X) in which L₂₀₁ is an unsubstituted p-phenylene group and Ar₂₀₁ is an unsubstituted 2-naphthyl group.

In an exemplary embodiment, the second compound is also preferably a compound represented by the formula (2X) in which L₂₀₁ is an unsubstituted 1,4-naphthalene-diyl group and Ar₂₀₁ is an unsubstituted phenyl group.

In an exemplary embodiment, the second compound is also preferably a compound represented by the formula (2X) in which L₂₀₁ is an unsubstituted m-phenylene group and Ar₂₀₁ is an unsubstituted 2-naphthyl group.

In the second compound, the groups specified to be “substituted or unsubstituted” are each preferably an “unsubstituted” group.

In an exemplary embodiment, the second emitting layer preferably contains the second compound represented by the formula (2) as the second host material. Accordingly, for instance, the second emitting layer contains 50 mass % or more of the second compound represented by the formula (2) with respect to the total mass of the second emitting layer.

In the organic EL device according to the exemplary embodiment, in the second compound represented by the formula (2), R₂₀₁ to R₂₀₈ that are substituents of an anthracene skeleton are preferably hydrogen atoms in terms of preventing inhibition of intermolecular interaction and inhibiting a decrease in electron mobility. However, R₂₀₁ to R₂₀₈ may be a substituted or unsubstituted aryl group having 6 to 50 ring carbon atoms or a substituted or unsubstituted heterocyclic group having 5 to 50 ring atoms.

Assuming that R₂₀₁ to R₂₀ are each a bulky substituent such as an alkyl group and a cycloalkyl group, intermolecular interaction may be inhibited to decrease the electron mobility of the second compound relative to that of the first host material, so that the relationship of μe(H2)>μe(H1) shown by the numerical formula (Numerical Formula 30) may not be satisfied. When the second compound is used in the second emitting layer, it can be expected that satisfying the relationship of μe(H2)>μe(H1) inhibits a decrease in a recombination ability between holes and electrons in the first emitting layer and a decrease in luminous efficiency. It should be noted that substituents, namely, a haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group are likely to be bulky, and an alkyl group and cycloalkyl group are likely to be further bulky.

In the second compound represented by the formula (2), R₂₀₁ to R₂₀₈, which are the substituents on the anthracene skeleton, are each preferably not a bulky substituent and preferably not an alkyl group and cycloalkyl group. More preferably, R₂₀₁ to R₂₀₈ are each not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the second compound, examples of the substituent for the “substituted or unsubstituted” group on R₂₀₁ to R₂₀₈ also preferably do not include the above-described substituent that is likely to be bulky, especially a substituted or unsubstituted alkyl group and a substituted or unsubstituted cycloalkyl group. When examples of the substituent for the “substituted or unsubstituted” group on R₂₀₁ to R₂₀₈ do not include a substituted or unsubstituted alkyl group and a substituted or unsubstituted cycloalkyl group, the inhibition of intermolecular interaction to be caused by the presence of a bulky substituent such as an alkyl group and a cycloalkyl group can be prevented, thereby preventing a decrease in the electron mobility. Moreover, when the second compound described above is used in the second emitting layer, a decrease in a recombination ability between holes and electrons in the first emitting layer and a decrease in the luminous efficiency can be inhibited.

Further preferably, R₂₀₁ to R₂₀₈ that are the substituents on the anthracene skeleton are not bulky substituents and R₂₀₁ to R₂₀₈ as substituents are unsubstituted. Assuming that R₂₀₁ to R₂₀₈ that are the substituents on the anthracene skeleton are not bulky substituents and substituents are bonded to R₂₀₁ to R₂₀₈ that are not bulky substituents, the substituents bonded to R₂₀₁ to R₂₀₈ are preferably not bulky substituents; and the substituents bonded to R₂₀₁ to R₂₀₈ serving as substituents are preferably not an alkyl group and cycloalkyl group, more preferably not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

### Method of Producing Second Compound

The second compound can be produced by a known method. The second compound can also be produced based on a known method through a known alternative reaction using a known material(s) tailored for the target compound.

### Specific Examples of Second Compound

Specific examples of the second compound include the following compounds. It should however be noted that the invention is not limited to the specific examples of the second compound.

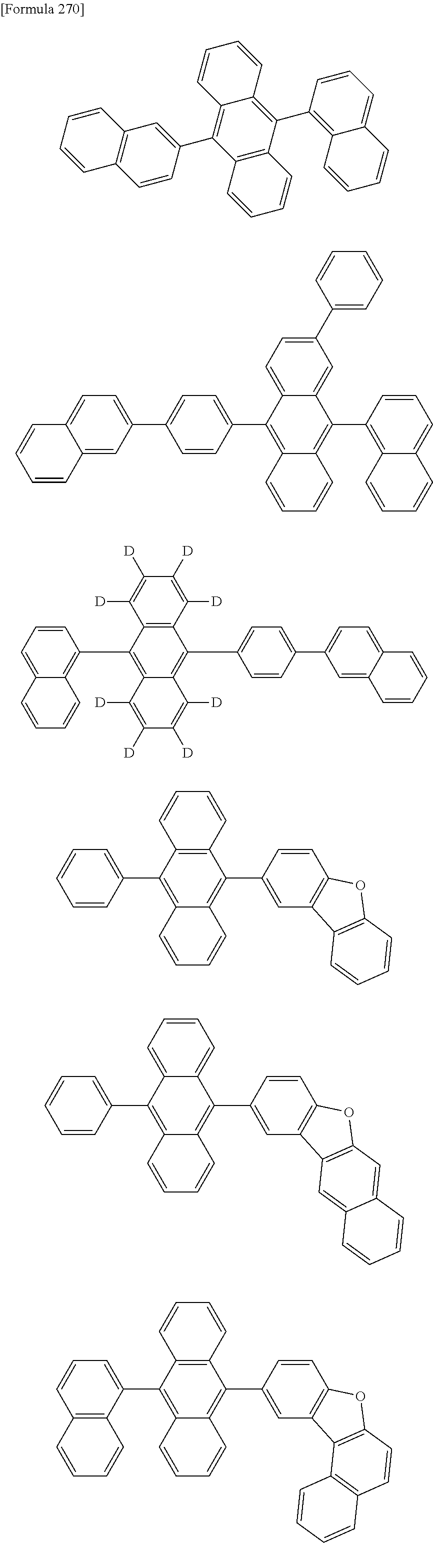

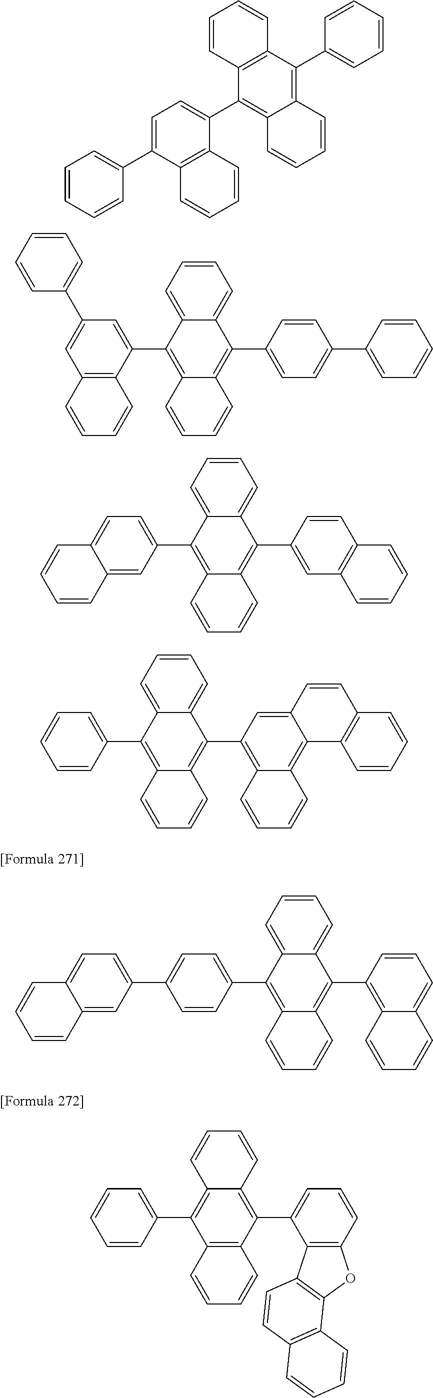

### Additional Layers of Organic EL Device

The organic EL device according to the exemplary embodiment may include one or more organic layer(s) in addition to the first anode side organic layer, the second anode side organic layer, the third anode side organic layer, and the emitting layer in the emitting region. Examples of the organic layer include, for instance, at least one layer selected from the group consisting of an electron injecting layer, an electron transporting layer, a hole blocking layer, and an electron blocking layer.

In the organic EL device according to the exemplary embodiment, only the first anode side organic layer, the second anode side organic layer, the third anode side organic layer, and the emitting layer in the emitting region may be included as the organic layers. Alternatively, for instance, at least one layer selected from the group consisting of the electron injecting layer, the electron transporting layer, and the hole blocking layer may be further included as the organic layer.

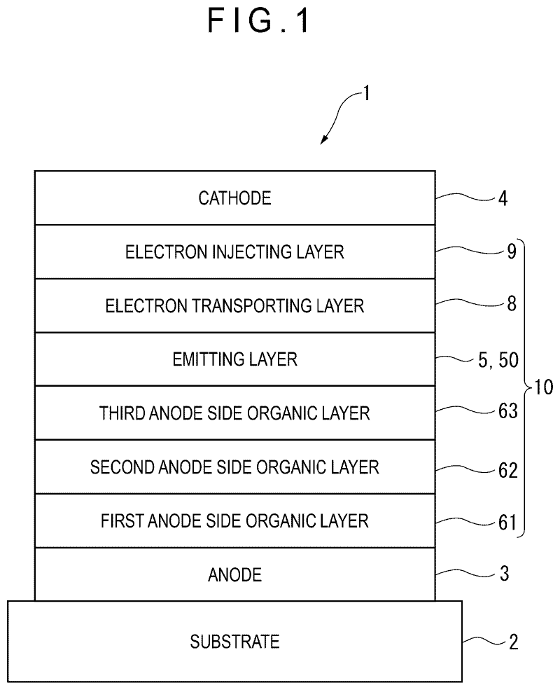

FIG. 1 schematically depicts an exemplary arrangement of the organic EL device of the exemplary embodiment.

An organic EL device 1 includes a substrate 2, an anode 3, a cathode 4, and organic layers 10 provided between the anode 3 and the cathode 4. The organic layers 10 include a first anode side organic layer 61, a second anode side organic layer 62, a third anode side organic layer 63, an emitting layer 50, an electron transporting layer 8, and an electron injecting layer 9, which are sequentially layered on the anode 3.

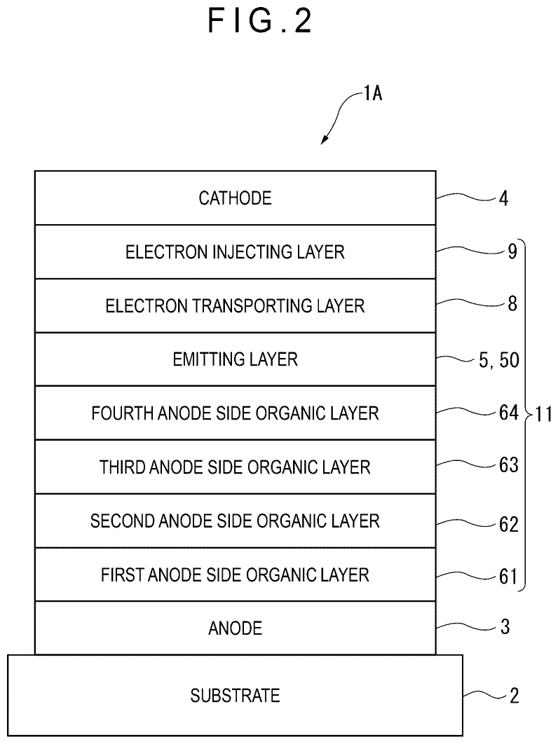

FIG. 2 schematically depicts another exemplary arrangement of the organic EL device according to the exemplary embodiment.

An organic EL device 1A includes the substrate 2, the anode 3, the cathode 4, and organic layers 11 provided between the anode 3 and the cathode 4. The organic layers 11 include the first anode side organic layer 61, the second anode side organic layer 62, the third anode side organic layer 63, a fourth anode side organic layer 64, the emitting layer 50, the electron transporting layer 8, and the electron injecting layer 9, which are sequentially layered on the anode 3.

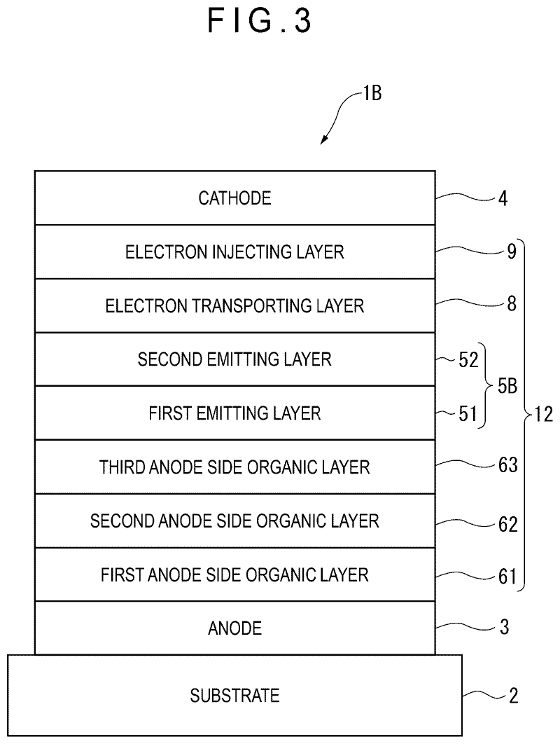

FIG. 3 schematically depicts still another exemplary arrangement of the organic EL device according to the exemplary embodiment.

An organic EL device 1B includes the substrate 2, the anode 3, the cathode 4, and organic layers 12 provided between the anode 3 and the cathode 4. The organic layers 12 include the first anode side organic layer 61, the second anode side organic layer 62, the third anode side organic layer 63, a first emitting layer 51, a second emitting layer 52, the electron transporting layer 8, and the electron injecting layer 9, which are sequentially layered on the anode 3.

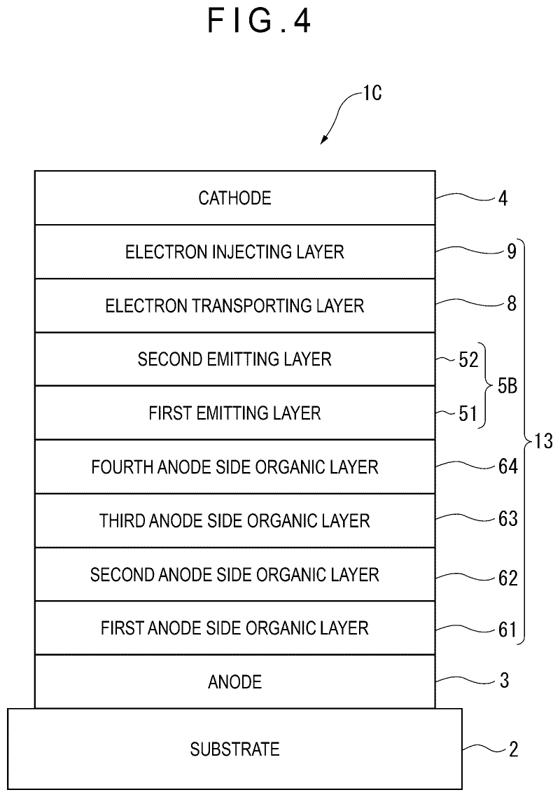

FIG. 4 schematically depicts a further exemplary arrangement of the organic EL device according to the exemplary embodiment.

An organic EL device 1C includes the substrate 2, the anode 3, the cathode 4, and organic layers 13 provided between the anode 3 and the cathode 4. The organic layers 13 include the first anode side organic layer 61, the second anode side organic layer 62, the third anode side organic layer 63, the fourth anode side organic layer 64, the first emitting layer 51, the second emitting layer 52, the electron transporting layer 8, and the electron injecting layer 9, which are sequentially layered on the anode 3.

In the organic EL device 1 of FIG. 1 and the organic EL device 1A of FIG. 2, the emitting region 5 includes the emitting layer 50.

In the organic EL device 1B of FIG. 3 and the organic EL device 1C of FIG. 4, an emitting region 5B includes the first emitting layer 51 and the second emitting layer 52.

In the organic EL device 1 of FIG. 1 and the organic EL device 1B of FIG. 3, the hole transporting zone includes the first anode side organic layer 61, the second anode side organic layer 62, and the third anode side organic layer 63.

In the organic EL device 1A of FIG. 2 and the organic EL device 1C of FIG. 4, the hole transporting zone includes the first anode side organic layer 61, the second anode side organic layer 62, the third anode side organic layer 63, and the fourth anode side organic layer 64.

The invention is not limited to the exemplary arrangements of the organic EL devices depicted in FIGS. 1 to 4. The organic EL device with any other arrangement is exemplified by an organic EL device in which the second emitting layer and the first emitting layer in the emitting region are layered in this order from the side close to the anode.

### Interposed Layer

The organic EL device according to the exemplary embodiment may include an interposed layer as an organic layer disposed between the first emitting layer and the second emitting layer.

In the exemplary embodiment, in order to inhibit an overlap between a Singlet emitting region and a TTF emitting region, the interposed layer contains no emitting compound or may contain an emitting compound in an insubstantial amount provided that the overlap can be inhibited.

For instance, the interposed layer contains 0 mass % of an emitting compound. Alternatively, for instance, the interposed layer may contain an emitting compound provided that the emitting compound contained is a component accidentally mixed in a producing process or a component contained as impurities in a material.

For instance, when the interposed layer consists of a material A, a material B, and a material C, the content ratios of the materials A, B, and C in the interposed layer are each 10 mass % or more, and the total of the content ratios of the materials A, B, and C is 100 mass %.

In the following, the interposed layer is occasionally referred to as a “non-doped layer”. A layer containing an emitting compound is occasionally referred to as a “doped layer”.

It is considered that luminous efficiency is improvable in an arrangement including layered emitting layers, because the Singlet emitting region and the TTF emitting region are typically likely to be separated from each other.

In the organic EL device according to the exemplary embodiment, when the interposed layer (non-doped layer) is disposed between the first emitting layer and the second emitting layer in the emitting region, it is expected that a region where the Singlet emitting region and the TTF emitting region overlap with each other is reduced to inhibit a decrease in TTF efficiency which may otherwise be caused by collision between triplet excitons and carriers. That is, it is considered that providing the interposed layer (non-doped layer) between the emitting layers contributes to the improvement in TTF emission efficiency.

The interposed layer is the non-doped layer.

The interposed layer contains no metal atom. The interposed layer thus contains no metal complex.

The interposed layer contains an interposed layer material. The interposed layer material is not an emitting compound.

The interposed layer material may be any material except for the emitting compound.

Examples of the interposed layer material include: 1) a heterocyclic compound such as an oxadiazole derivative, benzimidazole derivative, or phenanthroline derivative; 2) a fused aromatic compound such as a carbazole derivative, anthracene derivative, phenanthrene derivative, pyrene derivative or chrysene derivative; and 3) an aromatic amine compound such as a triarylamine derivative or a fused polycyclic aromatic amine derivative.

One or both of the first host material and the second host material may be used as the interposed layer material. The interposed layer material may be any material provided that the Singlet emitting region and the TTF emitting region are separated from each other and the Singlet emission and the TTF emission are not hindered.

In the organic EL device according to the exemplary embodiment, the respective content ratios of all the materials forming the interposed layer in the interposed layer are 10 mass % or more.

The interposed layer contains the interposed layer material as a material forming the interposed layer.

The interposed layer preferably contains 60 mass % or more of the interposed layer material, more preferably contains 70 mass % or more of the interposed layer material, still more preferably contains 80 mass % or more of the interposed layer material, still further more preferably 90 mass % or more of the interposed layer material, and yet still further more preferably 95 mass % or more of the interposed layer material, with respect to the total mass of the interposed layer.

The interposed layer may contain a single type of the interposed layer material or may contain two or more types of the interposed layer material.

When the interposed layer contains two or more types of the interposed layer material, the upper limit of the total of the content ratios of the two or more types of the interposed layer material is 100 mass %.

It should be noted that the interposed layer of the exemplary embodiment may further contain any other material than the interposed layer material.

The interposed layer may be provided in the form of a single layer or a laminate of two or more layers.

As long as the overlap between the Singlet emitting region and the TTF emitting region is inhibited, the film thickness of the interposed layer is not particularly limited, but each layer in the interposed layer is preferably in a range from 3 nm to 15 nm, more preferably in a range from 5 nm to 10 nm.

The interposed layer having a film thickness of 3 nm or more easily separates the Singlet emitting region from the emitting region derived from TTF.

The interposed layer having a film thickness of 15 nm or less easily inhibits a phenomenon in which the host material of the interposed layer emits light.

It is preferable that the interposed layer contains the interposed layer material as a material forming the interposed layer and the triplet energy of the first host material T₁(H1), the triplet energy of the second host material T₁(H2), and a triplet energy of at least one interposed layer material T₁(M_{mid}) satisfy a relationship of a numerical formula (Numerical Formula 21) below.

$${T}_{1} ( H 1 ) \geq {T}_{1} ( {M}_{mid} ) \geq {T}_{1} ( H 2 ) \qquad ( Numerical Formula 21 )$$

When the interposed layer contains two or more interposed layer materials as a material forming the interposed layer, the triplet energy of the first host material T₁(H1), the triplet energy of the second host material T₁(H2), and a triplet energy of each interposed layer material T₁(M_{EA}) more preferably satisfy a relationship of a numerical formula (Numerical Formula 21A) below.

$${T}_{1} ( H 1 ) \geq {T}_{1} ( {M}_{EA} ) \geq {T}_{1} ( H 2 ) \qquad ( Numerical Formula 21 A )$$

The organic EL device according to the exemplary embodiment may further include a diffusion layer.

When the organic EL device according to the exemplary embodiment includes the diffusion layer, the diffusion layer is preferably disposed between the first emitting layer and the second emitting layer.

The arrangement of the organic EL device will be further described below. It should be noted that the reference numerals are occasionally omitted below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include indium tin oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Electron Transporting Layer

In an exemplary arrangement of the organic EL device of the exemplary embodiment, the electron transporting layer is provided between the emitting region and the cathode.

The electron transporting layer is a layer containing a highly electron-transporting substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is preferably usable. The above-described substances mostly have an electron mobility of 10⁻⁶ cm²/Vs or more. It should be noted that any other substance than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyridine-3,5-diyl)](abbreviation: PF-Py), poly[(9,9-dioctylfluorene-2,7-diyl)-co-(2,2′-bipyridine-6,6′-diyl)] (abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method(s)

A method of forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

The film thickness of each of the organic layers of the organic EL device in the exemplary embodiment is not limited unless otherwise specified in the above. In general, the thickness preferably ranges from several nanometers to 1 μm because an excessively small film thickness is likely to cause defects (e.g. pin holes) and an excessively large thickness leads to the necessity of applying high voltage and consequent reduction in efficiency.

### Emission Wavelength of Organic EL Device

The organic electroluminescence device according to the exemplary embodiment preferably emits light having a maximum peak wavelength of 500 nm or less when the organic electroluminescence device is driven.

The organic electroluminescence device according to the exemplary embodiment more preferably emits light having a maximum peak wavelength in a range from 430 nm to 480 nm when the organic electroluminescence device is driven.

The maximum peak wavelength of the light emitted from the organic EL device when being driven is measured as follows. Voltage is applied to the organic EL device such that a current density becomes 10 mA/cm², where spectral radiance spectrum is measured by a spectroradiometer CS-2000 (produced by Konica Minolta, Inc.). A peak wavelength of an emission spectrum, at which the luminous intensity of the resultant spectral radiance spectrum is at the maximum, is measured and defined as a maximum peak wavelength (unit: nm).

### Method of Measuring HOMO

Herein, an energy level HOMO of a highest occupied molecular orbital is measured using a photoelectron spectroscope under atmosphere. Specifically, the energy level HOMO of the highest occupied molecular orbital is measurable by a method described in Examples.

### Method of Measuring Electron Mobility

The electron mobility can be measured according to an impedance measurement using a mobility evaluation device produced by the following steps. The mobility evaluation device is, for instance, produced by the following steps.

A compound Target, which is to be measured for an electron mobility, is vapor-deposited on a glass substrate having an aluminum electrode (anode) so as to cover the aluminum electrode, thereby forming a measurement target layer. A compound ET-A below is vapor-deposited on this measurement target layer to form an electron transporting layer. LiF is vapor-deposited on this formed electron transporting layer to form an electron injecting layer. Metal aluminum (Al) is vapor-deposited on this formed electron injecting layer to form a metal cathode.

An arrangement of the mobility evaluation device above is roughly shown as follows.
glass/Al(50)/Target(200)/ET-A(10)/LiF(1)/Al(50)

Numerals in parentheses represent a film thickness (nm).

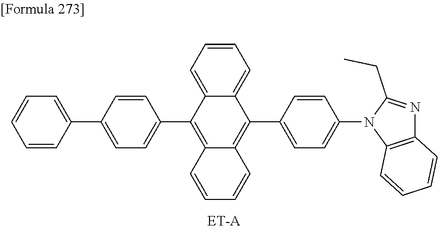 [SMILES: CCc1nc2ccccc2n1-c1ccc(-c2c3ccccc3c(-c3ccc(-c4ccccc4)cc3)c3ccccc23)cc1]

The mobility evaluation device for the electron mobility is set in an impedance measurement apparatus to perform an impedance measurement. In the impedance measurement, a measurement frequency is swept from 1 Hz to 1 MHz. At this time, an alternating current amplitude of 0.1 V and a direct current voltage V are applied to the device. A modulus M is calculated from a measured impedance Z using a relationship of a calculation formula (C1) below.

$$Calculation formula ( C 1 ) : M = j ω Z$$

In the calculation formula (C1), j is an imaginary unit whose square is −1 and w is an angular frequency [rad/s].

In a bode plot in which an imaginary part of the modulus M is represented by an ordinate axis and the frequency [Hz] is represented by an abscissa axis, an electrical time constant T of the mobility evaluation device is obtained from a frequency fmax showing a peak using a calculation formula (C2) below.

$$Calculation formula ( C 2 ) : ⊤ = 1 / ( 2 ⊤ ⊤ fmax )$$

π in the calculation formula (C2) is a symbol representing a circumference ratio.

An electron mobility μe is calculated from a relationship of a calculation formula (C3-1) below using τ.

$$Calculation formula ( C 3 - 1 ) : μ e = {d}^{2} / ( {V}_{⊤} )$$

d in the calculation formula (C3-1) is a total film thickness of organic thin film(s) forming the device. In a case of the arrangement of the mobility evaluation device for the electron mobility, d=210 [nm] is satisfied.

### Method of Measuring Hole Mobility

The hole mobility can be measured according to an impedance measurement using a mobility evaluation device produced by the following steps. The mobility evaluation device is, for instance, produced by the following steps.

A compound HA-2 below is vapor-deposited on a glass substrate having an ITO transparent electrode (anode) so as to cover the transparent electrode, thereby forming a hole injecting layer. A compound HT-A below is vapor-deposited on this formed hole injecting layer to form a hole transporting layer. Subsequently, a compound Target, which is to be measured for a hole mobility, is vapor-deposited to form a measurement target layer. Metal aluminum (Al) is vapor-deposited on this measurement target layer to form a metal cathode.

An arrangement of the mobility evaluation device above is roughly shown as follows.
ITO(130)/HA-2(5)/HT-A(10)/Target(200)/Al(80)

Numerals in parentheses represent a film thickness (nm).

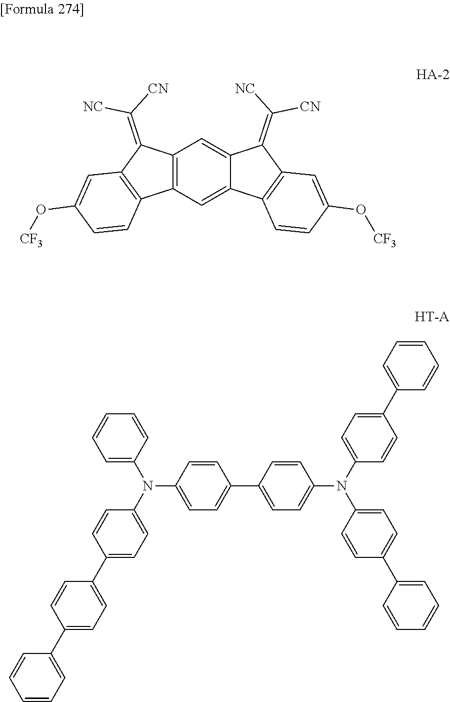 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

The mobility evaluation device for the hole mobility is set in an impedance measurement apparatus to perform an impedance measurement. In the impedance measurement, a measurement frequency is swept from 1 Hz to 1 MHz. At this time, an alternating current amplitude of 0.1 V and a direct current voltage V are applied to the device. A modulus M is calculated from a measured impedance Z using the relationship of the calculation formula (C1).

In a bode plot in which an imaginary part of the modulus M is represented by an ordinate axis and the frequency [Hz] is represented by an abscissa axis, an electrical time constant T of the mobility evaluation device is obtained from a frequency fmax showing a peak using the calculation formula (C2).

A hole mobility ph is calculated from a relationship of a calculation formula (C3-2) below using T obtained from the calculation formula (C2).

$$Calculation formula ( C 3 - 2 ) : μ h = {d}^{2} / ( {V}_{⊤} )$$

d in the calculation formula (C3-2) is a total film thickness of organic thin film(s) forming the device. In a case of the arrangement of the mobility evaluation device for the hole mobility, d=215 [nm] is satisfied.

The electron mobility and the hole mobility herein are each a value obtained in a case where a square root of an electric field intensity meets E^{1/2}=500 [V^{1/2}/cm^{1/2}]. The square root of the electric field intensity, E^{1/2}, can be calculated from a relationship of a calculation formula (C4) below.

$$Calculation formula ( C 4 ) : {E}^{1 / 2} = {V}^{1 / 2} / {d}^{1 / 2}$$

For the impedance measurement, a 1260 type by Solartron Analytical is used as the impedance measurement apparatus, and for a higher accuracy, a 1296 type dielectric constant measurement interface by Solartron Analytical can be used together therewith.

### Second Exemplary Embodiment

An organic electroluminescence display device (hereinafter also referred to as an organic EL display device) according to a second exemplary embodiment will be described below. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable, unless otherwise specified.

### Organic Electroluminescence Display Device

An organic electroluminescence display device according to the second exemplary embodiment includes: an anode and a cathode arranged opposite each other; a blue-emitting organic EL device as a blue pixel; a green-emitting organic EL device as a green pixel; and a red-emitting organic EL device as a red pixel, in which the blue pixel includes the organic EL device according to any arrangement of the first exemplary embodiment as the blue-emitting organic EL device, the green-emitting organic EL device includes a green emitting region provided between the anode and the cathode, the red-emitting organic EL device includes a red emitting region provided between the anode and the cathode, and the first anode side organic layer, the second anode side organic layer, and the third anode side organic layer are provided between the anode and the emitting region of the blue-emitting organic EL device, the green emitting region, and the red emitting region in a shared manner across the blue-emitting organic EL device, the green-emitting organic EL device, and the red-emitting organic EL device.

In the organic EL display device according to the second exemplary embodiment, examples of the arrangement of the blue-emitting organic EL device included in the blue pixel include the first arrangement, the second arrangement, the third arrangement, the fourth arrangement, and the fifth arrangement of the first exemplary embodiment. In the organic EL display device herein, the emitting region of the blue-emitting organic EL device included in the blue pixel is occasionally referred to as a blue emitting region.

For instance, an organic EL display device including the organic EL device according to the first arrangement of the first exemplary embodiment includes:
an anode and a cathode arranged opposite each other;
a blue-emitting organic EL device as a blue pixel; a green-emitting organic EL device as a green pixel; and a red-emitting organic EL device as a red pixel,
in which the blue-emitting organic EL device includes a blue emitting region provided between the anode and the cathode,
the blue emitting region includes at least one blue emitting layer,
the green-emitting organic EL device includes a green emitting region provided between the anode and the cathode,
the green emitting region includes at least one green emitting layer,
the red-emitting organic EL device includes a red emitting region provided between the anode and the cathode,
the red emitting region includes at least one red emitting layer,
the first anode side organic layer, the second anode side organic layer, and the third anode side organic layer are provided between the anode and the blue emitting region of the blue-emitting organic EL device, the green emitting region of the green-emitting organic EL device, and the red emitting region of the red-emitting organic EL device in a shared manner across the blue-emitting organic EL device, the green-emitting organic EL device, and the red-emitting organic EL device,
the first anode side organic layer, the second anode side organic layer, and the third anode side organic layer are provided between the anode and the blue emitting region, the green emitting region, and the red emitting region in this order from the side close to the anode,
the third anode side organic layer does not contain a compound contained in the second anode side organic layer,
the total of a film thickness of the second anode side organic layer and a film thickness of the third anode side organic layer is in range from 30 nm to 150 nm, and
a ratio of the film thickness of the third anode side organic layer to the film thickness of the second anode side organic layer satisfies the relationship of the numerical formula (Numerical Formula 1).

For instance, an organic EL display device including the organic EL device according to the second arrangement of the first exemplary embodiment includes:
an anode and a cathode arranged opposite each other;
a blue-emitting organic EL device as a blue pixel; a green-emitting organic EL device as a green pixel; and a red-emitting organic EL device as a red pixel,
in which the blue-emitting organic EL device includes a blue emitting region provided between the anode and the cathode,
the blue emitting region includes at least one blue emitting layer,
the green-emitting organic EL device includes a green emitting region provided between the anode and the cathode,
the green emitting region includes at least one green emitting layer,
the red-emitting organic EL device includes a red emitting region provided between the anode and the cathode,
the red emitting region includes at least one red emitting layer,
the first anode side organic layer, the second anode side organic layer, and the third anode side organic layer are provided between the anode and the blue emitting region of the blue-emitting organic EL device, the green emitting region of the green-emitting organic EL device, and the red emitting region of the red-emitting organic EL device in a shared manner across the blue-emitting organic EL device, the green-emitting organic EL device, and the red-emitting organic EL device,
the first anode side organic layer, the second anode side organic layer, and the third anode side organic layer are provided between the anode and the blue emitting region, the green emitting region, and the red emitting region in this order from the side close to the anode,
the third anode side organic layer does not contain a compound contained in the second anode side organic layer,
the third anode side organic layer contains a compound represented by the formula (C1) or a compound represented by the formula (C2),
a total of a film thickness of the second anode side organic layer and a film thickness of the third anode side organic layer is in range from 30 nm to 150 nm, and
a ratio of the film thickness of the third anode side organic layer to the film thickness of the second anode side organic layer satisfies the relationship of the numerical formula (Numerical Formula A2).

For instance, an organic EL display device including the organic EL device according to the third arrangement of the first exemplary embodiment includes:
an anode and a cathode arranged opposite each other;
a blue-emitting organic EL device as a blue pixel; a green-emitting organic EL device as a green pixel; and a red-emitting organic EL device as a red pixel,
in which the blue-emitting organic EL device includes a blue emitting region provided between the anode and the cathode,
the blue emitting region includes at least one blue emitting layer,
the green-emitting organic EL device includes a green emitting region provided between the anode and the cathode,
the green emitting region includes at least one green emitting layer,
the red-emitting organic EL device includes a red emitting region provided between the anode and the cathode,
the red emitting region includes at least one red emitting layer,
the first anode side organic layer, the second anode side organic layer, and the third anode side organic layer are provided between the anode and the blue emitting region of the blue-emitting organic EL device, the green emitting region of the green-emitting organic EL device, and the red emitting region of the red-emitting organic EL device in a shared manner across the blue-emitting organic EL device, the green-emitting organic EL device, and the red-emitting organic EL device,
the first anode side organic layer, the second anode side organic layer, and the third anode side organic layer are provided between the anode and the blue emitting region, the green emitting region, and the red emitting region in this order from the side close to the anode,
the first anode side organic layer, the second anode side organic layer, and the third anode side organic layer each contain at least one compound, the compounds respectively contained in the first, second, and third anode side organic layers being different from each other,
the third anode side organic layer does not contain a compound contained in the second anode side organic layer,
the third anode side organic layer contains a third hole transporting zone material, and
a hole mobility of the third hole transporting zone material μh(cHT3) is larger than 1.0×10⁻⁵ cm²/Vs, and an energy level of a highest occupied molecular orbital of the third hole transporting zone material HOMO(cHT3) is −5.6 eV or less.

For instance, an organic EL display device including the organic EL device according to the fourth arrangement of the first exemplary embodiment includes:
an anode and a cathode arranged opposite each other;
a blue-emitting organic EL device as a blue pixel; a green-emitting organic EL device as a green pixel; and a red-emitting organic EL device as a red pixel,
in which the blue-emitting organic EL device includes a blue emitting region provided between the anode and the cathode,
the blue emitting region includes at least one blue emitting layer,
the green-emitting organic EL device includes a green emitting region provided between the anode and the cathode,
the green emitting region includes at least one green emitting layer,
the red-emitting organic EL device includes a red emitting region provided between the anode and the cathode,
the red emitting region includes at least one red emitting layer,
the first anode side organic layer, the second anode side organic layer, and the third anode side organic layer are provided between the anode and the blue emitting region of the blue-emitting organic EL device, the green emitting region of the green-emitting organic EL device, and the red emitting region of the red-emitting organic EL device in a shared manner across the blue-emitting organic EL device, the green-emitting organic EL device, and the red-emitting organic EL device,
the first anode side organic layer, the second anode side organic layer, and the third anode side organic layer are provided between the anode and the blue emitting region, the green emitting region, and the red emitting region in this order from the side close to the anode,
the third anode side organic layer does not contain a compound contained in the second anode side organic layer, and
a total of a film thickness of the second anode side organic layer and a film thickness of the third anode side organic layer is 100 nm or more.

For instance, an organic EL display device including the organic EL device according to the fifth arrangement of the first exemplary embodiment includes:
an anode and a cathode arranged opposite each other;
a blue-emitting organic EL device as a blue pixel; a green-emitting organic EL device as a green pixel; and a red-emitting organic EL device as a red pixel,
in which the blue-emitting organic EL device includes a blue emitting region provided between the anode and the cathode,
the blue emitting region includes at least one blue emitting layer,
the green-emitting organic EL device includes a green emitting region provided between the anode and the cathode,
the green emitting region includes at least one green emitting layer,
the red-emitting organic EL device includes a red emitting region provided between the anode and the cathode,
the red emitting region includes at least one red emitting layer,
the first anode side organic layer, the second anode side organic layer, and the third anode side organic layer are provided between the anode and the blue emitting region of the blue-emitting organic EL device, the green emitting region of the green-emitting organic EL device, and the red emitting region of the red-emitting organic EL device in a shared manner across the blue-emitting organic EL device, the green-emitting organic EL device, and the red-emitting organic EL device,
the first anode side organic layer, the second anode side organic layer, and the third anode side organic layer are provided between the anode and the blue emitting region, the green emitting region, and the red emitting region in this order from the side close to the anode,
the third anode side organic layer does not contain a compound contained in the second anode side organic layer,
a total of a film thickness of the second anode side organic layer and a film thickness of the third anode side organic layer is 30 nm or more,
a ratio of the film thickness of the third anode side organic layer to the film thickness of the second anode side organic layer satisfies the relationship of the numerical formula (Numerical Formula A4), and
the third anode side organic layer contains a third hole transporting zone material, and a singlet energy of the third hole transporting zone material is larger than 3.12 eV.

The organic EL display device of the second exemplary embodiment is not limited to these arrangements.

The elements that may be contained in the blue-emitting organic EL device of the organic EL display device according to each of the arrangements of the second exemplary embodiment are similar to the elements that may be contained in the organic EL device described in the first exemplary embodiment.

Since the blue pixel of the organic EL display device according to the second exemplary embodiment includes, as the blue-emitting organic EL device, the organic EL device according to any of the arrangements of the first exemplary embodiment, the blue-emitting organic EL device as the blue pixel has improved luminous efficiency. The performance of the organic EL display device is thus improved.

Further, the blue-emitting organic EL device as the blue pixel has improved luminous efficiency by providing the first emitting layer and the second emitting layer that satisfy the relationship of the numerical formula (Numerical Formula 1) in the emitting region of the blue-emitting organic EL device similarly to the first exemplary embodiment, as compared to a case where the emitting region includes a single emitting layer.

The blue-emitting organic EL device as the blue pixel has a longer lifetime by providing the fourth anode side organic layer between the emitting region of the blue-emitting organic EL device and the third anode side organic layer similarly to the first exemplary embodiment.

Herein, a layer provided in a shared manner across a plurality of devices is occasionally referred to as a common layer. Herein, a layer not provided in a shared manner across a plurality of devices is occasionally referred to as a non-common layer.

Herein, a zone provided in a shared manner across a plurality of devices is occasionally referred to as a common zone. The hole transporting zone, which is provided between the anode and the blue emitting region of the blue-emitting organic EL device, the green emitting layer of the green-emitting organic EL device, and the red emitting layer of the red-emitting organic EL device in a shared manner across the blue-emitting organic EL device, the green-emitting organic EL device, and the red-emitting organic EL device, is a common zone.

Herein, “blue”, “green”, or “red” used for each element, such as “pixel”, “emitting layer”, “organic layer”, or “material”, is used to distinguish one from another. Although “blue”, “green”, or “red” may represent a color of light emitted from “pixel”, “emitting layer”, “organic layer”, or “material”, “blue”, “green”, or “red” does not mean the color of appearance of each element.

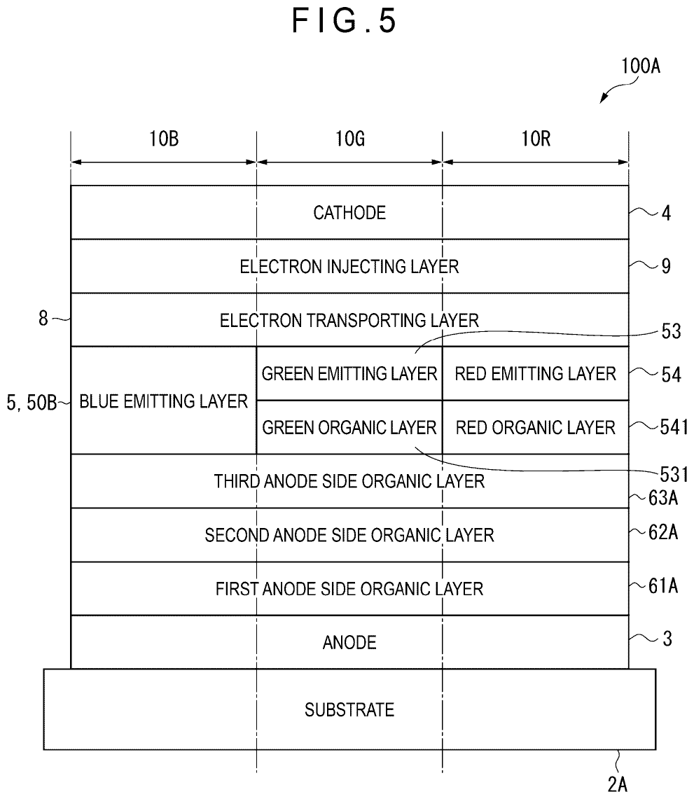

Referring to FIG. 5, explanation is made about an exemplary arrangement of the organic EL display device according to the second exemplary embodiment.

FIG. 5 depicts an organic EL display device 100A according to an exemplary embodiment.

The organic EL display device 100A includes electrodes and organic layers supported by a substrate 2A.

The organic EL display device 100A includes the anode 3 and the cathode 4 arranged opposite each other.

The organic EL display device 100A includes a blue-emitting organic EL device 10B as a blue pixel, a green-emitting organic EL device 10G as a green pixel, and a red-emitting organic EL device 10R as a red pixel.

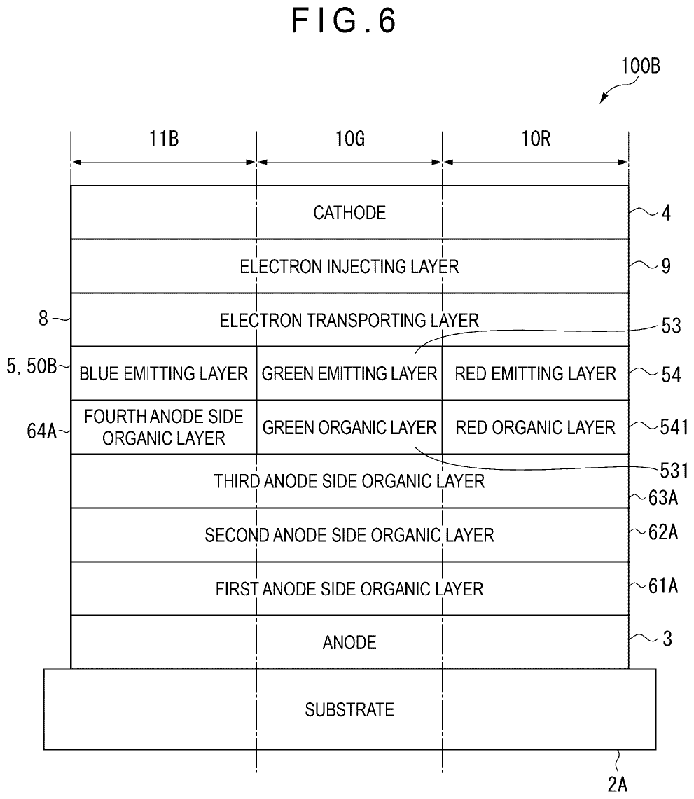

It should be noted that FIG. 5 schematically depicts the organic EL display device 100A, and thus does not limit, for instance, a thickness of each layer of the device 100A and a size of the device 100A. For instance, FIG. 5 depicts that a green emitting layer 53 and a red emitting layer 54 have the same thickness, but does not necessarily mean that these layers in an actual organic EL display device have the same thickness. The same applies to organic EL display devices depicted in FIGS. 6 to 8.

In the organic EL display device 100A, a hole transporting zone as the common zone is provided between the anode 3 and the respective emitting regions of the blue-emitting organic EL device 10B, the green-emitting organic EL device 10G, and the red-emitting organic EL device 10R.

In the hole transporting zone of the organic EL display device 100A, a first anode side organic layer 61A, a second anode side organic layer 62A, and a third anode side organic layer 63A are layered in this order from the side close to the anode 3. In the organic EL display device 100A, the hole transporting zone is provided in a shared manner across the blue-emitting organic EL device 10B, the green-emitting organic EL device 10G, and the red-emitting organic EL device 10R.

In the organic EL display device 100A, the electron transporting layer 8 and the electron injecting layer 9 as the common layers are layered in this order between the cathode and the respective emitting regions of the organic EL devices 10B,10G,10R.

A blue emitting region 5 of the blue-emitting organic EL device 10B of the organic EL display device 100A is similar to the emitting region 5 according to the first exemplary embodiment. The blue emitting region 5 includes a blue emitting layer 50B. The blue emitting layer 50B corresponds to the emitting layer 50 according to the first exemplary embodiment.

The green emitting region of the green-emitting organic EL device 10G of the organic EL display device 100A includes the green emitting layer 53. In the green-emitting organic EL device 10G, a green organic layer 531 as the non-common layer is provided between the green emitting layer 53 and the third anode side organic layer 63A.

The red emitting region of the red-emitting organic EL device 10R of the organic EL display device 100A includes the red emitting layer 54. In the red-emitting organic EL device 10R, a red organic layer 541 as the non-common layer is provided between the red emitting layer 54 and the third anode side organic layer 63A.

The anode 3 of the organic EL display device 100A is formed by the anodes of the blue-emitting organic EL device 10B, the green-emitting organic EL device 10G, and the red-emitting organic EL device 10R. The anode 3 is independently provided for each of the blue-emitting organic EL device 10B, the green-emitting organic EL device 10G, and the red-emitting organic EL device 10R. Thus, the blue-emitting organic EL device 10B, the green-emitting organic EL device 10G, and the red-emitting organic EL device 10R can be individually driven in the organic EL display device 100A. The respective anodes of the organic EL devices 10B,10G,10R are insulated from each other by an insulation material (not depicted). The cathode 4 of the organic EL display device 100A is formed by the cathodes of the blue-emitting organic EL device 10B, the green-emitting organic EL device 10G, and the red-emitting organic EL device 10R. The cathode 4 is provided in a shared manner across the blue-emitting organic EL device 10B, the green-emitting organic EL device 10G, and the red-emitting organic EL device 10R.

In an exemplary embodiment, the blue-emitting organic EL device 10B, the green-emitting organic EL device 10G, and the red-emitting organic EL device 10R as pixels are arranged in parallel with each other on the substrate 2A.

FIG. 6 schematically depicts another exemplary arrangement of the organic EL display device according to the second exemplary embodiment.

An organic EL display device 100B depicted in FIG. 6 is configured the same as the organic EL display device 100A depicted in FIG. 5 except for a blue-emitting organic EL device 11B as a blue pixel. Thus, only differences from the organic EL display device 100A are described below.

The blue-emitting organic EL device 11B includes a fourth anode side organic layer 64A as the non-common layer between the blue emitting layer 50B and the third anode side organic layer 63A. In FIG. 6, the fourth anode side organic layer 64A is in direct contact with the blue emitting layer 50B and the third anode side organic layer 63A. The fourth anode side organic layer 64A is preferably an electron blocking layer.

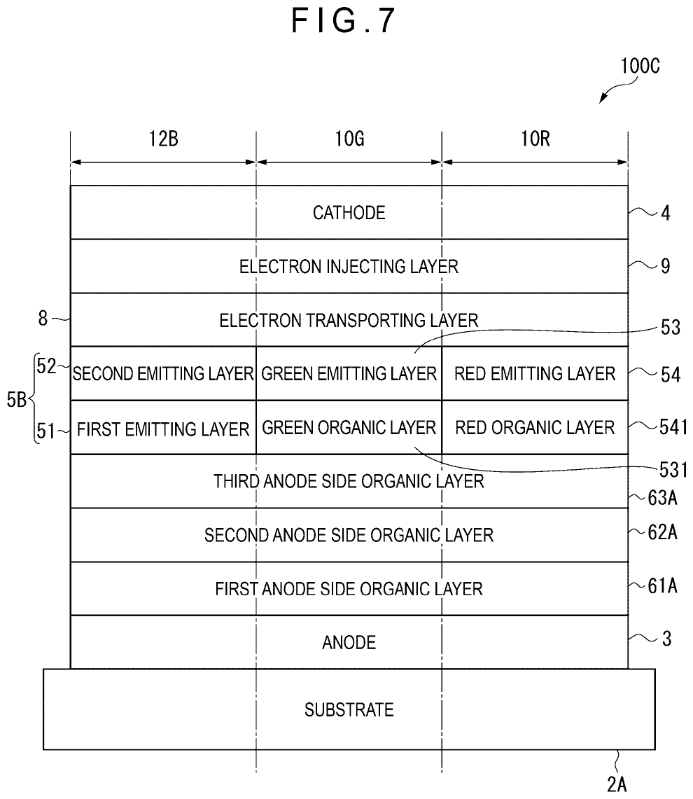

FIG. 7 schematically depicts still another exemplary arrangement of the organic EL display device according to the second exemplary embodiment.

An organic EL display device 100C depicted in FIG. 7 is configured the same as the organic EL display device 100A depicted in FIG. 5 except for a blue-emitting organic EL device 12B as a blue pixel. Thus, only differences from the organic EL display device 100A are described below.

A blue emitting region 5B of the blue-emitting organic EL device 12B is similar to the emitting region 5B of the first exemplary embodiment. In the blue emitting region 5B, the first emitting layer 51 and the second emitting layer 52 are layered in this order.

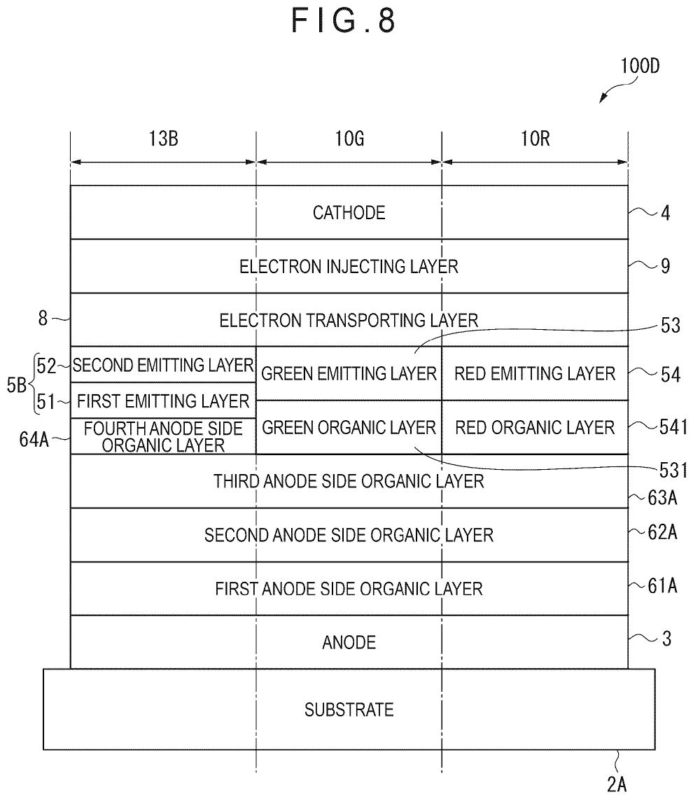

FIG. 8 schematically depicts yet another exemplary arrangement of the organic EL display device according to the second exemplary embodiment.

An organic EL display device 100D depicted in FIG. 8 is configured the same as the organic EL display device 100A depicted in FIG. 5 except for a blue-emitting organic EL device 13B as a blue pixel. Thus, only differences from the organic EL display device 100A are described below.

The blue-emitting organic EL device 13B includes the fourth anode side organic layer 64A as the non-common layer between the third anode side organic layer 63A and the first emitting layer 51 of the blue emitting region 5B. In FIG. 8, the fourth anode side organic layer 64A is in direct contact with the first emitting layer 51 and the third anode side organic layer 63A. The fourth anode side organic layer 64A is preferably an electron blocking layer.

The invention is not limited to the arrangements of the organic EL display device depicted in FIGS. 5 to 8.

For instance, in an exemplary arrangement of the organic EL display device of the second exemplary embodiment, the green organic layer 531 is not provided between the green emitting layer 53 and the third anode side organic layer 63A, and the green emitting layer 53 is in direct contact with the third anode side organic layer 63A.

For instance, in an exemplary arrangement of the organic EL display device of the second exemplary embodiment, the red organic layer 541 is not provided between the red emitting layer 54 and the third anode side organic layer 63A, and the red emitting layer 54 is in direct contact with the third anode side organic layer 63A.

For instance, in an exemplary arrangement of the organic EL display device of the second exemplary embodiment, the blue-emitting organic EL device, the green-emitting organic EL device, and the red-emitting organic EL device may each independently further include a layer different from the layers depicted in FIGS. 5 to 8. For instance, a hole blocking layer may be provided as the common layer between the emitting regions and the electron transporting layer.

For instance, in an exemplary arrangement of the organic EL display device of the second exemplary embodiment, the blue-emitting organic EL device, the green-emitting organic EL device, and the red-emitting organic EL device may be each independently a device that fluoresces or a device that phosphoresces. The blue-emitting organic EL device is preferably a device that fluoresces.

In an exemplary arrangement of the organic EL display device of the second exemplary embodiment, the third anode side organic layer as the common layer contains a third hole transporting zone material, and a hole mobility of the third hole transporting zone material μh(cHT3) is larger than 1.0×10⁻⁵ cm²/Vs, and an energy level of a highest occupied molecular orbital of the third hole transporting zone material HOMO(cHT3) is −5.6 eV or less. When the third anode side organic layer as the common layer contains the third hole transporting zone material having such a hole mobility and HOMO, hole injectability to the emitting regions of the blue pixel, the green pixel, and the red pixel is improved. Further, when the organic EL display device includes the fourth anode side organic layer, the green organic layer 531, and the red organic layer 541, the hole injectability to those layers is high.

In an exemplary arrangement of the organic EL display device of the second exemplary embodiment, the first anode side organic layer as the common layer contains the first hole transporting zone material of the first exemplary embodiment.

In an exemplary arrangement of the organic EL display device of the second exemplary embodiment, the second anode side organic layer as the common layer contains the second hole transporting zone material of the first exemplary embodiment.

In an exemplary arrangement of the organic EL display device of the second exemplary embodiment, the fourth anode side organic layer as the non-common layer contains the fourth hole transporting zone material of the first exemplary embodiment.

### Emission Wavelength of Organic EL Device

The blue-emitting organic EL device of the organic EL display device according to the exemplary embodiment preferably emits light having a maximum peak wavelength of 500 nm or less when being driven.

The blue-emitting organic EL device of the organic EL display device according to the exemplary embodiment more preferably emits light having a maximum peak wavelength in a range from 430 nm to 480 nm when being driven.

The maximum peak wavelength of the light emitted from the organic EL device when being driven is measured as follows. Voltage is applied to the organic EL device such that a current density becomes 10 mA/cm², where spectral radiance spectrum is measured by a spectroradiometer CS-2000 (produced by Konica Minolta, Inc.). A peak wavelength of an emission spectrum, at which the luminous intensity of the obtained spectral radiance spectrum is at the maximum, is measured and defined as a maximum peak wavelength (unit: nm).

In an exemplary arrangement of the organic EL display device of the second exemplary embodiment, the green emitting layer contains a host material. For instance, the green emitting layer contains 50 mass % or more of the host material with respect to the total mass of the green emitting layer.

In an exemplary arrangement of the organic EL display device of the second exemplary embodiment, the green emitting layer of the green-emitting organic EL device contains a green emitting compound that emits light having a maximum peak wavelength in a range from 500 nm to 550 nm. For instance, the green emitting compound is a fluorescent compound that exhibits fluorescence having a maximum peak wavelength in a range from 500 nm to 550 nm. For instance, the green emitting compound is a phosphorescent compound that exhibits phosphorescence having a maximum peak wavelength in a range from 500 nm to 550 nm. Herein, the green light emission refers to light emission in which a maximum peak wavelength of emission spectrum is in a range from 500 nm to 550 nm.

The fluorescent compound is a compound capable of emitting in a singlet state. The phosphorescent compound is a compound capable of emitting in a triplet state.

Examples of a green fluorescent compound usable for the green emitting layer include an aromatic amine derivative. Examples of a green phosphorescent compound usable for the green emitting layer include an iridium complex.

### Maximum Phosphorescence Peak Wavelength (PH-peak)

A maximum peak wavelength (maximum phosphorescence peak wavelength) of a phosphorescent compound is measurable by the following method. A measurement target compound is dissolved in EPA (diethylether:isopentane:ethanol=5:5:2 in volume ratio) so as to fall within a range from 10⁻⁵ mol/L to 10⁻⁴ mol/L, and the obtained EPA solution is encapsulated in a quartz cell to provide a measurement sample. A phosphorescence spectrum (ordinate axis: phosphorescent luminous intensity, abscissa axis: wavelength) of the measurement sample is measured at a low temperature (77K). The local maximum value closest to the short-wavelength region among the local maximum values of the phosphorescence spectrum is defined as the maximum phosphorescence peak wavelength. A spectrophotofluorometer F-7000 produced by Hitachi High-Tech Science Corporation can be used to measure phosphorescence. The measurement apparatus is not limited to this arrangement. A combination of a cooling unit, a low temperature container, an excitation light source and a light-receiving unit may be used for measurement. Herein, the maximum peak wavelength of phosphorescence is occasionally referred to as the maximum phosphorescence peak wavelength (PH-peak).

In an exemplary arrangement of the organic EL display device of the second exemplary embodiment, the green-emitting organic EL device includes the green organic layer between the green emitting layer and the third anode side organic layer. The green organic layer may be in direct contact with the hole transporting zone. The green organic layer may be in direct contact with the green emitting layer. An emission position in the green-emitting organic EL device is easily adjustable by providing the green organic layer in the green-emitting organic EL device.

The green organic layer contains a green organic material. The hole transporting zone material according to the first exemplary embodiment is usable as the green organic material. Although the green organic material and the hole transporting zone material contained in the hole transporting zone may be the same compound or different compounds, the green organic material is preferably different from the hole transporting zone material. The hole mobility of the green organic material is preferably larger than the hole mobility of the hole transporting zone material contained in the hole transporting zone. The green organic material is a compound different from the host material and the green emitting compound contained in the green emitting layer.

In an exemplary arrangement of the organic EL display device of the second exemplary embodiment, the red emitting layer contains a host material. For instance, the red emitting layer contains 50 mass % or more of the host material with respect to the total mass of the red emitting layer.

In an exemplary arrangement of the organic EL display device of the second exemplary embodiment, the red emitting layer of the red organic EL device contains a red emitting compound that emits light having a maximum peak wavelength in a range from 600 nm to 640 nm. For instance, the red emitting compound is a fluorescent compound that exhibits fluorescence having a maximum peak wavelength in a range from 600 nm to 640 nm. For instance, the red emitting compound is a phosphorescent compound that exhibits phosphorescence having a maximum peak wavelength in a range from 600 nm to 640 nm. Herein, the red light emission refers to light emission in which a maximum peak wavelength of emission spectrum is in a range from 600 nm to 640 nm.

Examples of a red fluorescent compound usable for the red emitting layer include a tetracene derivative and a diamine derivative. Examples of a red phosphorescent compound usable for the red emitting layer include metal complexes such as an iridium complex, platinum complex, terbium complex, and europium complex.

In an exemplary arrangement of the organic EL display device of the second exemplary embodiment, the red-emitting organic EL device preferably includes the red organic layer between the red emitting layer and the third anode side organic layer. The red organic layer may be in direct contact with the hole transporting zone. The red organic layer may be in direct contact with the red emitting layer. In an exemplary arrangement of the organic EL display device of the second exemplary embodiment, an emission position in the red-emitting organic EL device is easily adjustable by providing the red organic layer in the red-emitting organic EL device.

The red organic layer contains a red organic material. The hole transporting zone material according to the first exemplary embodiment is usable as the red organic material. Although the red organic material and the hole transporting zone material contained in the hole transporting zone may be the same compound or different compounds, the red organic material is preferably different from the hole transporting zone material. The hole mobility of the red organic material is preferably larger than the hole mobility of the hole transporting zone material contained in the hole transporting zone. The red organic material is a compound different from the host material and the red emitting compound contained in the red emitting layer.

Although the red organic material contained in the red organic layer of the red-emitting organic EL device and the green organic material contained in the green organic layer of the green-emitting organic EL device may be the same compound or different compounds, the red organic material is preferably different from the green organic material. The hole mobility of the red organic material is preferably larger than the hole mobility of the green organic material.

In an exemplary arrangement of the organic EL display device of the second exemplary embodiment, the film thickness of the red organic layer is preferably larger than the film thickness of the green organic layer.

In an exemplary arrangement of the organic EL display device of the second exemplary embodiment, the host material contained in the green emitting layer and the host material contained in the red emitting layer are, for instance, a compound for dispersing a highly emittable substance (dopant material) in the emitting layers. As the host material contained in the green emitting layer and the host material contained in the red emitting layer, it is possible to use, for instance, a substance having a higher Lowest Unoccupied Molecular Orbital (LUMO) level and a lower Highest Occupied Molecular Orbital (HOMO) level than the highly emittable substance.

For instance, the following compounds (1) to (4) can be each independently used as the host material contained in the green emitting layer and the host material contained in the red emitting layer.
(1) a metal complex such as an aluminum complex, beryllium complex, and zinc complex
(2) a heterocyclic compound such as an oxadiazole derivative, benzimidazole derivative, or phenanthroline derivative
(3) a fused aromatic compound such as a carbazole derivative, anthracene derivative, phenanthrene derivative, pyrene derivative or chrysene derivative
(4) an aromatic amine compound such as a triarylamine derivative or a fused polycyclic aromatic amine derivative

Referring to FIG. 5, the organic EL display device according to the second exemplary embodiment is further explained. Descriptions on the same arrangements as those of the organic EL device according to the first exemplary embodiment are simplified or omitted.

### Anode

In an exemplary embodiment, the anode 3 is arranged opposite to the cathode 4.

In an exemplary embodiment, the anode 3 is typically the non-common layer. In an exemplary embodiment, for instance, when the anode 3 is the non-common layer, the respective anodes in the blue-emitting organic EL device 10B, the green-emitting organic EL device 10G and the red-emitting organic EL device 10R are physically separated from each other, and specifically, may be insulated from each other by an insulation material (not illustrated in the drawings) or the like.

### Cathode

In an exemplary embodiment, the cathode 4 is arranged opposite to the anode 3.

In an exemplary embodiment, the cathode 4 may be the common layer or the non-common layer.

In an exemplary embodiment, the cathode 4 is preferably the common layer provided in a shared manner across the blue-emitting organic EL device 10B, the green-emitting organic EL device 10G, and the red-emitting organic EL device 10R.

In an exemplary embodiment, the cathode 4 is in direct contact with the electron injecting layer 9.

In an exemplary embodiment, when the cathode 4 is the common layer, the film thickness of the cathode 4 is constant over the blue-emitting organic EL device 10B, the green-emitting organic EL device 10G, and the red-emitting organic EL device 10R. When the cathode 4 is the common layer, the cathode 4 provided for the blue-emitting organic EL device 10B, the green-emitting organic EL device 10G, and the red-emitting organic EL device 10R can be produced without changing a mask or the like. The organic EL display device 100A thus has enhanced productivity.

### Electron Transporting Layer

In an exemplary embodiment, the electron transporting layer 8 is the common layer provided in a shared manner across the blue-emitting organic EL device 10B, the green-emitting organic EL device 10G, and the red-emitting organic EL device 10R.

In an exemplary embodiment, the electron transporting layer 8 is provided between the electron injecting layer 9 and the emitting layers of the blue-emitting organic EL device 10B, the green-emitting organic EL device 10G, and the red-emitting organic EL device 10R.

In an exemplary embodiment, the side of the electron transporting layer 8 close to the anode 3 is in direct contact with the emitting region 5 (blue emitting layer 50B), the green emitting layer 53, and the red emitting layer 54.

The side of the electron transporting layer 8 close to the cathode 4 is in direct contact with the electron injecting layer 9.

In an exemplary embodiment, the electron transporting layer 8 is the common layer. In this case, the film thickness of the electron transporting layer 8 is constant over the blue-emitting organic EL device 10B, the green-emitting organic EL device 10G, and the red-emitting organic EL device 10R. When the electron transporting layer 8 is the common layer, the electron transporting layer 8 provided for the blue-emitting organic EL device 10B, the green-emitting organic EL device 10G, and the red-emitting organic EL device 10R can be produced without changing a mask or the like. The organic EL display device 100A thus has enhanced productivity.

### Electron Injecting Layer

In an exemplary embodiment, the electron injecting layer 9 is the common layer provided in a shared manner across the blue-emitting organic EL device 10B, the green-emitting organic EL device 10G, and the red-emitting organic EL device 10R.

In an exemplary embodiment, the electron injecting layer 9 is disposed between the electron transporting layer 8 and the cathode 4.

In an exemplary embodiment, the electron injecting layer 9 is in direct contact with the electron transporting layer 8.

In an exemplary embodiment, the electron injecting layer 9 is the common layer. In this case, the film thickness of the electron injecting layer 9 is constant over the blue-emitting organic EL device 10B, the green-emitting organic EL device 10G, and the red-emitting organic EL device 10R. When the electron injecting layer 9 is the common layer, the electron injecting layer 9 provided for the blue-emitting organic EL device 10B, the green-emitting organic EL device 10G, and the red-emitting organic EL device 10R can be produced without changing a mask or the like. The organic EL display device 100A thus has enhanced productivity.

In an exemplary embodiment, any other layer than the emitting layer(s), the first emitting layer, the second emitting layer, the fourth anode side organic layer, the green emitting layer, the red emitting layer, the green organic layer and the red organic layer is preferably provided in a shared manner across the blue-emitting organic EL device, the green-emitting organic EL device, and the red-emitting organic EL device. Reducing the number of the non-common layers in the organic EL display device improves productivity of the device.

### Method of Producing Organic EL Display Device

As an exemplary method of producing the organic EL display device of the second exemplary embodiment, explanation is made about a method of producing the organic EL display device 100A depicted in FIG. 5.

First, the anode 3 is formed on the substrate 2A.

Subsequently, the anode side organic layers as the common layers (first anode side organic layer 61A, second anode side organic layer 62A, and third anode side organic layer 63A) are sequentially formed on the anode 3 to extend thereover, forming the hole transporting zone as the common zone. Respective organic layers in the hole transporting zone of the blue-emitting organic EL device 10B, the green-emitting organic EL device 10G, and the red-emitting organic EL device 10R are formed to have the same film thickness.

Subsequently, the blue emitting layer 50B is formed on the third anode side organic layer 63A in a region corresponding to the anode 3 of the blue-emitting organic EL device 10B using a predetermined film-forming mask (mask for the blue-emitting organic EL device).

Subsequently, the green organic layer 531 is formed on the third anode side organic layer 63A in a region corresponding to the anode 3 of the green-emitting organic EL device 10G using a predetermined film-forming mask (mask for the green-emitting organic EL device). After forming the green organic layer 531, the green emitting layer 53 is formed on the green organic layer 531.

Subsequently, the red organic layer 541 is formed on the third anode side organic layer 63A in a region corresponding to the anode 3 of the red-emitting organic EL device 10R using a predetermined film-forming mask (mask for the red-emitting organic EL device). After forming the red organic layer 541, the red emitting layer 54 is formed on the red organic layer 541.

The emitting layer 50, the green emitting layer 53, and the red emitting layer 54 are formed from mutually different materials.

After the formation of the third anode side organic layer 63A, the order of forming the non-common layers of the blue-emitting organic EL device 10B, the green-emitting organic EL device 10G, and the red-emitting organic EL device 10R is not particularly limited.

For instance, after forming the third anode side organic layer 63A, the green organic layer 531 and the green emitting layer 53 of the green-emitting organic EL device 10G may be formed, then the red organic layer 541 and the red emitting layer 54 of the red-emitting organic EL device 10R may be formed, and then the blue emitting layer 50B of the blue-emitting organic EL device 10B may be formed.

Alternatively, for instance, after forming the third anode side organic layer 63A, the red organic layer 541 and the red emitting layer 54 of the red-emitting organic EL device 10R may be formed, then the green organic layer 531 and the green emitting layer 53 of the green-emitting organic EL device 10G may be formed, and then the blue emitting layer 50B of the blue-emitting organic EL device 10B may be formed.

Subsequently, the electron transporting layer 8 as the common layer is formed on the blue emitting layer 50B, the green emitting layer 53, and the red emitting layer 54 to extend thereover. The electron transporting layer 8 of the blue-emitting organic EL device 10B, the green-emitting organic EL device 10G, and the red-emitting organic EL device 10R is formed to have a constant film thickness using the same material.

Subsequently, the electron injecting layer 9 as the common layer is formed on the electron transporting layer 8. The electron injecting layer 9 of the blue-emitting organic EL device 10B, the green-emitting organic EL device 10G, and the red-emitting organic EL device 10R is formed to have a constant film thickness using the same material.

Subsequently, the cathode 4 as the common layer is formed on the electron injecting layer 9. The cathode 4 of the blue-emitting organic EL device 10B, the green-emitting organic EL device 10G, and the red-emitting organic EL device 10R is formed to have a constant film thickness using the same material.

The organic EL display device 100A depicted in FIG. 5 is produced as described above.

The organic EL display device 100B depicted in FIG. 6 is different from the organic EL display device 100A depicted in FIG. 5 in that the organic EL display device 100B includes the fourth anode side organic layer 64A. In producing the organic EL display device 100B depicted in FIG. 6, the fourth anode side organic layer 64A is formed on the third anode side organic layer 63A in a region corresponding to the anode 3 of the blue-emitting organic EL device 11B using a predetermined film-forming mask (mask for the blue-emitting organic EL device). Subsequently, the blue emitting layer 50B is formed on the fourth anode side organic layer 64A. Any other producing steps of the organic EL display device 100B are similar to those of the organic EL display device 100A.

The organic EL display device 1000 depicted in FIG. 7 is different from the organic EL display device 100A depicted in FIG. 5 in that the emitting region 5B includes the first emitting layer 51 and the second emitting layer 52. In producing the organic EL display device 1000 depicted in FIG. 7, the first emitting layer 51 is formed on the third anode side organic layer 63A in a region corresponding to the anode 3 of the blue-emitting organic EL device 12B using a predetermined film-forming mask (mask for the blue-emitting organic EL device). Subsequently, the second emitting layer 52 is formed on the first emitting layer 51. After that, the electron transporting layer 8 as the common layer is formed on the second emitting layer 52, the green emitting layer 53, and the red emitting layer 54 to extend thereover. Any other producing steps of the organic EL display device 1000 are similar to those of the organic EL display device 100A.

The organic EL display device 100D depicted in FIG. 8 is different from the organic EL display device 1000 depicted in FIG. 7 in that the organic EL display device 100D includes the fourth anode side organic layer 64A. In producing the organic EL display device 100D depicted in FIG. 8, the fourth anode side organic layer 64A is formed on the third anode side organic layer 63A in a region corresponding to the anode 3 of the blue-emitting organic EL device 13B using a predetermined film-forming mask (mask for the blue-emitting organic EL device). Subsequently, the first emitting layer 51 is formed on the fourth anode side organic layer 64A. After that, the second emitting layer 52 is formed on the first emitting layer 51. Any other producing steps of the organic EL display device 100D are similar to those of the organic EL display device 100C.

The organic EL display device of the exemplary embodiment may include, as the blue-emitting organic EL device, the green-emitting organic EL device, and the red-emitting organic EL device, the organic EL device according to any of the arrangements of the first exemplary embodiment. This organic EL display device includes: a blue-emitting organic EL device as a blue pixel; a green-emitting organic EL device as a green pixel; and a red-emitting organic EL device as a red pixel, in which the blue pixel, the green pixel, and the red pixel respectively include, as the blue-emitting organic EL device, the green-emitting organic EL device, and the red-emitting organic EL device, the organic EL device according to any of the arrangements of the first exemplary embodiment, the emitting region in the blue-emitting organic EL device is a blue emitting region provided between the anode and the cathode, the emitting region in the green-emitting organic EL device is a green emitting region provided between the anode and the cathode, the emitting region in the red-emitting organic EL device is a red emitting region provided between the anode and the cathode, and the first anode side organic layer, the second anode side organic layer, and the third anode side organic layer are provided between the anode and the blue emitting region, the green emitting region, and the red emitting region in a shared manner across the blue-emitting organic EL device, the green-emitting organic EL device, and the red-emitting organic EL device. Since the blue pixel, the green pixel, and the red pixel of this organic EL display device include the organic EL device of the first exemplary embodiment, the organic EL device serving as the blue pixel, the green pixel, and the red pixel has improved light-extraction efficiency and the organic EL display device including the organic EL device has enhanced performance.

### Third Exemplary Embodiment

### Organic Electroluminescence Device

An organic electroluminescence device according to a third exemplary embodiment is described below. In the description of the organic EL device according to the third exemplary embodiment, the same components as those in the first exemplary embodiment are denoted by the same reference signs and names to simplify or omit an explanation of the components. In the third exemplary embodiment, the same materials and compounds as those described in the first exemplary embodiment are usable, unless otherwise specified.

An organic EL device according to the third exemplary embodiment includes a cathode, an anode, an emitting region provided between the cathode and the anode, and a hole transporting zone provided between the anode and the emitting region, in which the emitting region includes at least one emitting layer, the hole transporting zone includes at least a second anode side organic layer and a third anode side organic layer, the second anode side organic layer and the third anode side organic layer are arranged between the anode and the emitting region in this order from a side close to the anode, the second anode side organic layer contains at least one compound selected from the group consisting of a compound represented by the formula (C1) and a compound represented by a formula (C3) below, the third anode side organic layer contains a compound represented by the formula (C1), here, the second anode side organic layer contains at least one compound different from the compound contained in the third anode side organic layer, a difference NM₂−NM₃ between a refractive index NM₂ of a constituent material contained in the second anode side organic layer and a refractive index NM₃ of a constituent material contained in the third anode side organic layer satisfies a relationship of a numerical formula (Numerical Formula N1) below, and a distance from an interface at a side close to the anode of the third anode side organic layer to an interface at a side close to the anode of an emitting layer disposed closest to the anode in the emitting region is 20 nm or more.

$${NM}_{2} - {NM}_{3} \geq 0.05 \qquad ( Numerical Formula N1 )$$

The organic EL device according to the third exemplary embodiment has the following features.

The organic EL device according to the third exemplary embodiment may not include the first anode side organic layer. However, the hole transporting zone of the organic EL device according to the third exemplary embodiment may include the first anode side organic layer. In this case, the first anode side organic layer is disposed between the anode and the second anode side organic layer.

Also in an exemplary arrangement of the organic EL device of the third exemplary embodiment, similar to the first exemplary embodiment, the first anode side organic layer also preferably contains the first organic material and the second organic material different from each other. The content of the second organic material in the first anode side organic layer is preferably less than 50 mass %. The first anode side organic layer containing the first and second organic materials improves the hole injectability from the anode to the first anode side organic layer.

In the organic EL device according to the third exemplary embodiment, the second anode side organic layer and the third anode side organic layer each contain a predetermined compound(s). Here, the second anode side organic layer contains at least one compound different from the compound contained in the third anode side organic layer. For instance, when the second anode side organic layer contains two types of compounds (compound AA and compound AB) and the third anode side organic layer contains a single type of compound (compound AA), the compound AB is different from the compound AA contained in the third anode side organic layer. Thus, this case satisfies the condition “the second anode side organic layer contains at least one compound different from the compound contained in the third anode side organic layer”.

In the organic EL device according to the third exemplary embodiment, the difference NM₂−NM₃ between the refractive index NM₂ of the constituent material contained in the second anode side organic layer and the refractive index NM₃ of the constituent material contained in the third anode side organic layer satisfies the relationship of the numerical formula (Numerical Formula N1).

In the organic EL device of the third exemplary embodiment, the difference NM₂−NM₃ between the refractive index NM₂ of the constituent material contained in the second anode side organic layer and the refractive index NM₃ of the constituent material contained in the third anode side organic layer also preferably satisfies a relationship of a numerical formula (Numerical Formula N2) or a numerical formula (Numerical Formula N3) below.

$${NM}_{2} - {NM}_{3} \geq 0.1 \qquad ( Numerical Formula N2 )$$

$${NM}_{2} - {NM}_{3} \geq 0.075 \qquad ( Numerical Formula N3 )$$

In the organic EL device according to the third exemplary embodiment, the distance from the interface at the side close to the anode of the third anode side organic layer to the interface at the side close to the anode of the emitting layer disposed closest to the anode in the emitting region is 20 nm or more.

In an exemplary arrangement of the organic EL device of the third exemplary embodiment, the film thickness of the third anode side organic layer is nm or more or 20 nm or more.

In an exemplary arrangement of the organic EL device of the exemplary embodiment, the film thickness of the third anode side organic layer is 80 nm or less, 75 nm or less, or 60 nm or less.

In the organic EL device of the third exemplary embodiment, in terms of an improvement in light-extraction efficiency, the film thickness of the third anode side organic layer is preferably in a range from 15 nm to 75 nm, more preferably in a range from 20 nm to 60 nm.

In an exemplary arrangement of the organic EL device of the third exemplary embodiment, the total of the film thickness of the first anode side organic layer, the film thickness of the second anode side organic layer, and the film thickness of the third anode side organic layer is 150 nm or less.

In an exemplary arrangement of the organic EL device of the third exemplary embodiment, the organic EL device further includes the fourth anode side organic layer disposed between the third anode side organic layer and the emitting region.

In an exemplary arrangement of the organic EL device of the third exemplary embodiment, the total of the film thickness of the first anode side organic layer, the film thickness of the second anode side organic layer, the film thickness of the third anode side organic layer, and the film thickness of the fourth anode side organic layer is 150 nm or less.

Any other features of the organic EL device according to the third exemplary embodiment are similar to those of the organic EL device according to the first exemplary embodiment, and thus all the arrangements of the organic EL device described in the first exemplary embodiment are applicable to the organic EL device according to the third exemplary embodiment.

The compound represented by the formula (C1) in the organic EL device according to the third exemplary embodiment represents the same as the compound represented by the formula (C1) described in the first exemplary embodiment.

The compound represented by the formula (C3) in the organic EL device according to the third exemplary embodiment is as follows:

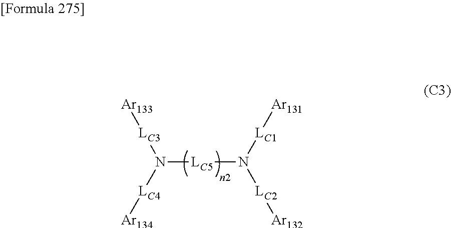

In the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

In the compound represented by the formula (C3), the substituent for the “substituted or unsubstituted” group is not a group represented by —N(R_{C6})(R_{C7}), and R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound represented by the formula (C3), a first amino group represented by a formula (C3-1) below and a second amino group represented by a formula (C3-2) below may be an identical group or different groups. The first and second amino groups, however, are preferably an identical group.

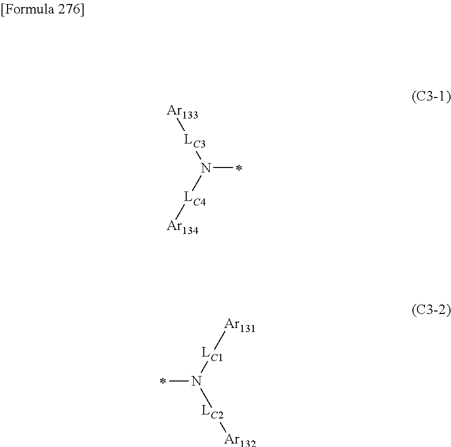

In the formulae (C3-1) and (C3-2), each * represents a bonding position to L_{C5}.

In an exemplary arrangement of the organic EL device of the third exemplary embodiment, the second anode side organic layer contains a monoamine compound or a diamine compound, and the third anode side organic layer contains the monoamine compound and does not contain the diamine compound.

In an exemplary arrangement of the organic EL device of the third exemplary embodiment, the compound contained in the second anode side organic layer (second hole transporting zone material) is the same as that of the first exemplary embodiment.

In an exemplary arrangement of the organic EL device of the third exemplary embodiment, the compound contained in the third anode side organic layer (third hole transporting zone material) is the same as that of the first exemplary embodiment.

The organic EL device according to the third exemplary embodiment also has enhanced light-extraction efficiency when the second anode side organic layer and the third anode side organic layer satisfy the relationship of the numerical formula (Numerical Formula N1). Further, the light-extraction efficiency is readily improved by making the distance from the interface at the side close to the anode of the third anode side organic layer to the interface at the side close to the anode of the emitting layer disposed closest to the anode in the emitting region, 20 nm or more.

### Fourth Exemplary Embodiment

An organic EL display device according to a fourth exemplary embodiment is explained below. In the description of the organic EL display device according to the fourth exemplary embodiment, the same components as those in the first, second, and third exemplary embodiments are denoted by the same reference signs and names to simplify or omit an explanation of the components. In the fourth exemplary embodiment, the same materials and compounds as those described in the first, second, and third exemplary embodiments are usable, unless otherwise specified.

### Organic Electroluminescence Display Device

An organic EL display device according to the fourth exemplary embodiment is different from the organic EL display device according to the second exemplary embodiment in that a blue-emitting organic EL device included in a blue pixel of the organic EL display device according to the fourth exemplary embodiment is the organic EL device according to the third exemplary embodiment, and any other features or arrangements than the above are similar to those of the organic EL display device according to the second exemplary embodiment. Thus, all the arrangements of the organic EL display device described in the second exemplary embodiment are applicable to the organic EL display device according to the fourth exemplary embodiment.

When the first anode side organic layer is not included in the blue-emitting organic EL device and the second anode side organic layer and the third anode side organic layer are included in the blue-emitting organic EL device, the second anode side organic layer and the third anode side organic layer are provided between the anode and the emitting region of the blue-emitting organic EL device, the green emitting region, and the red emitting region in a shared manner across the blue-emitting organic EL device, the green-emitting organic EL device, and the red-emitting organic EL device.

Since the blue pixel of the organic EL display device according to the fourth exemplary embodiment includes, as the blue-emitting organic EL device, the organic EL device of the third exemplary embodiment, the blue-emitting organic EL device as the blue pixel has improved luminous efficiency. The performance of the organic EL display device is thus improved.

The organic EL display device of the fourth exemplary embodiment may include, as the blue-emitting organic EL device, the green-emitting organic EL device, and the red-emitting organic EL device, the organic EL device according to any of the arrangements of the third exemplary embodiment. This organic EL display device includes: an anode and a cathode arranged opposite each other; a blue-emitting organic EL device as a blue pixel; a green-emitting organic EL device as a green pixel; and a red-emitting organic EL device as a red pixel, in which the blue pixel, the green pixel, and the red pixel respectively include, as the blue-emitting organic EL device, the green-emitting organic EL device, and the red-emitting organic EL device, the organic EL device according to any of the arrangements of the third exemplary embodiment, the emitting region in the blue-emitting organic EL device is a blue emitting region provided between the anode and the cathode, the emitting region in the green-emitting organic EL device is a green emitting region provided between the anode and the cathode, the emitting region in the red-emitting organic EL device is a red emitting region provided between the anode and the cathode, and the first anode side organic layer, the second anode side organic layer, and the third anode side organic layer are provided between the anode and the blue emitting region, the green emitting region, and the red emitting region in a shared manner across the blue-emitting organic EL device, the green-emitting organic EL device, and the red-emitting organic EL device. Since the blue pixel, the green pixel, and the red pixel of this organic EL display device include the organic EL device according to the third exemplary embodiment, the organic EL device serving as the blue pixel, the green pixel, and the red pixel has improved light-extraction efficiency and the organic EL display device including the organic EL device has enhanced performance.

### Fifth Exemplary Embodiment

### Tandem Organic Electroluminescence Device

The organic EL device according to the fifth exemplary embodiment is a so-called tandem organic EL device, in which a plurality of emitting regions are layered via a charge generating layer (occasionally also referred to as an intermediate layer and the like). The tandem organic EL device is exemplified by an organic EL device below.

The tandem organic EL device according to the fifth exemplary embodiment includes two or more emitting units and at least one charge generating layer disposed between the two or more emitting units, in which at least one of the two or more emitting units is a first emitting unit including a first hole transporting zone and a first emitting region. For instance, in the fifth exemplary embodiment, the first hole transporting zone included in the first emitting unit is the hole transporting zone explained in the first exemplary embodiment or the third exemplary embodiment, and the first emitting region is the emitting region explained in the first exemplary embodiment or the third exemplary embodiment.

Each of the emitting units included in the tandem organic EL device preferably includes two or more anode side organic layers closer to the anode with respect to the emitting region. When each emitting unit includes two or more anode side organic layers, the constituent materials of the respective anode side organic layers preferably have mutually different refractive indices. The anode side organic layer containing the constituent material with a higher refractive index is more preferably disposed closer to the anode than the anode side organic layer containing the constituent material with a lower refractive index. When the anode side organic layers of each emitting unit satisfy the refractive index relationship as described above, the difference in refractive indices between the constituent materials of the anode side organic layers is preferably 0.05 or more, 0.075 or more, or 0.10 or more. In each emitting unit, the organic layer containing the constituent material with a high refractive index is disposed close to the anode and the organic layer containing the constituent material with a low refractive index is disposed close to the emitting region. The tandem organic EL device thus has improved light-extraction efficiency and enhanced performance.

The charge generating layer in the tandem organic EL device means a layer in which holes and electrons are generated upon voltage application. When a plurality of charge generating layers are provided between the emitting units in the tandem organic EL device, the plurality of charge generating layers may be referred collectively to as a charge generating unit.

Herein, a zone including a plurality of organic layers disposed between the charge generating layer or the charge generating unit and the emitting regions of each emitting unit may be also referred to as the hole transporting zone.

In an exemplary arrangement of the fifth exemplary embodiment, the tandem organic EL device includes: a first emitting unit and a second emitting unit as the emitting unit; and a first charge generating layer disposed between the first emitting unit and the second emitting unit. The second emitting unit includes a second hole transporting zone and a second emitting region. The first hole transporting zone, the first emitting region, the first charge generating layer, the second hole transporting zone, and the second emitting region are arranged in this order from the side close to the anode.

In an exemplary arrangement of the fifth exemplary embodiment, the tandem organic EL device further includes: a third emitting unit and a second charge generating layer. The third emitting unit is disposed between the second emitting unit and the cathode, and the second charge generating layer is disposed between the third emitting unit and the second emitting unit. The third emitting unit includes a third hole transporting zone and a third emitting region. The first hole transporting zone, the first emitting region, the first charge generating layer, the second hole transporting zone, the second emitting region, the second charge generating layer, the third hole transporting zone, and the third emitting region are arranged in this order from the side close to the anode.

In the tandem organic EL device of the fifth exemplary embodiment, the second emitting region and the third emitting region each independently include at least one emitting layer. The emitting layers included in the second emitting region and the third emitting region may each independently be the same as or different from an emitting layer included in the first emitting region.

In the tandem organic EL device of the fifth exemplary embodiment, the second hole transporting zone and the third hole transporting zone may each independently include at least one organic layer, and the organic layers included in the second hole transporting zone and the third hole transporting zone may each independently be the same as or different from any of the organic layers included in the first hole transporting zone. The second hole transporting zone and the third hole transporting zone may each independently include two or more anode side organic layers. The two or more anode side organic layers included in the second hole transporting zone and the third hole transporting zone may each independently be the second anode side organic layer or the third anode side organic layer included in the first emitting unit, or an anode side organic layer different from the second anode side organic layer and the third anode side organic layer included in the first emitting unit.

In the tandem organic EL device of the fifth exemplary embodiment, three or more anode side organic layers included in the second hole transporting zone and the third hole transporting zone may each independently be the first anode side organic layer, the second anode side organic layer, or the third anode side organic layer included in the first emitting unit, or an anode side organic layer different from the first anode side organic layer, the second anode side organic layer, and the third anode side organic layer included in the first emitting unit.

In the second hole transporting zone and the third hole transporting zone, the third anode side organic layer is disposed closer to the emitting region than the second anode side organic layer. The constituent material of the second anode side organic layer in each of the second hole transporting zone and the third hole transporting zone is the same as or different from the constituent material of the second anode side organic layer in the first emitting unit. The constituent material of the third anode side organic layer in each of the second hole transporting zone and the third hole transporting zone is the same as or different from the constituent material of the third anode side organic layer in the first emitting unit. In the second hole transporting zone and the third hole transporting zone, the refractive index of the constituent material of the second anode side organic layer is preferably larger than the refractive index of the constituent material of the third anode side organic layer. In the second hole transporting zone and the third hole transporting zone, a difference NM₂−NM₃ between a refractive index NM₂ of the constituent material contained in the second anode side organic layer and a refractive index NM₃ of the constituent material contained in the third anode side organic layer preferably satisfies the relationship of the above numerical formula (Numerical Formula N1, Numerical Formula N2, or Numerical Formula N3).

In the second hole transporting zone and the third hole transporting zone, the first anode side organic layer is disposed between the second anode side organic layer and the charge generating layer. The constituent material of the first anode side organic layer in each of the second hole transporting zone and the third hole transporting zone is the same as or different from the constituent material of the first anode side organic layer in the first emitting unit.

In the tandem organic EL device according to the exemplary embodiment, the first charge generating layer and the second charge generating layer each mean a layer in which holes and electrons are generated upon voltage application. For instance, when the first charge generating layer includes a plurality of layers, the first charge generating layer preferably includes an N layer disposed close to the anode and through which electrons are injected into the first emitting unit, and a P layer disposed close to the cathode and through which holes are injected into the second emitting unit. For instance, when the second charge generating layer includes a plurality of layers, the second charge generating layer preferably includes an N layer disposed close to the anode and through which electrons are injected into the second emitting unit, and a P layer disposed close to the cathode and through which holes are injected into the third emitting unit. Examples of a material usable for the first charge generating layer and the second charge generating layer include a known material(s) usable for the charge generating layer in the tandem organic EL device.

In the tandem organic EL device according to the fifth exemplary arrangement, an electron transporting zone is preferably provided between the emitting region of each emitting unit and the charge generating layer, the charge generating unit, or the cathode. The electron transporting zone preferably includes, for instance, at least any of the electron transporting layer, the electron injecting layer, or the hole blocking layer.

Examples of the device arrangement of the tandem organic EL device including a plurality of emitting units include (TND1) to (TND4) below.
(TND1) anode/first emitting unit/first charge generating layer/second emitting unit/cathode
(TND2) anode/first emitting unit/first charge generating unit/second emitting unit/cathode
(TND3) anode/first emitting unit/first charge generating layer/second emitting unit/second charge generating layer/third emitting unit/cathode
(TND4) anode/first emitting unit/first charge generating unit/second emitting unit/second charge generating unit/third emitting unit/cathode

In the tandem organic EL device according to the fifth exemplary arrangement, the number of emitting units and charge generating layers (or charge generating units) is not limited to the above examples (TND1) to (TND4).

The tandem organic EL device according to the fifth exemplary arrangement is used, for instance, for a light-emitting unit.

### Sixth Exemplary Embodiment

### Electronic Device

An electronic device according to a sixth exemplary embodiment is installed with the organic EL device according to any of the above exemplary embodiments or the organic EL display device according to any of the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

In an exemplary arrangement of the electronic device according to the sixth exemplary embodiment, the light-emitting unit is installed with the tandem organic EL device according to the above exemplary embodiment. In an exemplary arrangement of the electronic device according to the sixth exemplary embodiment, the light-emitting unit preferably includes the tandem organic EL device according to the above exemplary embodiment and a color conversion layer. The light-emitting unit preferably includes a color filter. The color conversion layer is preferably disposed between the tandem organic EL device and the color filter. The color conversion layer preferably contains a substance that emits light by absorbing light. The substance that emits light by absorbing light is preferably a quantum dot. In the light-emitting unit, the color conversion layer is preferably disposed to be irradiated with light emission from the tandem organic EL device.

In an exemplary arrangement of the electronic device according to the sixth exemplary embodiment, the display device is installed with the light-emitting unit according to the sixth exemplary embodiment. The light-emitting unit also can be used for a display device, for instance, as a backlight of the display device.

### Modification of Embodiment(s)

The scope of the invention is not limited to the above-described exemplary embodiments but includes any modification and improvement as long as such modification and improvement are compatible with the invention.

For instance, the number of emitting layers is not limited to one or two, and more than two emitting layers may be layered. For instance, the rest of the emitting layers may be a fluorescent emitting layer or a phosphorescent emitting layer with use of emission caused by electron transfer from the triplet excited state directly to the ground state.

Further, for instance, a blocking layer is optionally provided adjacent to a side of the emitting layer close to the cathode. The blocking layer provided in direct contact with the side of the emitting layer close to the cathode preferably blocks at least one of holes or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer may be disposed between the emitting layer and the electron transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) closer to the electrode(s) (e.g., the electron transporting layer and the like) beyond the blocking layer. The emitting layer is preferably in direct contact with the blocking layer.

Specific structure, shape and the like of the components in the invention may be designed in any manner as long as an object of the invention can be achieved.

### EXAMPLES

The invention will be described in further detail with reference to Examples. The scope of the invention is by no means limited to Examples.

### Compounds

Structures of compounds used for producing organic EL devices in Examples and Comparatives are shown below.

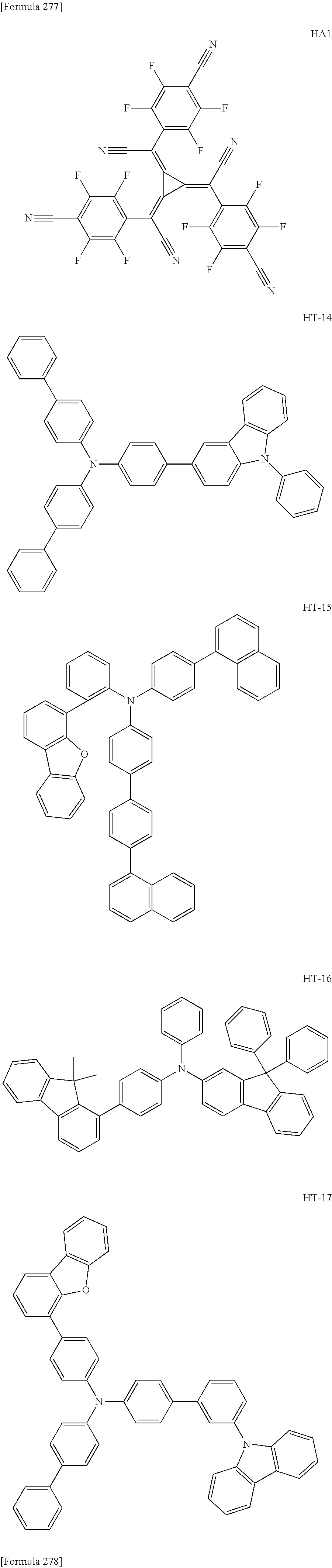 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(N(c2ccc(-c3ccc(-c4cccc5ccccc45)cc3)cc2)c2ccc(-c3cccc4ccccc34)cc2)c(-c2cccc3c2oc2ccccc23)c1 ; CC1(C)c2ccccc2-c2cccc(-c3ccc(N(c4ccccc4)c4ccc5c(c4)C(c4ccccc4)(c4ccccc4)c4ccccc4-5)cc3)c21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

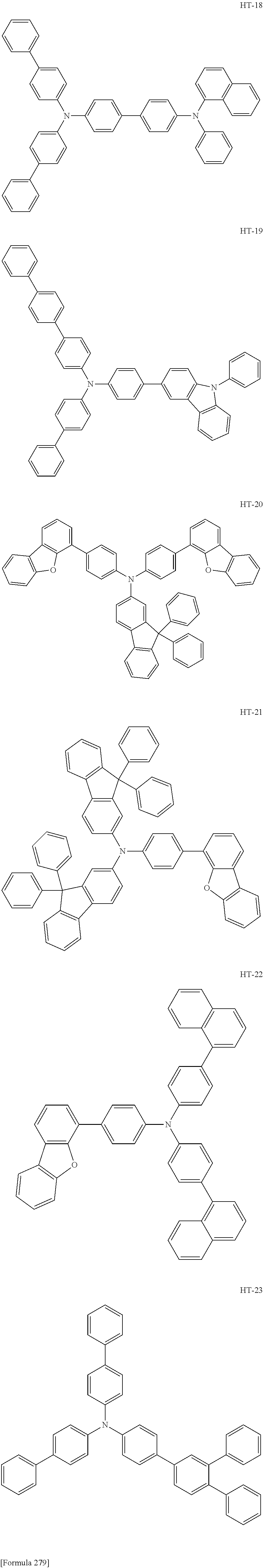

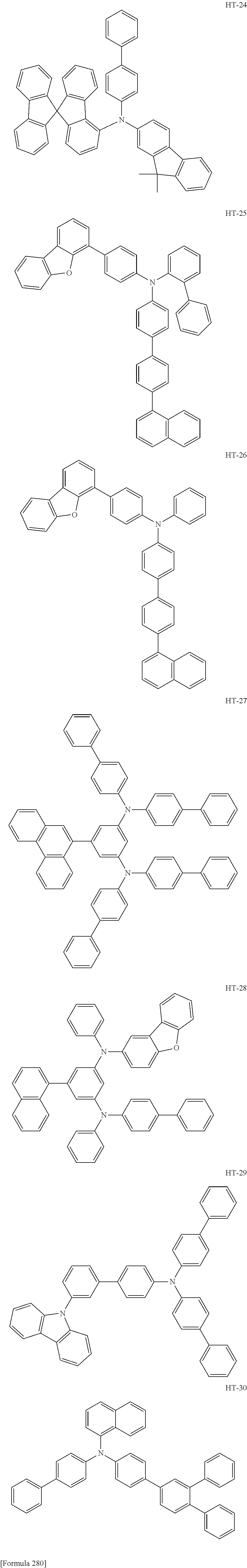

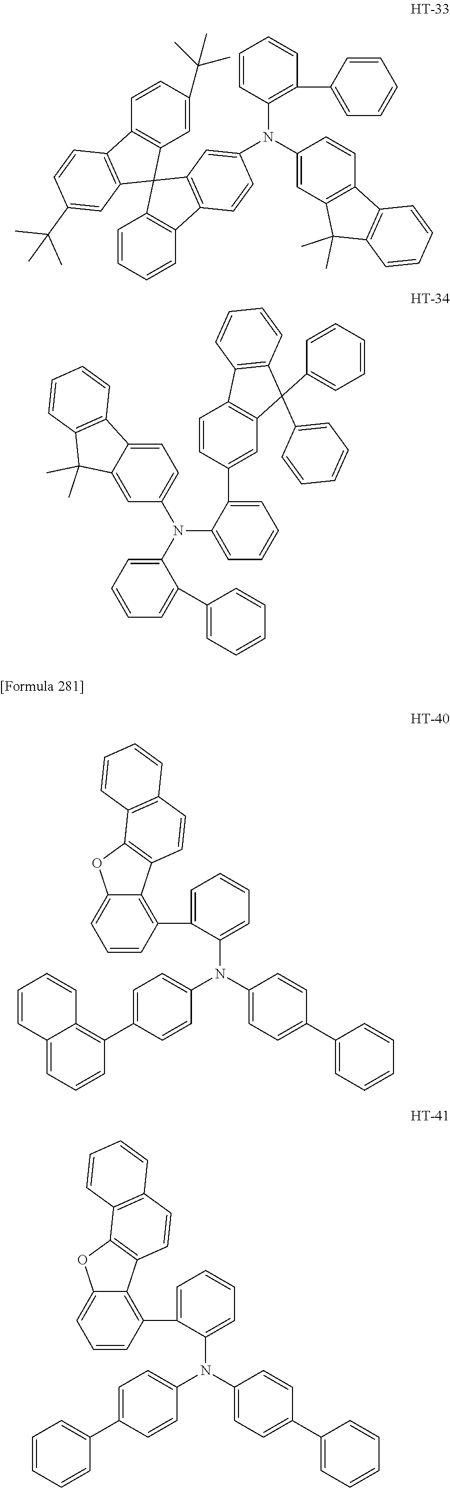 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccccc3-c3ccccc3)c3ccccc3-c3ccc4c(c3)C(c3ccccc3)(c3ccccc3)c3ccccc3-4)cc21 ; c1ccc(-c2ccc(N(c3ccc(-c4cccc5ccccc45)cc3)c3ccccc3-c3cccc4oc5c6ccccc6ccc5c34)cc2)cc1 ; c1ccc(-c2ccc(N(c3ccc(-c4ccccc4)cc3)c3ccccc3-c3cccc4oc5c6ccccc6ccc5c34)cc2)cc1]

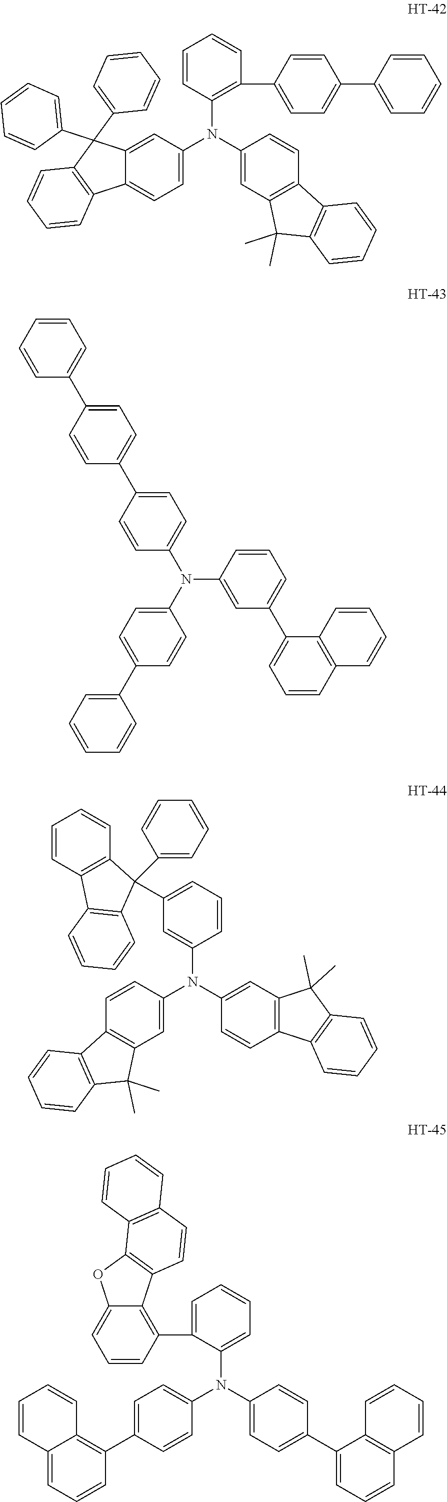

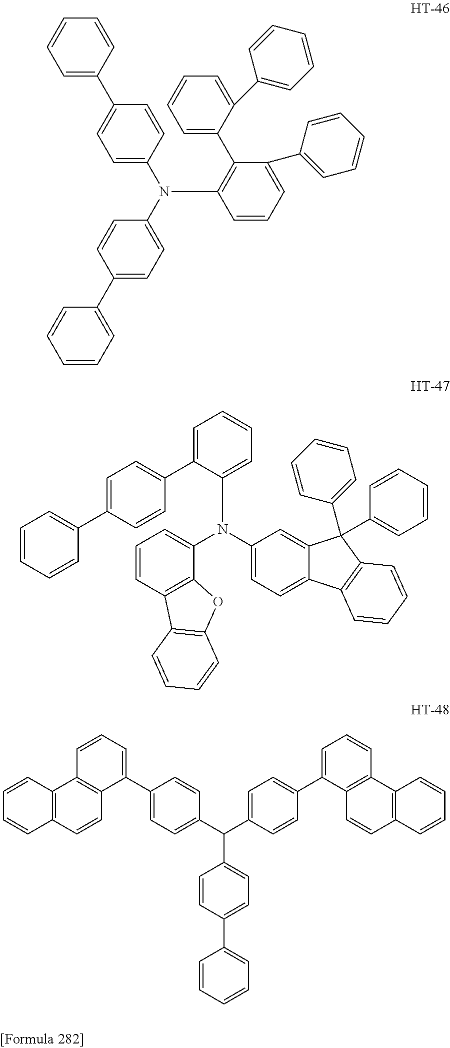

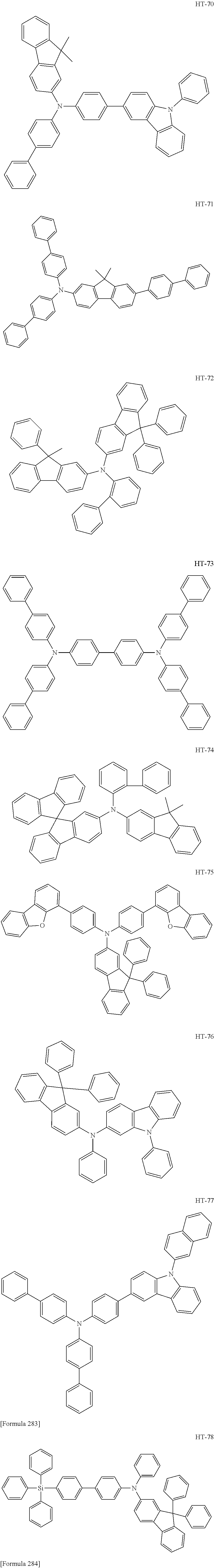

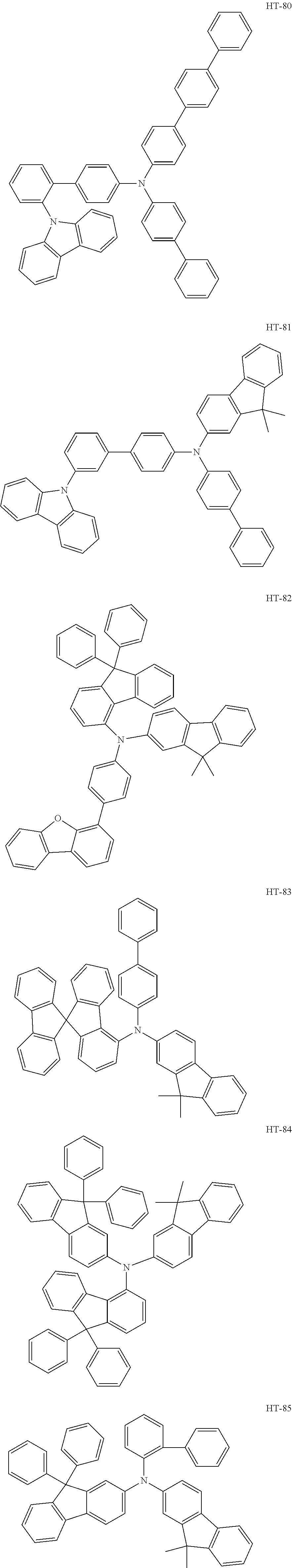

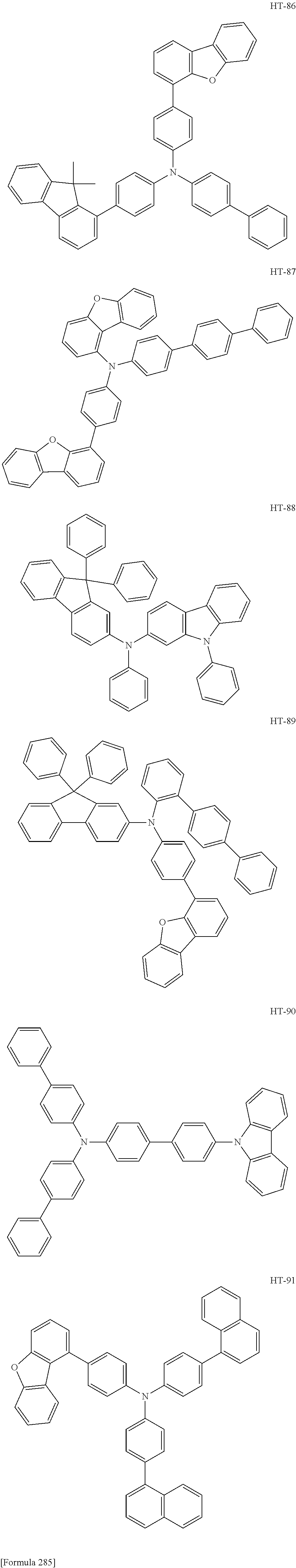

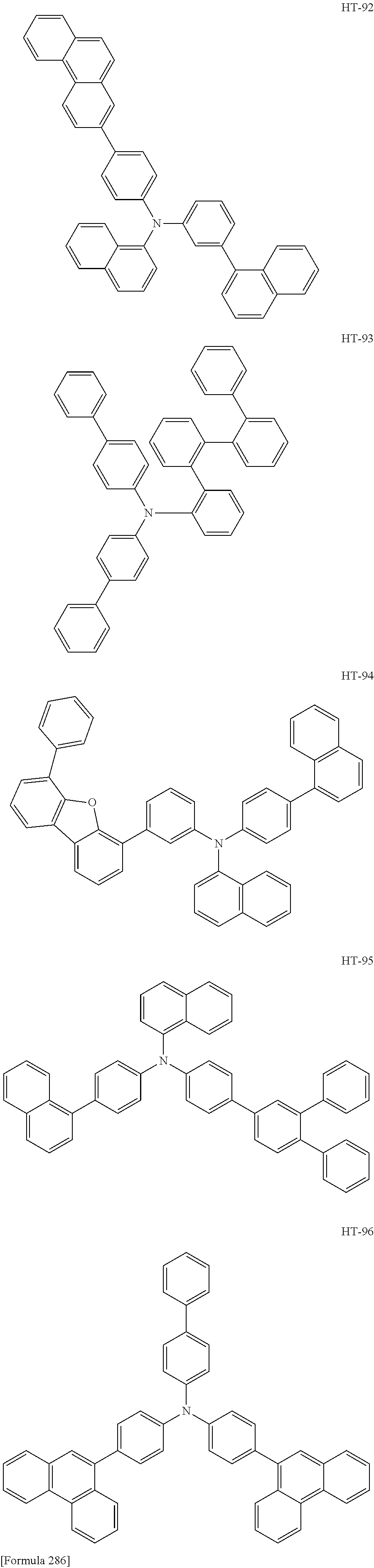

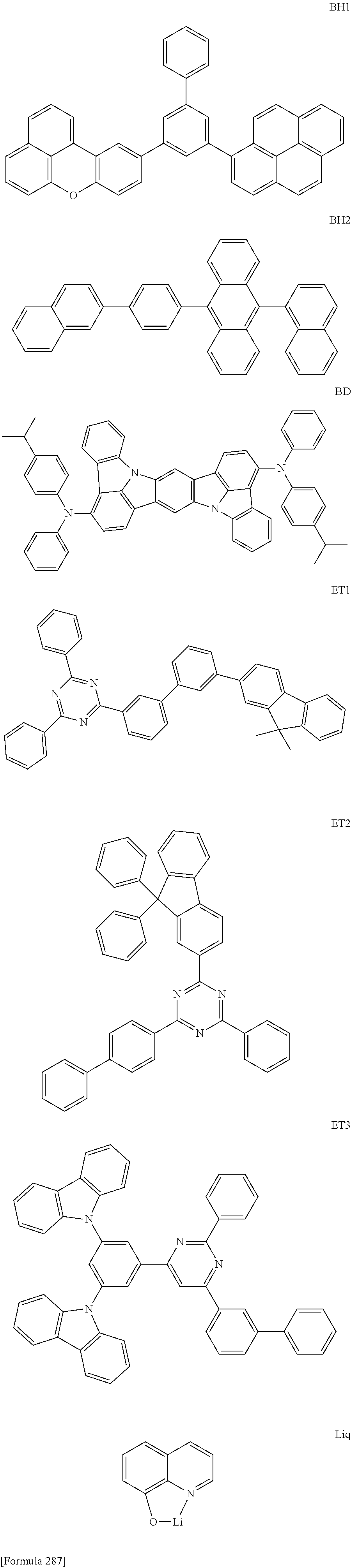

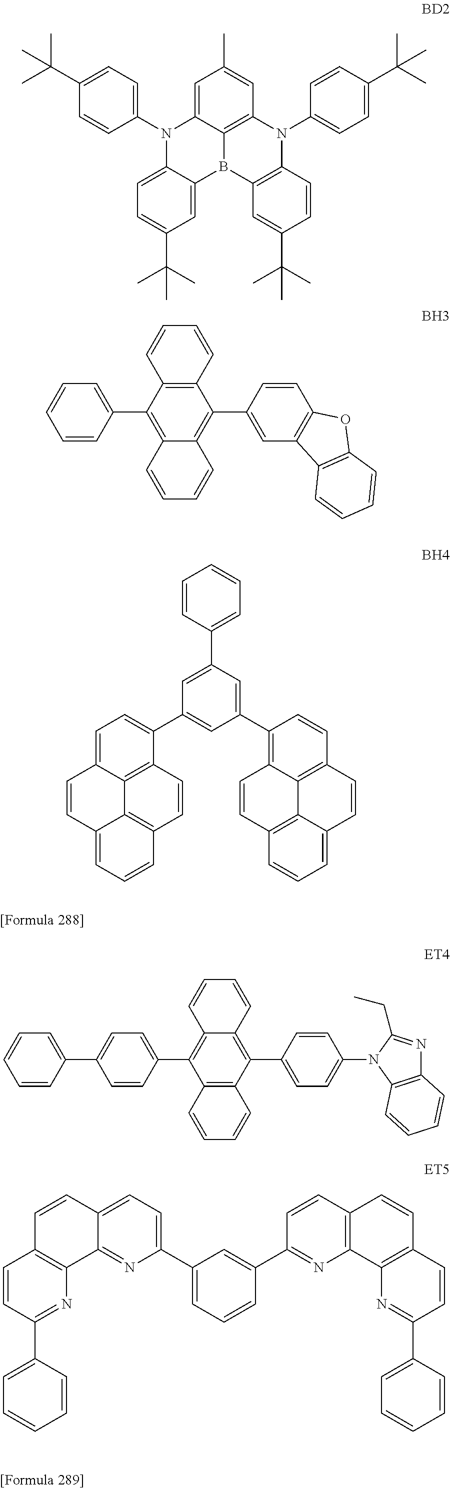

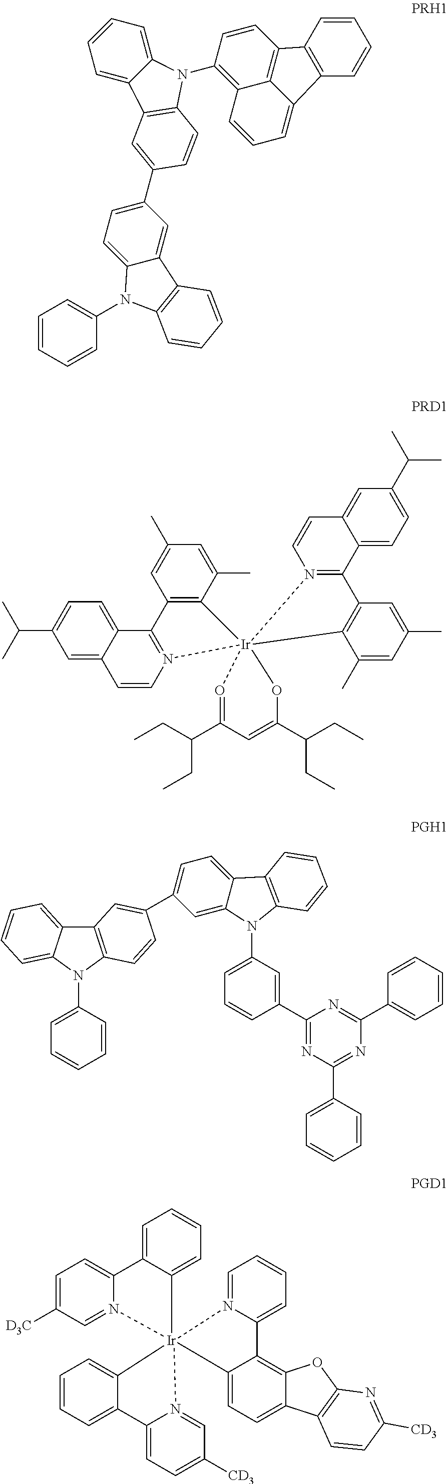

### Production of Organic EL Device

The organic EL devices were produced and evaluated as follows.

### Example 1-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-14 and a compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-14 and the compound HA1 in the first anode side organic layer were 97 mass % and 3 mass %, respectively.

The compound HT-14 was vapor-deposited on the first anode side organic layer to form a 40-nm-thick second anode side organic layer (occasionally also referred to as a first hole transporting layer).

A compound HT-15 was vapor-deposited on the second anode side organic layer to form a 45-nm-thick third anode side organic layer (occasionally also referred to as an electron blocking layer).

A compound BH1 (first host material) and a compound BD (first emitting compound) were co-deposited on the third anode side organic layer so that a ratio of the compound BD accounted for 1 mass %, thereby forming a 5-nm-thick first emitting layer.

A compound BH2 (second host material) and the compound BD (second emitting compound) were co-deposited on the first emitting layer so that a ratio of the compound BD accounted for 1 mass %, thereby forming a 15-nm-thick second emitting layer.

A compound ET1 was vapor-deposited on the second emitting layer to form a 5-nm-thick first electron transporting layer (occasionally also referred to as a hole blocking layer (HBL)).

A compound ET2 and a compound Liq were co-deposited on the first electron transporting layer to form a 25-nm-thick second electron transporting layer (ET). The ratios of the compound ET2 and the compound Liq in the second electron transporting layer were 50 mass % and 50 mass %, respectively.

Ytterbium (Yb) was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 1-1 is roughly shown as follows.
ITO(130)/HT-14:HA1(10.97%:3%)/HT-14(40)/HT-15(45)/BH1:BD(5.99%:1%)/BH2:BD(15.99%:1%)/ET1(5)/ET2:Liq(25.50%:50%)/Yb(1)/Al(80)

Numerals in parentheses represent a film thickness (unit: nm).

The numerals (97%:3%) represented by percentage in the same parentheses indicate a ratio (mass %) between the compound HT-14 and the compound HA1 in the first anode side organic layer, the numerals (99%:1%) represented by percentage in the same parentheses indicate a ratio (mass %) between the host material (compound BH1 or BH2) and the emitting compound (compound BD) in the first emitting layer or the second emitting layer, and the numerals (50%:50%) represented by percentage in the same parentheses indicate a ratio (mass %) between the compound ET2 and the compound Liq in the electron injecting layer.

### Example 1-2

The organic EL device of Example 1-2 was produced in the same manner as in Example 1-1 except that the compound HT-15 used for forming the third anode side organic layer in Example 1-1 was changed to a compound HT-16, as shown in Table 1.

### Example 1-3

The organic EL device of Example 1-3 was produced in the same manner as in Example 1-1 except that the third anode side organic layer was formed to have a film thickness of 35 nm in Example 1-3, a compound HT-17 was vapor-deposited on the third anode side organic layer to form a 10-nm-thick fourth anode side organic layer (occasionally also referred to as an electron blocking layer) in Example 1-3, and the first emitting layer was formed on the fourth anode side organic layer in Example 1-3, as shown in Table 1.

### Example 1-4

The organic EL device of Example 1-4 was produced in the same manner as in Example 1-3 except that the compound HT-15 used for forming the third anode side organic layer in Example 1-3 was changed to the compound HT-16, as shown in Table 1.

### Example 1-5

The organic EL device of Example 1-5 was produced in the same manner as in Example 1-1 except that the second anode side organic layer was formed to have a film thickness of 20 nm in Example 1-5 and the third anode side organic layer was formed to have a film thickness of 65 nm in Example 1-5, as shown in Table 1.

### Example 1-6

The organic EL device of Example 1-6 was produced in the same manner as in Example 1-1 except that the second anode side organic layer was formed to have a film thickness of 60 nm in Example 1-6 and the third anode side organic layer was formed to have a film thickness of 25 nm in Example 1-6, as shown in Table 1.

### Comparative 1-1

The organic EL device of Comparative 1-1 was produced in the same manner as in Example 1-1 except that the film thickness of the second and third anode side organic layers was changed from those in Example 1-1 to those in Comparative 1-1, as shown in Table 1.

### Comparative 1-2

The organic EL device of Comparative 1-2 was produced in the same manner as in Example 1-2 except that the film thickness of the second and third anode side organic layers was changed from those in Example 1-2 to those in Comparative 1-2, as shown in Table 1.

### Evaluation of Organic EL Devices

The produced organic EL devices were evaluated as follows. Tables 1 to 21 show evaluation results. Further, Tables 1 to 21 show, for each Example and Comparative, a film thickness ratio TL₃/TL₂ between a film thickness TL₂ of the second anode side organic layer and a film thickness TL₃ of the third anode side organic layer.

### External Quantum Efficiency EQE

Voltage was applied to the organic EL device such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation.

### Lifetime LT95

Voltage was applied to the produced organic EL device such that a current density was 50 mA/cm², where a time (LT95 (unit: hr)) elapsed before a luminance intensity was reduced to 95% of the initial luminance intensity was measured as a lifetime. The luminance intensity was measured by a spectroradiometer CS-2000 (produced by Konica Minolta, Inc.).

### Drive Voltage

The voltage (unit: V) when electric current was applied to between the anode and the cathode of the produced organic EL device so that the current density was 10 mA/cm² was measured.

TABLE 1

| | Anode Side Organic Layer | | | | | | | | | | | |
|---|---|---|---|---|---|---|---|---|---|---|---|---|
| | First Anode | | Second Anode | | Third Anode | | | Fourth Anode | | | | |
| | Side Organic Layer | | Side Organic Layer | | Side Organic Layer | | | Side Organic Layer | | Film | Device | |
| | | Film | | Film | Compound | | Film | | Film | Thickness | Performance | |
| | Compound | Thickness | Compound | Thickness | | S₁ | Thickness | Compound | Thickness | Ratio | EQE | LT95 |
| | Name | [nm] | Name | [nm] | Name | [eV] | [nm] | Name | [nm] | TL₃/TL₂ | [%] | [hr] |
| Example 1-1 | HT-14 | 10 | HT-14 | 40 | HT-15 | 3.18 | 45 | — | — | 1.13 | 12.09 | 174 |
| | and HA1 | | | | | | | | | | | |
| Example 1-3 | HT-14 | 10 | HT-14 | 40 | HT-15 | 3.18 | 35 | HT-17 | 10 | 0.88 | 12.17 | 241 |
| | and HA1 | | | | | | | | | | | |
| Example 1-5 | HT-14 | 10 | HT-14 | 20 | HT-15 | 3.18 | 65 | — | — | 3.25 | 11.97 | 147 |
| | and HA1 | | | | | | | | | | | |
| Example 1-6 | HT-14 | 10 | HT-14 | 60 | HT-15 | 3.18 | 25 | — | — | 0.42 | 11.82 | 172 |
| | and HA1 | | | | | | | | | | | |
| Comparative | HT-14 | 10 | HT-14 | 75 | HT-15 | 3.18 | 10 | — | — | 0.13 | 11.69 | 140 |
| 1-1 | and HA1 | | | | | | | | | | | |
| Example 1-2 | HT-14 | 10 | HT-14 | 40 | HT-16 | 3.26 | 45 | — | — | 1.13 | 12.48 | 153 |
| | and HA1 | | | | | | | | | | | |
| Example 1-4 | HT-14 | 10 | HT-14 | 40 | HT-16 | 3.26 | 35 | HT-17 | 10 | 0.88 | 12.46 | 193 |
| | and HA1 | | | | | | | | | | | |
| Comparative | HT-14 | 10 | HT-14 | 75 | HT-16 | 3.26 | 10 | — | — | 0.13 | 11.42 | 123 |
| 1-2 | and HA1 | | | | | | | | | | | |

### Examples 1-7 and 1-9

The organic EL devices of Examples 1-7 and 1-9 were respectively produced in the same manner as in Example 1-1 except that the compound HT-15 used for forming the third anode side organic layer in Example 1-1 was changed to compounds shown in Table 2.

### Examples 1-8 and 1-10

The organic EL devices of Examples 1-8 and 1-10 were respectively produced in the same manner as in Example 1-3 except that the compound HT-15 used for forming the third anode side organic layer in Example 1-3 was changed to compounds shown in Table 2.

### Comparatives 1-4 and 1-5

The organic EL devices of Comparatives 1-4 and 1-5 were respectively produced in the same manner as in Comparative 1-1 except that the compound HT-15 used for forming the third anode side organic layer in Comparative 1-1 was changed to compounds shown in Table 2.

TABLE 2

| | Anode Side Organic Layer | | | | | | | | | | |
|---|---|---|---|---|---|---|---|---|---|---|---|
| | First Anode | | Second Anode | | Third Anode | | Fourth Anode | | | | |
| | Side Organic Layer | | Side Organic Layer | | Side Organic Layer | | Side Organic Layer | | Film | Device | |
| | | Film | | Film | | Film | | Film | Thickness | Performance | |
| | Compound | Thickness | Compound | Thickness | Compound | Thickness | Compound | Thickness | Ratio | EQE | LT95 |
| | Name | [nm] | Name | [nm] | Name | [nm] | Name | [nm] | TL₃/TL₂ | [%] | [hr] |
| Comparative | HT-14 | 10 | HT-14 | 75 | HT-22 | 10 | — | — | 0.13 | 11.6 | 180 |
| 1-4 | and HA1 | | | | | | | | | | |
| Example 1-7 | HT-14 | 10 | HT-14 | 40 | HT-22 | 45 | — | — | 1.13 | 11.9 | 190 |
| | and HA1 | | | | | | | | | | |
| Example 1-8 | HT-14 | 10 | HT-14 | 40 | HT-22 | 35 | HT-17 | 10 | 0.88 | 11.8 | 240 |
| | and HA1 | | | | | | | | | | |
| Comparative | HT-14 | 10 | HT-14 | 75 | HT-23 | 10 | — | — | 0.13 | 11.6 | 220 |
| 1-5 | and HA1 | | | | | | | | | | |
| Example 1-9 | HT-14 | 10 | HT-14 | 40 | HT-23 | 45 | — | — | 1.13 | 12.1 | 230 |
| | and HA1 | | | | | | | | | | |
| Example 1-10 | HT-14 | 10 | HT-14 | 40 | HT-23 | 35 | HT-17 | 10 | 0.88 | 12.1 | 250 |
| | and HA1 | | | | | | | | | | |

### Example 1-11

The organic EL device of Example 1-11 was produced in the same manner as in Example 1-1 except that the compound HT-14 used for forming the first and second anode side organic layers in Example 1-1 was changed to compounds shown in Table 3 and that the compound ET1 used for forming the first electron transporting layer in Example 1-1 was changed to a compound ET3.

### Comparative 1-6

The organic EL device of Comparative 1-6 was produced in the same manner as in Example 1-11 except that the film thickness of the second and third anode side organic layers was changed from those in Example 1-11 to those in Comparative 1-6, as shown in Table 3.

TABLE 3

| | Anode Side Organic Layer | | | | | | | | | | |
|---|---|---|---|---|---|---|---|---|---|---|---|
| | First Anode | | Second Anode | | Third Anode | | Fourth Anode | | | | |
| | Side Organic Layer | | Side Organic Layer | | Side Organic Layer | | Side Organic Layer | | Film | Device | |
| | | Film | | Film | | Film | | Film | Thickness | Performance | |
| | Compound | Thickness | Compound | Thickness | Compound | Thickness | Compound | Thickness | Ratio | EQE | LT95 |
| | Name | [nm] | Name | [nm] | Name | [nm] | Name | [nm] | TL₃/TL₂ | [%] | [hr] |
| Comparative | HT-18 | 10 | HT-18 | 75 | HT-15 | 10 | — | — | 0.13 | 11.5 | 200 |
| 1-6 | and HA1 | | | | | | | | | | |
| Example 1-11 | HT-18 | 10 | HT-18 | 40 | HT-15 | 45 | — | — | 1.13 | 11.8 | 230 |
| | and HA1 | | | | | | | | | | |

### Examples 1-12, 1-13, and 1-14

The organic EL devices of Examples 1-12, 1-13, and 1-14 were respectively produced in the same manner as in Example 1-1 except that the compound HT-14 used for forming the first and second anode side organic layers in Example 1-1 was changed to compounds shown in Table 4.

### Comparatives 1-7, 1-8, and 1-9

The organic EL devices of Comparatives 1-7, 1-8, and 1-9 were respectively produced in the same manner as in Comparative 1-1 except that the compound HT-14 used for forming the first and second anode side organic layers in Comparative 1-1 was changed to compounds shown in Table 4.

TABLE 4

| | Anode Side Organic Layer | | | | | | | | | | |
|---|---|---|---|---|---|---|---|---|---|---|---|
| | First Anode | | Second Anode | | Third Anode | | Fourth Anode | | | | |
| | Side Organic Layer | | Side Organic Layer | | Side Organic Layer | | Side Organic Layer | | Film | Device | |
| | | Film | | Film | | Film | | Film | Thickness | Performance | |
| | Compound | Thickness | Compound | Thickness | Compound | Thickness | Compound | Thickness | Ratio | EQE | LT95 |
| | Name | [nm] | Name | [nm] | Name | [nm] | Name | [nm] | TL₃/TL₂ | [%] | [hr] |
| Comparative | HT-19 | 10 | HT-19 | 75 | HT-15 | 10 | — | — | 0.13 | 11.7 | 210 |
| 1-7 | and HA1 | | | | | | | | | | |
| Example 1-12 | HT-19 | 10 | HT-19 | 40 | HT-15 | 45 | — | — | 1.13 | 12.5 | 240 |
| | and HA1 | | | | | | | | | | |
| Comparative | HT-20 | 10 | HT-20 | 75 | HT-15 | 10 | — | — | 0.13 | 11.4 | 220 |
| 1-8 | and HA1 | | | | | | | | | | |
| Example 1-13 | HT-20 | 10 | HT-20 | 40 | HT-15 | 45 | — | — | 1.13 | 12.3 | 250 |
| | and HA1 | | | | | | | | | | |
| Comparative | HT-21 | 10 | HT-21 | 75 | HT-15 | 10 | — | — | 0.13 | 11.3 | 230 |
| 1-9 | and HA1 | | | | | | | | | | |
| Example 1-14 | HT-21 | 10 | HT-21 | 40 | HT-15 | 45 | — | — | 1.13 | 11.8 | 254 |
| | and HA1 | | | | | | | | | | |

### Examples 1-15, 1-16, and 1-17

The organic EL devices of Examples 1-15, 1-16, and 1-17 were respectively produced in the same manner as in Example 1-1 except that the compound HT-15 used for forming the third anode side organic layer in Example 1-1 was changed to compounds shown in Table 5.

### Examples 1-18 and 1-19

The organic EL devices of Examples 1-18 and 1-19 were respectively produced in the same manner as in Example 1-3 except that the compound HT-15 used for forming the third anode side organic layer in Example 1-3 and the compound HT-17 used for forming the fourth anode side organic layer in Example 1-3 were changed to compounds shown in Table 5.

### Examples 1-20 and 1-21

The organic EL devices of Examples 1-20 and 1-21 were respectively produced in the same manner as in Example 1-1 except that the compound HT-14 used for forming the first and second anode side organic layers in Example 1-1 and the compound HT-15 used for forming the third anode side organic layer in Example 1-1 were changed to compounds shown in Table 5.

### Example 1-22

The organic EL device of Example 1-22 was produced in the same manner as in Example 1-3 except that the compound HT-14 used for forming the first and second anode side organic layers in Example 1-3, the compound HT-15 used for forming the third anode side organic layer in Example 1-3, and the compound HT-17 used for forming the fourth anode side organic layer in Example 1-3 were changed to compounds shown in Table 5.

### Comparatives 1-10 to 1-14

The organic EL devices of Comparatives 1-10 to 1-14 were respectively produced in the same manner as in Comparative 1-1 except that the compound HT-used for forming the third anode side organic layer in Comparative 1-1 was changed to compounds shown in Table 5.

### Comparatives 1-15 and 1-16

The organic EL devices of Comparatives 1-15 and 1-16 were respectively produced in the same manner as in Comparative 1-1 except that the compound HT-14 used for forming the first and second anode side organic layers in Comparative 1-1 and the compound HT-15 used for forming the third anode side organic layer in Comparative 1-1 were changed to compounds shown in Table 5.

TABLE 5

| | Anode Side Organic Layer | | | | | | | | | | |
|---|---|---|---|---|---|---|---|---|---|---|---|
| | First Anode | | Second Anode | | Third Anode | | Fourth Anode | | | | |
| | Side Organic Layer | | Side Organic Layer | | Side Organic Layer | | Side Organic Layer | | Film | Device | |
| | | Film | | Film | | Film | | Film | Thickness | Performance | |
| | Compound | Thickness | Compound | Thickness | Compound | Thickness | Compound | Thickness | Ratio | EQE | LT95 |
| | Name | [nm] | Name | [nm] | Name | [nm] | Name | [nm] | TL₃/TL₂ | [%] | [hr] |
| Comparative | HT-14 | 10 | HT-14 | 75 | HT-24 | 10 | — | — | 0.13 | 11.4 | 160 |
| 1-10 | and HA1 | | | | | | | | | | |
| Example 1-15 | HT-14 | 10 | HT-14 | 40 | HT-24 | 45 | — | — | 1.13 | 12.2 | 214 |
| | and HA1 | | | | | | | | | | |
| Comparative | HT-14 | 10 | HT-14 | 75 | HT-25 | 10 | — | — | 0.13 | 11.4 | 220 |
| 1-11 | and HA1 | | | | | | | | | | |
| Example 1-16 | HT-14 | 10 | HT-14 | 40 | HT-25 | 45 | — | — | 1.13 | 12.0 | 251 |
| | and HA1 | | | | | | | | | | |
| Comparative | HT-14 | 10 | HT-14 | 75 | HT-26 | 10 | — | — | 0.13 | 11.4 | 220 |
| 1-12 | and HA1 | | | | | | | | | | |
| Example 1-17 | HT-14 | 10 | HT-14 | 40 | HT-26 | 45 | — | — | 1.13 | 11.9 | 259 |
| | and HA1 | | | | | | | | | | |
| Comparative | HT-14 | 10 | HT-14 | 75 | HT-27 | 10 | — | — | 0.13 | 11.7 | 60 |
| 1-13 | and HA1 | | | | | | | | | | |
| Example 1-18 | HT-14 | 10 | HT-14 | 40 | HT-27 | 35 | HT-29 | 10 | 0.88 | 12.1 | 220 |
| | and HA1 | | | | | | | | | | |
| Comparative | HT-14 | 10 | HT-14 | 75 | HT-28 | 10 | — | — | 0.13 | 11.7 | 10 |
| 1-14 | and HA1 | | | | | | | | | | |
| Example 1-19 | HT-14 | 10 | HT-14 | 40 | HT-28 | 35 | HT-30 | 10 | 0.88 | 12.6 | 220 |
| | and HA1 | | | | | | | | | | |
| Comparative | HT-19 | 10 | HT-19 | 75 | HT-16 | 10 | — | — | 0.13 | 11.4 | 160 |
| 1-15 | and HA1 | | | | | | | | | | |
| Example 1-20 | HT-19 | 10 | HT-19 | 40 | HT-16 | 45 | — | — | 1.13 | 13.3 | 170 |
| | and HA1 | | | | | | | | | | |
| Comparative | HT-19 | 10 | HT-19 | 75 | HT-23 | 10 | — | — | 0.13 | 11.5 | 180 |
| 1-16 | and HA1 | | | | | | | | | | |
| Example 1-21 | HT-19 | 10 | HT-19 | 40 | HT-23 | 45 | — | — | 1.13 | 12.5 | 190 |
| | and HA1 | | | | | | | | | | |
| Example 1-22 | HT-19 | 10 | HT-19 | 40 | HT-23 | 35 | HT-30 | 10 | 0.88 | 12.6 | 210 |
| | and HA1 | | | | | | | | | | |

### Example 2-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, the compound HT-14 and the compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-14 and the compound HA1 in the first anode side organic layer were 97 mass % and 3 mass %, respectively.

The compound HT-14 was vapor-deposited on the first anode side organic layer to form a 40-nm-thick second anode side organic layer (occasionally also referred to as a first hole transporting layer).

The compound HT-15 was vapor-deposited on the second anode side organic layer to form a 45-nm-thick third anode side organic layer (occasionally also referred to as an electron blocking layer).

The compound BH2 (host material) and the compound BD (emitting compound) were co-deposited on the third anode side organic layer so that a ratio of the compound BD accounted for 1 mass %, thereby forming a 20-nm-thick emitting layer.

Next, the compound ET1 was vapor-deposited on the emitting layer to form a 5-nm-thick first electron transporting layer (also referred to as a hole blocking layer (HBL)).

The compound ET2 and the compound Liq were co-deposited on the first electron transporting layer to form a 25-nm-thick second electron transporting layer (ET). The ratios of the compound ET2 and the compound Liq in the second electron transporting layer were 50 mass % and 50 mass %, respectively.

Ytterbium (Yb) was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 2-1 is roughly shown as follows.
ITO(130)/HT-14:HA1(10.97%:3%)/HT-14(40)/HT-15(45)/BH2:BD(20.99%:1%)/ET1(5)/ET2:Liq(25.50%:50%)/Yb(1)/Al(80)

Numerals in parentheses represent a film thickness (unit: nm).

The numerals (97%:3%) represented by percentage in the same parentheses indicate a ratio (mass %) between the compound HT-14 and the compound HA1 in the first anode side organic layer, the numerals (99%:1%) represented by percentage in the same parentheses indicate a ratio (mass %) between the host material (compound BH2) and the emitting compound (compound BD) in the emitting layer, and the numerals (50%:50%) represented by percentage in the same parentheses indicate a ratio (mass %) between the compound ET2 and the compound Liq in the electron injecting layer.

### Example 2-2

The organic EL device of Example 2-2 was produced in the same manner as in Example 2-1 except that the third anode side organic layer was formed to have a film thickness of 35 nm in Example 2-2, the compound HT-17 was vapor-deposited on the third anode side organic layer to form a 10-nm-thick fourth anode side organic layer (occasionally also referred to as an electron blocking layer) in Example 2-2, and the emitting layer was formed on the fourth anode side organic layer in Example 2-2, as shown in Table 6.

### Example 2-3

The organic EL device of Example 2-3 was produced in the same manner as in Example 2-2 except that the compound HT-15 used for forming the third anode side organic layer in Example 2-2 was changed to the compound HT-16, as shown in Table 6.

### Comparative 2-1

The organic EL device of Comparative 2-1 was produced in the same manner as in Example 2-1 except that the film thickness of the second and third anode side organic layers was changed from those in Example 2-1 to those in Comparative 2-1, as shown in Table 6.

### Comparative 2-2

The organic EL device of Comparative 2-2 was produced in the same manner as in Example 2-1 except that the film thickness of the second and third anode side organic layers was changed from those in Example 2-1 to those in Comparative 2-2 and the compound HT-15 used for forming the third anode side organic layer in Example 2-1 was changed to the compound HT-16, as shown in Table 6.

TABLE 6

| | Anode Side Organic Layer | | | | | | | | | | | |
|---|---|---|---|---|---|---|---|---|---|---|---|---|
| | First Anode | | Second Anode | | Third Anode | | | Fourth Anode | | | | |
| | Side Organic Layer | | Side Organic Layer | | Side Organic Layer | | | Side Organic Layer | | Film | Device | |
| | | Film | | Film | Compound | | Film | | Film | Thickness | Performance | |
| | Compound | Thickness | Compound | Thickness | | S₁ | Thickness | Compound | Thickness | Ratio | EQE | LT95 |
| | Name | [nm] | Name | [nm] | Name | [eV] | [nm] | Name | [nm] | TL₃/TL₂ | [%] | [hr] |
| Example 2-1 | HT-14 | 10 | HT-14 | 40 | HT-15 | 3.18 | 45 | — | — | 1.13 | 11.51 | 80 |
| | and HA1 | | | | | | | | | | | |
| Example 2-2 | HT-14 | 10 | HT-14 | 40 | HT-15 | 3.18 | 35 | HT-17 | 10 | 0.88 | 11.57 | 158 |
| | and HA1 | | | | | | | | | | | |
| Comparative | HT-14 | 10 | HT-14 | 75 | HT-15 | 3.18 | 10 | — | — | 0.13 | 11.18 | 67 |
| 2-1 | and HA1 | | | | | | | | | | | |
| Example 2-3 | HT-14 | 10 | HT-14 | 40 | HT-16 | 3.26 | 35 | HT-17 | 10 | 0.88 | 12.12 | 108 |
| | and HA1 | | | | | | | | | | | |
| Comparative | HT-14 | 10 | HT-14 | 75 | HT-16 | 3.26 | 10 | — | — | 0.13 | 10.66 | 19 |
| 2-2 | and HA1 | | | | | | | | | | | |

### Example 2-4, Examples 2-6 to 2-8

The organic EL devices of Example 2-4 and Examples 2-6 to 2-8 were respectively produced in the same manner as in Example 2-2 except that the compound HT-15 used for forming the third anode side organic layer in Example 2-2 was changed to compounds shown in Table 7.

### Examples 2-5, 2-9, and 2-10

The organic EL devices of Examples 2-5, 2-9 and 2-10 were respectively produced in the same manner as in Example 2-2 except that the compound HT-15 used for forming the third anode side organic layer in Example 2-2 and the compound HT-17 used for forming the fourth anode side organic layer in Example 2-2 were changed to compounds shown in Table 7.

### Comparatives 2-3 to 2-9

The organic EL devices of Comparatives 2-3 to 2-9 were respectively produced in the same manner as in Comparative 2-1 except that the compound HT-used for forming the third anode side organic layer in Comparative 2-1 was changed to compounds shown in Table 7.

TABLE 7

| | Anode Side Organic Layer | | | | | | | | | | |
|---|---|---|---|---|---|---|---|---|---|---|---|
| | First Anode | | Second Anode | | Third Anode | | Fourth Anode | | | | |
| | Side Organic Layer | | Side Organic Layer | | Side Organic Layer | | Side Organic Layer | | Film | Device | |
| | | Film | | Film | | Film | | Film | Thickness | Performance | |
| | Compound | Thickness | Compound | Thickness | Compound | Thickness | Compound | Thickness | Ratio | EQE | LT95 |
| | Name | [nm] | Name | [nm] | Name | [nm] | Name | [nm] | TL₃/TL₂ | [%] | [hr] |
| Comparative | HT-14 | 10 | HT-14 | 75 | HT-22 | 10 | — | — | 0.13 | 11.0 | 95 |
| 2-3 | and HA1 | | | | | | | | | | |
| Example 2-4 | HT-14 | 10 | HT-14 | 40 | HT-22 | 35 | HT-17 | 10 | 0.88 | 11.2 | 163 |
| | and HA1 | | | | | | | | | | |
| Comparative | HT-14 | 10 | HT-14 | 75 | HT-23 | 10 | — | — | 0.13 | 10.9 | 95 |
| 2-4 | and HA1 | | | | | | | | | | |
| Example 2-5 | HT-14 | 10 | HT-14 | 40 | HT-23 | 35 | HT-30 | 10 | 0.88 | 11.3 | 148 |
| | and HA1 | | | | | | | | | | |
| Comparative | HT-14 | 10 | HT-14 | 75 | HT-24 | 10 | — | — | 0.13 | 10.9 | 65 |
| 2-5 | and HA1 | | | | | | | | | | |
| Example 2-6 | HT-14 | 10 | HT-14 | 40 | HT-24 | 35 | HT-17 | 10 | 0.88 | 11.7 | 125 |
| | and HA1 | | | | | | | | | | |
| Comparative | HT-14 | 10 | HT-14 | 75 | HT-25 | 10 | — | — | 0.13 | 10.7 | 173 |
| 2-6 | and HA1 | | | | | | | | | | |
| Example 2-7 | HT-14 | 10 | HT-14 | 40 | HT-25 | 35 | HT-17 | 10 | 0.88 | 11.0 | 213 |
| | and HA1 | | | | | | | | | | |
| Comparative | HT-14 | 10 | HT-14 | 75 | HT-26 | 10 | — | — | 0.13 | 10.7 | 162 |
| 2-7 | and HA1 | | | | | | | | | | |
| Example 2-8 | HT-14 | 10 | HT-14 | 40 | HT-26 | 35 | HT-17 | 10 | 0.88 | 10.8 | 215 |
| | and HA1 | | | | | | | | | | |
| Comparative | HT-14 | 10 | HT-14 | 75 | HT-27 | 10 | — | — | 0.13 | 11.2 | 11 |
| 2-8 | and HA1 | | | | | | | | | | |
| Example 2-9 | HT-14 | 10 | HT-14 | 40 | HT-27 | 35 | HT-30 | 10 | 0.88 | 11.6 | 169 |
| | and HA1 | | | | | | | | | | |
| Comparative | HT-14 | 10 | HT-14 | 75 | HT-28 | 10 | — | — | 0.13 | 11.2 | 3 |
| 2-9 | and HA1 | | | | | | | | | | |
| Example 2-10 | HT-14 | 10 | HT-14 | 40 | HT-28 | 35 | HT-30 | 10 | 0.88 | 11.7 | 205 |
| | and HA1 | | | | | | | | | | |

### Example 2-11

The organic EL device of Example 2-11 was produced in the same manner as in Example 2-2 except that the compound HT-14 used for forming the first and second anode side organic layers in Example 2-2 and the compound HT-17 used for forming the fourth anode side organic layer in Example 2-2 were changed to compounds shown in Table 8.

### Example 2-12

The organic EL device of Example 2-12 was produced in the same manner as in Example 2-2 except that the compound HT-14 used for forming the first and second anode side organic layers in Example 2-2 and the compound HT-15 used for forming the third anode side organic layer in Example 2-2 were changed to compounds shown in Table 8.

### Example 2-13

The organic EL device of Example 2-13 was produced in the same manner as in Example 2-2 except that the compound HT-14 used for forming the first and second anode side organic layers in Example 2-2, the compound HT-15 used for forming the third anode side organic layer in Example 2-2, and the compound HT-17 used for forming the fourth anode side organic layer in Example 2-2 were changed to compounds shown in Table 8.

### Comparative 2-10

The organic EL device of Comparative 2-10 was produced in the same manner as in Comparative 2-1 except that the compound HT-14 used for forming the first and second anode side organic layers in Comparative 2-1 was changed to compounds shown in Table 8.

### Comparatives 2-11 and 2-12

The organic EL devices of Comparatives 2-11 and 2-12 were respectively produced in the same manner as in Comparative 2-1 except that the compound HT-14 used for forming the first and second anode side organic layers in Comparative 2-1 and the compound HT-15 used for forming the third anode side organic layer in Comparative 2-1 were changed to compounds shown in Table 8.

TABLE 8

| | Anode Side Organic Layer | | | | | | | | | | |
|---|---|---|---|---|---|---|---|---|---|---|---|
| | First Anode Side | | Second Anode Side | | Third Anode Side | | Fourth Anode Side | | | | |
| | Organic Layer | | Organic Layer | | Organic Layer | | Organic Layer | | Film | Device | |
| | | Film | | Film | | Film | | Film | Thickness | Performance | |
| | Compound | Thickness | Compound | Thickness | Compound | Thickness | Compound | Thickness | Ratio | EQE | LT95 |
| | Name | [nm] | Name | [nm] | Name | [nm] | Name | [nm] | TL₃/TL₂ | [%] | [hr] |
| Comparative | HT-19 | 10 | HT-19 | 75 | HT-15 | 10 | — | — | 0.13 | 11.2 | 120 |
| 2-10 | and HA1 | | | | | | | | | | |
| Example 2-11 | HT-19 | 10 | HT-19 | 40 | HT-15 | 35 | HT-29 | 10 | 0.88 | 11.9 | 176 |
| | and HA1 | | | | | | | | | | |
| Comparative | HT-19 | 10 | HT-19 | 75 | HT-16 | 10 | — | — | 0.13 | 11.2 | 100 |
| 2-11 | and HA1 | | | | | | | | | | |
| Example 2-12 | HT-19 | 10 | HT-19 | 40 | HT-16 | 35 | HT-17 | 10 | 0.88 | 12.5 | 122 |
| | and HA1 | | | | | | | | | | |
| Comparative | HT-19 | 10 | HT-19 | 75 | HT-23 | 10 | — | — | 0.13 | 11.2 | 130 |
| 2-12 | and HA1 | | | | | | | | | | |
| Example 2-13 | HT-19 | 10 | HT-19 | 40 | HT-23 | 35 | HT-30 | 10 | 0.88 | 11.8 | 168 |
| | and HA1 | | | | | | | | | | |

### Example 3-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-19 and the compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-19 and the compound HA1 in the first anode side organic layer were 97 mass % and 3 mass %, respectively.

The compound HT-19 was vapor-deposited on the first anode side organic layer to form a 45-nm-thick second anode side organic layer (occasionally also referred to as a first hole transporting layer).

A compound HT-80 was vapor-deposited on the second anode side organic layer to form a 45-nm-thick third anode side organic layer (occasionally also referred to as an electron blocking layer).

The compound BH1 (first host material) and the compound BD (first emitting compound) were co-deposited on the third anode side organic layer so that a ratio of the compound BD accounted for 1 mass %, thereby forming a 5-nm-thick first emitting layer.

The compound BH2 (second host material) and the compound BD (second emitting compound) were co-deposited on the first emitting layer so that a ratio of the compound BD accounted for 1 mass %, thereby forming a 15-nm-thick second emitting layer.

The compound ET3 was vapor-deposited on the second emitting layer to form a 5-nm-thick first electron transporting layer (occasionally also referred to as a hole blocking layer (HBL)).

The compound ET2 and the compound Liq were co-deposited on the first electron transporting layer to form a 25-nm-thick second electron transporting layer (ET). The ratios of the compound ET2 and the compound Liq in the second electron transporting layer were 50 mass % and 50 mass %, respectively.

Ytterbium (Yb) was vapor-deposited on the second electron transporting layer to form a 1-nm-thick electron injecting layer.

Metal (Al) was vapor-deposited on the electron injecting layer to form a 50-nm-thick cathode.

A device arrangement of the organic EL device in Example 3-1 is roughly shown as follows.
ITO(130)/HT-19:HA1(10.97%:3%)/HT-19(45)/HT-80(45)/BH1:BD(5.99%:1%)/BH2:BD(15.99%:1%)/ET3(5)/ET2:Liq(25.50%:50%)/Yb(1)/Al(50)

Numerals in parentheses represent a film thickness (unit: nm).

The numerals (97%:3%) represented by percentage in the same parentheses indicate a ratio (mass %) between the compound HT-19 and the compound HA1 in the first anode side organic layer, the numerals (99%:1%) represented by percentage in the same parentheses indicate a ratio (mass %) between the host material (compound BH1 or BH2) and the emitting compound (compound BD) in the first emitting layer or the second emitting layer, and the numerals (50%:50%) represented by percentage in the same parentheses indicate a ratio (mass %) between the compound ET2 and the compound Liq in the electron injecting layer. Similar notations apply to the description below.

### Comparative 3-1

The organic EL device of Comparative 3-1 was produced in the same manner as in Example 3-1 except that the film thickness of the second and third anode side organic layers was changed from that in Example 3-1 to those in Comparative 3-1, as shown in Table 9.

### Example 3-2

The organic EL device of Example 3-2 was produced in the same manner as in Example 3-1 except that the first, second, and third anode side organic layers of Example 3-2 were formed using compounds shown in Table 9 instead of those used in Example 3-1.

### Comparative 3-2

The organic EL device of Comparative 3-2 was produced in the same manner as in Example 3-2 except that the film thickness of the second and third anode side organic layers was changed from that in Example 3-2 to those in Comparative 3-2, as shown in Table 9.

TABLE 9

| Anode Side Organic Layer | | | | | | | | | | | | | |
|---|---|---|---|---|---|---|---|---|---|---|---|---|---|
| | First Anode Side | | Second Anode Side | | | Third Anode Side | | | | | | | |
| | Organic Layer | | Organic Layer | | | Organic Layer | | | Refractive | Film | | | |
| | | Film | | Film | Re- | | Film | Re- | Index | Thick- | Device | | |
| | Com- | Thick- | Com- | Thick- | fractive | Com- | Thick- | fractive | Difference | ness | Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-19 | 10 | HT-19 | 45 | 2.00 | HT-80 | 45 | 1.93 | 0.07 | 1.00 | 3.5 | 11.5 | 245 |
| 3-1 | and HA1 | | | | | | | | | | | | |
| Com- | HT-19 | 10 | HT-19 | 80 | 2.00 | HT-80 | 10 | 1.93 | 0.07 | 0.13 | 3.4 | 10.5 | 224 |
| parative | and HA1 | | | | | | | | | | | | |
| 3-1 | | | | | | | | | | | | | |
| Example | HT-70 | 10 | HT-70 | 45 | 1.95 | HT-81 | 45 | 1.89 | 0.06 | 1.00 | 3.3 | 10.8 | 186 |
| 3-2 | and HA1 | | | | | | | | | | | | |
| Com- | HT-70 | 10 | HT-70 | 80 | 1.95 | HT-81 | 10 | 1.89 | 0.06 | 0.13 | 3.3 | 9.8 | 167 |
| parative | and HA1 | | | | | | | | | | | | |
| 3-2 | | | | | | | | | | | | | |

### Example 3-3

The organic EL device of Example 3-3 was produced in the same manner as in Example 3-1 except that the third anode side organic layer of Example 3-3 was formed using a compound shown in Table 10 and the first electron transporting layer of Example 3-3 was formed using the compound ET1 instead of the compound ET3 used in Example 3-1.

### Comparative 3-3

The organic EL device of Comparative 3-3 was produced in the same manner as in Example 3-3 except that the film thickness of the second and third anode side organic layers was changed from that in Example 3-3 to those in Comparative 3-3, as shown in Table 10.

### Examples 3-4 to 3-6

The organic EL devices of Examples 3-4 to 3-6 were respectively produced in the same manner as in Example 3-3 except that the first, second, and third anode side organic layers of Examples 3-4 to 3-6 were formed using compounds shown in Table 10 instead of those used in Example 3-3.

### Comparatives 3-4 to 3-6

The organic EL devices of Comparatives 3-4 to 3-6 were respectively produced in the same manner as in Comparative 3-3 except that the first, second, and third anode side organic layers of Comparatives 3-4 to 3-6 were formed using compounds shown in Table 10 instead of those used in Comparative 3-3.

TABLE 10

| | Anode Side Organic Layers | | | | | | | | | | | | |
|---|---|---|---|---|---|---|---|---|---|---|---|---|---|
| | First Anode | | | | | | | | | | | | |
| | Side Organic | | Second Anode Side | | | Third Anode Side | | | | | | | |
| | Layer | | Organic Layer | | | Organic Layer | | | Refractive | Film | | | |
| | | Film | | Film | Re- | | Film | Re- | Index | Thick- | Device | | |
| | Com- | Thick- | Com- | Thick- | fractive | Com- | Thick- | fractive | Difference | ness | Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-19 | 10 | HT-19 | 45 | 2.00 | HT-82 | 42 | 1.71 | 0.29 | 1.00 | 3.4 | 12.1 | 241 |
| 3-3 | and HA1 | | | | | | | | | | | | |
| Com- | HT-19 | 10 | HT-19 | 80 | 2.00 | HT-82 | 10 | 1.71 | 0.29 | 0.13 | 3.3 | 11.5 | 220 |
| parative | and HA1 | | | | | | | | | | | | |
| 3-3 | | | | | | | | | | | | | |
| Example | HT-70 | 10 | HT-70 | 45 | 1.95 | HT-83 | 45 | 1.83 | 0.12 | 1.00 | 3.3 | 12.2 | 210 |
| 3-4 | and HA1 | | | | | | | | | | | | |
| Com- | HT-70 | 10 | HT-70 | 80 | 1.95 | HT-83 | 10 | 1.83 | 0.12 | 0.13 | 3.3 | 10.5 | 130 |
| parative | and HA1 | | | | | | | | | | | | |
| 3-4 | | | | | | | | | | | | | |
| Example | HT-71 | 10 | HT-71 | 45 | 1.98 | HT-83 | 45 | 1.83 | 0.15 | 1.00 | 3.4 | 12.7 | 150 |
| 3-5 | and HA1 | | | | | | | | | | | | |
| Com- | HT-71 | 10 | HT-71 | 80 | 1.98 | HT-83 | 10 | 1.83 | 0.15 | 0.13 | 3.4 | 11.7 | 125 |
| parative | and HA1 | | | | | | | | | | | | |
| 3-5 | | | | | | | | | | | | | |
| Example | HT-72 | 10 | HT-72 | 45 | 1.85 | HT-84 | 45 | 1.80 | 0.05 | 1.00 | 3.5 | 11.5 | 181 |
| 3-6 | and HA1 | | | | | | | | | | | | |
| Com- | HT-72 | 10 | HT-72 | 80 | 1.85 | HT-84 | 10 | 1.80 | 0.05 | 0.13 | 3.4 | 10.4 | 150 |
| parative | and HA1 | | | | | | | | | | | | |
| 3-6 | | | | | | | | | | | | | |

### Example 3-7

A glass substrate (size: 25 mm×75 mm×1.1 mm thick, produced by Geomatec Go., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, the compound HT-19 and the compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-19 and the compound HA1 in the first anode side organic layer were 97 mass % and 3 mass %, respectively.

The compound HT-19 was vapor-deposited on the first anode side organic layer to form a 40-nm-thick second anode side organic layer (occasionally also referred to as a first hole transporting layer).

A compound HT-85 was vapor-deposited on the second anode side organic layer to form a 40-nm-thick third anode side organic layer (occasionally also referred to as a second hole transporting layer).

The compound HT-17 was vapor-deposited on the third anode side organic layer to form a 10-nm-thick fourth anode side organic layer (occasionally also referred to as an electron blocking layer).

The compound BH1 (first host material) and the compound BD (first emitting compound) were co-deposited on the fourth anode side organic layer so that a ratio of the compound BD accounted for 1 mass %, thereby forming a 5-nm-thick first emitting layer.

The compound BH2 (second host material) and the compound BD (second emitting compound) were co-deposited on the first emitting layer so that a ratio of the compound BD accounted for 1 mass %, thereby forming a 15-nm-thick second emitting layer.

The compound ET3 was vapor-deposited on the second emitting layer to form a 5-nm-thick first electron transporting layer (occasionally also referred to as a hole blocking layer (HBL)).

The compound ET2 and the compound Liq were co-deposited on the first electron transporting layer to form a 25-nm-thick second electron transporting layer (ET). The ratios of the compound ET2 and the compound Liq in the second electron transporting layer were 50 mass % and 50 mass %, respectively.

Ytterbium (Yb) was vapor-deposited on the second electron transporting layer to form a 1-nm-thick electron injecting layer.

Metal (Al) was vapor-deposited on the electron injecting layer to form a 50-nm-thick cathode.

A device arrangement of the organic EL device in Example 3-7 is roughly shown as follows.
ITO(130)/HT-19:HA1(10.97%:3%)/HT-19(40)/HT-85(40)/HT-17(10)/BH1:BD(5.99%:1%)/BH2:BD(15.99%:1%)/ET3(5)/ET2:Liq(25.50%:50%)/Yb(1)/Al(50)

### Comparative 3-7

The organic EL device of Comparative 3-7 was produced in the same manner as in Example 3-7 except that the film thickness of the second and third anode side organic layers was changed from that in Example 3-7 to those in Comparative 3-7, as shown in Table 11.

### Example 3-8

The organic EL device of Example 3-8 was produced in the same manner as in Example 3-7 except that the first, second, and third anode side organic layers of Example 3-8 were formed using compounds shown in Table 11 instead of those used in Example 3-7.

### Comparative 3-8

The organic EL device of Comparative 3-8 was produced in the same manner as in Comparative 3-7 except that the first, second, and third anode side organic layers of Comparative 3-8 were formed using compounds shown in Table 11 instead of those used in Comparative 3-7.

TABLE 11

| | Anode Side Organic Layers | | | | | | | | | | | | | | |
|---|---|---|---|---|---|---|---|---|---|---|---|---|---|---|---|
| | First Anode | | | | | | | | Fourth | | Re- | | | | |
| | Side Organic | | Second Anode Side | | | Third Anode Side | | | Anode Side | | fractive | | | | |
| | Layer | | Organic Layer | | | Organic Layer | | | Organic Layer | | Index | Film | | | |
| | | Film | | Film | Re- | | Film | Re- | | Film | Differ- | Thick- | Device | | |
| | Com- | Thick- | Com- | Thick- | fractive | Com- | Thick- | fractive | Com- | Thick- | ence | ness | Performance | | |
| | pound | ness | pound | ness | Index | pound | ness | Index | pound | ness | NM₂ − | Ratio | Voltage | EQE | LT95 |
| | Name | [nm] | Name | [nm] | NM₂ | Name | [nm] | NM₃ | Name | [nm] | NM₃ | TL₃/TL₂ | [V] | [%] | [hr] |
| Example | HT-19 | 10 | HT-19 | 40 | 2.00 | HT-85 | 40 | 1.83 | HT-17 | 10 | 0.17 | 1.00 | 3.4 | 11.2 | 200 |
| 3-7 | and HA1 | | | | | | | | | | | | | | |
| Com- | HT-19 | 10 | HT-19 | 70 | 2.00 | HT-85 | 10 | 1.83 | HT-17 | 10 | 0.17 | 0.14 | 3.4 | 10.6 | 140 |
| parative | and HA1 | | | | | | | | | | | | | | |
| 3-7 | | | | | | | | | | | | | | | |
| Example | HT-71 | 10 | HT-71 | 40 | 1.98 | HT-87 | 40 | 1.93 | HT-17 | 10 | 0.05 | 1.00 | 3.4 | 11.3 | 86 |
| 3-8 | and HA1 | | | | | | | | | | | | | | |
| Com- | HT-71 | 10 | HT-71 | 70 | 1.98 | HT-87 | 10 | 1.93 | HT-17 | 10 | 0.05 | 0.14 | 3.3 | 10.3 | 50 |
| parative | and HA1 | | | | | | | | | | | | | | |
| 3-8 | | | | | | | | | | | | | | | |

### Example 3-9

The organic EL device of Example 3-9 was produced in the same manner as in Example 3-1 except that the first, second, and third anode side organic layers of Example 3-9 were formed using compounds shown in Table 12 instead of those used in Example 3-1 and the electron injecting layer of Example 3-9 was formed using lithium fluoride (LiF) instead of ytterbium (Yb) used in Example 3-1.

### Comparative 3-9

The organic EL device of Comparative 3-9 was produced in the same manner as in Example 3-9 except that the film thickness of the second and third anode side organic layers was changed from that in Example 3-9 to those in Comparative 3-9, as shown in Table 12.

TABLE 12

| | Anode Side Organic Layers | | | | | | | | | | | | |
|---|---|---|---|---|---|---|---|---|---|---|---|---|---|
| | First Anode | | | | | | | | | | | | |
| | Side Organic | | Second Anode Side | | | Third Anode Side | | | | | | | |
| | Layer | | Organic Layer | | | Organic Layer | | | Refractive | Film | | | |
| | | Film | | Film | Re- | | Film | Re- | Index | Thick- | | | |
| | Com- | Thick- | Com- | Thick- | fractive | Com- | Thick- | fractive | Difference | ness | Device Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-70 | 10 | HT-70 | 45 | 1.95 | HT-78 | 45 | 1.81 | 0.14 | 1.00 | 3.9 | 11.4 | 74 |
| 3-9 | and HA1 | | | | | | | | | | | | |
| Comparative | HT-70 | 10 | HT-70 | 80 | 1.95 | HT-78 | 10 | 1.81 | 0.14 | 0.13 | 3.5 | 10.8 | 50 |
| 3-9 | and HA1 | | | | | | | | | | | | |

### Example 3-10

The organic EL device of Example 3-10 was produced in the same manner as in Example 3-1 except that the third anode side organic layer of Example 3-10 was formed using a compound shown in Table 13 instead of the compound used in Example 3-1 and the first and second emitting layers of Example 3-10 were formed using the compound BD2 instead of the compound BD used in Example 3-1.

### Comparative 3-10

The organic EL device of Comparative 3-10 was produced in the same manner as in Example 3-10 except that the film thickness of the second and third anode side organic layers was changed from that in Example 3-10 to those in Comparative 3-10, as shown in Table 13.

### Examples 3-11 to 3-13

The organic EL devices of Examples 3-11 to 3-13 were respectively produced in the same manner as in Example 3-10 except that the first, second, and third anode side organic layers of Examples 3-11 to 3-13 were formed using compounds shown in Table 13 instead of those used in Example 3-10.

### Comparatives 3-11 to 3-13

The organic EL devices of Comparatives 3-11 to 3-13 were respectively produced in the same manner as in Comparative 3-10 except that the first, second, and third anode side organic layers of Comparatives 3-11 to 3-13 were formed using compounds shown in Table 13 instead of those used in Comparative 3-10.

TABLE 13

| | Anode Side Organic Layers | | | | | | | | | | | | |
|---|---|---|---|---|---|---|---|---|---|---|---|---|---|
| | First Anode | | | | | | | | | | | | |
| | Side Organic | | Second Anode Side | | | Third Anode Side | | | | | | | |
| | Layer | | Organic Layer | | | Organic Layer | | | Refractive | Film | | | |
| | | Film | | Film | Re- | | Film | Re- | Index | Thick- | | | |
| | Com- | Thick- | Com- | Thick- | fractive | Com- | Thick- | fractive | Difference | ness | Device Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-19 | 10 | HT-19 | 45 | 2.00 | HT-16 | 45 | 1.79 | 0.21 | 1.00 | 3.8 | 12.1 | 64 |
| 3-10 | and HA1 | | | | | | | | | | | | |
| Comparative | HT-19 | 10 | HT-19 | 80 | 2.00 | HT-16 | 10 | 1.79 | 0.21 | 0.13 | 3.5 | 11.2 | 43 |
| 3-10 | and HA1 | | | | | | | | | | | | |
| Example | HT-73 | 10 | HT-73 | 45 | 1.98 | HT-86 | 45 | 1.87 | 0.11 | 1.00 | 3.9 | 10.4 | 136 |
| 3-11 | and HA1 | | | | | | | | | | | | |
| Comparative | HT-73 | 10 | HT-73 | 80 | 1.98 | HT-86 | 10 | 1.87 | 0.11 | 0.13 | 3.5 | 8.9 | 115 |
| 3-11 | and HA1 | | | | | | | | | | | | |
| Example | HT-74 | 10 | HT-74 | 45 | 1.86 | HT-16 | 45 | 1.79 | 0.07 | 1.00 | 3.7 | 10.3 | 61 |
| 3-12 | and HA1 | | | | | | | | | | | | |
| Comparative | HT-74 | 10 | HT-74 | 80 | 1.86 | HT-16 | 10 | 1.79 | 0.07 | 0.13 | 3.5 | 8.5 | 30 |
| 3-12 | and HA1 | | | | | | | | | | | | |
| Example | HT-70 | 10 | HT-70 | 45 | 1.95 | HT-88 | 45 | 1.89 | 0.06 | 1.00 | 3.9 | 10.7 | 95 |
| 3-13 | and HA1 | | | | | | | | | | | | |
| Comparative | HT-70 | 10 | HT-70 | 80 | 1.95 | HT-88 | 10 | 1.89 | 0.06 | 0.13 | 3.5 | 10.1 | 70 |
| 3-13 | and HA1 | | | | | | | | | | | | |

### Example 3-14

The organic EL device of Example 3-14 was produced in the same manner as in Example 3-1 except that the third anode side organic layer of Example 3-14 was formed using a compound shown in Table 14 instead of the compound used in Example 3-1 and the second emitting layer of Example 3-14 was formed using a compound BH3 instead of the compound BH2 used in Example 3-1.

### Comparative 3-14

The organic EL device of Comparative 3-14 was produced in the same manner as in Example 3-14 except that the film thickness of the second and third anode side organic layers was changed from that in Example 3-14 to those in Comparative 3-14, as shown in Table 14.

TABLE 14

| | Anode Side Organic Layers | | | | | | | | | | | | |
|---|---|---|---|---|---|---|---|---|---|---|---|---|---|
| | First Anode | | | | | | | | | | | | |
| | Side Organic | | Second Anode Side | | | Third Anode Side | | | | | | | |
| | Layer | | Organic Layer | | | Organic Layer | | | Refractive | Film | | | |
| | | Film | | Film | Re- | | Film | Re- | Index | Thick- | | | |
| | Com- | Thick- | Com- | Thick- | fractive | Com- | Thick- | fractive | Difference | ness | Device Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-19 | 10 | HT-19 | 45 | 2.00 | HT-89 | 45 | 1.84 | 0.16 | 1.00 | 3.9 | 11.0 | 135 |
| 3-14 | and HA1 | | | | | | | | | | | | |
| Comparative | HT-19 | 10 | HT-19 | 80 | 2.00 | HT-89 | 10 | 1.84 | 0.16 | 0.13 | 3.6 | 10.6 | 100 |
| 3-14 | and HA1 | | | | | | | | | | | | |

### Example 3-15

The organic EL device of Example 3-15 was produced in the same manner as in Example 3-1 except that the third anode side organic layer of Example 3-15 was formed using a compound shown in Table 15 and the first emitting layer of Example 3-15 was formed using a compound BH4 instead of the compound BH1 used in Example 3-1.

### Comparative 3-15

The organic EL device of Comparative 3-15 was produced in the same manner as in Example 3-15 except that the film thickness of the second and third anode side organic layers was changed from that in Example 3-15 to those in Comparative 3-15, as shown in Table 15.

TABLE 15

| | Anode Side Organic Layers | | | | | | | | | | | | |
|---|---|---|---|---|---|---|---|---|---|---|---|---|---|
| | First Anode | | | | | | | | | | | | |
| | Side Organic | | Second Anode Side | | | Third Anode Side | | | | | | | |
| | Layer | | Organic Layer | | | Organic Layer | | | Refractive | Film | | | |
| | | Film | | Film | Re- | | Film | Re- | Index | Thick- | | | |
| | Com- | Thick- | Com- | Thick- | fractive | Com- | Thick- | fractive | Difference | ness | Device Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-19 | 10 | HT-19 | 45 | 2.00 | HT-90 | 45 | 1.93 | 0.07 | 1.00 | 3.4 | 11.1 | 164 |
| 3-15 | and HA1 | | | | | | | | | | | | |
| Comparative | HT-19 | 10 | HT-19 | 80 | 2.00 | HT-90 | 10 | 1.93 | 0.07 | 0.13 | 3.4 | 10.2 | 150 |
| 3-15 | and HA1 | | | | | | | | | | | | |

### Example 3-16

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-74 and the compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-74 and the compound HA1 in the first anode side organic layer were 97 mass % and 3 mass %, respectively.

The compound HT-74 was vapor-deposited on the first anode side organic layer to form a 40-nm-thick second anode side organic layer (occasionally also referred to as a first hole transporting layer).

A compound HT-91 was vapor-deposited on the second anode side organic layer to form a 40-nm-thick third anode side organic layer (occasionally also referred to as a second electron transporting layer).

The compound HT-17 was vapor-deposited on the third anode side organic layer to form a 10-nm-thick fourth anode side organic layer (occasionally also referred to as an electron blocking layer).

The compound BH2 (host material) and the compound BD (emitting compound) were co-deposited on the fourth anode side organic layer so that a ratio of the compound BD accounted for 1 mass %, thereby forming a 20-nm-thick emitting layer.

Next, the compound ET3 was vapor-deposited on the emitting layer to form a 5-nm-thick first electron transporting layer (also referred to as a hole blocking layer (HBL)).

The compound ET2 and the compound Liq were co-deposited on the first electron transporting layer to form a 25-nm-thick second electron transporting layer (ET). The ratios of the compound ET2 and the compound Liq in the second electron transporting layer were 50 mass % and 50 mass %, respectively.

Ytterbium (Yb) was vapor-deposited on the second electron transporting layer to form a 1-nm-thick electron injecting layer.

Metal (Al) was vapor-deposited on the electron injecting layer to form a 50-nm-thick cathode.

A device arrangement of the organic EL device in Example 3-16 is roughly shown as follows.
ITO(130)/HT-74:HA1(10.97%:3%)/HT-74(40)/HT-91(40)/HT-17(10)/BH2:BD(20.99%:1%)/ET3(5)/ET2:Liq(25.50%:50%)/Yb(1)/Al(50)

### Comparative 3-16

The organic EL device of Comparative 3-16 was produced in the same manner as in Example 3-16 except that the film thickness of the second and third anode side organic layers was changed from that in Example 3-16 to those in Comparative 3-16, as shown in Table 16.

TABLE 16

| | Anode Side Organic Layers | | | | | | | | | | | | | | |
|---|---|---|---|---|---|---|---|---|---|---|---|---|---|---|---|
| | First Anode | | | | | | | | Fourth Anode | | Re- | | | | |
| | Side Organic | | Second Anode Side | | | Third Anode Side | | | Side Organic | | fractive | Film | | | |
| | Layer | | Organic Layer | | | Organic Layer | | | Layer | | Index | Thick- | | | |
| | | Film | | Film | Re- | | Film | Re- | | Film | Differ- | ness | | | |
| | Com- | Thick- | Com- | Thick- | fractive | Com- | Thick- | fractive | Com- | Thick- | ence | Ratio | Device Performance | | |
| | pound | ness | pound | ness | Index | pound | ness | Index | pound | ness | NM₂ − | TL₃/ | Voltage | EQE | LT95 |
| | Name | [nm] | Name | [nm] | NM₂ | Name | [nm] | NM₃ | Name | [nm] | NM₃ | TL₂ | [V] | [%] | [hr] |
| Example | HT-74 | 10 | HT-74 | 40 | 1.86 | HT-91 | 40 | 1.77 | HT-17 | 10 | 0.09 | 1.00 | 4.1 | 10.4 | 111 |
| 3-16 | and HA1 | | | | | | | | | | | | | | |
| Com- | HT-74 | 10 | HT-74 | 70 | 1.86 | HT-91 | 10 | 1.77 | HT-17 | 10 | 0.09 | 0.14 | 3.7 | 9.5 | 90 |
| parative | and HA1 | | | | | | | | | | | | | | |
| 3-16 | | | | | | | | | | | | | | | |

### Example 3-17

The organic EL device of Example 3-17 was produced in the same manner as in Example 3-16 except that the first, second, and third anode side organic layers of Example 3-17 were formed using compounds shown in Table 17 instead of those used in Example 3-16 and the first electron transporting layer of Example 3-17 was formed using the compound ET1 instead of the compound ET3 used in Example 3-16.

### Comparative 3-17

The organic EL device of Comparative 3-17 was produced in the same manner as in Example 3-17 except that the film thickness of the second and third anode side organic layers was changed from that in Example 3-17 to those in Comparative 3-17, as shown in Table 17.

### Example 3-18

The organic EL device of Example 3-18 was produced in the same manner as in Example 3-17 except that the first and second anode side organic layers of Example 3-18 were formed using compounds shown in Table 17 instead of those used in Example 3-17.

### Comparative 3-18

The organic EL device of Comparative 3-18 was produced in the same manner as in Comparative 3-17 except that the first and second anode side organic layers of Comparative 3-18 were formed using compounds shown in Table 17 instead of those used in Comparative 3-17.

TABLE 17

| | Anode Side Organic Layers | | | | | | | | | | | | | | |
|---|---|---|---|---|---|---|---|---|---|---|---|---|---|---|---|
| | First Anode | | | | | | | | Fourth Anode | | Re- | | | | |
| | Side Organic | | Second Anode Side | | | Third Anode Side | | | Side Organic | | fractive | Film | | | |
| | Layer | | Organic Layer | | | Organic Layer | | | Layer | | Index | Thick- | | | |
| | | Film | | Film | Re- | | Film | Re- | | Film | Differ- | ness | | | |
| | Com- | Thick- | Com- | Thick- | fractive | Com- | Thick- | fractive | Com- | Thick- | ence | Ratio | Device Performance | | |
| | pound | ness | pound | ness | Index | pound | ness | Index | pound | ness | NM₂ − | TL₃/ | Voltage | EQE | LT95 |
| | Name | [nm] | Name | [nm] | NM₂ | Name | [nm] | NM₃ | Name | [nm] | NM₃ | TL₂ | [V] | [%] | [hr] |
| Example | HT-73 | 10 | HT-73 | 40 | 1.98 | HT-92 | 40 | 1.81 | HT-17 | 10 | 0.17 | 1.00 | 4.1 | 11.4 | 97 |
| 3-17 | and HA1 | | | | | | | | | | | | | | |
| Com- | HT-73 | 10 | HT-73 | 70 | 1.98 | HT-92 | 10 | 1.81 | HT-17 | 10 | 0.17 | 0.14 | 3.8 | 9.7 | 68 |
| parative | and HA1 | | | | | | | | | | | | | | |
| 3-17 | | | | | | | | | | | | | | | |
| Example | HT-75 | 10 | HT-75 | 40 | 1.99 | HT-92 | 40 | 1.81 | HT-17 | 10 | 0.18 | 1.00 | 3.8 | 11.5 | 109 |
| 3-18 | and HA1 | | | | | | | | | | | | | | |
| Com- | HT-75 | 10 | HT-75 | 70 | 1.99 | HT-92 | 10 | 1.81 | HT-17 | 10 | 0.18 | 0.14 | 3.6 | 10.2 | 77 |
| parative | and HA1 | | | | | | | | | | | | | | |
| 3-17 | | | | | | | | | | | | | | | |

### Example 3-19

The organic EL device of Example 3-19 was produced in the same manner as in Example 3-16 except that the first, second, and third anode side organic layers of Example 3-19 were formed using compounds shown in Table 18 instead of those used in Example 3-16 and the electron injecting layer of Example 3-19 was formed using lithium fluoride (LiF) instead of ytterbium (Yb) used in Example 3-16.

### Comparative 3-19

The organic EL device of Comparative 3-19 was produced in the same manner as in Example 3-19 except that the film thickness of the second and third anode side organic layers was changed from that in Example 3-19 to those in Comparative 3-19, as shown in Table 18.

### Examples 3-20 to 3-21

The organic EL devices of Examples 3-20 to 3-21 were respectively produced in the same manner as in Example 3-19 except that the first and second anode side organic layers of Examples 3-20 to 3-21 were formed using compounds shown in Table 18 instead of those used in Example 3-19.

### Comparatives 3-20 to 3-21

The organic EL devices of Comparatives 3-20 to 3-21 were respectively produced in the same manner as in Comparative 3-19 except that the first and second anode side organic layers of Comparatives 3-20 to 3-21 were formed using compounds shown in Table 18 instead of those used in Comparative 3-19.

TABLE 18

| | Anode Side Organic Layers | | | | | | | | | | | | | | |
|---|---|---|---|---|---|---|---|---|---|---|---|---|---|---|---|
| | First Anode | | | | | | | | Fourth Anode | | Re- | | | | |
| | Side Organic | | Second Anode Side | | | Third Anode Side | | | Side Organic | | fractive | Film | | | |
| | Layer | | Organic Layer | | | Organic Layer | | | Layer | | Index | Thick- | | | |
| | | Film | | Film | Re- | | Film | Re- | | Film | Differ- | ness | | | |
| | Com- | Thick- | Com- | Thick- | fractive | Com- | Thick- | fractive | Com- | Thick- | ence | Ratio | Device Performance | | |
| | pound | ness | pound | ness | Index | pound | ness | Index | pound | ness | NM₂ − | TL₃/ | Voltage | EQE | LT95 |
| | Name | [nm] | Name | [nm] | NM₂ | Name | [nm] | NM₃ | Name | [nm] | NM₃ | TL₂ | [V] | [%] | [hr] |
| Example | HT-19 | 10 | HT-19 | 40 | 2.00 | HT-93 | 40 | 1.79 | HT-17 | 10 | 0.21 | 1.00 | 3.4 | 11.4 | 115 |
| 3-19 | and HA1 | | | | | | | | | | | | | | |
| Com- | HT-19 | 10 | HT-19 | 70 | 2.00 | HT-93 | 10 | 1.79 | HT-17 | 10 | 0.21 | 0.14 | 3.3 | 10.1 | 100 |
| parative | and HA1 | | | | | | | | | | | | | | |
| 3-19 | | | | | | | | | | | | | | | |
| Example | HT-74 | 10 | HT-74 | 40 | 1.86 | HT-93 | 40 | 1.79 | HT-17 | 10 | 0.07 | 1.00 | 3.5 | 11.5 | 123 |
| 3-20 | and HA1 | | | | | | | | | | | | | | |
| Com- | HT-74 | 10 | HT-74 | 70 | 1.86 | HT-93 | 10 | 1.79 | HT-17 | 10 | 0.07 | 0.14 | 3.3 | 10.5 | 95 |
| parative | and HA1 | | | | | | | | | | | | | | |
| 3-20 | | | | | | | | | | | | | | | |
| Example | HT-76 | 10 | HT-76 | 40 | 1.89 | HT-93 | 40 | 1.79 | HT-17 | 10 | 0.10 | 1.00 | 3.4 | 11.3 | 140 |
| 3-21 | and HA1 | | | | | | | | | | | | | | |
| Com- | HT-76 | 10 | HT-76 | 70 | 1.89 | HT-93 | 10 | 1.79 | HT-17 | 10 | 0.10 | 0.14 | 3.4 | 10.5 | 90 |
| parative | and HA1 | | | | | | | | | | | | | | |
| 3-21 | | | | | | | | | | | | | | | |

### Example 3-22

The organic EL device of Example 3-22 was produced in the same manner as in Example 3-16 except that the first, second, and third anode side organic layers of Example 3-22 were formed using compounds shown in Table 19 instead of those used in Example 3-16 and the emitting layer of Example 3-22 was formed using the compound BD2 instead of the compound BD used in Example 3-16.

### Comparative 3-22

The organic EL device of Comparative 3-22 was produced in the same manner as in Example 3-22 except that the film thickness of the second and third anode side organic layers was changed from that in Example 3-22 to those in Comparative 3-22, as shown in Table 19.

TABLE 19

| | Anode Side Organic Layers | | | | | | | | | | | | | | |
|---|---|---|---|---|---|---|---|---|---|---|---|---|---|---|---|
| | First Anode | | | | | | | | Fourth Anode | | Re- | | | | |
| | Side Organic | | Second Anode Side | | | Third Anode Side | | | Side Organic | | fractive | Film | | | |
| | Layer | | Organic Layer | | | Organic Layer | | | Layer | | Index | Thick- | | | |
| | | Film | | Film | Re- | | Film | Re- | | Film | Differ- | ness | | | |
| | Com- | Thick- | Com- | Thick- | fractive | Com- | Thick- | fractive | Com- | Thick- | ence | Ratio | Device Performance | | |
| | pound | ness | pound | ness | Index | pound | ness | Index | pound | ness | NM₂ − | TL₃/ | Voltage | EQE | LT95 |
| | Name | [nm] | Name | [nm] | NM₂ | Name | [nm] | NM₃ | Name | [nm] | NM₃ | TL₂ | [V] | [%] | [hr] |
| Example | HT-19 | 10 | HT-19 | 40 | 2.00 | HT-96 | 40 | 1.95 | HT-17 | 10 | 0.05 | 1.00 | 3.6 | 10.8 | 100 |
| 3-22 | and HA1 | | | | | | | | | | | | | | |
| Com- | HT-19 | 10 | HT-19 | 70 | 2.00 | HT-96 | 10 | 1.95 | HT-17 | 10 | 0.05 | 0.14 | 3.3 | 9.5 | 50 |
| parative | and HA1 | | | | | | | | | | | | | | |
| 3-22 | | | | | | | | | | | | | | | |

### Example 3-23

The organic EL device of Example 3-23 was produced in the same manner as in Example 3-16 except that the first, second, and third anode side organic layers of Example 3-23 were formed using compounds shown in Table 20 instead of those used in Example 3-16 and the emitting layer of Example 3-23 was formed using the compound BH3 instead of the compound BH2 used in Example 3-16.

### Comparative 3-23

The organic EL device of Comparative 3-23 was produced in the same manner as in Example 3-23 except that the film thickness of the second and third anode side organic layers was changed from that in Example 3-23 to those in Comparative 3-23, as shown in Table 20.

TABLE 20

| | Anode Side Organic Layers | | | | | | | | | | | | | | |
|---|---|---|---|---|---|---|---|---|---|---|---|---|---|---|---|
| | First Anode | | | | | | | | Fourth Anode | | Re- | | | | |
| | Side Organic | | Second Anode Side | | | Third Anode Side | | | Side Organic | | fractive | Film | | | |
| | Layer | | Organic Layer | | | Organic Layer | | | Layer | | Index | Thick- | | | |
| | | Film | | Film | Re- | | Film | Re- | | Film | Differ- | ness | | | |
| | Com- | Thick- | Com- | Thick- | fractive | Com- | Thick- | fractive | Com- | Thick- | ence | Ratio | Device Performance | | |
| | pound | ness | pound | ness | Index | pound | ness | Index | pound | ness | NM₂ − | TL₃/ | Voltage | EQE | LT95 |
| | Name | [nm] | Name | [nm] | NM₂ | Name | [nm] | NM₃ | Name | [nm] | NM₃ | TL₂ | [V] | [%] | [hr] |
| Example | HT-77 | 10 | HT-77 | 40 | 1.97 | HT-94 | 40 | 1.75 | HT-17 | 10 | 0.22 | 1.00 | 4.8 | 12.2 | 87 |
| 3-23 | and HA1 | | | | | | | | | | | | | | |
| Com- | HT-77 | 10 | HT-77 | 70 | 1.97 | HT-94 | 10 | 1.75 | HT-17 | 10 | 0.22 | 0.14 | 3.8 | 8.5 | 40 |
| parative | and HA1 | | | | | | | | | | | | | | |
| 3-23 | | | | | | | | | | | | | | | |

### Example 3-24

The organic EL device of Example 3-24 was produced in the same manner as in Example 3-16 except that the first, second, and third anode side organic layers of Example 3-24 were formed using compounds shown in Table 21 instead of those used in Example 3-16, the film thickness of the second and third anode side organic layers was changed from that in Example 3-16 to that in Example 3-24 (Table 21), and the emitting layer was formed on the third anode side organic layer without forming the fourth anode side organic layer in Example 3-24.

A device arrangement of the organic EL device in Example 3-24 is roughly shown as follows.
ITO(130)/HT-70:HA1(10.97%:3%)/HT-70(45)/HT-95(45)/BH2:BD(20.99%:1%)/ET3(5)/ET2:Liq(25.50%:50%)/Yb(1)/Al(50)

### Comparative 3-24

The organic EL device of Comparative 3-24 was produced in the same manner as in Example 3-24 except that the film thickness of the second and third anode side organic layers was changed from that in Example 3-24 to those in Comparative 3-24, as shown in Table 21.

TABLE 21

| | Anode Side Organic Layers | | | | | | | | | | | | |
|---|---|---|---|---|---|---|---|---|---|---|---|---|---|
| | First Anode | | | | | | | | | | | | |
| | Side Organic | | Second Anode Side | | | Third Anode Side | | | | | | | |
| | Layer | | Organic Layer | | | Organic Layer | | | Refractive | Film | | | |
| | | Film | | Film | Re- | | Film | Re- | Index | Thick- | | | |
| | Com- | Thick- | Com- | Thick- | fractive | Com- | Thick- | fractive | Difference | ness | Device Performance | | |
| | pound | ness | pound | ness | Index | pound | ness | Index | NM₂ − | Ratio | Voltage | EQE | LT95 |
| | Name | [nm] | Name | [nm] | NM₂ | Name | [nm] | NM₃ | NM₃ | TL₃/TL₂ | [V] | [%] | [hr] |
| Example | HT-70 | 10 | HT-70 | 45 | 1.95 | HT-95 | 45 | 1.80 | 0.15 | 1.00 | 4.4 | 10.8 | 47 |
| 3-24 | and HA1 | | | | | | | | | | | | |
| Comparative | HT-70 | 10 | HT-70 | 80 | 1.95 | HT-95 | 10 | 1.80 | 0.15 | 0.13 | 3.8 | 9.2 | 30 |
| 3-24 | and HA1 | | | | | | | | | | | | |

### Example 4-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 80 nm.

After the glass substrate having the transparent electrode line was cleaned, the glass substrate was mounted on a substrate holder of a vacuum evaporation apparatus. First, the compound HT-19 and the compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-19 and the compound HA1 in the first anode side organic layer were 97 mass % and 3 mass %, respectively.

The compound HT-19 was vapor-deposited on the first anode side organic layer to form a 24-nm-thick second anode side organic layer (occasionally also referred to as a first hole transporting layer).

The compound HT-16 was vapor-deposited on the second anode side organic layer to form a 40-nm-thick third anode side organic layer (occasionally also referred to as an electron blocking layer).

The first hole transporting zone including the first anode side organic layer, the second anode side organic layer, and the third anode side organic layer was formed as described above.

The compound BH2 (host material) and the compound BD (emitting compound) were co-deposited on the third anode side organic layer to form a 15-nm-thick emitting layer, thereby forming the first emitting region. The concentrations of the compound BH2 and the compound BD in the emitting layer were 99 mass % and 1 mass %, respectively.

Subsequently, the compound ET3 was vapor-deposited on the emitting layer of the first emitting region to form a 5-nm-thick first electron transporting layer (also referred to as a hole blocking layer), and the compound ET4 was vapor-deposited on the first electron transporting layer to form a 10-nm-thick second electron transporting layer, thereby forming a first electron transporting zone including the first electron transporting layer and the second electron transporting layer.

The first emitting unit including the first hole transporting zone, the first emitting region, and the first electron transporting zone was formed as described above.

Next, the first charge generating unit including a first N layer and a first P layer was formed on the first emitting unit. First, a compound ET5 and Li were co-deposited on the second electron transporting layer to form a 10-nm-thick first N layer. The concentrations of the compound ET5 and Li in the first N layer were 96 mass % and 4 mass %, respectively.

Next, the compounds HT-19 and HA1 were co-deposited on the first N layer to form an 8-nm-thick first P layer. The concentrations of the compound HT-19 and the compound HA1 in the first P layer were 97 mass % and 3 mass %, respectively.

The first charge generating unit was formed as described above.

Subsequently, the second emitting unit including the hole transporting layer, the second emitting region (red phosphorescent layer and green phosphorescent layer), and the second electron transporting zone (first electron transporting layer and second electron transporting layer) was formed on the first charge generating unit.

First, in the second emitting unit, the compound HT-16 was vapor-deposited on the first P layer of the first charge generating unit to form a 13-nm-thick hole transporting layer.

Next, a compound PRH1 (phosphorescent host material) and a phosphorescent compound PR_{D1} were co-deposited on the hole transporting layer to form an 8-nm-thick red phosphorescent layer. The concentrations of the compound PRH1 and the compound PR_{D1} in the red phosphorescent layer were 96 mass % and 4 mass %, respectively.

Next, a compound PGH1 (phosphorescent host material) and a phosphorescent compound PGD1 were co-deposited on the red phosphorescent layer to form a 40-nm-thick green phosphorescent layer. The concentrations of the compound PGH1 and the compound PGD1 in the green phosphorescent layer were 97 mass % and 3 mass %, respectively. In the second emitting unit, the second emitting region including the red phosphorescent layer and the green phosphorescent layer was formed as described above.

Subsequently, in the second emitting unit, the compound ET3 was vapor-deposited on the green phosphorescent layer to form a 5-nm-thick first electron transporting layer (also referred to as a hole blocking layer), and the compound ET4 was vapor-deposited on the first electron transporting layer to form a 20-nm-thick second electron transporting layer, thereby forming a second electron transporting zone including the first electron transporting layer and the second electron transporting layer.

The second emitting unit was formed as described above.

Next, the second charge generating unit including a second N layer and a second P layer was formed on the second emitting unit. First, the compound ET5 and Li were co-deposited on the second electron transporting layer of the second emitting unit to form a 20-nm-thick second N layer. The concentrations of the compound ET5 and Li in the second N layer were 96 mass % and 4 mass %, respectively.

Next, the compounds HT-19 and HA1 were co-deposited on the second N layer to form a 25-nm-thick second P layer. The concentrations of the compound HT-19 and the compound HA1 in the second P layer were 97 mass % and 3 mass %, respectively.

The second charge generating unit was formed as described above.

Subsequently, the third emitting unit including the third hole transporting zone (second anode side organic layer and third anode side organic layer), the third emitting region, and a third electron transporting zone (first electron transporting layer and second electron transporting layer) was formed on the second charge generating unit.

First, the compound HT-19 was vapor-deposited on the second P layer of the second charge generating unit to form a 56-nm-thick second anode side organic layer.

Next, the compound HT-16 was vapor-deposited on the second anode side organic layer to form a 52-nm-thick third anode side organic layer.

In the third emitting unit, the third hole transporting zone including the second anode side organic layer and the third anode side organic layer was formed as described above.

In the third emitting unit, the compound BH2 (host material) and the compound BD (emitting compound) were co-deposited on the third anode side organic layer to form a 20-nm-thick emitting layer, thereby forming the third emitting region. The concentrations of the compound BH2 and the compound BD in the emitting layer of the third emitting region were 99 mass % and 1 mass %, respectively.

Subsequently, in the third emitting unit, the compound ET3 was vapor-deposited on the emitting layer of the third emitting region to form a 5-nm-thick first electron transporting layer (also referred to as a hole blocking layer), and the compound ET4 and Liq were co-deposited on the first electron transporting layer to form a 15-nm-thick second electron transporting layer. The concentrations of the compound ET4 and Liq in the second electron transporting layer were 50 mass % and 50 mass %, respectively. Liq is an abbreviation of (8-quinolinolato)lithium.

Next, in the third emitting unit, Ytterbium (Yb) was vapor-deposited on the second electron transporting layer to form a 1-nm-thick electron injecting layer.

In the third emitting unit, the third electron transporting zone including the first electron transporting layer, the second electron transporting layer, and the electron injecting layer was formed as described above.

The third emitting unit was formed as described above.

Next, metal (Al) was vapor-deposited on the electron injecting layer of the third emitting unit to form an 80-nm-thick cathode.

A bottom-emission white organic EL device was produced as described above.

A device arrangement of the organic EL device in Example 4-1 is roughly shown as follows.
ITO(80)/HT-19:HA1(10.97%:3%)/HT-19(24)/HT-16(40)/BH2:BD(15.99%:1%)/ET3(5)/ET4(10)/ET5:Li(10.96%:4%)/HT-19:HA1(8.97%:3%)/HT-16(13)/PRH1:PR_{D1}(8.96%:4%)/PGH1:PGD1(40.97%:3%)/ET3(5)/ET4(20)/ET5:Li(20.96%:4%)/HT-19:HA1(25.97%:3%)/HT-19(56)/HT-16(52)/BH2:BD(20.99%:1%)/ET3(5)/ET4:Liq(15.50%:50%)/Yb(1)/Al(80)

Numerals in parentheses represent a film thickness (unit: nm).

Regarding the device arrangement of the organic EL device in Example 4-1, the numerals (97%:3%) represented by percentage in the same parentheses indicate a ratio (mass %) between the compound HT-19 and the compound HA1 in the first anode side organic layer or the first P layer or a ratio (mass %) between the compound PGH1 and the compound PGD1 in the green phosphorescent layer, the numerals (99%:1%) represented by percentage in the same parentheses indicate a ratio (mass %) between the compound BH2 and the compound BD in the emitting layer, the numerals (96%:4%) represented by percentage in the same parentheses indicate a ratio (mass %) between the compound ET5 and Li in the first N layer or a ratio (mass %) between the compound PRH1 and the compound PR_{D1} in the red phosphorescent layer, and the numerals (50%:50%) represented by percentage in the same parentheses indicate a ratio (mass %) between the compound ET4 and Liq in the electron injecting layer. Similar notations apply to the description below.

### Comparative 4-1

The organic EL device of Comparative 4-1 was produced in the same manner as in Example 4-1 except that the second anode side organic layer in the first emitting unit was formed to have a film thickness of 59 nm in Comparative 4-1, the third anode side organic layer in the first emitting unit was formed to have a film thickness of 5 nm in Comparative 4-1, the first P layer in the first charge generating unit was formed to have a film thickness of 16 nm in Comparative 4-1, the hole transporting layer in the second emitting unit was formed to have a film thickness of nm in Comparative 4-1, the second anode side organic layer in the third emitting unit was formed to have a film thickness of 100 nm in Comparative 4-1, and the third anode side organic layer was formed to have a film thickness of 5 nm in Comparative 4-1.

A device arrangement of the organic EL device in Comparative 4-1 is roughly shown as follows.
ITO(80)/HT-19:HA1(10.97%:3%)/HT-19(59)/HT-16(5)/BH2:BD(15.99%:1%)/ET3(5)/ET4(10)/ET5:Li(10.96%:4%)/HT-19:HA1(16.97%:3%)/HT-16(5)/PRH1:PR_{D1}(8.96%:4%)/PGH1:PGD1(40.97%:3%)/ET3(5)/ET4(10)/HT5:HA1 (25.97%:3%)/HT-19(100)/HT-16(5)/BH2:BD(20.99%:1%)/ET3(5)/ET4:Liq(15.50%:50%)/Yb(1)/Al(80)

### Evaluation of Organic EL Devices

The organic EL devices produced in Example 4-1 and Comparative 4-1 were evaluated as follows. Voltage was applied to the organic EL device such that a current density was 10 mA/cm², where spectral radiance spectrum was measured by a spectroradiometer CS-2000A (produced by Konica Minolta, Inc.). Measurement was performed by using a peak intensity at 460 nm as a peak intensity of blue emission, a peak intensity at 530 nm as a peak intensity of green emission, and a peak intensity at 620 nm as a peak intensity of red emission in the obtained spectral-radiance spectra, and comparison between the peak intensities was performed. Table 22 shows the peak intensity of each color in Example 4-1 on the condition that the peak intensity of each color in Comparative 4-1 was set to 100%.

TABLE 22

| | Peak intensity | | |
|---|---|---|---|
| | Blue | Green | Red |
| Comp. 4-1 | 100% | 100% | 100% |
| Ex. 4-1 | 135% | 117% | 106% |

### Example 5-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-77 and the compound HA1 were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-77 and the compound HA1 in the first anode side organic layer were 97 mass % and 3 mass %, respectively.

The compound HT-77 was vapor-deposited on the first anode side organic layer to form a 40-nm-thick second anode side organic layer (occasionally also referred to as a first hole transporting layer).

A compound HT-93 was vapor-deposited on the second anode side organic layer to form a 35-nm-thick third anode side organic layer (occasionally also referred to as a second hole transporting layer).

A compound HT-95 was vapor-deposited on the third anode side organic layer to form a 10-nm-thick fourth anode side organic layer (occasionally also referred to as an electron blocking layer).

The compound BH2 (host material) and the compound BD (emitting compound) were co-deposited on the fourth anode side organic layer so that a ratio of the compound BD accounted for 1 mass %, thereby forming a 20-nm-thick emitting layer.

Next, the compound ET1 was vapor-deposited on the emitting layer to form a 5-nm-thick first electron transporting layer (also referred to as a hole blocking layer (HBL)).

The compound ET2 and the compound Liq were co-deposited on the first electron transporting layer to form a 25-nm-thick second electron transporting layer (ET). The ratios of the compound ET2 and the compound Liq in the second electron transporting layer were 50 mass % and 50 mass %, respectively.

Ytterbium (Yb) was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 5-1 is roughly shown as follows.
ITO(130)/HT-77:HA1(10.97%:3%)/HT-77(40)/HT-93(35)/HT-95(10)/BH2:BD(20.99%:1%)/ET1(5)/ET2:Liq(25.50%:50%)/Yb(1)/Al(80)

### Example 5-2 and Examples 5-4 to 5-7

The organic EL devices of Examples 5-2 and 5-4 to 5-7 were respectively produced in the same manner as in Example 5-1 except that the compound HT-93 used for forming the third anode side organic layer in Example 5-1 and the compound HT-95 used for forming the fourth anode side organic layer in Example 5-1 were changed to compounds shown in Table 23.

### Example 5-3

The organic EL device of Example 5-3 was produced in the same manner as in Example 5-1 except that the compound HT-77 used for forming the first and second anode side organic layers in Example 5-1, the compound HT-93 used for forming the third anode side organic layer in Example 5-1 and the compound HT-95 used for forming the fourth anode side organic layer in Example 5-1 were changed to compounds shown in Table 23.

### Comparative 5-1

The organic EL device of Comparative 5-1 was produced in the same manner as in Example 5-1 except that the film thickness of the second and third anode side organic layers was changed from those in Example 5-1 to those in Comparative 5-1 and the emitting layer was formed on the third anode side organic layer without forming the fourth anode side organic layer, as shown in Table 23.

### Comparative 5-2 and Comparatives 5-4 to 5-7

The organic EL devices of Comparative 5-2 and Comparatives 5-4 to 5-7 were respectively produced in the same manner as in Comparative 5-1 except that the compound HT-93 used for forming the third anode side organic layer in Comparative 5-1 was changed to compounds shown in Table 23, as shown in Table 23.

### Comparative 5-3

The organic EL device of Comparative 5-3 was produced in the same manner as in Comparative 5-1 except that the compound HT-77 used for forming the first and second anode side organic layers in Comparative 5-1 and the compound HT-93 used for forming the third anode side organic layer in Comparative 5-1 were changed to compounds shown in Table 23, as shown in Table 23.

TABLE 23

| | Anode Side Organic Layers | | | | | | | | | | | | | |
|---|---|---|---|---|---|---|---|---|---|---|---|---|---|---|
| | First Anode | | | | | | | | Fourth Anode | | | | | |
| | Side Organic | | Second Anode Side | | | Third Anode Side | | | Side Organic | | | | | |
| | Layer | | Organic Layer | | | Organic Layer | | | Layer | | Refractive | Film | | |
| | | Film | | Film | Re- | | Film | Re- | | Film | Index | Thick- | Device | |
| | Com- | Thick- | Com- | Thick- | fractive | Com- | Thick- | fractive | Com- | Thick- | Difference | ness | Performance | |
| | pound | ness | pound | ness | Index | pound | ness | Index | pound | ness | NM₂ − | Ratio | EQE | LT95 |
| | Name | [nm] | Name | [nm] | NM₂ | Name | [nm] | NM₃ | Name | [nm] | NM₃ | TL₃/TL₂ | [%] | [hr] |
| Ex. 5-1 | HT-77 | 10 | HT-77 | 40 | 1.97 | HT-93 | 35 | 1.79 | HT-95 | 10 | 0.18 | 0.88 | 12.5 | 153 |
| | and HA1 | | | | | | | | | | | | | |
| Comp. | HT-77 | 10 | HT-77 | 75 | 1.97 | HT-93 | 10 | 1.79 | — | — | 0.18 | 0.13 | 11.3 | 41 |
| 5-1 | and HA1 | | | | | | | | | | | | | |
| Ex. 5-2 | HT-77 | 10 | HT-77 | 40 | 1.97 | HT-34 | 35 | 1.79 | HT-48 | 10 | 0.18 | 0.88 | 12.3 | 120 |
| | and HA1 | | | | | | | | | | | | | |
| Comp. | HT-77 | 10 | HT-77 | 75 | 1.97 | HT-34 | 10 | 1.79 | — | — | 0.18 | 0.13 | 10.5 | 10 |
| 5-2 | and HA1 | | | | | | | | | | | | | |
| Ex. 5-3 | HT-19 | 10 | HT-19 | 40 | 1.96 | HT-33 | 35 | 1.77 | HT-40 | 10 | 0.19 | 0.88 | 12.8 | 200 |
| | and HA1 | | | | | | | | | | | | | |
| Comp. | HT-19 | 10 | HT-19 | 75 | 1.96 | HT-33 | 10 | 1.77 | — | — | 0.19 | 0.13 | 9.0 | 60 |
| 5-3 | and HA1 | | | | | | | | | | | | | |
| Ex. 5-4 | HT-77 | 10 | HT-77 | 40 | 1.97 | HT-42 | 35 | 1.82 | HT-43 | 10 | 0.15 | 0.88 | 12.4 | 165 |
| | and HA1 | | | | | | | | | | | | | |
| Comp. | HT-77 | 10 | HT-77 | 75 | 1.97 | HT-42 | 10 | 1.82 | — | — | 0.15 | 0.13 | 11.0 | 50 |
| 5-4 | and HA1 | | | | | | | | | | | | | |
| Ex. 5-5 | HT-77 | 10 | HT-77 | 40 | 1.97 | HT-44 | 35 | 1.80 | HT-45 | 10 | 0.17 | 0.88 | 12.8 | 130 |
| | and HA1 | | | | | | | | | | | | | |
| Comp. | HT-77 | 10 | HT-77 | 75 | 1.97 | HT-44 | 10 | 1.80 | — | — | 0.17 | 0.13 | 11.3 | 41 |
| 5-5 | and HA1 | | | | | | | | | | | | | |
| Ex. 5-6 | HT-77 | 10 | HT-77 | 40 | 1.97 | HT-46 | 35 | 1.81 | HT-41 | 10 | 0.16 | 0.88 | 12.4 | 162 |
| | and HA1 | | | | | | | | | | | | | |
| Comp. | HT-77 | 10 | HT-77 | 75 | 1.97 | HT-46 | 10 | 1.81 | — | — | 0.16 | 0.13 | 11.3 | 41 |
| 5-6 | and HA1 | | | | | | | | | | | | | |
| Ex. 5-7 | HT-77 | 10 | HT-77 | 40 | 1.97 | HT-47 | 35 | 1.81 | HT-17 | 10 | 0.16 | 0.88 | 12.4 | 170 |
| | and HA1 | | | | | | | | | | | | | |
| Comp. | HT-77 | 10 | HT-77 | 75 | 1.97 | HT-47 | 10 | 1.81 | — | — | 0.16 | 0.13 | 11.3 | 41 |
| 5-6 | and HA1 | | | | | | | | | | | | | |

### Evaluation of Compounds

### Singlet Energy S₁

A toluene solution of a measurement target compound at a concentration of

μmol/L was prepared and put in a quartz cell. An absorption spectrum (ordinate axis: absorption intensity, abscissa axis: wavelength) of the thus-obtained sample was measured at a normal temperature (300K). A tangent was drawn to the fall of the absorption spectrum close to the long-wavelength region, and a wavelength value λ_{edge} (nm) at an intersection of the tangent and the abscissa axis was assigned to a conversion equation (F2) below to calculate singlet energy.

$$Conversion Equation ( F 2 ) : {S}_{1} [ eV ] = 1239 \text{.85} / {λ}_{edge}$$

A spectrophotometer (U3310 produced by Hitachi, Ltd.) was used for measuring absorption spectrum.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Measurement of Maximum Fluorescence Peak Wavelength (FL-Peak)

A measurement target compound was dissolved in toluene at a concentration of 4.9×10⁻⁶ mol/L to prepare a toluene solution. Using a fluorescence spectrometer (spectrophotofluorometer F-7000 produced by Hitachi High-Tech Science Corporation), the toluene solution of the measurement target compound was excited at 390 nm, where a maximum fluorescence peak wavelength λ (unit: nm) was measured.

The maximum fluorescence peak wavelength λ of the compound BD was 452 nm.

### Energy Level HOMO of Highest Occupied Molecular Orbital

An energy level HOMO of a highest occupied molecular orbital was measured under atmosphere using a photoelectron spectroscope (“AC-3” produced by RIKEN KEIKI Co., Ltd.). Specifically, the material was irradiated with light and the amount of electrons generated by charge separation was measured to measure the energy level HOMO of the highest occupied molecular orbital of the compound.

### Hole Mobility μh

A hole mobility μh was measured using a mobility evaluation device produced by the following steps.

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film of ITO was 130 nm thick.

After the glass substrate was cleaned, the glass substrate was mounted on a substrate holder of a vacuum evaporation apparatus. First, the compound HA-2 was vapor-deposited on a surface of the glass substrate, where the transparent electrode line was provided, to cover the transparent electrode, thereby forming a 5-nm-thick hole injecting layer.

The compound HT-A was vapor-deposited on this formed hole injecting layer to form a 10-nm-thick hole transporting layer.

Subsequently, the compound Target to be measured for the hole mobility μh was vapor-deposited to form a 200-nm-thick measurement target layer.

Metal aluminum (Al) was vapor-deposited on this measurement target layer to form an 80-nm-thick metal cathode.

An arrangement of the mobility evaluation device above is roughly shown as follows.
ITO(130)/HA-2(5)/HT-A(10)/Target(200)/Al(80)

Numerals in parentheses represent a film thickness (nm).

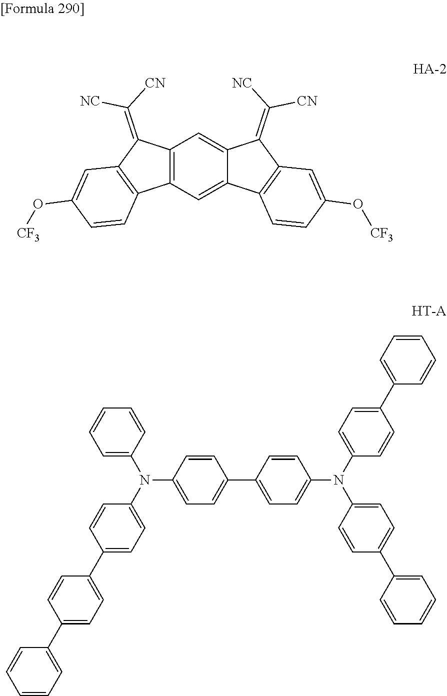 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

Subsequently, the hole mobility is measured by the following steps using the mobility evaluation device produced as described above.

The mobility evaluation device was set in an impedance measurement apparatus to perform an impedance measurement.

In the impedance measurement, a measurement frequency was swept from 1 Hz to 1 MHz. At this time, an alternating current amplitude of 0.1 V and a direct current voltage V were applied to the device.

A modulus M was calculated from a measured impedance Z using a relationship of a calculation formula (C1) below.

$$Calculation formula ( C 1 ) : M = j ωZ \qquad ( C1 )$$

In the calculation formula (C1), j is an imaginary unit whose square is −1 and w is an angular frequency [rad/s].

In a bode plot in which an imaginary part of the modulus M is represented by an ordinate axis and the frequency [Hz] is represented by an abscissa axis, an electrical time constant τ of the mobility evaluation device was obtained from a frequency fmax showing a peak using a calculation formula (C2) below.

$$Calcuation formula ( C 2 ) : ⊤ = 1 / ( 2 ⊤ ⊤ fmax ) \qquad ( C2 )$$

π in the calculation formula (C2) is a symbol representing a circumference ratio.

The hole mobility μh was calculated from a relationship of a calculation formula (C3) below using T.

$$Calculation formula ( C 3 ) : μ h = {d}^{2} / ( V ⊤ ) \qquad ( C3 )$$

d in the calculation formula (C3) is a total film thickness of organic thin film(s) forming the device. As in the arrangement of the mobility evaluation device, d=215 [nm] is satisfied.

The mobility herein is a value obtained in a case where a square root of an electric field intensity meets E^{1/2}=500 [V^{1/2}/cm^{1/2}]. The square root of the electric field intensity, E^{1/2}, can be calculated from a relationship of a calculation formula (C4) below.

$$Calculation formula ( C 4 ) : {E}^{1 / 2} = {V}^{1 / 2} / {d}^{1 / 2}$$

For the impedance measurement in Examples, a 1260 type by Solartron Analytical was used as the impedance measurement apparatus, and a 1296 type dielectric constant measurement interface by Solartron Analytical was used together therewith to enhance measurement accuracy.

In addition to the compounds used for producing the organic EL devices, values of physical properties of compounds HT-31, HT-32, and Ref-HT1 below were also measured. Table 24 shows measurement results of the values of physical properties.

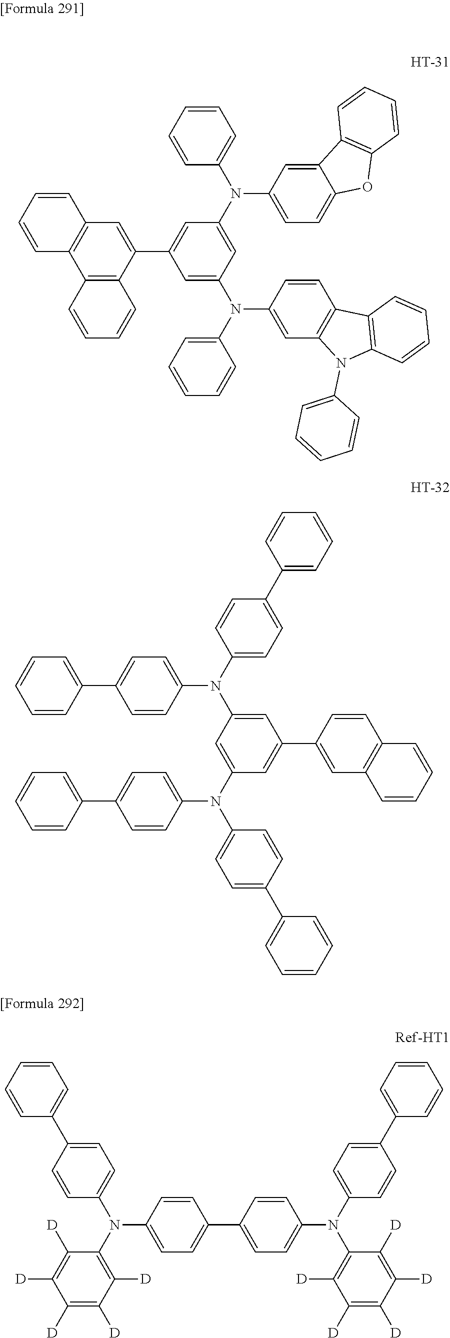 [SMILES: c1ccc(N(c2cc(-c3cc4ccccc4c4ccccc34)cc(N(c3ccccc3)c3ccc4c5ccccc5n(-c5ccccc5)c4c3)c2)c2ccc3oc4ccccc4c3c2)cc1 ; c1ccc(-c2ccc(N(c3ccc(-c4ccccc4)cc3)c3cc(-c4ccc5ccccc5c4)cc(N(c4ccc(-c5ccccc5)cc4)c4ccc(-c5ccccc5)cc4)c3)cc2)cc1 ; [2H]c1c([2H])c([2H])c(N(c2ccc(-c3ccccc3)cc2)c2ccc(-c3ccc(N(c4ccc(-c5ccccc5)cc4)c4c([2H])c([2H])c([2H])c([2H])c4[2H])cc3)cc2)c([2H])c1[2H]]

TABLE 24

| | | μh | HOMO |
|---|---|---|---|
| Compound | S₁[eV] | [cm²/Vs] | [eV] |
| HT-14 | 3.23 | 7.3 × 10⁻⁴ | −5.55 |
| HT-15 | 3.18 | 2.1 × 10⁻⁴ | −5.72 |
| HT-16 | 3.26 | 6.8 × 10⁻⁵ | −5.73 |
| HT-17 | 3.19 | 1.6 × 10⁻⁶ | −5.74 |
| HT-27 | 3.28 | 4.0 × 10⁻⁴ | −5.61 |
| HT-28 | 3.13 | 3.3 × 10⁻⁴ | −5.63 |
| HT-31 | 3.23 | 2.2 × 10⁻⁴ | — |
| HT-32 | 3.28 | — | −5.58 |
| Ref-HT1 | 3.12 | — | — |

### Refractive Index

The refractive index of the constituent material (compound) forming the organic layer was measured as follows.

A measurement target material was vacuum-deposited on a glass substrate to form a film having an approximately 50 nm thickness. Using a spectroscopic ellipsometer (M-2000UI, produced by J. A. Woollam Co., Inc. (US)), the obtained sample film was irradiated with incident light (from ultraviolet light through visible light to near-infrared light) every 5 degrees in a measurement angle range of 45 degrees to 75 degrees to measure change in a deflection state of the light reflected on the sample surface. In order to improve the measurement accuracy of the extinction coefficient, a transmission spectrum in a substrate normal direction (direction perpendicular to a surface of the substrate of the organic EL device) was also measured by M-2000UI. Similarly, the same measurement was performed also on the glass substrate on which no measurement target material was vapor-deposited. The obtained measurement information was fitted using analysis software (Complete EASE) produced by J. A. Woollam Co., Inc.

Refractive indices in an in-plane direction and a normal direction, extinction coefficients in the in-plane direction and the normal direction, and an order parameter of an organic film formed on the substrate were calculated under fitting conditions of using an anisotropic model rotationally symmetric about one axis and setting a parameter MSE indicating a mean square error in said analysis software to be 3.0 or less. A peak close to the long-wavelength region of the extinction coefficient (in-plane direction) was defined as S1, and the order parameter was calculated by a peak wavelength of S1. As fitting conditions for the glass substrate, an isotropic model was used.

Typically, a film formed by vacuum-depositing a low molecular material on the substrate is rotationally symmetric about one axis extending along the substrate normal direction. When an angle formed by the substrate normal direction and a molecular axis in a thin film formed on the substrate is defined as 6 and the extinction coefficients in a substrate parallel direction (Ordinary direction) and a substrate perpendicular direction (Extra-Ordinary direction) obtained by performing the variable-angle spectroscopic ellipsometry measurement on the thin film are respectively defined as ko and ke, S′ represented by a formula below is the order parameter.

$$\begin{matrix}S ’ = 1 - < cos 2 θ >= 2 ko / ( ke + 2 ko ) = 2 / 3 ( 1 - S ) \\ S = ( 1 / 2 ) < 3 cos 2 θ - 1 >= ( e - ko ) / ( ke + 2 ko )\end{matrix}$$

An evaluation method of the molecular orientation is a publicly known method, and details thereof are described in Organic Electronics, volume 10, page 127 (2009). Further, the method for forming the thin film is a vacuum deposition method.

The order parameter S′ obtained by the variable-angle spectroscopic ellipsometry measurement is 1.0 when all the molecules are oriented in parallel with the substrate. When molecules are random without being oriented, the order parameter S′ is 0.66.

Herein, a value at 2.7 eV in the substrate parallel direction (Ordinary direction), from among the values measured above, is defined as a refractive index of the measurement target material. The refractive index at 2.7 eV corresponds to the refractive index at 460 nm. Herein, the refractive index at 2.7 eV (460 nm) in the substrate parallel direction (Ordinary direction) may be referred to as n_{ORD}, and the refractive index at 2.7 eV (460 nm) in a substrate perpendicular direction (Extra-Ordinary direction) may be referred to as n_{EXT}.

When a layer was formed by a constituent material containing a plurality of compounds, a refractive index of the constituent material of the layer, the layer being a film formed by co-depositing the plurality of compounds as the measurement target material on the glass substrate or a film formed by vapor-depositing a mixture containing the plurality of compounds as the measurement target material, was measured using a spectroscopic ellipsometer in the same manner as above.

Tables 9 to 21, 23 and 25 show, for each Example and Comparative, constituent materials of the second and third anode side organic layers and a difference NM₂−NM₃ between a refractive index NM₂ of the constituent material contained in the second anode side organic layer and a refractive index NM₃ of the constituent material contained in the third anode side organic layer.

TABLE 25

| Second Anode Side | | Third Anode Side | | |
|---|---|---|---|---|
| Organic Layer | | Organic Layer | | Refractive |
| | Refractive | | Refractive | Index |
| Compound | Index | Compound | Index | Difference |
| Name | NM₂ | Name | NM₃ | NM₂ − NM₃ |
| HT-14 | 1.94 | HT-15 | 1.89 | 0.05 |
| HT-14 | 1.94 | HT-16 | 1.79 | 0.15 |
| HT-14 | 1.94 | HT-23 | 1.89 | 0.05 |
| HT-18 | 1.96 | HT-15 | 1.89 | 0.07 |
| HT-19 | 1.96 | HT-15 | 1.89 | 0.07 |
| HT-20 | 1.99 | HT-15 | 1.89 | 0.10 |
| HT-14 | 1.94 | HT-24 | 1.83 | 0.11 |
| HT-14 | 1.94 | HT-27 | 1.89 | 0.05 |
| HT-14 | 1.94 | HT-28 | 1.83 | 0.11 |
| HT-19 | 2.00 | HT-16 | 1.79 | 0.21 |
| HT-19 | 2.00 | HT-23 | 1.90 | 0.10 |

Table 26 shows compounds used for forming the hole transporting zone and a refractive index n_{ORD}, a refractive index n_{EXT}, and a difference n_{ORD}−n_{EXT} between the refractive index n_{ORD} and the refractive index n_{EXT} at 460 nm of each compound used for forming the hole transporting zone.

TABLE 26

| Compound | n_{ORD} | n_{EXT} | n_{ORD} − n_{EXT} |
|---|---|---|---|
| HT-14 | 1.94 | 1.72 | 0.22 |
| HT-15 | 1.89 | 1.76 | 0.13 |
| HT-16 | 1.79 | 1.74 | 0.05 |
| HT-20 | 1.99 | 1.70 | 0.29 |
| HT-33 | 1.77 | 1.76 | 0.01 |
| HT-34 | 1.79 | 1.78 | 0.01 |
| HT-85 | 1.83 | 1.77 | 0.06 |
| HT-93 | 1.79 | 1.78 | 0.01 |

### EXPLANATION OF CODES

1,1A, 1B,1C . . . organic EL device, 10,11,12,13 . . . organic layer, 100A,100B,100C,100D . . . organic EL display device, 10B,11B,12B,13B . . . blue-emitting organic EL device, 10G . . . green-emitting organic EL device, 10R . . . red-emitting organic EL device, 2,2A . . . substrate, 3 . . . anode, 4 . . . cathode, 5 . . . emitting region, 50 . . . emitting layer, 50B . . . blue emitting layer, 51 . . . first emitting layer, 52 . . . second emitting layer, 53 . . . green emitting layer, 531 . . . green organic layer, 54 . . . red emitting layer, 541 . . . red organic layer, 5B . . . blue emitting region, 61,61A . . . first anode side organic layer, 62,62A . . . second anode side organic layer, 63,63A . . . third anode side organic layer, 64,64A . . . fourth anode side organic layer, 8 . . . electron transporting layer, 9 . . . electron injecting layer

1. An organic electroluminescence device, comprising:
a cathode;
an anode;
an emitting region provided between the cathode and the anode; and
a hole transporting zone provided between the anode and the emitting region, wherein
the emitting region comprises at least one emitting layer,
the hole transporting zone comprises at least a first anode side organic layer, a second anode side organic layer, and a third anode side organic layer,
the first anode side organic layer, the second anode side organic layer, and the third anode side organic layer are arranged between the anode and the emitting region in this order from a side close to the anode,
the first anode side organic layer comprises a first organic material and a second organic material,
the first organic material and the second organic material are different from each other,
a content of the second organic material in the first anode side organic layer is less than 50 mass %,
the second anode side organic layer comprises at least one compound selected from the group consisting of a compound represented by a formula (C1) below and a compound represented by a formula (C3) below,
the third anode side organic layer comprises a compound represented by the formula (C1),
the second anode side organic layer comprises at least one compound different from the compound comprised in the third anode side organic layer,
a difference NM₂−NM₃ between a refractive index NM₂ of a constituent material comprised in the second anode side organic layer and a refractive index NM₃ of a constituent material comprised in the third anode side organic layer satisfies a relationship of a numerical formula (Numerical Formula N1) below, and
the third anode side organic layer has a film thickness of 20 nm or more,
$${NM}_{2} - {NM}_{3} \geq 0.05 \qquad ( Numerical Formula N 1 )$$ 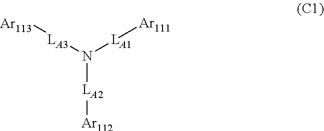
where, in the formula (C1):
L_{A1}, L_{A2}, and L_{A3} are each independently a single bond, a substituted or unsubstituted arylene group having 6 to 50 ring carbon atoms, or a substituted or unsubstituted divalent heterocyclic group having 5 to 50 ring atoms;
Ar₁₁₁, Ar₁₁₂, and Ar₁₁₃ are each independently a substituted or unsubstituted aryl group having 6 to 50 ring carbon atoms, a substituted or unsubstituted heterocyclic group having to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different, 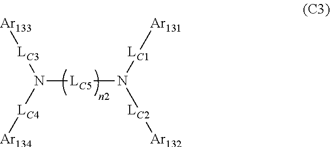
where, in the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C}2, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C}2 are present, the plurality of R_{C}2 are mutually the same or different; and
when a plurality of R_{C3} are present, the plurality of R_{C3} are mutually the same or different, and
in the compound represented by the formula (C1) and the compound represented by the formula (C3), the substituent for the “substituted or unsubstituted” group is not a group represented by —N(R_{C6})(R_{C7}), and R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

2. The organic electroluminescence device according to claim 1, wherein a first amino group represented by a formula (C3-1) below and a second amino group represented by a formula (C3-2) below in the compound represented by the formula (C3) are an identical group, 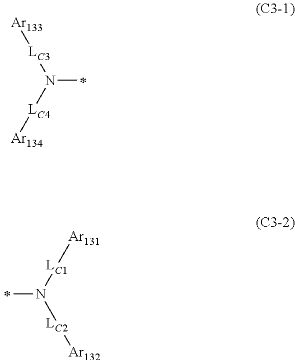
where, in the formulae (C3-1) and (C3-2), * each represent a bonding position to L_{C5}.

3. The organic electroluminescence device according to claim 1, wherein the third anode side organic layer has a film thickness in a range from 20 nm to 60 nm.

4. The organic electroluminescence device according to claim 1, wherein a distance from an interface at a side close to the anode of the third anode side organic layer to an interface at a side close to the anode of the emitting layer disposed closest to the anode in the emitting region is 30 nm or more.

5. The organic electroluminescence device according to claim 1, wherein the difference NM₂−NM₃ between the refractive index NM₂ of the constituent material comprised in the second anode side organic layer and the refractive index NM₃ of the constituent material comprised in the third anode side organic layer satisfies a relationship of a numerical formula (Numerical Formula N3) below,
$${NM}_{2} - {NM}_{3} \geq 0.0 75. \qquad ( Numerical Formula N 3 )$$

6. The organic electroluminescence device according to claim 1, wherein the difference NM₂−NM₃ between the refractive index NM₂ of the constituent material comprised in the second anode side organic layer and the refractive index NM₃ of the constituent material comprised in the third anode side organic layer satisfies a relationship of a numerical formula (Numerical Formula N2) below,
$${NM}_{2} - {NM}_{3} \geq 0 \text{.10} . \qquad ( Numerical Formula N 2 )$$

7. The organic electroluminescence device according to claim 1, wherein
the compound comprised in the second anode side organic layer comprises a plurality of compounds, and
all the compounds comprised in the second anode side organic layer are different from the compound comprised in the third anode side organic layer.

8-9. (canceled)

10. The organic electroluminescence device according to claim 1, wherein the emitting region comprises a fluorescent substance and an organic compound.

11. The organic electroluminescence device according to claim 1, wherein the emitting region comprises a single emitting layer.

12. The organic electroluminescence device according to claim 1, wherein the emitting region consists of a single emitting layer.

13. The organic electroluminescence device according to claim 1, wherein the emitting region consists of two emitting layers.

14. The organic electroluminescence device according to claim 1, further comprising a fourth anode side organic layer, wherein
the fourth anode side organic layer is provided between the third anode side organic layer and the emitting region.

15. The organic electroluminescence device according to claim 14, wherein a total of a film thickness of the first anode side organic layer, a film thickness of the second anode side organic layer, the film thickness of the third anode side organic layer, and a film thickness of the fourth anode side organic layer is 150 nm or less.

16. The organic electroluminescence device according to claim 1, wherein the third anode side organic layer and the emitting region are in direct contact with each other.

17. The organic electroluminescence device according to claim 1, wherein a ratio of the film thickness of the third anode side organic layer to a film thickness of the second anode side organic layer satisfies a relationship of a numerical formula (Numerical Formula A3) below,
$$0.75 < T {L}_{3} / {TL}_{2} < 3. \qquad ( Numerical Formula A 3 )$$
where TL₂ is a film thickness of the second anode side organic layer, TL₃ is a film thickness of the third anode side organic layer, and a unit of the film thickness is denoted by nm.

18. The organic electroluminescence device according to claim 1, wherein a total of a film thickness of the second anode side organic layer and the film thickness of the third anode side organic layer is 100 nm or more.

19. The organic electroluminescence device according to claim 1, wherein a total of a film thickness of the first anode side organic layer, a film thickness of the second anode side organic layer, and the film thickness of the third anode side organic layer is 150 nm or less.

20. The organic electroluminescence device according to claim 1, wherein
the third anode side organic layer comprises a third hole transporting zone material, a hole mobility of the third hole transporting zone material h(cHT3) is larger than 1.0×10⁻⁵ cm²/Vs, and
an energy level of a highest occupied molecular orbital of the third hole transporting zone material HOMO(cHT3) is −5.6 eV or less.

21. The organic electroluminescence device according to claim 1, wherein
the second anode side organic layer comprises a second hole transporting zone material,
the third anode side organic layer comprises a third hole transporting zone material,
the second hole transporting zone material and the third hole transporting zone material are different compounds,
a hole mobility of the second hole transporting zone material h(cHT2) is larger than 1.0×10⁻⁴ cm²/Vs,
a hole mobility of the third hole transporting zone material h(cHT3) is larger than 1.0×10⁻⁵ cm²/Vs, and
an energy level of a highest occupied molecular orbital of the second hole transporting zone material HOMO(cHT2) and an energy level of a highest occupied molecular orbital of the third hole transporting zone material HOMO(cHT3) satisfy a relationship of a numerical formula (Numerical Formula B1) below,
$$HOMO ( c H T 2 ) < H O M O ( cHT 3 ) . \qquad ( Numerical Formula B 1 )$$

22. The organic electroluminescence device according to claim 1, wherein
the third anode side organic layer comprises a third hole transporting zone material, and
a singlet energy of the third hole transporting zone material is larger than 3.12 eV.

23. The organic electroluminescence device according to claim 1, wherein the third anode side organic layer comprises at least one compound selected from the group consisting of a compound represented by a formula (cHT3-11), a compound represented by a formula (cHT3-2), a compound represented by a formula (cHT3-31), and a compound represented by a formula (cHT3-4) below, 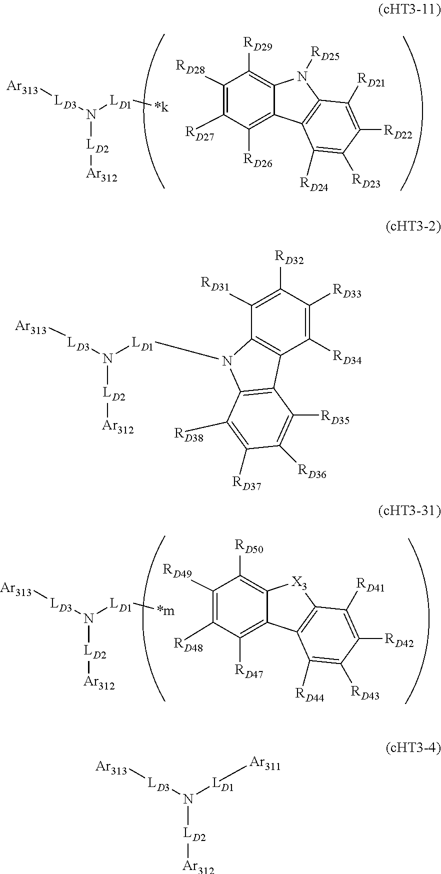
where, in the formulae (cHT3-11), (cHT3-2), (cHT3-31), and (cHT3-4):
Ar₃₁₁ is a group represented by one of formulae (1-a), (1-b), (1-c), and (1-d) below;
Ar₃₁₂ and Ar₃₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{D1}, L_{D2}, and L_{D3} are each independently a single bond, a substituted or unsubstituted arylene group having 6 to 50 ring carbon atoms, or a substituted or unsubstituted divalent heterocyclic group having 5 to 50 ring atoms;
one of R_{D26} to R_{D29} is a single bond with L_{D1}, and *k represents a bonding position;
at least one combination of adjacent two or more of R_{D21} to R_{D24} and R_{D26} to R_{D29} not being the single bond with L_{D1} are mutually bonded to form a substituted or unsubstituted monocyclic ring, mutually bonded to form a substituted or unsubstituted fused ring, or not mutually bonded;
at least one combination of adjacent two or more of R_{D31} to R_{D3}8 are mutually bonded to form a substituted or unsubstituted monocyclic ring, mutually bonded to form a substituted or unsubstituted fused ring, or not mutually bonded;
one of R_{D47} to R_{D50} is a single bond with L_{D1}, and *m represents a bonding position;
at least one combination of adjacent two or more of R_{D41} to R_{D44} and R_{D47} to R_{D50} not being the single bond with L_{D1} are mutually bonded to form a substituted or unsubstituted monocyclic ring, mutually bonded to form a substituted or unsubstituted fused ring, or not mutually bonded;
X₃ is an oxygen atom, a sulfur atom, or C(R_{D45})(R_{D46});
a combination of R_{D45} and R_{D46} are mutually bonded to form a substituted or unsubstituted monocyclic ring, mutually bonded to form a substituted or unsubstituted fused ring, or not mutually bonded;
R_{D25}, and R_{D21} to R_{D24}, R_{D26} to R_{D29}, R_{D31} to R_{D38}, and R_{D41} to R_{D50} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
R₉₀₁ to R₉₀₄ in the compounds represented by the formulae (cHT3-11), (cHT3-2), (cHT3-31), and (cHT3-4) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different, 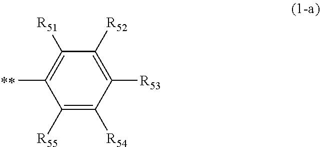
where, in the formula (1-a):
none of a combination(s) of adjacent two or more of R₅₁ to R₅₅ are bonded to each other;
R₅₁ to R₅₅ are each independently a hydrogen atom, or a substituted or unsubstituted alkyl group having 1 to 6 carbon atoms; and
*represents a bonding position to L_{D1}, 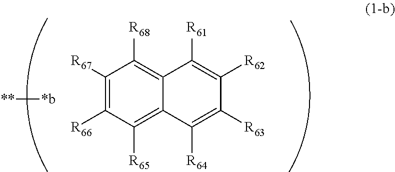
where, in the formula (1-b):
one of R₆₁ to R₆₈ is a single bond with *b;
none of a combination(s) of adjacent two or more of R₆₁ to R₆₈ not being the single bond with *b are bonded to each other;
R₆₁ to R₆₈ not being the single bond with *b are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}, 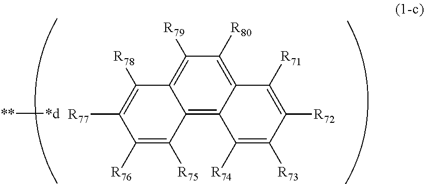
where, in the formula (1-c):
one of R₇₁ to R₈₀ is a single bond with *d;
none of a combination(s) of adjacent two or more of R₇₁ to R₈₀ not being the single bond with *d are bonded to each other;
R₇₁ to R₈₀ not being the single bond with *d are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}, 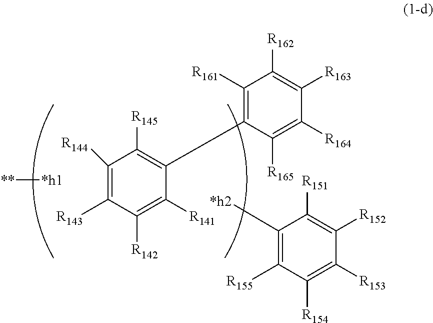
where, in the formula (1-d):
one of R₁₄₁ to R₁₄₅ is a single bond with *h1, and another one of R₁₄₁ to R₁₄₅ is a single bond with *h2;
none of a combination(s) of adjacent two or more of R₁₄₁ to R₁₄₅ not being the single bond with *h1 and not being the single bond with *h2 are bonded to each other;
at least one combination of adjacent two or more of R₁₅₁ to R₁₅₅ are mutually bonded to form a substituted or unsubstituted monocyclic ring, mutually bonded to form a substituted or unsubstituted fused ring, or not mutually bonded;
at least one combination of adjacent two or more of R₁₆₁ to R₁₆₅ are mutually bonded to form a substituted or unsubstituted monocyclic ring, mutually bonded to form a substituted or unsubstituted fused ring, or not mutually bonded;
R₁₄₁ to R₁₄₅ not being the single bond with *h1 and not being the single bond with *h2 as well as R₁₅₁ to R₁₅₅ and R₁₆₁ to R₁₆₅ forming neither the substituted or unsubstituted monocyclic ring nor the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}.

24. The organic electroluminescence device according to claim 1, wherein the second anode side organic layer comprises at least one compound selected from the group consisting of a compound represented by a formula (cHT2-1), a compound represented by a formula (cHT2-2), and a compound represented by a formula (cHT2-3) below, 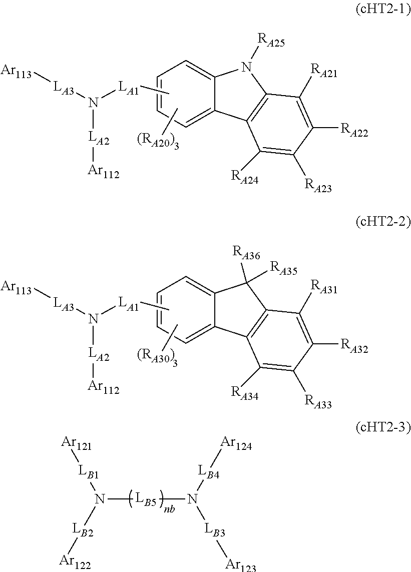
where, in the formulae (cHT2-1), (cHT2-2), and (cHT2-3):
Ar₁₁₂, Ar₁₁₃, Ar₁₂₁, Ar₁₂₂, Ar₁₂₃, and Ar₁₂₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{A1}, L_{A2}, L_{A3}, L_{B1}, L_{B2}, L_{B3}, and L_{B4} are each independently a single bond, a substituted or unsubstituted arylene group having 6 to 50 ring carbon atoms, or a substituted or unsubstituted divalent heterocyclic group having 5 to 50 ring atoms;
nb is 1, 2, 3 or 4;
when nb is 1, L_{B5} is a substituted or unsubstituted arylene group having 6 to 50 ring carbon atoms, or a substituted or unsubstituted divalent heterocyclic group having 5 to 50 ring atoms;
when nb is 2, 3, or 4, a plurality of L_{B5} are mutually the same or different;
when nb is 2, 3, or 4, a plurality of L_{B5} are mutually bonded to form a substituted or unsubstituted monocyclic ring, mutually bonded to form a substituted or unsubstituted fused ring, or not mutually bonded;
L_{B5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
a combination of R_{A35} and R_{A36} are mutually bonded to form a substituted or unsubstituted monocyclic ring, mutually bonded to form a substituted or unsubstituted fused ring, or not mutually bonded;
R_{A25}, and R_{A35} and R_{A36} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
at least one combination of adjacent two or more of R_{A20} to R_{A24} are mutually bonded to form a substituted or unsubstituted monocyclic ring, mutually bonded to form a substituted or unsubstituted fused ring, or not mutually bonded;
at least one combination of adjacent two or more of R_{A30} to R_{A34} are mutually bonded to form a substituted or unsubstituted monocyclic ring, mutually bonded to form a substituted or unsubstituted fused ring, or not mutually bonded;
R_{A20} to R_{A24} and R_{A30} to R_{A34} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a plurality of R_{A20} are mutually the same or different;
a plurality of R_{A30} are mutually the same or different;
R₉₀₁ to R₉₀₄ in the compounds represented by the formulae (cHT2-1), (cHT2-2), and (cHT2-3) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

25. The organic electroluminescence device according to claim 23, wherein the second anode side organic layer comprises at least one compound selected from the group consisting of a compound represented by a formula (cHT2-1), a compound represented by a formula (cHT2-2), and a compound represented by a formula (cHT2-3) below, 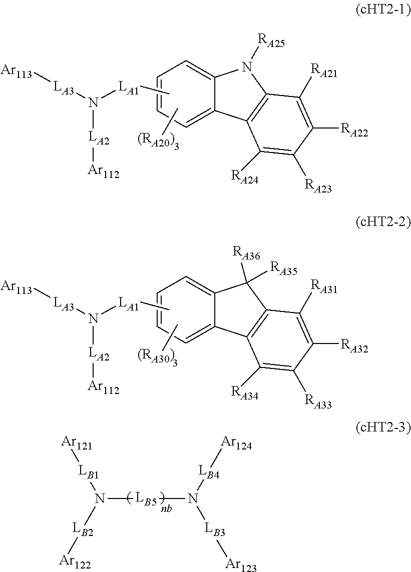
where, in the formulae (cHT2-1), (cHT2-2), and (cHT2-3):
Ar₁₁₂, Ar₁₁₃, Ar₁₂₁, Ar₁₂₂, Ar₁₂₃, and Ar₁₂₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{A1}, L_{A2}, L_{A3}, L_{B1}, L_{B2}, L_{B3}, and L_{B4} are each independently a single bond, a substituted or unsubstituted arylene group having 6 to 50 ring carbon atoms, or a substituted or unsubstituted divalent heterocyclic group having 5 to 50 ring atoms;
nb is 1, 2, 3 or 4;
when nb is 1, L_{B5} is a substituted or unsubstituted arylene group having 6 to 50 ring carbon atoms, or a substituted or unsubstituted divalent heterocyclic group having 5 to 50 ring atoms;
when nb is 2, 3, or 4, a plurality of L_{B5} are mutually the same or different;
when nb is 2, 3, or 4, a plurality of L_{B5} are mutually bonded to form a substituted or unsubstituted monocyclic ring, mutually bonded to form a substituted or unsubstituted fused ring, or not mutually bonded;
L_{B5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
a combination of R_{A35} and R_{A36} are mutually bonded to form a substituted or unsubstituted monocyclic ring, mutually bonded to form a substituted or unsubstituted fused ring, or not mutually bonded;
R_{A25}, and R_{A35} and R_{A36} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
at least one combination of adjacent two or more of R_{A20} to R_{A24} are mutually bonded to form a substituted or unsubstituted monocyclic ring, mutually bonded to form a substituted or unsubstituted fused ring, or not mutually bonded;
at least one combination of adjacent two or more of R_{A30} to R_{A34} are mutually bonded to form a substituted or unsubstituted monocyclic ring, mutually bonded to form a substituted or unsubstituted fused ring, or not mutually bonded;
R_{A20} to R_{A24} and R_{A30} to R_{A34} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a plurality of R_{A20} are mutually the same or different;
a plurality of R_{A30} are mutually the same or different;
R₉₀₁ to R₉₀₄ in the compounds represented by the formulae (cHT2-1), (cHT2-2), and (cHT2-3) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

26. The organic electroluminescence device according to claim 1, wherein the compound comprised in the second anode side organic layer is a monoamine compound.

27. The organic electroluminescence device according to claim 1, further comprising:
two or more emitting units; and
at least one charge generating layer disposed between the two or more emitting units, wherein
at least one of the two or more emitting units is a first emitting unit comprising the hole transporting zone as a first hole transporting zone and the emitting region as a first emitting region.

28. An organic electroluminescence display device, comprising:
an anode and a cathode arranged opposite each other;
a blue-emitting organic EL device as a blue pixel; a green-emitting organic EL device as a green pixel; and a red-emitting organic EL device as a red pixel, wherein
the blue pixel comprises the organic electroluminescence device according to claim 1 as the blue-emitting organic EL device,
the green-emitting organic EL device comprises a green emitting region provided between the anode and the cathode,
the red-emitting organic EL device comprises a red emitting region provided between the anode and the cathode, and
the first anode side organic layer, the second anode side organic layer, and the third anode side organic layer are provided between the anode and the emitting region of the blue-emitting organic EL device, the green emitting region, and the red emitting region in a shared manner across the blue-emitting organic EL device, the green-emitting organic EL device, and the red-emitting organic EL device.

29. An organic electroluminescence display device, comprising:
an anode and a cathode arranged opposite each other;
a blue-emitting organic EL device as a blue pixel; a green-emitting organic EL device as a green pixel; and a red-emitting organic EL device as a red pixel, wherein
the blue pixel, the green pixel, and the red pixel respectively respectively comprise, as the blue-emitting organic EL device, the green-emitting organic EL device, and the red-emitting organic EL device, the organic electroluminescence device according to claim 1,
the emitting region in the blue-emitting organic EL device is a blue emitting region provided between the anode and the cathode,
the emitting region in the green-emitting organic EL device is a green emitting region provided between the anode and the cathode,
the emitting region in the red-emitting organic EL device is a red emitting region provided between the anode and the cathode, and
the first anode side organic layer, the second anode side organic layer, and the third anode side organic layer are provided between the anode and the blue emitting region, the green emitting region, and the red emitting region in a shared manner across the blue-emitting organic EL device, the green-emitting organic EL device, and the red-emitting organic EL device.

30. An electronic device comprising the organic electroluminescence device according to claim 1.
